(19) United States
(12) Patent Application Publication
(10) Pub. No.: US 2025/0143174 A1
(43) Pub. Date: May 1, 2025

(54) ORGANIC ELECTROLUMINESCENT COMPOUND, ORGANIC ELECTROLUMINESCENT MATERIAL, AND ORGANIC ELECTROLUMINESCENT DEVICE COMPRISING THE SAME

(71) Applicant: DuPont Specialty Materials Korea Ltd., Chungcheongnam-do (KR)

(72) Inventors: Jeong-Eun YANG, Gyeonggi-do (KR); Jeong-Hwan JEON, Gyeonggi-do (KR); Sang-Hee CHO, Gyeonggi-do (KR); Hee-Ryong KANG, Gyeonggi-do (KR); Hyo-Jung LEE, Gyeonggi-do (KR)

(21) Appl. No.: 18/899,248

(22) Filed: Sep. 27, 2024

(30) Foreign Application Priority Data
Oct. 31, 2023 (KR) 10-2023-0147448

(51) Int. Cl. H10K 85/60

(52) U.S. Cl. CPC H10K 85/615; H10K 85/622; H10K 85/633; H10K 85/654; H10K 85/6572; H10K 85/6574; H10K 85/6576

(57) ABSTRACT

The present disclosure relates to an organic electroluminescent compound represented by formula 1, an organic electroluminescent material comprising compounds represented by formula 1 and formula 2, an organic electroluminescent material comprising compounds represented by formula 1 and formula 3, and an organic electroluminescent device comprising the same. An organic electroluminescent device with improved driving voltage, luminous efficiency, and/or lifetime properties can be provided by comprising the organic electroluminescent compound or the organic electroluminescent material according to the present disclosure.

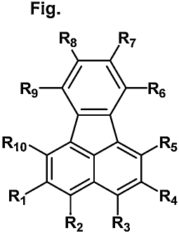

### TECHNICAL FIELD

The present disclosure relates to an organic electroluminescent compound, an organic electroluminescent material, and an organic electroluminescent device comprising the same.

### BACKGROUND ART

A small molecular green organic electroluminescent device (OLED) was first developed by Tang et al. of Eastman Kodak in 1987, utilizing a TPD/ALq3 bi-layer consisting of a light-emitting layer and a charge transport layer. Thereafter, OLED development progressed rapidly, leading to commercialization. Currently, OLEDs primarily use phosphorescent materials with excellent luminous efficiency in panel implementation. However, in various applications such as TVs and lighting, the lifetime of OLEDs is often insufficient, and OLEDs with higher efficiency are still required. Generally, the lifetime of an OLED decreases as its luminance increases. Thus, OLEDs with high luminous efficiency and/or extended lifetime are essential for long-term use and high-resolution displays.

In order to improve luminous efficiency, driving voltage, and/or lifetime, various materials or concepts for an organic layer of an organic electroluminescent device have been proposed, but these did not prove satisfactory in practical use. In addition, there is a continuous demand for the development of organic electroluminescent material with enhanced performance, such as improved driving voltage, luminous efficiency, power efficiency, and/or lifetime properties, as compared to combinations of previously disclosed specific compounds.

Meanwhile, Korean Patent Application Laid-Open No. 10-2023-0001569, Chinese Patent Application Laid-Open No. 111423390A, Korean Patent Application Laid-Open No. 10-2022-0123495 and Korean Patent Application Laid-Open No. 10-2021-0062293 disclose fluoranthene derivatives, etc. as an organic electroluminescent compound. Nevertheless, the aforementioned references fail to specifically disclose a compound having a specific structure and an organic electroluminescent material comprising the same as claimed in the present disclosure. In addition, there is a continuous demand for the development of organic electroluminescent material with enhanced performance, such as improved driving voltage, luminous efficiency, and/or lifetime properties, as compared to combinations of previously disclosed specific compounds.

### DISCLOSURE OF INVENTION

### Technical Problem

The objective of the present disclosure is to provide an organic electroluminescent compound with a new structure suitable for application to an organic electroluminescent device. Another objective of the present disclosure is to provide an organic electroluminescent compound and an organic electroluminescent material capable of providing an organic electroluminescent device with improved driving voltage, luminous efficiency, and/or lifetime properties.

### Solution to Problem

As a result of intensive study to solve the technical problems, the present inventors found that the above objective can be achieved by an organic electroluminescent compound represented by the following Formula 1.

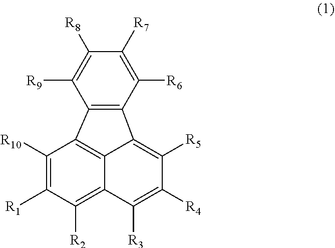

In Formula 1,

R₁ and R₂ are linked to each other to form a substituted or unsubstituted fused ring(s);

R₃ to R₁₀ each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1—C30)alkyldi(C6-C30)arylsilyl, or a substituted or unsubstituted tri(C6-C30)arylsilyl; and

at least one of the substituent(s) of the fused ring(s) and R₃ to R₁₀ represents a substituted or unsubstituted (3- to 30-membered)heteroaryl comprising at least one N.

In addition, the present inventors found that the above objective can be achieved by an organic electroluminescent material comprising a compound represented by the above Formula 1 and a compound represented by the following Formula 2 or a compound represented by the above Formula 1 and a compound represented by the following Formula 3.

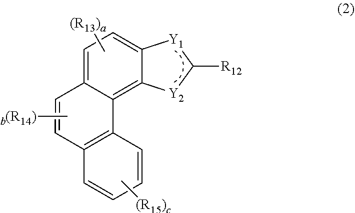

In Formula 2,

Y₁ and Y₂ each independently represent —N═, —NR₁₆—, —O—, or —S—, with a proviso that any one of Y₁ and Y₂ represents —N═, and the other of Y₁ and Y₂ represents —NR₁₆—, —O—, or —S—;

R₁₂ represents a substituted or unsubstituted (C6-C30)aryl, or a substituted or unsubstituted (3- to 30-membered)heteroaryl;

R₁₃ to R₁₆ each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring group of a (C3-C30) aliphatic ring(s) and a (C6-C30) aromatic ring(s), or -L₁-N(Ar₁)(Ar₂); or may be linked to an adjacent substituent(s) to form a ring(s); with a proviso that at least one of R₁₃ to R₁₅ is -L₁-N(Ar₁)(Ar₂);

Ar₁ and Ar₂ each independently represent a substituted or unsubstituted (C6-C30)aryl, a substituted or unsubstituted (3- to 30-membered)heteroaryl, or a substituted or unsubstituted fused ring group of a (C3-C30) aliphatic ring(s) and a (C6-C30) aromatic ring(s);

L₁ represents a single bond, a substituted or unsubstituted (C6-C30)arylene, or a substituted or unsubstituted (3- to 30-membered)heteroarylene; and

a and b each independently represent an integer of 1 or 2, c represents an integer of 1 to 4, where if a to c are an integer of 2 or more, each of R₁₃ to each of R₁₅ may be the same as or different from each other.

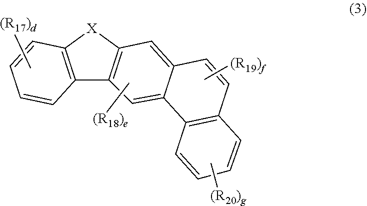

In Formula 3,

X represents O, S, CR₂₁R₂₂, NR₂₃, or Se;

R₂₁ to R₂₃ each independently represent hydrogen, deuterium, a halogen, a substituted or unsubstituted (C₁-C₃₀)alkyl, a substituted or unsubstituted (C6-C30)aryl, or a substituted or unsubstituted (3- to 30-membered)heteroaryl; or may be linked to an adjacent substituent(s) to form a ring(s);

R₁₇ to R₂₀ each independently represent hydrogen, deuterium, a halogen, a substituted or unsubstituted (C1-C30)alkyl, a substituted or unsubstituted (C6-C30)aryl,

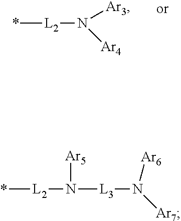

with a proviso that at least one of R₁₇ to R₂₀ is

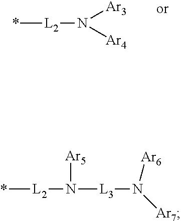

L₂ and L₃ each independently represent a single bond, a substituted or unsubstituted (C6-C30)arylene, a substituted or unsubstituted (C3—C30)cycloalkylene, or a substituted or unsubstituted (3- to 30-membered)heteroarylene;

Ar₃ to Ar₇ each independently represent a substituted or unsubstituted (C6-C30)aryl or a substituted or unsubstituted (3- to 30-membered)heteroaryl;

d and g represent an integer of 1 to 4, e and f represent an integer of 1 or 2, where if d to g are an integer of 2 or more, each of R₁₇ to each of R₂₀ may be the same as or different from each other; and

* represents a site linked to Formula 3.

### Advantageous Effects of Invention

An organic electroluminescent device with improved driving voltage, luminous efficiency, and/or lifetime properties can be provided by comprising the organic electroluminescent compound and the organic electroluminescent material according to the present disclosure.

### BRIEF DESCRIPTION OF THE FIGURE

FIGURE illustrates representative formula for the organic electroluminescent compound according to the present disclosure.

### MODE FOR THE INVENTION

Hereinafter, the present disclosure will be described in detail. However, the following description is intended to explain the present disclosure, and is not meant to restrict the scope of the present disclosure.

The term “organic electroluminescent compound” in the present disclosure refers to a compound that may be used in an organic electroluminescent device, and may be incorporated into any layer constituting an organic electroluminescent device, as necessary.

The term “organic electroluminescent material” in the present disclosure refers to a material that may be used in an organic electroluminescent device, and may comprise at least one compound. The organic electroluminescent material may be incorporated into any layer constituting an organic electroluminescent device, as necessary. For example, the organic electroluminescent material may be any of the following: a hole injection material, a hole transport material, a hole auxiliary material, a light-emitting auxiliary material, an electron-blocking material, a light-emitting material (including a host material and a dopant material), an electron buffer material, a hole-blocking material, an electron transport material, an electron injection material, etc.

The term “a plurality of host materials” in the present disclosure means a host material comprising a combination of at least two compounds, which may be comprised in any light-emitting layer constituting an organic electroluminescent device. It may mean both a material before being comprised in an organic electroluminescent device (for example, before vapor deposition) and a material after being comprised in an organic electroluminescent device (for example, after vapor deposition). For example, the plurality of host materials of the present disclosure is a combination of at least two host materials, and may selectively further comprise conventional materials comprised in an organic electroluminescent material. At least two compounds comprised in the plurality of host materials of the present disclosure may be comprised together in one light-emitting layer or may respectively be comprised in different light-emitting layers. For example, the at least two host materials may be mixture-evaporated or co-evaporated, or may be individually evaporated.

The term “hole transport zone” in the present disclosure means a zone where holes move between the first electrode and the light-emitting layer, and may include, for example, one or more of a hole injection layer, a hole transport layer, a hole auxiliary layer, a light-emitting auxiliary layer, and an electron-blocking layer. The hole injection layer, hole transport layer, hole auxiliary layer, light-emitting auxiliary layer, and electron-blocking layer may each be a single layer, two or more layers, or multiple layers in which three or more layers are laminated. According to one embodiment of the present disclosure, the hole transport zone may include a first hole transport layer and a second hole transport layer, and may further include a third hole transport layer. The second hole transport layer and the third hole transport layer may be at least one of a plurality of hole transport layers and may include at least one of a hole auxiliary layer, a light-emitting auxiliary layer, and an electron-blocking layer. In addition, according to another embodiment of the present disclosure, the hole transport zone includes a first hole transport layer and a second hole transport layer, the first hole transport layer can be located between the first electrode and the light-emitting layer, the second hole transport layer can be located between the first hole transport layer and the light-emitting layer, and the second hole transport layer can be a layer that functions as a hole transport layer, a light-emitting auxiliary layer, a hole auxiliary layer, and/or an electron-blocking layer.

According to another embodiment of the present disclosure, the hole transport zone includes a first hole transport layer, a second hole transport layer, and a third hole transport layer, wherein the first hole transport layer can be located between the first electrode and the light-emitting layer, the second hole transport layer can be located between the first hole transport layer and the light-emitting layer, the third hole transport layer can be located between the second hole transport layer and the light-emitting layer, and the third hole transport layer can be a layer that functions as a hole transport layer, a light-emitting auxiliary layer, a hole auxiliary layer, and/or an electron-blocking layer.

Herein, the term “(C1-C30)alkyl” is meant to be a linear or branched alkyl having 1 to 30 carbon atoms constituting the chain, in which the number of carbon atoms is preferably 1 to 10, and more preferably 1 to 6. The above alkyl may include methyl, ethyl, n-propyl, isopropyl, n-butyl, isobutyl, tert-butyl, sec-butyl, etc. The term “(C3-C30)cycloalkyl” is meant to be a mono- or polycyclic hydrocarbon having 3 to 30 ring backbone carbon atoms, in which the number of carbon atoms is preferably 3 to 20, and more preferably 3 to 7. The above cycloalkyl may include cyclopropyl, cyclobutyl, cyclopentyl, cyclohexyl, cyclopentylmethyl, cyclohexylmethyl, etc. The term “(3- to 7-membered)heterocycloalkyl” is meant to be a cycloalkyl having 3 to 7 ring backbone atoms, and including at least one heteroatom selected from the group consisting of B, N, O, S, Si, and P, and preferably the group consisting of O, S, and N. The above heterocycloalkyl may include tetrahydrofuran, pyrrolidine, thiolan, tetrahydropyran, etc. The term “(C6-C30)aryl”, “(C6-C30)arylene”, and “(C6-C30)arentriyl” are meant to be a monocyclic or fused ring radical derived from an aromatic hydrocarbon having 6 to 30 ring backbone carbon atoms. The above aryl, arylene, and arentriyl may be partially saturated, and may comprise a spiro structure. The above aryl may include phenyl, biphenyl, terphenyl, quinquephenyl, naphthyl, binaphthyl, phenylnaphthyl, naphthylphenyl, fluorenyl, phenylfluorenyl, diphenylfluorenyl, benzofluorenyl, dibenzofluorenyl, phenanthrenyl, phenylphenanthrenyl, benzophenanthrenyl, anthracenyl, indenyl, triphenylenyl, pyrenyl, tetracenyl, perylenyl, chrysenyl, naphthacenyl, fluoranthenyl, spirobifluorenyl, spiro[fluorene-benzofluoren]yl, spiro[cyclopentene-fluoren]yl, spiro[dihydroindene-fluoren]yl, azulenyl, tetramethyldihydrophenanthrenyl, etc.

Specifically, the above aryl may include phenyl, 1-naphthyl, 2-naphthyl, 1-anthryl, 2-anthryl, 9-anthryl, benzanthryl, 1-phenanthryl, 2-phenanthryl, 3-phenanthryl, 4-phenanthryl, 9-phenanthryl, naphthacenyl, pyrenyl, 1-chrysenyl, 2-chrysenyl, 3-chrysenyl, 4-chrysenyl, 5-chrysenyl, 6-chrysenyl, benzo[c]phenanthryl, benzo[g]chrysenyl, 1-triphenylenyl, 2-triphenylenyl, 3-triphenylenyl, 4-triphenylenyl, 1-fluorenyl, 2-fluorenyl, 3-fluorenyl, 4-fluorenyl, 9-fluorenyl, benzo[a]fluorenyl, benzo[b]fluorenyl, benzo[c]fluorenyl, dibenzofluorenyl, 2-biphenyl, 3-biphenyl, 4-biphenyl, o-terphenyl, m-terphenyl-4-yl, m-terphenyl-3-yl, m-terphenyl-2-yl, p-terphenyl-4-yl, p-terphenyl-3-yl, p-terphenyl-2-yl, m-quaterphenyl, 3-fluoranthenyl, 4-fluoranthenyl, 8-fluoranthenyl, 9-fluoranthenyl, benzofluoranthenyl, o-tolyl, m-tolyl, p-tolyl, 2,3-xylyl, 3,4-xylyl, 2,5-xylyl, mesityl, o-cumenyl, m-cumenyl, p-cumenyl, p-tert-butylphenyl, p-(2-phenylpropyl)phenyl, 4′-methylbiphenyl, 4″-tert-butyl-p-terphenyl-4-yl, 9,9-dimethyl-1-fluorenyl, 9,9-dimethyl-2-fluorenyl, 9,9-dimethyl-3-fluorenyl, 9,9-dimethyl-4-fluorenyl, 9,9-diphenyl-1-fluorenyl, 9,9-diphenyl-2-fluorenyl, 9,9-diphenyl-3-fluorenyl, 9,9-diphenyl-4-fluorenyl, 11,11-dimethyl-1-benzo[a]fluorenyl, 11,11-dimethyl-2-benzo[a]fluorenyl, 11,11-dimethyl-3-benzo[a]fluorenyl, 11,11-dimethyl-4-benzo[a]fluorenyl, 11,11-dimethyl-5-benzo[a]fluorenyl, 11,11-dimethyl-6-benzo[a]fluorenyl, 11,11-dimethyl-7-benzo[a]fluorenyl, 11,11-dimethyl-8-benzo[a]fluorenyl, 11,11-dimethyl-9-benzo[a]fluorenyl, 11,11-dimethyl-10-benzo[a]fluorenyl, 11,11-dimethyl-1-benzo[b]fluorenyl, 11,11-dimethyl-2-benzo[b]fluorenyl, 11,11-dimethyl-3-benzo[b]fluorenyl, 11,11-dimethyl-4-benzo[b]fluorenyl, 11,11-dimethyl-5-benzo[b]fluorenyl, 11,11-dimethyl-6-benzo[b]fluorenyl, 11,11-dimethyl-7-benzo[b]fluorenyl, 11,11-dimethyl-8-benzo[b]fluorenyl, 11,11-dimethyl-9-benzo[b]fluorenyl, 11,11-dimethyl-10-benzo[b]fluorenyl, 11,11-dimethyl-1-benzo[c]fluorenyl, 11,11-dimethyl-2-benzo[c]fluorenyl, 11,11-dimethyl-3-benzo[c]fluorenyl, 11,11-dimethyl-4-benzo[c]fluorenyl, 11,11-dimethyl-5-benzo[c]fluorenyl, 11,11-dimethyl-6-benzo[c]fluorenyl, 11,11-dimethyl-7-benzo[c]fluorenyl, 11,11-dimethyl-8-benzo[c]fluorenyl, 11,11-dimethyl-9-benzo[c]fluorenyl, 11,11-dimethyl-10-benzo[c]fluorenyl, 11,11-diphenyl-1-benzo[a]fluorenyl, 11,11-diphenyl-2-benzo[a]fluorenyl, 11,11-diphenyl-3-benzo[a]fluorenyl, 11,11-diphenyl-4-benzo[a]fluorenyl, 11,11-diphenyl-5-benzo[a]fluorenyl, 11,11-diphenyl-6-benzo[a]fluorenyl, 11,11-diphenyl-7-benzo[a]fluorenyl, 11,11-diphenyl-8-benzo[a]fluorenyl, 11,11-diphenyl-9-benzo[a]fluorenyl, 11,11-diphenyl-10-benzo[a]fluorenyl, 11,11-diphenyl-1-benzo[b]fluorenyl, 11,11-diphenyl-2-benzo[b]fluorenyl, 11,11-diphenyl-3-benzo[b]fluorenyl, 11,11-diphenyl-4-benzo[b]fluorenyl, 11,11-diphenyl-5-benzo[b]fluorenyl, 11,11-diphenyl-6-benzo[b]fluorenyl, 11,11-diphenyl-7-benzo[b]fluorenyl, 11,11-diphenyl-8-benzo[b]fluorenyl, 11,11-diphenyl-9-benzo[b]fluorenyl, 11,11-diphenyl-10-benzo[b]fluorenyl, 11,11-diphenyl-1-benzo[c]fluorenyl, 11,11-diphenyl-2-benzo[c]fluorenyl, 11,11-diphenyl-3-benzo[c]fluorenyl, 11,11-diphenyl-4-benzo[c]fluorenyl, 11,11-diphenyl-5-benzo[c]fluorenyl, 11,11-diphenyl-6-benzo[c]fluorenyl, 11,11-diphenyl-7-benzo[c]fluorenyl, 11,11-diphenyl-8-benzo[c]fluorenyl, 11,11-diphenyl-9-benzo[c]fluorenyl, 11,11-diphenyl-10-benzo[c]fluorenyl, 9,9,10,10-tetramethyl-9,10-dihydro-1-phenanthrenyl, 9,9,10,10-tetramethyl-9,10-dihydro-2-phenanthrenyl, 9,9,10,10-tetramethyl-9,10-dihydro-3-phenanthrenyl, 9,9,10,10-tetramethyl-9,10-dihydro-4-phenanthrenyl, etc.

The term “(3- to 30-membered)heteroaryl”, “(3- to 30-membered)heteroarylene”, and “(3- to 30-membered)heteroarentriyl” are meant to be an aryl group having 3 to 30 ring backbone atoms, and including at least one, preferably 1 to 4 heteroatoms selected from the group consisting of B, N, O, S, Si, P, Se, Te, and Ge. The above heteroaryl may be a monocyclic ring, or a fused ring condensed with at least one benzene ring; may be partially saturated; may be one formed by linking at least one heteroaryl or aryl group to a heteroaryl group via a single bond(s); and may comprise a spiro structure. The above heteroaryl may include a monocyclic ring-type heteroaryl such as furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, and pyridazinyl, and a fused ring-type heteroaryl such as benzofuranyl, benzothiophenyl, isobenzofuranyl, dibenzofuranyl, dibenzothiophenyl, dibenzoselenophenyl, naphthobenzofuranyl, naphthobenzothiophenyl, naphthooxazolyl, benzofuroquinolinyl, benzofuroquinazolinyl, benzofuronaphthyridinyl, benzofuropyrimidinyl, naphthofuropyrimidinyl, benzothienoquinolyl, benzothienoquinazolinyl, naphthyridinyl, benzothienonaphthyridinyl, benzothienopyrimidinyl, naphthothienopyrimidinyl, pyrimidoindolyl, benzopyrimidoindolyl, benzofuropyrazinyl, naphthofuropyrazinyl, benzothienopyrazinyl, naphthothienopyrazinyl, phenanthrooxazolyl, phenanthrothiazolyl, phenanthrobenzofuranyl, benzophenanthrothiophenyl, pyrazinoindolyl, benzopyrazinoindolyl, benzimidazolyl, benzothiazolyl, benzoisothiazolyl, benzoisoxazolyl, benzoxazolyl, isoindolyl, indolyl, indazolyl, benzothiadiazolyl, quinolyl, isoquinolyl, cinnolinyl, quinazolinyl, benzoquinazolinyl, quinoxalinyl, benzoquinoxalinyl, carbazolyl, benzocarbazolyl, dibenzocarbazolyl, phenoxazinyl, phenanthridinyl, benzodioxolyl, dihydroacridinyl, benzotriazolyl, phenazinyl, imidazopyridyl, chromenoquinazolinyl, thiochromenoquinazolinyl, dimethylbenzoperimidinyl, indolocarbazolyl, indenocarbazolyl, etc. More specifically, the above heteroaryl may include 1-pyrrolyl, 2-pyrrolyl, 3-pyrrolyl, pyrazinyl, 2-pyridyl, 2-pyrimidinyl, 4-pyrimidinyl, 5-pyrimidinyl, 6-pyrimidinyl, 1,2,3-triazin-4-yl, 1,2,4-triazin-3-yl, 1,3,5-triazin-2-yl, 1-imidazolyl, 2-imidazolyl, 1-pyrazolyl, 1-indolidinyl, 2-indolidinyl, 3-indolidinyl, 5-indolidinyl, 6-indolidinyl, 7-indolidinyl, 8-indolidinyl, 2-imidazopyridyl, 3-imidazopyridyl, 5-imidazopyridyl, 6-imidazopyridyl, 7-imidazopyridyl, 8-imidazopyridyl, 3-pyridyl, 4-pyridyl, 1-indolyl, 2-indolyl, 3-indolyl, 4-indolyl, 5-indolyl, 6-indolyl, 7-indolyl, 1-isoindolyl, 2-isoindolyl, 3-isoindolyl, 4-isoindolyl, 5-isoindolyl, 6-isoindolyl, 7-isoindolyl, 2-furyl, 3-furyl, 2-benzofuranyl, 3-benzofuranyl, 4-benzofuranyl, 5-benzofuranyl, 6-benzofuranyl, 7-benzofuranyl, 1-isobenzofuranyl, 3-isobenzofuranyl, 4-isobenzofuranyl, 5-isobenzofuranyl, 6-isobenzofuranyl, 7-isobenzofuranyl, 2-quinolyl, 3-quinolyl, 4-quinolyl, 5-quinolyl, 6-quinolyl, 7-quinolyl, 8-quinolyl, 1-isoquinolyl, 3-isoquinolyl, 4-isoquinolyl, 5-isoquinolyl, 6-isoquinolyl, 7-isoquinolyl, 8-isoquinolyl, 2-quinoxalinyl, 5-quinoxalinyl, 6-quinoxalinyl, 1-carbazolyl, 2-carbazolyl, 3-carbazolyl, 4-carbazolyl, 9-carbazolyl, azacarbazol-1-yl, azacarbazol-2-yl, azacarbazol-3-yl, azacarbazol-4-yl, azacarbazol-5-yl, azacarbazol-6-yl, azacarbazol-7-yl, azacarbazol-8-yl, azacarbazol-9-yl, 1-phenanthridinyl, 2-phenanthridinyl, 3-phenanthridinyl, 4-phenanthridinyl, 6-phenanthridinyl, 7-phenanthridinyl, 8-phenanthridinyl, 9-phenanthridinyl, 10-phenanthridinyl, 1-acridinyl, 2-acridinyl, 3-acridinyl, 4-acridinyl, 9-acridinyl, 2-oxazolyl, 4-oxazolyl, 5-oxazolyl, 2-oxadiazolyl, 5-oxadiazolyl, 3-furazanyl, 2-thienyl, 3-thienyl, 2-methylpyrrol-1-yl, 2-methylpyrrol-3-yl, 2-methylpyrrol-4-yl, 2-methylpyrrol-5-yl, 3-methylpyrrol-1-yl, 3-methylpyrrol-2-yl, 3-methylpyrrol-4-yl, 3-methylpyrrol-5-yl, 2-tert-butylpyrrol-4-yl, 3-(2-phenylpropyl)pyrrol-1-yl, 2-methyl-1-indolyl, 4-methyl-1-indolyl, 2-methyl-3-indolyl, 4-methyl-3-indolyl, 2-tert-butyl-1-indolyl, 4-tert-butyl-1-indolyl, 2-tert-butyl-3-indolyl, 4-tert-butyl-3-indolyl, 1-dibenzofuranyl, 2-dibenzofuranyl, 3-dibenzofuranyl, 4-dibenzofuranyl, 1-dibenzothiophenyl, 2-dibenzothiophenyl, 3-dibenzothiophenyl, 4-dibenzothiophenyl, 1-naphtho-[1,2-b]-benzofuranyl, 2-naphtho-[1,2-b]-benzofuranyl, 3-naphtho-[1,2-b]-benzofuranyl, 4-naphtho-[1,2-b]-benzofuranyl, 5-naphtho-[1,2-b]-benzofuranyl, 6-naphtho-[1,2-b]-benzofuranyl, 7-naphtho-[1,2-b]-benzofuranyl, 8-naphtho-[1,2-b]-benzofuranyl, 9-naphtho-[1,2-b]-benzofuranyl, 10-naphtho-[1,2-b]-benzofuranyl, 1-naphtho-[2,3-b]-benzofuranyl, 2-naphtho-[2,3-b]-benzofuranyl, 3-naphtho-[2,3-b]-benzofuranyl, 4-naphtho-[2,3-b]-benzofuranyl, 5-naphtho-[2,3-b]-benzofuranyl, 6-naphtho-[2,3-b]-benzofuranyl, 7-naphtho-[2,3-b]-benzofuranyl, 8-naphtho-[2,3-b]-benzofuranyl, 9-naphtho-[2,3-b]-benzofuranyl, 10-naphtho-[2,3-b]-benzofuranyl, 1-naphtho-[2,1-b]-benzofuranyl, 2-naphtho-[2,1-b]-benzofuranyl, 3-naphtho-[2,1-b]-benzofuranyl, 4-naphtho-[2,1-b]-benzofuranyl, 5-naphtho-[2,1-b]-benzofuranyl, 6-naphtho-[2,1-b]-benzofuranyl, 7-naphtho-[2,1-b]-benzofuranyl, 8-naphtho-[2,1-b]-benzofuranyl, 9-naphtho-[2,1-b]-benzofuranyl, 10-naphtho-[2,1-b]-benzofuranyl, 1-naphtho-[1,2-b]-benzothiophenyl, 2-naphtho-[1,2-b]-benzothiophenyl, 3-naphtho-[1,2-b]-benzothiophenyl, 4-naphtho-[1,2-b]-benzothiophenyl, 5-naphtho-[1,2-b]-benzothiophenyl, 6-naphtho-[1,2-b]-benzothiophenyl, 7-naphtho-[1,2-b]-benzothiophenyl, 8-naphtho-[1,2-b]-benzothiophenyl, 9-naphtho-[1,2-b]-benzothiophenyl, 10-naphtho-[1,2-b]-benzothiophenyl, 1-naphtho-[2,3-b]-benzothiophenyl, 2-naphtho-[2,3-b]-benzothiophenyl, 3-naphtho-[2,3-b]-benzothiophenyl, 4-naphtho-[2,3-b]-benzothiophenyl, 5-naphtho-[2,3-b]-benzothiophenyl, 1-naphtho-[2,1-b]-benzothiophenyl, 2-naphtho-[2,1-b]-benzothiophenyl, 3-naphtho-[2,1-b]-benzothiophenyl, 4-naphtho-[2,1-b]-benzothiophenyl, 5-naphtho-[2,1-b]-benzothiophenyl, 6-naphtho-[2,1-b]-benzothiophenyl, 7-naphtho-[2,1-b]-benzothiophenyl, 8-naphtho-[2,1-b]-benzothiophenyl, 9-naphtho-[2,1-b]-benzothiophenyl, 10-naphtho-[2,1-b]-benzothiophenyl, 2-benzofuro[3,2-d]pyrimidinyl, 6-benzofuro[3,2-d]pyrimidinyl, 7-benzofuro[3,2-d]pyrimidinyl, 8-benzofuro[3,2-d]pyrimidinyl, 9-benzofuro[3,2-d]pyrimidinyl, 2-benzothio[3,2-d]pyrimidinyl, 6-benzothio[3,2-d]pyrimidinyl, 7-benzothio[3,2-d]pyrimidinyl, 8-benzothio[3,2-d]pyrimidinyl, 9-benzothio[3,2-d]pyrimidinyl, 2-benzofuro[3,2-d]pyrazinyl, 6-benzofuro[3,2-d]pyrazinyl, 7-benzofuro[3,2-d]pyrazinyl, 8-benzofuro[3,2-d]pyrazinyl, 9-benzofuro[3,2-d]pyrazinyl, 2-benzothio[3,2-d]pyrazinyl, 6-benzothio[3,2-d]pyrazinyl, 7-benzothio[3,2-d]pyrazinyl, 8-benzothio[3,2-d]pyrazinyl, 9-benzothio[3,2-d]pyrazinyl, 1-silafluorenyl, 2-silafluorenyl, 3-silafluorenyl, 4-silafluorenyl, 1-germafluorenyl, 2-germafluorenyl, 3-germafluorenyl, 4-germafluorenyl, 1-dibenzoselenophenyl, 2-dibenzoselenophenyl, 3-dibenzoselenophenyl, 4-dibenzoselenophenyl, etc. “Heteroaryl(ene)” can be classified into heteroaryl(eme) with electronic properties and heteroaryl(ene) with hole properties. Heteroaryl(ene) with electronic properties is a substituent that is relatively rich in electrons in the parent nucleus, for example, a substituted or unsubstituted pyridinyl, a substituted or unsubstituted pyrimidinyl, a substituted or unsubstituted triazinyl, a substituted or unsubstituted quinazolinyl, a substituted or unsubstituted quinoxalinyl, a substituted or unsubstituted quinolyl, etc. Heteroaryl(ene) with hole properties is a substituent that is relatively electron-deficient in the parent nucleus, for example, a substituted or unsubstituted carbazolyl, a substituted or unsubstituted dibenzofuranyl, a substituted or unsubstituted dibenzothiophenyl, etc. In the present disclosure, the term “halogen” includes F, Cl, Br, and I.

In addition, “ortho-” (“o-”), “meta-” (“m-”), and “para-” (“p-”) are prefixes which each represent the relative positions of substituents. The prefix “ortho-” indicates that two substituents are adjacent to each other, and for example, when two substituents in a benzene derivative occupy positions 1 and 2, or positions 2 and 3, this is called an “ortho-” configuration. The prefix “meta-” indicates that two substituents are at positions 1 and 3, and for example, when two substituents in a benzene derivative occupy positions 1 and 3, this is called a “meta-” configuration. The prefix “para-” indicates that two substituents are at positions 1 and 4, and for example, when two substituents in a benzene derivative occupy positions 1 and 4, this is called a “para-” configuration. Unless otherwise specified, the substituent may replace hydrogen at a position where the substituent can be substituted without limitation, and when two or more hydrogen atoms in a certain functional group are each replaced with a substituent, each substituent may be the same as or different from each other. The maximum number of substituents that can be substituted for a certain functional group may be the total number of valences that can be substituted for each atom forming the functional group. Herein, the substituted alkyl, the substituted cycloalkyl, the substituted aryl(ene), the substituted heteroaryl(ene), the substituted alkoxy, the substituted trialkylsilyl, the substituted dialkylarylsilyl, the substituted alkyldiarylsilyl, the substituted triarylsilyl, the substituted fused ring, the substituted fused ring group of an aliphatic ring(s) and an aromatic ring(s) in the formulas of the present disclosure each independently are substituted by at least one selected from the group consisting of deuterium; a halogen; a cyano; a carboxyl; a nitro; a hydroxyl; a phosphine oxide; a (C1-C30)alkyl; a halo(C1-C30)alkyl; a (C2-C30)alkenyl; a (C2-C30)alkynyl; a (C1-C30)alkoxy; a (C1-C30)alkylthio; a (C3-C30)cycloalkyl; a (C3-C30)cycloalkenyl; a (3- to 7-membered)heterocycloalkyl; a (C6-C30)aryloxy; a (C6-C30)arylthio; a (C6-C30)aryl unsubstituted or substituted with at least one of a (C1-C30)alkyl(s) and a di(C6-C30)arylamino(s); a (3- to 30-membered)heteroaryl unsubstituted or substituted with a (C6-C30)aryl(s); a tri(C1-C30)alkylsilyl; a tri(C6-C30)arylsilyl(s); a di(C1-C30)alkyl(C6-C30)arylsilyl; a (C1-C30)alkyldi(C6-C30)arylsilyl; a fused ring group of an (C3-C30)aliphatic ring(s) and an (C6-C30)aromatic ring(s); amino; a mono- or di-(C1-C30)alkylamino; a mono- or di-(C2-C30)alkenylamino; a mono- or di-(C6-C30)arylamino unsubstituted or substituted with a (C1-C30)alkyl(s); a mono- or di-(3- to 30-membered)heteroarylamino; a (C1-C30)alkyl(C2-C30)alkenylamino; a (C1-C30)alkyl(C6-C30)arylamino; a (C1-C30)alkyl(3- to 30-membered)heteroarylamino; a (C2-C30)alkenyl(C6-C30)arylamino; a (C2-C30)alkenyl(3- to 30-membered)heteroarylamino; a (C6-C30)aryl(3- to 30-membered)heteroarylamino; a (C1-C30)alkylcarbonyl; a (C1-C30)alkoxycarbonyl; a (C6-C30)arylcarbonyl; a di(C6-C30)arylboronyl; a di(C1-C30)alkylboronyl; a (C1-C30)alkyl(C6-C30)arylboronyl; a (C6-C30)aryl(C1-C30)alkyl; and a (C1-C30)alkyl(C6-C30)aryl. According to one embodiment of the present disclosure, the substituted compounds each independently are substituted by at least one selected from the group consisting of deuterium; a halogen; a (C1—C30)alkyl; a halo(C1-C30)alkyl; a (C2-C30)alkenyl; a (C1-C30)alkoxy; a (C1-C30)alkylthio; a (C3-C30)cycloalkyl; a (C3-C30)cycloalkenyl; a (3- to 7-membered)heterocycloalkyl; a (C6-C30)aryloxy; a (C6-C30)arylthio; a (C6-C30)aryl unsubstituted or substituted with at least one of a (C1-C30)alkyl(s) and a di(C6-C30)arylamino(s); a (3- to 30-membered)heteroaryl unsubstituted or substituted with a (C6-C30)aryl(s); a fused ring group of an (C3-C30)aliphatic ring(s) and an (C6-C30)aromatic ring(s); amino; a mono- or di-(C1-C30)alkylamino; a mono- or di-(C2-C30)alkenylamino; a mono- or di-(C6-C30)arylamino unsubstituted or substituted with a (C1-C30)alkyl(s); a mono- or di-(3- to 30-membered)heteroarylamino; a (C1-C30)alkyl(C2-C30)alkenylamino; a (C1-C30)alkyl(C6-C30)arylamino; a (C1-C30)alkyl(3- to 30-membered)heteroarylamino; a (C2-C30)alkenyl(C6-C30)arylamino; a (C2-C30)alkenyl(3- to 30-membered)heteroarylamino; a (C6-C30)aryl(3- to 30-membered)heteroarylamino; a (C6-C30)aryl(C1-C30)alkyl; and a (C1-C30)alkyl(C6-C30)aryl. According to another embodiment of the present disclosure, the substituted compounds each independently are substituted by at least one selected from the group consisting of deuterium; a halogen; a (C1-C30)alkyl; a halo(C1-C30)alkyl; a (C2-C30)alkenyl; a (C1-C30)alkoxy; a (C1-C30)alkylthio; a (C3-C30)cycloalkyl; a (3- to 7-membered)heterocycloalkyl; a (C6-C30)aryloxy; a (C6-C30)arylthio; a (C6-C30)aryl unsubstituted or substituted with at least one of a (C1-C30)alkyl(s) and a di(C6-C30)arylamino(s); a (3- to 30-membered)heteroaryl unsubstituted or substituted with a (C6-C30)aryl(s); a fused ring group of an (C3-C30)aliphatic ring(s) and an (C6-C30)aromatic ring(s); amino; a mono- or di-(C6-C30)arylamino unsubstituted or substituted with (C1-C30)alkyl(s); a (C1-C30)alkyl(C6-C30)arylamino; a (C1-C30)alkyl(3- to 30-membered)heteroarylamino; a (C2-C30)alkenyl(C6-C30)arylamino; a (C2-C30)alkenyl(3- to 30-membered)heteroarylamino; a (C6-C30)aryl(3- to 30-membered)heteroarylamino; a (C6-C30)aryl(C1-C30)alkyl; and a (C1-C30)alkyl(C6-C30)aryl. For example, the substituted compounds each independently may be substituted by at least one selected from the group consisting of deuterium, a methyl, a cyclohexyl, a fluoranthenyl, a phenoxazinyl, a t-butylphenyl, a phenyl, a phenyl substituted with deuterium, a phenyl substituted with a naphthyl, a biphenyl, a terphenyl, a naphthyl, a naphthyl substituted with a phenyl, a dinaphthyl, a dibenzofuranyl, a dibenzofuranyl substituted with a phenyl, a triazinyl substituted with a diphenyl, a dibenzothiophenyl, a carbazolyl substituted with a phenyl, a carbazolyl, a benzothiazolyl, a phenanthrenyl, a dibenzoselenophenyl, an isochrycenyl, an anthracenyl, a benzoimidazolyl substituted with a phenyl, a pyridinyl substituted with a phenyl, a xylene, a dimethylfluorenyl, a naphthotriazolyl, a benzonaphthofuranyl, a dimethylbenzofluorenyl, a benzonaphthofuranyl, and a diphenylamino.

In the present disclosure, if a substituent is not indicated in the Formula or compound structure, this may mean that all possible positions for the substituent are hydrogen or deuterium. That is, in the case of deuterium, it is an isotope of hydrogen, and some hydrogen atoms may be the isotope deuterium, and in this case, the content of deuterium may be 0% to 100%. In the present disclosure, in cases where a substituent is not indicated in the Formula or compound structure, if the substituent is not explicitly excluded, such as 0% deuterium, 100% hydrogen, and all substituents are hydrogen, hydrogen and deuterium may be used intermixed in a compound. The deuterium is one of the isotopes of hydrogen and an element with a deuteron consisting of one proton and one neutron as its nucleus. It can be represented as hydrogen-2, whose element symbol can also be written as D or 2H. The isotopes are atoms with the same atomic number (Z) but different mass numbers (A), and can also be interpreted as elements with the same number of protons but different numbers of neutrons.

In the present disclosure, “a combination thereof” refers to a combination of one or more elements from the corresponding list to form a known or chemically stable arrangement that can be envisioned by one skilled in the art from the corresponding list. For example, alkyl and deuterium can be combined to form a partially or fully deuterated alkyl group; halogen and alkyl can be combined to form a halogenated alkyl substituent; halogen, alkyl, and aryl can be combined to form a halogenated arylalkyl. For example, a preferred combination of substituents includes up to 50 atoms excluding hydrogen or deuterium, up to 40 atoms excluding hydrogen or deuterium, up to 30 atoms excluding hydrogen or deuterium, or in many cases, a preferred combination of substituents may comprise up to 20 atoms excluding hydrogen or deuterium.

In the formula of the present disclosure, when there are multiple substituents represented by the same symbol, each substituent represented by the same symbol may be the same as or different from each other.

In the formula of the present disclosure, when forming a ring by linked to adjacent substituents, the ring may be linked to an adjacent two or more substituent(s) to form a substituted or unsubstituted, mono- or polycyclic, (3- to 30-membered) alicyclic or aromatic ring, or a combination thereof. In addition, the formed ring may contain at least one heteroatom selected from B, N, O, S, Si, and P, preferably at least one heteroatom selected from N, O, and S. According to one embodiment of the present disclosure, the number of ring backbone atoms is (5- to 20-membered), and according to another embodiment of the present disclosure, the number of ring backbone atoms is (5- to 15-membered).

Hereinafter, the compound according to one embodiment will be described in more detail.

A compound according to one embodiment of the present disclosure is represented by the following Formula 1.

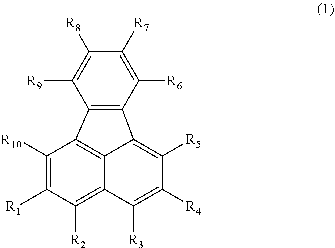

In Formula 1,

R₁ and R₂ are linked to each other to form a substituted or unsubstituted fused ring(s).

R₃ to R₁₀ each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1—C30)alkyldi(C6-C30)arylsilyl, or a substituted or unsubstituted tri(C6-C30)arylsilyl. At least one of the substituents of the above fused ring or R₃ to R₁₀ is a substituted or unsubstituted (3- to 30-membered) heteroaryl comprising nitrogen. According to one embodiment of the present disclosure, R₃ to R₁₀ each independently may represent hydrogen, deuterium, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, or a substituted or unsubstituted (C1-C30)alkoxy. According to another embodiment of the present disclosure, R₃ to R₁₀ each independently may represent hydrogen, a substituted or unsubstituted (C6-C30)aryl, a substituted or unsubstituted (3- to 30-membered)heteroaryl, a substituted or unsubstituted (C3-C30)cycloalkyl, or a substituted or unsubstituted (C1-C30)alkoxy. For example, R₃ to R₁₀ each independently, may be hydrogen, a triazinyl substituted with a diphenyl(s), a triazinyl substituted with a phenyl and a biphenyl, a triazinyl substituted with a phenyl and a naphthyl, a triazinyl substituted with a dinaphthyl(s), a triazinyl substituted with a phenyl and a dibenzofuranyl, a triazinyl substituted with a dibenzothiophenyl and a phenyl, a triazinyl substituted with a phenyl and a carbazoyl substituted with a phenyl(s), a triazinyl substituted with a diphenyl(s) substituted with deuterium, a phenyl substituted with a triazinyl(s) substituted with a diphenyl(s), a naphthyl substituted with a triazinyl(s) substituted with a diphenyl(s), a pyrimidinyl substituted with a diphenyl(s), a quinazolinyl substituted with a phenyl(s), a quinoxalinyl substituted with a phenyl(s), a benzotriazolyl substituted with a phenyl(s), a phenyl substituted with a benzotriazolyl(s), a triazinyl substituted with a phenyl and a naphthyl substituted with a phenyl(s), a triazinyl substituted with a phenyl and a phenyl substituted with a naphthyl(s), a triazinyl substituted with a naphthyl and a phenanthrenyl, a triazinyl unsubstituted or substituted with a phenyl and a dibenzoselenophenyl, a triazinyl unsubstituted or substituted with a phenanthrenyl and a dibenzofuranyl, a triazinyl unsubstituted or substituted with an isochrycenyl and a dibenzofuranyl, a triazinyl substituted with a dimethylfluorenyl and a dibenzofuranyl, a phenyl substituted with a naphthotriazolyl(s), a naphthotriazolyl substituted with a phenyl(s), a triazinyl substituted with a dibenzofuranyl and a carbazolyl substituted with a phenyl(s), a triazinyl substituted with a phenyl and a dibenzofuranyl substituted with a phenyl(s), a triazinyl substituted with a phenyl and a dibenzofuranyl substituted with a phenyl(s), a triazinyl substituted with a phenyl and a benzonaphthofuranyl, a triazinyl substituted with a phenyl and a terphenyl, a triazinyl substituted with a phenyl and dimethylbenzofluorenyl, or a triazinyl substituted with a phenyl and a benzonaphthofuranyl.

According to one embodiment of the present disclosure, Formula 1 may be represented by any one of the following Formulas 1-1 to 1-4.

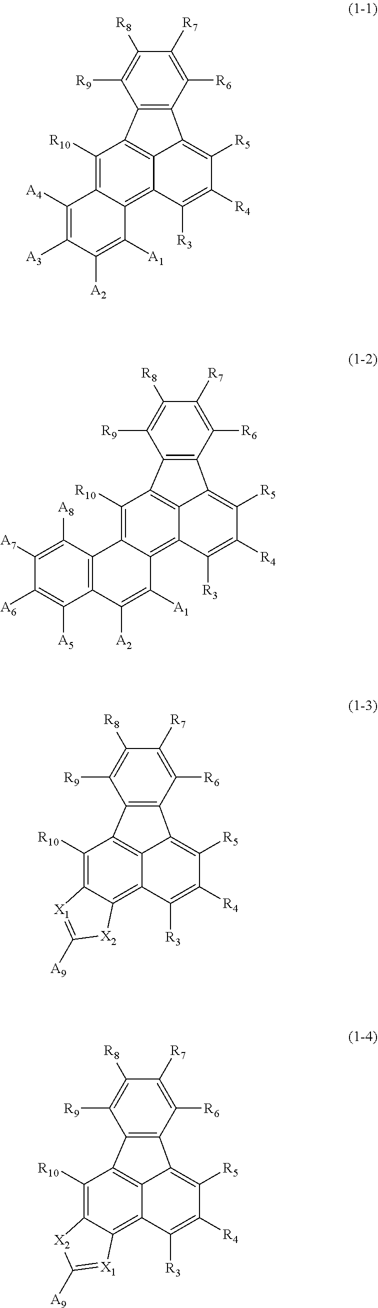

In Formulas 1-1 to 1-4,

R₃ to R₁₀ are as defined in Formula 1.

A₁ to A₉ each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, or a substituted or unsubstituted tri(C6-C30)arylsilyl. According to one embodiment of the present disclosure, A₁ to A₉ each independently represent hydrogen, a substituted or unsubstituted (C6-C30)aryl, a substituted or unsubstituted (3- to 30-membered)heteroaryl, a substituted or unsubstituted (C3-C30)cycloalkyl, or a substituted or unsubstituted (C1-C30)alkoxy. According to another embodiment of the present disclosure, A₁ to A₉ each independently represent hydrogen, a substituted or unsubstituted (C6-C25)aryl, or a substituted or unsubstituted (3- to 25-membered)heteroaryl. For example, A₁ to A₉ each independently, represent hydrogen, a triazinyl substituted with a diphenyl(s), a triazinyl substituted with a phenyl and a biphenyl, a triazinyl substituted with a phenyl and a naphthyl, a triazinyl substituted with a dinaphthyl(s), a triazinyl substituted with a phenyl and a dibenzofuranyl, a triazinyl substituted with a dibenzothiophenyl and a phenyl, a triazinyl substituted with a phenyl and a carbazolyl substituted with a phenyl(s), a triazinyl substituted with a diphenyl(s) substituted with deuterium, a phenyl substituted with a triazinyl(s) substituted with a diphenyl(s), a naphthyl substituted with a triazinyl substituted with diphenyl(s), a pyrimidinyl substituted with a diphenyl(s), a quinazolinyl substituted with a phenyl(s), or a quinoxalinyl substituted with a phenyl(s).

X₁ represents —N═; and X₂ represents —NR₁₁, —O—, or —S—.

R₁₁ represents hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, or a substituted or unsubstituted tri(C6-C30)arylsilyl. According to one embodiment of the present disclosure, R₁ represents hydrogen, deuterium, a substituted or unsubstituted (C1-C30)alkyl, a substituted or unsubstituted (C6-C30)aryl, a substituted or unsubstituted (3- to 30-membered)heteroaryl, or a substituted or unsubstituted (C3-C30)cycloalkyl. According to another embodiment of the present disclosure, R₁₁ represents hydrogen, deuterium, a substituted or unsubstituted (C1-C30)alkyl, or a substituted or unsubstituted (C6-C30)aryl.

For example, R₁₁ represents hydrogen or phenyl.

At least one of R₃ to R₁₁ and A₁ to A₉ represents a substituted or unsubstituted (3- to 30-membered)heteroaryl comprising at least one N.

The compound represented by Formula 1 may be selected from the following compounds, but is not limited thereto.

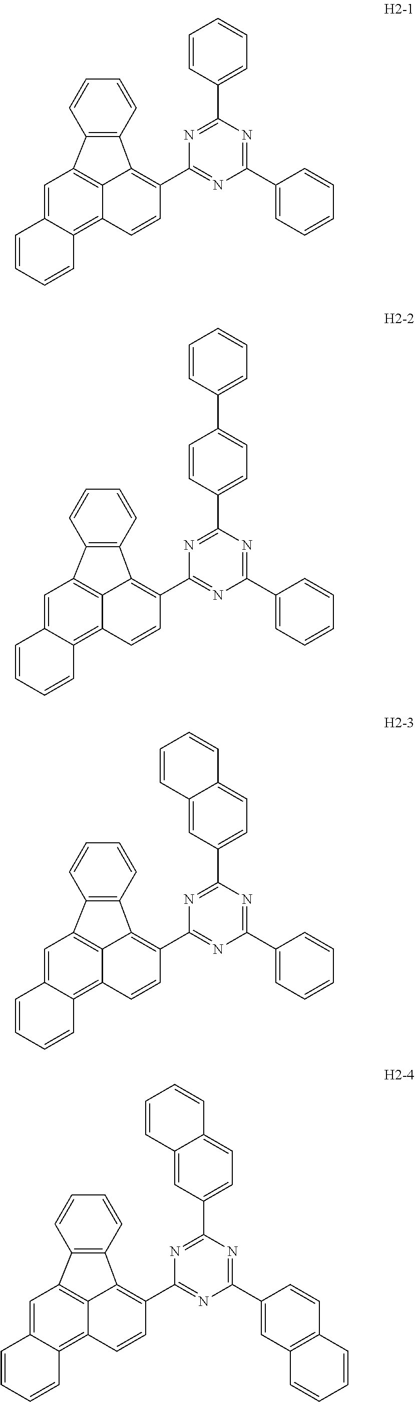 [SMILES: c1ccc(-c2nc(-c3ccccc3)nc(-c3ccc4c5c(cc6ccccc64)-c4ccccc4-c35)n2)cc1 ; c1ccc(-c2ccc(-c3nc(-c4ccccc4)nc(-c4ccc5c6c(cc7ccccc75)-c5ccccc5-c46)n3)cc2)cc1 ; c1ccc(-c2nc(-c3ccc4ccccc4c3)nc(-c3ccc4c5c(cc6ccccc64)-c4ccccc4-c35)n2)cc1 ; c1ccc2c(c1)-c1cc3ccccc3c3ccc(-c4nc(-c5ccc6ccccc6c5)nc(-c5ccc6ccccc6c5)n4)c-2c13]

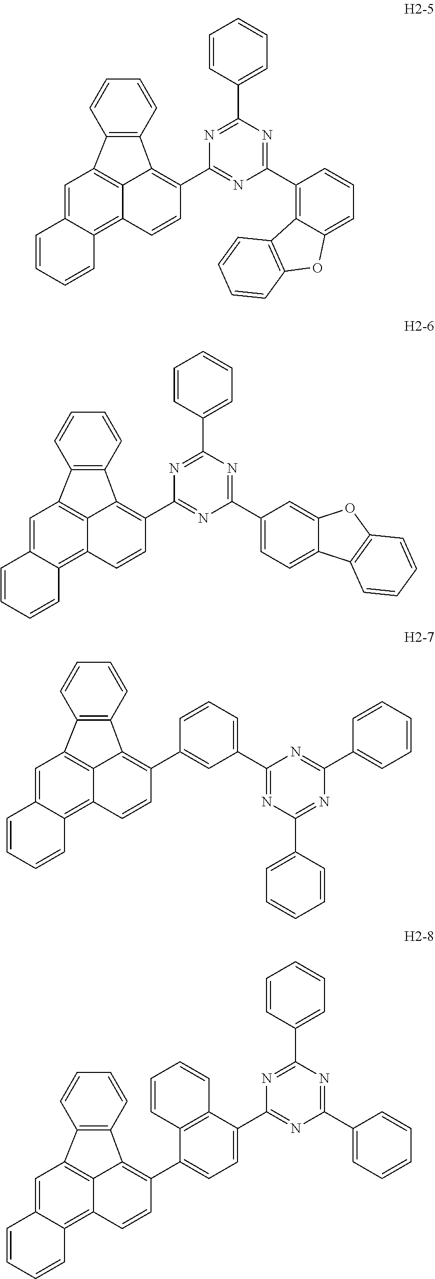

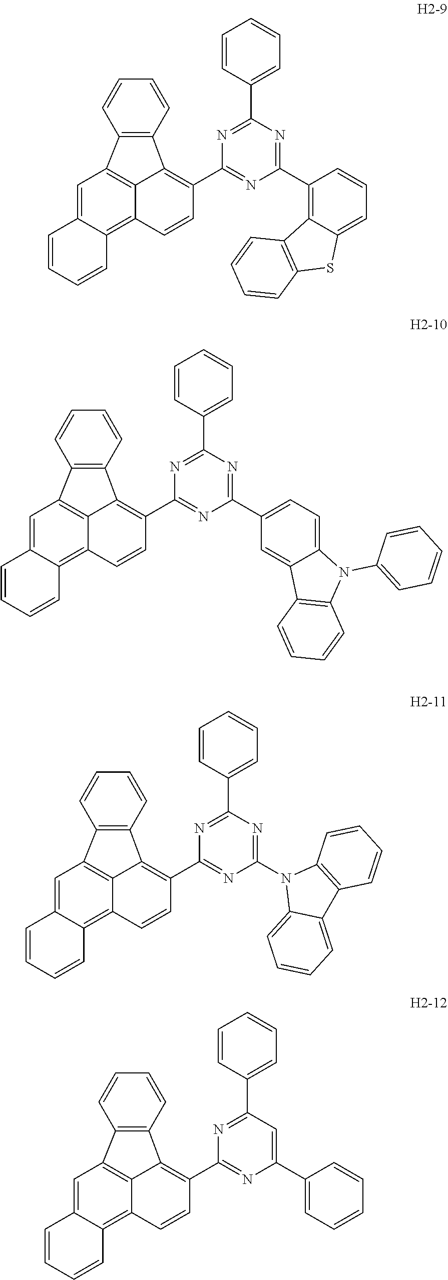 [SMILES: c1ccc(-c2nc(-c3ccc4c5c(cc6ccccc64)-c4ccccc4-c35)nc(-c3cccc4sc5ccccc5c34)n2)cc1 ; c1ccc(-c2nc(-c3ccc4c(c3)c3ccccc3n4-c3ccccc3)nc(-c3ccc4c5c(cc6ccccc64)-c4ccccc4-c35)n2)cc1 ; c1ccc(-c2nc(-c3ccc4c5c(cc6ccccc64)-c4ccccc4-c35)nc(-n3c4ccccc4c4ccccc43)n2)cc1 ; c1ccc(-c2cc(-c3ccccc3)nc(-c3ccc4c5c(cc6ccccc64)-c4ccccc4-c35)n2)cc1]

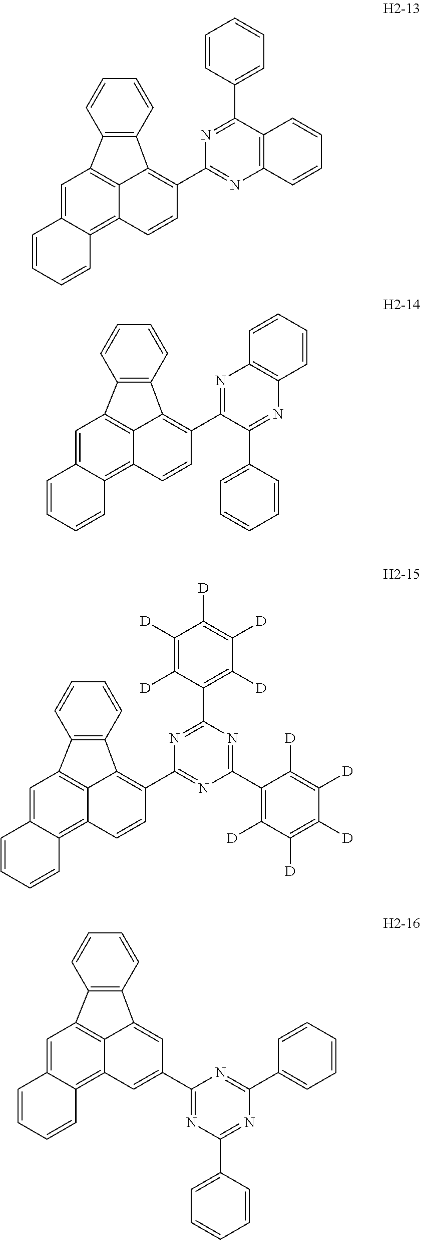 [SMILES: c1ccc(-c2nc(-c3ccc4c5c(cc6ccccc64)-c4ccccc4-c35)nc3ccccc23)cc1 ; c1ccc(-c2nc3ccccc3nc2-c2ccc3c4c(cc5ccccc53)-c3ccccc3-c24)cc1 ; [2H]c1c([2H])c([2H])c(-c2nc(-c3ccc4c5c(cc6ccccc64)-c4ccccc4-c35)nc(-c3c([2H])c([2H])c([2H])c([2H])c3[2H])n2)c([2H])c1[2H] ; c1ccc(-c2nc(-c3ccccc3)nc(-c3cc4c5c(cc6ccccc6c5c3)-c3ccccc3-4)n2)cc1]

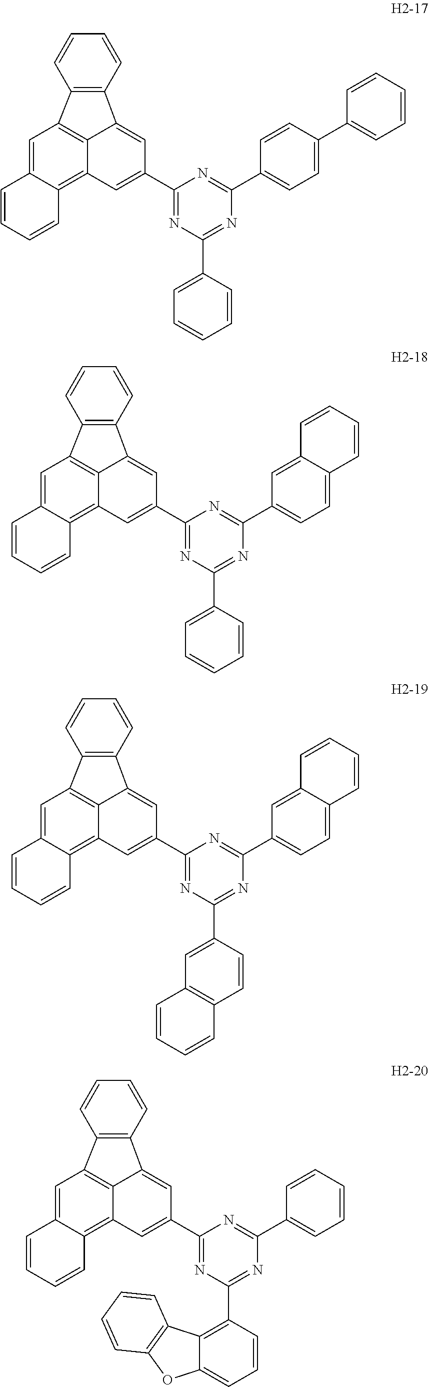 [SMILES: c1ccc(-c2ccc(-c3nc(-c4ccccc4)nc(-c4cc5c6c(cc7ccccc7c6c4)-c4ccccc4-5)n3)cc2)cc1 ; c1ccc(-c2nc(-c3ccc4ccccc4c3)nc(-c3cc4c5c(cc6ccccc6c5c3)-c3ccccc3-4)n2)cc1 ; c1ccc2c(c1)-c1cc(-c3nc(-c4ccc5ccccc5c4)nc(-c4ccc5ccccc5c4)n3)cc3c1c-2cc1ccccc13 ; c1ccc(-c2nc(-c3cc4c5c(cc6ccccc6c5c3)-c3ccccc3-4)nc(-c3cccc4oc5ccccc5c34)n2)cc1]

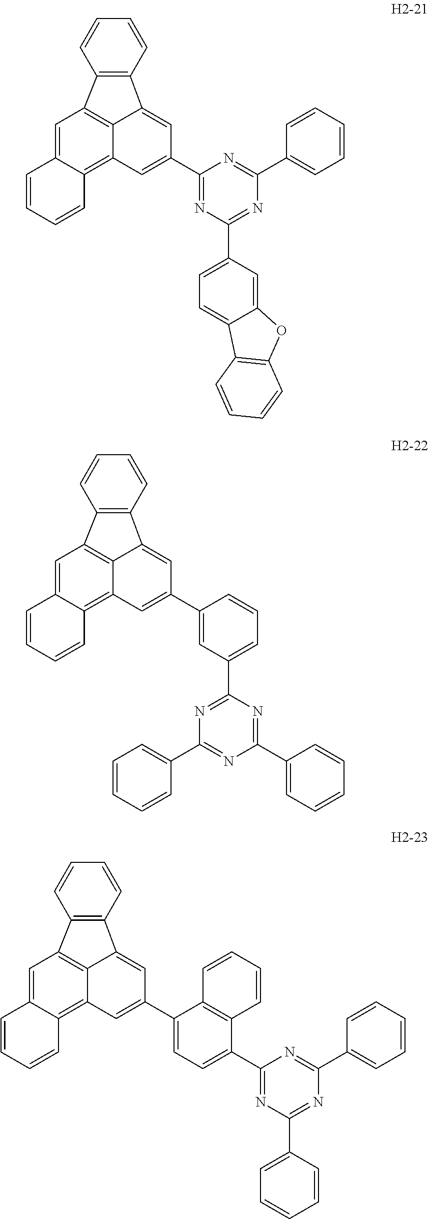 [SMILES: c1ccc(-c2nc(-c3ccc4c(c3)oc3ccccc34)nc(-c3cc4c5c(cc6ccccc6c5c3)-c3ccccc3-4)n2)cc1 ; c1ccc(-c2nc(-c3ccccc3)nc(-c3cccc(-c4cc5c6c(cc7ccccc7c6c4)-c4ccccc4-5)c3)n2)cc1 ; c1ccc(-c2nc(-c3ccccc3)nc(-c3ccc(-c4cc5c6c(cc7ccccc7c6c4)-c4ccccc4-5)c4ccccc34)n2)cc1]

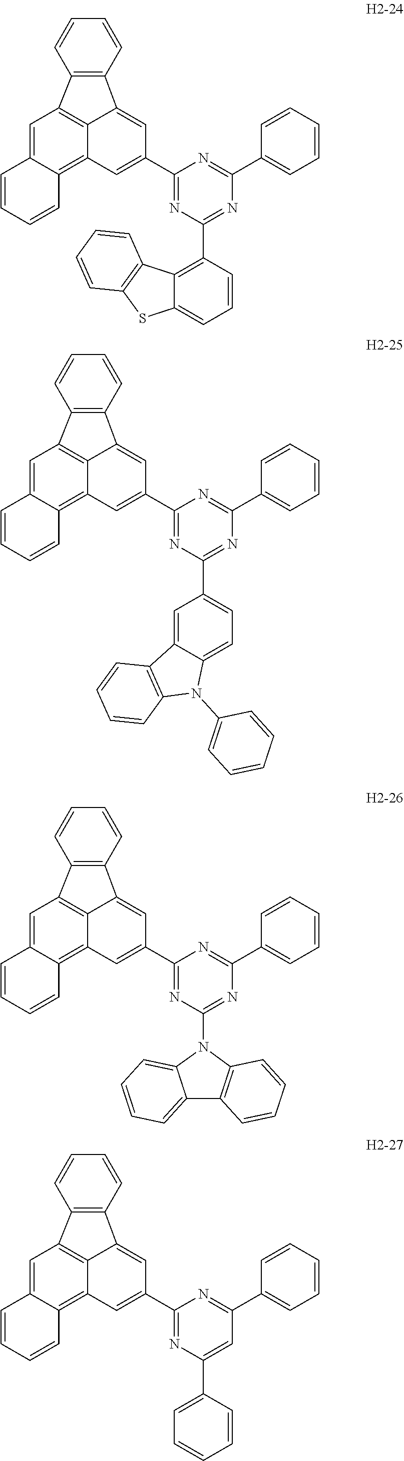

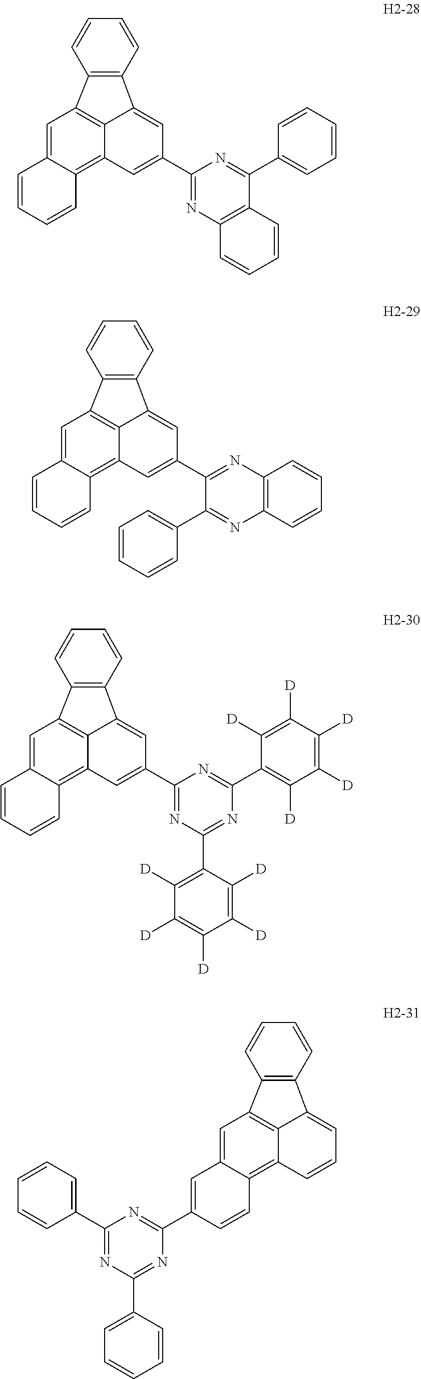 [SMILES: c1ccc(-c2nc(-c3cc4c5c(cc6ccccc6c5c3)-c3ccccc3-4)nc3ccccc23)cc1 ; c1ccc(-c2nc3ccccc3nc2-c2cc3c4c(cc5ccccc5c4c2)-c2ccccc2-3)cc1 ; [2H]c1c([2H])c([2H])c(-c2nc(-c3cc4c5c(cc6ccccc6c5c3)-c3ccccc3-4)nc(-c3c([2H])c([2H])c([2H])c([2H])c3[2H])n2)c([2H])c1[2H] ; c1ccc(-c2nc(-c3ccccc3)nc(-c3ccc4c(c3)cc3c5c(cccc54)-c4ccccc4-3)n2)cc1]

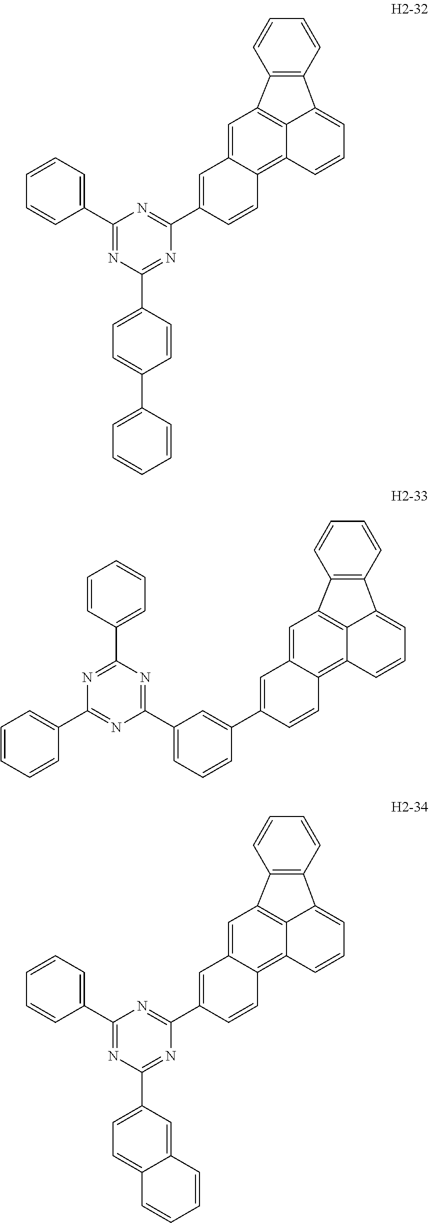 [SMILES: c1ccc(-c2ccc(-c3nc(-c4ccccc4)nc(-c4ccc5c(c4)cc4c6c(cccc65)-c5ccccc5-4)n3)cc2)cc1 ; c1ccc(-c2nc(-c3ccccc3)nc(-c3cccc(-c4ccc5c(c4)cc4c6c(cccc65)-c5ccccc5-4)c3)n2)cc1 ; c1ccc(-c2nc(-c3ccc4ccccc4c3)nc(-c3ccc4c(c3)cc3c5c(cccc54)-c4ccccc4-3)n2)cc1]

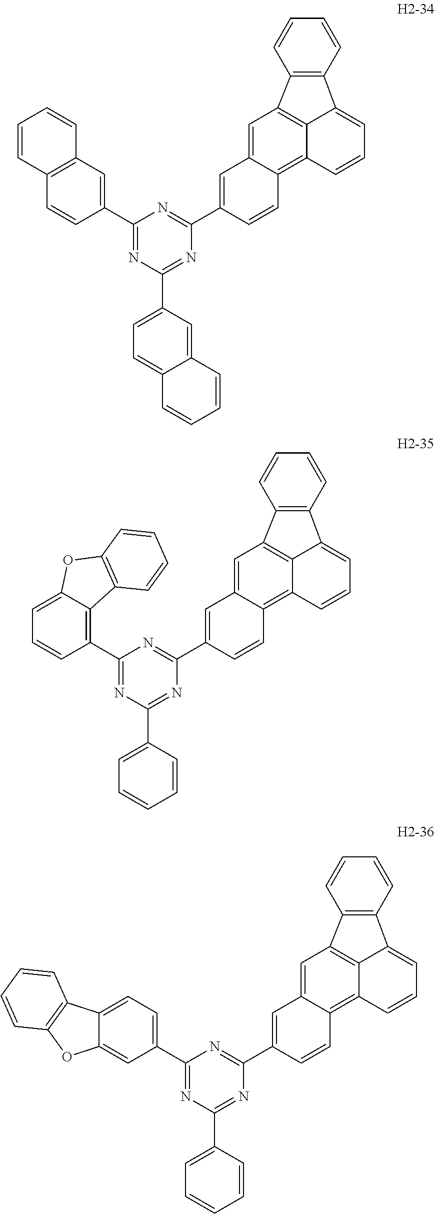 [SMILES: c1ccc2c(c1)-c1cccc3c1c-2cc1cc(-c2nc(-c4ccc5ccccc5c4)nc(-c4ccc5ccccc5c4)n2)ccc13 ; c1ccc(-c2nc(-c3ccc4c(c3)cc3c5c(cccc54)-c4ccccc4-3)nc(-c3cccc4oc5ccccc5c34)n2)cc1 ; c1ccc(-c2nc(-c3ccc4c(c3)cc3c5c(cccc54)-c4ccccc4-3)nc(-c3ccc4c(c3)oc3ccccc34)n2)cc1]

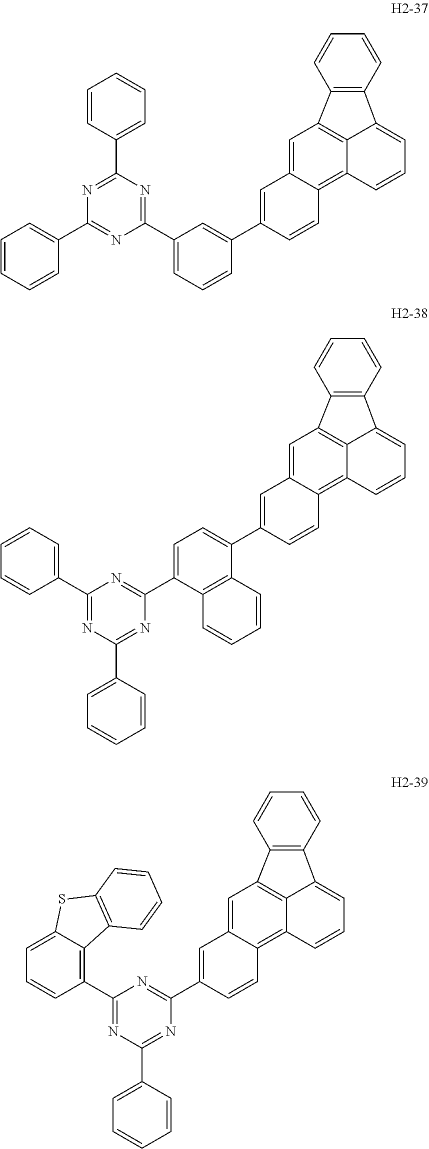 [SMILES: c1ccc(-c2nc(-c3ccccc3)nc(-c3cccc(-c4ccc5c(c4)cc4c6c(cccc65)-c5ccccc5-4)c3)n2)cc1 ; c1ccc(-c2nc(-c3ccccc3)nc(-c3ccc(-c4ccc5c(c4)cc4c6c(cccc65)-c5ccccc5-4)c4ccccc34)n2)cc1 ; c1ccc(-c2nc(-c3ccc4c(c3)cc3c5c(cccc54)-c4ccccc4-3)nc(-c3cccc4sc5ccccc5c34)n2)cc1]

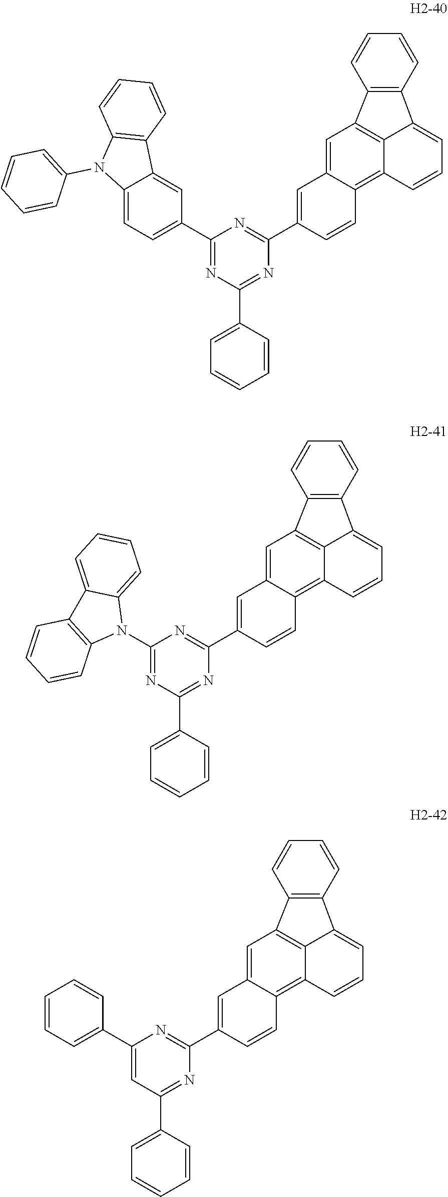 [SMILES: c1ccc(-c2nc(-c3ccc4c(c3)cc3c5c(cccc54)-c4ccccc4-3)nc(-c3ccc4c(c3)c3ccccc3n4-c3ccccc3)n2)cc1 ; c1ccc(-c2nc(-c3ccc4c(c3)cc3c5c(cccc54)-c4ccccc4-3)nc(-n3c4ccccc4c4ccccc43)n2)cc1 ; c1ccc(-c2cc(-c3ccccc3)nc(-c3ccc4c(c3)cc3c5c(cccc54)-c4ccccc4-3)n2)cc1]

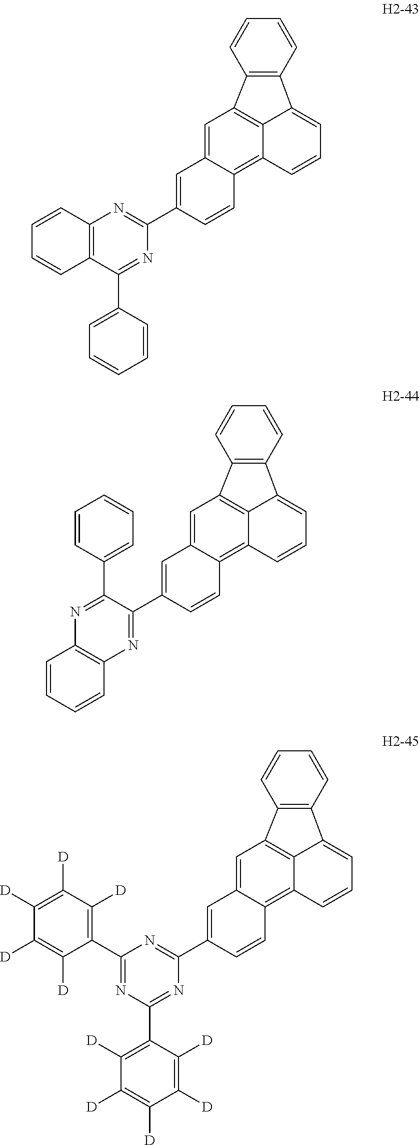 [SMILES: c1ccc(-c2nc(-c3ccc4c(c3)cc3c5c(cccc54)-c4ccccc4-3)nc3ccccc23)cc1 ; c1ccc(-c2nc3ccccc3nc2-c2ccc3c(c2)cc2c4c(cccc43)-c3ccccc3-2)cc1 ; [2H]c1c([2H])c([2H])c(-c2nc(-c3ccc4c(c3)cc3c5c(cccc54)-c4ccccc4-3)nc(-c3c([2H])c([2H])c([2H])c([2H])c3[2H])n2)c([2H])c1[2H]]

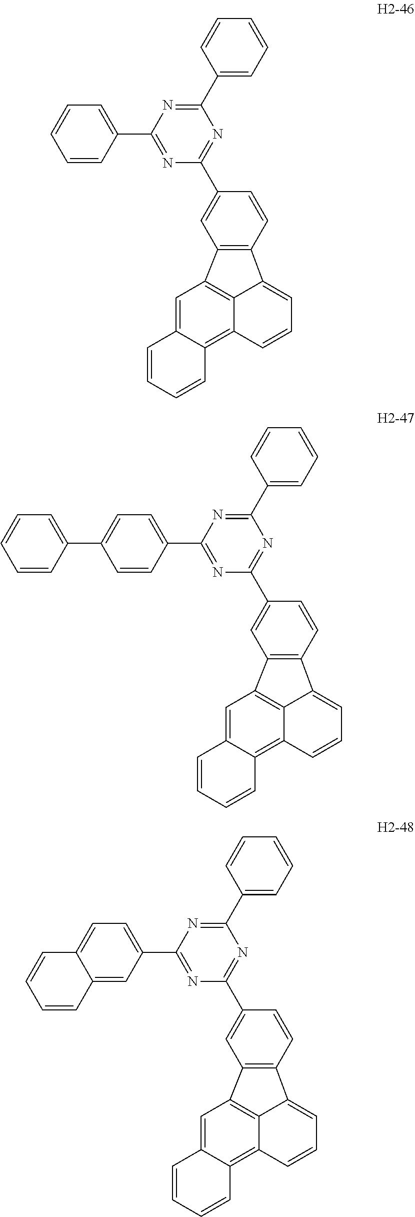

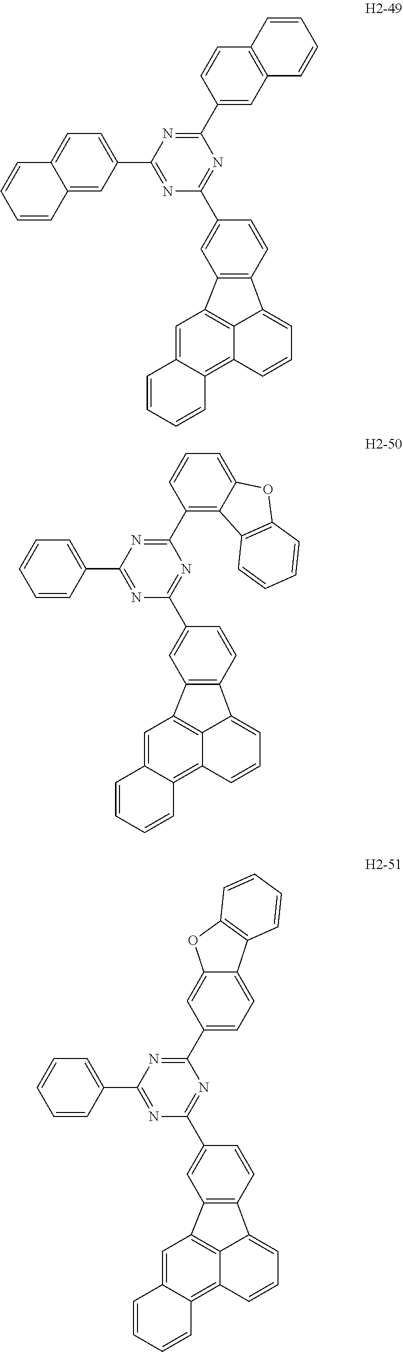

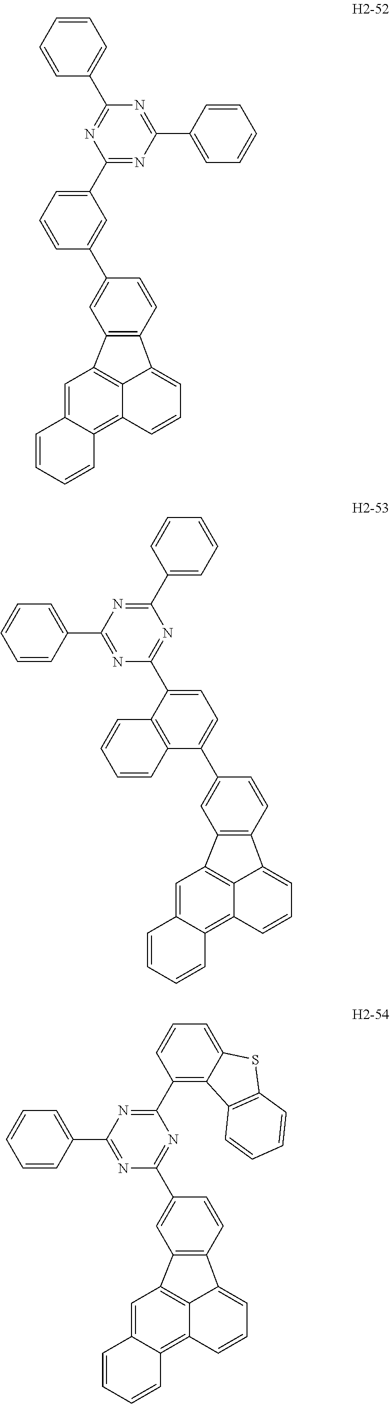

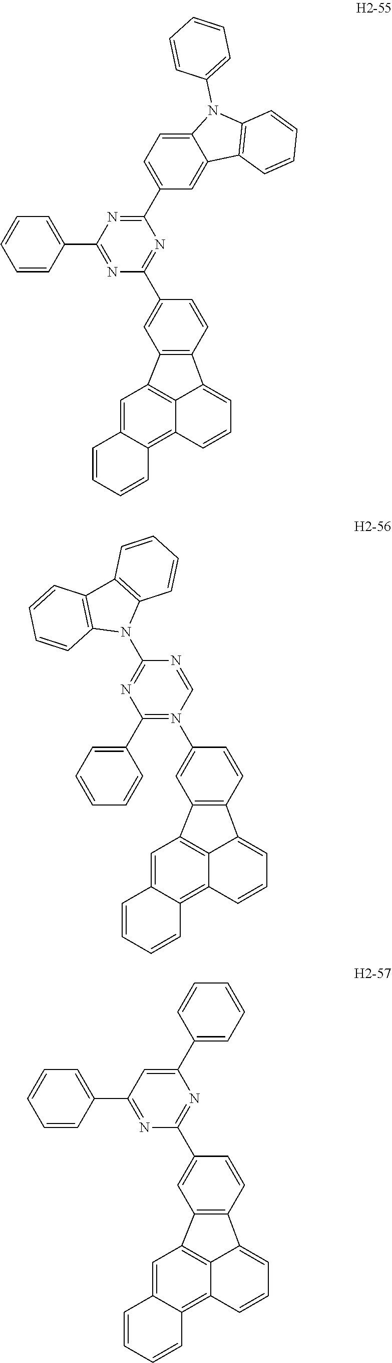

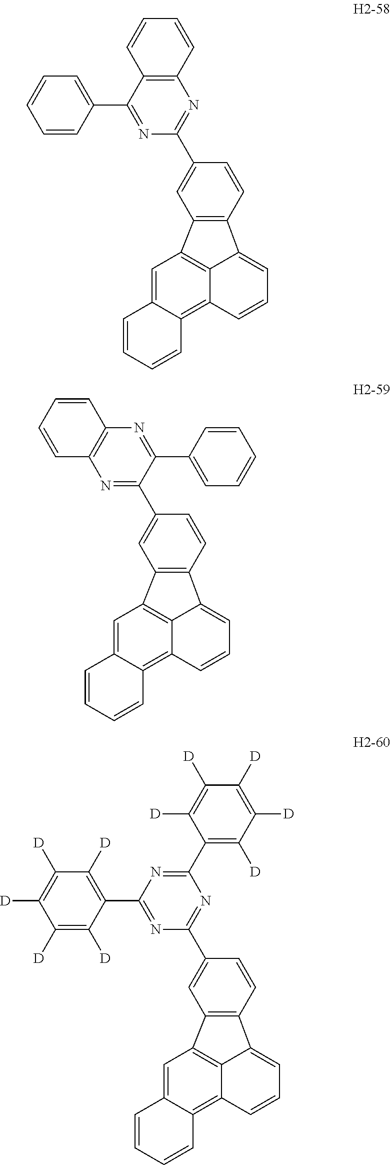 [SMILES: c1ccc(-c2nc(-c3ccc4c(c3)-c3cc5ccccc5c5cccc-4c35)nc3ccccc23)cc1 ; c1ccc(-c2nc3ccccc3nc2-c2ccc3c(c2)-c2cc4ccccc4c4cccc-3c24)cc1 ; [2H]c1c([2H])c([2H])c(-c2nc(-c3ccc4c(c3)-c3cc5ccccc5c5cccc-4c35)nc(-c3c([2H])c([2H])c([2H])c([2H])c3[2H])n2)c([2H])c1[2H]]

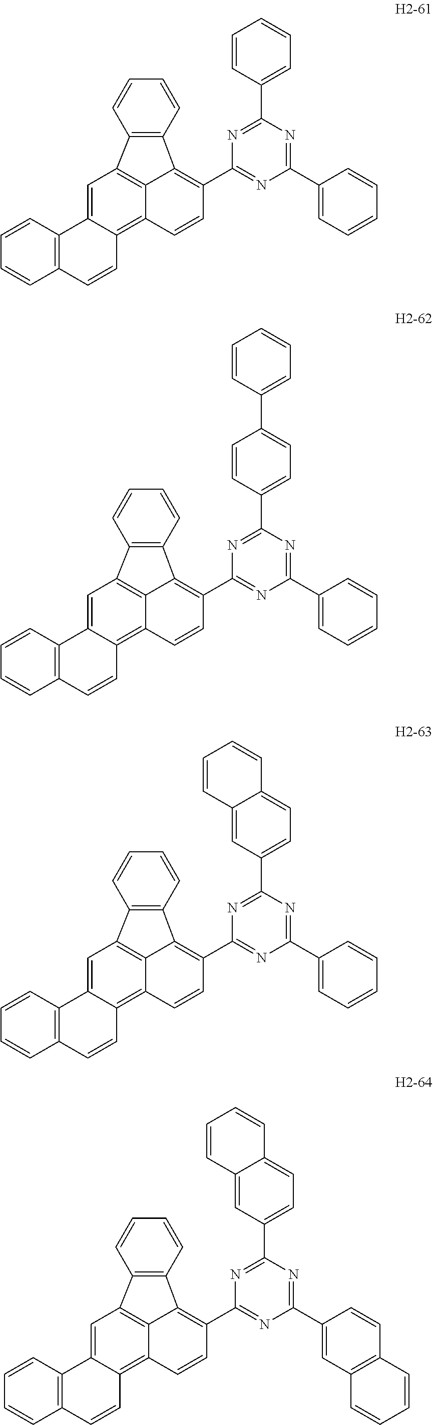 [SMILES: c1ccc(-c2nc(-c3ccccc3)nc(-c3ccc4c5c(cc6c7ccccc7ccc46)-c4ccccc4-c35)n2)cc1 ; c1ccc(-c2ccc(-c3nc(-c4ccccc4)nc(-c4ccc5c6c(cc7c8ccccc8ccc57)-c5ccccc5-c46)n3)cc2)cc1 ; c1ccc(-c2nc(-c3ccc4ccccc4c3)nc(-c3ccc4c5c(cc6c7ccccc7ccc46)-c4ccccc4-c35)n2)cc1 ; c1ccc2c(c1)-c1cc3c4ccccc4ccc3c3ccc(-c4nc(-c5ccc6ccccc6c5)nc(-c5ccc6ccccc6c5)n4)c-2c13]

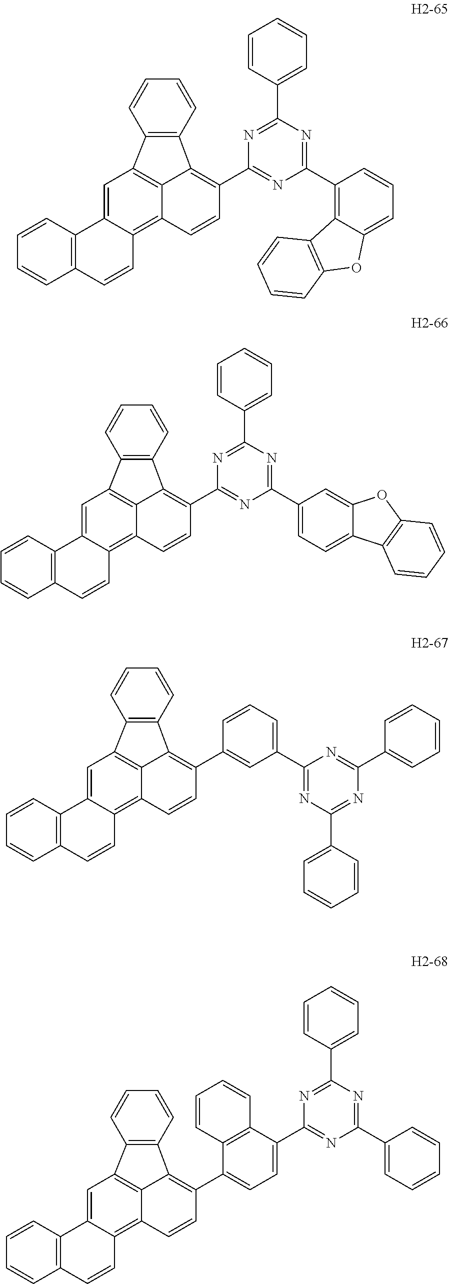 [SMILES: c1ccc(-c2nc(-c3ccc4c5c(cc6c7ccccc7ccc46)-c4ccccc4-c35)nc(-c3cccc4oc5ccccc5c34)n2)cc1 ; c1ccc(-c2nc(-c3ccc4c(c3)oc3ccccc34)nc(-c3ccc4c5c(cc6c7ccccc7ccc46)-c4ccccc4-c35)n2)cc1 ; c1ccc(-c2nc(-c3ccccc3)nc(-c3cccc(-c4ccc5c6c(cc7c8ccccc8ccc57)-c5ccccc5-c46)c3)n2)cc1 ; c1ccc(-c2nc(-c3ccccc3)nc(-c3ccc(-c4ccc5c6c(cc7c8ccccc8ccc57)-c5ccccc5-c46)c4ccccc34)n2)cc1]

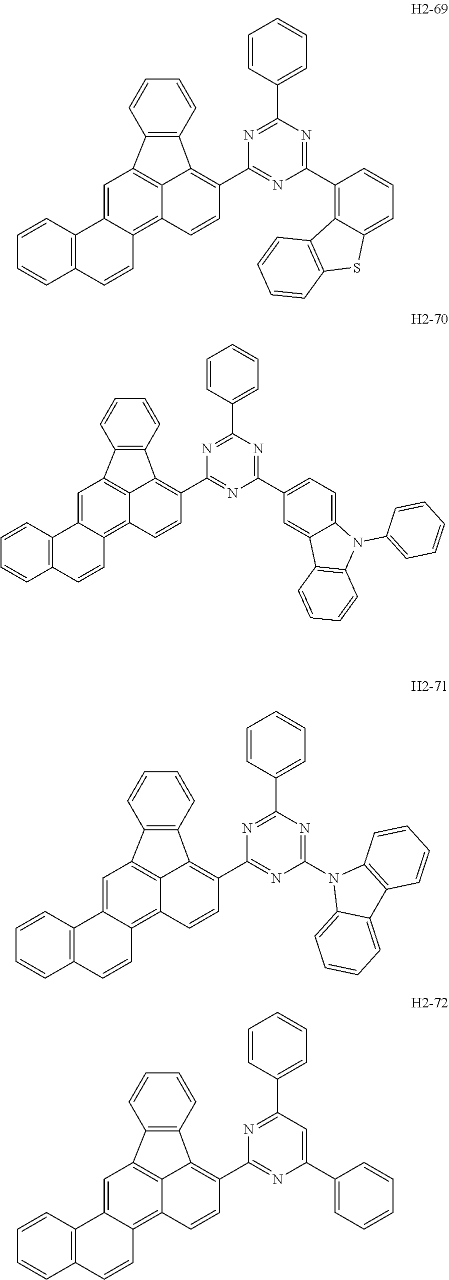 [SMILES: c1ccc(-c2nc(-c3ccc4c5c(cc6c7ccccc7ccc46)-c4ccccc4-c35)nc(-c3cccc4sc5ccccc5c34)n2)cc1 ; c1ccc(-c2nc(-c3ccc4c(c3)c3ccccc3n4-c3ccccc3)nc(-c3ccc4c5c(cc6c7ccccc7ccc46)-c4ccccc4-c35)n2)cc1 ; c1ccc(-c2nc(-c3ccc4c5c(cc6c7ccccc7ccc46)-c4ccccc4-c35)nc(-n3c4ccccc4c4ccccc43)n2)cc1 ; c1ccc(-c2cc(-c3ccccc3)nc(-c3ccc4c5c(cc6c7ccccc7ccc46)-c4ccccc4-c35)n2)cc1]

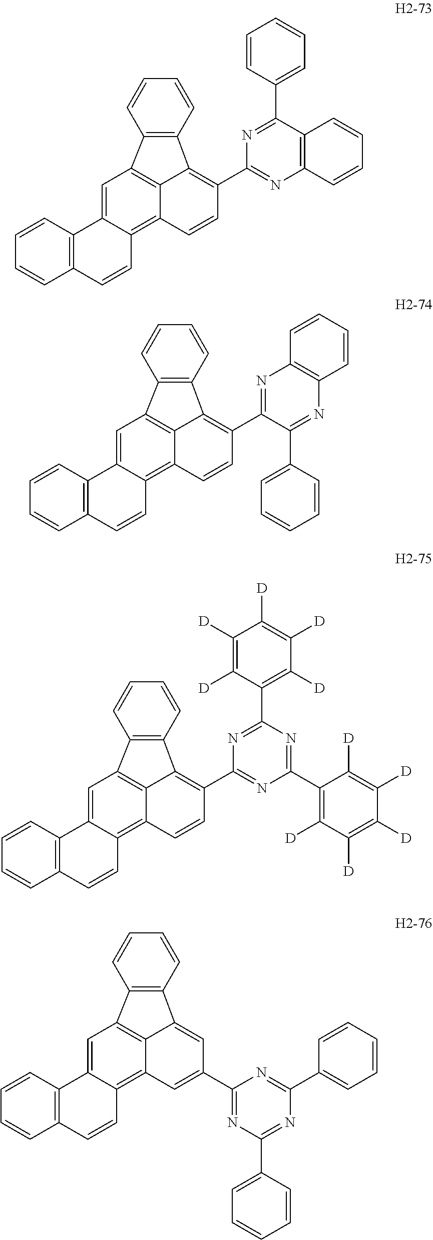 [SMILES: c1ccc(-c2nc(-c3ccc4c5c(cc6c7ccccc7ccc46)-c4ccccc4-c35)nc3ccccc23)cc1 ; c1ccc(-c2nc3ccccc3nc2-c2ccc3c4c(cc5c6ccccc6ccc35)-c3ccccc3-c24)cc1 ; [2H]c1c([2H])c([2H])c(-c2nc(-c3ccc4c5c(cc6c7ccccc7ccc46)-c4ccccc4-c35)nc(-c3c([2H])c([2H])c([2H])c([2H])c3[2H])n2)c([2H])c1[2H] ; c1ccc(-c2nc(-c3ccccc3)nc(-c3cc4c5c(cc6c7ccccc7ccc6c5c3)-c3ccccc3-4)n2)cc1]

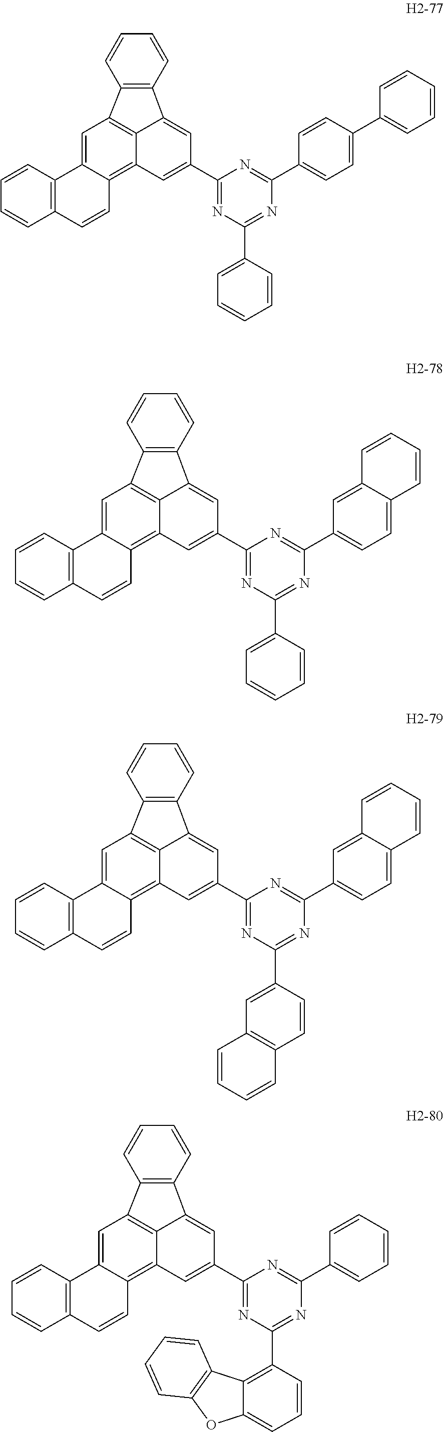 [SMILES: c1ccc(-c2ccc(-c3nc(-c4ccccc4)nc(-c4cc5c6c(cc7c8ccccc8ccc7c6c4)-c4ccccc4-5)n3)cc2)cc1 ; c1ccc(-c2nc(-c3ccc4ccccc4c3)nc(-c3cc4c5c(cc6c7ccccc7ccc6c5c3)-c3ccccc3-4)n2)cc1 ; c1ccc2c(c1)-c1cc(-c3nc(-c4ccc5ccccc5c4)nc(-c4ccc5ccccc5c4)n3)cc3c1c-2cc1c2ccccc2ccc31 ; c1ccc(-c2nc(-c3cc4c5c(cc6c7ccccc7ccc6c5c3)-c3ccccc3-4)nc(-c3cccc4oc5ccccc5c34)n2)cc1]

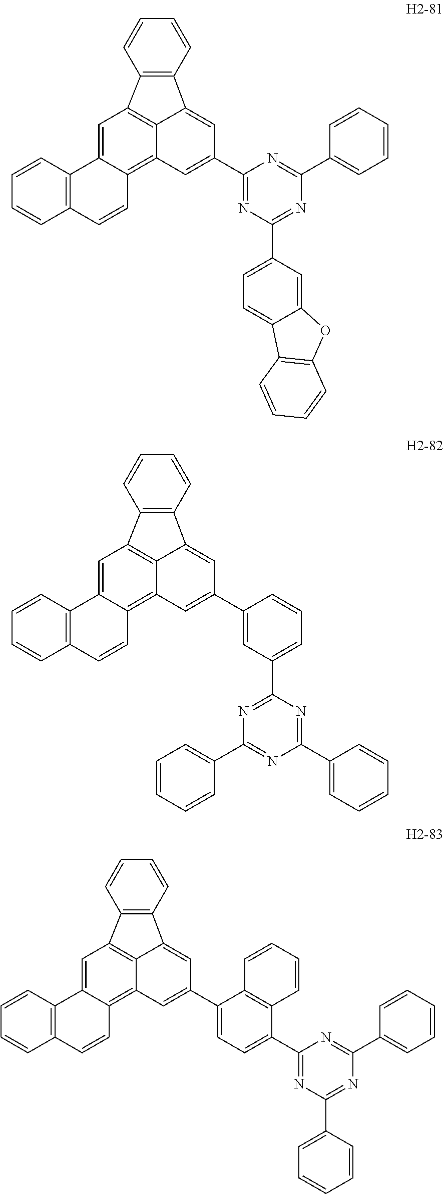 [SMILES: c1ccc(-c2nc(-c3ccc4c(c3)oc3ccccc34)nc(-c3cc4c5c(cc6c7ccccc7ccc6c5c3)-c3ccccc3-4)n2)cc1 ; c1ccc(-c2nc(-c3ccccc3)nc(-c3cccc(-c4cc5c6c(cc7c8ccccc8ccc7c6c4)-c4ccccc4-5)c3)n2)cc1 ; c1ccc(-c2nc(-c3ccccc3)nc(-c3ccc(-c4cc5c6c(cc7c8ccccc8ccc7c6c4)-c4ccccc4-5)c4ccccc34)n2)cc1]

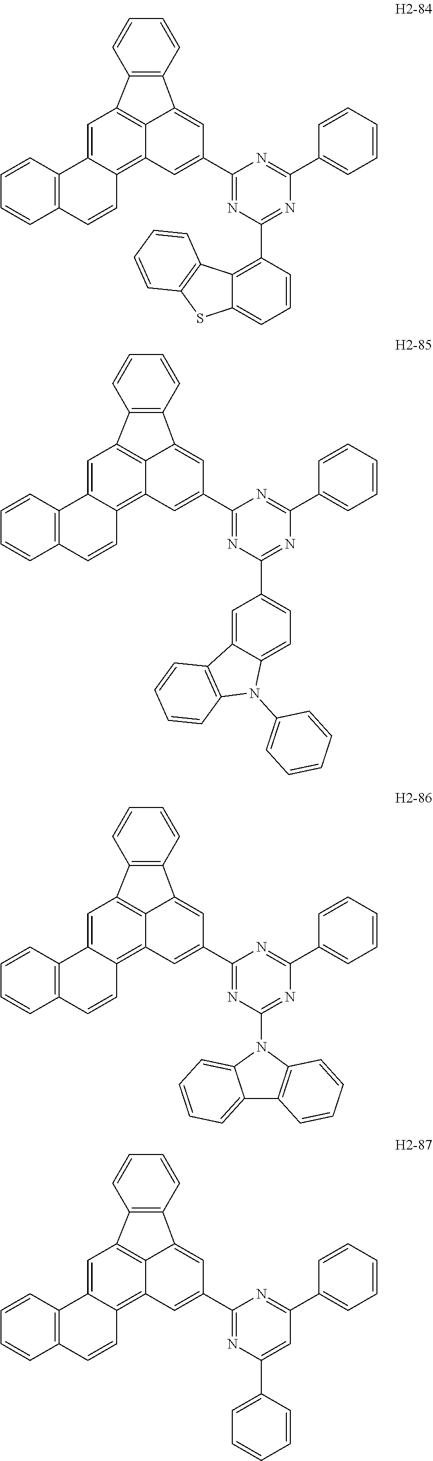

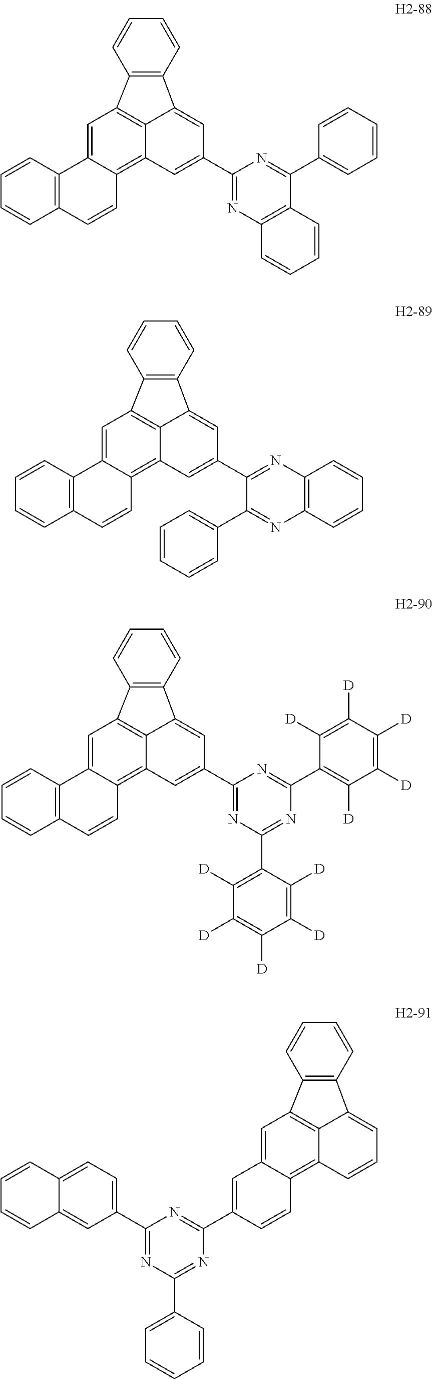 [SMILES: c1ccc(-c2nc(-c3cc4c5c(cc6c7ccccc7ccc6c5c3)-c3ccccc3-4)nc3ccccc23)cc1 ; c1ccc(-c2nc3ccccc3nc2-c2cc3c4c(cc5c6ccccc6ccc5c4c2)-c2ccccc2-3)cc1 ; [2H]c1c([2H])c([2H])c(-c2nc(-c3cc4c5c(cc6c7ccccc7ccc6c5c3)-c3ccccc3-4)nc(-c3c([2H])c([2H])c([2H])c([2H])c3[2H])n2)c([2H])c1[2H] ; c1ccc(-c2nc(-c3ccc4ccccc4c3)nc(-c3ccc4c(c3)cc3c5c(cccc54)-c4ccccc4-3)n2)cc1]

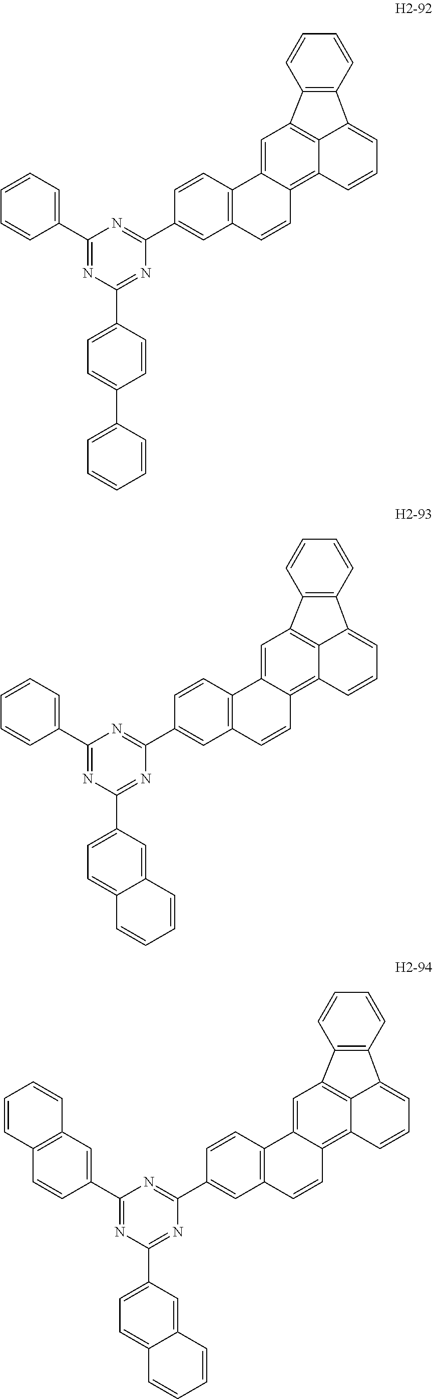 [SMILES: c1ccc(-c2ccc(-c3nc(-c4ccccc4)nc(-c4ccc5c(ccc6c7cccc8c7c(cc56)-c5ccccc5-8)c4)n3)cc2)cc1 ; c1ccc(-c2nc(-c3ccc4ccccc4c3)nc(-c3ccc4c(ccc5c6cccc7c6c(cc45)-c4ccccc4-7)c3)n2)cc1 ; c1ccc2c(c1)-c1cccc3c1c-2cc1c2ccc(-c4nc(-c5ccc6ccccc6c5)nc(-c5ccc6ccccc6c5)n4)cc2ccc31]

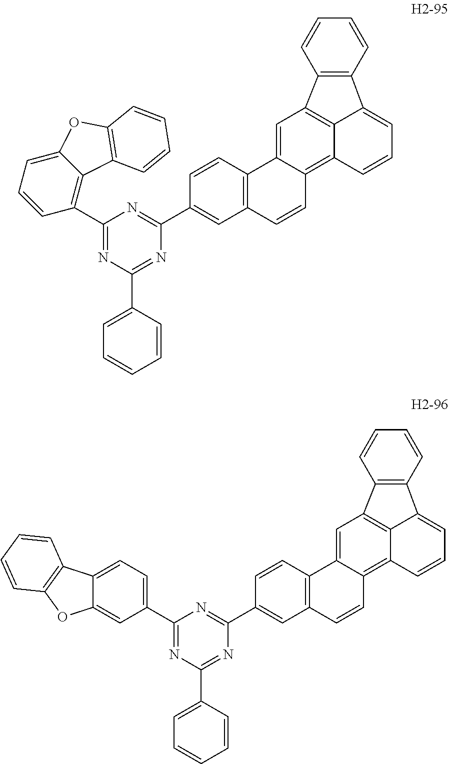 [SMILES: c1ccc(-c2nc(-c3ccc4c(ccc5c6cccc7c6c(cc45)-c4ccccc4-7)c3)nc(-c3cccc4oc5ccccc5c34)n2)cc1 ; c1ccc(-c2nc(-c3ccc4c(ccc5c6cccc7c6c(cc45)-c4ccccc4-7)c3)nc(-c3ccc4c(c3)oc3ccccc34)n2)cc1]

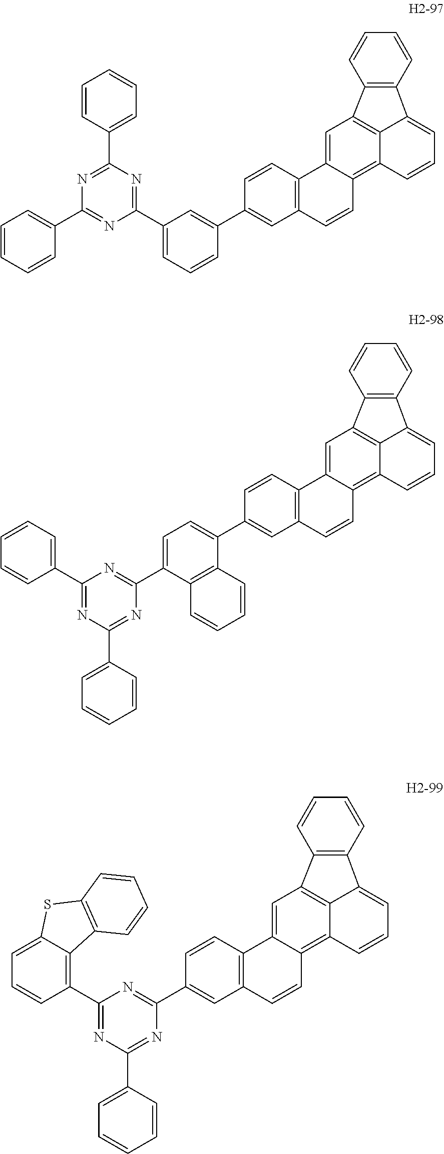 [SMILES: c1ccc(-c2nc(-c3ccccc3)nc(-c3cccc(-c4ccc5c(ccc6c7cccc8c7c(cc56)-c5ccccc5-8)c4)c3)n2)cc1 ; c1ccc(-c2nc(-c3ccccc3)nc(-c3ccc(-c4ccc5c(ccc6c7cccc8c7c(cc56)-c5ccccc5-8)c4)c4ccccc34)n2)cc1 ; c1ccc(-c2nc(-c3ccc4c(ccc5c6cccc7c6c(cc45)-c4ccccc4-7)c3)nc(-c3cccc4sc5ccccc5c34)n2)cc1]

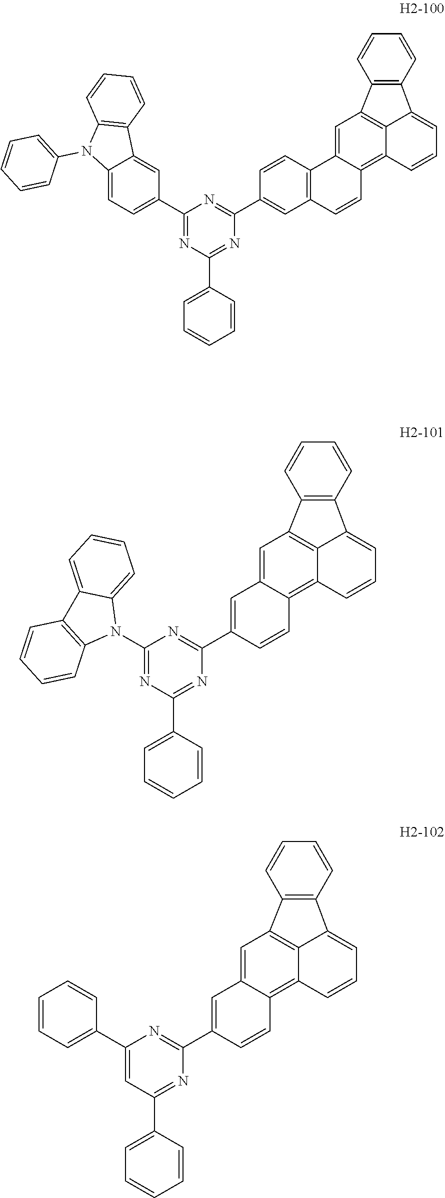 [SMILES: c1ccc(-c2nc(-c3ccc4c(ccc5c6cccc7c6c(cc45)-c4ccccc4-7)c3)nc(-c3ccc4c(c3)c3ccccc3n4-c3ccccc3)n2)cc1 ; c1ccc(-c2nc(-c3ccc4c(c3)cc3c5c(cccc54)-c4ccccc4-3)nc(-n3c4ccccc4c4ccccc43)n2)cc1 ; c1ccc(-c2cc(-c3ccccc3)nc(-c3ccc4c(c3)cc3c5c(cccc54)-c4ccccc4-3)n2)cc1]

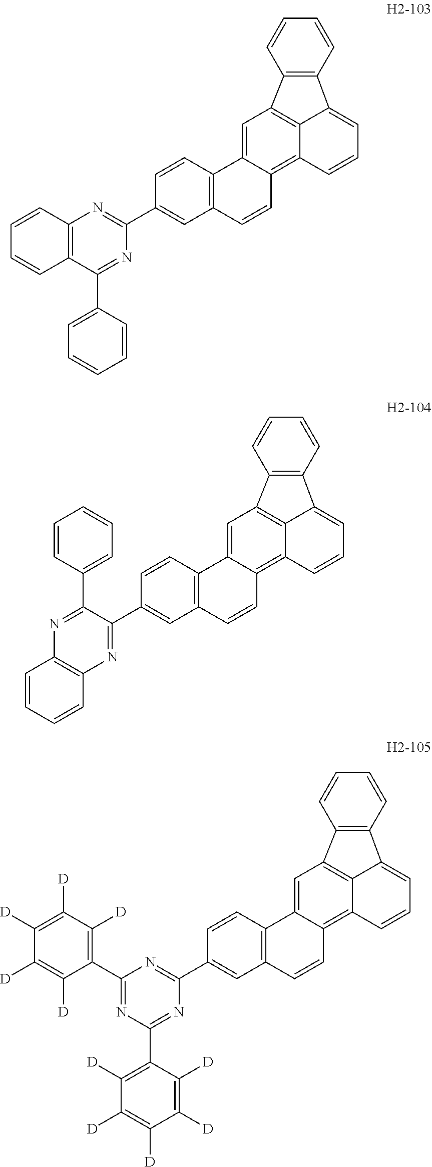 [SMILES: c1ccc(-c2nc(-c3ccc4c(ccc5c6cccc7c6c(cc45)-c4ccccc4-7)c3)nc3ccccc23)cc1 ; c1ccc(-c2nc3ccccc3nc2-c2ccc3c(ccc4c5cccc6c5c(cc34)-c3ccccc3-6)c2)cc1 ; [2H]c1c([2H])c([2H])c(-c2nc(-c3ccc4c(ccc5c6cccc7c6c(cc45)-c4ccccc4-7)c3)nc(-c3c([2H])c([2H])c([2H])c([2H])c3[2H])n2)c([2H])c1[2H]]

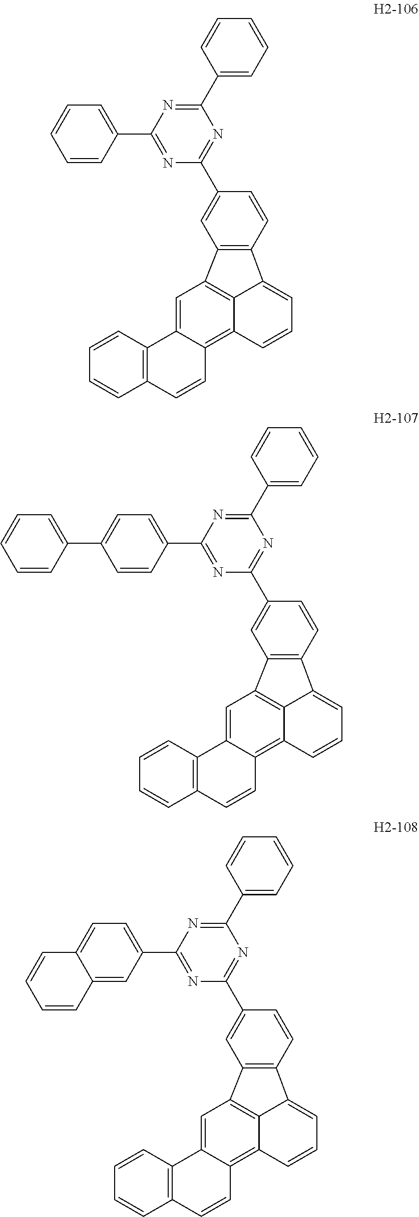

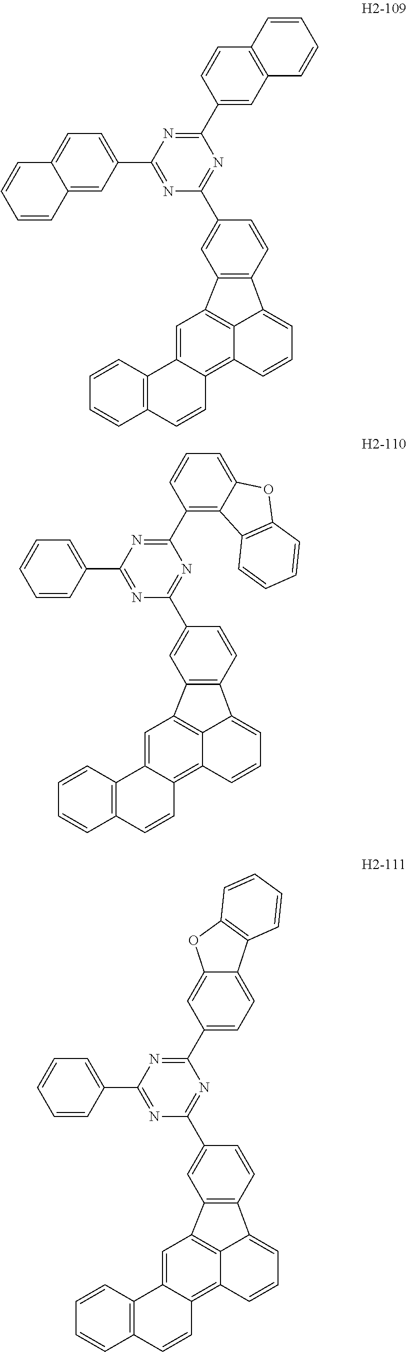

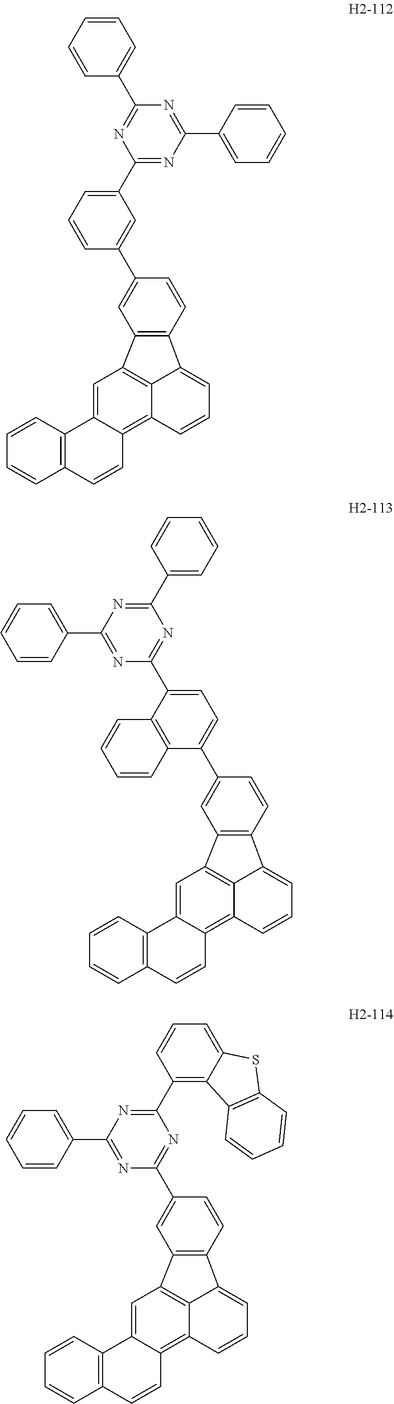

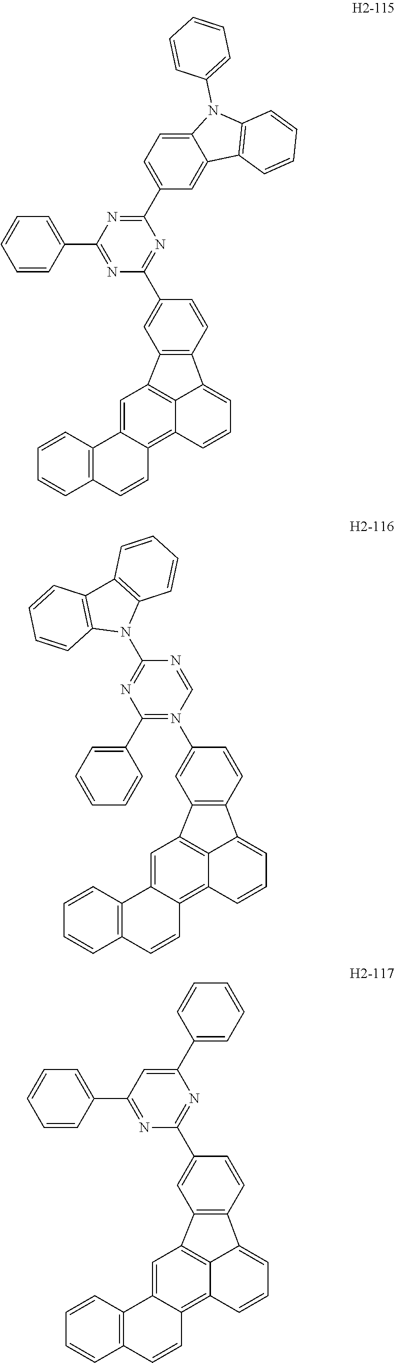

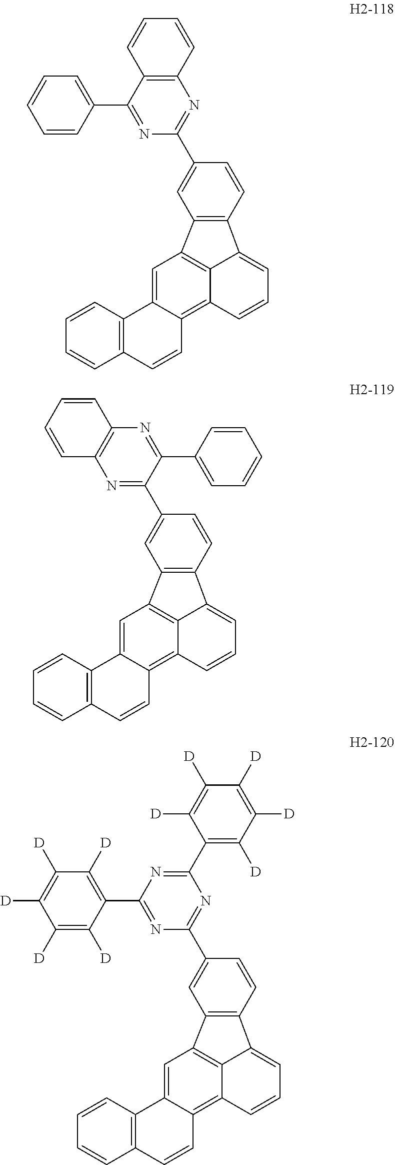

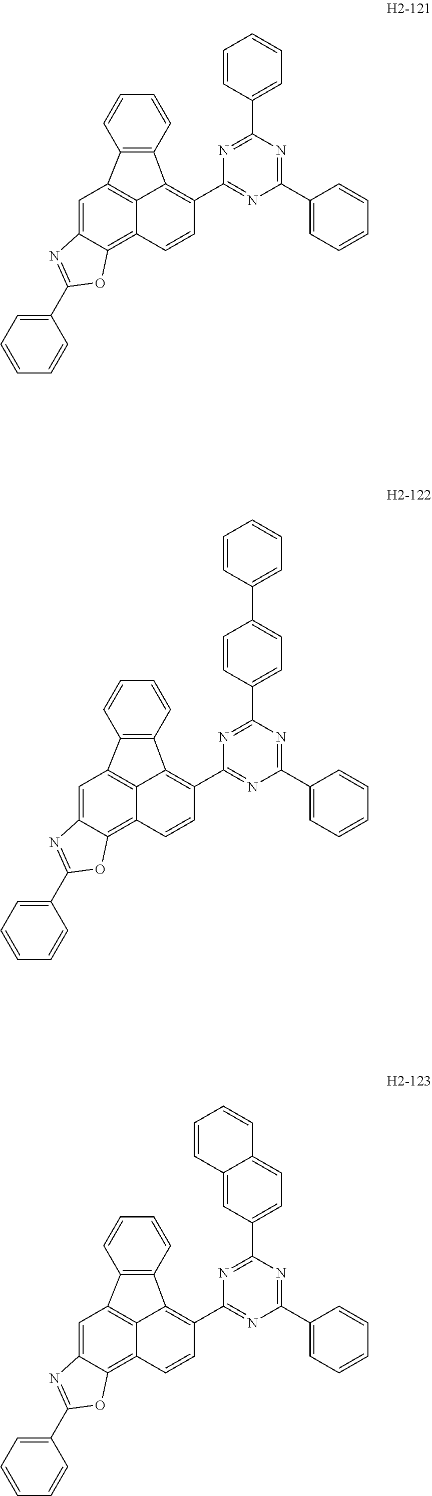 [SMILES: c1ccc(-c2nc(-c3ccccc3)nc(-c3ccc4c5c(cc6nc(-c7ccccc7)oc64)-c4ccccc4-c35)n2)cc1 ; c1ccc(-c2ccc(-c3nc(-c4ccccc4)nc(-c4ccc5c6c(cc7nc(-c8ccccc8)oc75)-c5ccccc5-c46)n3)cc2)cc1 ; c1ccc(-c2nc(-c3ccc4ccccc4c3)nc(-c3ccc4c5c(cc6nc(-c7ccccc7)oc64)-c4ccccc4-c35)n2)cc1]

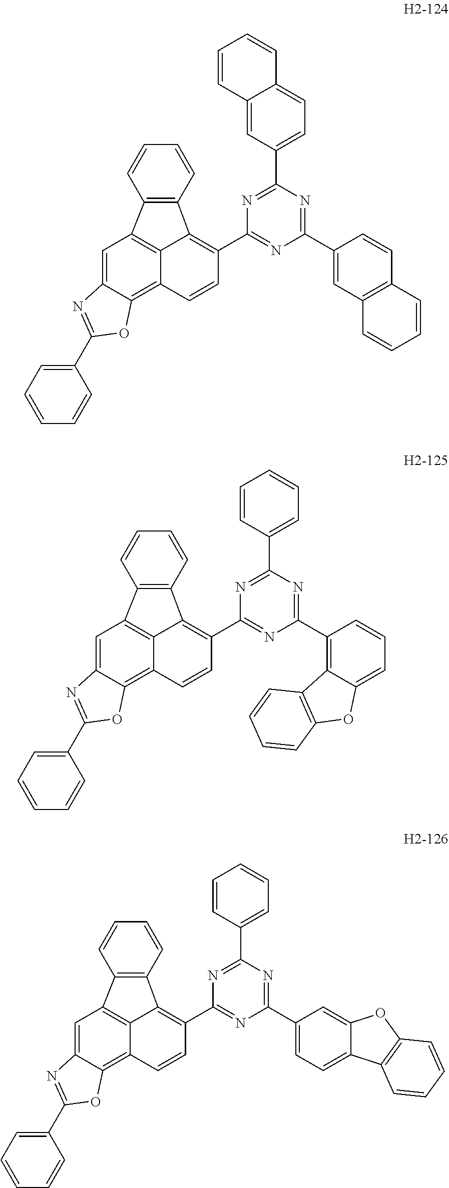 [SMILES: c1ccc(-c2nc3cc4c5c(c(-c6nc(-c7ccc8ccccc8c7)nc(-c7ccc8ccccc8c7)n6)ccc5c3o2)-c2ccccc2-4)cc1 ; c1ccc(-c2nc(-c3ccc4c5c(cc6nc(-c7ccccc7)oc64)-c4ccccc4-c35)nc(-c3cccc4oc5ccccc5c34)n2)cc1 ; c1ccc(-c2nc(-c3ccc4c(c3)oc3ccccc34)nc(-c3ccc4c5c(cc6nc(-c7ccccc7)oc64)-c4ccccc4-c35)n2)cc1]

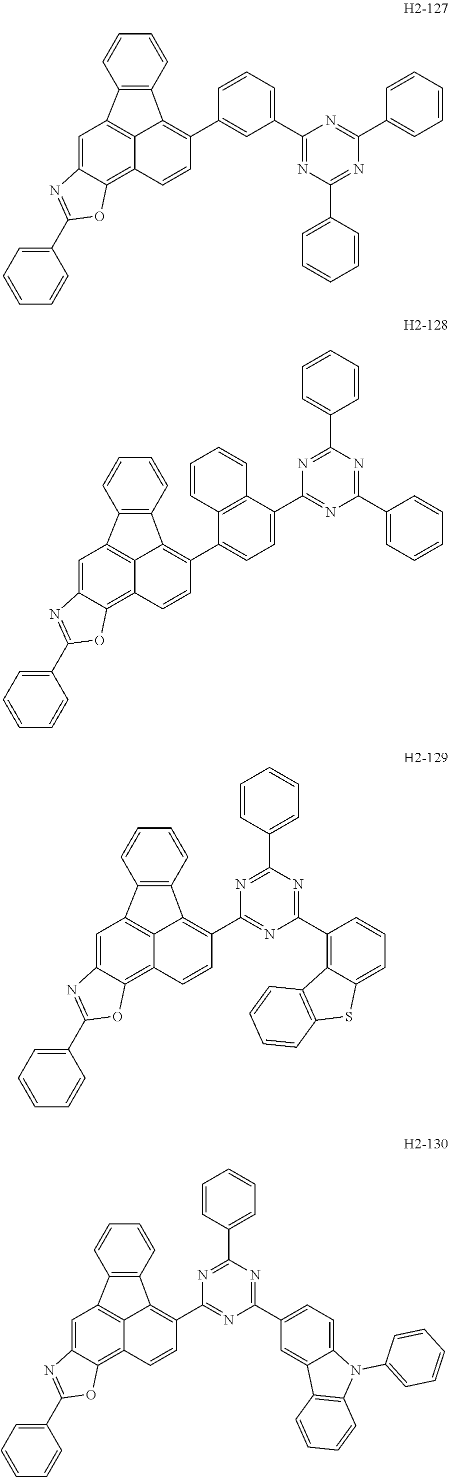 [SMILES: c1ccc(-c2nc(-c3ccccc3)nc(-c3cccc(-c4ccc5c6c(cc7nc(-c8ccccc8)oc75)-c5ccccc5-c46)c3)n2)cc1 ; c1ccc(-c2nc(-c3ccccc3)nc(-c3ccc(-c4ccc5c6c(cc7nc(-c8ccccc8)oc75)-c5ccccc5-c46)c4ccccc34)n2)cc1 ; c1ccc(-c2nc(-c3ccc4c5c(cc6nc(-c7ccccc7)oc64)-c4ccccc4-c35)nc(-c3cccc4sc5ccccc5c34)n2)cc1 ; c1ccc(-c2nc(-c3ccc4c(c3)c3ccccc3n4-c3ccccc3)nc(-c3ccc4c5c(cc6nc(-c7ccccc7)oc64)-c4ccccc4-c35)n2)cc1]

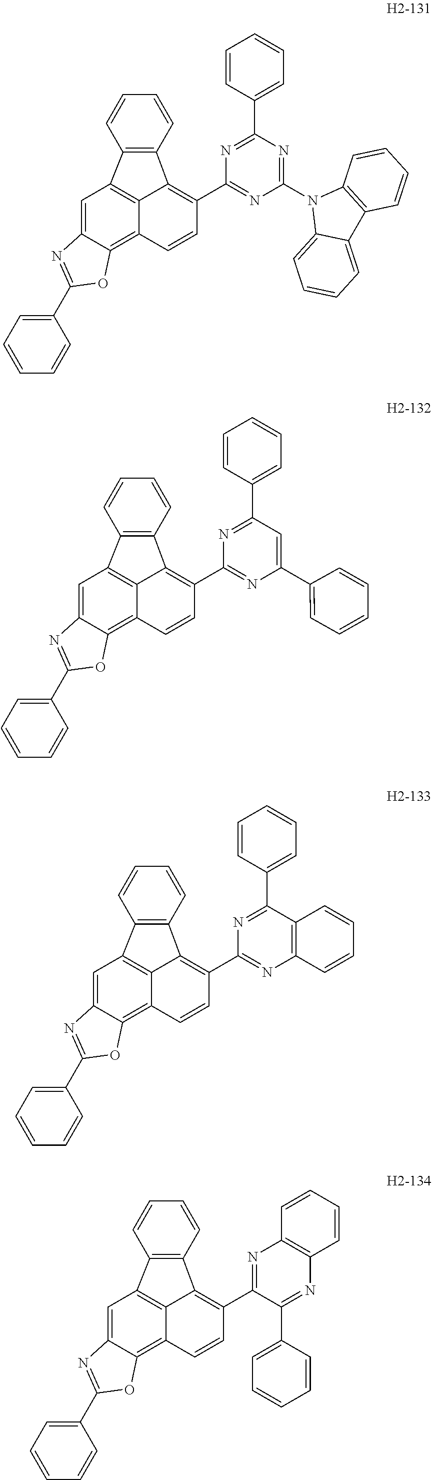 [SMILES: c1ccc(-c2nc(-c3ccc4c5c(cc6nc(-c7ccccc7)oc64)-c4ccccc4-c35)nc(-n3c4ccccc4c4ccccc43)n2)cc1 ; c1ccc(-c2cc(-c3ccccc3)nc(-c3ccc4c5c(cc6nc(-c7ccccc7)oc64)-c4ccccc4-c35)n2)cc1 ; c1ccc(-c2nc3cc4c5c(c(-c6nc(-c7ccccc7)c7ccccc7n6)ccc5c3o2)-c2ccccc2-4)cc1 ; c1ccc(-c2nc3cc4c5c(c(-c6nc7ccccc7nc6-c6ccccc6)ccc5c3o2)-c2ccccc2-4)cc1]

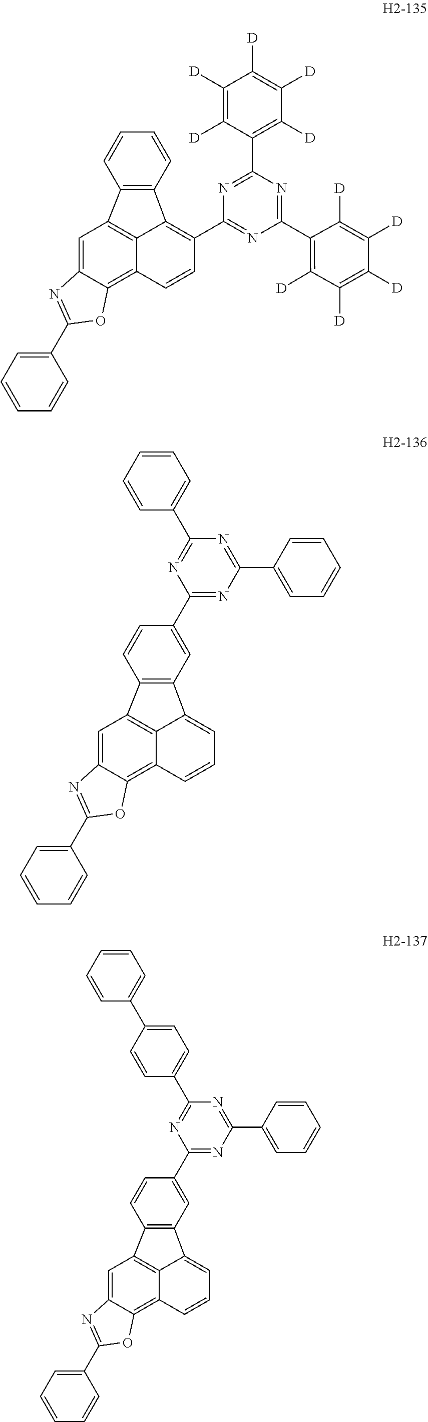 [SMILES: [2H]c1c([2H])c([2H])c(-c2nc(-c3ccc4c5c(cc6nc(-c7ccccc7)oc64)-c4ccccc4-c35)nc(-c3c([2H])c([2H])c([2H])c([2H])c3[2H])n2)c([2H])c1[2H] ; c1ccc(-c2nc(-c3ccccc3)nc(-c3ccc4c(c3)-c3cccc5c3c-4cc3nc(-c4ccccc4)oc35)n2)cc1 ; c1ccc(-c2ccc(-c3nc(-c4ccccc4)nc(-c4ccc5c(c4)-c4cccc6c4c-5cc4nc(-c5ccccc5)oc46)n3)cc2)cc1]

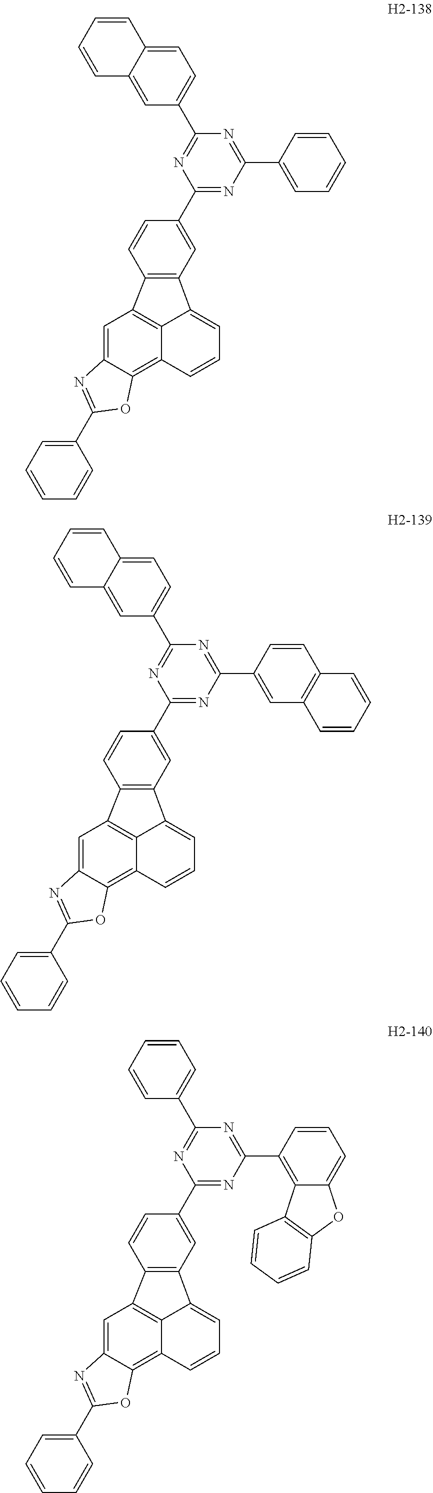

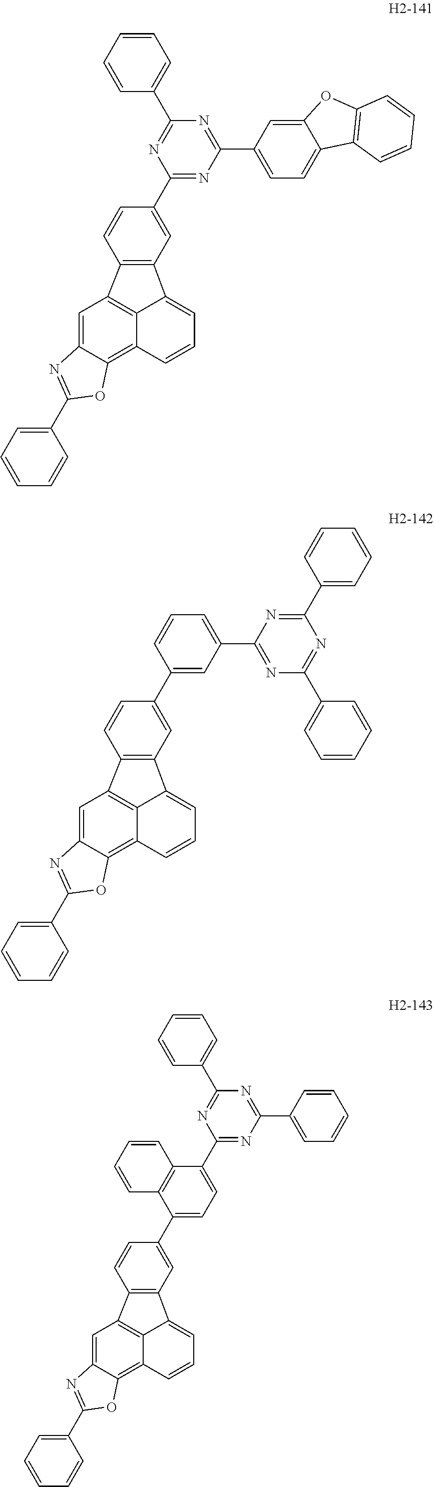 [SMILES: c1ccc(-c2nc(-c3ccc4c(c3)-c3cccc5c3c-4cc3nc(-c4ccccc4)oc35)nc(-c3ccc4c(c3)oc3ccccc34)n2)cc1 ; c1ccc(-c2nc(-c3ccccc3)nc(-c3cccc(-c4ccc5c(c4)-c4cccc6c4c-5cc4nc(-c5ccccc5)oc46)c3)n2)cc1 ; c1ccc(-c2nc(-c3ccccc3)nc(-c3ccc(-c4ccc5c(c4)-c4cccc6c4c-5cc4nc(-c5ccccc5)oc46)c4ccccc34)n2)cc1]

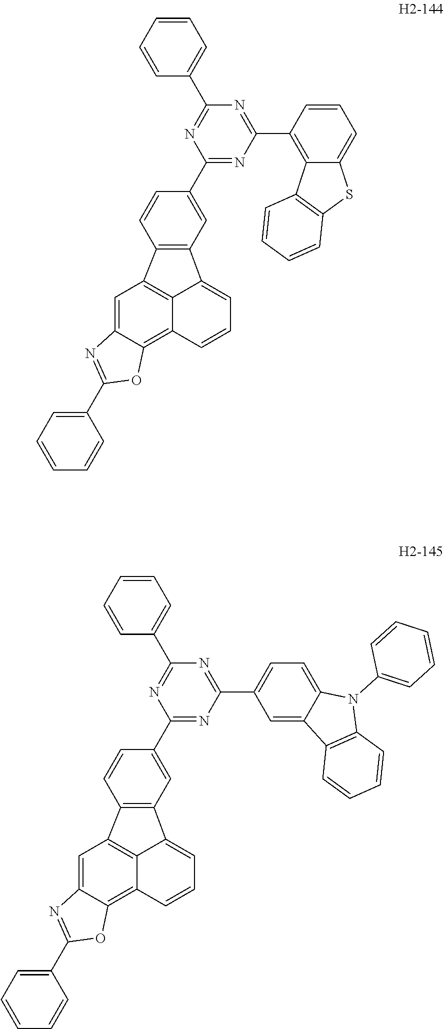 [SMILES: c1ccc(-c2nc(-c3ccc4c(c3)-c3cccc5c3c-4cc3nc(-c4ccccc4)oc35)nc(-c3cccc4sc5ccccc5c34)n2)cc1 ; c1ccc(-c2nc(-c3ccc4c(c3)-c3cccc5c3c-4cc3nc(-c4ccccc4)oc35)nc(-c3ccc4c(c3)c3ccccc3n4-c3ccccc3)n2)cc1]

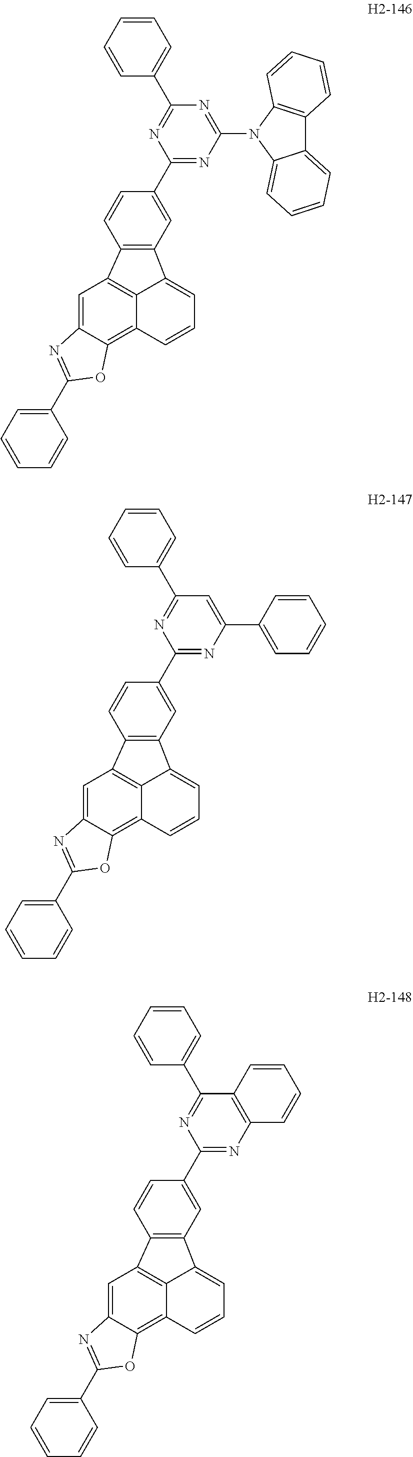 [SMILES: c1ccc(-c2nc(-c3ccc4c(c3)-c3cccc5c3c-4cc3nc(-c4ccccc4)oc35)nc(-n3c4ccccc4c4ccccc43)n2)cc1 ; c1ccc(-c2cc(-c3ccccc3)nc(-c3ccc4c(c3)-c3cccc5c3c-4cc3nc(-c4ccccc4)oc35)n2)cc1 ; c1ccc(-c2nc3cc4c5c(cccc5c3o2)-c2cc(-c3nc(-c5ccccc5)c5ccccc5n3)ccc2-4)cc1]

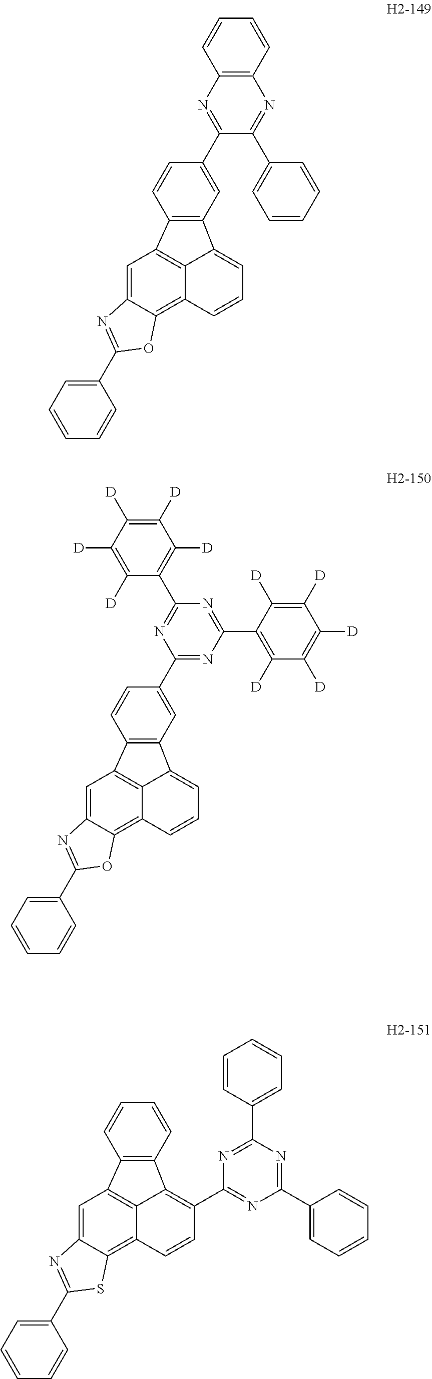 [SMILES: c1ccc(-c2nc3cc4c5c(cccc5c3o2)-c2cc(-c3nc5ccccc5nc3-c3ccccc3)ccc2-4)cc1 ; [2H]c1c([2H])c([2H])c(-c2nc(-c3ccc4c(c3)-c3cccc5c3c-4cc3nc(-c4ccccc4)oc35)nc(-c3c([2H])c([2H])c([2H])c([2H])c3[2H])n2)c([2H])c1[2H] ; c1ccc(-c2nc(-c3ccccc3)nc(-c3ccc4c5c(cc6nc(-c7ccccc7)sc64)-c4ccccc4-c35)n2)cc1]

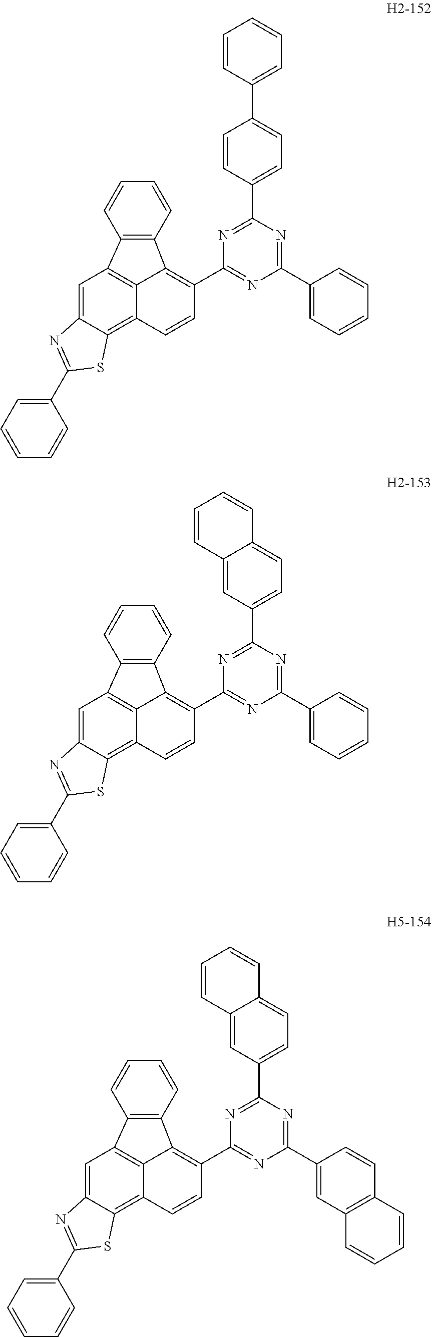 [SMILES: c1ccc(-c2ccc(-c3nc(-c4ccccc4)nc(-c4ccc5c6c(cc7nc(-c8ccccc8)sc75)-c5ccccc5-c46)n3)cc2)cc1 ; c1ccc(-c2nc(-c3ccc4ccccc4c3)nc(-c3ccc4c5c(cc6nc(-c7ccccc7)sc64)-c4ccccc4-c35)n2)cc1 ; c1ccc(-c2nc3cc4c5c(c(-c6nc(-c7ccc8ccccc8c7)nc(-c7ccc8ccccc8c7)n6)ccc5c3s2)-c2ccccc2-4)cc1]

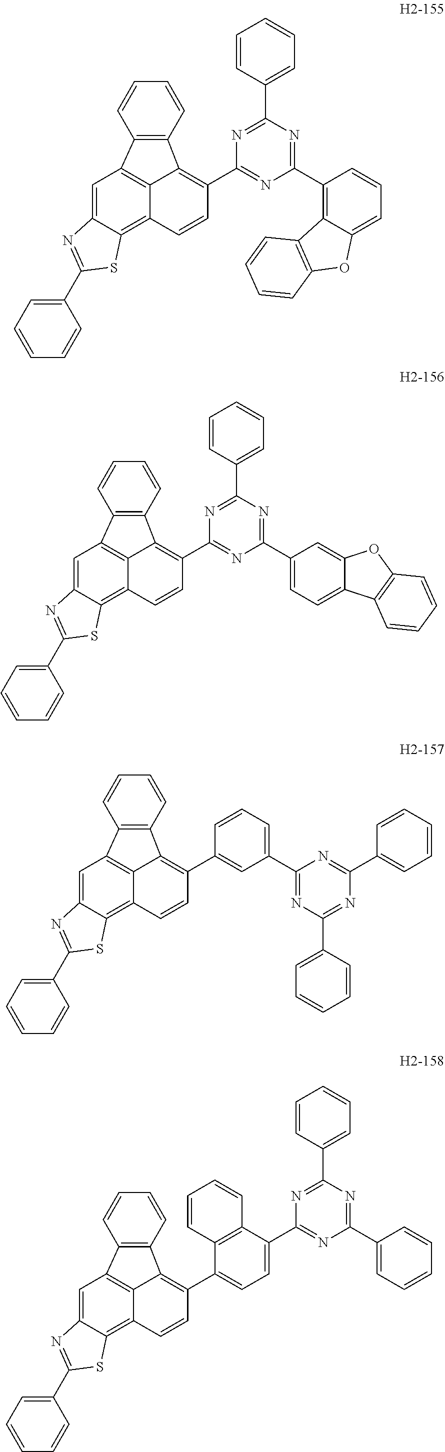 [SMILES: c1ccc(-c2nc(-c3ccc4c5c(cc6nc(-c7ccccc7)sc64)-c4ccccc4-c35)nc(-c3cccc4oc5ccccc5c34)n2)cc1 ; c1ccc(-c2nc(-c3ccc4c(c3)oc3ccccc34)nc(-c3ccc4c5c(cc6nc(-c7ccccc7)sc64)-c4ccccc4-c35)n2)cc1 ; c1ccc(-c2nc(-c3ccccc3)nc(-c3cccc(-c4ccc5c6c(cc7nc(-c8ccccc8)sc75)-c5ccccc5-c46)c3)n2)cc1 ; c1ccc(-c2nc(-c3ccccc3)nc(-c3ccc(-c4ccc5c6c(cc7nc(-c8ccccc8)sc75)-c5ccccc5-c46)c4ccccc34)n2)cc1]

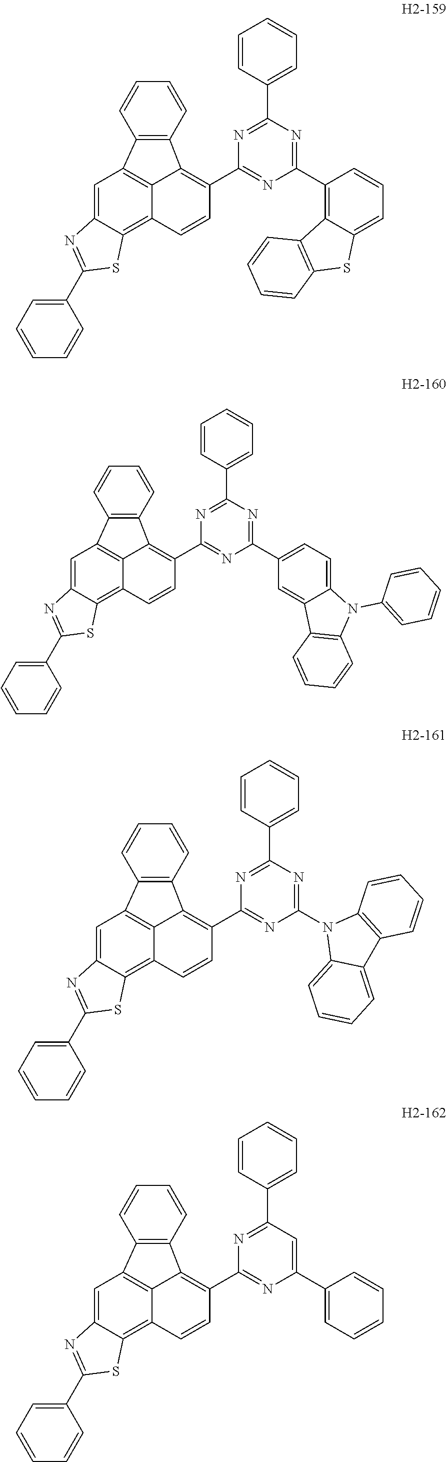 [SMILES: c1ccc(-c2nc(-c3ccc4c5c(cc6nc(-c7ccccc7)sc64)-c4ccccc4-c35)nc(-c3cccc4sc5ccccc5c34)n2)cc1 ; c1ccc(-c2nc(-c3ccc4c(c3)c3ccccc3n4-c3ccccc3)nc(-c3ccc4c5c(cc6nc(-c7ccccc7)sc64)-c4ccccc4-c35)n2)cc1 ; c1ccc(-c2nc(-c3ccc4c5c(cc6nc(-c7ccccc7)sc64)-c4ccccc4-c35)nc(-n3c4ccccc4c4ccccc43)n2)cc1 ; c1ccc(-c2cc(-c3ccccc3)nc(-c3ccc4c5c(cc6nc(-c7ccccc7)sc64)-c4ccccc4-c35)n2)cc1]

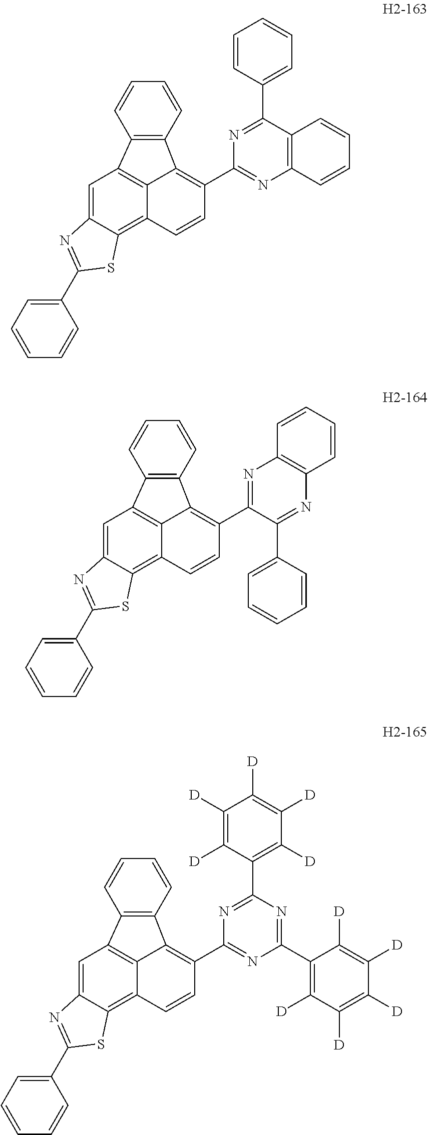 [SMILES: c1ccc(-c2nc3cc4c5c(c(-c6nc(-c7ccccc7)c7ccccc7n6)ccc5c3s2)-c2ccccc2-4)cc1 ; c1ccc(-c2nc3cc4c5c(c(-c6nc7ccccc7nc6-c6ccccc6)ccc5c3s2)-c2ccccc2-4)cc1 ; [2H]c1c([2H])c([2H])c(-c2nc(-c3ccc4c5c(cc6nc(-c7ccccc7)sc64)-c4ccccc4-c35)nc(-c3c([2H])c([2H])c([2H])c([2H])c3[2H])n2)c([2H])c1[2H]]

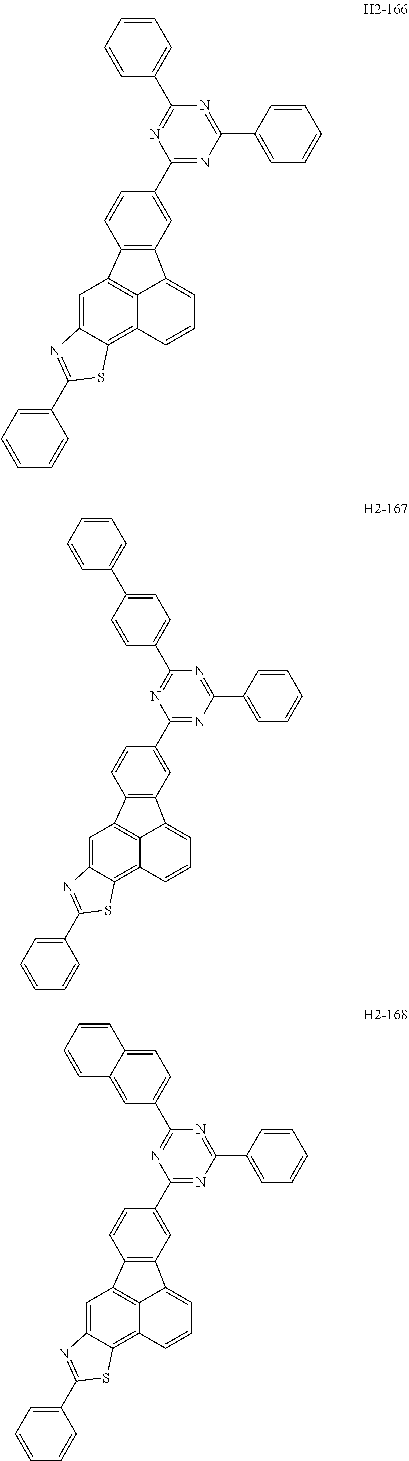

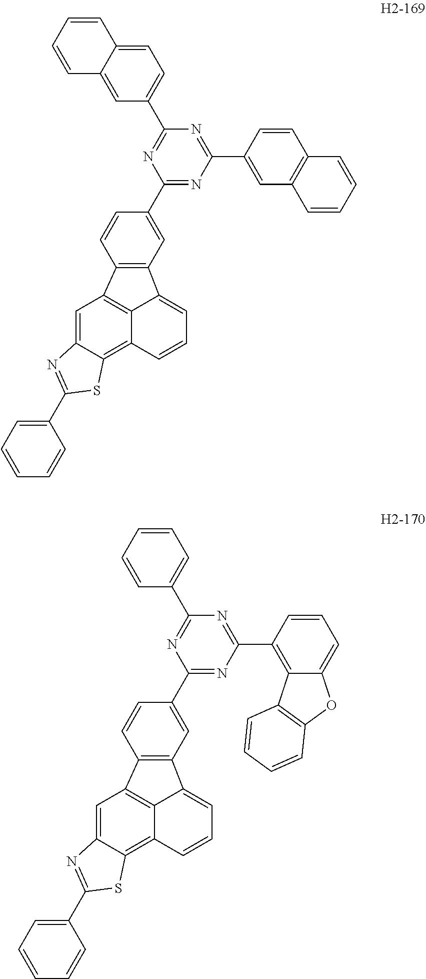 [SMILES: c1ccc(-c2nc3cc4c5c(cccc5c3s2)-c2cc(-c3nc(-c5ccc6ccccc6c5)nc(-c5ccc6ccccc6c5)n3)ccc2-4)cc1 ; c1ccc(-c2nc(-c3ccc4c(c3)-c3cccc5c3c-4cc3nc(-c4ccccc4)sc35)nc(-c3cccc4oc5ccccc5c34)n2)cc1]

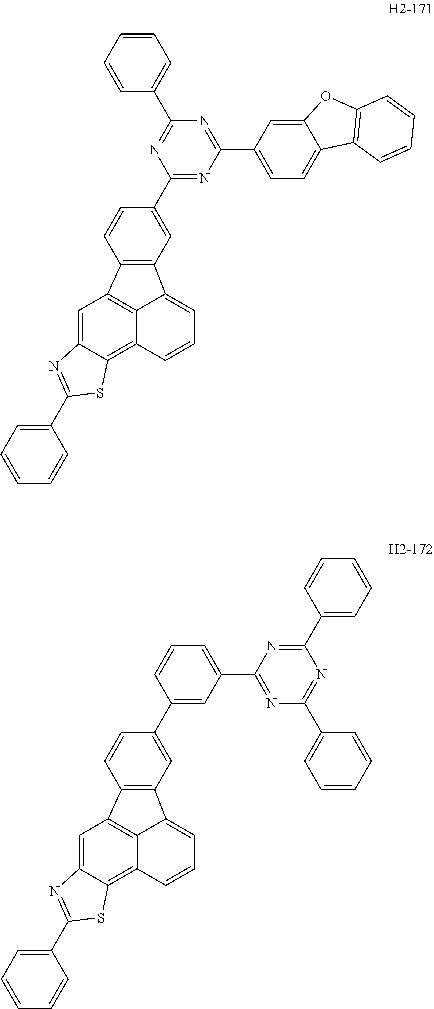 [SMILES: c1ccc(-c2nc(-c3ccc4c(c3)-c3cccc5c3c-4cc3nc(-c4ccccc4)sc35)nc(-c3ccc4c(c3)oc3ccccc34)n2)cc1 ; c1ccc(-c2nc(-c3ccccc3)nc(-c3cccc(-c4ccc5c(c4)-c4cccc6c4c-5cc4nc(-c5ccccc5)sc46)c3)n2)cc1]

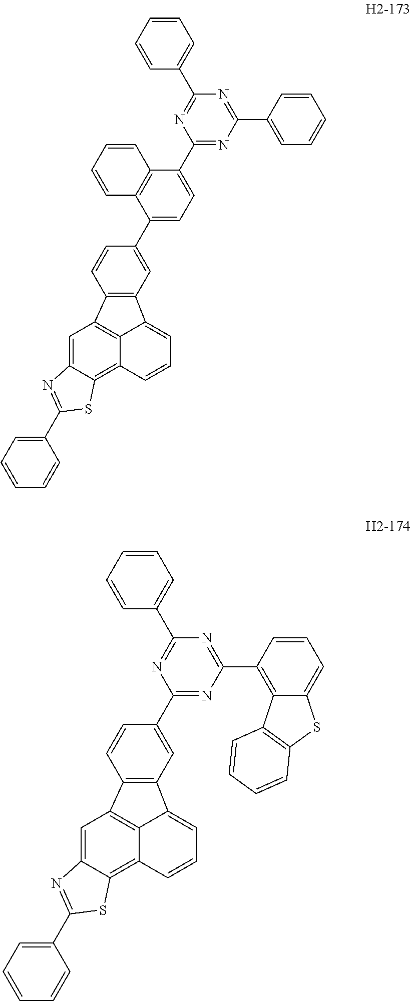 [SMILES: c1ccc(-c2nc(-c3ccccc3)nc(-c3ccc(-c4ccc5c(c4)-c4cccc6c4c-5cc4nc(-c5ccccc5)sc46)c4ccccc34)n2)cc1 ; c1ccc(-c2nc(-c3ccc4c(c3)-c3cccc5c3c-4cc3nc(-c4ccccc4)sc35)nc(-c3cccc4sc5ccccc5c34)n2)cc1]

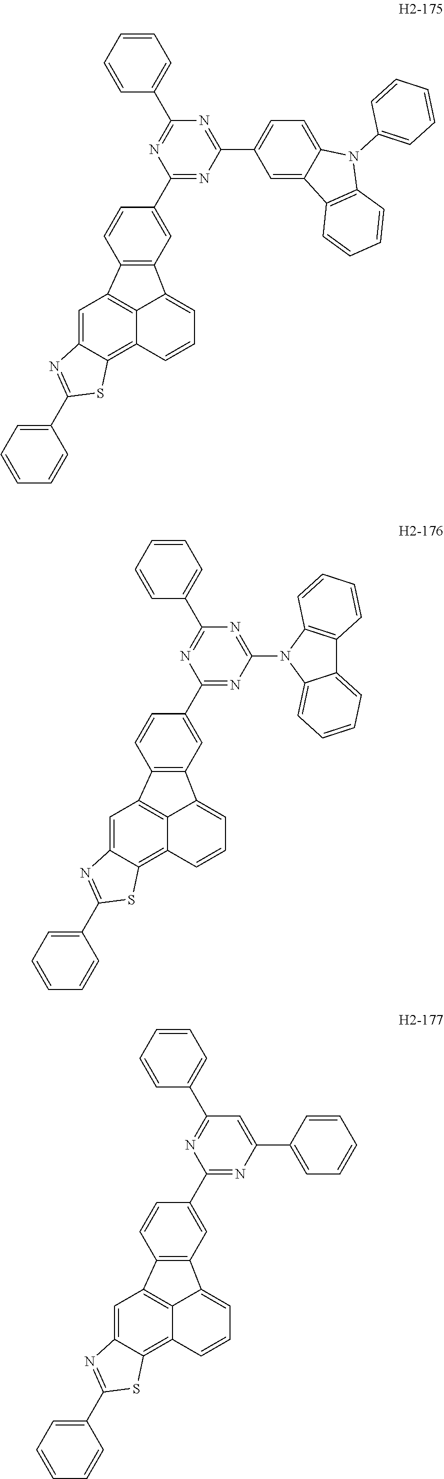 [SMILES: c1ccc(-c2nc(-c3ccc4c(c3)-c3cccc5c3c-4cc3nc(-c4ccccc4)sc35)nc(-c3ccc4c(c3)c3ccccc3n4-c3ccccc3)n2)cc1 ; c1ccc(-c2nc(-c3ccc4c(c3)-c3cccc5c3c-4cc3nc(-c4ccccc4)sc35)nc(-n3c4ccccc4c4ccccc43)n2)cc1 ; c1ccc(-c2cc(-c3ccccc3)nc(-c3ccc4c(c3)-c3cccc5c3c-4cc3nc(-c4ccccc4)sc35)n2)cc1]

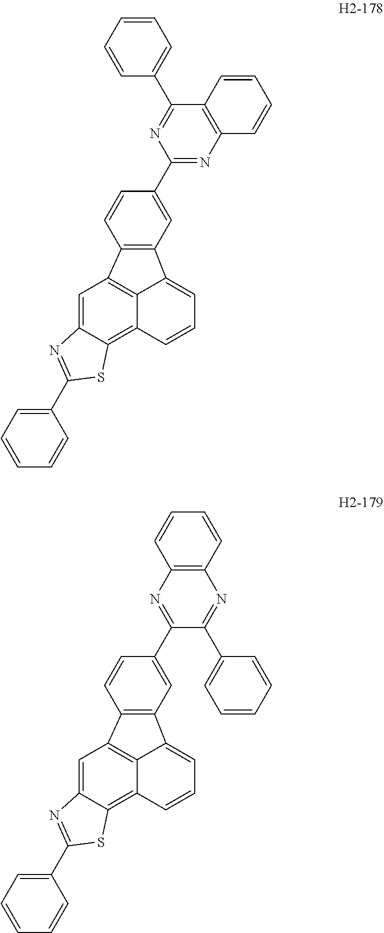 [SMILES: c1ccc(-c2nc3cc4c5c(cccc5c3s2)-c2cc(-c3nc(-c5ccccc5)c5ccccc5n3)ccc2-4)cc1 ; c1ccc(-c2nc3cc4c5c(cccc5c3s2)-c2cc(-c3nc5ccccc5nc3-c3ccccc3)ccc2-4)cc1]

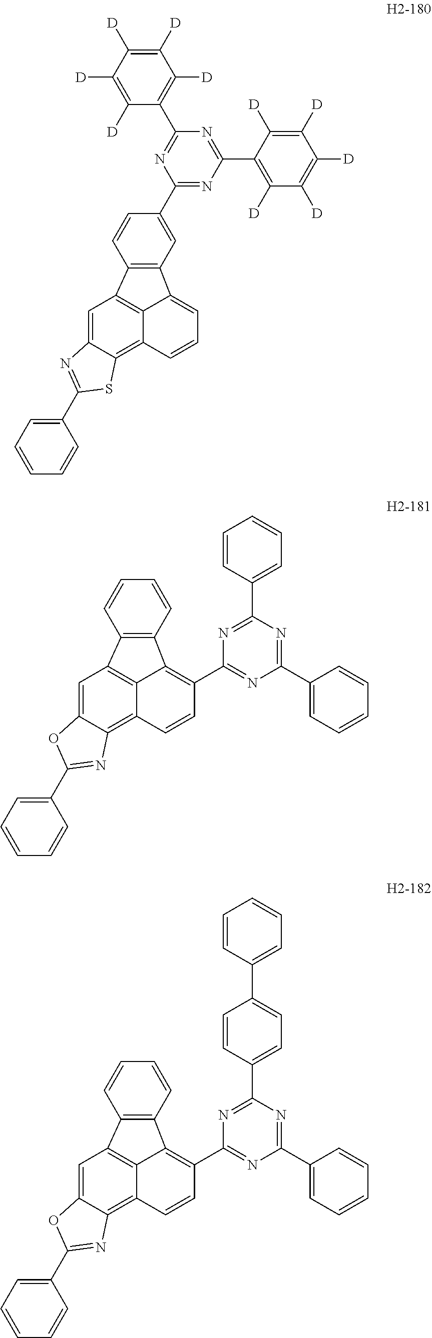 [SMILES: [2H]c1c([2H])c([2H])c(-c2nc(-c3ccc4c(c3)-c3cccc5c3c-4cc3nc(-c4ccccc4)sc35)nc(-c3c([2H])c([2H])c([2H])c([2H])c3[2H])n2)c([2H])c1[2H] ; c1ccc(-c2nc(-c3ccccc3)nc(-c3ccc4c5c(cc6oc(-c7ccccc7)nc64)-c4ccccc4-c35)n2)cc1 ; c1ccc(-c2ccc(-c3nc(-c4ccccc4)nc(-c4ccc5c6c(cc7oc(-c8ccccc8)nc75)-c5ccccc5-c46)n3)cc2)cc1]

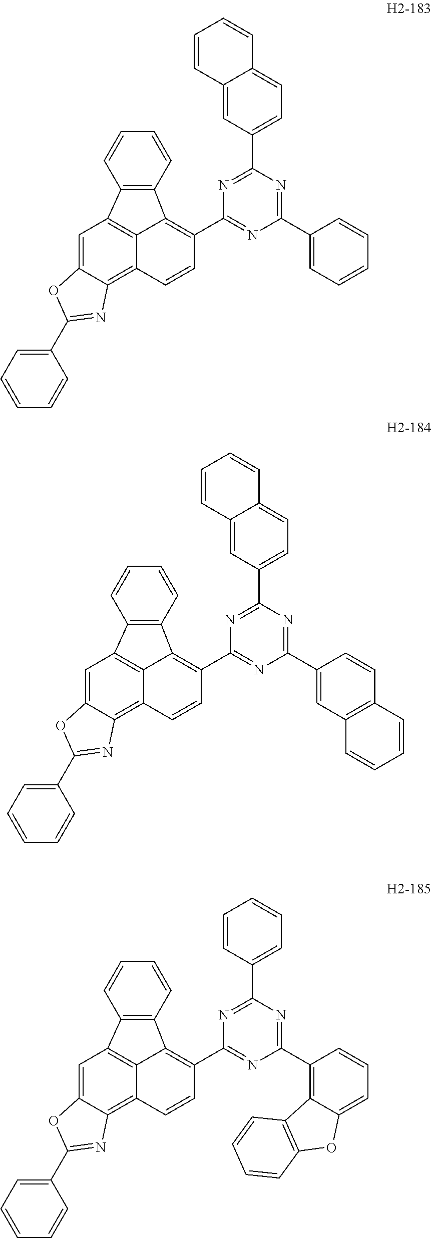 [SMILES: c1ccc(-c2nc(-c3ccc4ccccc4c3)nc(-c3ccc4c5c(cc6oc(-c7ccccc7)nc64)-c4ccccc4-c35)n2)cc1 ; c1ccc(-c2nc3c(cc4c5c(c(-c6nc(-c7ccc8ccccc8c7)nc(-c7ccc8ccccc8c7)n6)ccc53)-c3ccccc3-4)o2)cc1 ; c1ccc(-c2nc(-c3ccc4c5c(cc6oc(-c7ccccc7)nc64)-c4ccccc4-c35)nc(-c3cccc4oc5ccccc5c34)n2)cc1]

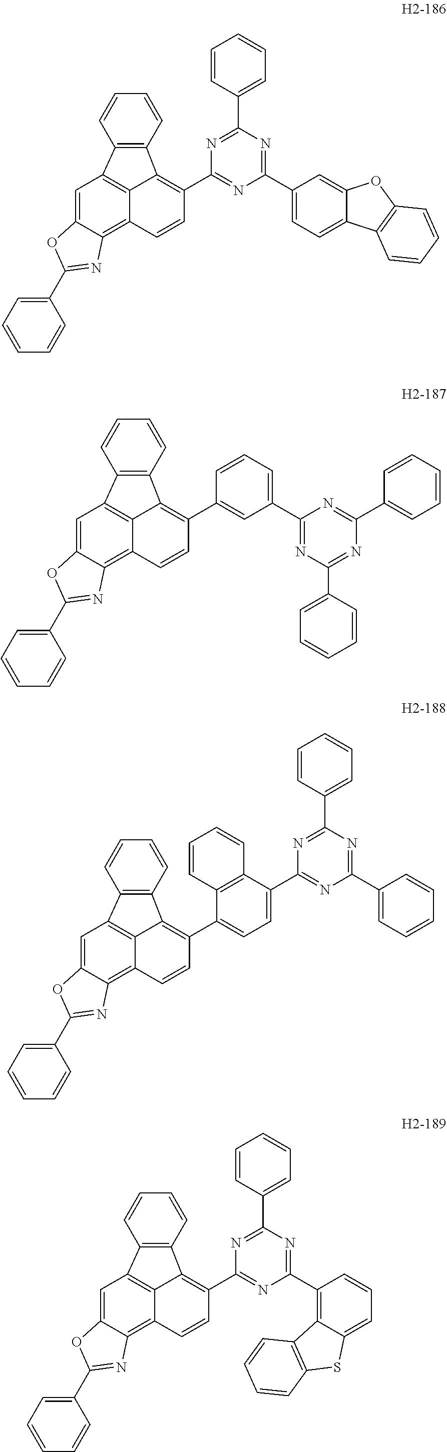 [SMILES: c1ccc(-c2nc(-c3ccc4c(c3)oc3ccccc34)nc(-c3ccc4c5c(cc6oc(-c7ccccc7)nc64)-c4ccccc4-c35)n2)cc1 ; c1ccc(-c2nc(-c3ccccc3)nc(-c3cccc(-c4ccc5c6c(cc7oc(-c8ccccc8)nc75)-c5ccccc5-c46)c3)n2)cc1 ; c1ccc(-c2nc(-c3ccccc3)nc(-c3ccc(-c4ccc5c6c(cc7oc(-c8ccccc8)nc75)-c5ccccc5-c46)c4ccccc34)n2)cc1 ; c1ccc(-c2nc(-c3ccc4c5c(cc6oc(-c7ccccc7)nc64)-c4ccccc4-c35)nc(-c3cccc4sc5ccccc5c34)n2)cc1]

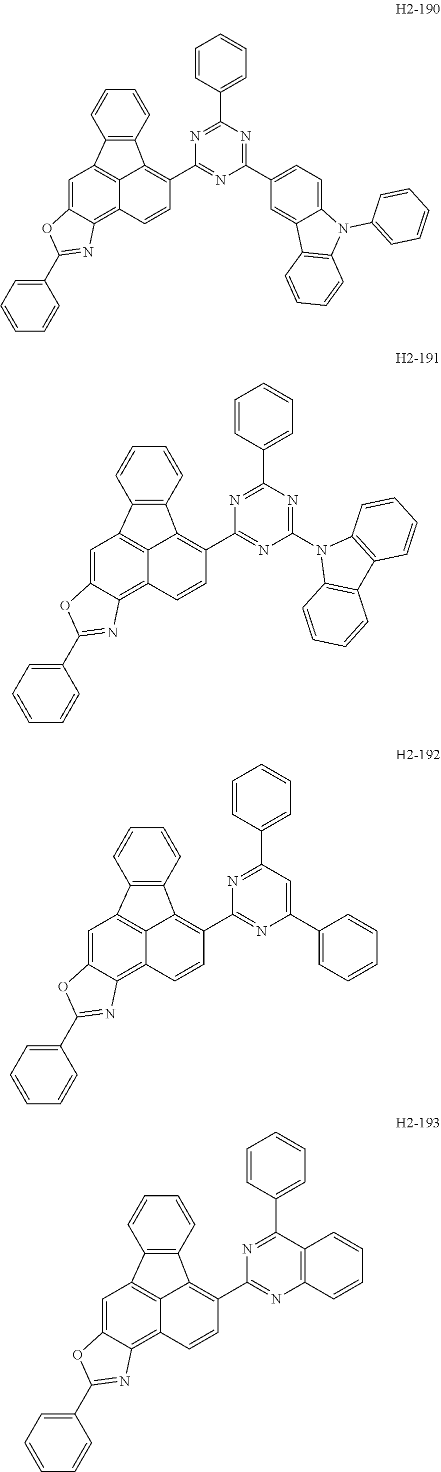 [SMILES: c1ccc(-c2nc(-c3ccc4c(c3)c3ccccc3n4-c3ccccc3)nc(-c3ccc4c5c(cc6oc(-c7ccccc7)nc64)-c4ccccc4-c35)n2)cc1 ; c1ccc(-c2nc(-c3ccc4c5c(cc6oc(-c7ccccc7)nc64)-c4ccccc4-c35)nc(-n3c4ccccc4c4ccccc43)n2)cc1 ; c1ccc(-c2cc(-c3ccccc3)nc(-c3ccc4c5c(cc6oc(-c7ccccc7)nc64)-c4ccccc4-c35)n2)cc1 ; c1ccc(-c2nc3c(cc4c5c(c(-c6nc(-c7ccccc7)c7ccccc7n6)ccc53)-c3ccccc3-4)o2)cc1]

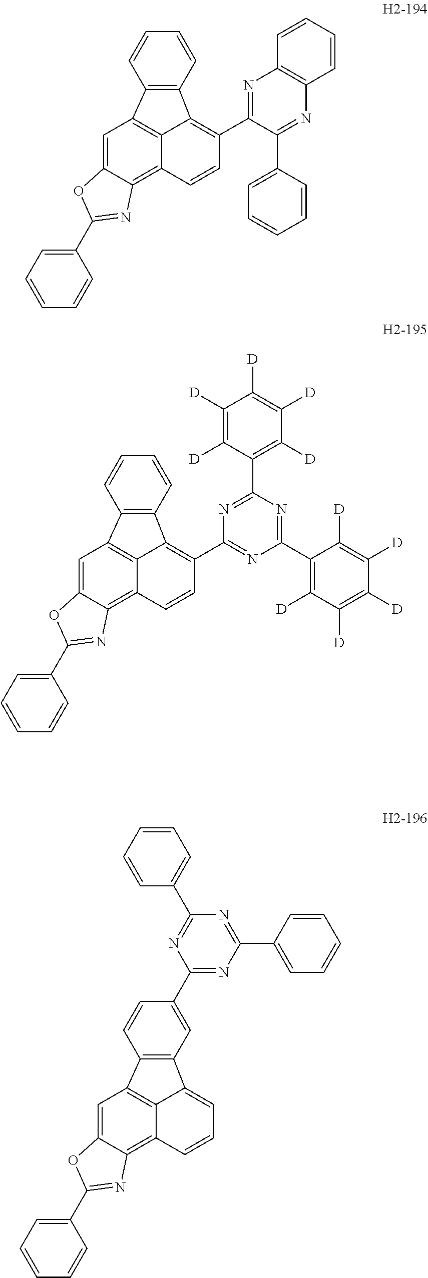 [SMILES: c1ccc(-c2nc3c(cc4c5c(c(-c6nc7ccccc7nc6-c6ccccc6)ccc53)-c3ccccc3-4)o2)cc1 ; [2H]c1c([2H])c([2H])c(-c2nc(-c3ccc4c5c(cc6oc(-c7ccccc7)nc64)-c4ccccc4-c35)nc(-c3c([2H])c([2H])c([2H])c([2H])c3[2H])n2)c([2H])c1[2H] ; c1ccc(-c2nc(-c3ccccc3)nc(-c3ccc4c(c3)-c3cccc5c3c-4cc3oc(-c4ccccc4)nc35)n2)cc1]

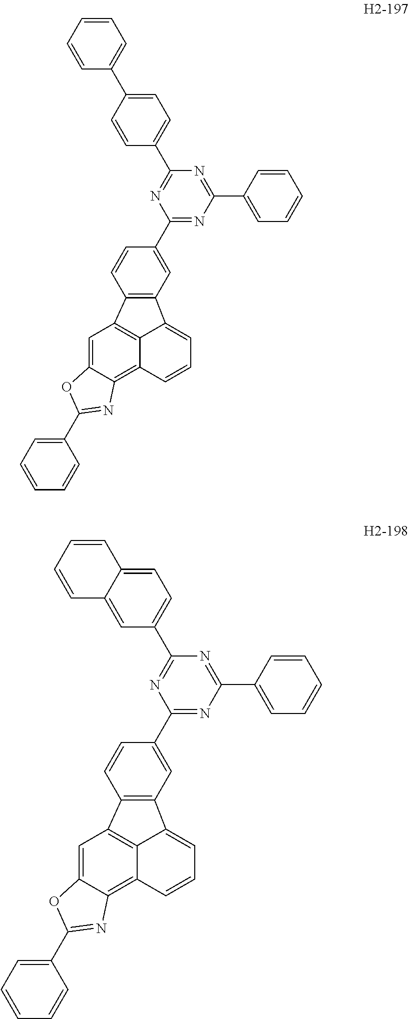 [SMILES: c1ccc(-c2ccc(-c3nc(-c4ccccc4)nc(-c4ccc5c(c4)-c4cccc6c4c-5cc4oc(-c5ccccc5)nc46)n3)cc2)cc1 ; c1ccc(-c2nc(-c3ccc4c(c3)-c3cccc5c3c-4cc3oc(-c4ccccc4)nc35)nc(-c3ccc4ccccc4c3)n2)cc1]

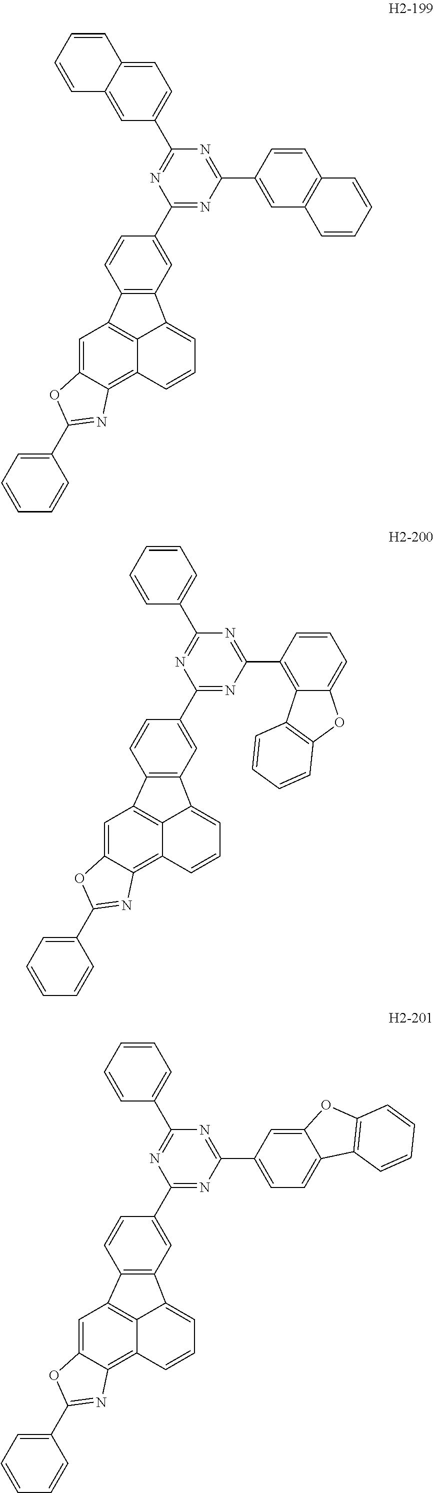 [SMILES: c1ccc(-c2nc3c(cc4c5c(cccc53)-c3cc(-c5nc(-c6ccc7ccccc7c6)nc(-c6ccc7ccccc7c6)n5)ccc3-4)o2)cc1 ; c1ccc(-c2nc(-c3ccc4c(c3)-c3cccc5c3c-4cc3oc(-c4ccccc4)nc35)nc(-c3cccc4oc5ccccc5c34)n2)cc1 ; c1ccc(-c2nc(-c3ccc4c(c3)-c3cccc5c3c-4cc3oc(-c4ccccc4)nc35)nc(-c3ccc4c(c3)oc3ccccc34)n2)cc1]

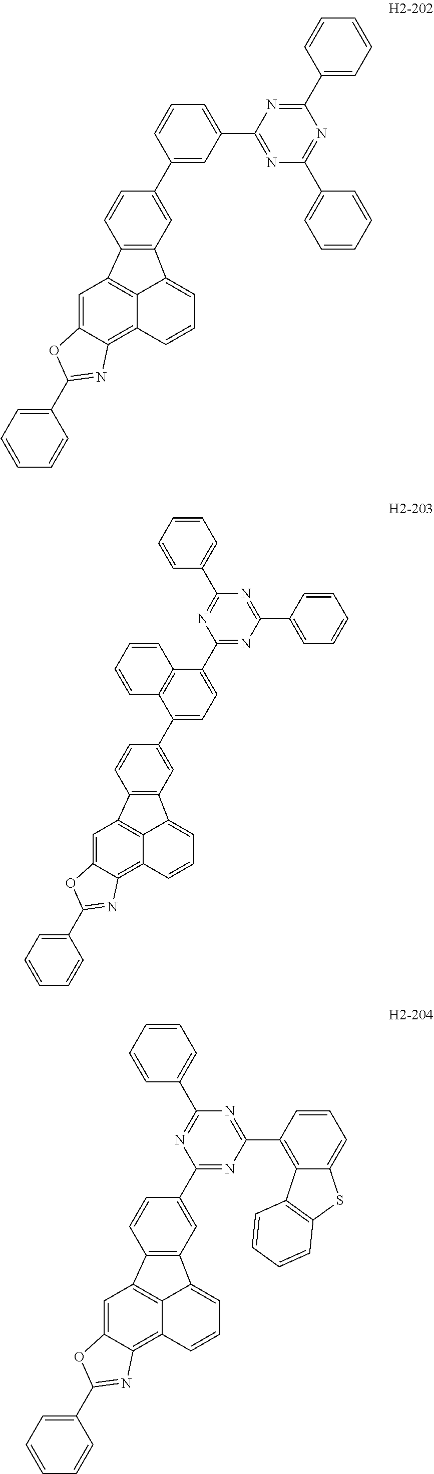 [SMILES: c1ccc(-c2nc(-c3ccccc3)nc(-c3cccc(-c4ccc5c(c4)-c4cccc6c4c-5cc4oc(-c5ccccc5)nc46)c3)n2)cc1 ; c1ccc(-c2nc(-c3ccccc3)nc(-c3ccc(-c4ccc5c(c4)-c4cccc6c4c-5cc4oc(-c5ccccc5)nc46)c4ccccc34)n2)cc1 ; c1ccc(-c2nc(-c3ccc4c(c3)-c3cccc5c3c-4cc3oc(-c4ccccc4)nc35)nc(-c3cccc4sc5ccccc5c34)n2)cc1]

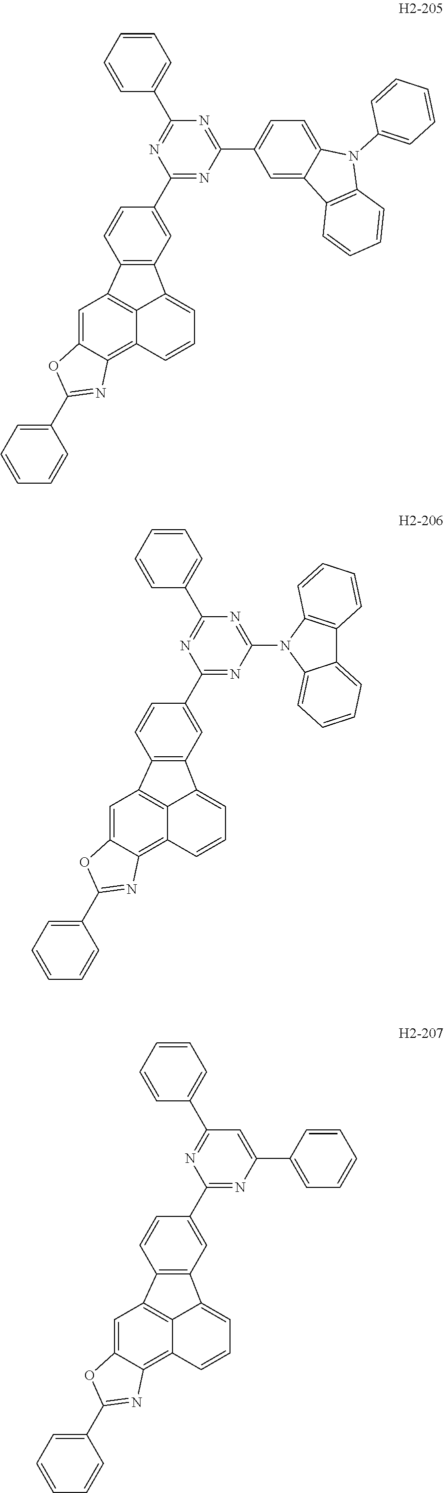 [SMILES: c1ccc(-c2nc(-c3ccc4c(c3)-c3cccc5c3c-4cc3oc(-c4ccccc4)nc35)nc(-c3ccc4c(c3)c3ccccc3n4-c3ccccc3)n2)cc1 ; c1ccc(-c2nc(-c3ccc4c(c3)-c3cccc5c3c-4cc3oc(-c4ccccc4)nc35)nc(-n3c4ccccc4c4ccccc43)n2)cc1 ; c1ccc(-c2cc(-c3ccccc3)nc(-c3ccc4c(c3)-c3cccc5c3c-4cc3oc(-c4ccccc4)nc35)n2)cc1]

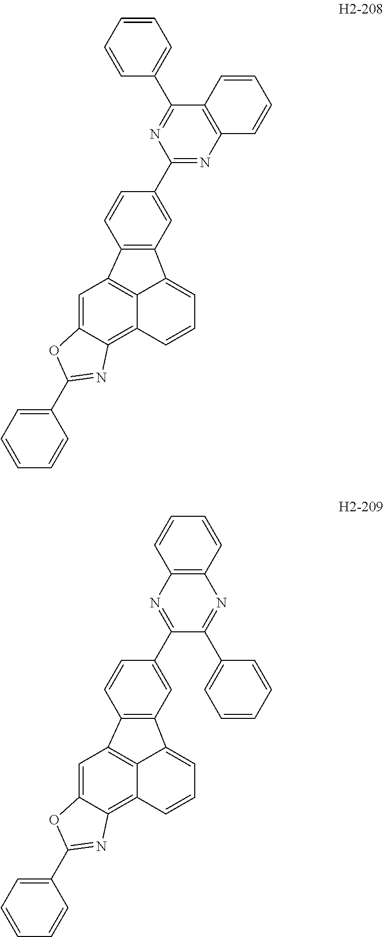 [SMILES: c1ccc(-c2nc3c(cc4c5c(cccc53)-c3cc(-c5nc(-c6ccccc6)c6ccccc6n5)ccc3-4)o2)cc1 ; c1ccc(-c2nc3c(cc4c5c(cccc53)-c3cc(-c5nc6ccccc6nc5-c5ccccc5)ccc3-4)o2)cc1]

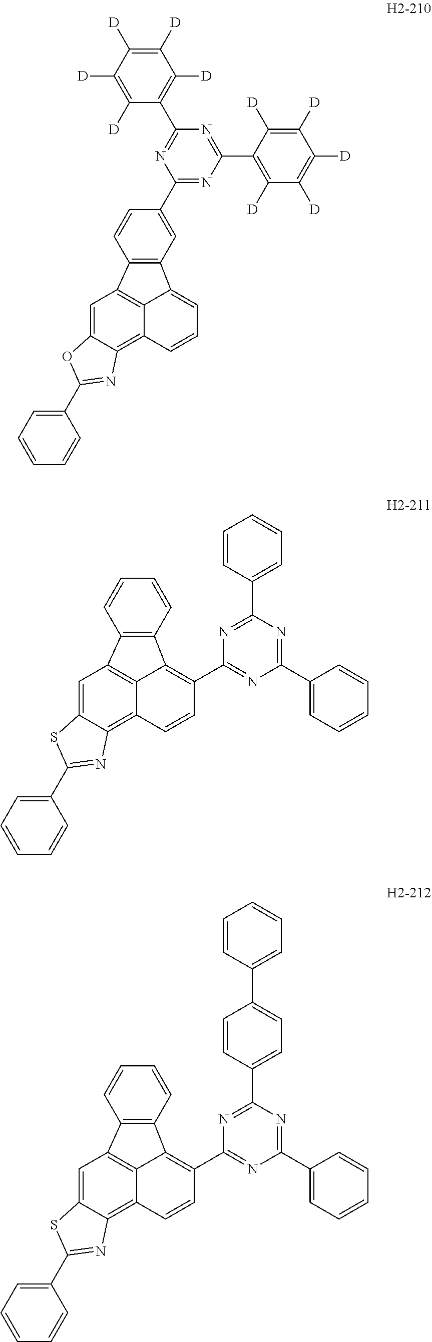 [SMILES: [2H]c1c([2H])c([2H])c(-c2nc(-c3ccc4c(c3)-c3cccc5c3c-4cc3oc(-c4ccccc4)nc35)nc(-c3c([2H])c([2H])c([2H])c([2H])c3[2H])n2)c([2H])c1[2H] ; c1ccc(-c2nc(-c3ccccc3)nc(-c3ccc4c5c(cc6sc(-c7ccccc7)nc64)-c4ccccc4-c35)n2)cc1 ; c1ccc(-c2ccc(-c3nc(-c4ccccc4)nc(-c4ccc5c6c(cc7sc(-c8ccccc8)nc75)-c5ccccc5-c46)n3)cc2)cc1]

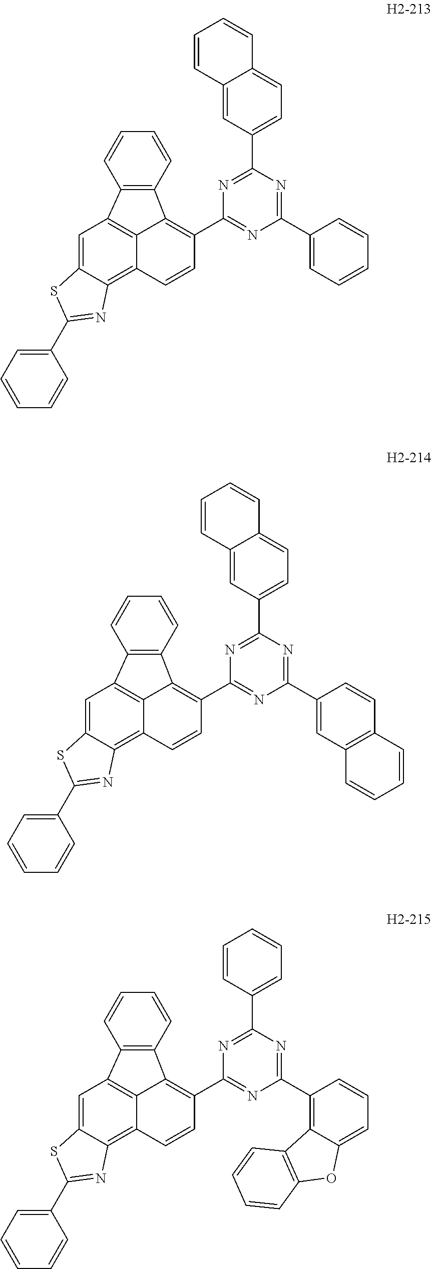 [SMILES: c1ccc(-c2nc(-c3ccc4ccccc4c3)nc(-c3ccc4c5c(cc6sc(-c7ccccc7)nc64)-c4ccccc4-c35)n2)cc1 ; c1ccc(-c2nc3c(cc4c5c(c(-c6nc(-c7ccc8ccccc8c7)nc(-c7ccc8ccccc8c7)n6)ccc53)-c3ccccc3-4)s2)cc1 ; c1ccc(-c2nc(-c3ccc4c5c(cc6sc(-c7ccccc7)nc64)-c4ccccc4-c35)nc(-c3cccc4oc5ccccc5c34)n2)cc1]

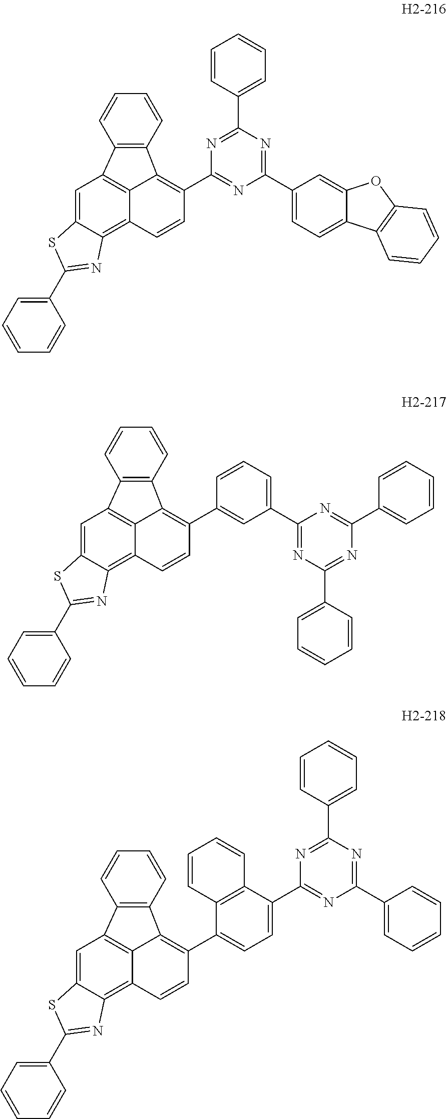 [SMILES: c1ccc(-c2nc(-c3ccc4c(c3)oc3ccccc34)nc(-c3ccc4c5c(cc6sc(-c7ccccc7)nc64)-c4ccccc4-c35)n2)cc1 ; c1ccc(-c2nc(-c3ccccc3)nc(-c3cccc(-c4ccc5c6c(cc7sc(-c8ccccc8)nc75)-c5ccccc5-c46)c3)n2)cc1 ; c1ccc(-c2nc(-c3ccccc3)nc(-c3ccc(-c4ccc5c6c(cc7sc(-c8ccccc8)nc75)-c5ccccc5-c46)c4ccccc34)n2)cc1]

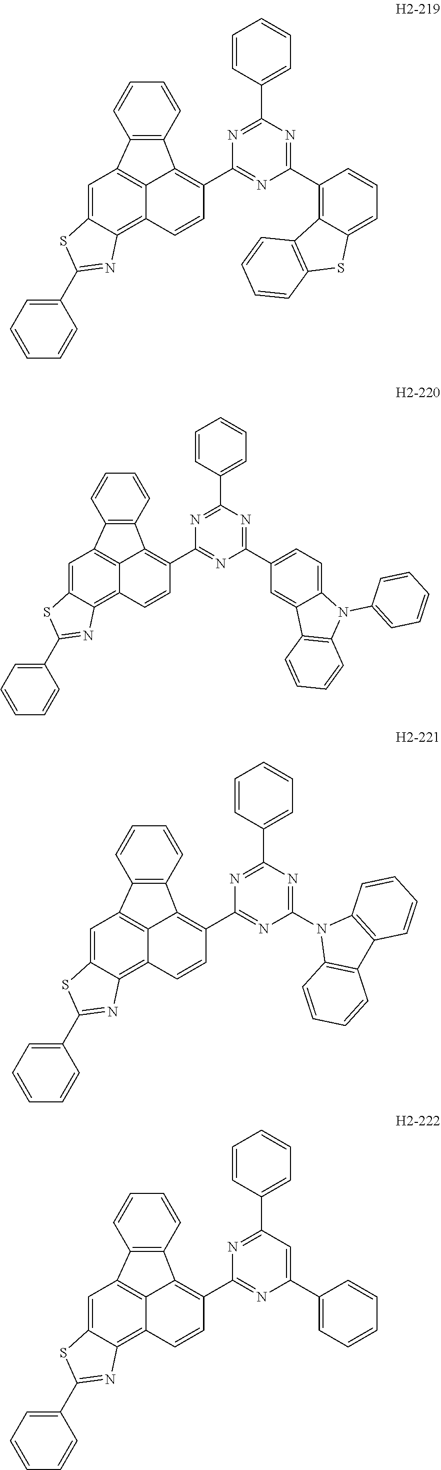 [SMILES: c1ccc(-c2nc(-c3ccc4c5c(cc6sc(-c7ccccc7)nc64)-c4ccccc4-c35)nc(-c3cccc4sc5ccccc5c34)n2)cc1 ; c1ccc(-c2nc(-c3ccc4c(c3)c3ccccc3n4-c3ccccc3)nc(-c3ccc4c5c(cc6sc(-c7ccccc7)nc64)-c4ccccc4-c35)n2)cc1 ; c1ccc(-c2nc(-c3ccc4c5c(cc6sc(-c7ccccc7)nc64)-c4ccccc4-c35)nc(-n3c4ccccc4c4ccccc43)n2)cc1 ; c1ccc(-c2cc(-c3ccccc3)nc(-c3ccc4c5c(cc6sc(-c7ccccc7)nc64)-c4ccccc4-c35)n2)cc1]

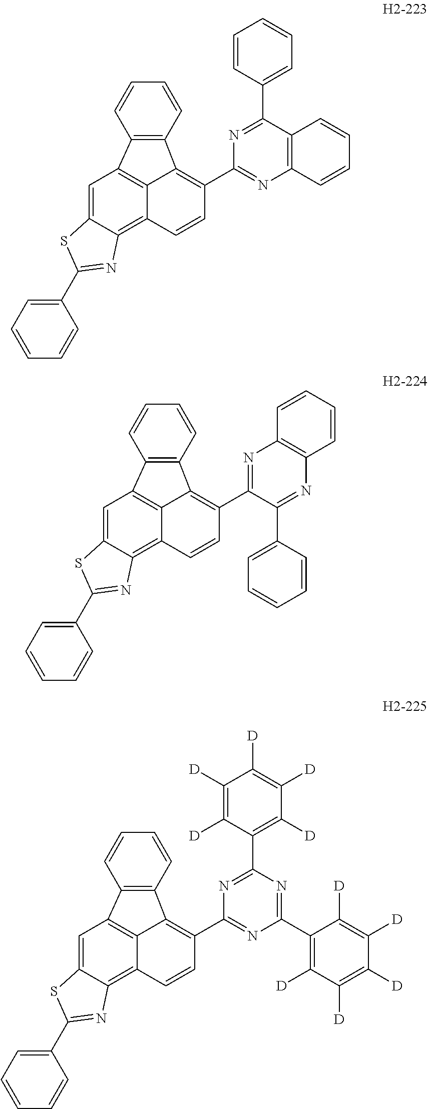 [SMILES: c1ccc(-c2nc3c(cc4c5c(c(-c6nc(-c7ccccc7)c7ccccc7n6)ccc53)-c3ccccc3-4)s2)cc1 ; c1ccc(-c2nc3c(cc4c5c(c(-c6nc7ccccc7nc6-c6ccccc6)ccc53)-c3ccccc3-4)s2)cc1 ; [2H]c1c([2H])c([2H])c(-c2nc(-c3ccc4c5c(cc6sc(-c7ccccc7)nc64)-c4ccccc4-c35)nc(-c3c([2H])c([2H])c([2H])c([2H])c3[2H])n2)c([2H])c1[2H]]

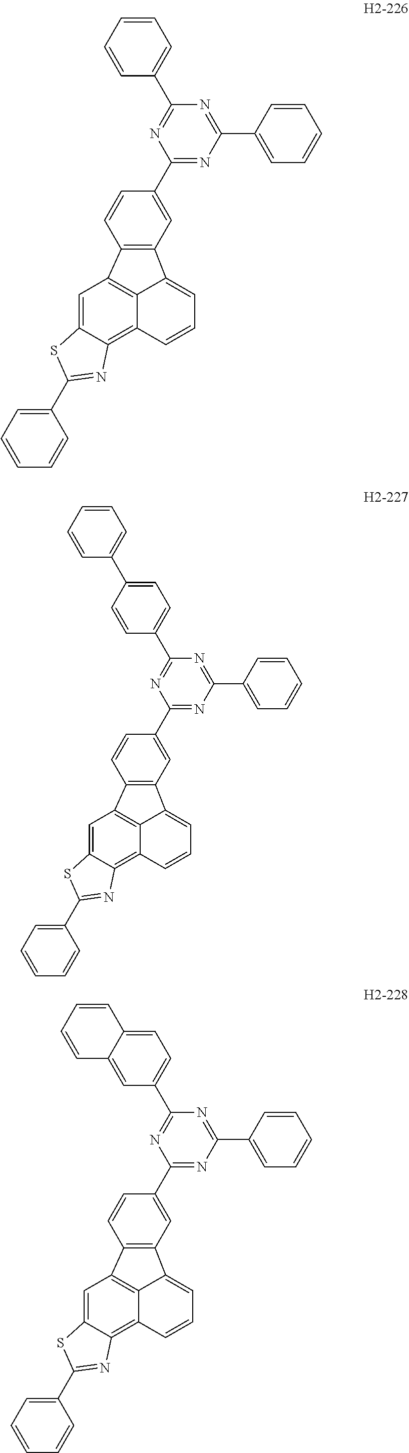

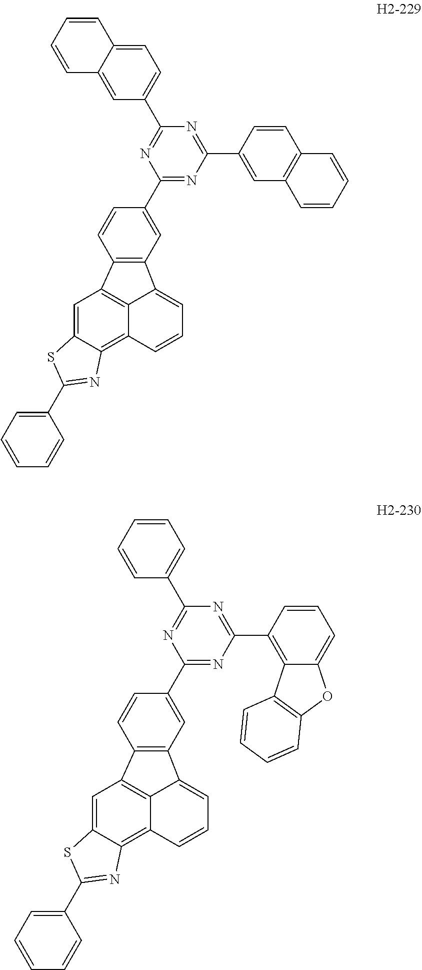 [SMILES: c1ccc(-c2nc3c(cc4c5c(cccc53)-c3cc(-c5nc(-c6ccc7ccccc7c6)nc(-c6ccc7ccccc7c6)n5)ccc3-4)s2)cc1 ; c1ccc(-c2nc(-c3ccc4c(c3)-c3cccc5c3c-4cc3sc(-c4ccccc4)nc35)nc(-c3cccc4oc5ccccc5c34)n2)cc1]

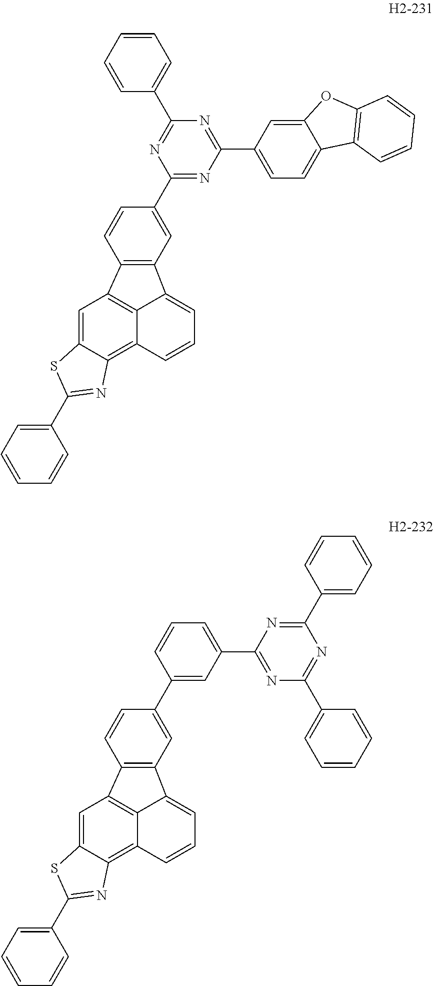 [SMILES: c1ccc(-c2nc(-c3ccc4c(c3)-c3cccc5c3c-4cc3sc(-c4ccccc4)nc35)nc(-c3ccc4c(c3)oc3ccccc34)n2)cc1 ; c1ccc(-c2nc(-c3ccccc3)nc(-c3cccc(-c4ccc5c(c4)-c4cccc6c4c-5cc4sc(-c5ccccc5)nc46)c3)n2)cc1]

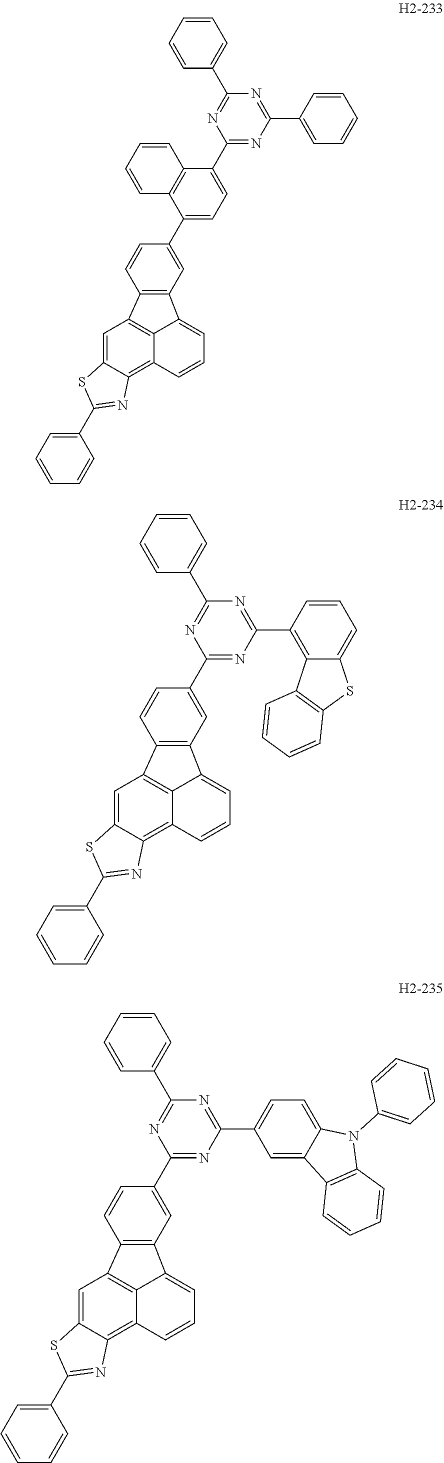 [SMILES: c1ccc(-c2nc(-c3ccccc3)nc(-c3ccc(-c4ccc5c(c4)-c4cccc6c4c-5cc4sc(-c5ccccc5)nc46)c4ccccc34)n2)cc1 ; c1ccc(-c2nc(-c3ccc4c(c3)-c3cccc5c3c-4cc3sc(-c4ccccc4)nc35)nc(-c3cccc4sc5ccccc5c34)n2)cc1 ; c1ccc(-c2nc(-c3ccc4c(c3)-c3cccc5c3c-4cc3sc(-c4ccccc4)nc35)nc(-c3ccc4c(c3)c3ccccc3n4-c3ccccc3)n2)cc1]

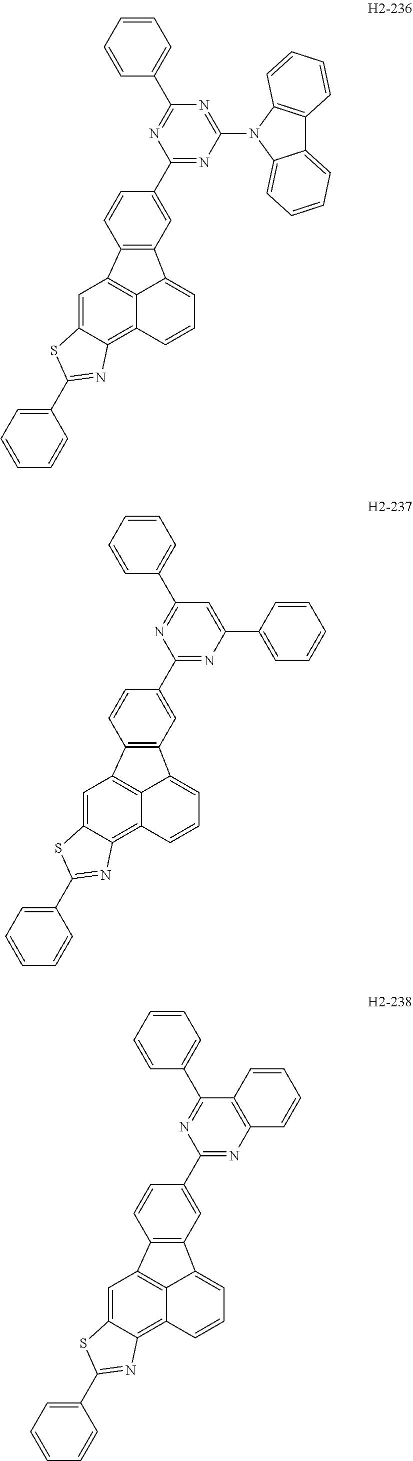 [SMILES: c1ccc(-c2nc(-c3ccc4c(c3)-c3cccc5c3c-4cc3sc(-c4ccccc4)nc35)nc(-n3c4ccccc4c4ccccc43)n2)cc1 ; c1ccc(-c2cc(-c3ccccc3)nc(-c3ccc4c(c3)-c3cccc5c3c-4cc3sc(-c4ccccc4)nc35)n2)cc1 ; c1ccc(-c2nc3c(cc4c5c(cccc53)-c3cc(-c5nc(-c6ccccc6)c6ccccc6n5)ccc3-4)s2)cc1]

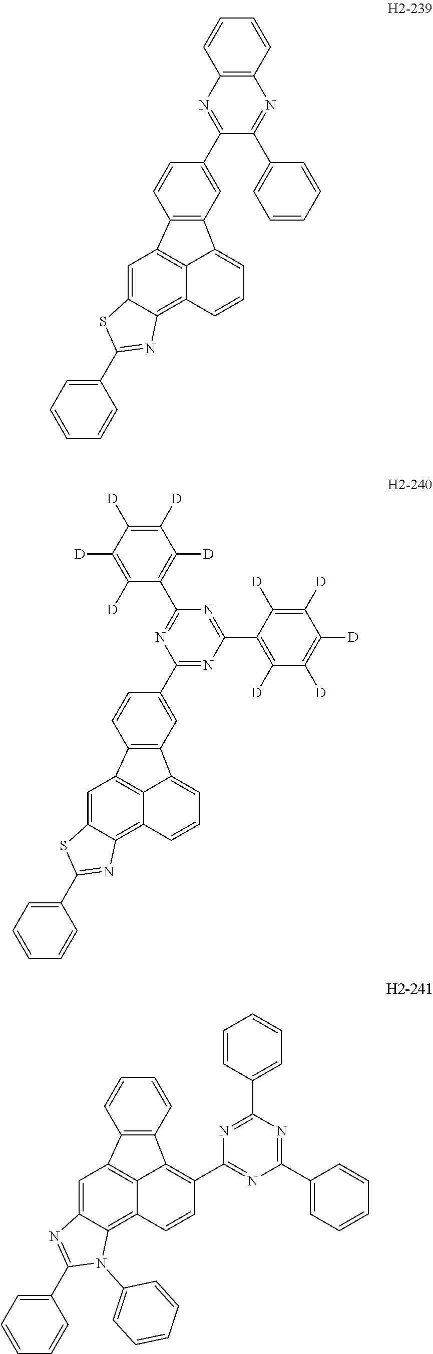 [SMILES: c1ccc(-c2nc3c(cc4c5c(cccc53)-c3cc(-c5nc6ccccc6nc5-c5ccccc5)ccc3-4)s2)cc1 ; [2H]c1c([2H])c([2H])c(-c2nc(-c3ccc4c(c3)-c3cccc5c3c-4cc3sc(-c4ccccc4)nc35)nc(-c3c([2H])c([2H])c([2H])c([2H])c3[2H])n2)c([2H])c1[2H] ; c1ccc(-c2nc(-c3ccccc3)nc(-c3ccc4c5c(cc6nc(-c7ccccc7)n(-c7ccccc7)c64)-c4ccccc4-c35)n2)cc1]

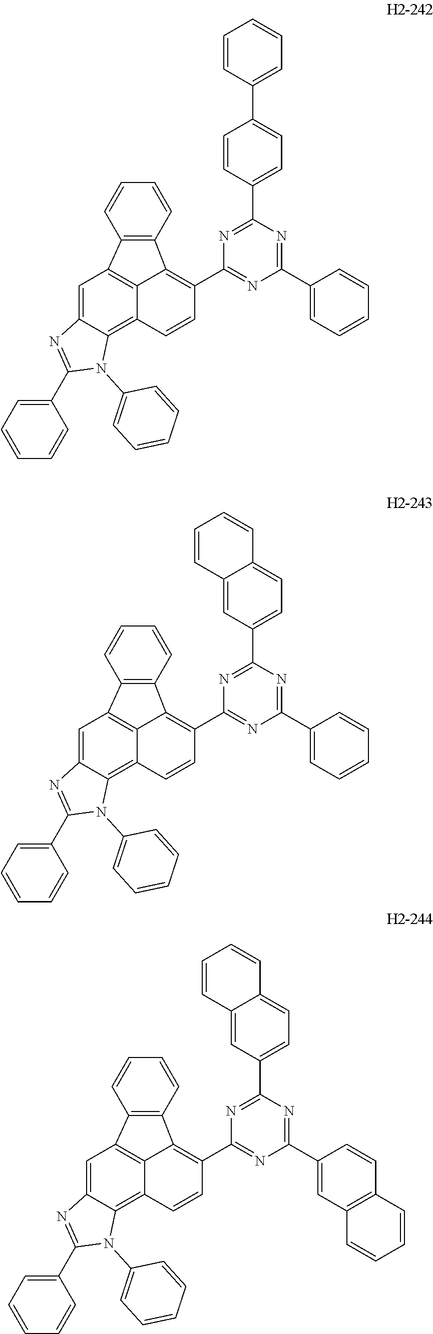 [SMILES: c1ccc(-c2ccc(-c3nc(-c4ccccc4)nc(-c4ccc5c6c(cc7nc(-c8ccccc8)n(-c8ccccc8)c75)-c5ccccc5-c46)n3)cc2)cc1 ; c1ccc(-c2nc(-c3ccc4ccccc4c3)nc(-c3ccc4c5c(cc6nc(-c7ccccc7)n(-c7ccccc7)c64)-c4ccccc4-c35)n2)cc1 ; c1ccc(-c2nc3cc4c5c(c(-c6nc(-c7ccc8ccccc8c7)nc(-c7ccc8ccccc8c7)n6)ccc5c3n2-c2ccccc2)-c2ccccc2-4)cc1]

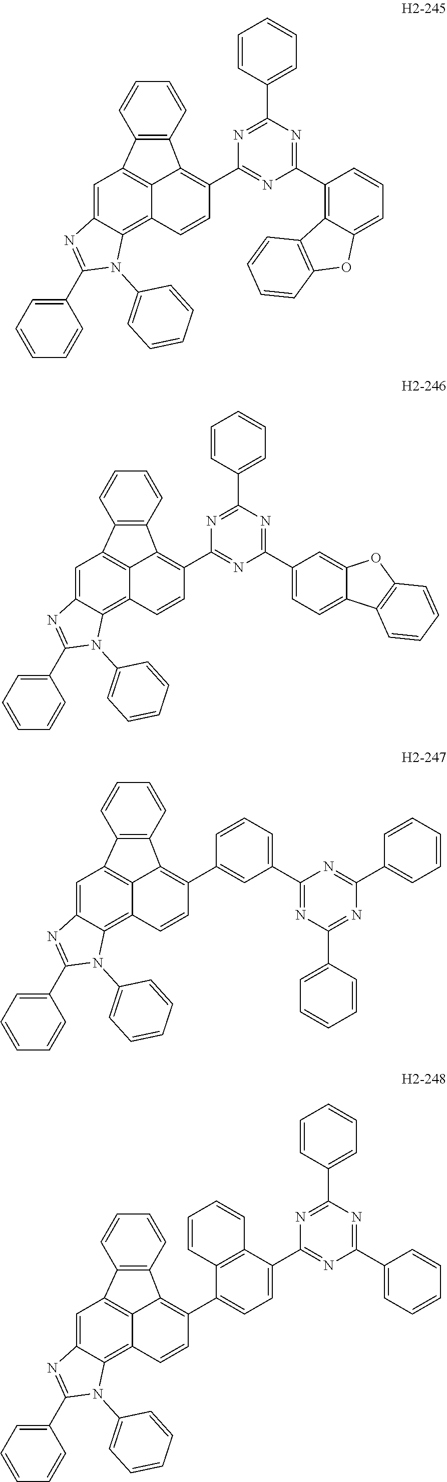 [SMILES: c1ccc(-c2nc(-c3ccc4c5c(cc6nc(-c7ccccc7)n(-c7ccccc7)c64)-c4ccccc4-c35)nc(-c3cccc4oc5ccccc5c34)n2)cc1 ; c1ccc(-c2nc(-c3ccc4c(c3)oc3ccccc34)nc(-c3ccc4c5c(cc6nc(-c7ccccc7)n(-c7ccccc7)c64)-c4ccccc4-c35)n2)cc1 ; c1ccc(-c2nc(-c3ccccc3)nc(-c3cccc(-c4ccc5c6c(cc7nc(-c8ccccc8)n(-c8ccccc8)c75)-c5ccccc5-c46)c3)n2)cc1 ; c1ccc(-c2nc(-c3ccccc3)nc(-c3ccc(-c4ccc5c6c(cc7nc(-c8ccccc8)n(-c8ccccc8)c75)-c5ccccc5-c46)c4ccccc34)n2)cc1]

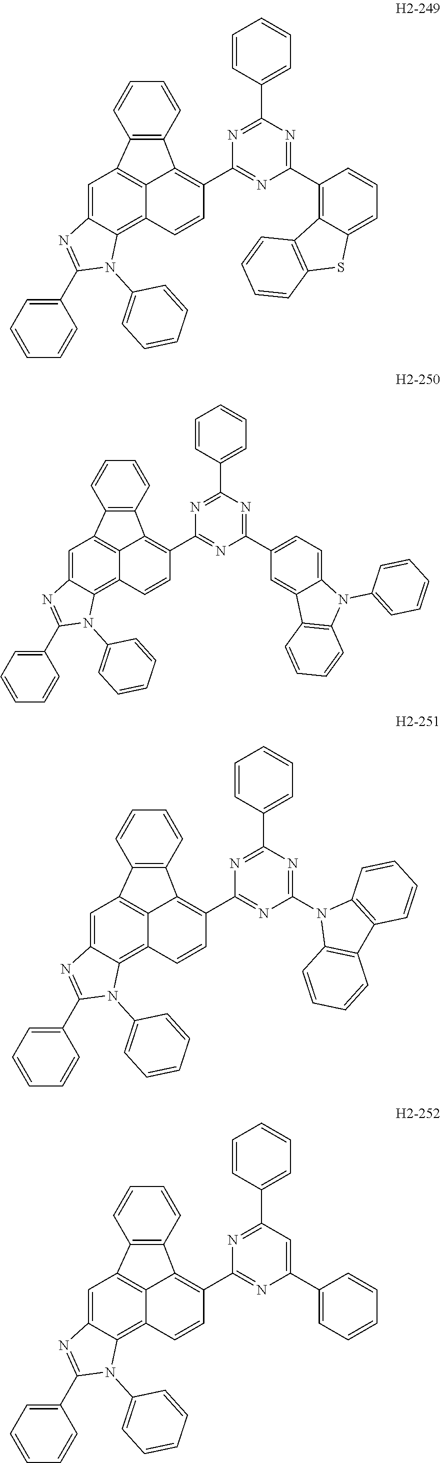 [SMILES: c1ccc(-c2nc(-c3ccc4c5c(cc6nc(-c7ccccc7)n(-c7ccccc7)c64)-c4ccccc4-c35)nc(-c3cccc4sc5ccccc5c34)n2)cc1 ; c1ccc(-c2nc(-c3ccc4c(c3)c3ccccc3n4-c3ccccc3)nc(-c3ccc4c5c(cc6nc(-c7ccccc7)n(-c7ccccc7)c64)-c4ccccc4-c35)n2)cc1 ; c1ccc(-c2nc(-c3ccc4c5c(cc6nc(-c7ccccc7)n(-c7ccccc7)c64)-c4ccccc4-c35)nc(-n3c4ccccc4c4ccccc43)n2)cc1 ; c1ccc(-c2cc(-c3ccccc3)nc(-c3ccc4c5c(cc6nc(-c7ccccc7)n(-c7ccccc7)c64)-c4ccccc4-c35)n2)cc1]

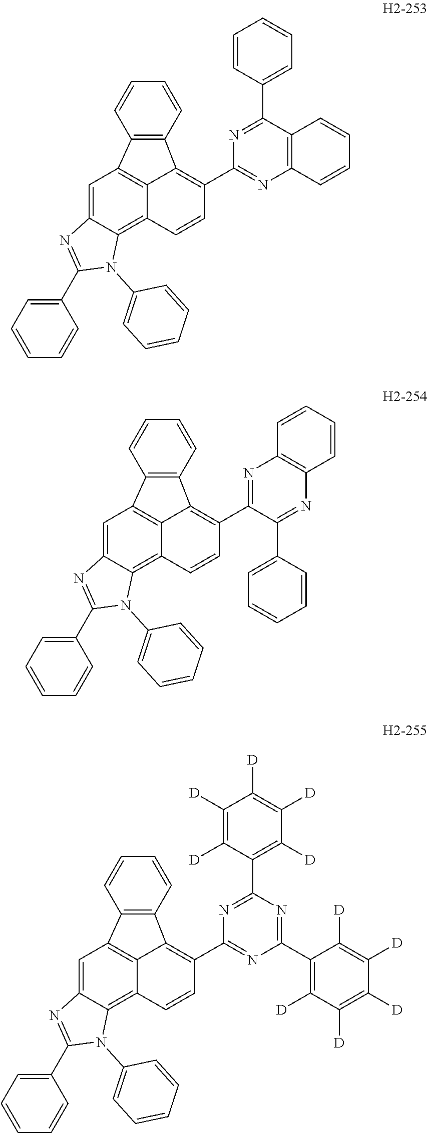 [SMILES: c1ccc(-c2nc(-c3ccc4c5c(cc6nc(-c7ccccc7)n(-c7ccccc7)c64)-c4ccccc4-c35)nc3ccccc23)cc1 ; c1ccc(-c2nc3ccccc3nc2-c2ccc3c4c(cc5nc(-c6ccccc6)n(-c6ccccc6)c53)-c3ccccc3-c24)cc1 ; [2H]c1c([2H])c([2H])c(-c2nc(-c3ccc4c5c(cc6nc(-c7ccccc7)n(-c7ccccc7)c64)-c4ccccc4-c35)nc(-c3c([2H])c([2H])c([2H])c([2H])c3[2H])n2)c([2H])c1[2H]]

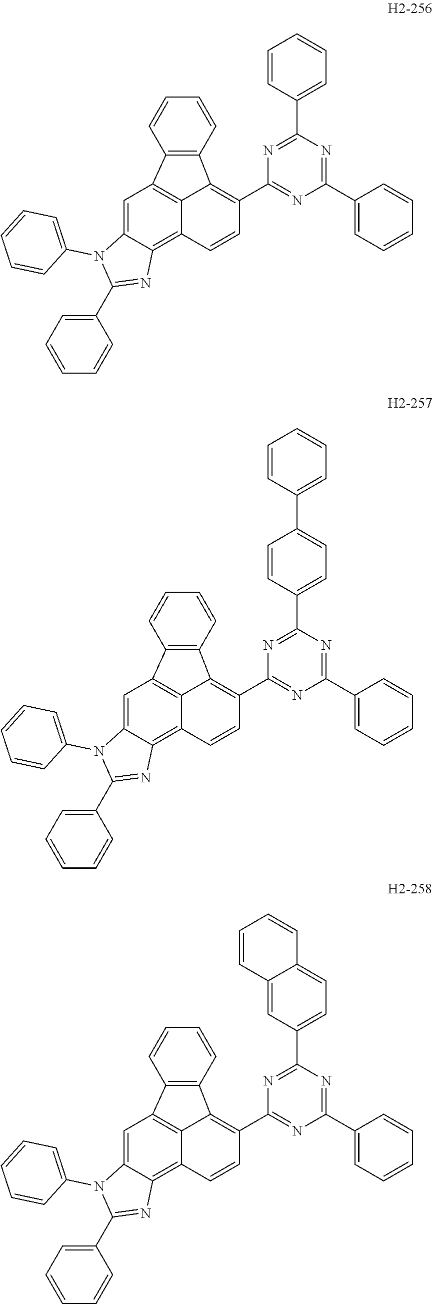 [SMILES: c1ccc(-c2nc(-c3ccccc3)nc(-c3ccc4c5c(cc6c4nc(-c4ccccc4)n6-c4ccccc4)-c4ccccc4-c35)n2)cc1 ; c1ccc(-c2ccc(-c3nc(-c4ccccc4)nc(-c4ccc5c6c(cc7c5nc(-c5ccccc5)n7-c5ccccc5)-c5ccccc5-c46)n3)cc2)cc1 ; c1ccc(-c2nc(-c3ccc4ccccc4c3)nc(-c3ccc4c5c(cc6c4nc(-c4ccccc4)n6-c4ccccc4)-c4ccccc4-c35)n2)cc1]

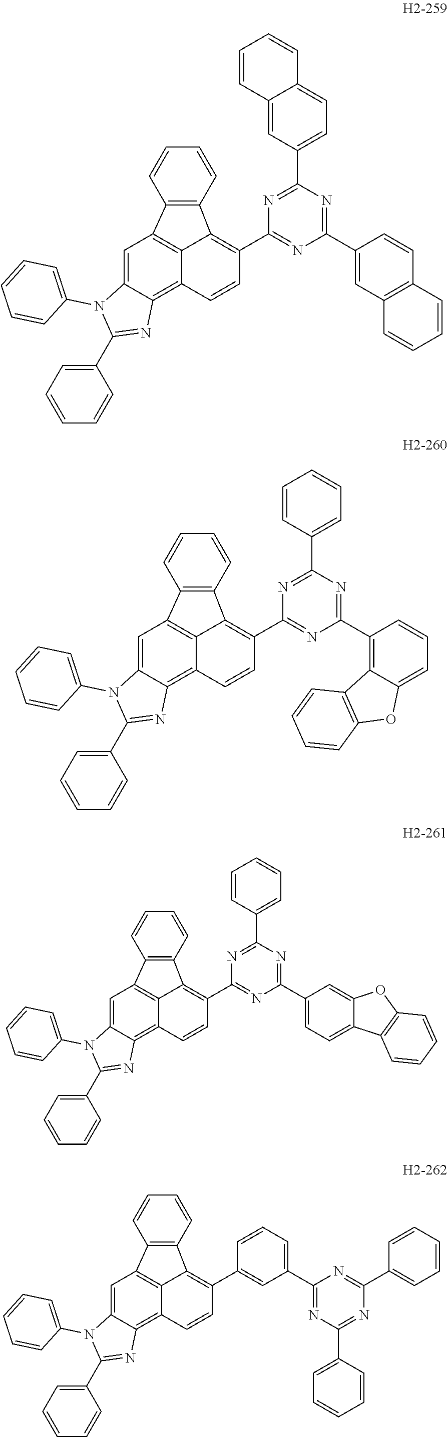 [SMILES: c1ccc(-c2nc3c4ccc(-c5nc(-c6ccc7ccccc7c6)nc(-c6ccc7ccccc7c6)n5)c5c4c(cc3n2-c2ccccc2)-c2ccccc2-5)cc1 ; c1ccc(-c2nc(-c3ccc4c5c(cc6c4nc(-c4ccccc4)n6-c4ccccc4)-c4ccccc4-c35)nc(-c3cccc4oc5ccccc5c34)n2)cc1 ; c1ccc(-c2nc(-c3ccc4c(c3)oc3ccccc34)nc(-c3ccc4c5c(cc6c4nc(-c4ccccc4)n6-c4ccccc4)-c4ccccc4-c35)n2)cc1 ; c1ccc(-c2nc(-c3ccccc3)nc(-c3cccc(-c4ccc5c6c(cc7c5nc(-c5ccccc5)n7-c5ccccc5)-c5ccccc5-c46)c3)n2)cc1]

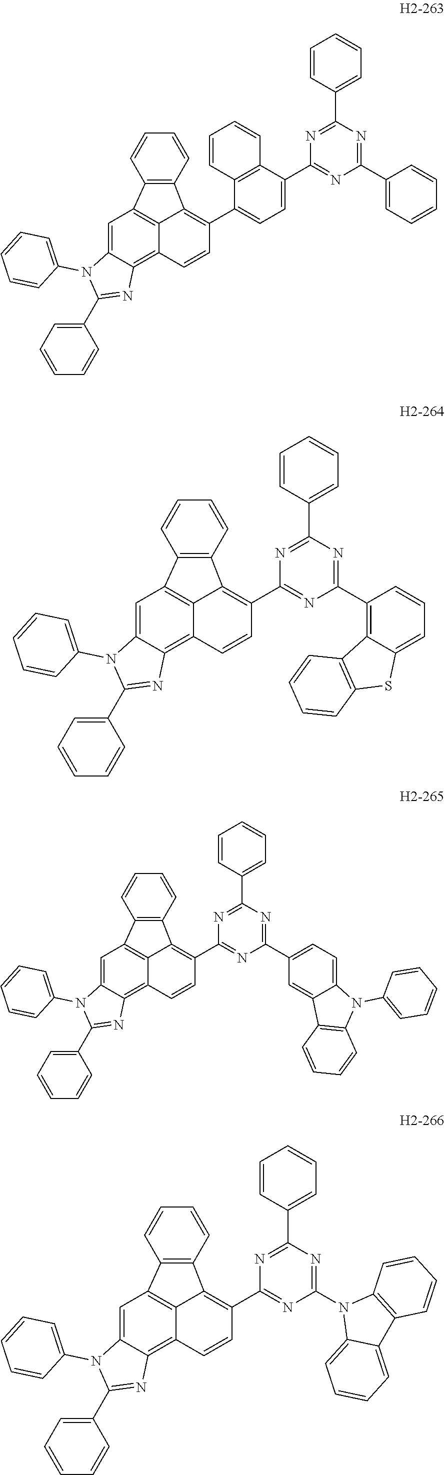 [SMILES: c1ccc(-c2nc(-c3ccccc3)nc(-c3ccc(-c4ccc5c6c(cc7c5nc(-c5ccccc5)n7-c5ccccc5)-c5ccccc5-c46)c4ccccc34)n2)cc1 ; c1ccc(-c2nc(-c3ccc4c5c(cc6c4nc(-c4ccccc4)n6-c4ccccc4)-c4ccccc4-c35)nc(-c3cccc4sc5ccccc5c34)n2)cc1 ; c1ccc(-c2nc(-c3ccc4c(c3)c3ccccc3n4-c3ccccc3)nc(-c3ccc4c5c(cc6c4nc(-c4ccccc4)n6-c4ccccc4)-c4ccccc4-c35)n2)cc1 ; c1ccc(-c2nc(-c3ccc4c5c(cc6c4nc(-c4ccccc4)n6-c4ccccc4)-c4ccccc4-c35)nc(-n3c4ccccc4c4ccccc43)n2)cc1]

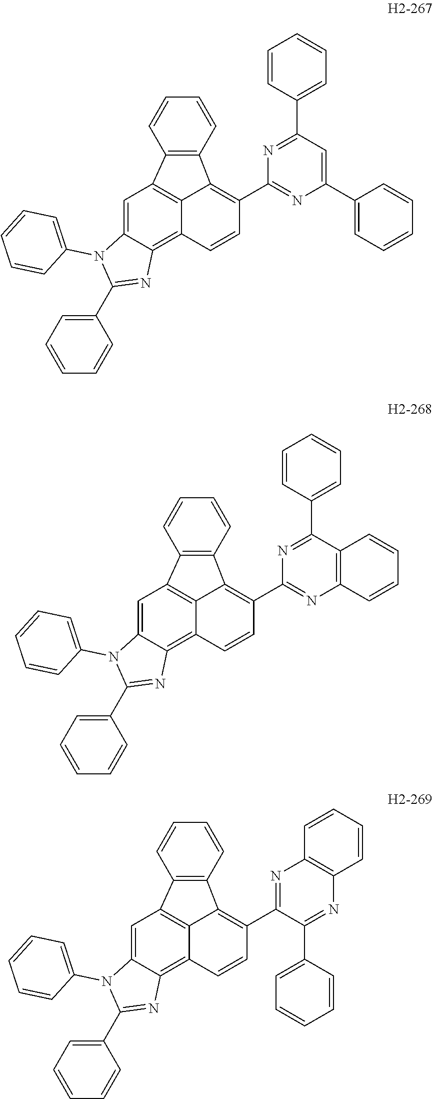 [SMILES: c1ccc(-c2cc(-c3ccccc3)nc(-c3ccc4c5c(cc6c4nc(-c4ccccc4)n6-c4ccccc4)-c4ccccc4-c35)n2)cc1 ; c1ccc(-c2nc(-c3ccc4c5c(cc6c4nc(-c4ccccc4)n6-c4ccccc4)-c4ccccc4-c35)nc3ccccc23)cc1 ; c1ccc(-c2nc3ccccc3nc2-c2ccc3c4c(cc5c3nc(-c3ccccc3)n5-c3ccccc3)-c3ccccc3-c24)cc1]

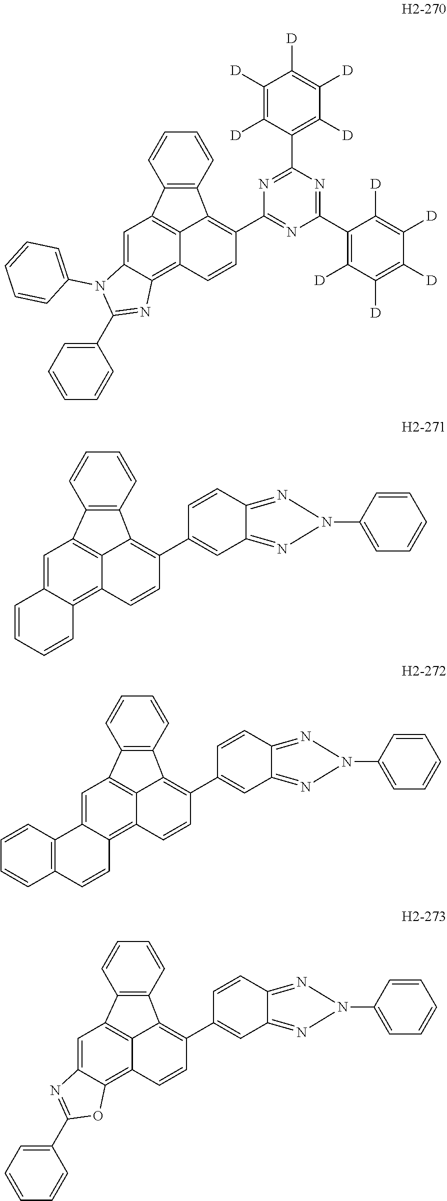 [SMILES: [2H]c1c([2H])c([2H])c(-c2nc(-c3ccc4c5c(cc6c4nc(-c4ccccc4)n6-c4ccccc4)-c4ccccc4-c35)nc(-c3c([2H])c([2H])c([2H])c([2H])c3[2H])n2)c([2H])c1[2H] ; c1ccc(-n2nc3ccc(-c4ccc5c6c(cc7ccccc75)-c5ccccc5-c46)cc3n2)cc1 ; c1ccc(-n2nc3ccc(-c4ccc5c6c(cc7c8ccccc8ccc57)-c5ccccc5-c46)cc3n2)cc1 ; c1ccc(-c2nc3cc4c5c(c(-c6ccc7nn(-c8ccccc8)nc7c6)ccc5c3o2)-c2ccccc2-4)cc1]

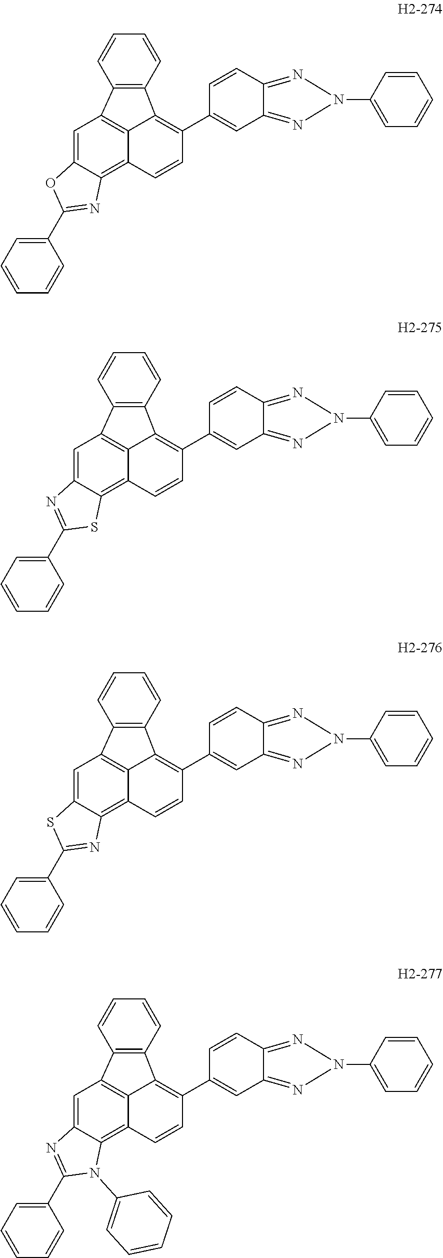 [SMILES: c1ccc(-c2nc3c(cc4c5c(c(-c6ccc7nn(-c8ccccc8)nc7c6)ccc53)-c3ccccc3-4)o2)cc1 ; c1ccc(-c2nc3cc4c5c(c(-c6ccc7nn(-c8ccccc8)nc7c6)ccc5c3s2)-c2ccccc2-4)cc1 ; c1ccc(-c2nc3c(cc4c5c(c(-c6ccc7nn(-c8ccccc8)nc7c6)ccc53)-c3ccccc3-4)s2)cc1 ; c1ccc(-c2nc3cc4c5c(c(-c6ccc7nn(-c8ccccc8)nc7c6)ccc5c3n2-c2ccccc2)-c2ccccc2-4)cc1]

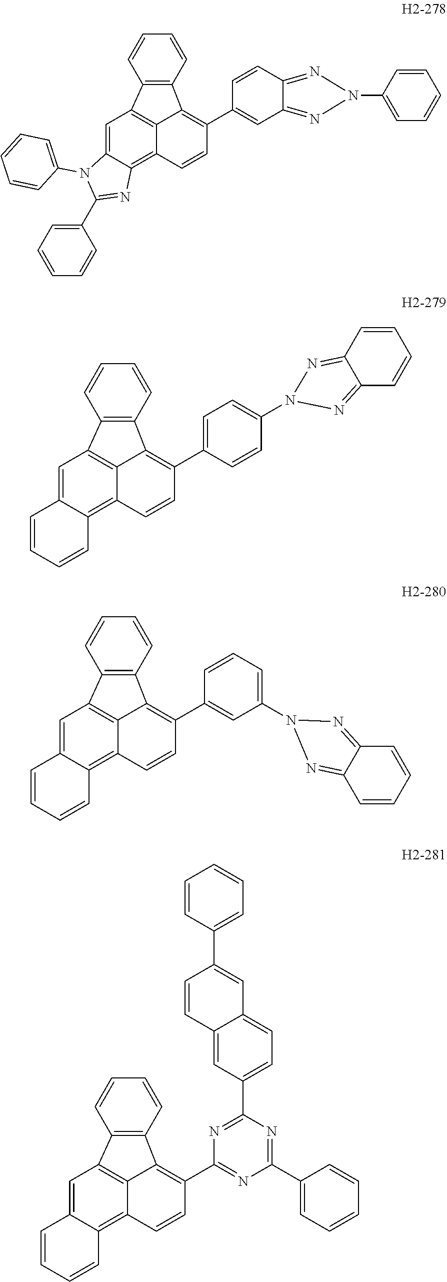 [SMILES: c1ccc(-c2nc3c4ccc(-c5ccc6nn(-c7ccccc7)nc6c5)c5c4c(cc3n2-c2ccccc2)-c2ccccc2-5)cc1 ; c1ccc2c(c1)-c1cc3ccccc3c3ccc(-c4ccc(-n5nc6ccccc6n5)cc4)c-2c13 ; c1cc(-c2ccc3c4c(cc5ccccc53)-c3ccccc3-c24)cc(-n2nc3ccccc3n2)c1 ; c1ccc(-c2ccc3cc(-c4nc(-c5ccccc5)nc(-c5ccc6c7c(cc8ccccc86)-c6ccccc6-c57)n4)ccc3c2)cc1]

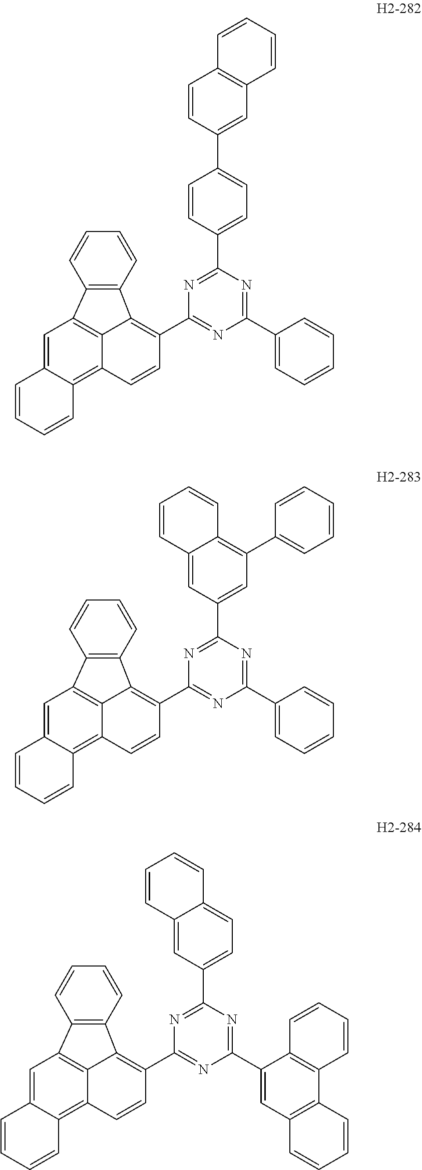 [SMILES: c1ccc(-c2nc(-c3ccc(-c4ccc5ccccc5c4)cc3)nc(-c3ccc4c5c(cc6ccccc64)-c4ccccc4-c35)n2)cc1 ; c1ccc(-c2nc(-c3cc(-c4ccccc4)c4ccccc4c3)nc(-c3ccc4c5c(cc6ccccc64)-c4ccccc4-c35)n2)cc1 ; c1ccc2c(c1)-c1cc3ccccc3c3ccc(-c4nc(-c5ccc6ccccc6c5)nc(-c5cc6ccccc6c6ccccc56)n4)c-2c13]

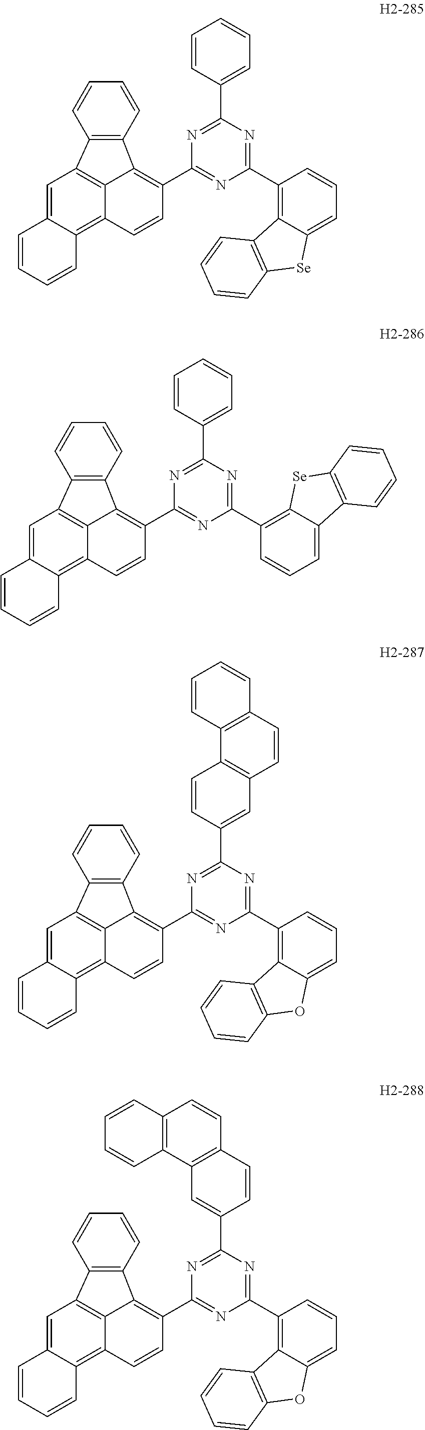 [SMILES: c1ccc(-c2nc(-c3ccc4c5c(cc6ccccc64)-c4ccccc4-c35)nc(-c3cccc4[se]c5ccccc5c34)n2)cc1 ; c1ccc(-c2nc(-c3ccc4c5c(cc6ccccc64)-c4ccccc4-c35)nc(-c3cccc4c3[se]c3ccccc34)n2)cc1 ; c1ccc2c(c1)-c1cc3ccccc3c3ccc(-c4nc(-c5ccc6c(ccc7ccccc76)c5)nc(-c5cccc6oc7ccccc7c56)n4)c-2c13 ; c1ccc2c(c1)-c1cc3ccccc3c3ccc(-c4nc(-c5ccc6ccc7ccccc7c6c5)nc(-c5cccc6oc7ccccc7c56)n4)c-2c13]

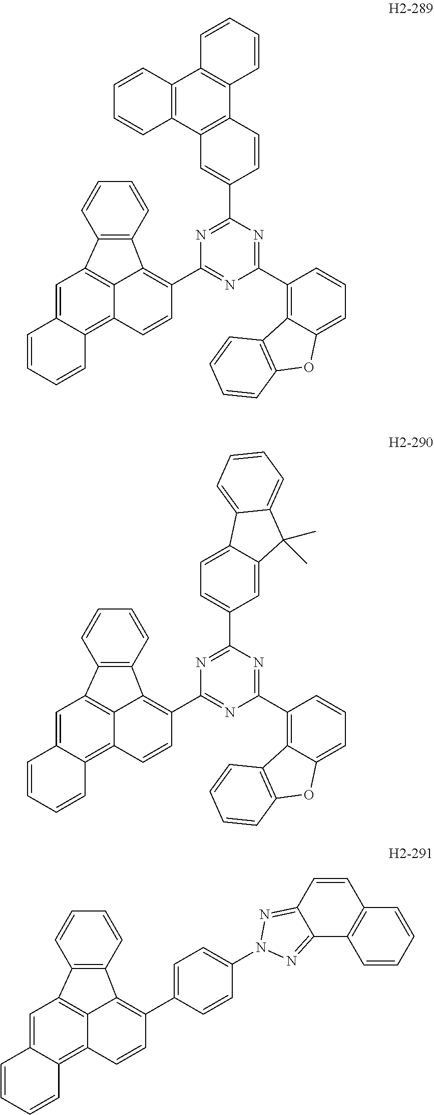 [SMILES: c1ccc2c(c1)-c1cc3ccccc3c3ccc(-c4nc(-c5ccc6c7ccccc7c7ccccc7c6c5)nc(-c5cccc6oc7ccccc7c56)n4)c-2c13 ; CC1(C)c2ccccc2-c2ccc(-c3nc(-c4ccc5c6c(cc7ccccc75)-c5ccccc5-c46)nc(-c4cccc5oc6ccccc6c45)n3)cc21 ; c1ccc2c(c1)-c1cc3ccccc3c3ccc(-c4ccc(-n5nc6ccc7ccccc7c6n5)cc4)c-2c13]

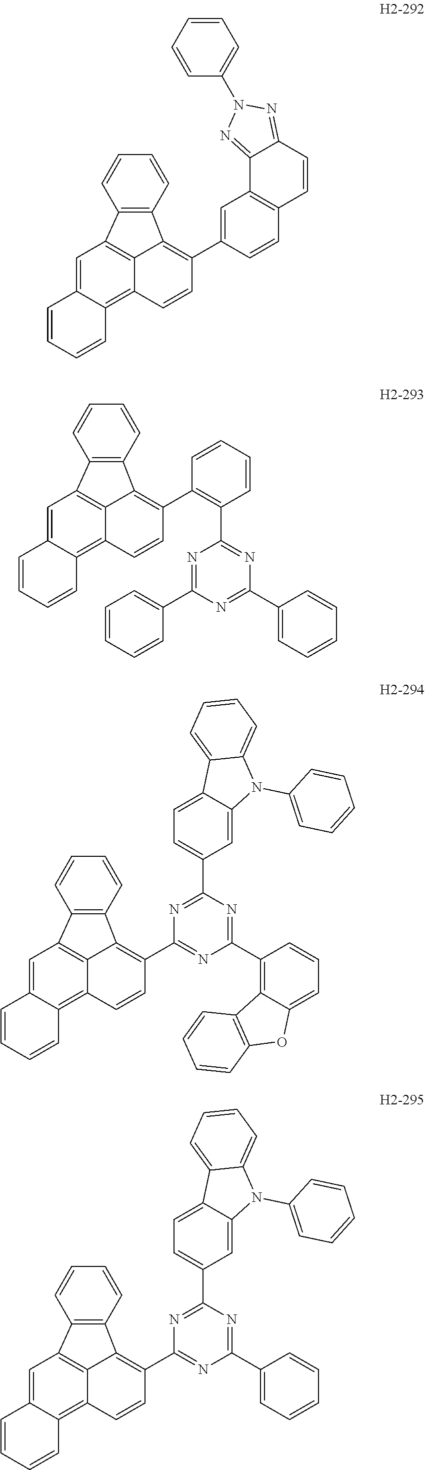

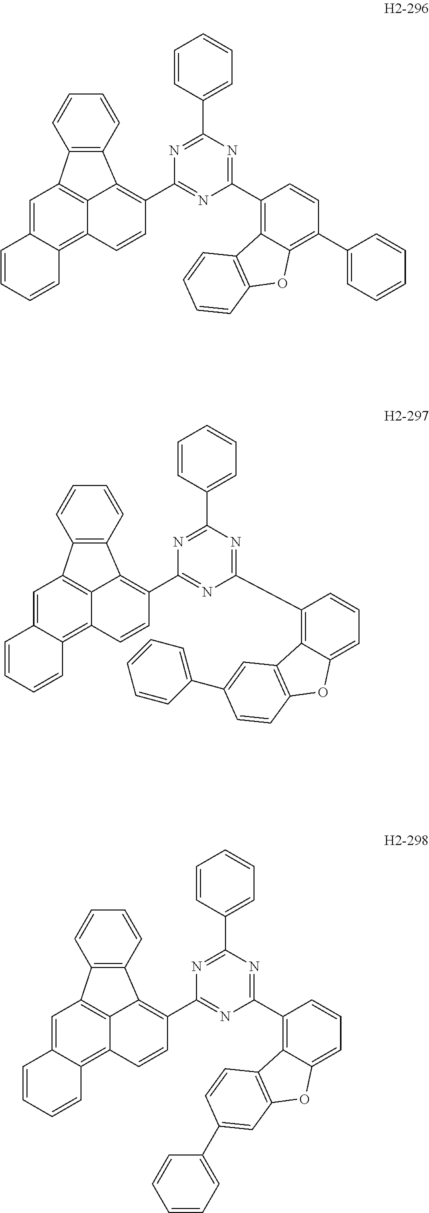 [SMILES: c1ccc(-c2nc(-c3ccc4c5c(cc6ccccc64)-c4ccccc4-c35)nc(-c3ccc(-c4ccccc4)c4oc5ccccc5c34)n2)cc1 ; c1ccc(-c2ccc3oc4cccc(-c5nc(-c6ccccc6)nc(-c6ccc7c8c(cc9ccccc97)-c7ccccc7-c68)n5)c4c3c2)cc1 ; c1ccc(-c2ccc3c(c2)oc2cccc(-c4nc(-c5ccccc5)nc(-c5ccc6c7c(cc8ccccc86)-c6ccccc6-c57)n4)c23)cc1]

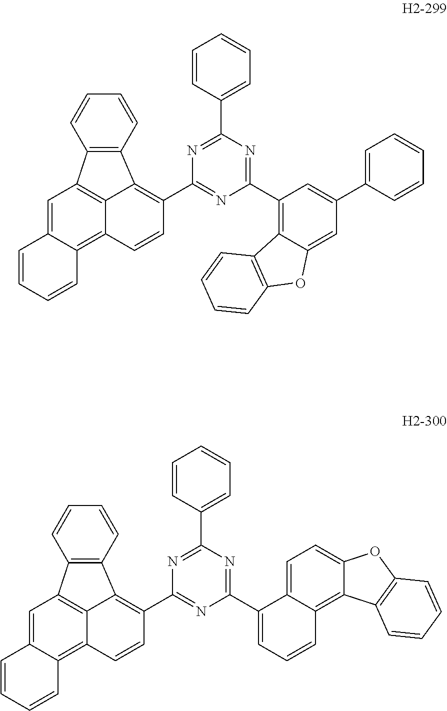 [SMILES: c1ccc(-c2cc(-c3nc(-c4ccccc4)nc(-c4ccc5c6c(cc7ccccc75)-c5ccccc5-c46)n3)c3c(c2)oc2ccccc23)cc1 ; c1ccc(-c2nc(-c3ccc4c5c(cc6ccccc64)-c4ccccc4-c35)nc(-c3cccc4c3ccc3oc5ccccc5c34)n2)cc1]

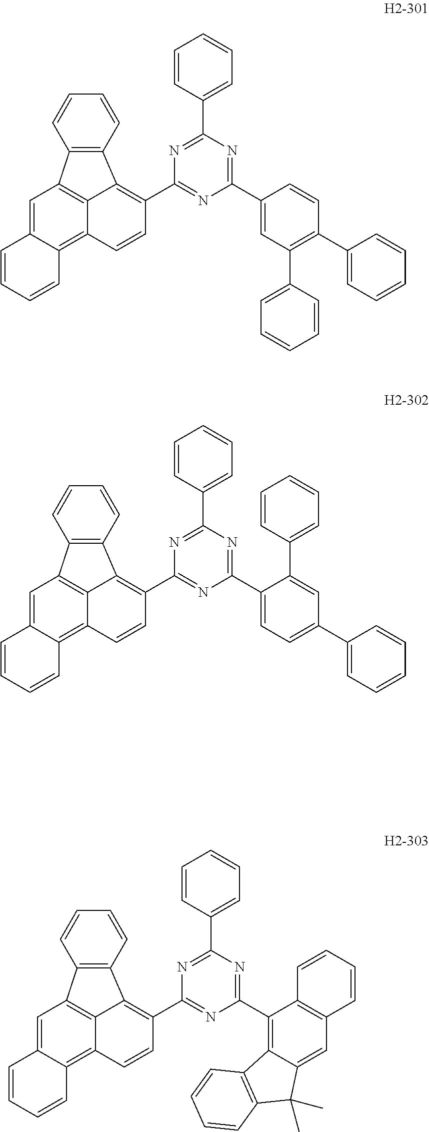 [SMILES: c1ccc(-c2nc(-c3ccc(-c4ccccc4)c(-c4ccccc4)c3)nc(-c3ccc4c5c(cc6ccccc64)-c4ccccc4-c35)n2)cc1 ; c1ccc(-c2ccc(-c3nc(-c4ccccc4)nc(-c4ccc5c6c(cc7ccccc75)-c5ccccc5-c46)n3)c(-c3ccccc3)c2)cc1 ; CC1(C)c2ccccc2-c2c1cc1ccccc1c2-c1nc(-c2ccccc2)nc(-c2ccc3c4c(cc5ccccc53)-c3ccccc3-c24)n1]

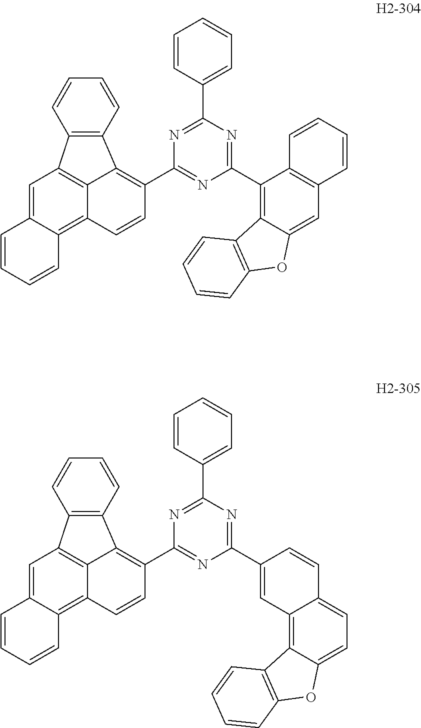 [SMILES: c1ccc(-c2nc(-c3ccc4c5c(cc6ccccc64)-c4ccccc4-c35)nc(-c3c4ccccc4cc4oc5ccccc5c34)n2)cc1 ; c1ccc(-c2nc(-c3ccc4ccc5oc6ccccc6c5c4c3)nc(-c3ccc4c5c(cc6ccccc64)-c4ccccc4-c35)n2)cc1]

The present disclosure provides an organic electroluminescent device comprising an organic electroluminescent compound represented by Formula 1.

The organic electroluminescent compound represented Formula 1 of the present disclosure may be comprised in at least one layer selected from a light-emitting layer, a hole injection layer, a hole transport layer, a hole auxiliary layer, a light-emitting auxiliary layer, an electron transport layer, an electron buffer layer, an electron injection layer, an interlayer, a hole-blocking layer, and an electron-blocking layer, and may be preferably comprised in the light-emitting layer (host material), the electron transport layer, or the electron buffer layer.

According to another embodiment of the present disclosure, an organic electroluminescent material comprising a compound represented by above Formula 1 and a compound represented by the following Formula 2 is provided.

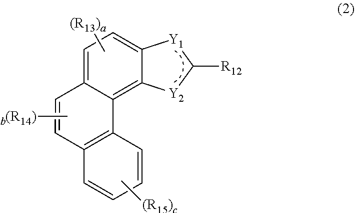

In Formula 2,

Y₁ and Y₂ each independently represent —N═, —NR₁₆—, —O—, or —S—, with a proviso that any one of Y₁ and Y₂ represents —N═, and the other of Y₁ and Y₂ represents —NR₁₆—, —O—, or —S—. For example, either Y₁ or Y₂ may be —N═, and the other of Y₁ or Y₂ may be —O— or —S—.

R₁₂ represents a substituted or unsubstituted (C6-C30)aryl, or a substituted or unsubstituted (3- to 30-membered)heteroaryl. According to one embodiment of the present disclosure, R₁₂ represents a substituted or unsubstituted (C6-C25)aryl, or a substituted or unsubstituted (3- to 25-membered)heteroaryl. According to another embodiment of the present disclosure, R₁₂ represents a substituted or unsubstituted (C6-C25)aryl. For example, R₁₂ may represent a phenyl, a biphenyl, a naphthyl, or a phenanthrenyl.

R₁₃ to R₁₆ each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring group of a (C3-C30) aliphatic ring(s) and a (C6-C30) aromatic ring(s), or -L₁-N(Ar₁)(Ar₂); or may be linked to an adjacent substituent(s) to form a ring(s); with a proviso that at least one of R₁₃ to R₁₅ is -L₁-N(Ar₁)(Ar₂). According to one embodiment of the present disclosure, R₁₃ to R₁₆ each independently represent hydrogen, deuterium, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted fused ring group of a (C3-C30) aliphatic ring(s) and a (C6-C30) aromatic ring(s), or -L₁-N(Ar₁)(Ar₂); or may be linked to an adjacent substituent(s) to form a ring(s); with a proviso that at least one of R₁₃ to R₁₅ is -L₁-N(Ar₁)(Ar₂). According to another embodiment of the present disclosure, R₁₃ to R₁₆ each independently represent hydrogen, deuterium, a substituted or unsubstituted (C1-C20)alkyl, a substituted or unsubstituted (C6-C20)aryl, a substituted or unsubstituted (3- to 20-membered)heteroaryl, a substituted or unsubstituted fused ring group of a (C3-C30) aliphatic ring(s) and a (C6-C30) aromatic ring(s), or -L₁-N(Ar₁)(Ar₂); or may be linked to an adjacent substituent(s) to form a ring(s); with a proviso that at least one of R₁₃ to R₁₅ is -L₁-N(Ar₁)(Ar₂). For example, R₁₃ to R₁₆ each independently represent hydrogen, a phenyl, or -L₁-N(Ar₁)(Ar₂), or may be linked to an adjacent substituent(s) to form a benzene ring(s); with a proviso that at least one of R₁₃ to R₁₅ is -L₁-N(Ar₁)(Ar₂).

Ar₁ and Ar₂ each independently represent a substituted or unsubstituted (C6-C30)aryl, a substituted or unsubstituted (3- to 30-membered)heteroaryl, or a substituted or unsubstituted fused ring group of a (C3-C30) aliphatic ring(s) and a (C6-C30) aromatic ring(s). According to one embodiment of the present disclosure, Ar₁ and Ar₂ each independently represent a substituted or unsubstituted (C6-C25)aryl, a substituted or unsubstituted (3- to 25-membered)heteroaryl, or a substituted or unsubstituted fused ring group of a (C3-C25) aliphatic ring(s) and a (C6-C25) aromatic ring(s). For example, Ar₁ and Ar₂ each independently may be a benzonaphthofuranyl, a benzothiophenyl, a dibenzofuranyl, a dibenzofuranyl substituted with a phenyl(s), a dibenzothiophenyl, a dimethylbenzofluorenyl, a dimethylfluorenyl, a diphenylfluorenyl, a naphthyl, a naphthyl substituted with phenyl(s), a phenyl, a phenyl substituted with an anthracenyl(s), a phenyl substituted with a benzoimidazolyl(s) substituted with a phenyl(s), a phenyl substituted with a naphthyl(s), a phenyl substituted with a pyridinyl(s) substituted with a phenyl(s), a phenyl substituted with a diphenylamino(s), a phenyl substituted with a xylene(s), a phenyl substituted with a phenyl(s) substituted with deuterium, a phenyl substituted with a cyclohexane(s), a phenyl substituted with a fluoranthenyl(s), a phenyl substituted with a phenoxazinyl(s), a phenyl substituted with a t-butylphenyl(s), a biphenyl, a terphenyl, a quaterphenyl, a benzonaphthothiophenyl, a carbazolyl substituted with a phenyl(s), a phenanthrenyl, a spirobifluorenyl, a dihydrophenanthrenyl substituted with a methyl(s), or a (C22)aryl.

L₁ represents a single bond, a substituted or unsubstituted (C6-C30)arylene, or a substituted or unsubstituted (3- to 30-membered)heteroarylene. According to one embodiment of the present disclosure, L₁ represents a single bond, or a substituted or unsubstituted (C6-C30)arylene. According to another embodiment of the present disclosure, L₁ represents a single bond, or a substituted or unsubstituted (C6-C20)arylene. For example, L₁ may be a single bond or a phenylene.

In Formula 2, a and b each independently represent an integer of 1 or 2, and c represents an integer of 1 to 4, where if a to c are an integer of 2 or more, each of R₁₃ to each of R₁₅ may be the same as or different from each other.

According to one embodiment of the present disclosure, the compound represented by Formula 2 may be more specifically exemplified as the following compounds but is not limited thereto.

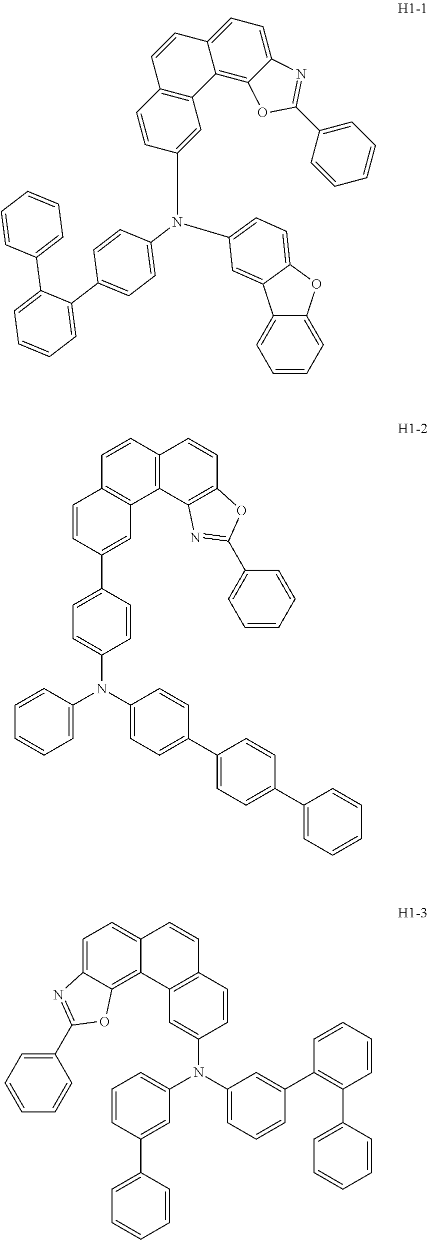 [SMILES: c1ccc(-c2nc3ccc4ccc5ccc(N(c6ccc(-c7ccccc7-c7ccccc7)cc6)c6ccc7oc8ccccc8c7c6)cc5c4c3o2)cc1 ; c1ccc(-c2ccc(-c3ccc(N(c4ccccc4)c4ccc(-c5ccc6ccc7ccc8oc(-c9ccccc9)nc8c7c6c5)cc4)cc3)cc2)cc1 ; c1ccc(-c2cccc(N(c3cccc(-c4ccccc4-c4ccccc4)c3)c3ccc4ccc5ccc6nc(-c7ccccc7)oc6c5c4c3)c2)cc1]

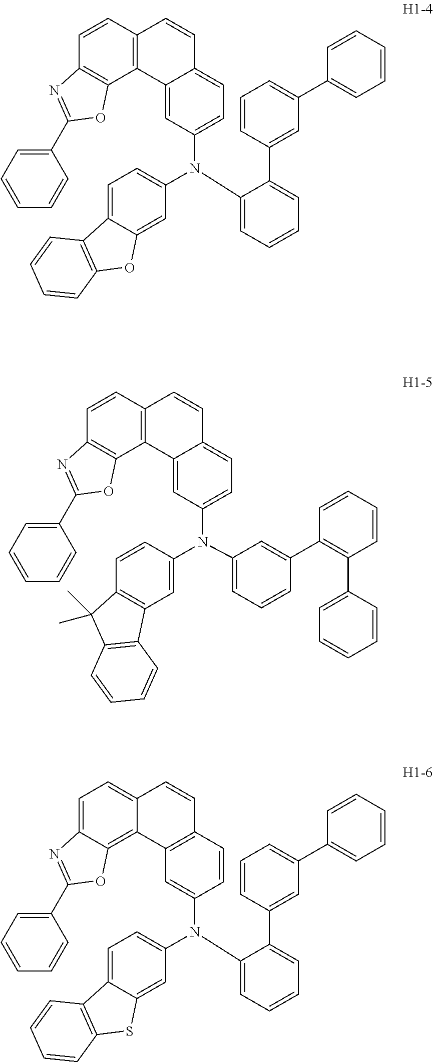 [SMILES: c1ccc(-c2cccc(-c3ccccc3N(c3ccc4c(c3)oc3ccccc34)c3ccc4ccc5ccc6nc(-c7ccccc7)oc6c5c4c3)c2)cc1 ; CC1(C)c2ccccc2-c2cc(N(c3cccc(-c4ccccc4-c4ccccc4)c3)c3ccc4ccc5ccc6nc(-c7ccccc7)oc6c5c4c3)ccc21 ; c1ccc(-c2cccc(-c3ccccc3N(c3ccc4c(c3)sc3ccccc34)c3ccc4ccc5ccc6nc(-c7ccccc7)oc6c5c4c3)c2)cc1]

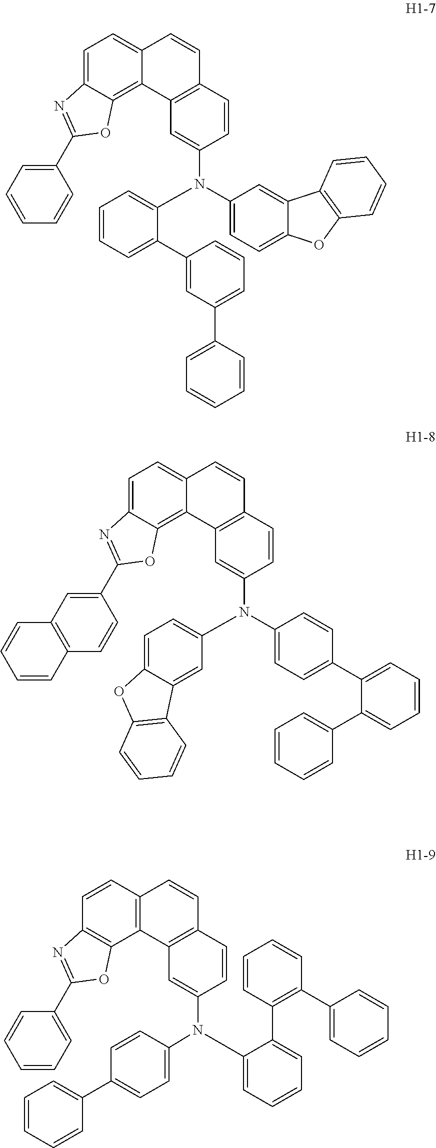 [SMILES: c1ccc(-c2cccc(-c3ccccc3N(c3ccc4oc5ccccc5c4c3)c3ccc4ccc5ccc6nc(-c7ccccc7)oc6c5c4c3)c2)cc1 ; c1ccc(-c2ccccc2-c2ccc(N(c3ccc4oc5ccccc5c4c3)c3ccc4ccc5ccc6nc(-c7ccc8ccccc8c7)oc6c5c4c3)cc2)cc1 ; c1ccc(-c2ccc(N(c3ccc4ccc5ccc6nc(-c7ccccc7)oc6c5c4c3)c3ccccc3-c3ccccc3-c3ccccc3)cc2)cc1]

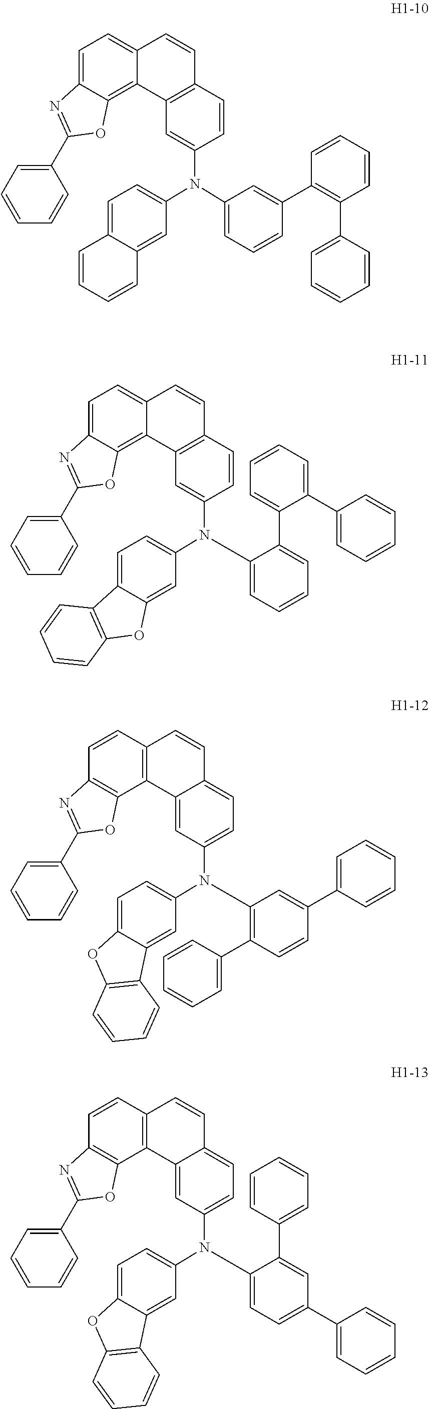 [SMILES: c1ccc(-c2nc3ccc4ccc5ccc(N(c6cccc(-c7ccccc7-c7ccccc7)c6)c6ccc7ccccc7c6)cc5c4c3o2)cc1 ; c1ccc(-c2nc3ccc4ccc5ccc(N(c6ccc7c(c6)oc6ccccc67)c6ccccc6-c6ccccc6-c6ccccc6)cc5c4c3o2)cc1 ; c1ccc(-c2ccc(-c3ccccc3)c(N(c3ccc4oc5ccccc5c4c3)c3ccc4ccc5ccc6nc(-c7ccccc7)oc6c5c4c3)c2)cc1 ; c1ccc(-c2ccc(N(c3ccc4oc5ccccc5c4c3)c3ccc4ccc5ccc6nc(-c7ccccc7)oc6c5c4c3)c(-c3ccccc3)c2)cc1]

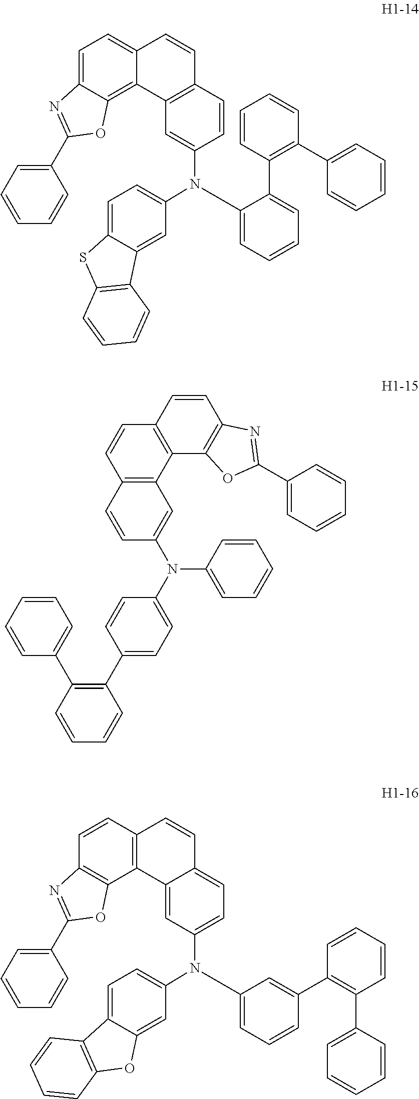 [SMILES: c1ccc(-c2nc3ccc4ccc5ccc(N(c6ccc7sc8ccccc8c7c6)c6ccccc6-c6ccccc6-c6ccccc6)cc5c4c3o2)cc1 ; c1ccc(-c2nc3ccc4ccc5ccc(N(c6ccccc6)c6ccc(-c7ccccc7-c7ccccc7)cc6)cc5c4c3o2)cc1 ; c1ccc(-c2nc3ccc4ccc5ccc(N(c6cccc(-c7ccccc7-c7ccccc7)c6)c6ccc7c(c6)oc6ccccc67)cc5c4c3o2)cc1]

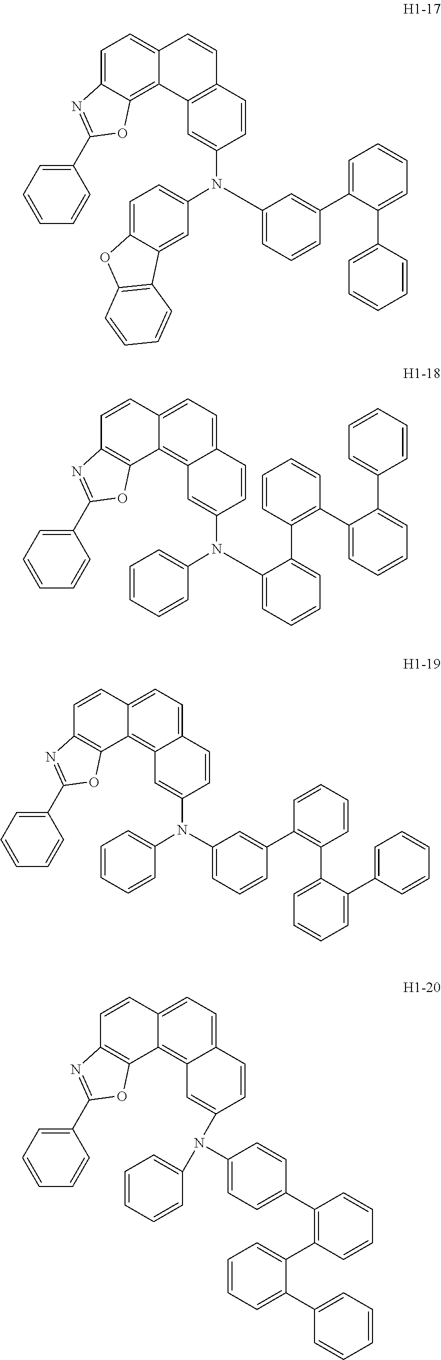 [SMILES: c1ccc(-c2nc3ccc4ccc5ccc(N(c6cccc(-c7ccccc7-c7ccccc7)c6)c6ccc7oc8ccccc8c7c6)cc5c4c3o2)cc1 ; c1ccc(-c2nc3ccc4ccc5ccc(N(c6ccccc6)c6ccccc6-c6ccccc6-c6ccccc6-c6ccccc6)cc5c4c3o2)cc1 ; c1ccc(-c2nc3ccc4ccc5ccc(N(c6ccccc6)c6cccc(-c7ccccc7-c7ccccc7-c7ccccc7)c6)cc5c4c3o2)cc1 ; c1ccc(-c2nc3ccc4ccc5ccc(N(c6ccccc6)c6ccc(-c7ccccc7-c7ccccc7-c7ccccc7)cc6)cc5c4c3o2)cc1]

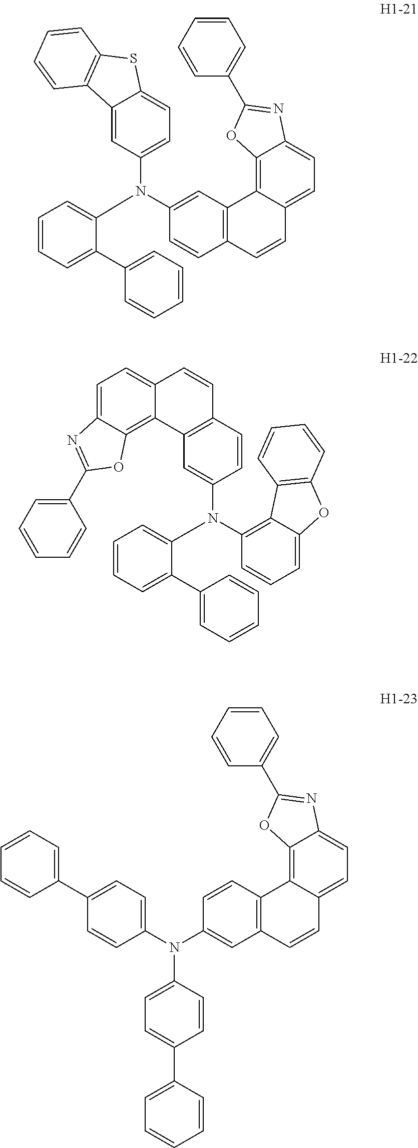 [SMILES: c1ccc(-c2nc3ccc4ccc5ccc(N(c6ccc7sc8ccccc8c7c6)c6ccccc6-c6ccccc6)cc5c4c3o2)cc1 ; c1ccc(-c2nc3ccc4ccc5ccc(N(c6ccccc6-c6ccccc6)c6cccc7oc8ccccc8c67)cc5c4c3o2)cc1 ; c1ccc(-c2ccc(N(c3ccc(-c4ccccc4)cc3)c3ccc4c(ccc5ccc6nc(-c7ccccc7)oc6c54)c3)cc2)cc1]

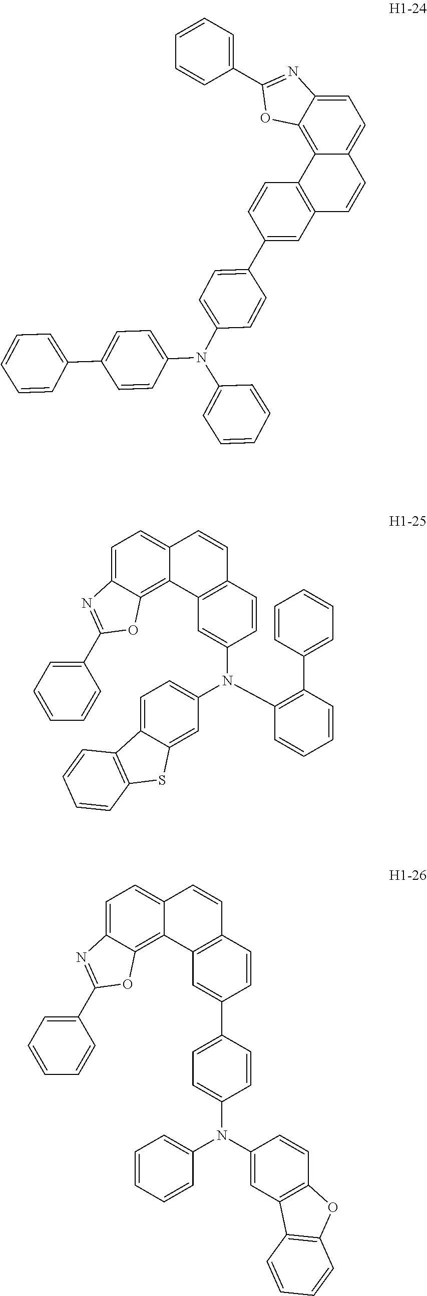 [SMILES: c1ccc(-c2ccc(N(c3ccccc3)c3ccc(-c4ccc5c(ccc6ccc7nc(-c8ccccc8)oc7c65)c4)cc3)cc2)cc1 ; c1ccc(-c2nc3ccc4ccc5ccc(N(c6ccc7c(c6)sc6ccccc67)c6ccccc6-c6ccccc6)cc5c4c3o2)cc1 ; c1ccc(-c2nc3ccc4ccc5ccc(-c6ccc(N(c7ccccc7)c7ccc8oc9ccccc9c8c7)cc6)cc5c4c3o2)cc1]

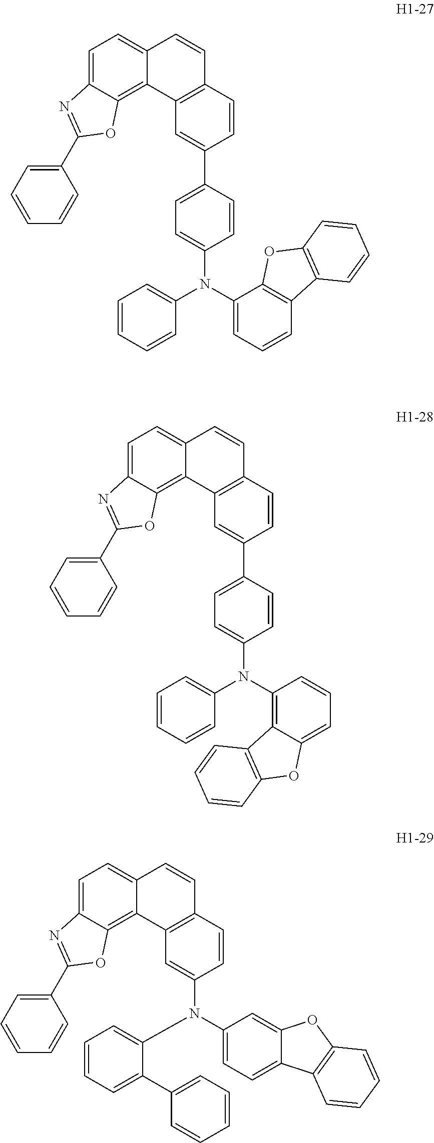 [SMILES: c1ccc(-c2nc3ccc4ccc5ccc(-c6ccc(N(c7ccccc7)c7cccc8c7oc7ccccc78)cc6)cc5c4c3o2)cc1 ; c1ccc(-c2nc3ccc4ccc5ccc(-c6ccc(N(c7ccccc7)c7cccc8oc9ccccc9c78)cc6)cc5c4c3o2)cc1 ; c1ccc(-c2nc3ccc4ccc5ccc(N(c6ccc7c(c6)oc6ccccc67)c6ccccc6-c6ccccc6)cc5c4c3o2)cc1]

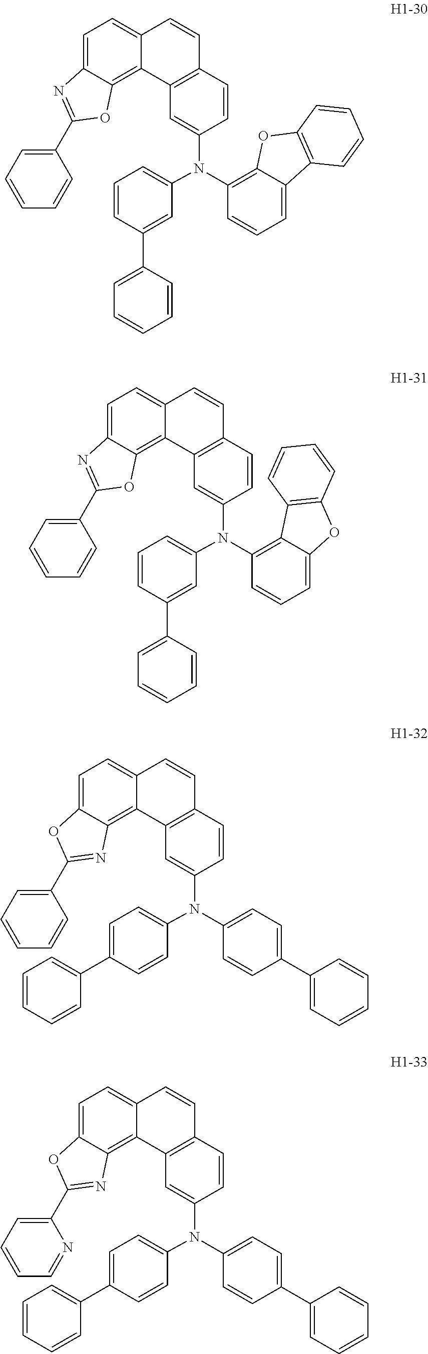 [SMILES: c1ccc(-c2cccc(N(c3ccc4ccc5ccc6nc(-c7ccccc7)oc6c5c4c3)c3cccc4c3oc3ccccc34)c2)cc1 ; c1ccc(-c2cccc(N(c3ccc4ccc5ccc6nc(-c7ccccc7)oc6c5c4c3)c3cccc4oc5ccccc5c34)c2)cc1 ; c1ccc(-c2ccc(N(c3ccc(-c4ccccc4)cc3)c3ccc4ccc5ccc6oc(-c7ccccc7)nc6c5c4c3)cc2)cc1 ; c1ccc(-c2ccc(N(c3ccc(-c4ccccc4)cc3)c3ccc4ccc5ccc6oc(-c7ccccn7)nc6c5c4c3)cc2)cc1]

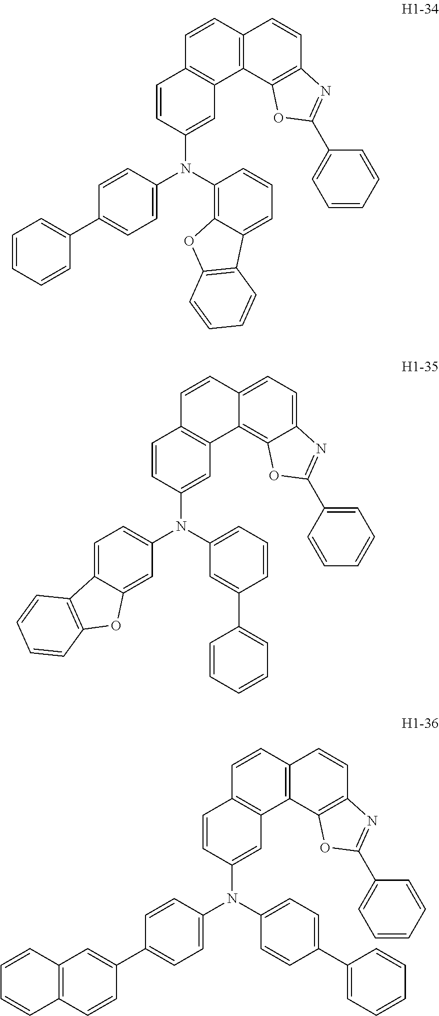 [SMILES: c1ccc(-c2ccc(N(c3ccc4ccc5ccc6nc(-c7ccccc7)oc6c5c4c3)c3cccc4c3oc3ccccc34)cc2)cc1 ; c1ccc(-c2cccc(N(c3ccc4c(c3)oc3ccccc34)c3ccc4ccc5ccc6nc(-c7ccccc7)oc6c5c4c3)c2)cc1 ; c1ccc(-c2ccc(N(c3ccc(-c4ccc5ccccc5c4)cc3)c3ccc4ccc5ccc6nc(-c7ccccc7)oc6c5c4c3)cc2)cc1]

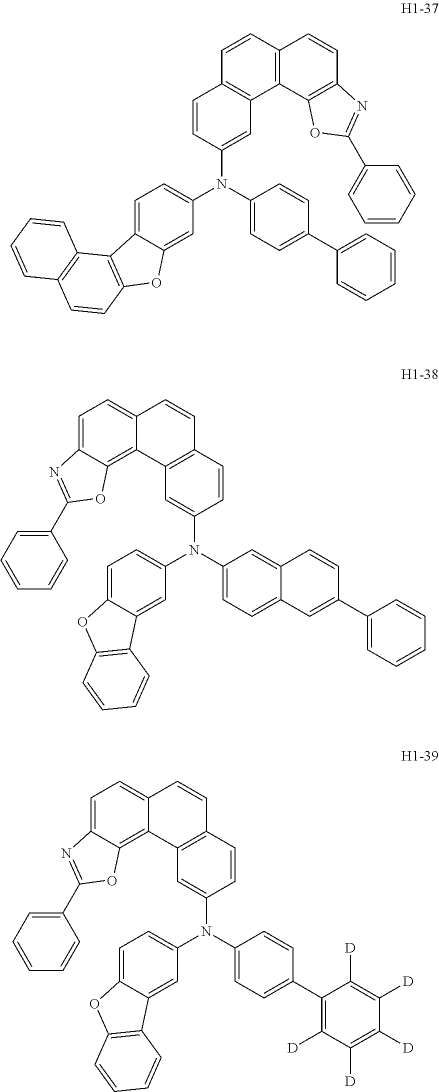 [SMILES: c1ccc(-c2ccc(N(c3ccc4c(c3)oc3ccc5ccccc5c34)c3ccc4ccc5ccc6nc(-c7ccccc7)oc6c5c4c3)cc2)cc1 ; c1ccc(-c2ccc3cc(N(c4ccc5oc6ccccc6c5c4)c4ccc5ccc6ccc7nc(-c8ccccc8)oc7c6c5c4)ccc3c2)cc1 ; [2H]c1c([2H])c([2H])c(-c2ccc(N(c3ccc4oc5ccccc5c4c3)c3ccc4ccc5ccc6nc(-c7ccccc7)oc6c5c4c3)cc2)c([2H])c1[2H]]

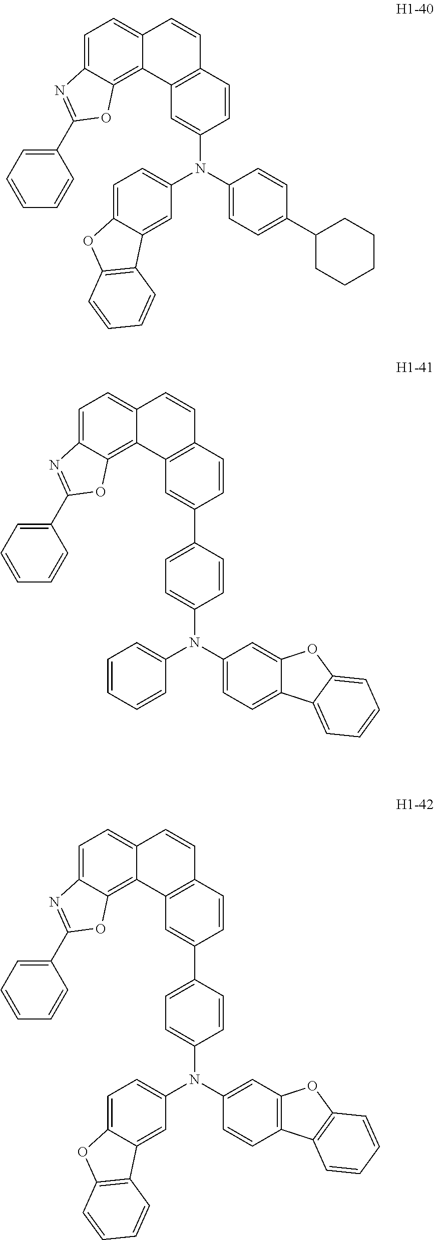 [SMILES: c1ccc(-c2nc3ccc4ccc5ccc(N(c6ccc(C7CCCCC7)cc6)c6ccc7oc8ccccc8c7c6)cc5c4c3o2)cc1 ; c1ccc(-c2nc3ccc4ccc5ccc(-c6ccc(N(c7ccccc7)c7ccc8c(c7)oc7ccccc78)cc6)cc5c4c3o2)cc1 ; c1ccc(-c2nc3ccc4ccc5ccc(-c6ccc(N(c7ccc8c(c7)oc7ccccc78)c7ccc8oc9ccccc9c8c7)cc6)cc5c4c3o2)cc1]

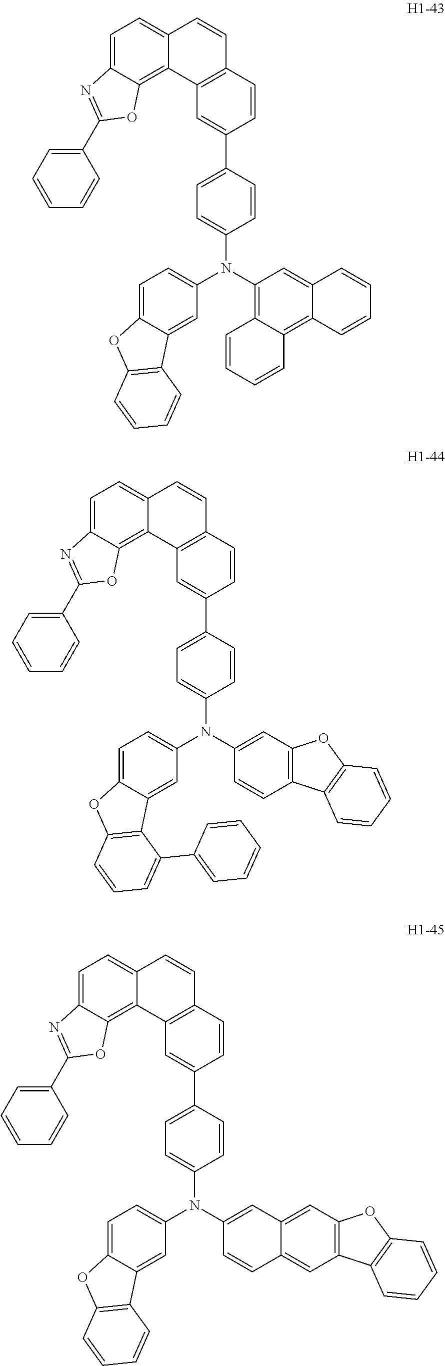 [SMILES: c1ccc(-c2nc3ccc4ccc5ccc(-c6ccc(N(c7ccc8oc9ccccc9c8c7)c7cc8ccccc8c8ccccc78)cc6)cc5c4c3o2)cc1 ; c1ccc(-c2nc3ccc4ccc5ccc(-c6ccc(N(c7ccc8c(c7)oc7ccccc78)c7ccc8oc9cccc(-c%10ccccc%10)c9c8c7)cc6)cc5c4c3o2)cc1 ; c1ccc(-c2nc3ccc4ccc5ccc(-c6ccc(N(c7ccc8cc9c(cc8c7)oc7ccccc79)c7ccc8oc9ccccc9c8c7)cc6)cc5c4c3o2)cc1]

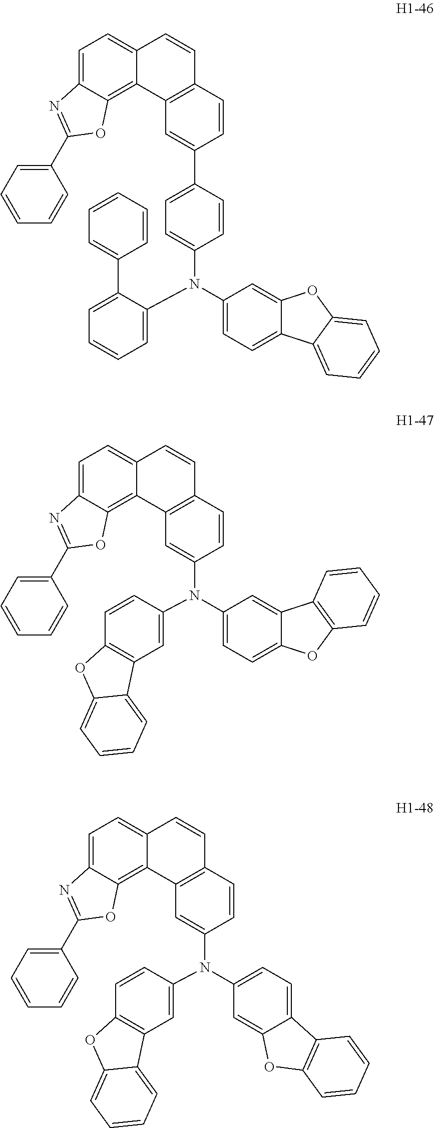 [SMILES: c1ccc(-c2nc3ccc4ccc5ccc(-c6ccc(N(c7ccc8c(c7)oc7ccccc78)c7ccccc7-c7ccccc7)cc6)cc5c4c3o2)cc1 ; c1ccc(-c2nc3ccc4ccc5ccc(N(c6ccc7oc8ccccc8c7c6)c6ccc7oc8ccccc8c7c6)cc5c4c3o2)cc1 ; c1ccc(-c2nc3ccc4ccc5ccc(N(c6ccc7c(c6)oc6ccccc67)c6ccc7oc8ccccc8c7c6)cc5c4c3o2)cc1]

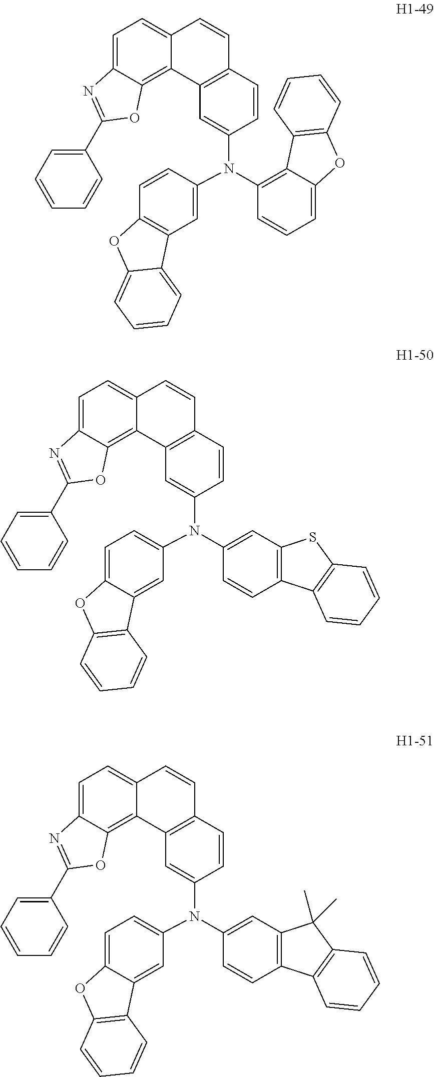 [SMILES: c1ccc(-c2nc3ccc4ccc5ccc(N(c6ccc7oc8ccccc8c7c6)c6cccc7oc8ccccc8c67)cc5c4c3o2)cc1 ; c1ccc(-c2nc3ccc4ccc5ccc(N(c6ccc7c(c6)sc6ccccc67)c6ccc7oc8ccccc8c7c6)cc5c4c3o2)cc1 ; CC1(C)c2ccccc2-c2ccc(N(c3ccc4oc5ccccc5c4c3)c3ccc4ccc5ccc6nc(-c7ccccc7)oc6c5c4c3)cc21]

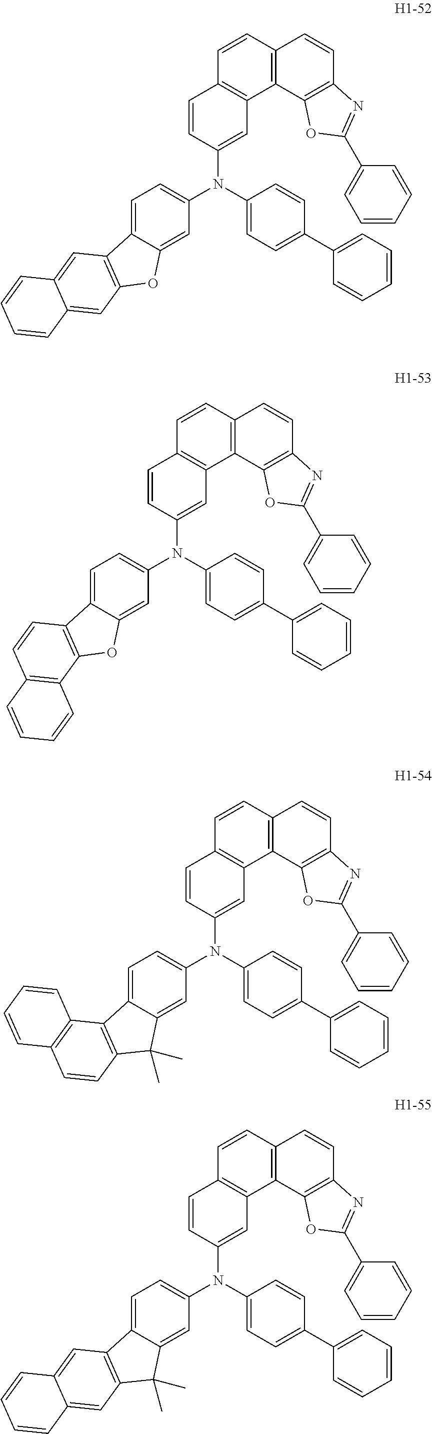 [SMILES: c1ccc(-c2ccc(N(c3ccc4c(c3)oc3cc5ccccc5cc34)c3ccc4ccc5ccc6nc(-c7ccccc7)oc6c5c4c3)cc2)cc1 ; c1ccc(-c2ccc(N(c3ccc4c(c3)oc3c5ccccc5ccc43)c3ccc4ccc5ccc6nc(-c7ccccc7)oc6c5c4c3)cc2)cc1 ; CC1(C)c2cc(N(c3ccc(-c4ccccc4)cc3)c3ccc4ccc5ccc6nc(-c7ccccc7)oc6c5c4c3)ccc2-c2c1ccc1ccccc21 ; CC1(C)c2cc(N(c3ccc(-c4ccccc4)cc3)c3ccc4ccc5ccc6nc(-c7ccccc7)oc6c5c4c3)ccc2-c2cc3ccccc3cc21]

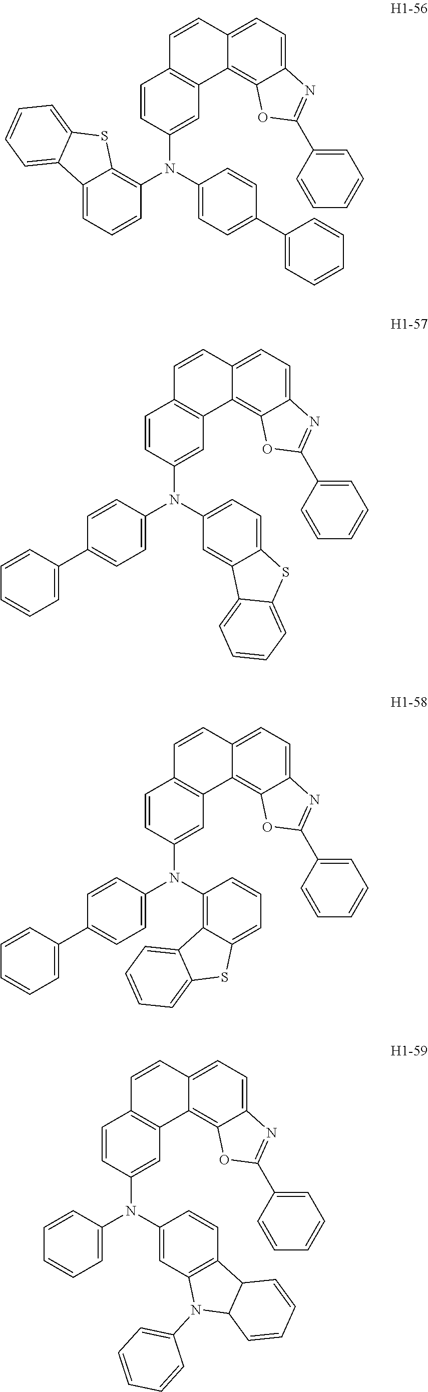 [SMILES: c1ccc(-c2ccc(N(c3ccc4ccc5ccc6nc(-c7ccccc7)oc6c5c4c3)c3cccc4c3sc3ccccc34)cc2)cc1 ; c1ccc(-c2ccc(N(c3ccc4sc5ccccc5c4c3)c3ccc4ccc5ccc6nc(-c7ccccc7)oc6c5c4c3)cc2)cc1 ; c1ccc(-c2ccc(N(c3ccc4ccc5ccc6nc(-c7ccccc7)oc6c5c4c3)c3cccc4sc5ccccc5c34)cc2)cc1 ; C1=CC2c3ccc(N(c4ccccc4)c4ccc5ccc6ccc7nc(-c8ccccc8)oc7c6c5c4)cc3N(c3ccccc3)C2C=C1]

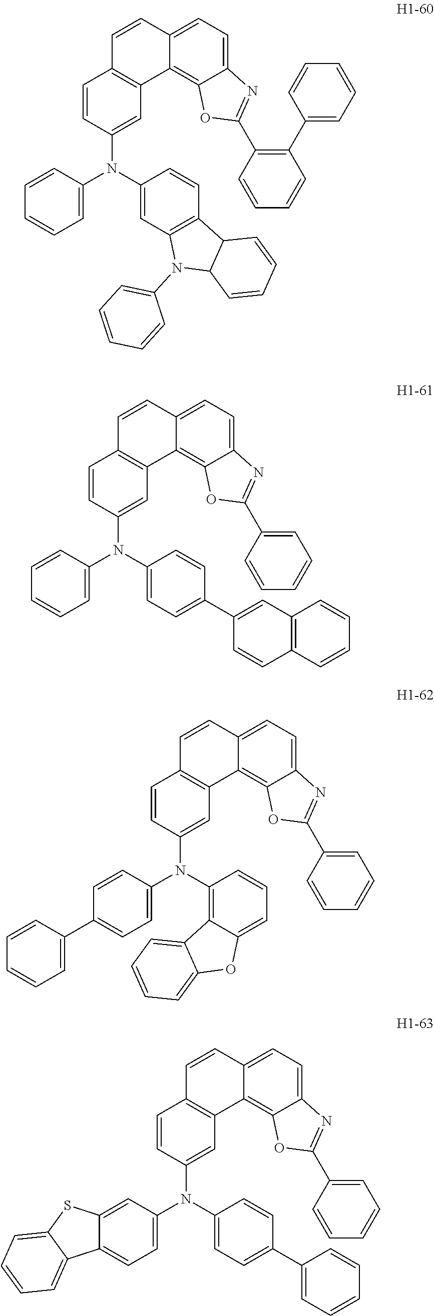 [SMILES: C1=CC2c3ccc(N(c4ccccc4)c4ccc5ccc6ccc7nc(-c8ccccc8-c8ccccc8)oc7c6c5c4)cc3N(c3ccccc3)C2C=C1 ; c1ccc(-c2nc3ccc4ccc5ccc(N(c6ccccc6)c6ccc(-c7ccc8ccccc8c7)cc6)cc5c4c3o2)cc1 ; c1ccc(-c2ccc(N(c3ccc4ccc5ccc6nc(-c7ccccc7)oc6c5c4c3)c3cccc4oc5ccccc5c34)cc2)cc1 ; c1ccc(-c2ccc(N(c3ccc4c(c3)sc3ccccc34)c3ccc4ccc5ccc6nc(-c7ccccc7)oc6c5c4c3)cc2)cc1]

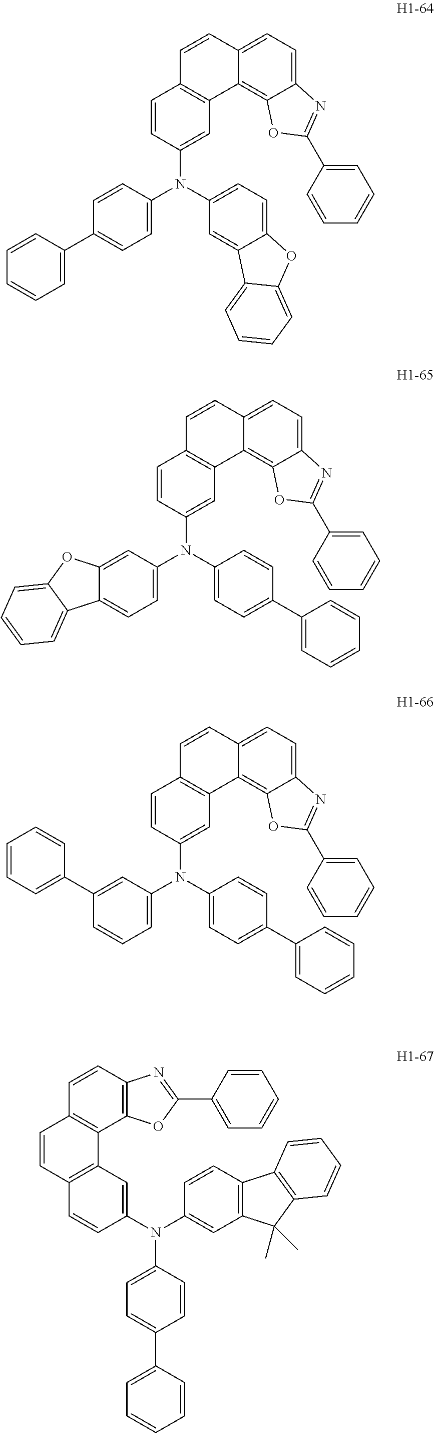 [SMILES: c1ccc(-c2ccc(N(c3ccc4oc5ccccc5c4c3)c3ccc4ccc5ccc6nc(-c7ccccc7)oc6c5c4c3)cc2)cc1 ; c1ccc(-c2ccc(N(c3ccc4c(c3)oc3ccccc34)c3ccc4ccc5ccc6nc(-c7ccccc7)oc6c5c4c3)cc2)cc1 ; c1ccc(-c2ccc(N(c3cccc(-c4ccccc4)c3)c3ccc4ccc5ccc6nc(-c7ccccc7)oc6c5c4c3)cc2)cc1 ; CC1(C)c2ccccc2-c2ccc(N(c3ccc(-c4ccccc4)cc3)c3ccc4ccc5ccc6nc(-c7ccccc7)oc6c5c4c3)cc21]

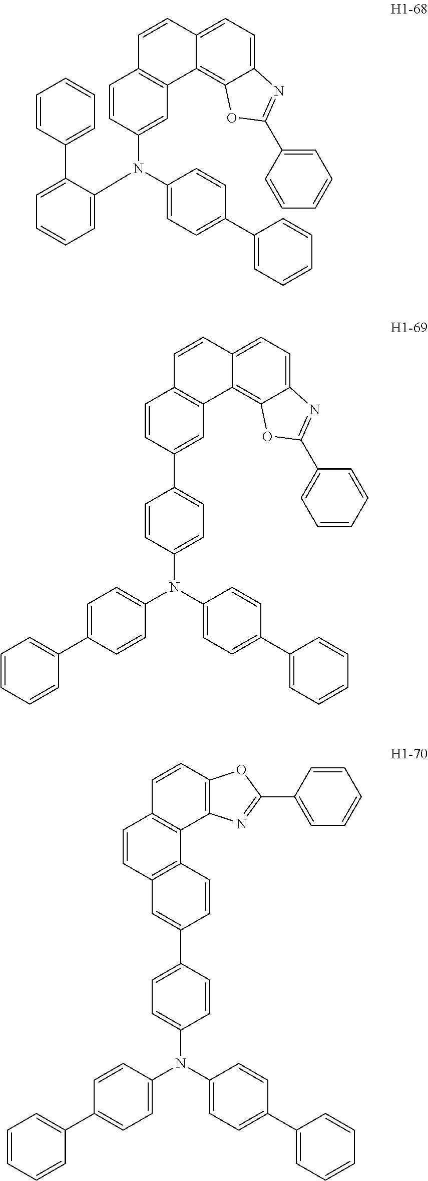 [SMILES: c1ccc(-c2ccc(N(c3ccc4ccc5ccc6nc(-c7ccccc7)oc6c5c4c3)c3ccccc3-c3ccccc3)cc2)cc1 ; c1ccc(-c2ccc(N(c3ccc(-c4ccccc4)cc3)c3ccc(-c4ccc5ccc6ccc7nc(-c8ccccc8)oc7c6c5c4)cc3)cc2)cc1 ; c1ccc(-c2ccc(N(c3ccc(-c4ccccc4)cc3)c3ccc(-c4ccc5c(ccc6ccc7oc(-c8ccccc8)nc7c65)c4)cc3)cc2)cc1]

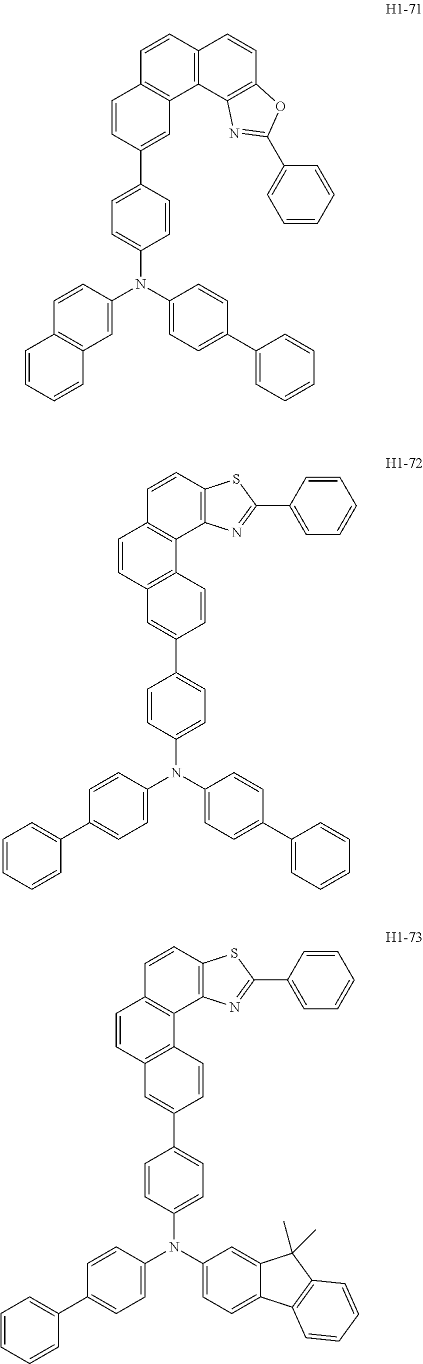 [SMILES: c1ccc(-c2ccc(N(c3ccc(-c4ccc5ccc6ccc7oc(-c8ccccc8)nc7c6c5c4)cc3)c3ccc4ccccc4c3)cc2)cc1 ; c1ccc(-c2ccc(N(c3ccc(-c4ccccc4)cc3)c3ccc(-c4ccc5c(ccc6ccc7sc(-c8ccccc8)nc7c65)c4)cc3)cc2)cc1 ; CC1(C)c2ccccc2-c2ccc(N(c3ccc(-c4ccccc4)cc3)c3ccc(-c4ccc5c(ccc6ccc7sc(-c8ccccc8)nc7c65)c4)cc3)cc21]

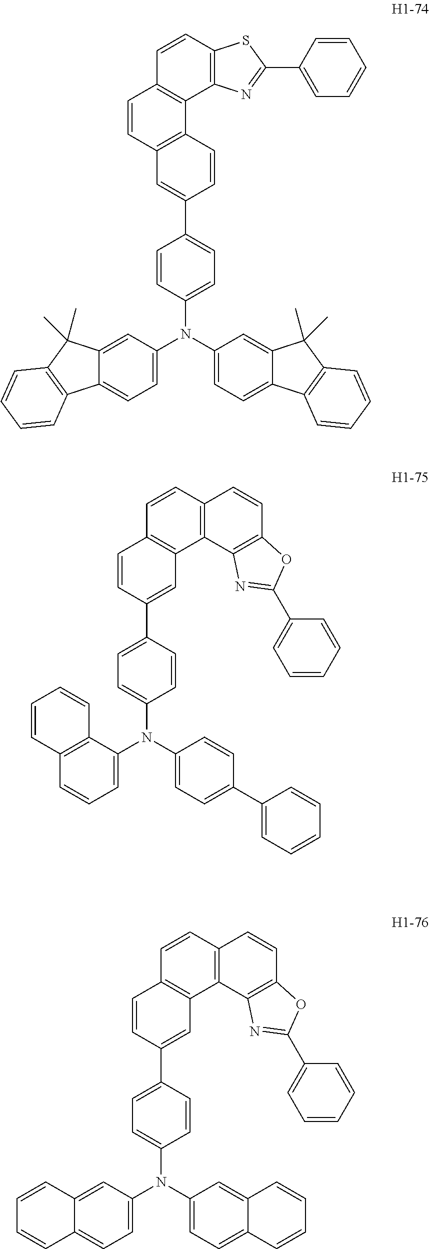 [SMILES: CC1(C)c2ccccc2-c2ccc(N(c3ccc(-c4ccc5c(ccc6ccc7sc(-c8ccccc8)nc7c65)c4)cc3)c3ccc4c(c3)C(C)(C)c3ccccc3-4)cc21 ; c1ccc(-c2ccc(N(c3ccc(-c4ccc5ccc6ccc7oc(-c8ccccc8)nc7c6c5c4)cc3)c3cccc4ccccc34)cc2)cc1 ; c1ccc(-c2nc3c(ccc4ccc5ccc(-c6ccc(N(c7ccc8ccccc8c7)c7ccc8ccccc8c7)cc6)cc5c43)o2)cc1]

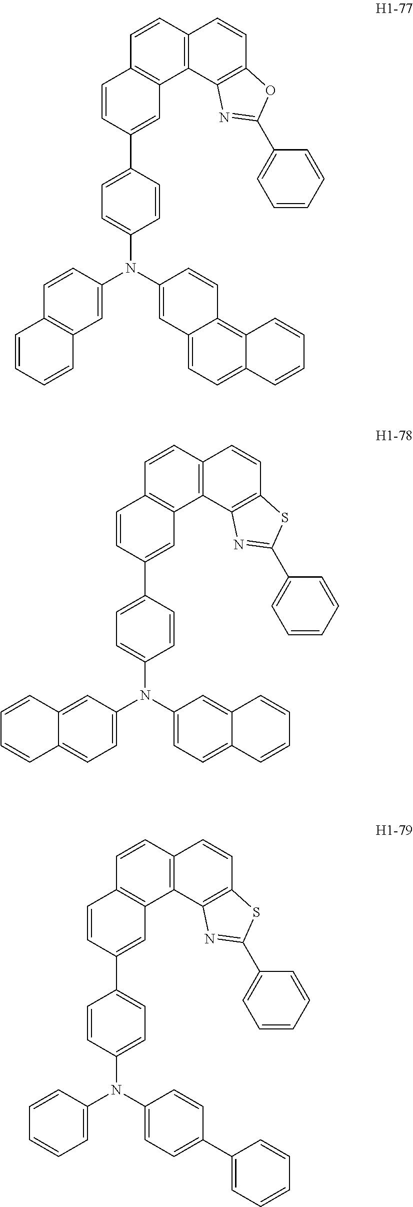 [SMILES: c1ccc(-c2nc3c(ccc4ccc5ccc(-c6ccc(N(c7ccc8ccccc8c7)c7ccc8c(ccc9ccccc98)c7)cc6)cc5c43)o2)cc1 ; c1ccc(-c2nc3c(ccc4ccc5ccc(-c6ccc(N(c7ccc8ccccc8c7)c7ccc8ccccc8c7)cc6)cc5c43)s2)cc1 ; c1ccc(-c2ccc(N(c3ccccc3)c3ccc(-c4ccc5ccc6ccc7sc(-c8ccccc8)nc7c6c5c4)cc3)cc2)cc1]

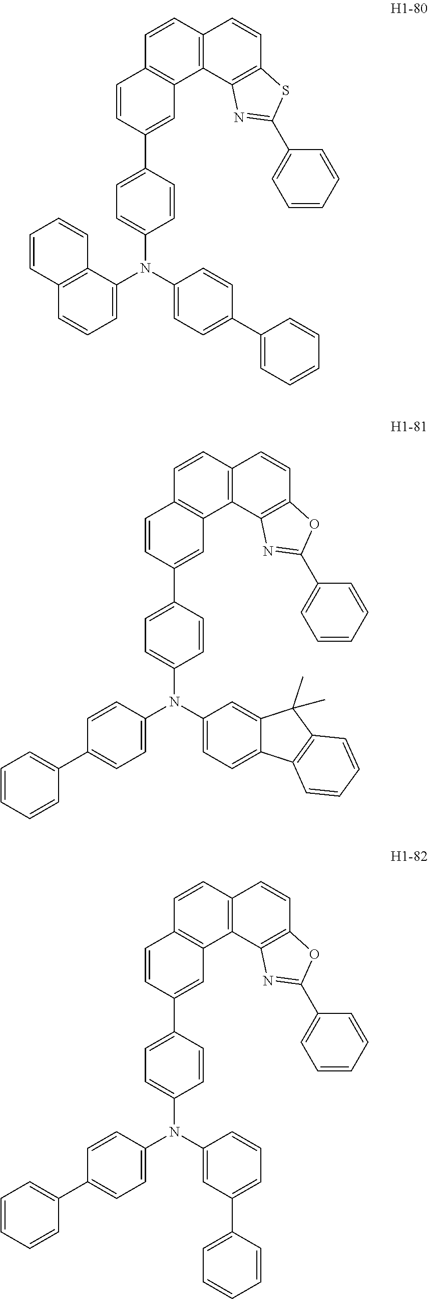 [SMILES: c1ccc(-c2ccc(N(c3ccc(-c4ccc5ccc6ccc7sc(-c8ccccc8)nc7c6c5c4)cc3)c3cccc4ccccc34)cc2)cc1 ; CC1(C)c2ccccc2-c2ccc(N(c3ccc(-c4ccccc4)cc3)c3ccc(-c4ccc5ccc6ccc7oc(-c8ccccc8)nc7c6c5c4)cc3)cc21 ; c1ccc(-c2ccc(N(c3ccc(-c4ccc5ccc6ccc7oc(-c8ccccc8)nc7c6c5c4)cc3)c3cccc(-c4ccccc4)c3)cc2)cc1]

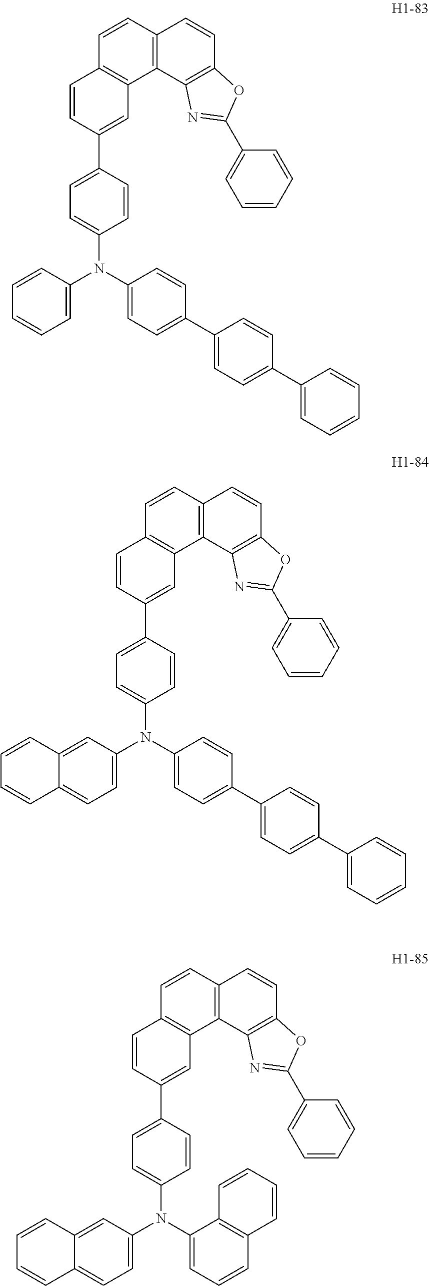 [SMILES: c1ccc(-c2ccc(-c3ccc(N(c4ccccc4)c4ccc(-c5ccc6ccc7ccc8oc(-c9ccccc9)nc8c7c6c5)cc4)cc3)cc2)cc1 ; c1ccc(-c2ccc(-c3ccc(N(c4ccc(-c5ccc6ccc7ccc8oc(-c9ccccc9)nc8c7c6c5)cc4)c4ccc5ccccc5c4)cc3)cc2)cc1 ; c1ccc(-c2nc3c(ccc4ccc5ccc(-c6ccc(N(c7ccc8ccccc8c7)c7cccc8ccccc78)cc6)cc5c43)o2)cc1]

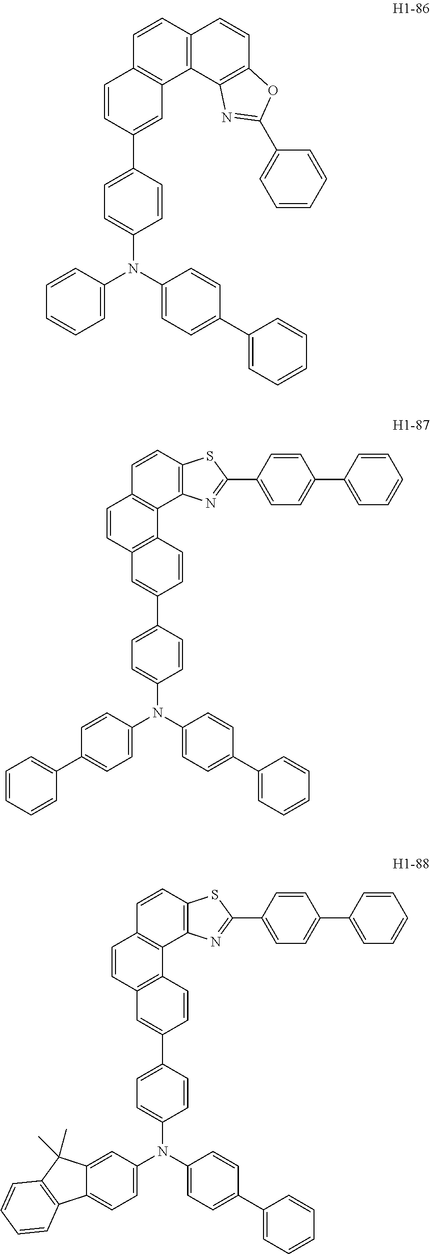 [SMILES: c1ccc(-c2ccc(N(c3ccccc3)c3ccc(-c4ccc5ccc6ccc7oc(-c8ccccc8)nc7c6c5c4)cc3)cc2)cc1 ; c1ccc(-c2ccc(-c3nc4c(ccc5ccc6cc(-c7ccc(N(c8ccc(-c9ccccc9)cc8)c8ccc(-c9ccccc9)cc8)cc7)ccc6c54)s3)cc2)cc1 ; CC1(C)c2ccccc2-c2ccc(N(c3ccc(-c4ccccc4)cc3)c3ccc(-c4ccc5c(ccc6ccc7sc(-c8ccc(-c9ccccc9)cc8)nc7c65)c4)cc3)cc21]

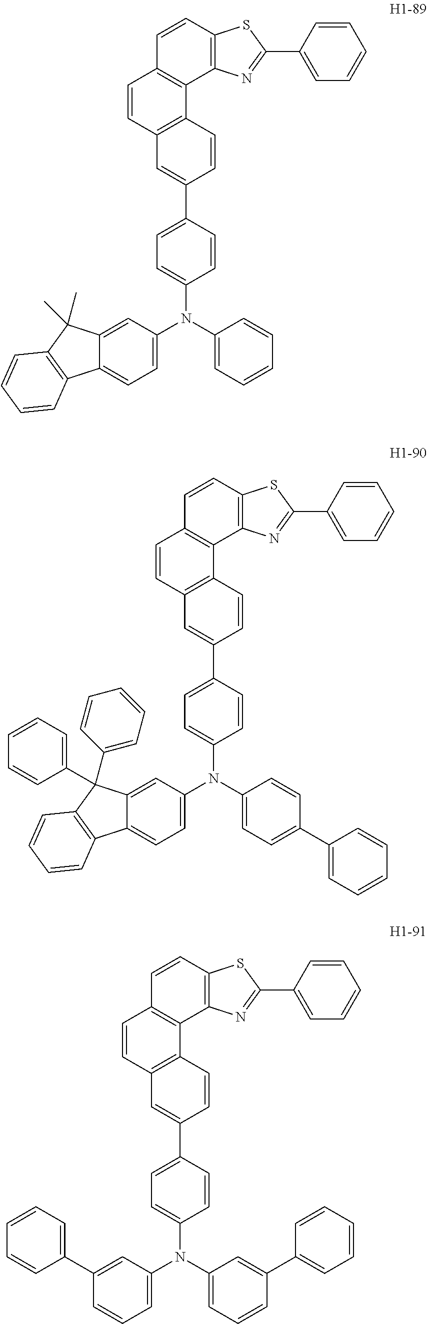 [SMILES: CC1(C)c2ccccc2-c2ccc(N(c3ccccc3)c3ccc(-c4ccc5c(ccc6ccc7sc(-c8ccccc8)nc7c65)c4)cc3)cc21 ; c1ccc(-c2ccc(N(c3ccc(-c4ccc5c(ccc6ccc7sc(-c8ccccc8)nc7c65)c4)cc3)c3ccc4c(c3)C(c3ccccc3)(c3ccccc3)c3ccccc3-4)cc2)cc1 ; c1ccc(-c2cccc(N(c3ccc(-c4ccc5c(ccc6ccc7sc(-c8ccccc8)nc7c65)c4)cc3)c3cccc(-c4ccccc4)c3)c2)cc1]

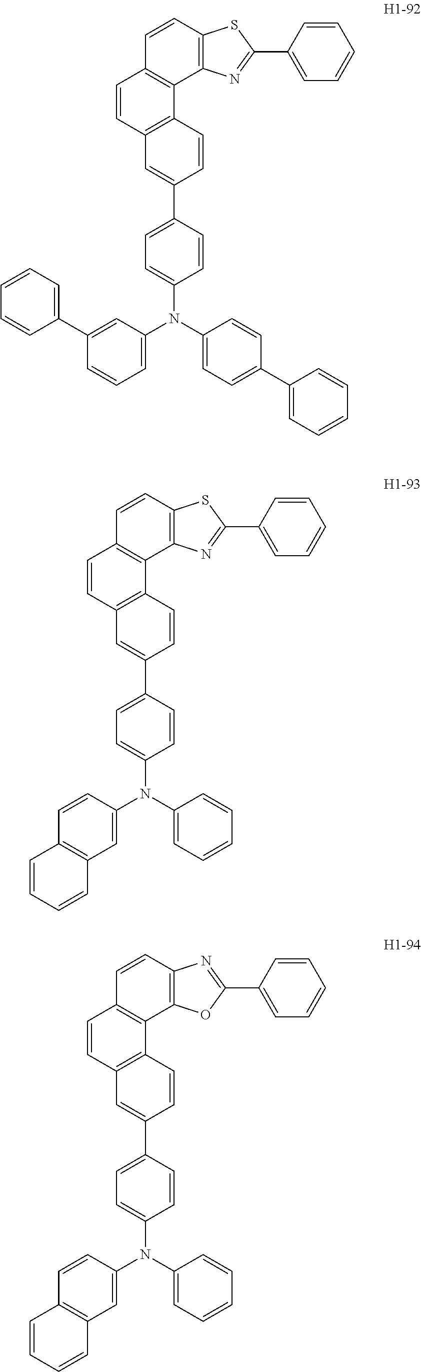 [SMILES: c1ccc(-c2ccc(N(c3ccc(-c4ccc5c(ccc6ccc7sc(-c8ccccc8)nc7c65)c4)cc3)c3cccc(-c4ccccc4)c3)cc2)cc1 ; c1ccc(-c2nc3c(ccc4ccc5cc(-c6ccc(N(c7ccccc7)c7ccc8ccccc8c7)cc6)ccc5c43)s2)cc1 ; c1ccc(-c2nc3ccc4ccc5cc(-c6ccc(N(c7ccccc7)c7ccc8ccccc8c7)cc6)ccc5c4c3o2)cc1]

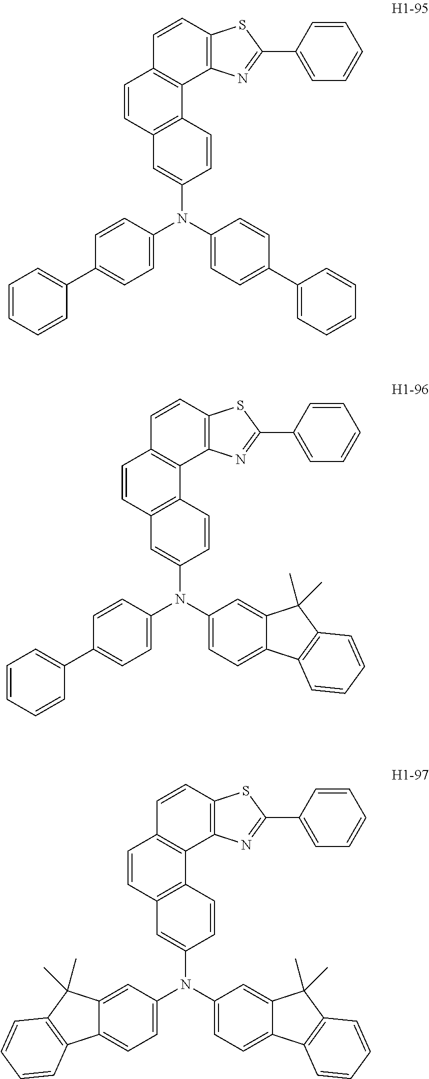 [SMILES: c1ccc(-c2ccc(N(c3ccc(-c4ccccc4)cc3)c3ccc4c(ccc5ccc6sc(-c7ccccc7)nc6c54)c3)cc2)cc1 ; CC1(C)c2ccccc2-c2ccc(N(c3ccc(-c4ccccc4)cc3)c3ccc4c(ccc5ccc6sc(-c7ccccc7)nc6c54)c3)cc21 ; CC1(C)c2ccccc2-c2ccc(N(c3ccc4c(c3)C(C)(C)c3ccccc3-4)c3ccc4c(ccc5ccc6sc(-c7ccccc7)nc6c54)c3)cc21]

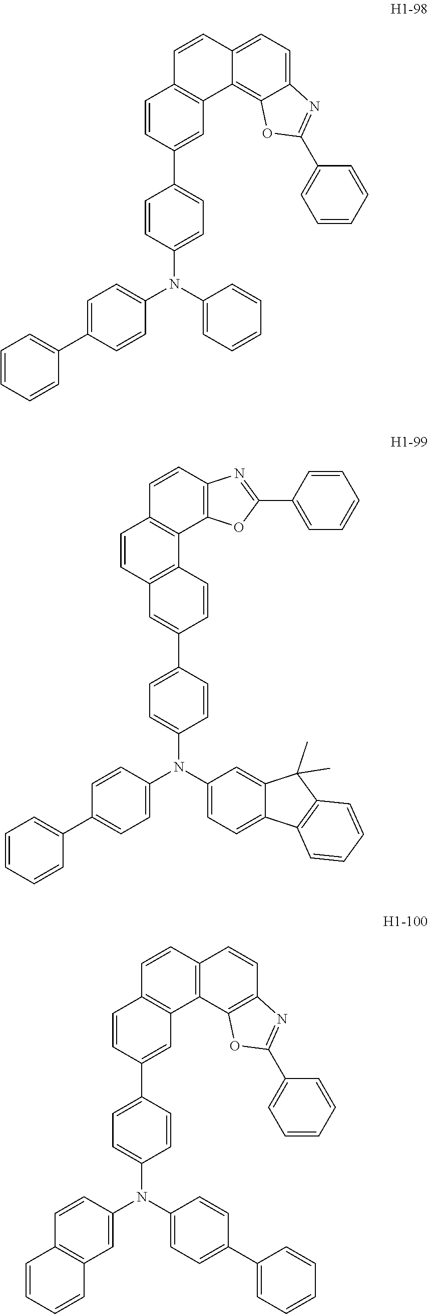 [SMILES: c1ccc(-c2ccc(N(c3ccccc3)c3ccc(-c4ccc5ccc6ccc7nc(-c8ccccc8)oc7c6c5c4)cc3)cc2)cc1 ; CC1(C)c2ccccc2-c2ccc(N(c3ccc(-c4ccccc4)cc3)c3ccc(-c4ccc5c(ccc6ccc7nc(-c8ccccc8)oc7c65)c4)cc3)cc21 ; c1ccc(-c2ccc(N(c3ccc(-c4ccc5ccc6ccc7nc(-c8ccccc8)oc7c6c5c4)cc3)c3ccc4ccccc4c3)cc2)cc1]

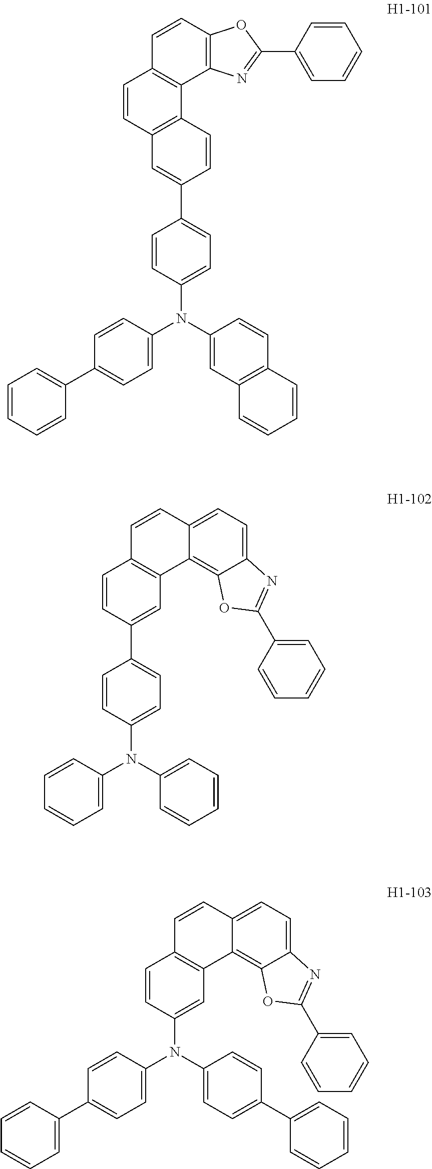 [SMILES: c1ccc(-c2ccc(N(c3ccc(-c4ccc5c(ccc6ccc7oc(-c8ccccc8)nc7c65)c4)cc3)c3ccc4ccccc4c3)cc2)cc1 ; c1ccc(-c2nc3ccc4ccc5ccc(-c6ccc(N(c7ccccc7)c7ccccc7)cc6)cc5c4c3o2)cc1 ; c1ccc(-c2ccc(N(c3ccc(-c4ccccc4)cc3)c3ccc4ccc5ccc6nc(-c7ccccc7)oc6c5c4c3)cc2)cc1]

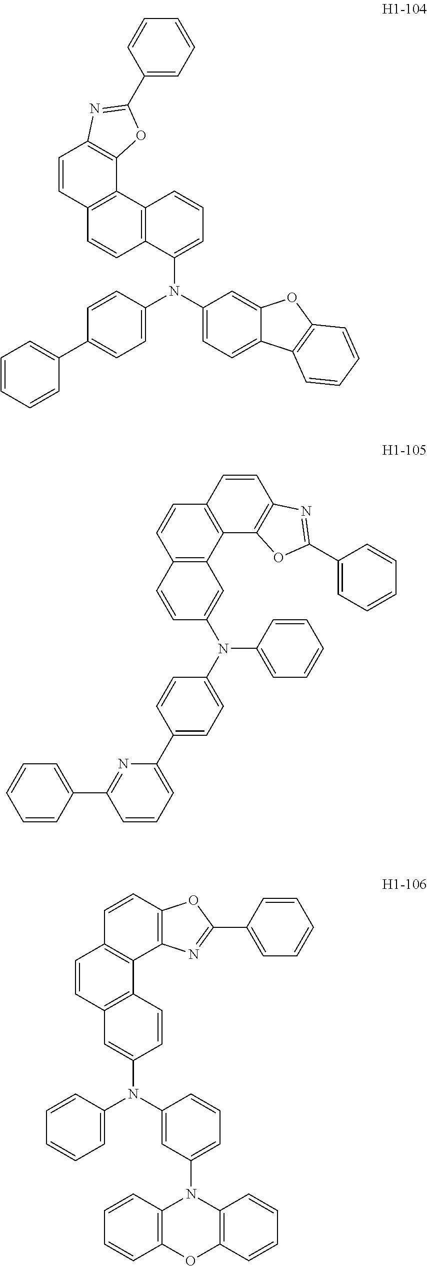 [SMILES: c1ccc(-c2ccc(N(c3ccc4c(c3)oc3ccccc34)c3cccc4c3ccc3ccc5nc(-c6ccccc6)oc5c34)cc2)cc1 ; c1ccc(-c2cccc(-c3ccc(N(c4ccccc4)c4ccc5ccc6ccc7nc(-c8ccccc8)oc7c6c5c4)cc3)n2)cc1 ; c1ccc(-c2nc3c(ccc4ccc5cc(N(c6ccccc6)c6cccc(N7c8ccccc8Oc8ccccc87)c6)ccc5c43)o2)cc1]

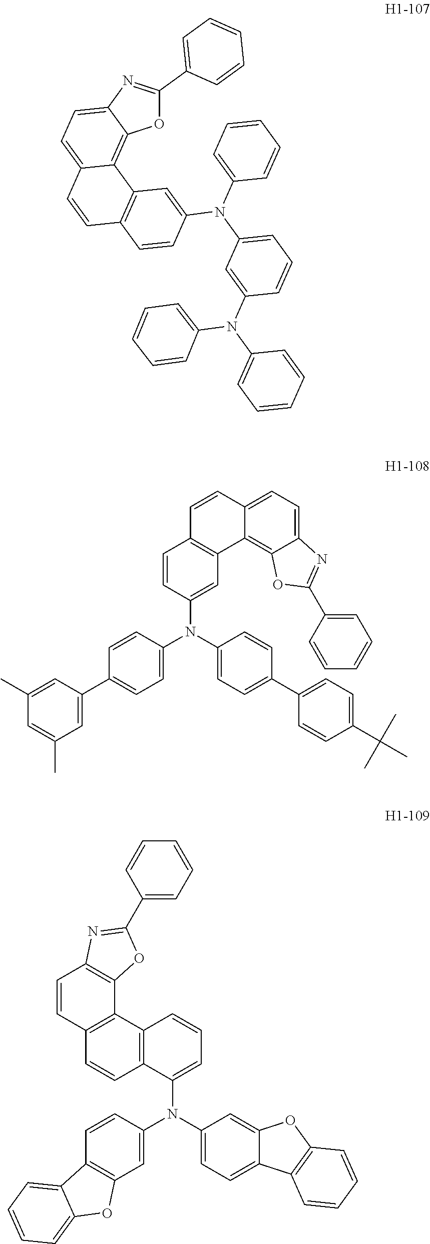 [SMILES: c1ccc(-c2nc3ccc4ccc5ccc(N(c6ccccc6)c6cccc(N(c7ccccc7)c7ccccc7)c6)cc5c4c3o2)cc1 ; Cc1cc(C)cc(-c2ccc(N(c3ccc(-c4ccc(C(C)(C)C)cc4)cc3)c3ccc4ccc5ccc6nc(-c7ccccc7)oc6c5c4c3)cc2)c1 ; c1ccc(-c2nc3ccc4ccc5c(N(c6ccc7c(c6)oc6ccccc67)c6ccc7c(c6)oc6ccccc67)cccc5c4c3o2)cc1]

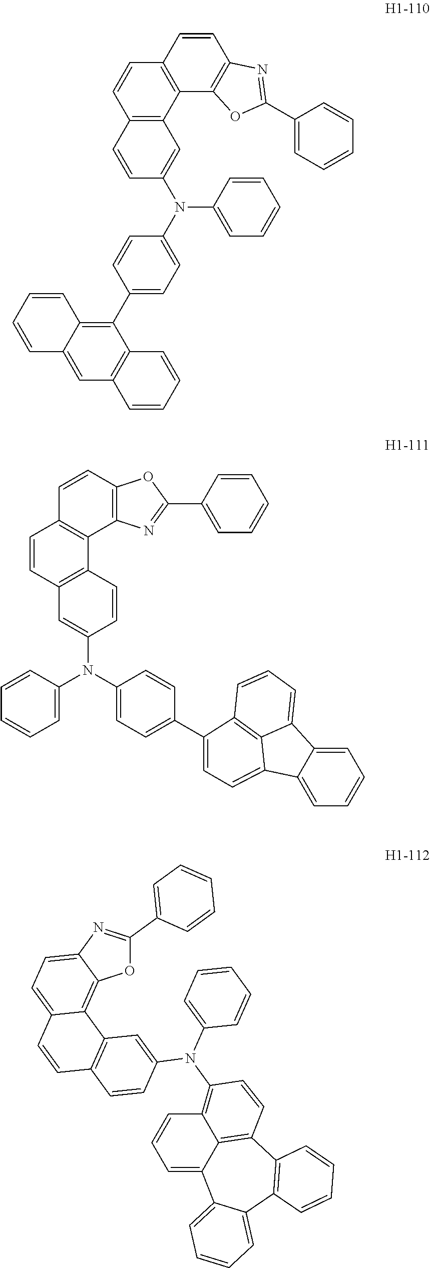 [SMILES: c1ccc(-c2nc3ccc4ccc5ccc(N(c6ccccc6)c6ccc(-c7c8ccccc8cc8ccccc78)cc6)cc5c4c3o2)cc1 ; c1ccc(-c2nc3c(ccc4ccc5cc(N(c6ccccc6)c6ccc(-c7ccc8c9c(cccc79)-c7ccccc7-8)cc6)ccc5c43)o2)cc1 ; c1ccc(-c2nc3ccc4ccc5ccc(N(c6ccccc6)c6ccc7c8c(cccc68)-c6ccccc6-c6ccccc6-7)cc5c4c3o2)cc1]

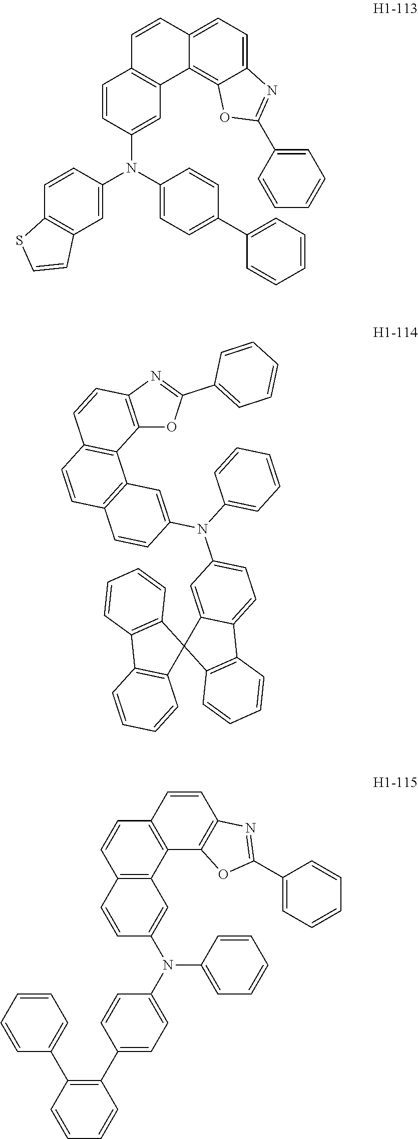 [SMILES: c1ccc(-c2ccc(N(c3ccc4sccc4c3)c3ccc4ccc5ccc6nc(-c7ccccc7)oc6c5c4c3)cc2)cc1 ; c1ccc(-c2nc3ccc4ccc5ccc(N(c6ccccc6)c6ccc7c(c6)C6(c8ccccc8-c8ccccc86)c6ccccc6-7)cc5c4c3o2)cc1 ; c1ccc(-c2nc3ccc4ccc5ccc(N(c6ccccc6)c6ccc(-c7ccccc7-c7ccccc7)cc6)cc5c4c3o2)cc1]

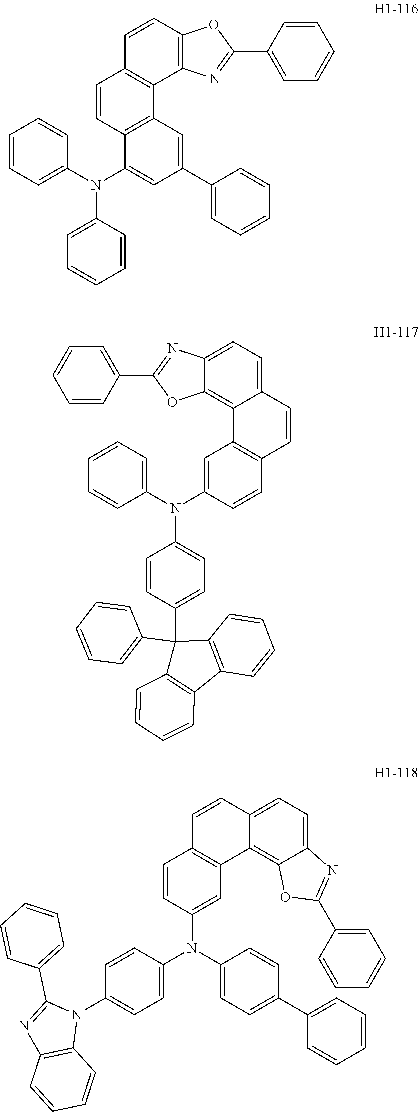 [SMILES: c1ccc(-c2cc(N(c3ccccc3)c3ccccc3)c3ccc4ccc5oc(-c6ccccc6)nc5c4c3c2)cc1 ; c1ccc(-c2nc3ccc4ccc5ccc(N(c6ccccc6)c6ccc(C7(c8ccccc8)c8ccccc8-c8ccccc87)cc6)cc5c4c3o2)cc1 ; c1ccc(-c2ccc(N(c3ccc(-n4c(-c5ccccc5)nc5ccccc54)cc3)c3ccc4ccc5ccc6nc(-c7ccccc7)oc6c5c4c3)cc2)cc1]

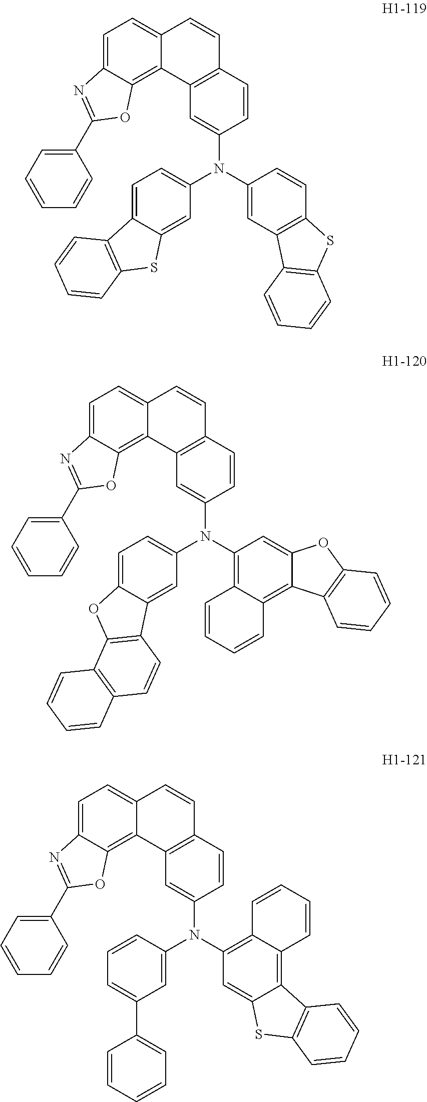 [SMILES: c1ccc(-c2nc3ccc4ccc5ccc(N(c6ccc7c(c6)sc6ccccc67)c6ccc7sc8ccccc8c7c6)cc5c4c3o2)cc1 ; c1ccc(-c2nc3ccc4ccc5ccc(N(c6ccc7oc8c9ccccc9ccc8c7c6)c6cc7oc8ccccc8c7c7ccccc67)cc5c4c3o2)cc1 ; c1ccc(-c2cccc(N(c3ccc4ccc5ccc6nc(-c7ccccc7)oc6c5c4c3)c3cc4sc5ccccc5c4c4ccccc34)c2)cc1]

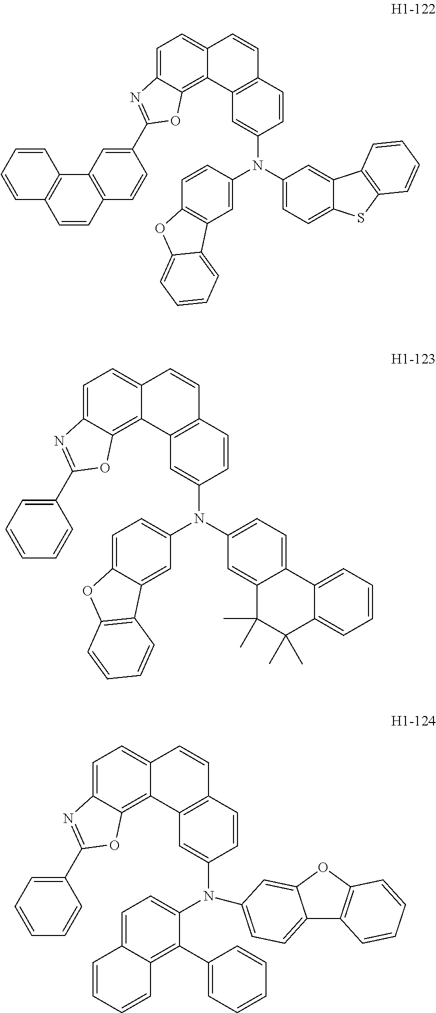 [SMILES: c1ccc2c(c1)ccc1ccc(-c3nc4ccc5ccc6ccc(N(c7ccc8oc9ccccc9c8c7)c7ccc8sc9ccccc9c8c7)cc6c5c4o3)cc12 ; CC1(C)c2ccccc2-c2ccc(N(c3ccc4oc5ccccc5c4c3)c3ccc4ccc5ccc6nc(-c7ccccc7)oc6c5c4c3)cc2C1(C)C ; c1ccc(-c2nc3ccc4ccc5ccc(N(c6ccc7c(c6)oc6ccccc67)c6ccc7ccccc7c6-c6ccccc6)cc5c4c3o2)cc1]

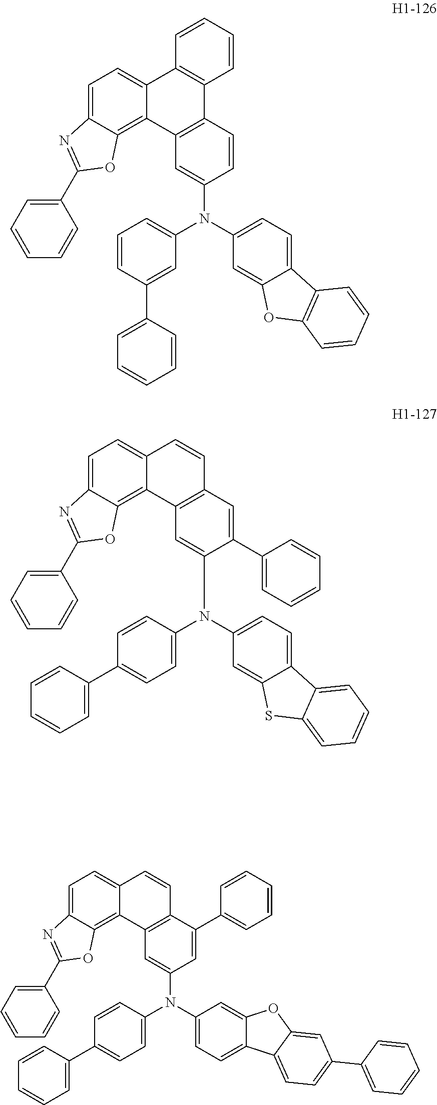 [SMILES: c1ccc(-c2cccc(N(c3ccc4c(c3)oc3ccccc34)c3ccc4c5ccccc5c5ccc6nc(-c7ccccc7)oc6c5c4c3)c2)cc1 ; c1ccc(-c2ccc(N(c3ccc4c(c3)sc3ccccc34)c3cc4c(ccc5ccc6nc(-c7ccccc7)oc6c54)cc3-c3ccccc3)cc2)cc1 ; c1ccc(-c2ccc(N(c3ccc4c(c3)oc3cc(-c5ccccc5)ccc34)c3cc(-c4ccccc4)c4ccc5ccc6nc(-c7ccccc7)oc6c5c4c3)cc2)cc1]

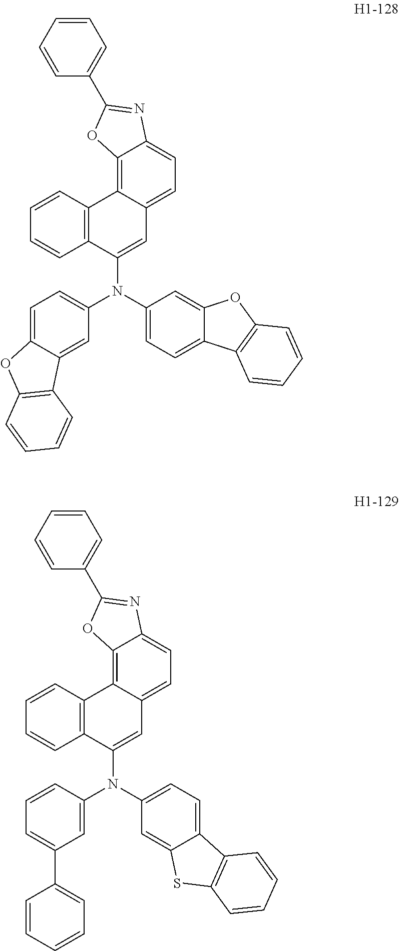 [SMILES: c1ccc(-c2nc3ccc4cc(N(c5ccc6c(c5)oc5ccccc56)c5ccc6oc7ccccc7c6c5)c5ccccc5c4c3o2)cc1 ; c1ccc(-c2cccc(N(c3ccc4c(c3)sc3ccccc34)c3cc4ccc5nc(-c6ccccc6)oc5c4c4ccccc34)c2)cc1]

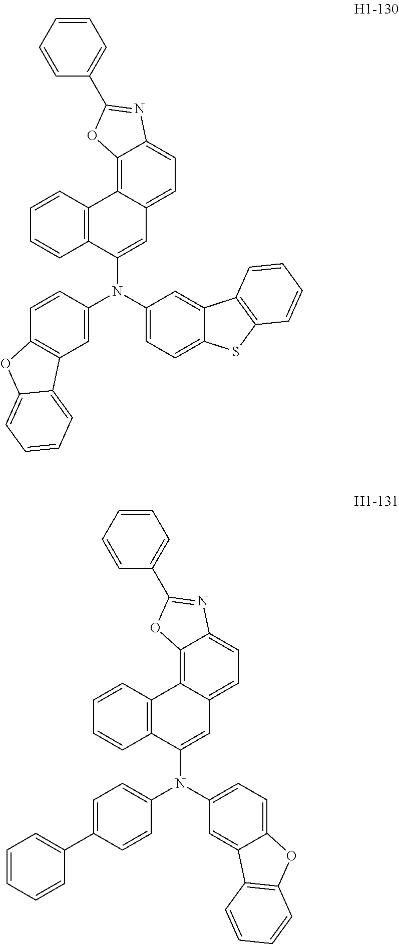 [SMILES: c1ccc(-c2nc3ccc4cc(N(c5ccc6oc7ccccc7c6c5)c5ccc6sc7ccccc7c6c5)c5ccccc5c4c3o2)cc1 ; c1ccc(-c2ccc(N(c3ccc4oc5ccccc5c4c3)c3cc4ccc5nc(-c6ccccc6)oc5c4c4ccccc34)cc2)cc1]

According to another embodiment of the present disclosure, an organic electroluminescent material comprising a compound represented by Formula 1 and a compound represented by the following Formula 3 is provided.

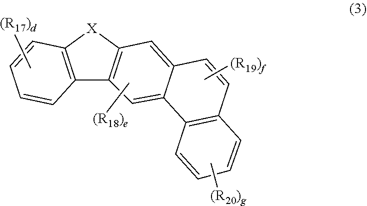

In Formula 3,

X represents O, S, CR₂₁R₂₂, NR₂₃, or Se. According to one embodiment of the present disclosure, X represents O or S. For example, X may be O.

R₂₁ to R₂₃ each independently represent hydrogen, deuterium, a halogen, a substituted or unsubstituted (C1-C30)alkyl, a substituted or unsubstituted (C6-C30)aryl, or a substituted or unsubstituted (3- to 30-membered)heteroaryl; or may be linked to an adjacent substituent(s) to form a ring(s). According to one embodiment of the present disclosure, R₂₁ to R₂₃ each independently may be hydrogen, deuterium, a halogen, or a substituted or unsubstituted (C1-C30)alkyl.

R₁₇ to R₂₀ each independently represent hydrogen, deuterium, a halogen, a substituted or unsubstituted (C1-C30)alkyl, a substituted or unsubstituted (C6—C30)aryl,

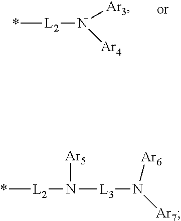

with a proviso that at least one of R₁₇ to R₂₀ is

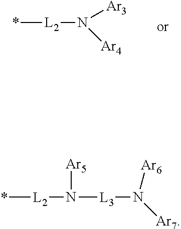

According to one embodiment of the present disclosure, R₁₇ to R₂₀ each independently represent hydrogen, deuterium, Ar₄, or

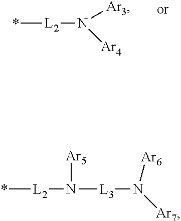

with a proviso that at least one of R₁₇ to R₂₀ is

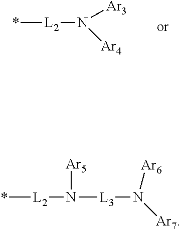

For example, R₁₇ to R₂₀ each independently may be hydrogen,

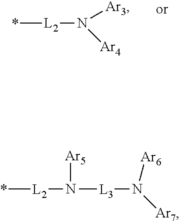

with a proviso that at least one of R₁₇ to R₂₀ may be

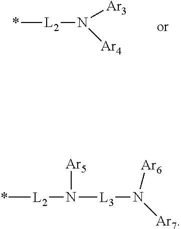

L₂ and L₃ each independently represent a single bond, a substituted or unsubstituted (C6-C30)arylene, a substituted or unsubstituted (C3-C30)cycloalkylene, or a substituted or unsubstituted (3- to 30-membered)heteroarylene. According to one embodiment of the present disclosure, L₂ and L₃ each independently represent a single bond, or a substituted or unsubstituted (C6-C30)arylene. For example, L₂ and L₃ each independently may be a single bond or a phenylene.

Ar₃ to Ar₇ each independently represent a substituted or unsubstituted (C6-C30)aryl or a substituted or unsubstituted (3- to 30-membered)heteroaryl. According to one embodiment of the present disclosure, Ar₃ to Ar₇ each independently represent a substituted or unsubstituted (C6-C25)aryl or a substituted or unsubstituted (3- to 25-membered)heteroaryl. For example, Ar₃ to Ar₇ each independently may be a phenyl, a phenyl substituted with a phenylpropyl(s), a biphenyl, a terphenyl, a naphthyl, a phenanthrenyl, a pyridinyl substituted with a phenyl(s), a dibenzofuranyl, a naphthyl substituted with a phenyl(s), a phenylcarbazolyl, or a dihydrophenanthrenyl substituted with a methyl(s).

d and g represent an integer of 1 to 4, e and f represent an integer of 1 or 2, where if d to g are an integer of 2 or more, each of R₁₇ to each of R₂₀ may be the same as or different from each other.

* represents a site linked to Formula 3.

According to one embodiment of the present disclosure, the compound represented by Formula 3 may be more specifically exemplified as the following compounds but is not limited thereto.

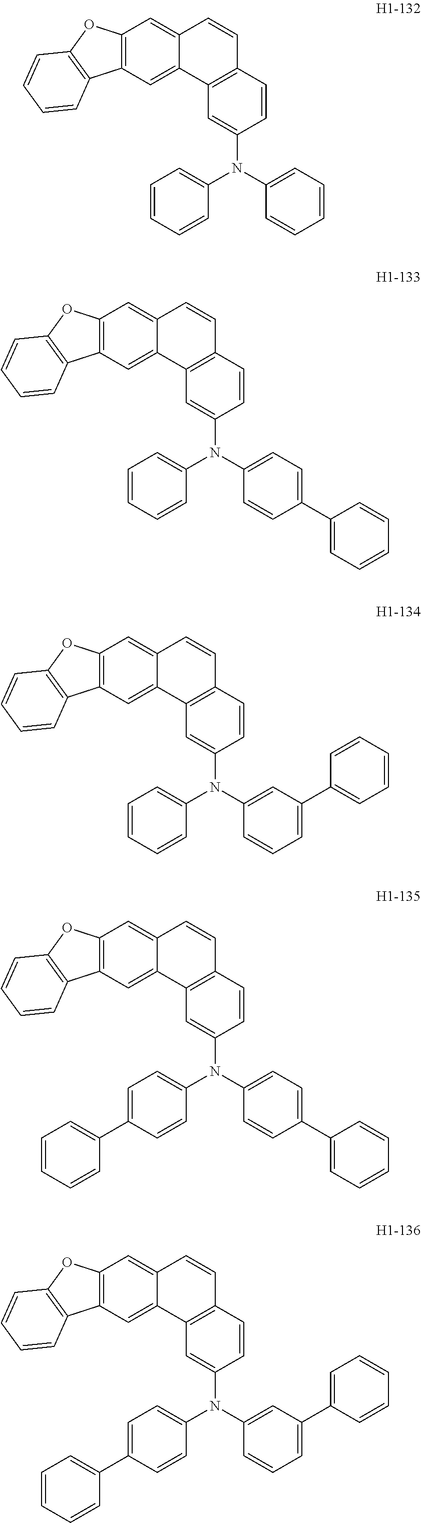 [SMILES: c1ccc(N(c2ccccc2)c2ccc3ccc4cc5oc6ccccc6c5cc4c3c2)cc1 ; c1ccc(-c2ccc(N(c3ccccc3)c3ccc4ccc5cc6oc7ccccc7c6cc5c4c3)cc2)cc1 ; c1ccc(-c2cccc(N(c3ccccc3)c3ccc4ccc5cc6oc7ccccc7c6cc5c4c3)c2)cc1 ; c1ccc(-c2ccc(N(c3ccc(-c4ccccc4)cc3)c3ccc4ccc5cc6oc7ccccc7c6cc5c4c3)cc2)cc1 ; c1ccc(-c2ccc(N(c3cccc(-c4ccccc4)c3)c3ccc4ccc5cc6oc7ccccc7c6cc5c4c3)cc2)cc1]

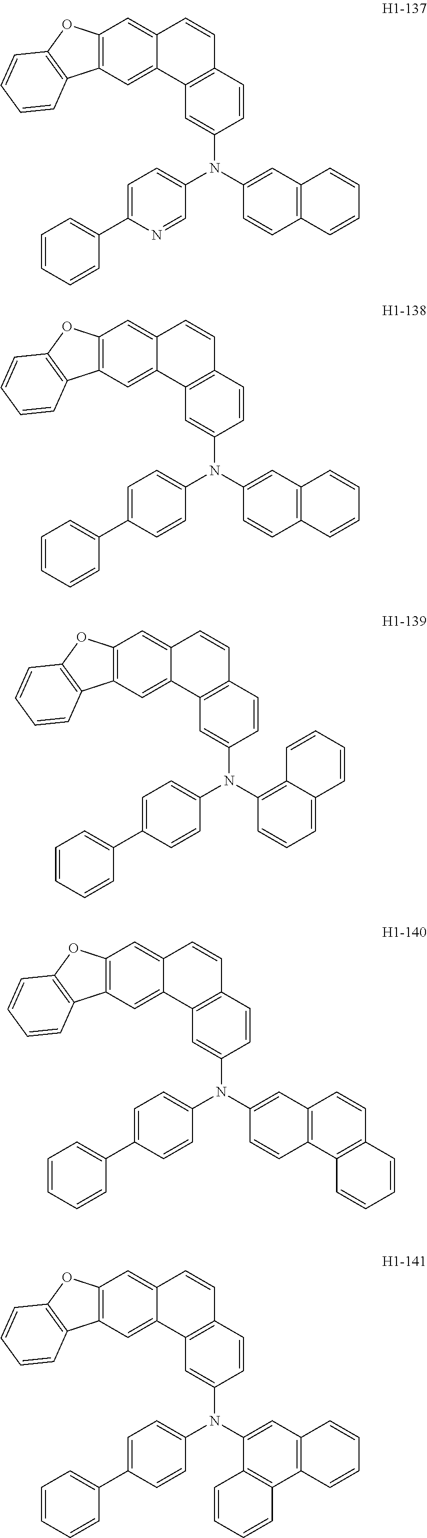

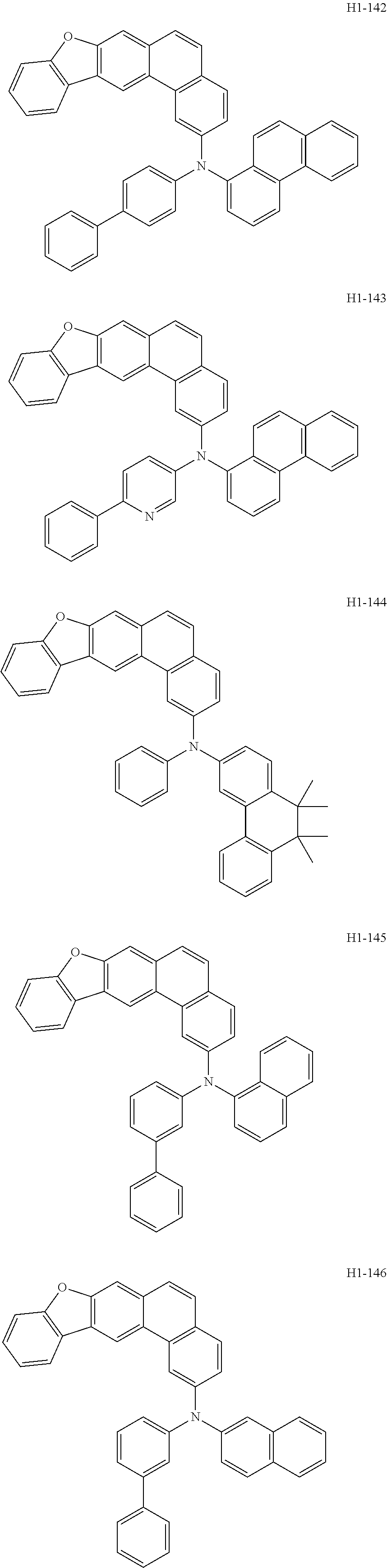 [SMILES: c1ccc(-c2ccc(N(c3ccc4ccc5cc6oc7ccccc7c6cc5c4c3)c3cccc4c3ccc3ccccc34)cc2)cc1 ; c1ccc(-c2ccc(N(c3ccc4ccc5cc6oc7ccccc7c6cc5c4c3)c3cccc4c3ccc3ccccc34)cn2)cc1 ; CC1(C)c2ccccc2-c2cc(N(c3ccccc3)c3ccc4ccc5cc6oc7ccccc7c6cc5c4c3)ccc2C1(C)C ; c1ccc(-c2cccc(N(c3ccc4ccc5cc6oc7ccccc7c6cc5c4c3)c3cccc4ccccc34)c2)cc1 ; c1ccc(-c2cccc(N(c3ccc4ccccc4c3)c3ccc4ccc5cc6oc7ccccc7c6cc5c4c3)c2)cc1]

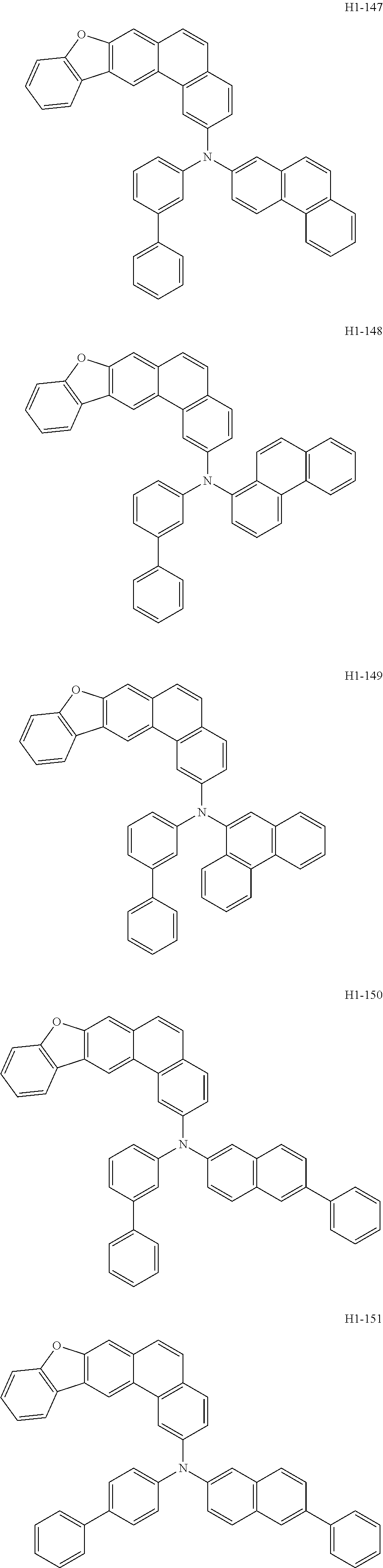 [SMILES: c1ccc(-c2cccc(N(c3ccc4c(ccc5ccccc54)c3)c3ccc4ccc5cc6oc7ccccc7c6cc5c4c3)c2)cc1 ; c1ccc(-c2cccc(N(c3ccc4ccc5cc6oc7ccccc7c6cc5c4c3)c3cccc4c3ccc3ccccc34)c2)cc1 ; c1ccc(-c2cccc(N(c3ccc4ccc5cc6oc7ccccc7c6cc5c4c3)c3cc4ccccc4c4ccccc34)c2)cc1 ; c1ccc(-c2cccc(N(c3ccc4cc(-c5ccccc5)ccc4c3)c3ccc4ccc5cc6oc7ccccc7c6cc5c4c3)c2)cc1 ; c1ccc(-c2ccc(N(c3ccc4cc(-c5ccccc5)ccc4c3)c3ccc4ccc5cc6oc7ccccc7c6cc5c4c3)cc2)cc1]

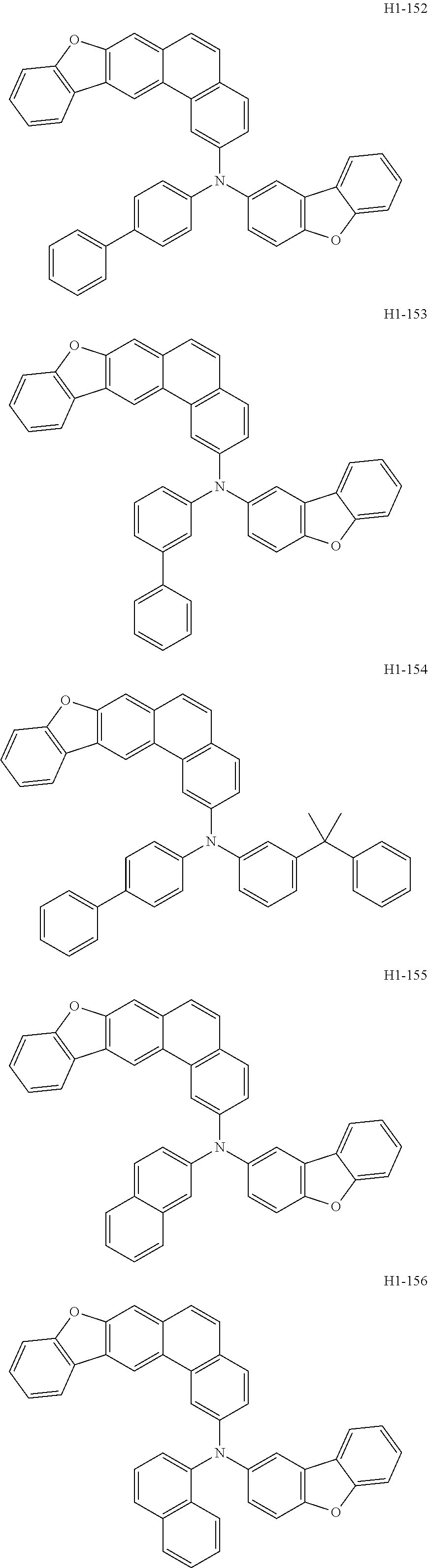

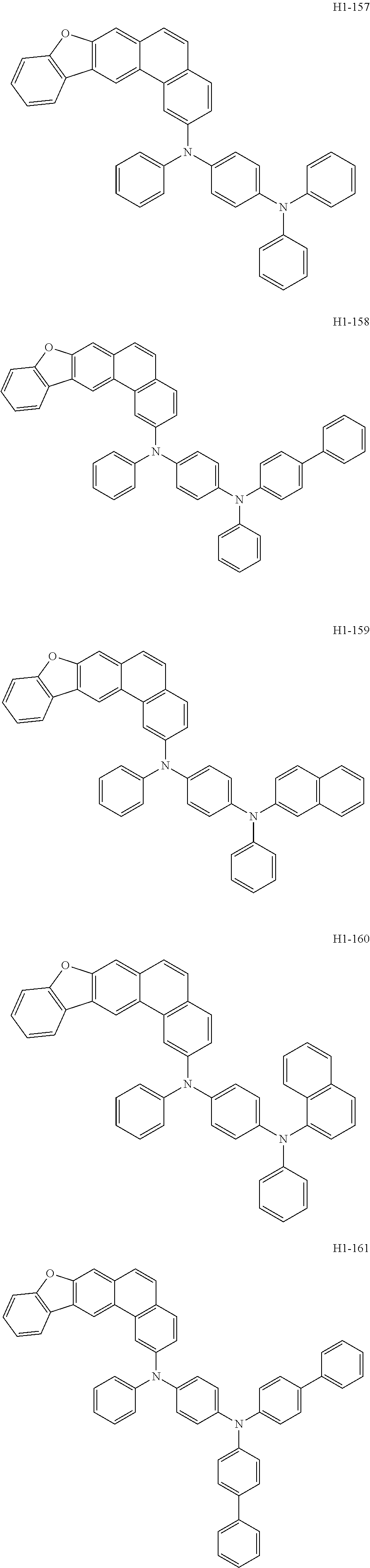 [SMILES: c1ccc(N(c2ccccc2)c2ccc(N(c3ccccc3)c3ccc4ccc5cc6oc7ccccc7c6cc5c4c3)cc2)cc1 ; c1ccc(-c2ccc(N(c3ccccc3)c3ccc(N(c4ccccc4)c4ccc5ccc6cc7oc8ccccc8c7cc6c5c4)cc3)cc2)cc1 ; c1ccc(N(c2ccc(N(c3ccccc3)c3ccc4ccc5cc6oc7ccccc7c6cc5c4c3)cc2)c2ccc3ccccc3c2)cc1 ; c1ccc(N(c2ccc(N(c3ccccc3)c3cccc4ccccc34)cc2)c2ccc3ccc4cc5oc6ccccc6c5cc4c3c2)cc1 ; c1ccc(-c2ccc(N(c3ccc(-c4ccccc4)cc3)c3ccc(N(c4ccccc4)c4ccc5ccc6cc7oc8ccccc8c7cc6c5c4)cc3)cc2)cc1]

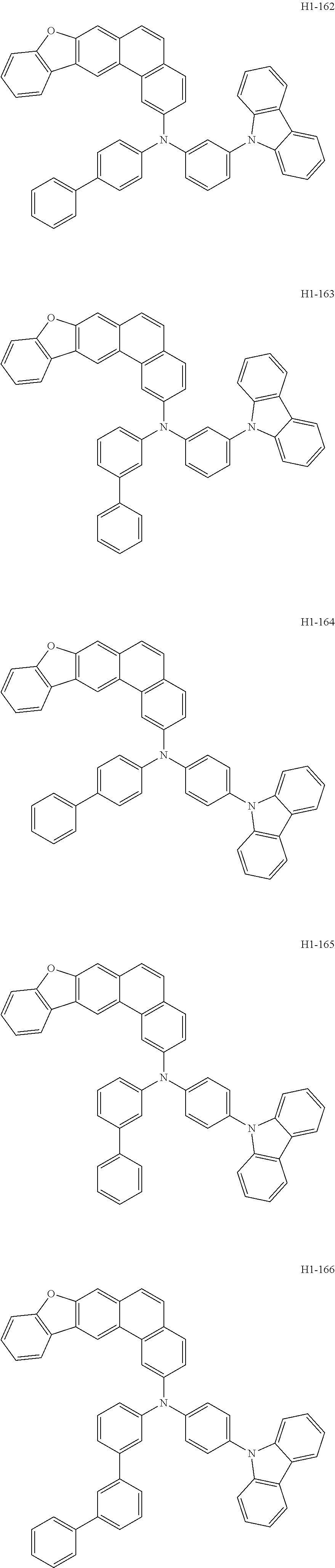 [SMILES: c1ccc(-c2ccc(N(c3cccc(-n4c5ccccc5c5ccccc54)c3)c3ccc4ccc5cc6oc7ccccc7c6cc5c4c3)cc2)cc1 ; c1ccc(-c2cccc(N(c3cccc(-n4c5ccccc5c5ccccc54)c3)c3ccc4ccc5cc6oc7ccccc7c6cc5c4c3)c2)cc1 ; c1ccc(-c2ccc(N(c3ccc(-n4c5ccccc5c5ccccc54)cc3)c3ccc4ccc5cc6oc7ccccc7c6cc5c4c3)cc2)cc1 ; c1ccc(-c2cccc(N(c3ccc(-n4c5ccccc5c5ccccc54)cc3)c3ccc4ccc5cc6oc7ccccc7c6cc5c4c3)c2)cc1 ; c1ccc(-c2cccc(-c3cccc(N(c4ccc(-n5c6ccccc6c6ccccc65)cc4)c4ccc5ccc6cc7oc8ccccc8c7cc6c5c4)c3)c2)cc1]

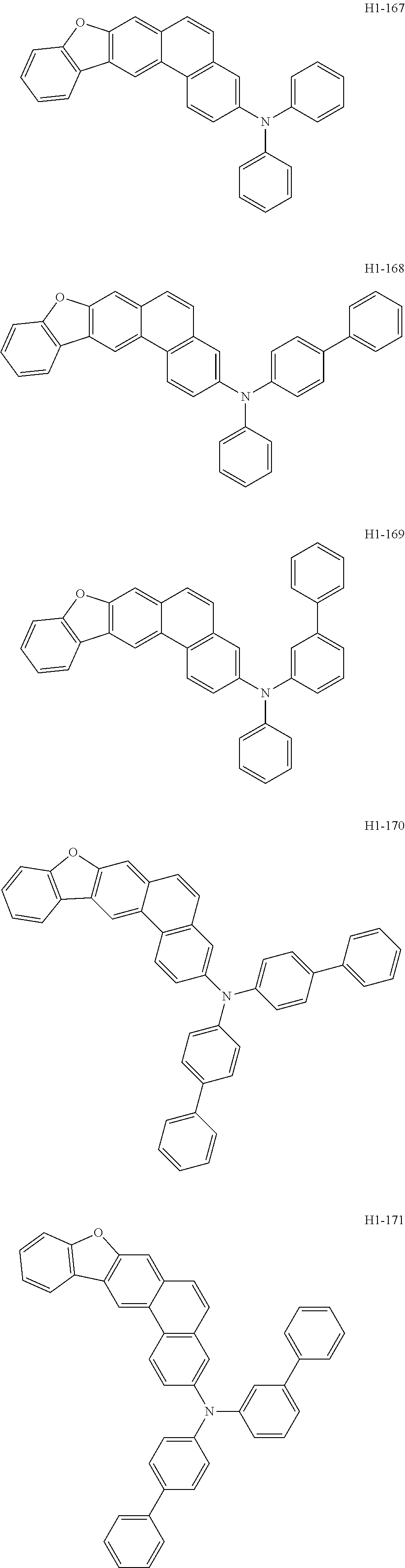 [SMILES: c1ccc(N(c2ccccc2)c2ccc3c(ccc4cc5oc6ccccc6c5cc43)c2)cc1 ; c1ccc(-c2ccc(N(c3ccccc3)c3ccc4c(ccc5cc6oc7ccccc7c6cc54)c3)cc2)cc1 ; c1ccc(-c2cccc(N(c3ccccc3)c3ccc4c(ccc5cc6oc7ccccc7c6cc54)c3)c2)cc1 ; c1ccc(-c2ccc(N(c3ccc(-c4ccccc4)cc3)c3ccc4c(ccc5cc6oc7ccccc7c6cc54)c3)cc2)cc1 ; c1ccc(-c2ccc(N(c3cccc(-c4ccccc4)c3)c3ccc4c(ccc5cc6oc7ccccc7c6cc54)c3)cc2)cc1]

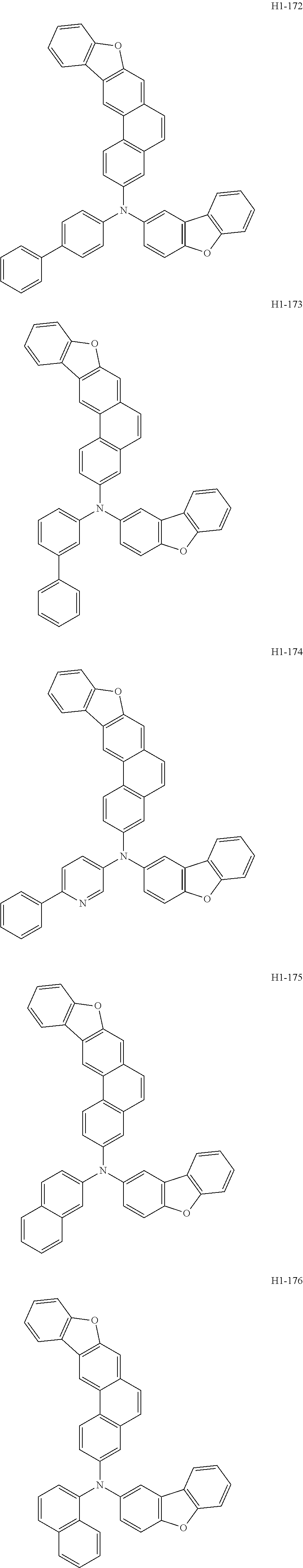 [SMILES: c1ccc(-c2ccc(N(c3ccc4c(ccc5cc6oc7ccccc7c6cc54)c3)c3ccc4oc5ccccc5c4c3)cc2)cc1 ; c1ccc(-c2cccc(N(c3ccc4c(ccc5cc6oc7ccccc7c6cc54)c3)c3ccc4oc5ccccc5c4c3)c2)cc1 ; c1ccc(-c2ccc(N(c3ccc4c(ccc5cc6oc7ccccc7c6cc54)c3)c3ccc4oc5ccccc5c4c3)cn2)cc1 ; c1ccc2cc(N(c3ccc4c(ccc5cc6oc7ccccc7c6cc54)c3)c3ccc4oc5ccccc5c4c3)ccc2c1 ; c1ccc2c(N(c3ccc4c(ccc5cc6oc7ccccc7c6cc54)c3)c3ccc4oc5ccccc5c4c3)cccc2c1]

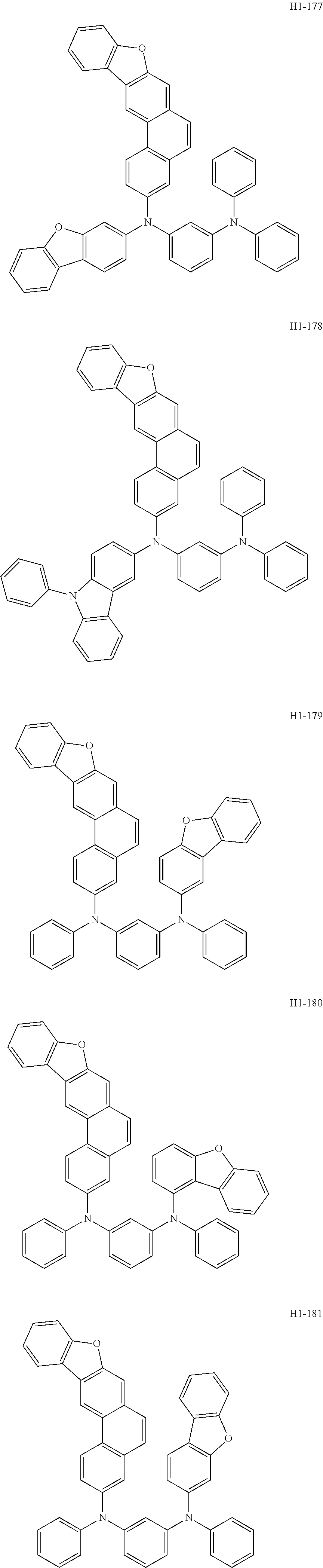 [SMILES: c1ccc(N(c2ccccc2)c2cccc(N(c3ccc4c(ccc5cc6oc7ccccc7c6cc54)c3)c3ccc4c(c3)oc3ccccc34)c2)cc1 ; c1ccc(N(c2ccccc2)c2cccc(N(c3ccc4c(ccc5cc6oc7ccccc7c6cc54)c3)c3ccc4c(c3)c3ccccc3n4-c3ccccc3)c2)cc1 ; c1ccc(N(c2cccc(N(c3ccccc3)c3ccc4oc5ccccc5c4c3)c2)c2ccc3c(ccc4cc5oc6ccccc6c5cc43)c2)cc1 ; c1ccc(N(c2cccc(N(c3ccccc3)c3cccc4oc5ccccc5c34)c2)c2ccc3c(ccc4cc5oc6ccccc6c5cc43)c2)cc1 ; c1ccc(N(c2cccc(N(c3ccccc3)c3ccc4c(c3)oc3ccccc34)c2)c2ccc3c(ccc4cc5oc6ccccc6c5cc43)c2)cc1]

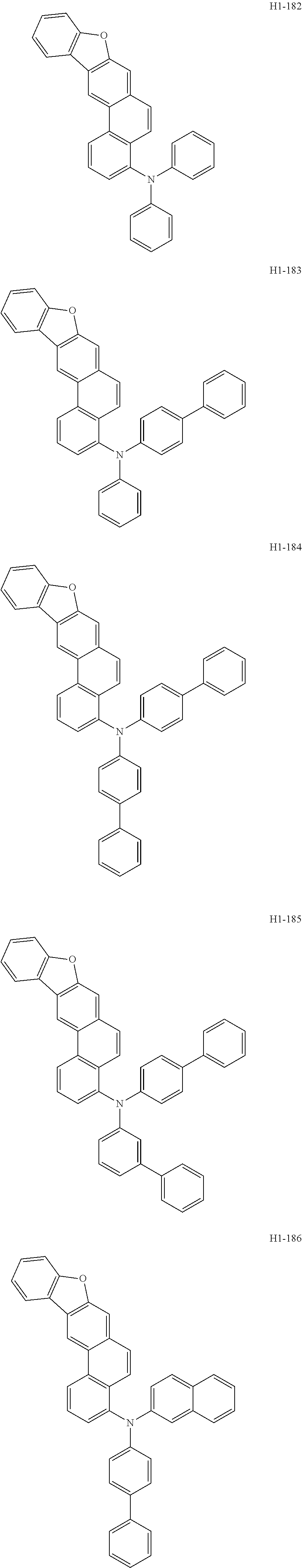 [SMILES: c1ccc(N(c2ccccc2)c2cccc3c2ccc2cc4oc5ccccc5c4cc23)cc1 ; c1ccc(-c2ccc(N(c3ccccc3)c3cccc4c3ccc3cc5oc6ccccc6c5cc34)cc2)cc1 ; c1ccc(-c2ccc(N(c3ccc(-c4ccccc4)cc3)c3cccc4c3ccc3cc5oc6ccccc6c5cc34)cc2)cc1 ; c1ccc(-c2ccc(N(c3cccc(-c4ccccc4)c3)c3cccc4c3ccc3cc5oc6ccccc6c5cc34)cc2)cc1 ; c1ccc(-c2ccc(N(c3ccc4ccccc4c3)c3cccc4c3ccc3cc5oc6ccccc6c5cc34)cc2)cc1]

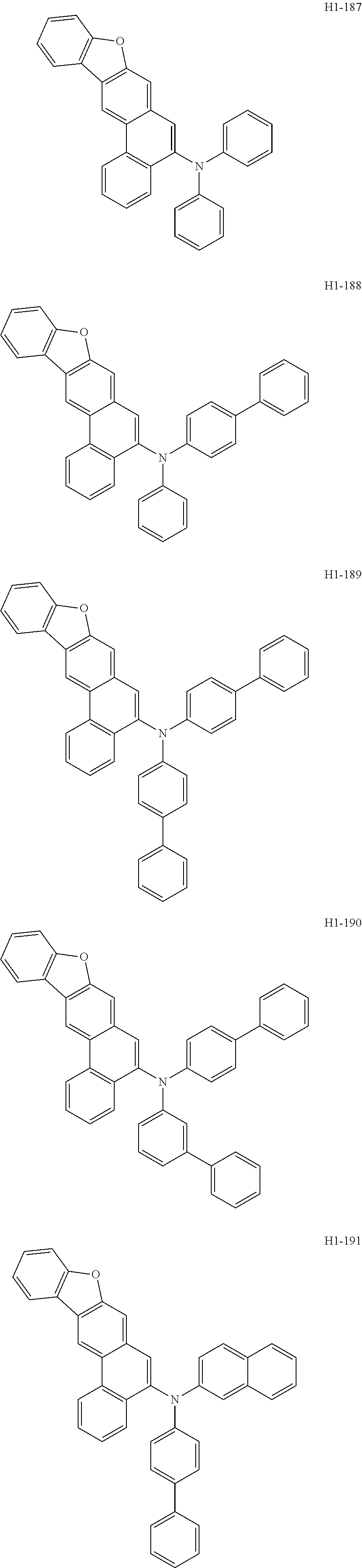 [SMILES: c1ccc(N(c2ccccc2)c2cc3cc4oc5ccccc5c4cc3c3ccccc23)cc1 ; c1ccc(-c2ccc(N(c3ccccc3)c3cc4cc5oc6ccccc6c5cc4c4ccccc34)cc2)cc1 ; c1ccc(-c2ccc(N(c3ccc(-c4ccccc4)cc3)c3cc4cc5oc6ccccc6c5cc4c4ccccc34)cc2)cc1 ; c1ccc(-c2ccc(N(c3cccc(-c4ccccc4)c3)c3cc4cc5oc6ccccc6c5cc4c4ccccc34)cc2)cc1 ; c1ccc(-c2ccc(N(c3ccc4ccccc4c3)c3cc4cc5oc6ccccc6c5cc4c4ccccc34)cc2)cc1]

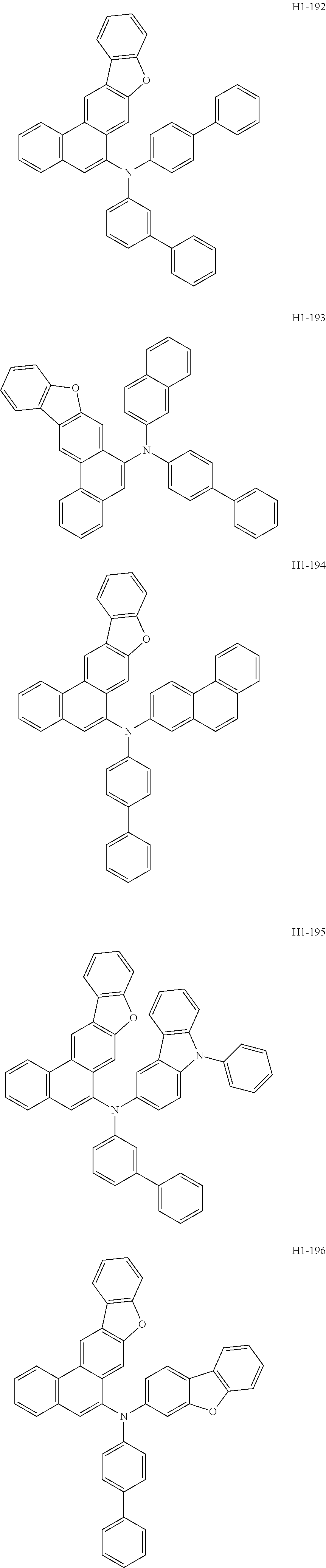 [SMILES: c1ccc(-c2ccc(N(c3cccc(-c4ccccc4)c3)c3cc4ccccc4c4cc5c(cc34)oc3ccccc35)cc2)cc1 ; c1ccc(-c2ccc(N(c3ccc4ccccc4c3)c3cc4ccccc4c4cc5c(cc34)oc3ccccc35)cc2)cc1 ; c1ccc(-c2ccc(N(c3ccc4c(ccc5ccccc54)c3)c3cc4ccccc4c4cc5c(cc34)oc3ccccc35)cc2)cc1 ; c1ccc(-c2cccc(N(c3ccc4c(c3)c3ccccc3n4-c3ccccc3)c3cc4ccccc4c4cc5c(cc34)oc3ccccc35)c2)cc1 ; c1ccc(-c2ccc(N(c3ccc4c(c3)oc3ccccc34)c3cc4ccccc4c4cc5c(cc34)oc3ccccc35)cc2)cc1]

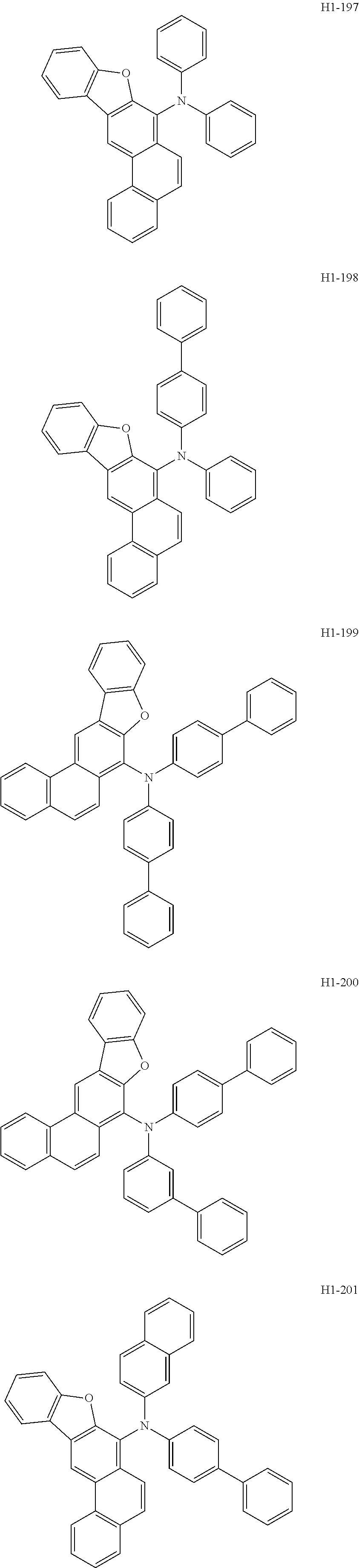 [SMILES: c1ccc(N(c2ccccc2)c2c3ccc4ccccc4c3cc3c2oc2ccccc23)cc1 ; c1ccc(-c2ccc(N(c3ccccc3)c3c4ccc5ccccc5c4cc4c3oc3ccccc34)cc2)cc1 ; c1ccc(-c2ccc(N(c3ccc(-c4ccccc4)cc3)c3c4ccc5ccccc5c4cc4c3oc3ccccc34)cc2)cc1 ; c1ccc(-c2ccc(N(c3cccc(-c4ccccc4)c3)c3c4ccc5ccccc5c4cc4c3oc3ccccc34)cc2)cc1 ; c1ccc(-c2ccc(N(c3ccc4ccccc4c3)c3c4ccc5ccccc5c4cc4c3oc3ccccc34)cc2)cc1]

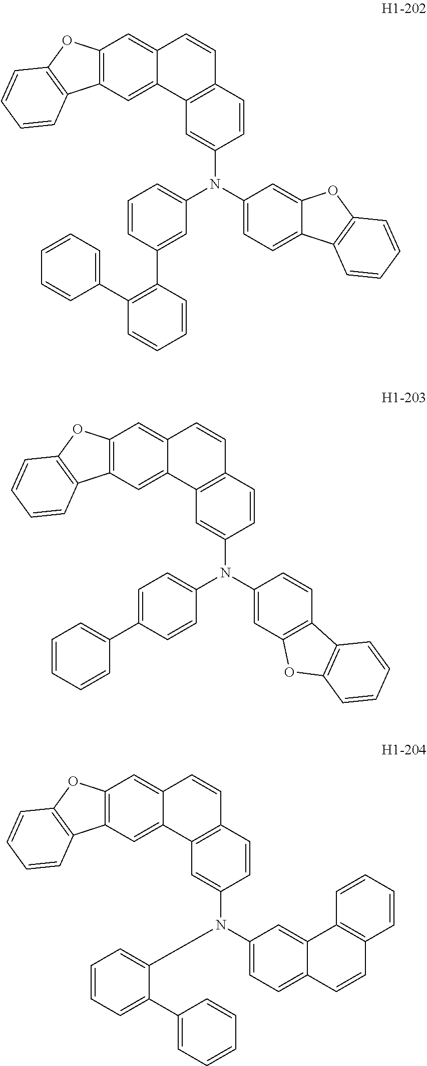 [SMILES: c1ccc(-c2ccccc2-c2cccc(N(c3ccc4c(c3)oc3ccccc34)c3ccc4ccc5cc6oc7ccccc7c6cc5c4c3)c2)cc1 ; c1ccc(-c2ccc(N(c3ccc4c(c3)oc3ccccc34)c3ccc4ccc5cc6oc7ccccc7c6cc5c4c3)cc2)cc1 ; c1ccc(-c2ccccc2N(c2ccc3ccc4ccccc4c3c2)c2ccc3ccc4cc5oc6ccccc6c5cc4c3c2)cc1]

The compound represented by Formula 1 and at least one of Compounds H1-1 to H1-131 can be used in an organic electroluminescent material. According to one embodiment of the present disclosure, the present disclosure provides an organic electroluminescent device comprising the organic electroluminescent material.

The compound represented by Formula 1 and at least one of Compounds H1-132 to H1-204 can be used in an organic electroluminescent material. According to one embodiment of the present disclosure, the present disclosure provides an organic electroluminescent device comprising the organic electroluminescent material.

The compound represented by Formula 1 according to the present disclosure may be produced by referring to the following Reaction Scheme 1, but is not limited thereto.

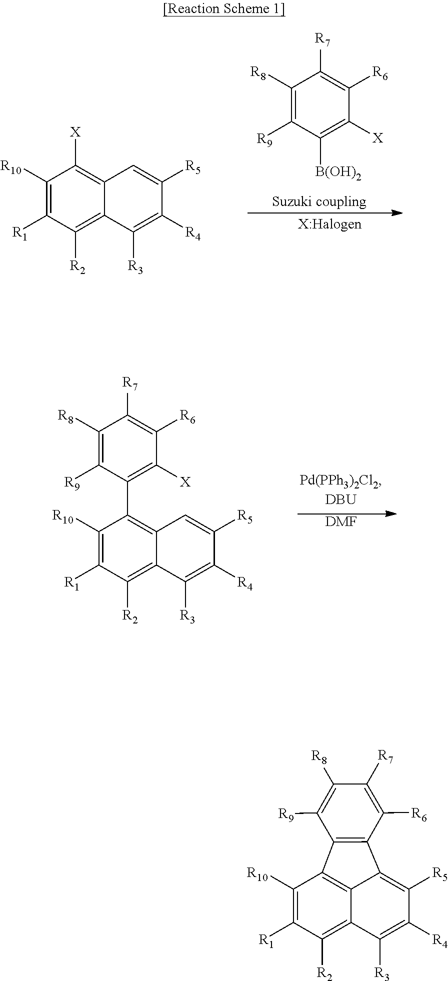

In Reaction Scheme 1, R₁ to R₁₀ are as defined for Formula 1.

The compound represented by Formula 2 according to the present disclosure may be synthesized by referring to synthetic methods known to one skilled in the art, and in particular, as synthetic method disclosed in a number of patent documents can be used. For example, it may be synthesized by referring to synthetic methods disclosed in Korean Patent Application Laid-Open No. 2017-0022865 (published on Jun. 24, 2032), etc., but is not limited thereto.

The compound represented by Formula 3 according to the present disclosure may be produced by referring to the following Reaction Scheme 2, but is not limited thereto, and it can also be produced by way of synthetic methods known to one skilled in the art.

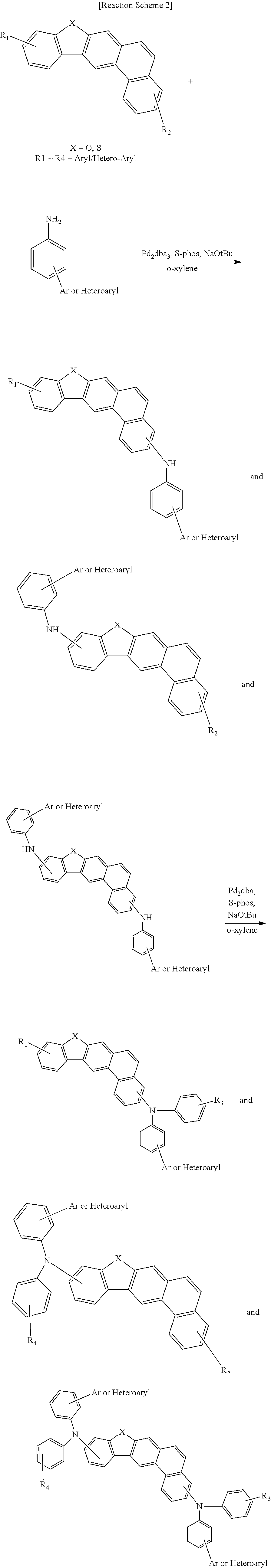

Although illustrative synthesis examples of the compounds represented by Formulas 1 to 3 are described above, one skilled in the art will be able to readily understand that all of them are based on a Buchwald-Hartwig cross coupling reaction, a N-arylation reaction, an H-mont-mediated etherification reaction, a Miyaura borylation reaction, a Suzuki cross-coupling reaction, an intramolecular acid-induced cyclization reaction, a Pd(II)-catalyzed oxidative cyclization reaction, a Grignard reaction, a Heck reaction, a cyclic dehydration reaction, an SN1 substitution reaction, an SN2 substitution reaction, a phosphine-mediated reductive cyclization reaction, and Wittig reaction, etc., and the above reactions proceed even when substituents defined in Formulas 1 to 3 other than the substituents specified in the specific synthesis examples are bonded.

Hereinafter, an organic electroluminescent device using the compound and an organic electroluminescent material comprising the same will be described.

According to one embodiment of the present disclosure, the organic electroluminescent device of the present disclosure comprises a first electrode; a second electrode; and at least one organic layer between the first electrode and the second electrode, wherein the organic layer includes a hole transport layer and a light-emitting layer. According to one example, the hole transport layer may include a compound represented by Formula 1. According to another example, the light-emitting layer may include a compound represented by Formula 1 as a first host compound and a compound represented by Formula 2 as a second host compound. Here, the weight ratio of the first host compound to the second host compound may be included in the light-emitting layer in a range of about 1:99 to about 99:1, preferably about 10:90 to about 90:10, more preferably about 30:70 to about 70:30, more preferably about 40:60 to about 60:40, and even more preferably about 50:50. According to another example, the light-emitting layer may include a compound represented by Formula 1 as a first host compound and a compound represented by Formula 3 as a second host compound. Here, the weight ratio of the first host compound to the second host compound may be included in the light-emitting layer in a range of about 1:99 to about 99:1, preferably about 10:90 to about 90:10, more preferably about 30:70 to about 70:30, more preferably about 40:60 to about 60:40, and even more preferably about 50:50.

According to one example, the organic electroluminescent material of the present disclosure comprises at least one compound among Compounds H2-1 to H2-305 and at least one compound among Compounds H1-1 to H1-131, and these organic electroluminescent materials may be comprised in the same organic layer, for example, the light-emitting layer, or may be comprised in different light-emitting layers, respectively. In addition, according to another example, the organic electroluminescent material of the present disclosure comprises at least one compound among Compounds H2-1 to H2-305 and at least one compound among Compounds H1-132 to H1-204, and these organic electroluminescent materials may be comprised in the same organic layer, for example, the light-emitting layer, or may be comprised in different light-emitting layers, respectively.

In addition to the hole transport layer and the light-emitting layer, the organic layer may further include at least one layers selected from a hole injection layer, a hole auxiliary layer, an light-emitting auxiliary layer, an electron transport layer, an electron injection layer, an interlayer, a hole-blocking layer, an electron-blocking layer, and an electron buffer layer. The organic layer may further comprise an amine-based compound and/or an azine-based compound in addition to the light-emitting material of the present disclosure. Specifically, the hole injection layer, the hole transport layer, the hole auxiliary layer, the light-emitting layer, the light-emitting auxiliary layer, or the electron-blocking layer may comprise an amine-based compound, for example, an arylamine-based compound, a styrylarylamine-based compound, etc., as a hole injection material, a hole transport material, a hole auxiliary material, a light-emitting material, a light-emitting auxiliary material, or an electron-blocking material. In addition, the electron transport layer, the electron injection layer, the electron buffer layer and the hole-blocking layer may comprise an azine-based compound as an electron transport material, an electron injection material, an electron buffer material or a hole-blocking material. In addition, the organic layer may further comprise at least one metal selected from the group consisting of metals of Group 1, metals of Group 2, transition metals of the 4^{th} period, transition metals of the 5^{th} period, lanthanides, and organic metals of the d-transition elements of the Periodic Table, or at least one complex compound comprising the metal thereof.

The organic electroluminescent material according to one embodiment of the present disclosure may be used as a light-emitting material for a white organic light-emitting device. The white organic light-emitting device has been suggested to have various structures such as a side-by-side structure or a stacking structure depending on the arrangement of R (Red), G (Green) or YG (Yellowish Green), and B (Blue) light-emitting parts, or a color conversion material (CCM) method, etc. In addition, the compound or the organic electroluminescent material according to one embodiment of the present disclosure may also be used in an organic electroluminescent device comprising a quantum dot (QD).

One of the first electrode and the second electrode may be an anode and the other may be a cathode. At this time, the first electrode and the second electrode may each be formed of a transparent conductive material or a semi-transparent or reflective conductive material. Depending on the type of material forming the first electrode and second electrode, the organic electroluminescent device can be a front emitting type, a back emitting type, or a double-sided emitting type.

A hole injection layer, a hole transport layer, an electron-blocking layer, or a combination thereof may be used between the anode and the light-emitting layer. The hole injection layer may be composed of multiple layers for the purpose of lowering the hole injection barrier (or hole injection voltage) from the anode to the hole transport layer or electron-blocking layer, and each layer may use two compounds simultaneously. In addition, the hole injection layer may be doped with a p-type dopant. The electron-blocking layer may be placed between the hole transport layer (or hole injection layer) and the light-emitting layer, and may block the overflow of electrons from the light-emitting layer and confine the excitons in the light-emitting layer to prevent light leakage. The hole transport layer or electron-blocking layer may use multiple layers, and multiple compounds may be used in each layer.

An electron buffer layer, a hole-blocking layer, an electron transport layer, an electron injection layer, or a combination thereof can be used between the light-emitting layer and the cathode. The electron buffer layer may be multi-layers in order to control the injection of the electron and improve the interfacial properties between the light-emitting layer and the electron injection layer, wherein each of the multi-layers may use two compounds simultaneously. The hole-blocking layer is located between the electron transport layer (or electron injection layer) and the light-emitting layer and is a layer that blocks holes from reaching the cathode, thereby improving the probability of recombination of electrons and holes in the light-emitting layer. The hole-blocking layer or electron transport layer may also be multiple layers, and multiple compounds may be used in each layer. In addition, the electron injection layer may be doped with an n-type dopant.

The light-emitting auxiliary layer may be a layer placed between an anode and a light-emitting layer, or between a cathode and a light-emitting layer. When the light-emitting auxiliary layer placed between the anode and the light-emitting layer, the light-emitting auxiliary layer may be used to facilitate hole injection and/or hole transport or to block the overflow of electrons. When the light-emitting auxiliary layer placed between the cathode and the light-emitting layer, the light-emitting auxiliary layer may be used to facilitate electron injection and/or electron transport or to block the overflow of holes. In addition, the hole auxiliary layer may be placed between the hole transport layer (or hole injection layer) and the light-emitting layer, and may exhibit an effect of facilitating or-blocking the hole transport rate (or hole injection rate), and accordingly, may adjust the charge balance. When an organic electroluminescent device includes two or more hole transport layers, the hole transport layer, which is further included, may be used as a hole auxiliary layer or an electron-blocking layer. The light-emitting auxiliary layer, the hole auxiliary layer, or the electron-blocking layer may have an effect of improving the efficiency and/or lifetime of the organic electroluminescent device.

In the organic electroluminescent device of the present disclosure, it is preferable to dispose at least one layer selected from a chalcogenide layer, a metal halide layer, and a metal oxide layer (hereinafter referred to as a “surface layer”) on at least one inner surface of a pair of electrodes. Specifically, a chalcogenide (including oxide) layer of silicon and aluminum is preferably placed on an anode surface of an electroluminescent medium layer side, and a metal halide layer or a metal oxide layer is preferably placed on a cathode surface of an electroluminescent medium layer side. Driving stabilization of the organic electroluminescent device can be obtained by the surface layer. Preferred examples of the chalcogenide include SiO_{X} (1≤X≤2), AlO_{X} (1≤X≤1.5), SiON, SiAlON, etc., preferred examples of the metal halide include LiF, MgF₂, CaF₂, a rare earth metal fluoride, etc., and preferred examples of the metal oxide include Cs₂O, Li₂O, MgO, SrO, BaO, CaO, etc.

In addition, in an organic electroluminescent device of the present disclosure, a mixed region of an electron transport compound and a reductive dopant, or a mixed region of a hole transport compound and an oxidative dopant, may be placed on at least one surface of a pair of electrodes. In this case, the electron transport compound is reduced to an anion, and thus it becomes easier to inject and transport electrons from the mixed region to the light-emitting medium. Furthermore, the hole transport compound is oxidized to a cation, and thus it becomes easier to inject and transport holes from the mixed region to the light-emitting medium. Preferred oxidative dopants include various Lewis acids and acceptor compounds, and preferred reductive dopants include alkali metals, alkali metal compounds, alkaline earth metals, rare earth metals, and mixtures thereof. In addition, an organic electroluminescent device having at least two light-emitting layers and emitting white light may be manufactured by using the reductive dopant layer as a charge-generating layer.

An organic electroluminescent device according to the present disclosure may be an organic electroluminescent device having a tandem structure. In the case of the tandem organic electroluminescent device according to one embodiment, a single light-emitting unit (light-emitting part) may be formed in a structure in which two or more units are connected by a charge generation layer. The organic electroluminescent device may include a plurality of two or more light-emitting units, for example, a plurality of three or more light-emitting units, having first and second electrodes opposed to each other on a substrate and a light-emitting layer stacked between the first and second electrodes and emits light in a specific wavelength range. It may include a plurality of light-emitting units, and each of the light-emitting units may include a hole transport zone, a light-emitting layer, and an electron transport zone, and the hole transport zone may include a hole injection layer and a hole transport layer, the electron transport zone may include an electron transport layer and an electron injection layer. According to one embodiment of the present disclosure, three or more light-emitting layers may be included in the light-emitting unit. A plurality of light-emitting units may emit the same color or different colors. Additionally, one light-emitting unit may include one or more light-emitting layers, the plurality of light-emitting layers may be light-emitting layers of the same or different colors. It may include one or more charge generation layers located between each light-emitting unit. The charge generation layer refers to the layer in which holes and electrons are generated when voltage is applied. When there are three or more light-emitting units, a charge generation layer may be located between each light-emitting unit. At this time, the plurality of charge generation layers may be the same as or different from each other. By disposing the charge generating layer between light-emitting units, current efficiency is increased in each light-emitting unit and charges can be smoothly distributed. Specifically, the charge generation layer is provided between two adjacent stacks and can serve to drive a tandem organic electroluminescent device using only a pair of anodes and cathodes without a separate internal electrode located between the stacks.

The charge generation layer may be composed of an N-type charge generation layer and a P-type charge generation layer, and the N-type charge generation layer may be doped with an alkali metal, an alkaline earth metal, or a compound of an alkali metal and an alkaline earth metal. The alkali metal may include one selected from the group consisting of Li, Na, K, Rb, Cs, Fr, Yb, and the combinations thereof, and the alkaline earth metal may include one selected from the group consisting of Be, Mg, Ca, Sr, Ba, Ra, and the combinations thereof. The P-type charge generation layer may be made of a metal or an organic material doped with a P-type dopant. For example, the metal may be made of one or two or more alloys selected from the group consisting of Al, Cu, Fe, Pb, Zn, Au, Pt, W, In, Mo, Ni, and Ti. Additionally, commonly used materials may be used as the P-type dopant and host materials used in the P-type doped organic material.

The manufacturing method of the organic electroluminescent device of the present disclosure is not limited, and the manufacturing method of the Device Example as described below is only an example and is not limited thereto. One skilled in the art can reasonably modify the manufacturing method of the Device Examples as described below by relying on existing technology. For example, there is no particular limitation on the mixing ratio of the first compound and the second compound, and thus one skilled in the art can reasonably select it within a certain range by depending on existing technology. For example, based on the total weight of the light-emitting layer material, the total weight of the first compound and the second compound accounts for 99.5%-80.0% of the total weight of the light-emitting layer, the weight ratio of the first compound and the second compound is between 1:99 and 99:1, the weight ratio of the first compound and the second compound may be between 20:80 and 99:1, or the weight ratio of the first compound and the second compound may be between 50:50 and 90:10. In the manufacture of devices, when forming a light-emitting layer by co-depositing two or more host materials and a light-emitting material, the two or more host materials and the light-emitting material may each be placed in different evaporation sources and co-deposited to form a light-emitting layer, or a pre-mixed mixture of two or more host materials may be placed on the same evaporation source and then co-deposited with a light-emitting material placed on another evaporation source to form a light-emitting layer. This premixing method can further save evaporation sources. According to one embodiment, the first compound, the second compound, and the light-emitting material of the present disclosure may each be placed in different evaporation sources and co-deposited to form a light-emitting layer, or a pre-mixed mixture of the first compound and the second compound may be placed in the same evaporation source and then co-deposited with a light-emitting material placed in another evaporation source to form a light-emitting layer.

An organic electroluminescent device according to one embodiment may further include one or more dopants in the light-emitting layer.

The dopant comprised in the organic electroluminescent device of the present disclosure may be at least one phosphorescent or fluorescent dopant, and is preferably a phosphorescent dopant. The phosphorescent dopant material applied to the organic electroluminescent device of the present disclosure is not particularly limited, but may be preferably selected from the group consisting of the metallated complex compounds of iridium (Ir), osmium (Os), copper (Cu), and platinum (Pt), more preferably selected from the group consisting of ortho-metallated complex compounds of iridium (Ir), osmium (Os), copper (Cu), and platinum (Pt), and even more preferably ortho-metallated iridium complex compounds.

The dopant comprised in the organic electroluminescent device of the present disclosure may be a compound represented by the following Formula 101, but is not limited thereto.

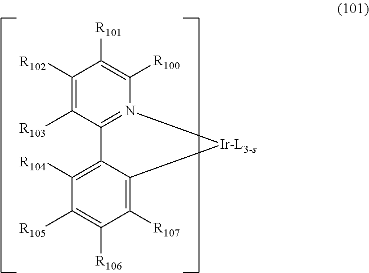

In Formula 101,

L is any one selected from the following structures 1 to 3;

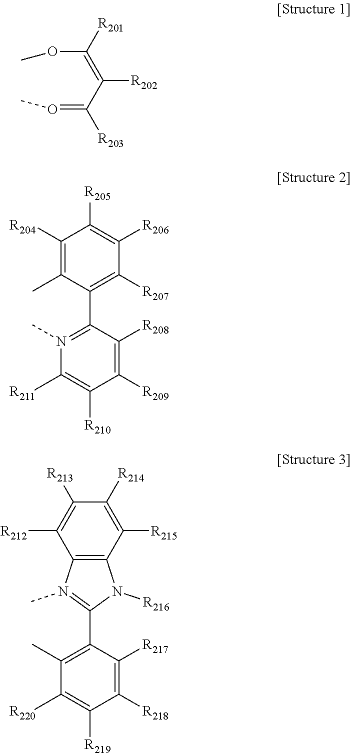

R₁₀₀ to R₁₀₃ each independently represent hydrogen, deuterium, a halogen, a (C1-C30)alkyl unsubstituted or substituted with deuterium and/or a halogen(s), a substituted or unsubstituted (C3-C30)cycloalkyl, a substituted or unsubstituted (C6-C30)aryl, a cyano, a substituted or unsubstituted (3- to 30-membered)heteroaryl, or a substituted or unsubstituted (C1-C30)alkoxy; or may be linked to an adjacent substituent(s) to form a ring(s), e.g., a substituted or unsubstituted, quinoline, benzofuropyridine, benzothienopyridine, indenopyridine, benzofuroquinoline, benzothienoquinoline, or indenoquinoline, together with pyridine;

R₁₀₄ to R₁₀₇ each independently represent hydrogen, deuterium, a halogen, a (C1-C30)alkyl unsubstituted or substituted with deuterium and/or a halogen(s), a substituted or unsubstituted (C3-C30)cycloalkyl, a substituted or unsubstituted (C6-C30)aryl, a substituted or unsubstituted (3- to 30-membered)heteroaryl, a cyano, or a substituted or unsubstituted (C1-C30)alkoxy; or may be linked to an adjacent substituent(s) to form a substituted or unsubstituted ring(s), e.g., a substituted or unsubstituted, naphthalene, fluorene, dibenzothiophene, dibenzofuran, indenopyridine, benzofuropyridine, or benzothienopyridine, together with benzene;

R₂₀₁ to R₂₂₀ each independently represent hydrogen, deuterium, a halogen, a (C1-C30)alkyl unsubstituted or substituted with deuterium and/or a halogen(s), a substituted or unsubstituted (C3-C30)cycloalkyl, or a substituted or unsubstituted (C6-C30)aryl; or may be linked to an adjacent substituent(s) to form a substituted or unsubstituted ring(s); and

s represents an integer of 1 to 3.

The specific examples of the dopant compound are as follows, but are not limited thereto.

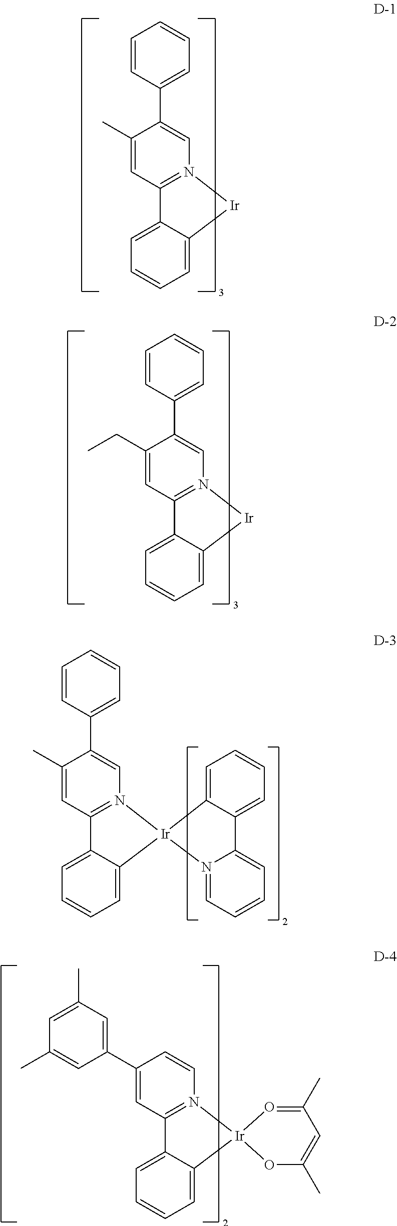

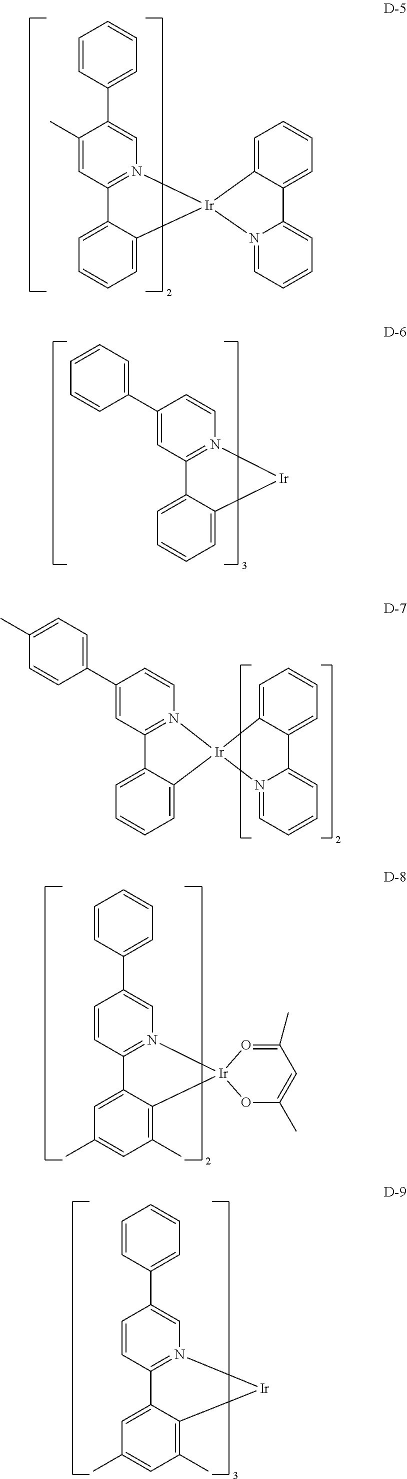

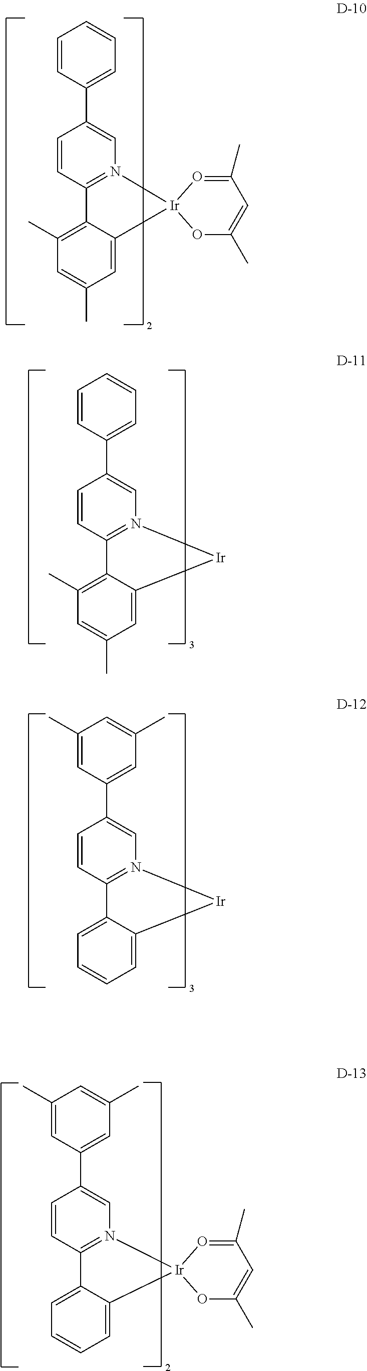

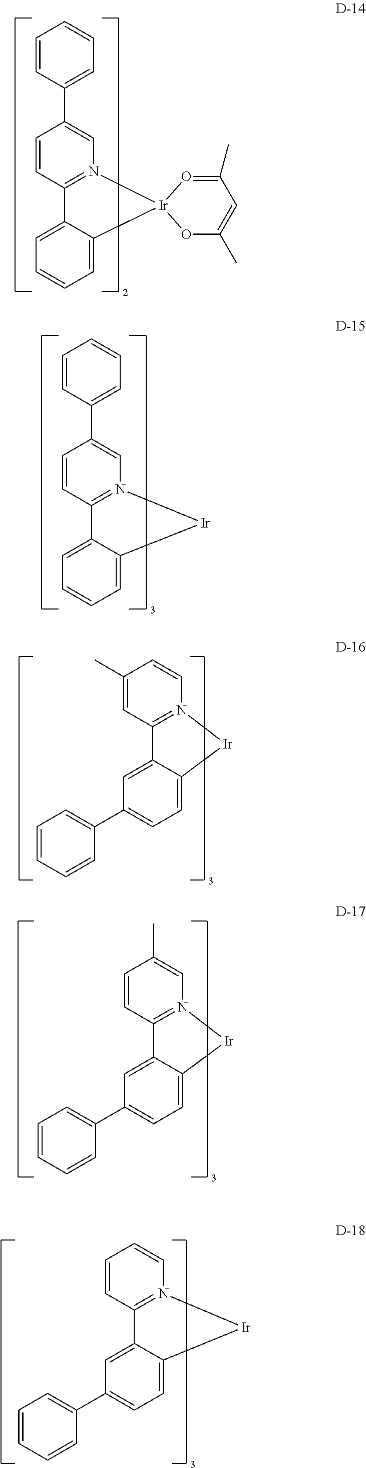

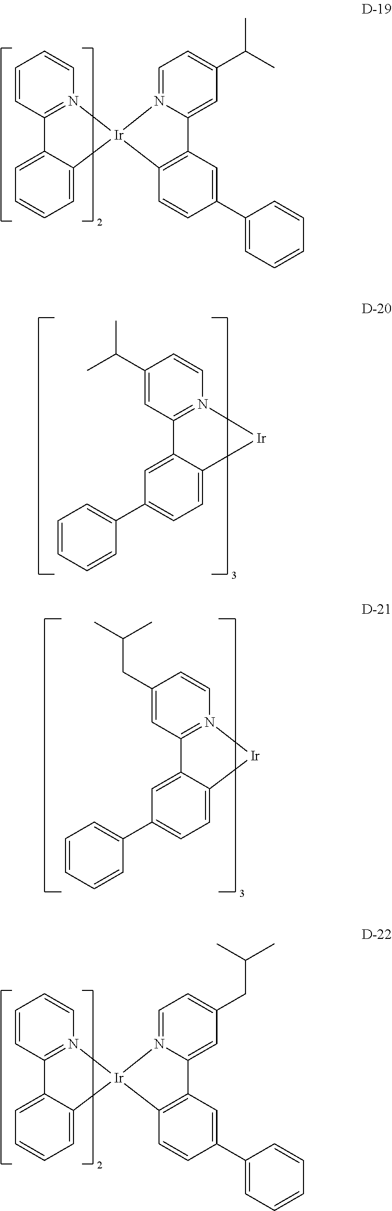

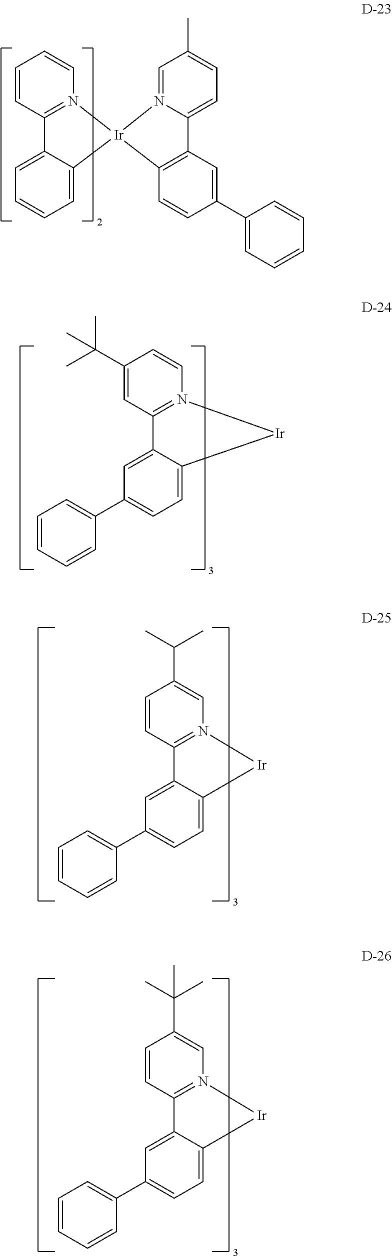

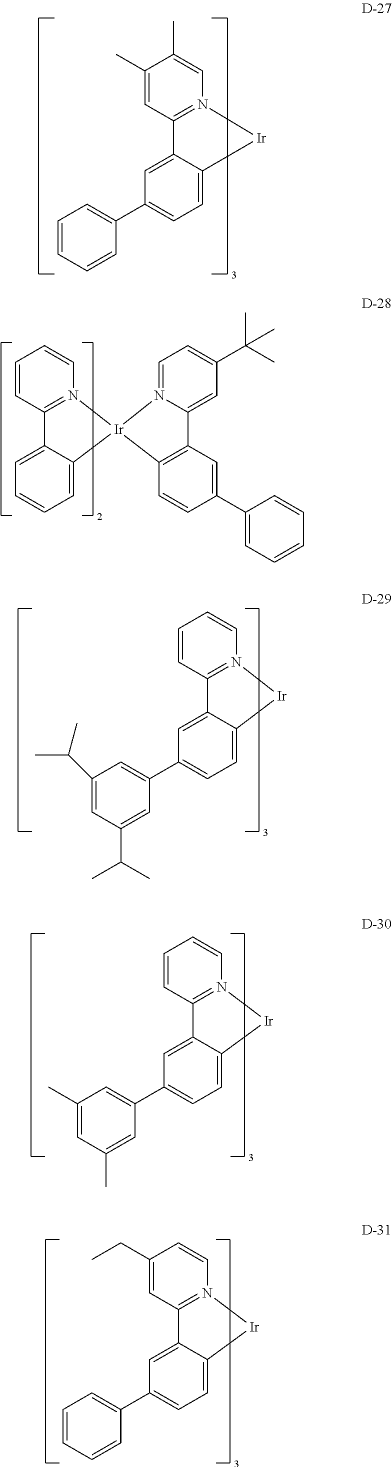

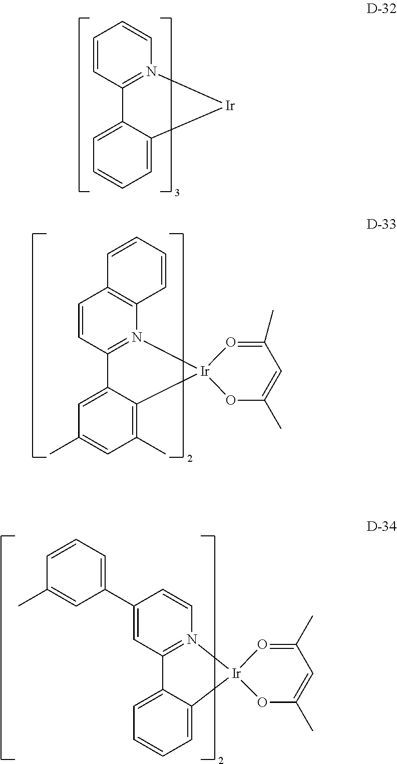

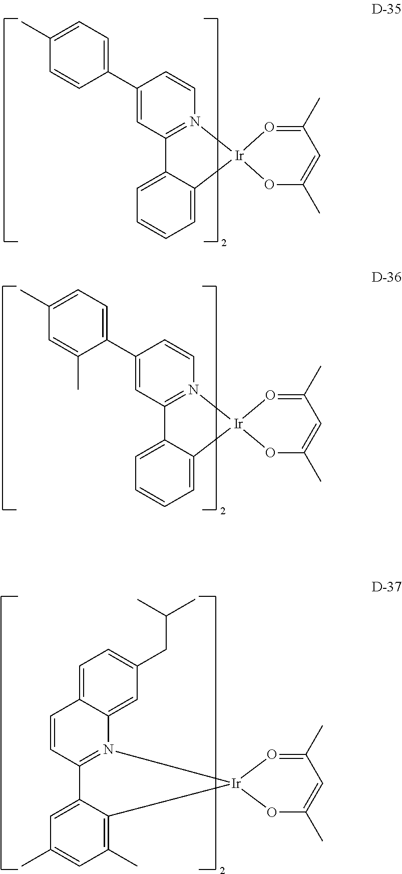

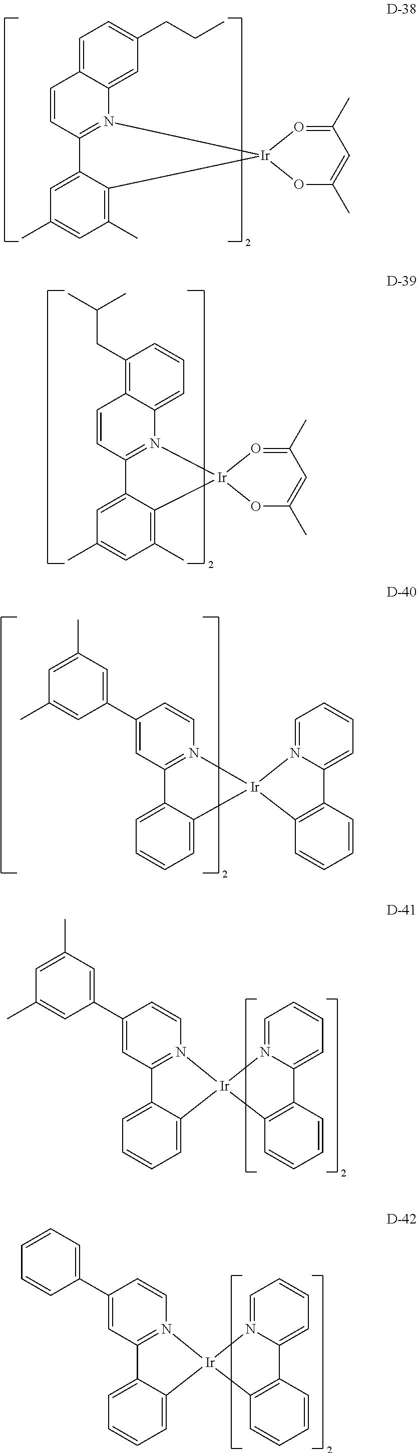

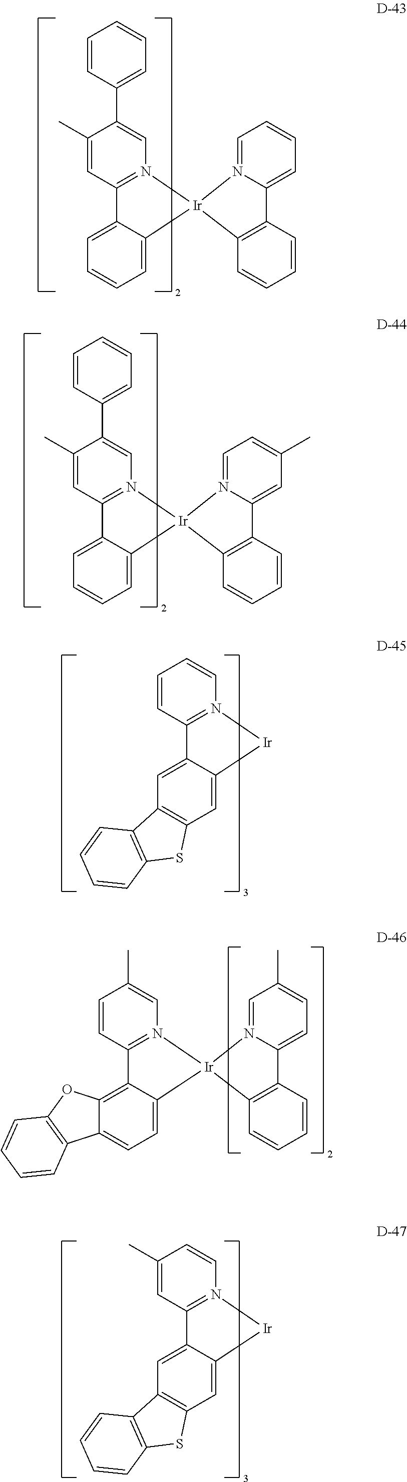

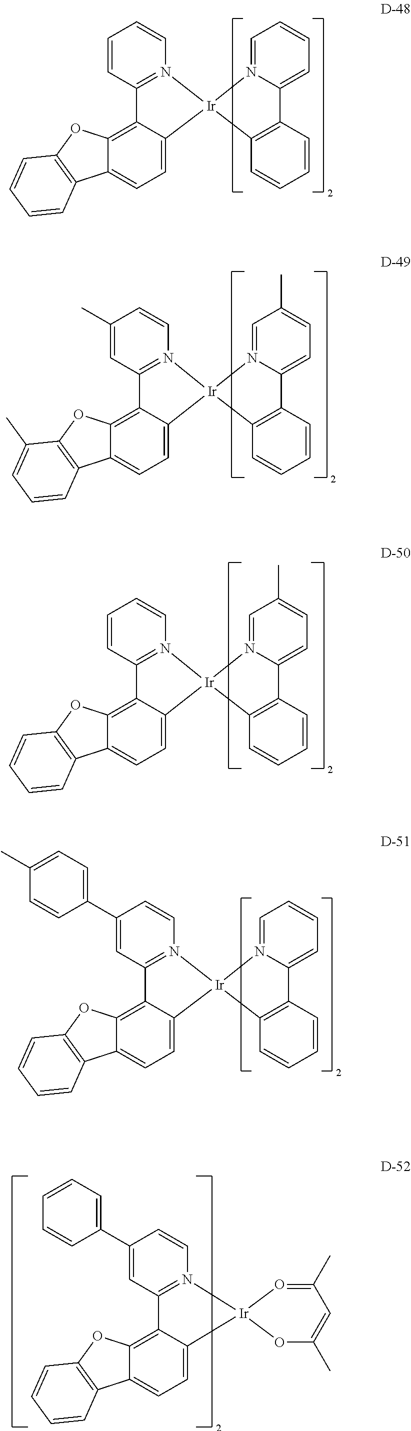

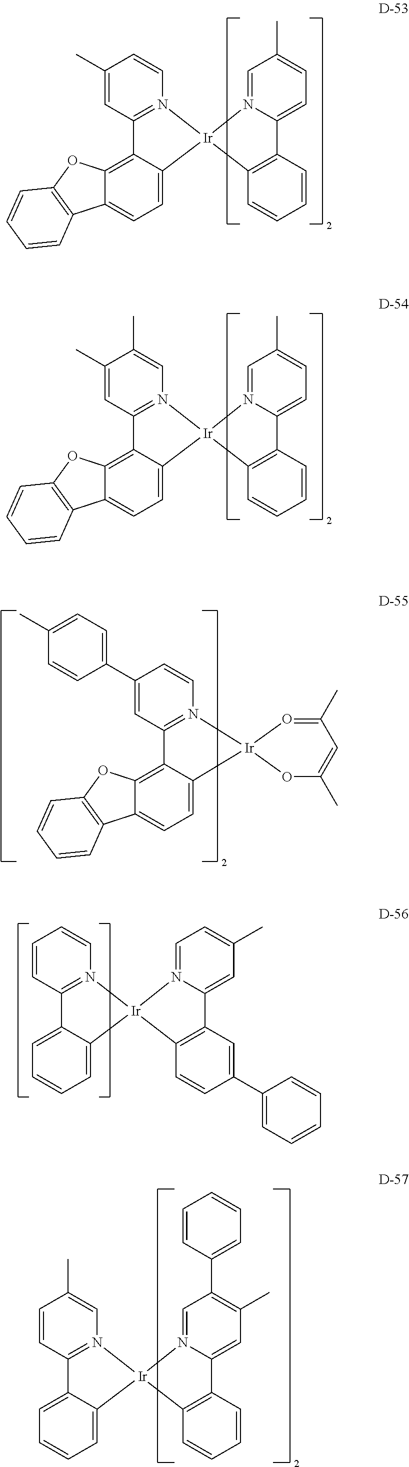

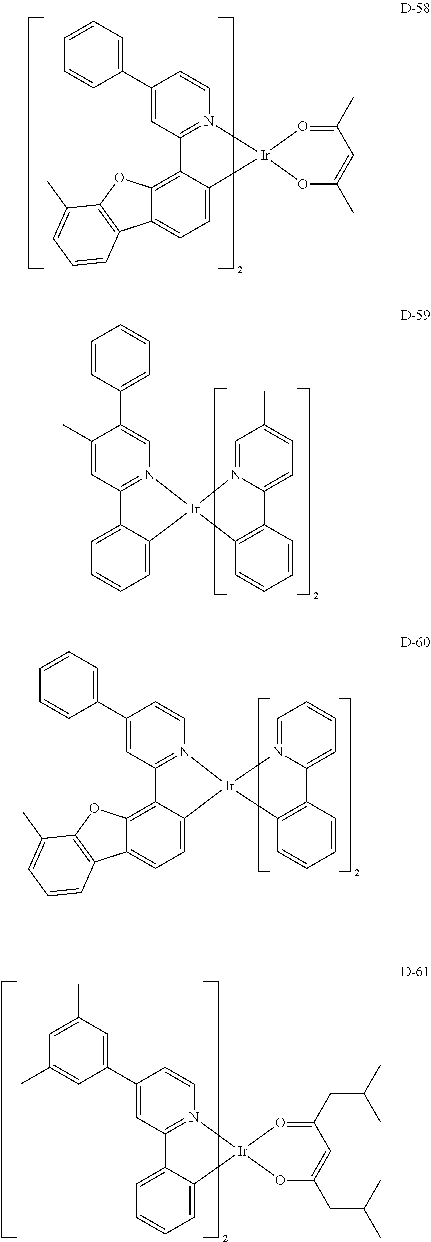

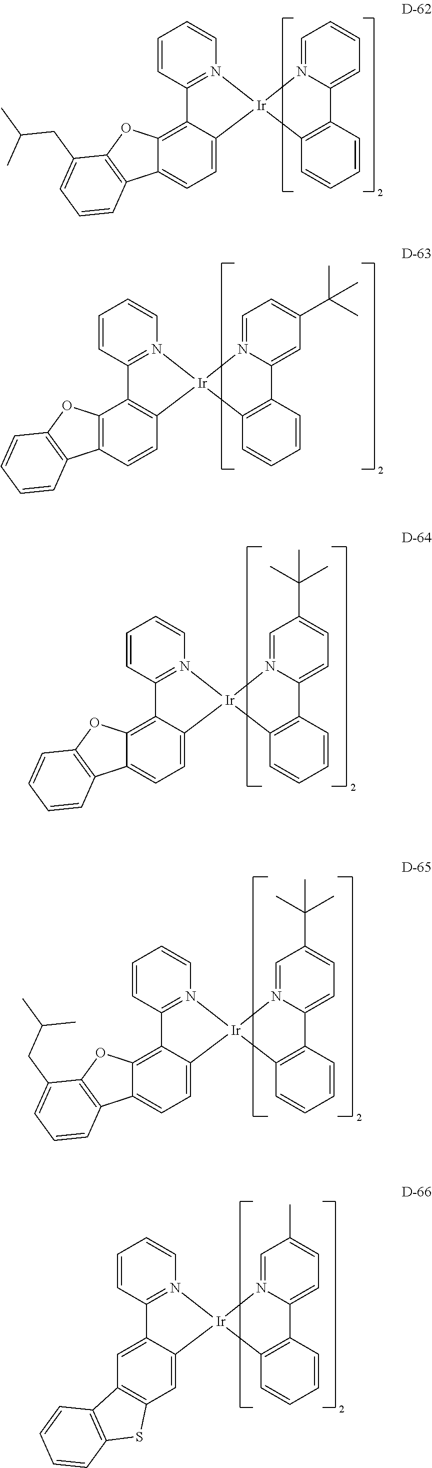

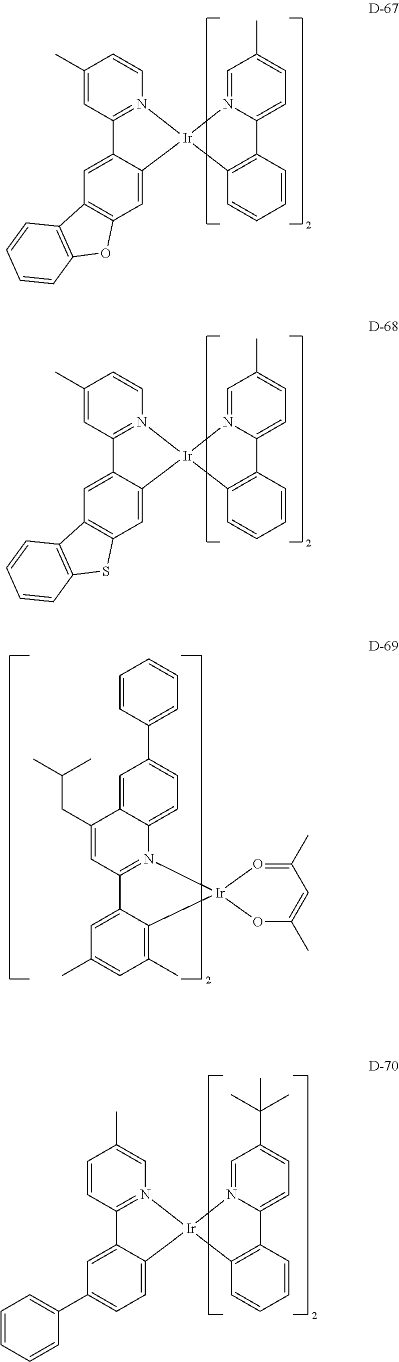

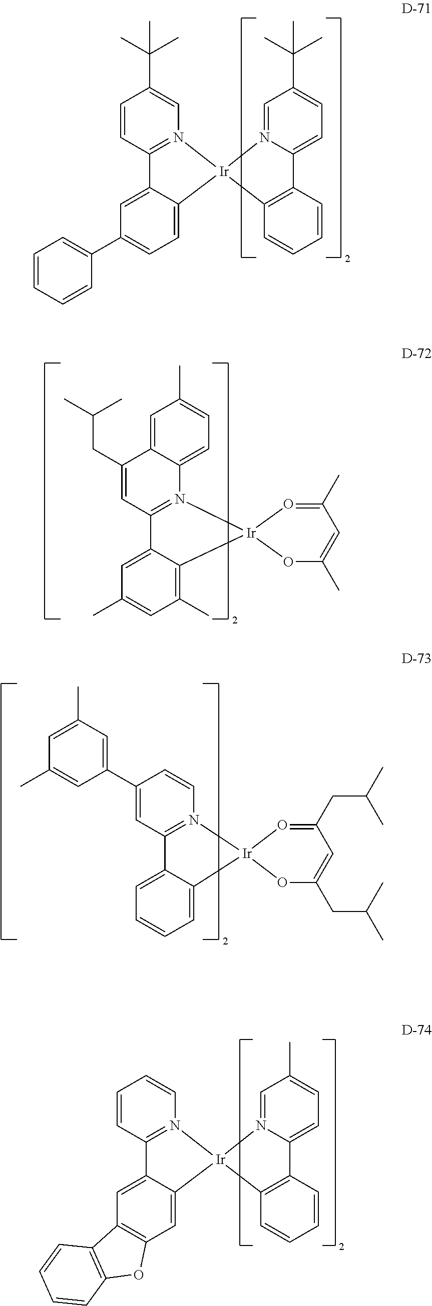

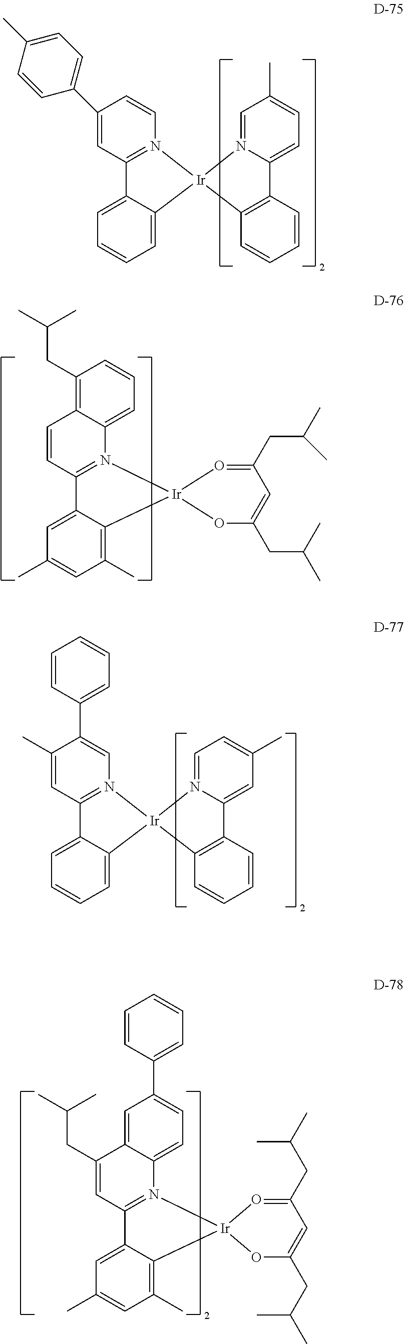

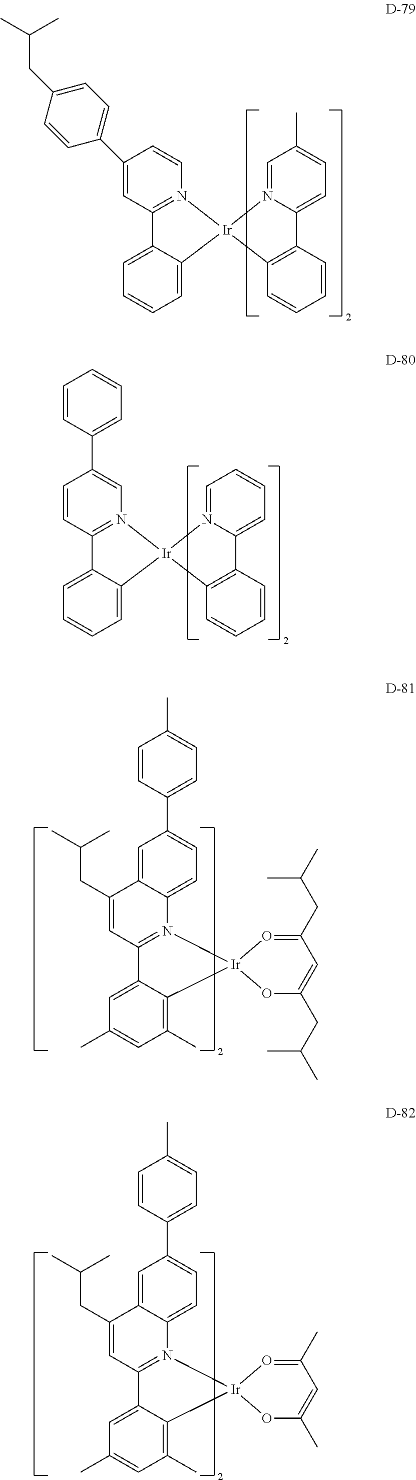

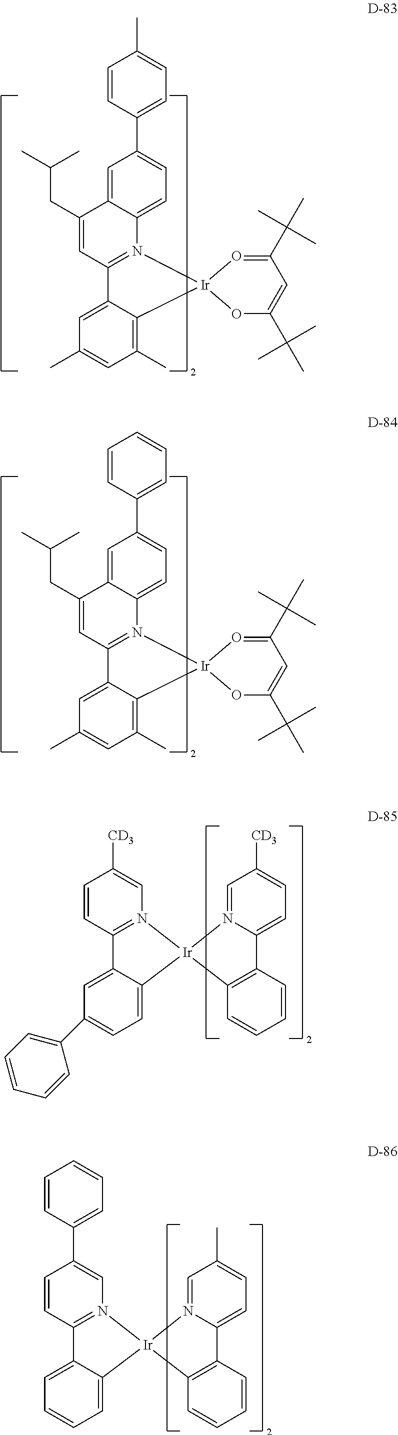

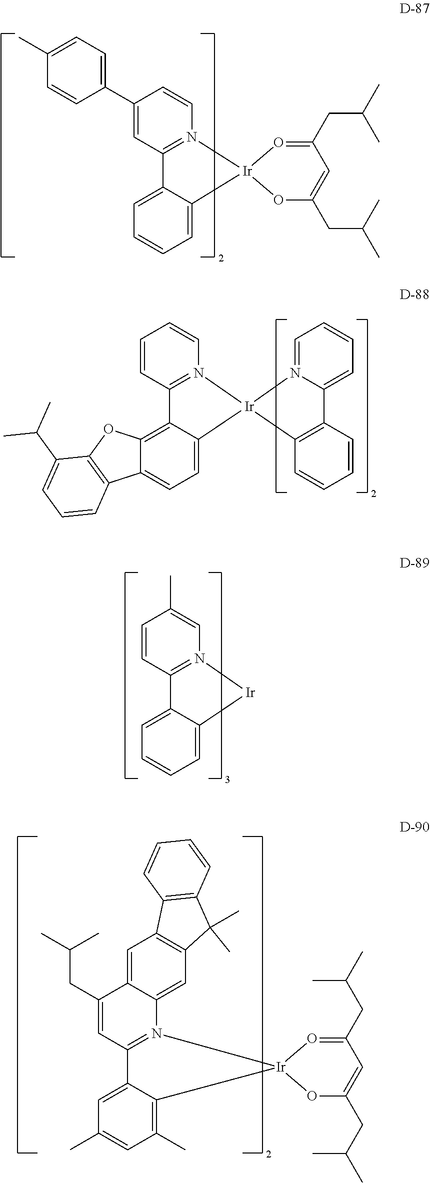

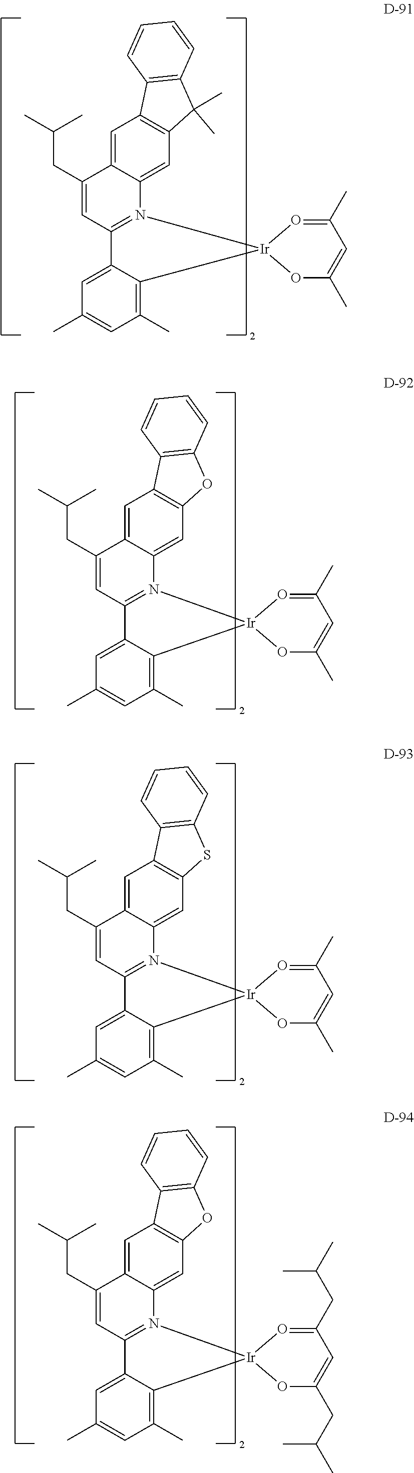

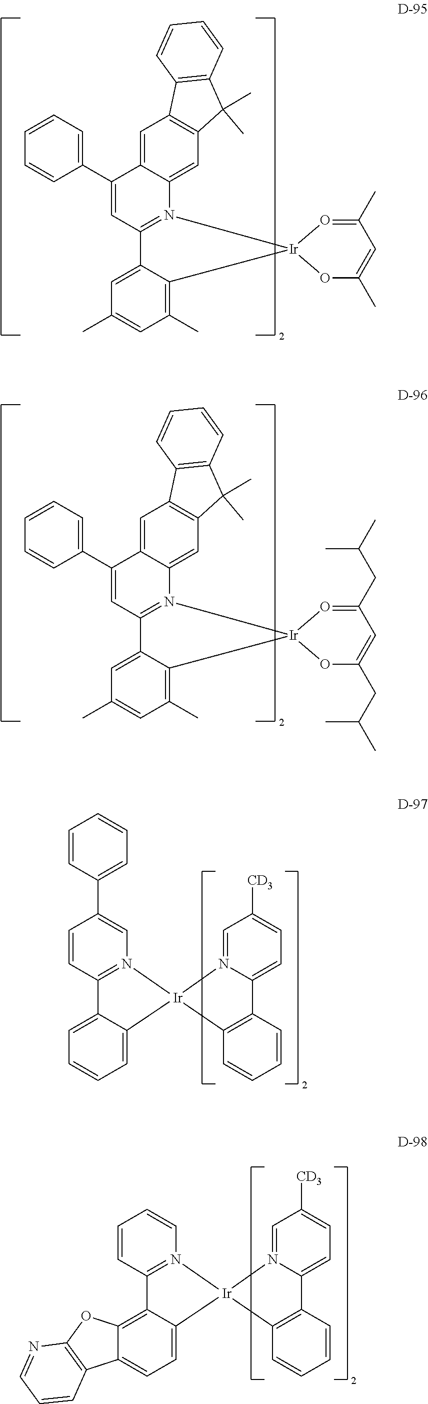

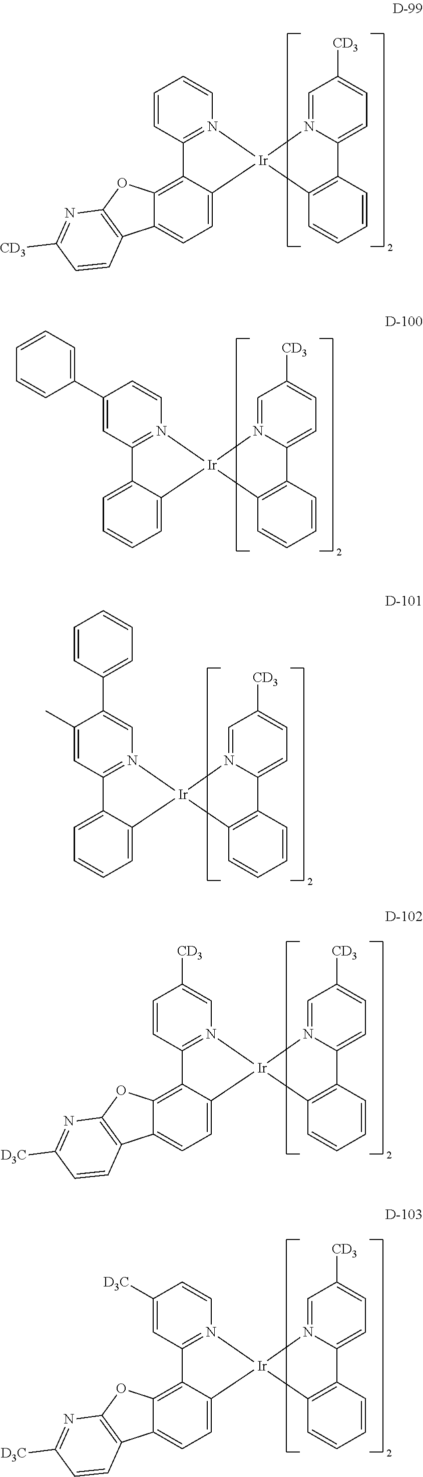

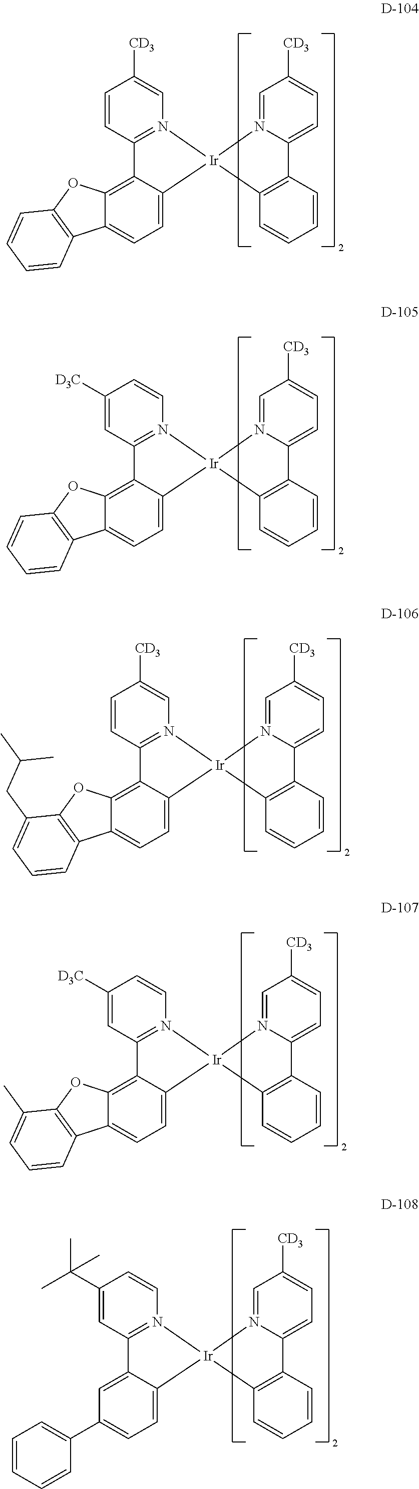

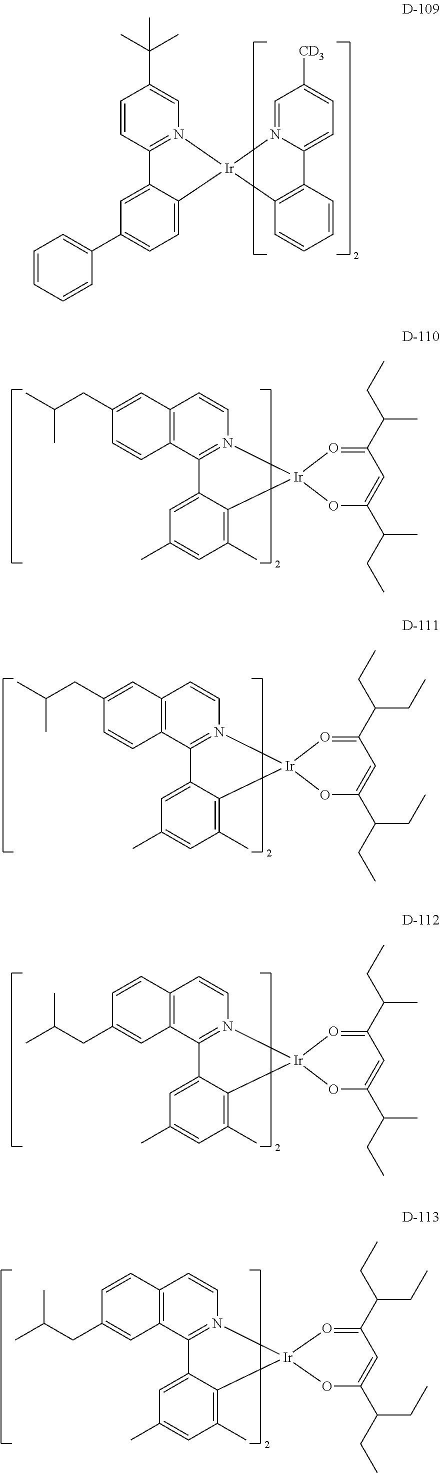

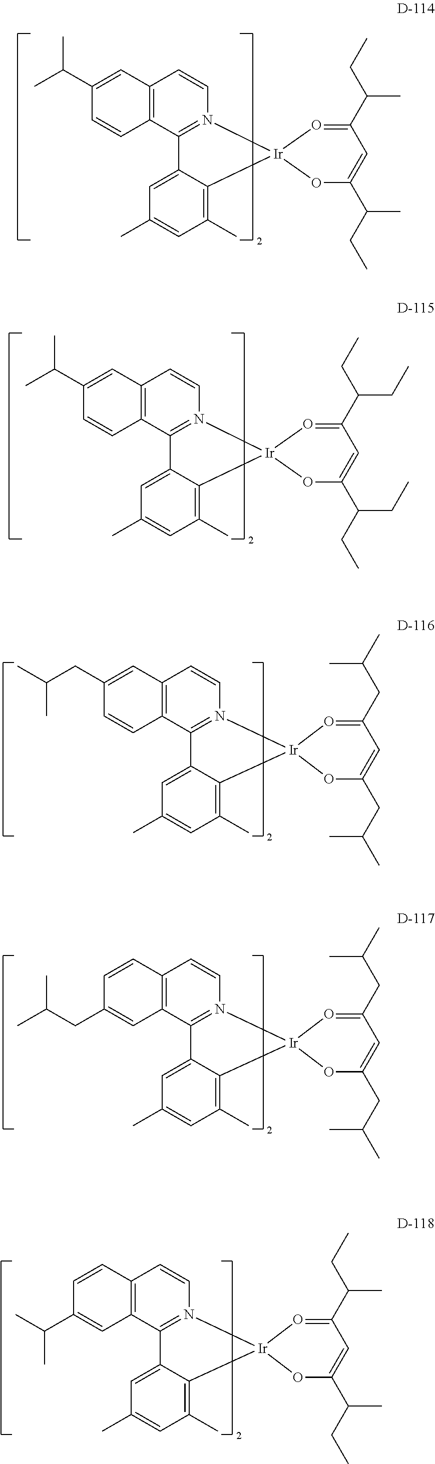

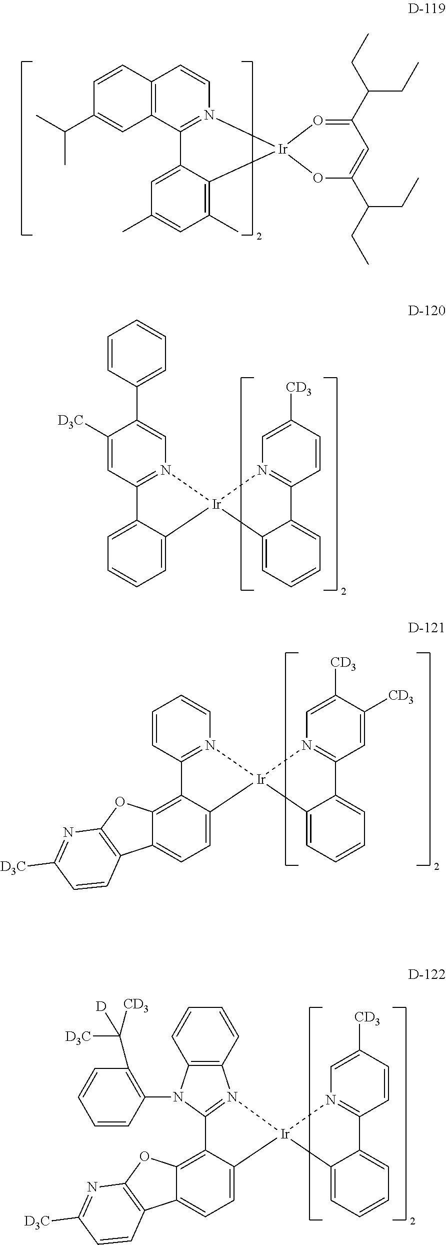

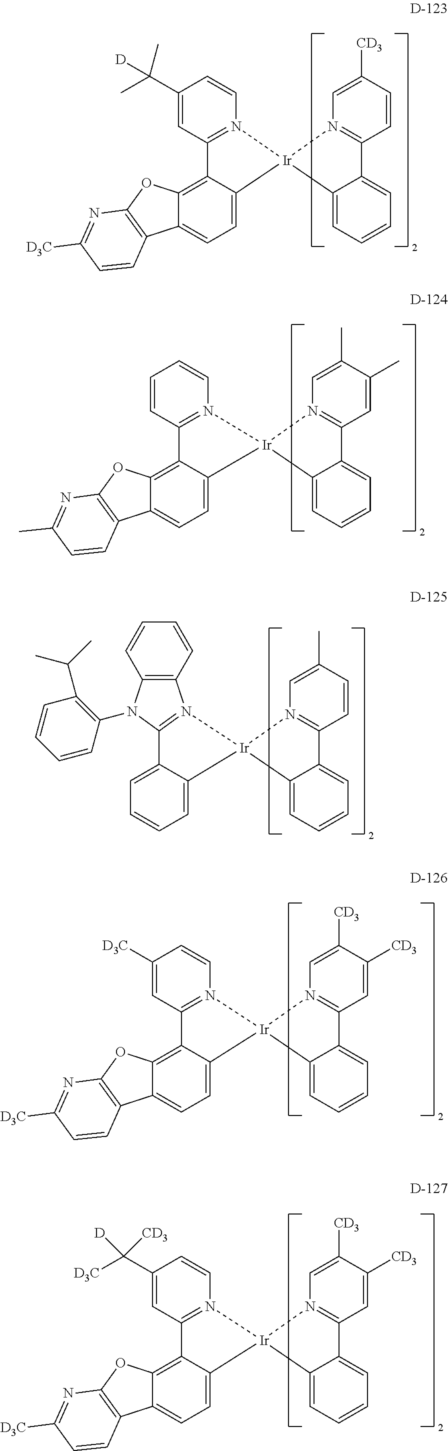

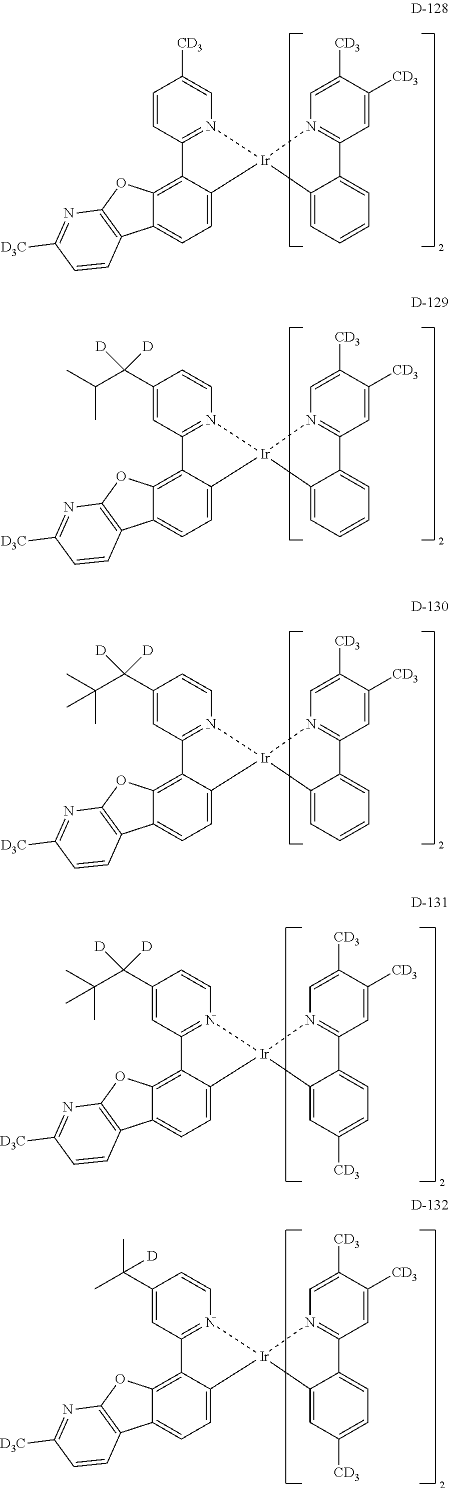

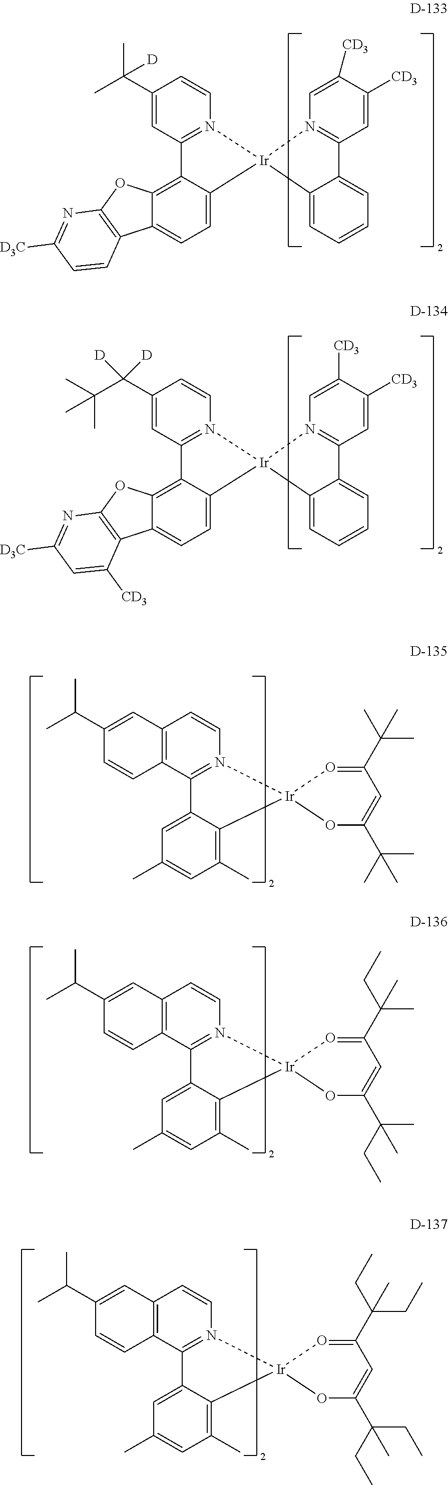

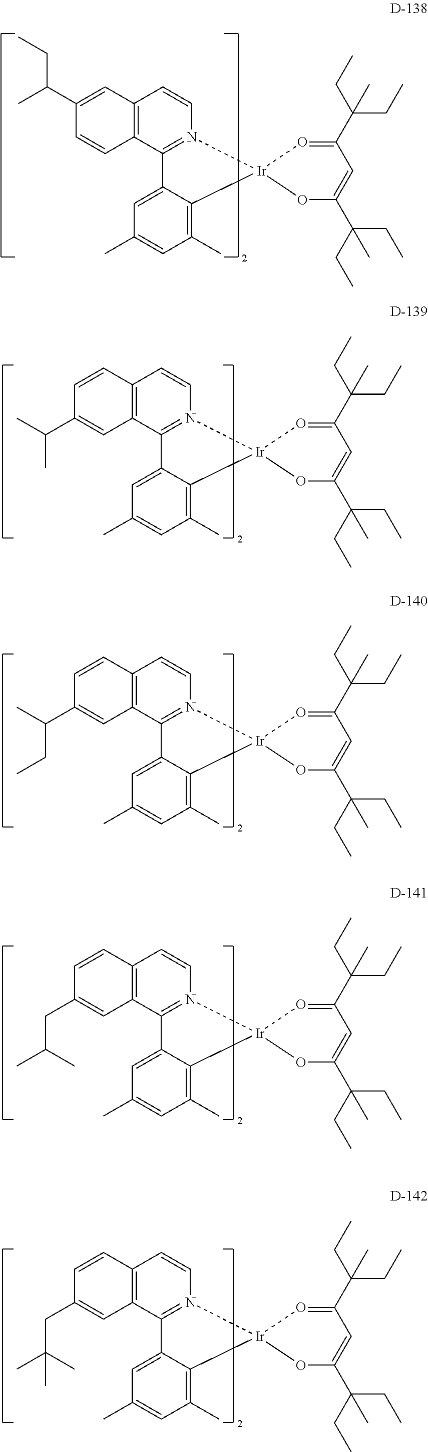

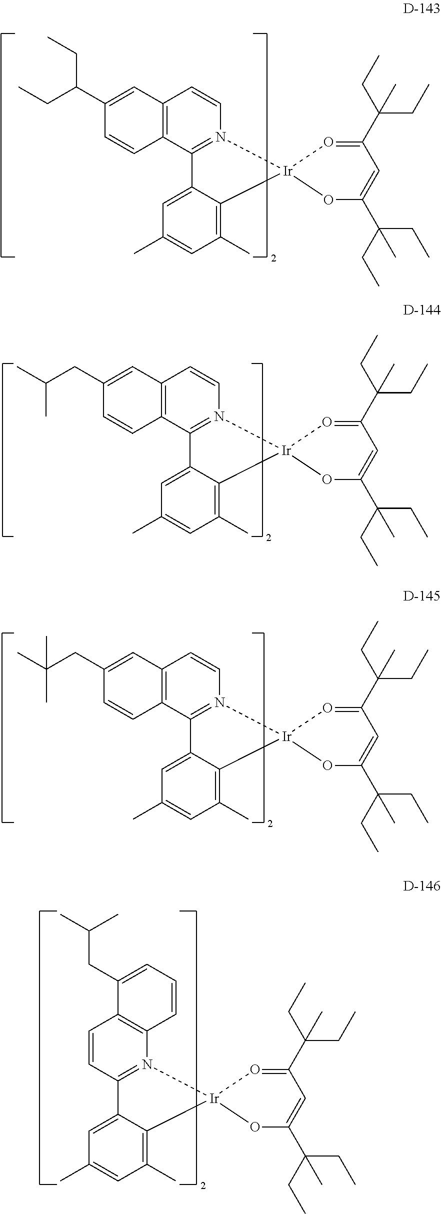

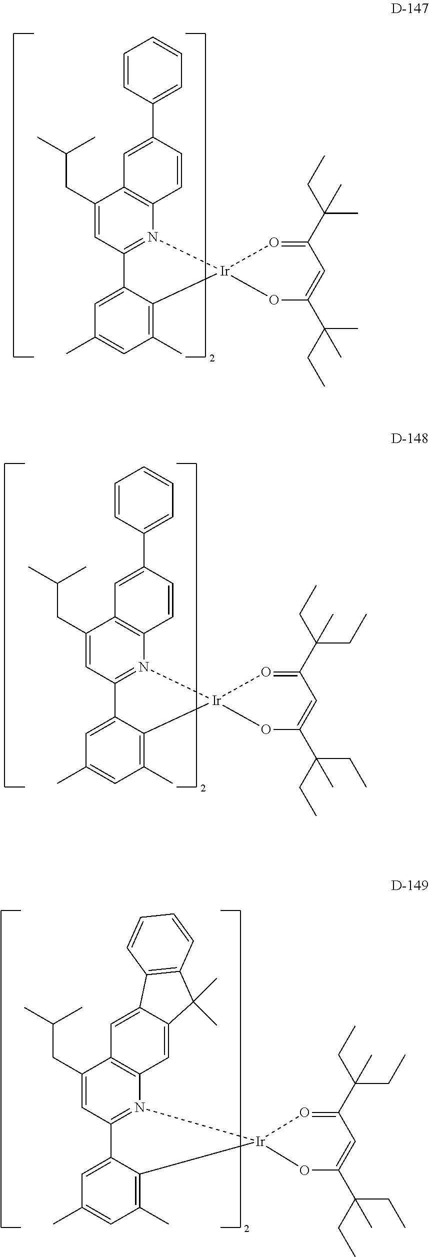

In order to form each layer of the organic electroluminescent device of the present disclosure, dry film-forming methods such as vacuum evaporation, sputtering, plasma, ion plating methods, etc. or wet film-forming methods such as spin coating, dip coating, flow coating methods, etc. can be used. When using a wet film-forming method, a thin film may be formed by dissolving or diffusing materials forming each layer into any suitable solvent such as ethanol, chloroform, tetrahydrofuran, dioxane, etc. The solvent may be any solvent where the materials forming each layer can be dissolved or diffused, and where there are no problems in film formation capability.

When forming a film of an organic electroluminescent material according to one embodiment, the film can be formed by the above-listed methods, and can be formed commonly by a co-deposition or mixed deposition process. The co-deposition is a method of mixing and depositing two or more materials by placing them in separate crucible sources and applying current to two cells simultaneously to evaporate the materials, and the mixed deposition is a method of mixing two or more materials in one crucible source before deposition and then applying current to one cell to evaporate the materials.

According to one embodiment of the present disclosure, the present disclosure can provide a display device comprising a compound represented by Formula 1, a display device comprising an organic electroluminescent material comprising a first host compound represented by Formula 1 and a second host compound represented by Formula 2, and/or a display device comprising an organic electroluminescent material comprising a first host compound represented by Formula 1 and a second host compound represented by Formula 3. In addition, it is possible to produce a display system, e.g., a display system for smartphones, tablets, notebooks, PCs, TVs, or cars, or a lighting system, e.g., an outdoor or indoor lighting system, using the organic electroluminescent device of the present disclosure.

Hereinafter, for a detailed understanding of the present disclosure, a method of preparing a compound according to the present disclosure will be described using the synthesis of a representative compound or intermediate compound of the present disclosure as an example.

### Example 1: Preparation of Compound H2-5

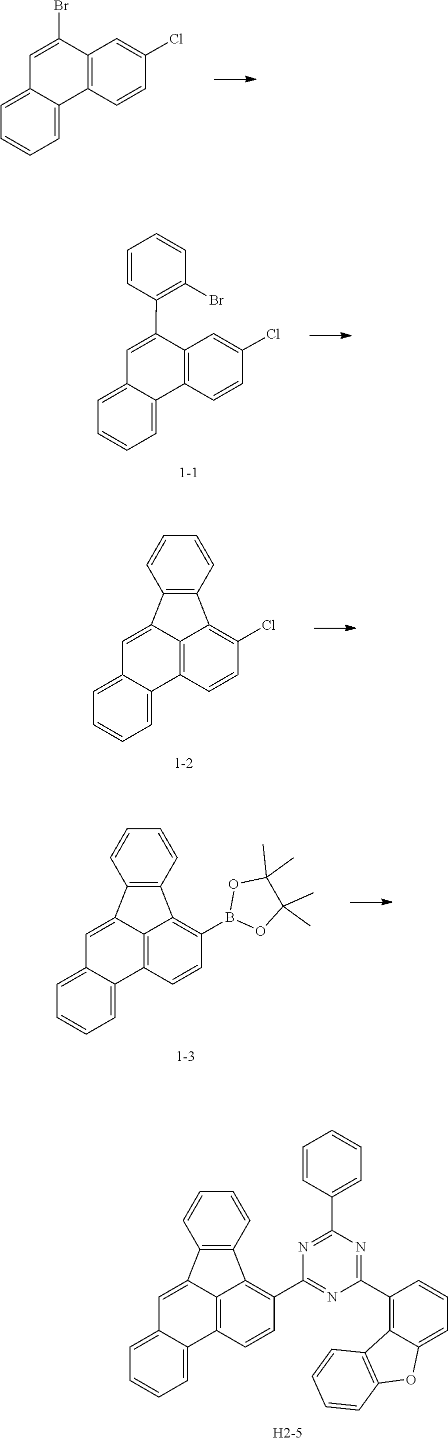 [SMILES: Clc1ccc2c(c1)c(Br)cc1ccccc12 ; Clc1ccc2c(c1)c(-c1ccccc1Br)cc1ccccc12 ; Clc1ccc2c3c(cc4ccccc42)-c2ccccc2-c13 ; CC1(C)OB(c2ccc3c4c(cc5ccccc53)-c3ccccc3-c24)OC1(C)C ; c1ccc(-c2nc(-c3ccc4c5c(cc6ccccc64)-c4ccccc4-c35)nc(-c3cccc4oc5ccccc5c34)n2)cc1]

### 1) Synthesis of Compound 1-1

In a flask, 10-bromo-2-chlorophenanthrene (20 g, 68 mmol), 2-bromophenylboronic acid (15 g, 75 mmol), Pd(PPh₃)₄ (4 g, 3.4 mmol), and K₂CO₃ (23.7 g, 171 mmol) were dissolved in 340 mL of toluene, 85 mL of ethanol, and 85 mL of water followed by refluxing for 4 hours at 120° C. After completion of the reaction, the organic layer was extracted with ethyl acetate, and the remaining moisture was removed with magnesium sulfate. Thereafter, the organic layer was dried and separated by column chromatography to obtain Compound 1-1 (21 g, yield: 83%).

### 2) Synthesis of Compound 1-2

In a flask, Compound 1-1 (21 g, 57 mmol), Pd(PPh₃)₂Cl₂ (2 g, 2.8 mmol), and 1,8-diazabicyclo[5,4,0]undec-7-ene (25.6 mL, 171 mmol) were dissolved in 190 mL of dimethylformamide (DMF) followed by refluxing for 4 hours at 165° C. After completion of the reaction, the organic layer was extracted with ethyl acetate, and the remaining moisture was removed with magnesium sulfate. Thereafter, the organic layer was dried and separated by column chromatography to obtain Compound 1-2 (12.2 g, yield: 63%).

### 3) Synthesis of Compound 1-3

In a flask, compounds 1-2 (5 g, 17 mmol), 4,4,4′, 4′, 5,5,5′, 5′-octamethyl-2,2′-bis(1,3,2-dioxaborolane) (22 g, 87 mmol), Pd₂dba₃ (798 mg, 0.8 mmol), SPhos (715 mg, 1.7 mmol), and KOAc (4.3 g, 43 mmol) were dissolved in 113 mL of 1,4-dioxane followed by refluxing for 3 hours at 100° C. After completion of the reaction, the organic layer was extracted with ethyl acetate, and the remaining moisture was removed with magnesium sulfate. Thereafter, the organic layer was dried and separated by column chromatography to obtain Compound 1-3 (6.5 g, yield: 82%). 4) Synthesis of Compound H2-5 In a flask, Compound 1-3 (6 g, 15.8 mmol), 2-chloro-4-(dibenzo[b,d]furan-1-yl)-6-phenyl-1,3,5-triazine (5.6 g, 15.8 mmol), Pd(PPh₃)₄ (916 mg, 0.8 mmol), and K₂CO₃ (5.5 g, 40 mmol) were dissolved in 80 mL of toluene, 20 mL of ethanol, and 20 mL of water followed by stirring under reflux for 4 hours. After completion of the reaction, the organic layer was extracted with ethyl acetate, and the remaining moisture was removed with magnesium sulfate. Thereafter, the organic layer was dried and separated by column chromatography to obtain Compound H2-5 (3.6 g, yield: 40%).

| | MW | M.P. | T_{g} |
|---|---|---|---|
| H2-5 | 573.65 | 294.7° C. | 123° C. |

### Example 2: Preparation of Compound H2-35

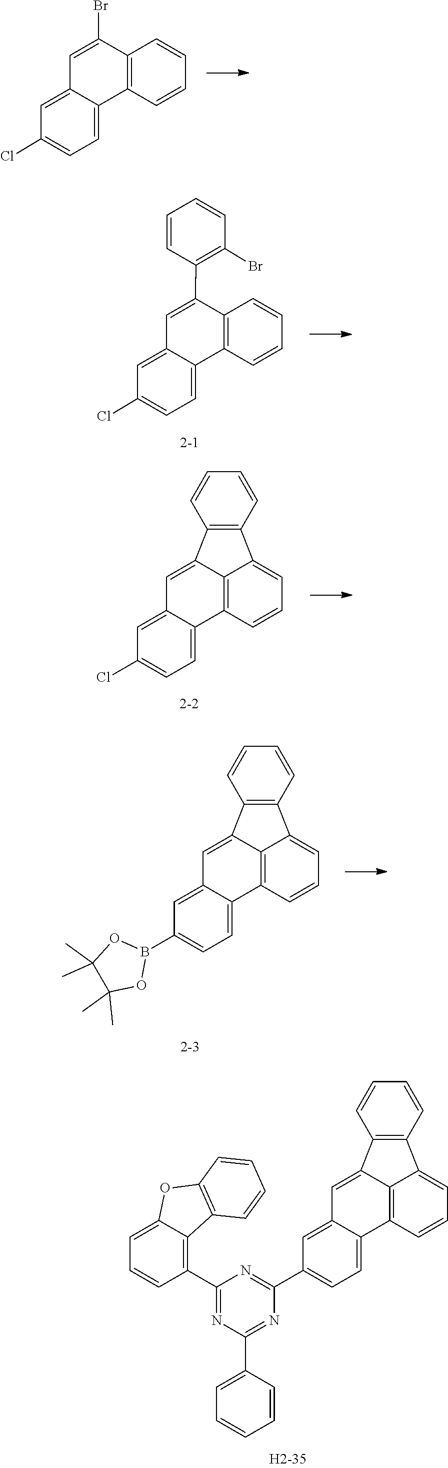 [SMILES: Clc1ccc2c(c1)cc(Br)c1ccccc12 ; Clc1ccc2c(c1)cc(-c1ccccc1Br)c1ccccc12 ; Clc1ccc2c(c1)cc1c3c(cccc32)-c2ccccc2-1 ; CC1(C)OB(c2ccc3c(c2)cc2c4c(cccc43)-c3ccccc3-2)OC1(C)C ; c1ccc(-c2nc(-c3ccc4c(c3)cc3c5c(cccc54)-c4ccccc4-3)nc(-c3cccc4oc5ccccc5c34)n2)cc1]

### 1) Synthesis of Compound 2-1

In a flask, 9-bromo-2-chlorophenanthrene (50 g, 171 mmol), 2-bromophenylboronic acid (38 g, 188 mmol), Pd(PPh₃)₄ (9.9 g, 8.5 mmol), and K₂CO₃ (59 g, 428 mmol) were dissolved in 860 mL of toluene, 215 mL of ethanol, and 215 mL of water followed by refluxing for 4 hours at 120° C. After completion of the reaction, the organic layer was extracted with ethyl acetate, and the remaining moisture was removed with magnesium sulfate. Thereafter, the organic layer was dried and separated by column chromatography to obtain Compound 2-1 (56.7 g, yield: 90%).

### 2) Synthesis of Compound 2-2

In a flask, Compound 2-1 (26.7 g, 72 mmol), Pd(PPh₃)₂Cl₂ (2.5 g, 3.6 mmol), and 1,8-diazabicyclo[5,4,0]undec-7-ene (32.5 mL, 217 mmol) were dissolved in 240 mL of dimethylformamide (DMF) followed by refluxing for 4 hours at 165° C. After completion of the reaction, the organic layer was extracted with ethyl acetate, and the remaining moisture was removed with magnesium sulfate. Thereafter, the organic layer was dried and separated by column chromatography to obtain Compound 2-2 (16.5 g, yield: 79%).

### 3) Synthesis of Compound 2-3

In a flask, Compound 2-2 (7.6 g, 26 mmol), 4,4,4′, 4′, 5,5,5′, 5′-octamethyl-2,2′-bis(1,3,2-dioxaborolane) (13.4 g, 53 mmol), Pd₂dba₃ (1.2 g, 1.3 mmol), SPhos (1.1 g, 2.6 mmol), and KOAc (6.5 g, 66 mmol) were dissolved in 173 mL of 1,4-dioxane followed by refluxing for 3 hours at 100° C. After completion of the reaction, the organic layer was extracted with ethyl acetate, and the remaining moisture was removed with magnesium sulfate. Thereafter, the organic layer was dried and separated by column chromatography to obtain Compound 2-3 (8.1 g, yield: 81%).

### 4) Synthesis of Compound H2-35

In a flask, Compound 2-3 (4 g, 10 mmol), 2-chloro-4-(dibenzo[b,d]furan-1-yl)-6-phenyl-1,3,5-triazine (3.78 g, 10 mmol), Pd(PPh₃)₄ (610 mg, 0.5 mmol), and K₂CO₃ (3.6 g, 26 mmol) were dissolved in 52 mL of toluene, 13 mL of ethanol, and 13 mL of water followed by stirring under reflux for 5 hours. After completion of the reaction, the organic layer was extracted with ethyl acetate, and the remaining moisture was removed with magnesium sulfate. Thereafter, the organic layer was dried and separated by column chromatography to obtain Compound H2-35 (3.1 g, yield: 51%).

| | MW | M.P. | T_{g} |
|---|---|---|---|
| H2-35 | 573.65 | 329.6° C. | 128° C. |

### Example 3: Preparation of Compound H2-33

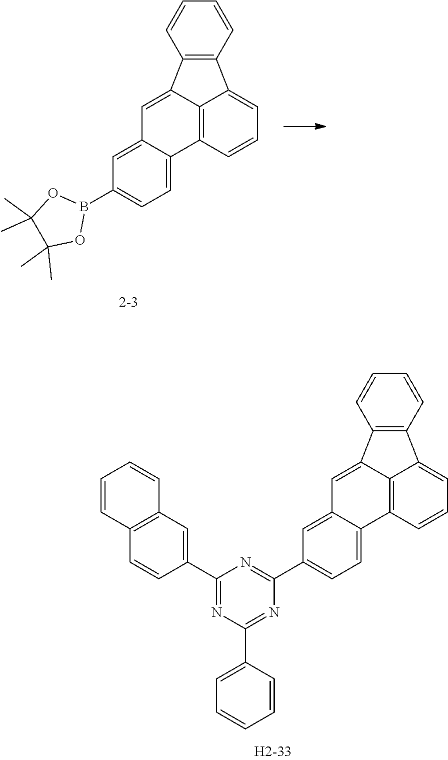 [SMILES: CC1(C)OB(c2ccc3c(c2)cc2c4c(cccc43)-c3ccccc3-2)OC1(C)C ; c1ccc(-c2nc(-c3ccc4ccccc4c3)nc(-c3ccc4c(c3)cc3c5c(cccc54)-c4ccccc4-3)n2)cc1]

In a flask, Compound 2-3 (4 g, 10.5 mmol), 2-chloro-4-(2-naphthalenyl)-6-phenyl-1,3,5-triazine (3.7 g, 11 mmol), Pd(PPh₃)₄ (610 mg, 0.5 mmol), and K₂CO₃ (3.6 g, 26 mmol) were dissolved in 52 mL of toluene, 13 mL of ethanol, and 13 mL of water were dissolved followed by stirring under reflux for 8 hours. After completion of the reaction, the organic layer was extracted with ethyl acetate, and the remaining moisture was removed with magnesium sulfate. Thereafter, the organic layer was dried and separated by column chromatography to obtain Compound H2-33 (2 g, yield: 35%).

| | MW | M.P. | T_{g} |
|---|---|---|---|
| H2-33 | 533.63 | 303.6° C. | 103° C. |

### Device Examples 1 to 3: Producing OLEDs Comprising Organic Electroluminescent Materials According to the Present Disclosure

An OLED according to the present disclosure was produced. First, a transparent electrode indium tin oxide (ITO) thin film (10 Ω/sq) on a glass substrate for an OLED (GEOMATEC CO., LTD., Japan) was subjected to an ultrasonic washing with acetone and isopropyl alcohol, sequentially, and was then stored in isopropyl alcohol. The ITO substrate was mounted on a substrate holder of a vacuum vapor deposition apparatus. Compound HI-1, shown in Table 3, was introduced into a cell of the vacuum vapor deposition apparatus, and Compound HT-1 was introduced into another cell. The two materials were evaporated at different rates, and Compound HI-1 was deposited in a doping amount of 3 wt % based to the total amount of Compound HI-1 and Compound HT-1 to form a first hole injection layer with a thickness of 10 nm. Subsequently, Compound HT-1 was deposited on the first hole injection layer to form a first hole transport layer with a thickness of 80 nm. Next, Compound HT-2 was introduced into another cell of the vacuum vapor deposition apparatus and was evaporated by applying an electric current to the cell to thereby deposit a second hole transport layer with a thickness of 60 nm on the first hole transport layer. After forming the hole injection layer and the hole transport layers, a light-emitting layer was deposited thereon as follows: each of the first host compound and the second host compound shown in Table 1 below were introduced into two cells of the vacuum vapor deposition apparatus as hosts, and Compound D-39 was introduced into another cell as a dopant. The two host materials were evaporated at a rate of 1:1, the dopant material was simultaneously evaporated at a different rate, and the dopant was deposited in a doping amount of 3 wt % based on the total amount of the hosts and dopant to form a light-emitting layer with a thickness of 40 nm on the second hole transport layer. Then, Compound ET-1 and Compound EI-1 were evaporated at a weight ratio of 50:50 as an electron transport material to form an electron transport layer having a thickness of 35 nm on the light-emitting layer. After depositing Compound EI-1 as an electron injection layer with a thickness of 2 nm on the electron transport layer, an Al cathode was deposited with a thickness of 80 nm on the electron injection layer by using another vacuum vapor deposition apparatus to thereby produce an OLED. All of the materials used for producing the OLED were purified by vacuum sublimation at 10⁻⁶ Torr.

### Comparative Example 1: Producing an OLED Comprising a Comparative Compound as a Host

An OLED was produced in the same manner as in Device Example 1, except that the second host compound shown in Table 1 below was used.

The following Table 1 shows the driving voltage, luminous efficiency, light-emitting color at a luminance of 1,000 nit, and time taken for luminance to reduce from 100% to 95% at a luminance of 10,000 nit (lifetime: T95) for the OLEDs of Device Examples 1 to 3 and Comparative Example 1 produced as described above.

TABLE 1

| | | | | | | Life- |
|---|---|---|---|---|---|---|
| | | | Driving | Luminous | Light- | time |
| | First | Second | Voltage | Efficiency | Emitting | T95 |
| | Host | Host | [V] | [cd/A] | Color | [hr] |
| Device | H1-16 | H2-35 | 2.9 | 32.8 | Red | 243 |
| Example 1 | | | | | | |
| Device | H1-16 | H2-5 | 3.0 | 33.4 | Red | 314 |
| Example 2 | | | | | | |
| Device | H1-16 | H2-20 | 3.1 | 33.2 | Red | 212 |
| Example 3 | | | | | | |
| Comparative | H1-16 | A | 3.5 | 17.8 | Red | 72 |
| Example 1 | | | | | | |

From Table 1 above, it can be confirmed that the OLED according to the present disclosure exhibits lower driving voltage and significantly higher luminous efficiency and lifetime properties compared to Comparative Example 1 using a conventional compound as a second host.

### Device Examples 4 and 5: Producing an OLED Comprising the Organic Electroluminescent Compound According to the Present Disclosure

OLEDs were produced in the same manner as in Device Example 1, except that the host compound in Table 2 below was used alone as a host for the light-emitting layer.

### Comparative Example 2: Producing an OLED Comprising a Comparative Compound as a Host

An OLED was produced in the same manner as in Device Example 4, except that the host compound in Table 2 below was used alone as a host for the light-emitting layer.

The following Table 2 shows the driving voltage, luminous efficiency, light-emitting color at a luminance of 1,000 nit, and time taken for luminance to reduce from 100% to 95% at a luminance of 10,000 nit (lifetime: T95) for the OLEDs of Device Examples 4, 5 and Comparative Example 2 produced as described above.

TABLE 2

| | | Driving | Luminous | Light- | |
|---|---|---|---|---|---|
| | | Voltage | Efficiency | Emitting | Lifetime |
| | Host | [V] | [cd/A] | Color | T95 [hr] |
| Device | H2-5 | 3.2 | 29.4 | Red | 74 |
| Example 4 | | | | | |
| Device | H2-35 | 3.5 | 27.5 | Red | 28 |
| Example 5 | | | | | |
| Comparative | A | 5.1 | 3.7 | Red | 1.8 |
| Example 2 | | | | | |

From Table 2 above, it can be confirmed that the OLED according to the present disclosure exhibits lower driving voltage and significantly higher luminous efficiency and lifetime properties compared to Comparative Example 2 using a conventional compound as a host.

TABLE 3

| | |
|---|---|
| Hole Injection Layer/ Hole Transport Layer | 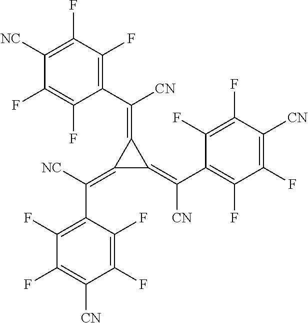 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F] HI-16 |
| | 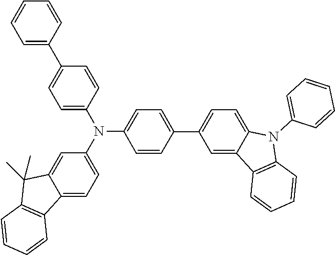 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21] HT-1 |
| | 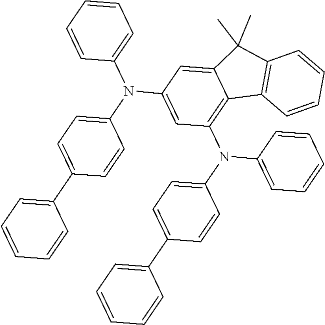 [SMILES: CC1(C)c2ccccc2-c2c(N(c3ccccc3)c3ccc(-c4ccccc4)cc3)cc(N(c3ccccc3)c3ccc(-c4ccccc4)cc3)cc21] HT-2 |
| Light- Emitting Layer | 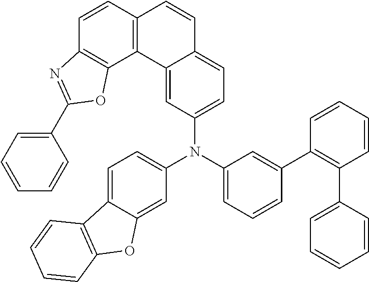 [SMILES: c1ccc(-c2nc3ccc4ccc5ccc(N(c6cccc(-c7ccccc7-c7ccccc7)c6)c6ccc7c(c6)oc6ccccc67)cc5c4c3o2)cc1] H1-1 |
| | 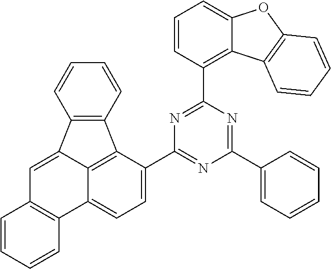 [SMILES: c1ccc(-c2nc(-c3ccc4c5c(cc6ccccc64)-c4ccccc4-c35)nc(-c3cccc4oc5ccccc5c34)n2)cc1] H2-5 |
| | 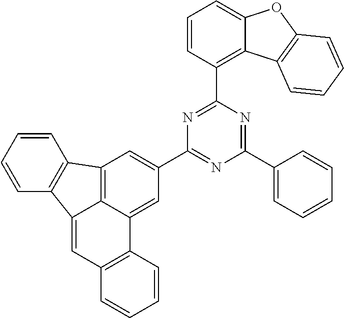 [SMILES: c1ccc(-c2nc(-c3cc4c5c(cc6ccccc6c5c3)-c3ccccc3-4)nc(-c3cccc4oc5ccccc5c34)n2)cc1] H2-20 |
| | 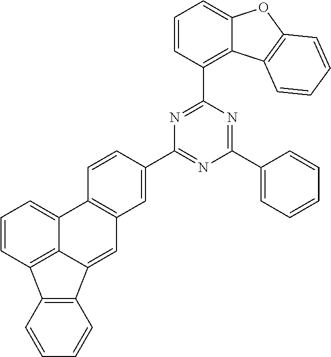 [SMILES: c1ccc(-c2nc(-c3ccc4c(c3)cc3c5c(cccc54)-c4ccccc4-3)nc(-c3cccc4oc5ccccc5c34)n2)cc1] H2-35 |
| | 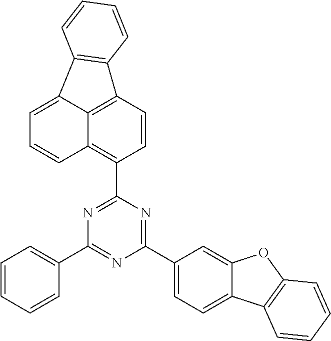 [SMILES: c1ccc(-c2nc(-c3ccc4c(c3)oc3ccccc34)nc(-c3ccc4c5c(cccc35)-c3ccccc3-4)n2)cc1] A |
| | 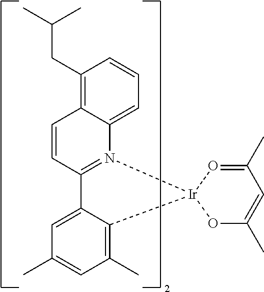 D-39 |
| Electron Transport Layer/ Electron Injection Layer | 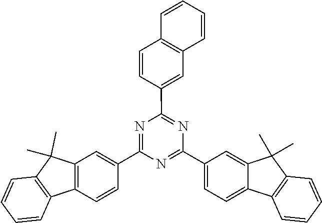 [SMILES: CC1(C)c2ccccc2-c2ccc(-c3nc(-c4ccc5c(c4)C(C)(C)c4ccccc4-5)nc(-c4ccc5ccccc5c4)n3)cc21] ET-1 |
| | 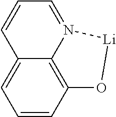 EI-1 |

1. An organic electroluminescent compound represented by the following Formula 1: 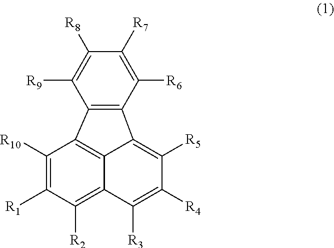
wherein in Formula 1,
R₁ and R₂ are linked to each other to form a substituted or unsubstituted fused ring(s);
R₃ to R₁₀ each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, or a substituted or unsubstituted tri(C6-C30)arylsilyl; and
at least one of the substituent(s) of the fused ring(s) and R₃ to R₁₀ represents a substituted or unsubstituted (3- to 30-membered)heteroaryl comprising at least one N.

2. The organic electroluminescent compound according to claim 1, wherein the substituted alkyl, the substituted cycloalkyl, the substituted aryl, the substituted heteroaryl, the substituted alkoxy, the substituted trialkylsilyl, the substituted dialkylarylsilyl, the substituted alkyldiarylsilyl, the substituted triarylsilyl, and the substituted fused ring each independently are substituted by at least one selected from the group consisting of deuterium; a halogen; a cyano; a carboxyl; a nitro; a hydroxyl; a phosphine oxide; a (C1-C30)alkyl; a halo(C1-C30)alkyl; a (C2-C30)alkenyl; a (C2-C30)alkynyl; a (C1-C30)alkoxy; a (C1-C30)alkylthio; a (C3-C30)cycloalkyl; a (C3-C30)cycloalkenyl; a (3- to 7-membered)heterocycloalkyl; a (C6-C30)aryloxy; a (C6-C30)arylthio; a (C6-C30)aryl unsubstituted or substituted with at least one of a (C1-C30)alkyl(s) and a di(C6-C30)arylamino(s); a (3- to 30-membered)heteroaryl unsubstituted or substituted with at least one of a (C6-C30)aryl(s); a tri(C1-C30)alkylsilyl; a tri(C6-C30)arylsilyl; a di(C1-C30)alkyl(C6-C30)arylsilyl; a (C1-C30)alkyldi(C6-C30)arylsilyl; a fused ring group of a (C3-C30) aliphatic ring(s) and a (C6-C30) aromatic ring(s); an amino; a mono- or di-(C1-C30)alkylamino; a mono- or di-(C2-C30)alkenylamino; a mono- or di-(C6-C30)arylamino unsubstituted or substituted with a (C1-C30)alkyl(s); a mono- or di-(3- to 30-membered)heteroarylamino; a (C1-C30)alkyl(C2-C30)alkenylamino; a (C1-C30)alkyl(C6-C30)arylamino; a (C1-C30)alkyl(3- to 30-membered)heteroarylamino; a (C2-C30)alkenyl(C6-C30)arylamino; a (C2-C30)alkenyl(3- to 30-membered)heteroarylamino; a (C6-C30)aryl(3- to 30-membered)heteroarylamino; a (C1-C30)alkylcarbonyl; a (C1-C30)alkoxycarbonyl; a (C6-C30)arylcarbonyl; a di(C6-C30)arylboronyl; a di(C1-C30)alkylboronyl; a (C1-C30)alkyl(C6-C30)arylboronyl; a (C6-C30)aryl(C1-C30)alkyl; and a (C1-C30)alkyl(C6-C30)aryl.

3. The organic electroluminescent compound according to claim 1, wherein Formula 1 is represented by any one of the following Formulas 1-1 to 1-4: 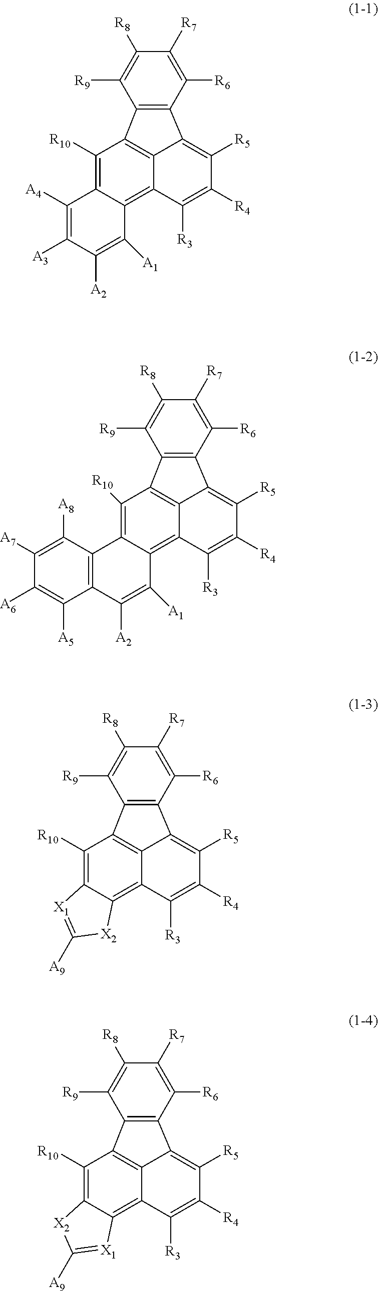
wherein in Formulas 1-1 to 1-4,
R₃ to R₁₀ are as defined in claim 1;
A₁ to A₉ each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, or a substituted or unsubstituted tri(C6-C30)arylsilyl;
X₁ represents —N═;
X₂ represents —NR₁₁, —O—, or —S—;
R₁₁ represents hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, or a substituted or unsubstituted tri(C6-C30)arylsilyl; and
at least one of R₃ to R₁ and A₁ to A₉ represents a substituted or unsubstituted (3- to 30-membered)heteroaryl comprising at least one N.

4. The organic electroluminescent compound according to claim 1, wherein the compound represented by Formula 1 is selected from the following compounds:

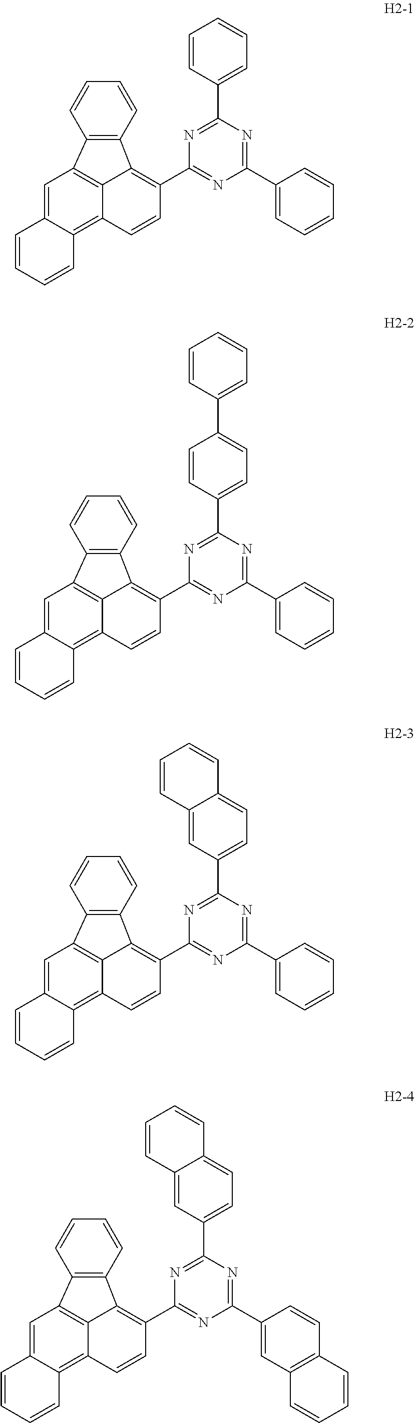 [SMILES: c1ccc(-c2nc(-c3ccccc3)nc(-c3ccc4c5c(cc6ccccc64)-c4ccccc4-c35)n2)cc1 ; c1ccc(-c2ccc(-c3nc(-c4ccccc4)nc(-c4ccc5c6c(cc7ccccc75)-c5ccccc5-c46)n3)cc2)cc1 ; c1ccc(-c2nc(-c3ccc4ccccc4c3)nc(-c3ccc4c5c(cc6ccccc64)-c4ccccc4-c35)n2)cc1 ; c1ccc2c(c1)-c1cc3ccccc3c3ccc(-c4nc(-c5ccc6ccccc6c5)nc(-c5ccc6ccccc6c5)n4)c-2c13]

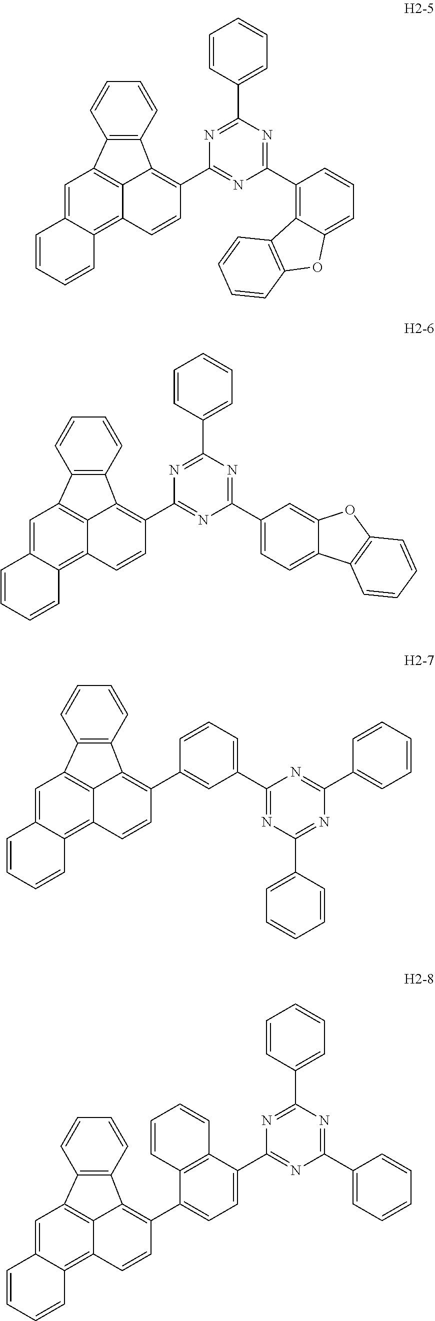 [SMILES: c1ccc(-c2nc(-c3ccc4c5c(cc6ccccc64)-c4ccccc4-c35)nc(-c3cccc4oc5ccccc5c34)n2)cc1 ; c1ccc(-c2nc(-c3ccc4c(c3)oc3ccccc34)nc(-c3ccc4c5c(cc6ccccc64)-c4ccccc4-c35)n2)cc1 ; c1ccc(-c2nc(-c3ccccc3)nc(-c3cccc(-c4ccc5c6c(cc7ccccc75)-c5ccccc5-c46)c3)n2)cc1 ; c1ccc(-c2nc(-c3ccccc3)nc(-c3ccc(-c4ccc5c6c(cc7ccccc75)-c5ccccc5-c46)c4ccccc34)n2)cc1]

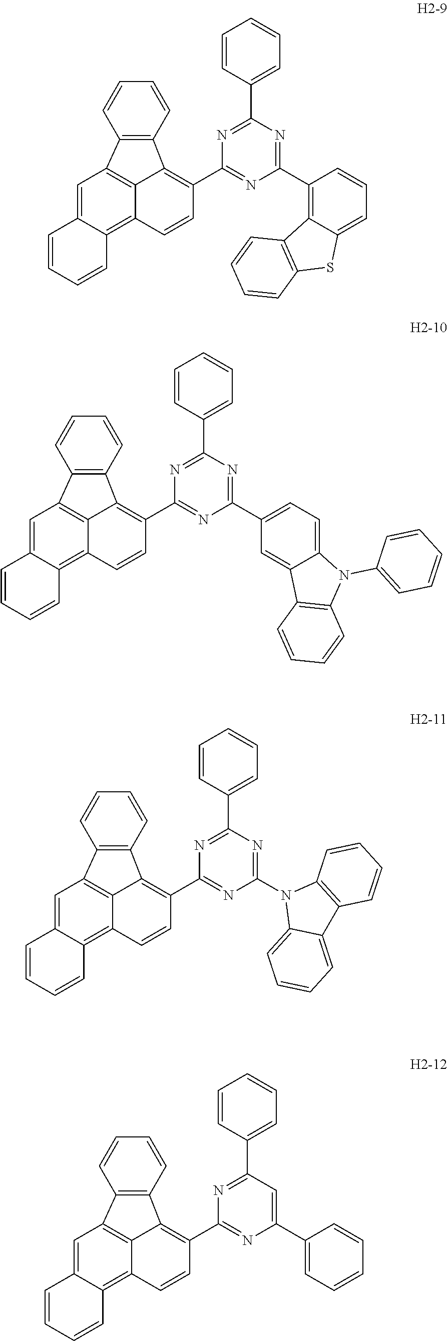 [SMILES: c1ccc(-c2nc(-c3ccc4c5c(cc6ccccc64)-c4ccccc4-c35)nc(-c3cccc4sc5ccccc5c34)n2)cc1 ; c1ccc(-c2nc(-c3ccc4c(c3)c3ccccc3n4-c3ccccc3)nc(-c3ccc4c5c(cc6ccccc64)-c4ccccc4-c35)n2)cc1 ; c1ccc(-c2nc(-c3ccc4c5c(cc6ccccc64)-c4ccccc4-c35)nc(-n3c4ccccc4c4ccccc43)n2)cc1 ; c1ccc(-c2cc(-c3ccccc3)nc(-c3ccc4c5c(cc6ccccc64)-c4ccccc4-c35)n2)cc1]

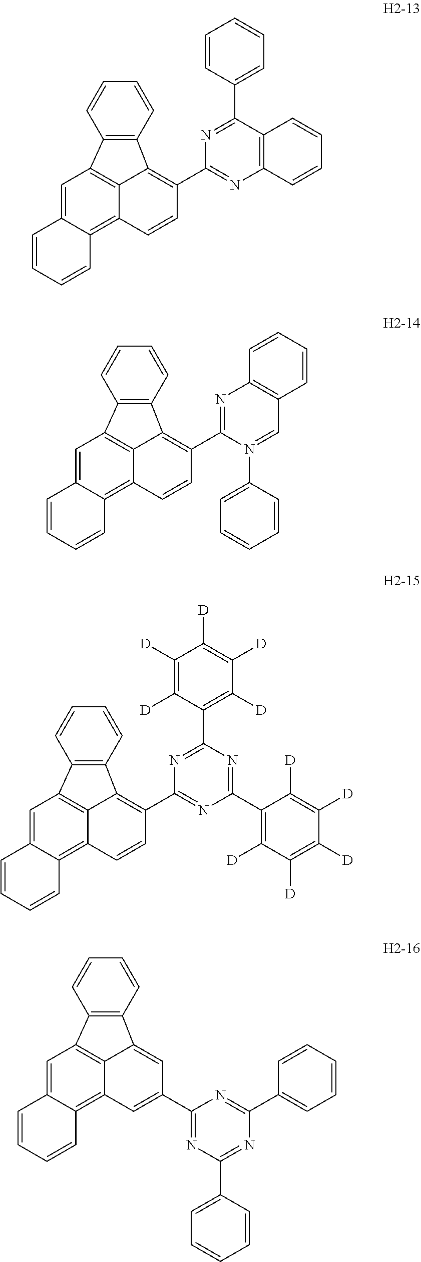

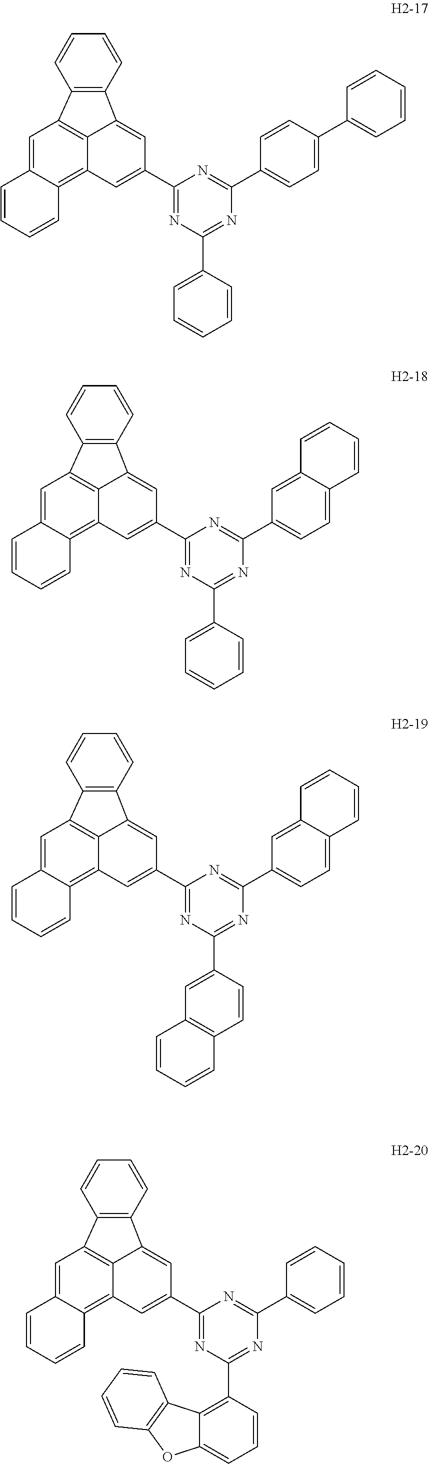 [SMILES: c1ccc(-c2ccc(-c3nc(-c4ccccc4)nc(-c4cc5c6c(cc7ccccc7c6c4)-c4ccccc4-5)n3)cc2)cc1 ; c1ccc(-c2nc(-c3ccc4ccccc4c3)nc(-c3cc4c5c(cc6ccccc6c5c3)-c3ccccc3-4)n2)cc1 ; c1ccc2c(c1)-c1cc(-c3nc(-c4ccc5ccccc5c4)nc(-c4ccc5ccccc5c4)n3)cc3c1c-2cc1ccccc13 ; c1ccc(-c2nc(-c3cc4c5c(cc6ccccc6c5c3)-c3ccccc3-4)nc(-c3cccc4oc5ccccc5c34)n2)cc1]

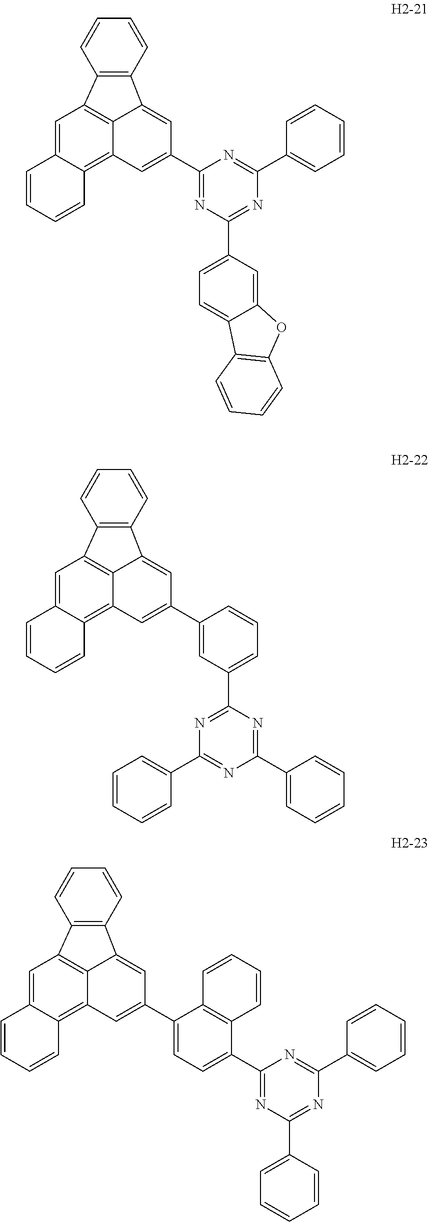 [SMILES: c1ccc(-c2nc(-c3ccc4c(c3)oc3ccccc34)nc(-c3cc4c5c(cc6ccccc6c5c3)-c3ccccc3-4)n2)cc1 ; c1ccc(-c2nc(-c3ccccc3)nc(-c3cccc(-c4cc5c6c(cc7ccccc7c6c4)-c4ccccc4-5)c3)n2)cc1 ; c1ccc(-c2nc(-c3ccccc3)nc(-c3ccc(-c4cc5c6c(cc7ccccc7c6c4)-c4ccccc4-5)c4ccccc34)n2)cc1]

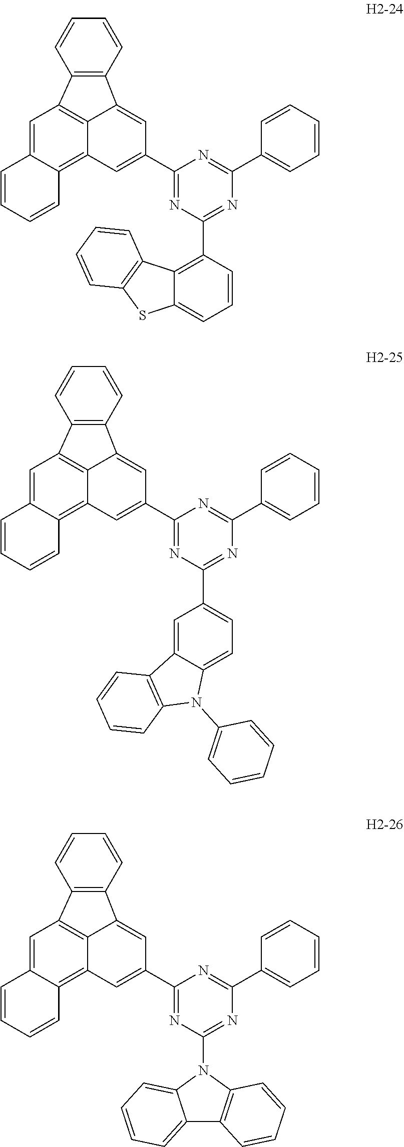 [SMILES: c1ccc(-c2nc(-c3cc4c5c(cc6ccccc6c5c3)-c3ccccc3-4)nc(-c3cccc4sc5ccccc5c34)n2)cc1 ; c1ccc(-c2nc(-c3cc4c5c(cc6ccccc6c5c3)-c3ccccc3-4)nc(-c3ccc4c(c3)c3ccccc3n4-c3ccccc3)n2)cc1 ; c1ccc(-c2nc(-c3cc4c5c(cc6ccccc6c5c3)-c3ccccc3-4)nc(-n3c4ccccc4c4ccccc43)n2)cc1]

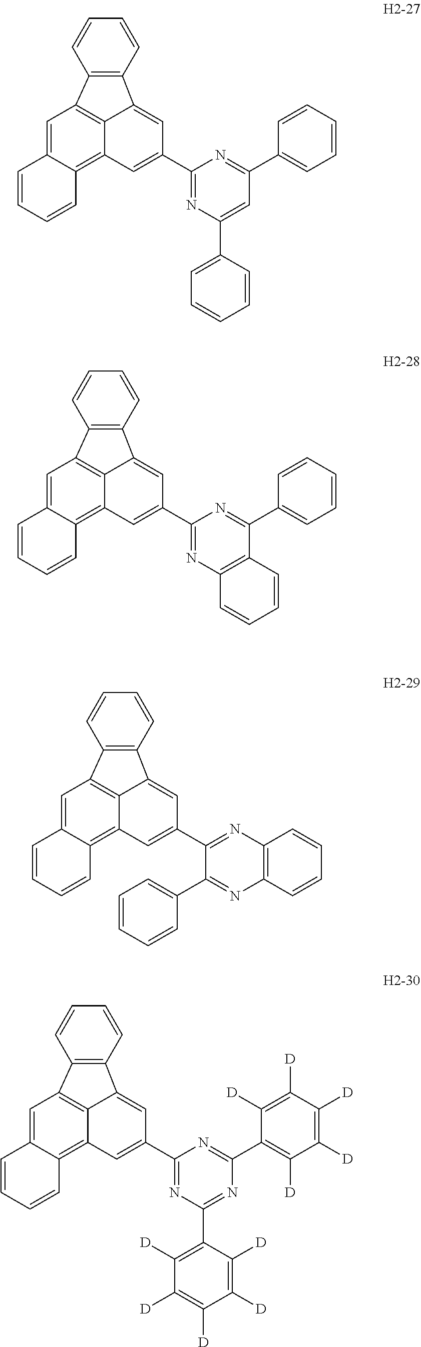 [SMILES: c1ccc(-c2cc(-c3ccccc3)nc(-c3cc4c5c(cc6ccccc6c5c3)-c3ccccc3-4)n2)cc1 ; c1ccc(-c2nc(-c3cc4c5c(cc6ccccc6c5c3)-c3ccccc3-4)nc3ccccc23)cc1 ; c1ccc(-c2nc3ccccc3nc2-c2cc3c4c(cc5ccccc5c4c2)-c2ccccc2-3)cc1 ; [2H]c1c([2H])c([2H])c(-c2nc(-c3cc4c5c(cc6ccccc6c5c3)-c3ccccc3-4)nc(-c3c([2H])c([2H])c([2H])c([2H])c3[2H])n2)c([2H])c1[2H]]

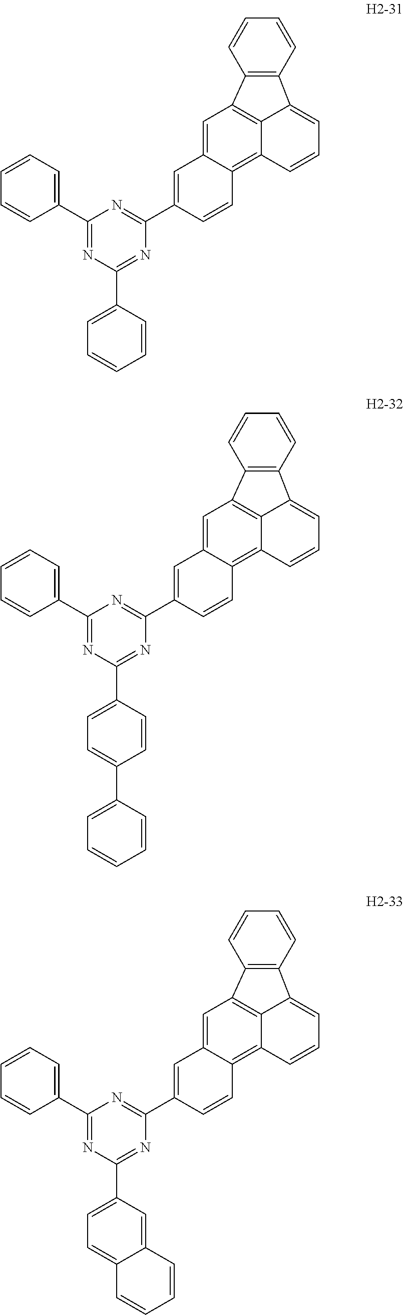 [SMILES: c1ccc(-c2nc(-c3ccccc3)nc(-c3ccc4c(c3)cc3c5c(cccc54)-c4ccccc4-3)n2)cc1 ; c1ccc(-c2ccc(-c3nc(-c4ccccc4)nc(-c4ccc5c(c4)cc4c6c(cccc65)-c5ccccc5-4)n3)cc2)cc1 ; c1ccc(-c2nc(-c3ccc4ccccc4c3)nc(-c3ccc4c(c3)cc3c5c(cccc54)-c4ccccc4-3)n2)cc1]

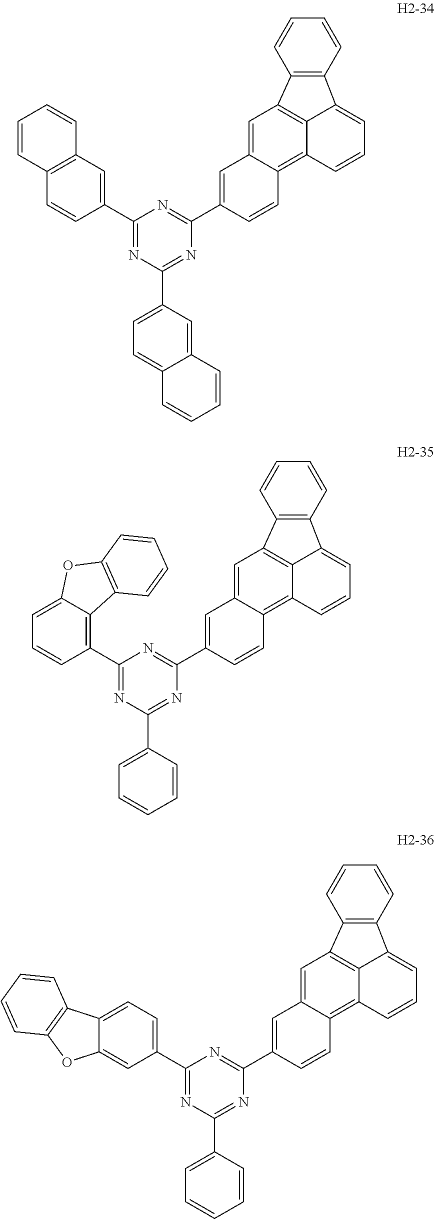 [SMILES: c1ccc2c(c1)-c1cccc3c1c-2cc1cc(-c2nc(-c4ccc5ccccc5c4)nc(-c4ccc5ccccc5c4)n2)ccc13 ; c1ccc(-c2nc(-c3ccc4c(c3)cc3c5c(cccc54)-c4ccccc4-3)nc(-c3cccc4oc5ccccc5c34)n2)cc1 ; c1ccc(-c2nc(-c3ccc4c(c3)cc3c5c(cccc54)-c4ccccc4-3)nc(-c3ccc4c(c3)oc3ccccc34)n2)cc1]

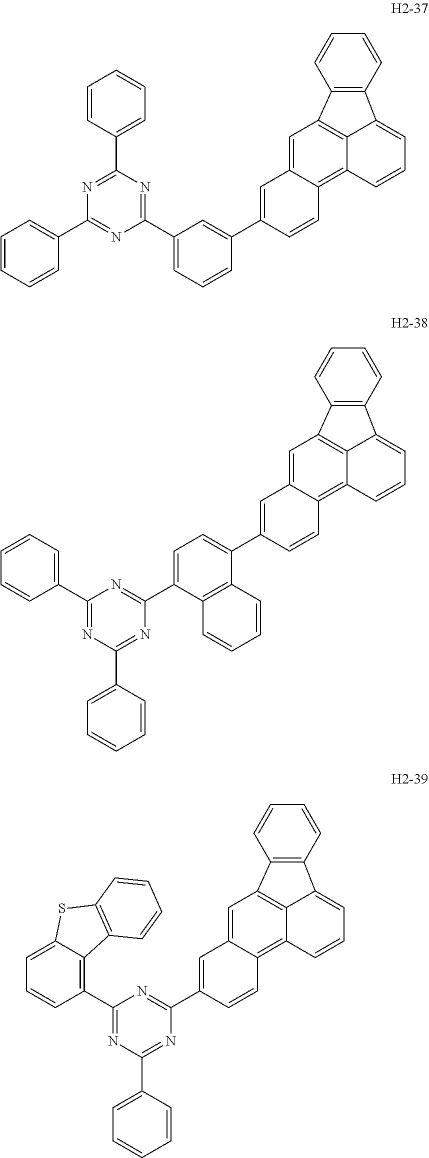 [SMILES: c1ccc(-c2nc(-c3ccccc3)nc(-c3cccc(-c4ccc5c(c4)cc4c6c(cccc65)-c5ccccc5-4)c3)n2)cc1 ; c1ccc(-c2nc(-c3ccccc3)nc(-c3ccc(-c4ccc5c(c4)cc4c6c(cccc65)-c5ccccc5-4)c4ccccc34)n2)cc1 ; c1ccc(-c2nc(-c3ccc4c(c3)cc3c5c(cccc54)-c4ccccc4-3)nc(-c3cccc4sc5ccccc5c34)n2)cc1]

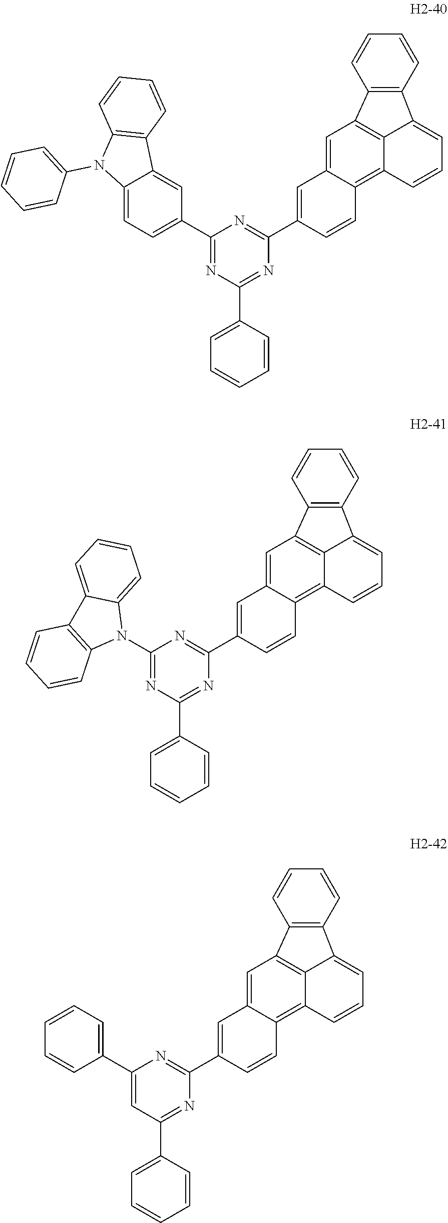 [SMILES: c1ccc(-c2nc(-c3ccc4c(c3)cc3c5c(cccc54)-c4ccccc4-3)nc(-c3ccc4c(c3)c3ccccc3n4-c3ccccc3)n2)cc1 ; c1ccc(-c2nc(-c3ccc4c(c3)cc3c5c(cccc54)-c4ccccc4-3)nc(-n3c4ccccc4c4ccccc43)n2)cc1 ; c1ccc(-c2cc(-c3ccccc3)nc(-c3ccc4c(c3)cc3c5c(cccc54)-c4ccccc4-3)n2)cc1]

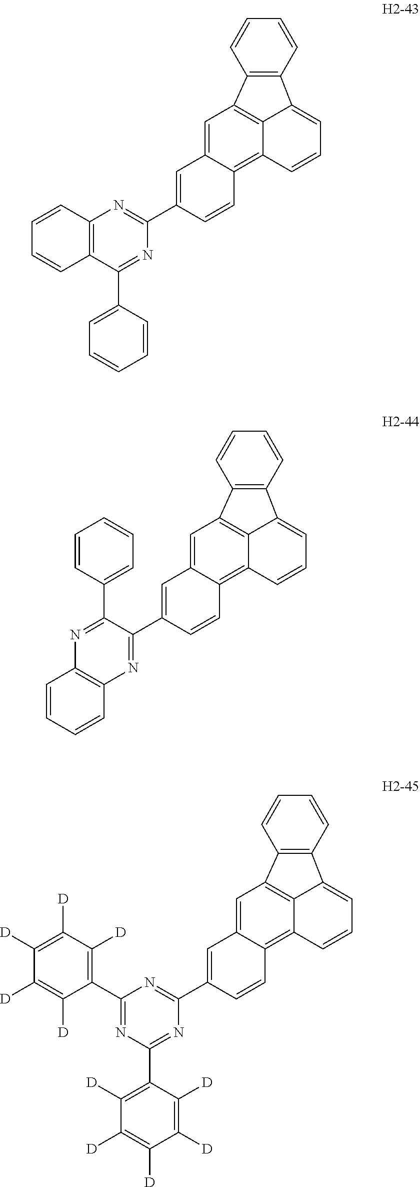 [SMILES: c1ccc(-c2nc(-c3ccc4c(c3)cc3c5c(cccc54)-c4ccccc4-3)nc3ccccc23)cc1 ; c1ccc(-c2nc3ccccc3nc2-c2ccc3c(c2)cc2c4c(cccc43)-c3ccccc3-2)cc1 ; [2H]c1c([2H])c([2H])c(-c2nc(-c3ccc4c(c3)cc3c5c(cccc54)-c4ccccc4-3)nc(-c3c([2H])c([2H])c([2H])c([2H])c3[2H])n2)c([2H])c1[2H]]

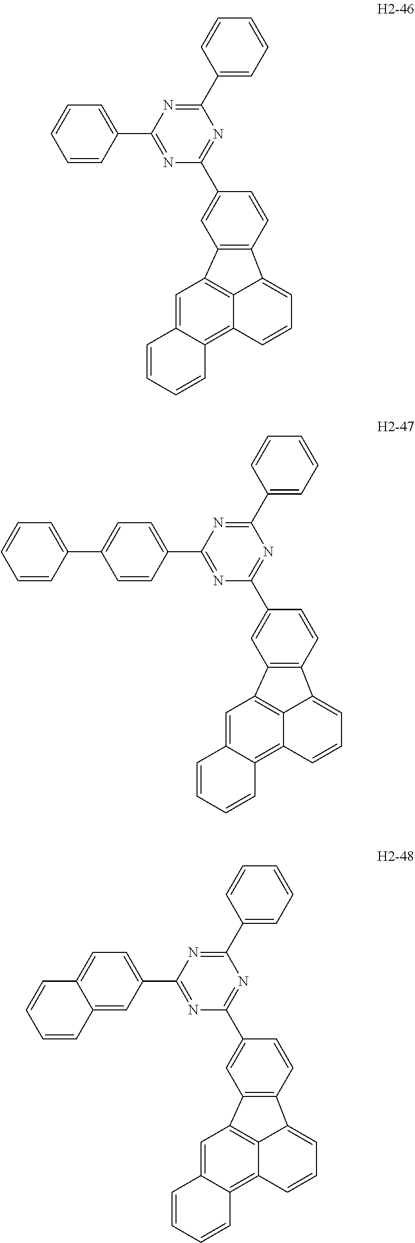 [SMILES: c1ccc(-c2nc(-c3ccccc3)nc(-c3ccc4c(c3)-c3cc5ccccc5c5cccc-4c35)n2)cc1 ; c1ccc(-c2ccc(-c3nc(-c4ccccc4)nc(-c4ccc5c(c4)-c4cc6ccccc6c6cccc-5c46)n3)cc2)cc1 ; c1ccc(-c2nc(-c3ccc4c(c3)-c3cc5ccccc5c5cccc-4c35)nc(-c3ccc4ccccc4c3)n2)cc1]

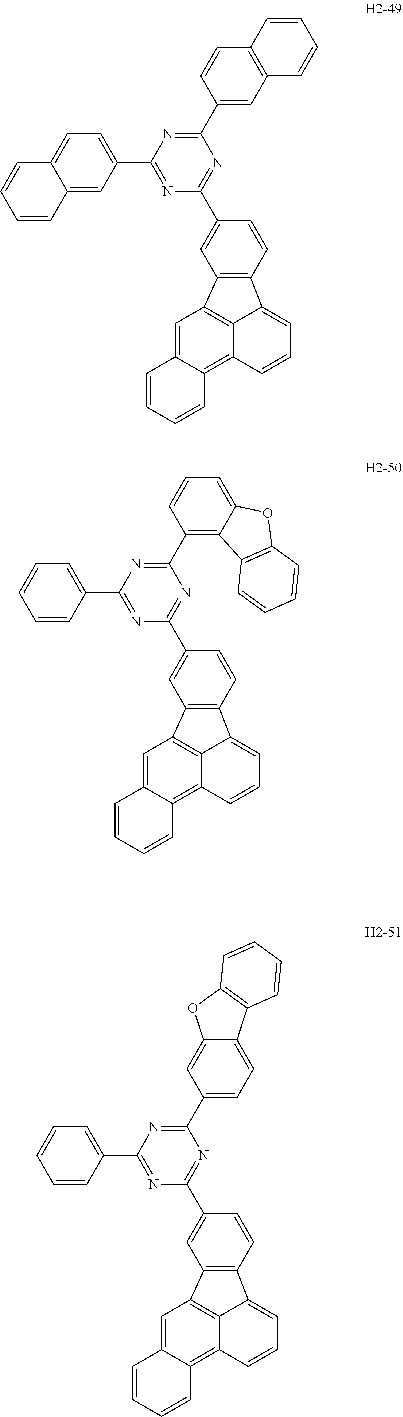 [SMILES: c1ccc2cc(-c3nc(-c4ccc5c(c4)-c4cc6ccccc6c6cccc-5c46)nc(-c4ccc5ccccc5c4)n3)ccc2c1 ; c1ccc(-c2nc(-c3ccc4c(c3)-c3cc5ccccc5c5cccc-4c35)nc(-c3cccc4oc5ccccc5c34)n2)cc1 ; c1ccc(-c2nc(-c3ccc4c(c3)-c3cc5ccccc5c5cccc-4c35)nc(-c3ccc4c(c3)oc3ccccc34)n2)cc1]

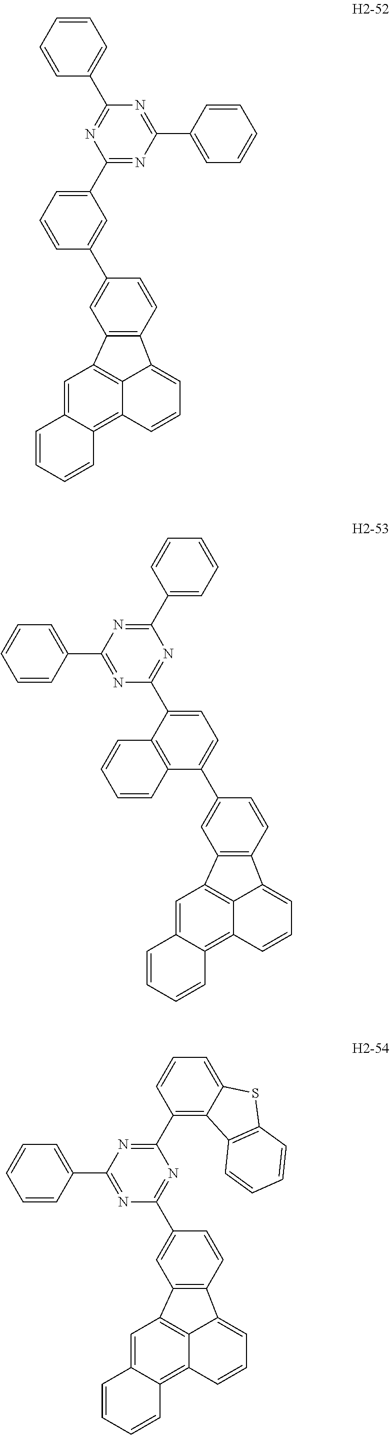 [SMILES: c1ccc(-c2nc(-c3ccccc3)nc(-c3cccc(-c4ccc5c(c4)-c4cc6ccccc6c6cccc-5c46)c3)n2)cc1 ; c1ccc(-c2nc(-c3ccccc3)nc(-c3ccc(-c4ccc5c(c4)-c4cc6ccccc6c6cccc-5c46)c4ccccc34)n2)cc1 ; c1ccc(-c2nc(-c3ccc4c(c3)-c3cc5ccccc5c5cccc-4c35)nc(-c3cccc4sc5ccccc5c34)n2)cc1]

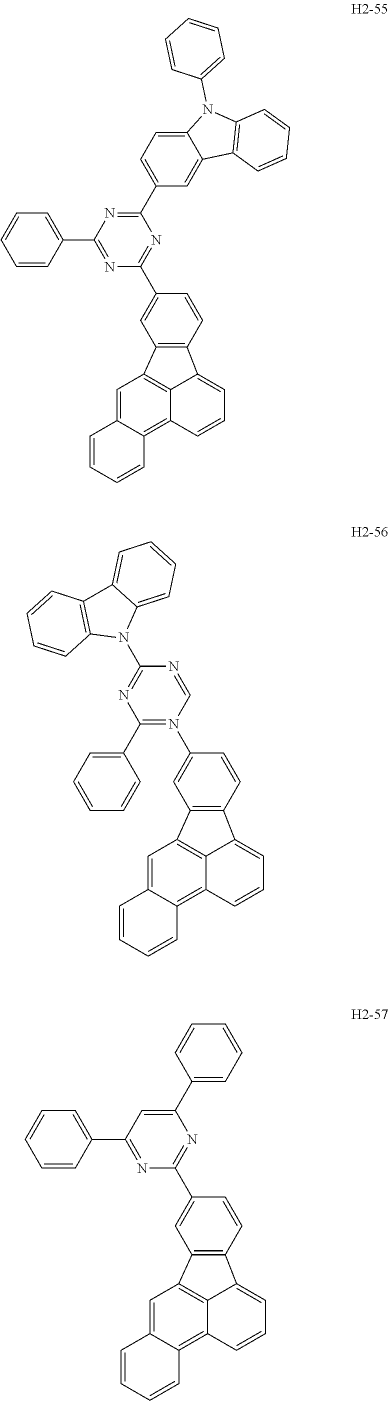

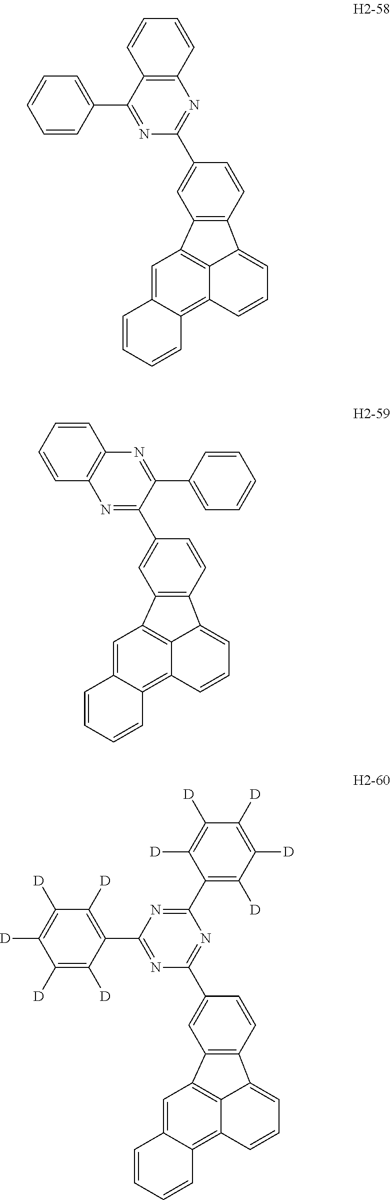 [SMILES: c1ccc(-c2nc(-c3ccc4c(c3)-c3cc5ccccc5c5cccc-4c35)nc3ccccc23)cc1 ; c1ccc(-c2nc3ccccc3nc2-c2ccc3c(c2)-c2cc4ccccc4c4cccc-3c24)cc1 ; [2H]c1c([2H])c([2H])c(-c2nc(-c3ccc4c(c3)-c3cc5ccccc5c5cccc-4c35)nc(-c3c([2H])c([2H])c([2H])c([2H])c3[2H])n2)c([2H])c1[2H]]

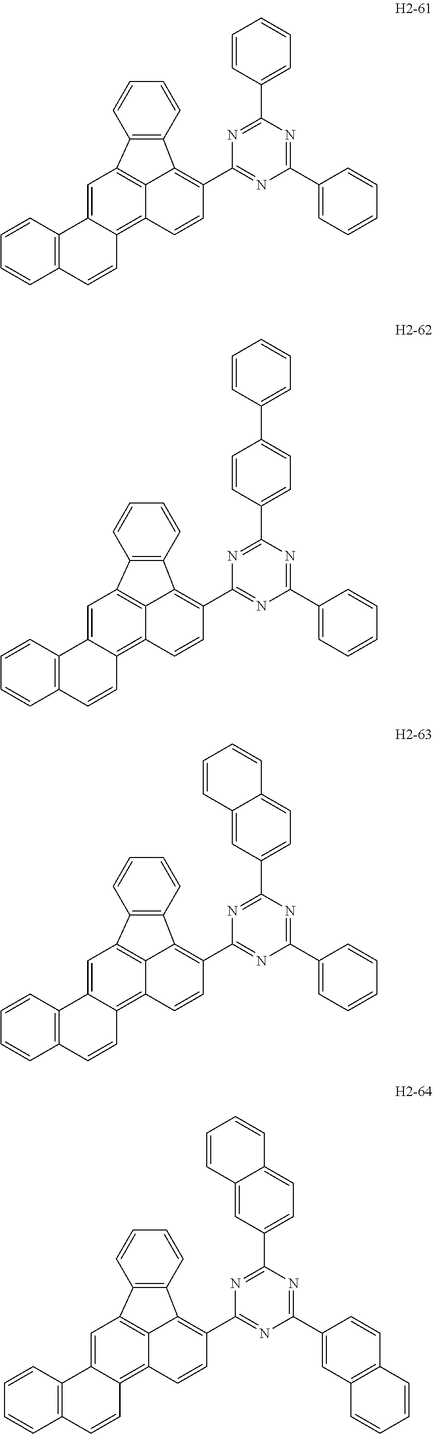 [SMILES: c1ccc(-c2nc(-c3ccccc3)nc(-c3ccc4c5c(cc6c7ccccc7ccc46)-c4ccccc4-c35)n2)cc1 ; c1ccc(-c2ccc(-c3nc(-c4ccccc4)nc(-c4ccc5c6c(cc7c8ccccc8ccc57)-c5ccccc5-c46)n3)cc2)cc1 ; c1ccc(-c2nc(-c3ccc4ccccc4c3)nc(-c3ccc4c5c(cc6c7ccccc7ccc46)-c4ccccc4-c35)n2)cc1 ; c1ccc2c(c1)-c1cc3c4ccccc4ccc3c3ccc(-c4nc(-c5ccc6ccccc6c5)nc(-c5ccc6ccccc6c5)n4)c-2c13]

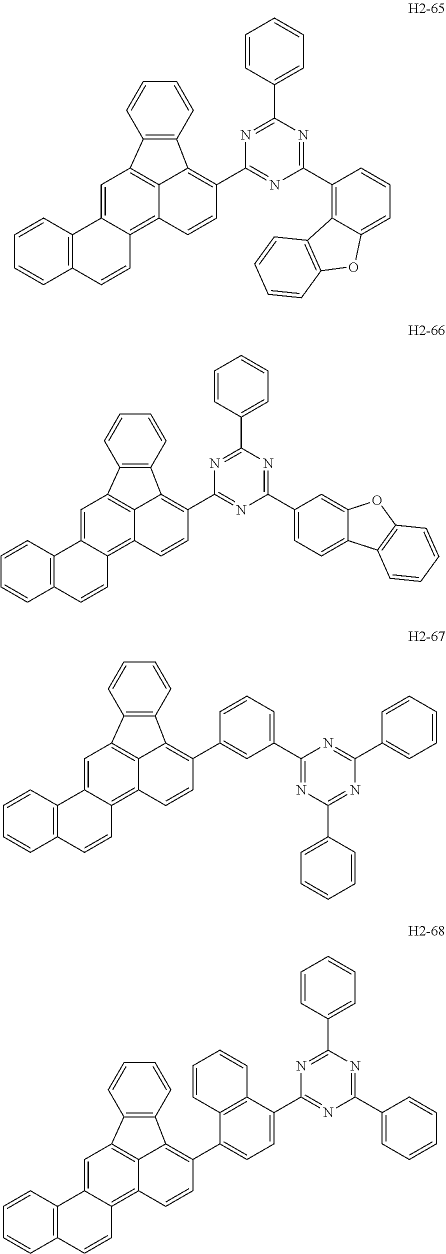 [SMILES: c1ccc(-c2nc(-c3ccc4c5c(cc6c7ccccc7ccc46)-c4ccccc4-c35)nc(-c3cccc4oc5ccccc5c34)n2)cc1 ; c1ccc(-c2nc(-c3ccc4c(c3)oc3ccccc34)nc(-c3ccc4c5c(cc6c7ccccc7ccc46)-c4ccccc4-c35)n2)cc1 ; c1ccc(-c2nc(-c3ccccc3)nc(-c3cccc(-c4ccc5c6c(cc7c8ccccc8ccc57)-c5ccccc5-c46)c3)n2)cc1 ; c1ccc(-c2nc(-c3ccccc3)nc(-c3ccc(-c4ccc5c6c(cc7c8ccccc8ccc57)-c5ccccc5-c46)c4ccccc34)n2)cc1]

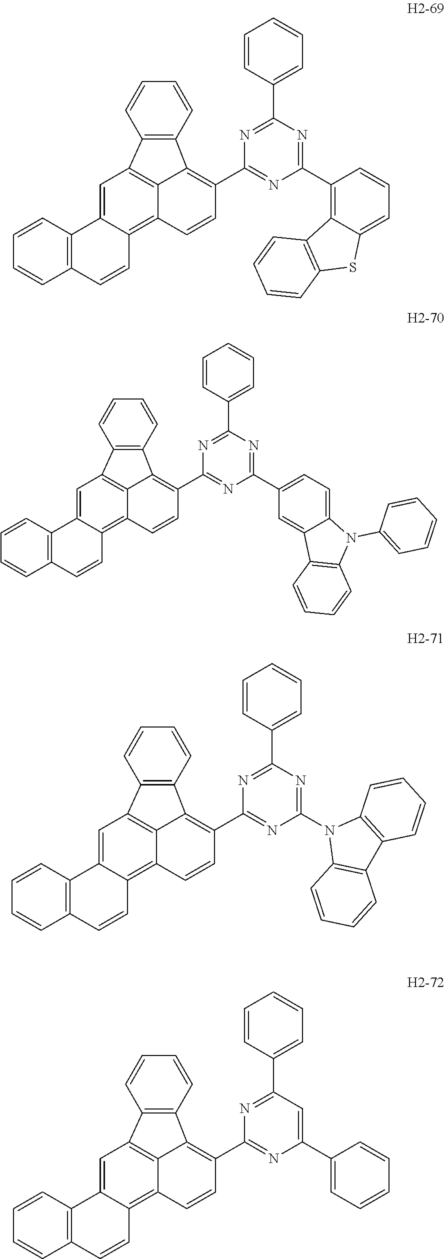 [SMILES: c1ccc(-c2nc(-c3ccc4c5c(cc6c7ccccc7ccc46)-c4ccccc4-c35)nc(-c3cccc4sc5ccccc5c34)n2)cc1 ; c1ccc(-c2nc(-c3ccc4c(c3)c3ccccc3n4-c3ccccc3)nc(-c3ccc4c5c(cc6c7ccccc7ccc46)-c4ccccc4-c35)n2)cc1 ; c1ccc(-c2nc(-c3ccc4c5c(cc6c7ccccc7ccc46)-c4ccccc4-c35)nc(-n3c4ccccc4c4ccccc43)n2)cc1 ; c1ccc(-c2cc(-c3ccccc3)nc(-c3ccc4c5c(cc6c7ccccc7ccc46)-c4ccccc4-c35)n2)cc1]

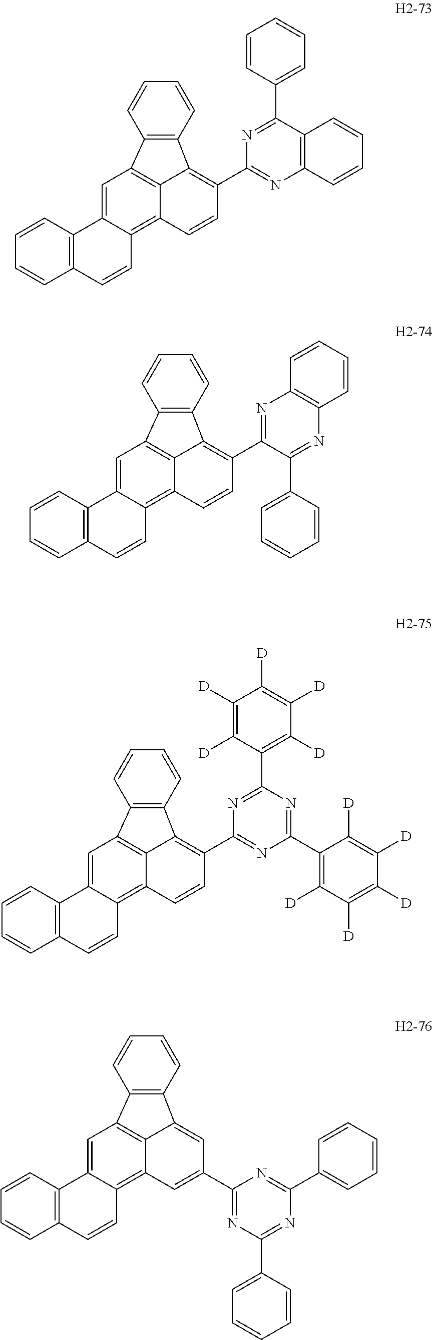 [SMILES: c1ccc(-c2nc(-c3ccc4c5c(cc6c7ccccc7ccc46)-c4ccccc4-c35)nc3ccccc23)cc1 ; c1ccc(-c2nc3ccccc3nc2-c2ccc3c4c(cc5c6ccccc6ccc35)-c3ccccc3-c24)cc1 ; [2H]c1c([2H])c([2H])c(-c2nc(-c3ccc4c5c(cc6c7ccccc7ccc46)-c4ccccc4-c35)nc(-c3c([2H])c([2H])c([2H])c([2H])c3[2H])n2)c([2H])c1[2H] ; c1ccc(-c2nc(-c3ccccc3)nc(-c3cc4c5c(cc6c7ccccc7ccc6c5c3)-c3ccccc3-4)n2)cc1]

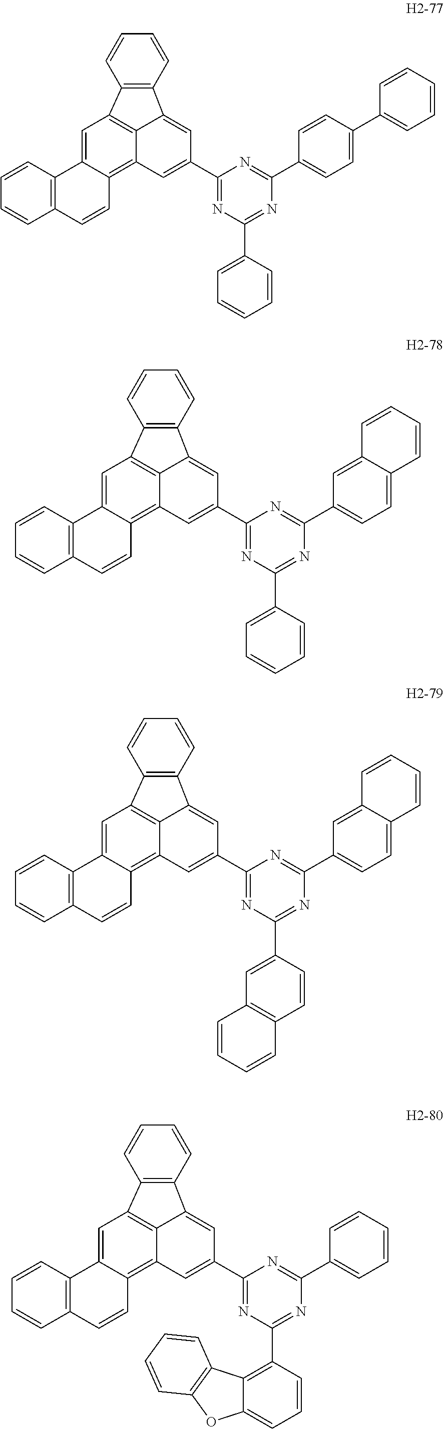 [SMILES: c1ccc(-c2ccc(-c3nc(-c4ccccc4)nc(-c4cc5c6c(cc7c8ccccc8ccc7c6c4)-c4ccccc4-5)n3)cc2)cc1 ; c1ccc(-c2nc(-c3ccc4ccccc4c3)nc(-c3cc4c5c(cc6c7ccccc7ccc6c5c3)-c3ccccc3-4)n2)cc1 ; c1ccc2c(c1)-c1cc(-c3nc(-c4ccc5ccccc5c4)nc(-c4ccc5ccccc5c4)n3)cc3c1c-2cc1c2ccccc2ccc31 ; c1ccc(-c2nc(-c3cc4c5c(cc6c7ccccc7ccc6c5c3)-c3ccccc3-4)nc(-c3cccc4oc5ccccc5c34)n2)cc1]

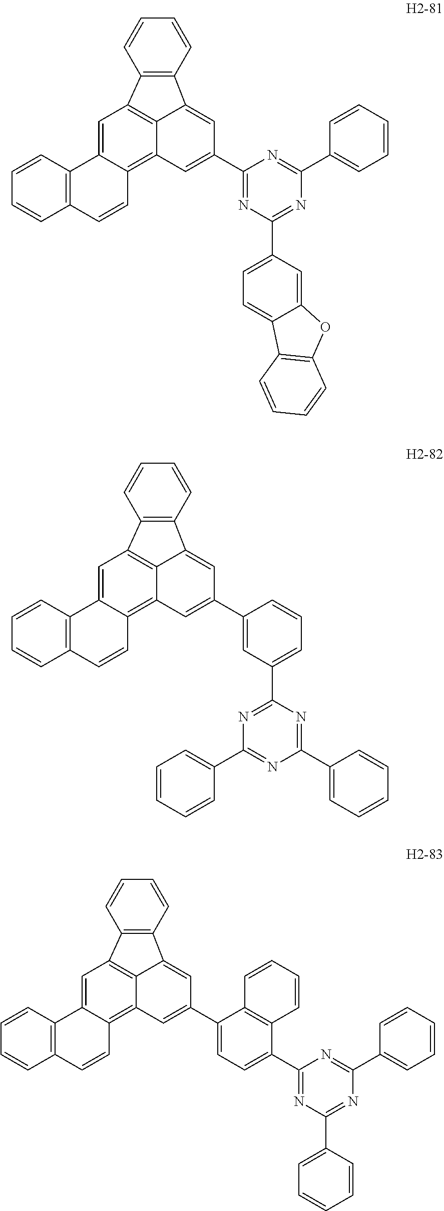 [SMILES: c1ccc(-c2nc(-c3ccc4c(c3)oc3ccccc34)nc(-c3cc4c5c(cc6c7ccccc7ccc6c5c3)-c3ccccc3-4)n2)cc1 ; c1ccc(-c2nc(-c3ccccc3)nc(-c3cccc(-c4cc5c6c(cc7c8ccccc8ccc7c6c4)-c4ccccc4-5)c3)n2)cc1 ; c1ccc(-c2nc(-c3ccccc3)nc(-c3ccc(-c4cc5c6c(cc7c8ccccc8ccc7c6c4)-c4ccccc4-5)c4ccccc34)n2)cc1]

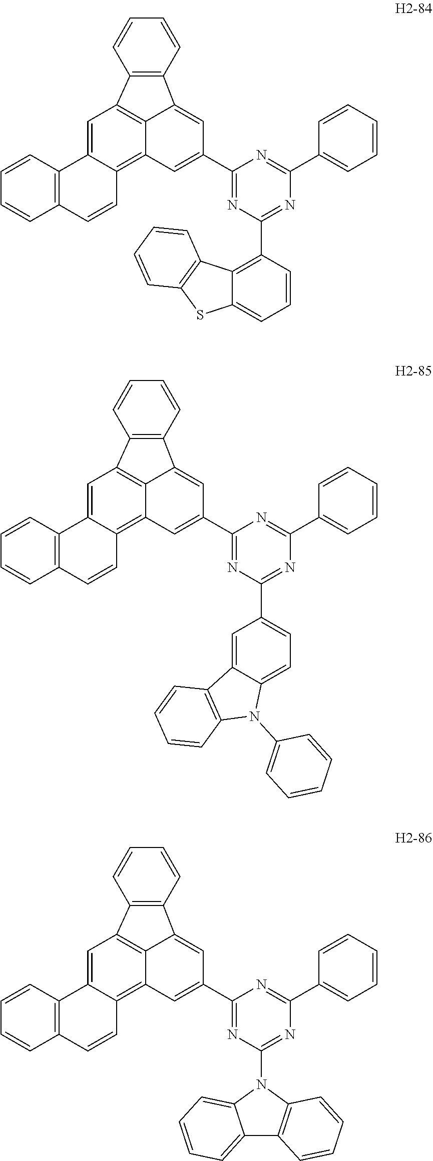 [SMILES: c1ccc(-c2nc(-c3cc4c5c(cc6c7ccccc7ccc6c5c3)-c3ccccc3-4)nc(-c3cccc4sc5ccccc5c34)n2)cc1 ; c1ccc(-c2nc(-c3cc4c5c(cc6c7ccccc7ccc6c5c3)-c3ccccc3-4)nc(-c3ccc4c(c3)c3ccccc3n4-c3ccccc3)n2)cc1 ; c1ccc(-c2nc(-c3cc4c5c(cc6c7ccccc7ccc6c5c3)-c3ccccc3-4)nc(-n3c4ccccc4c4ccccc43)n2)cc1]

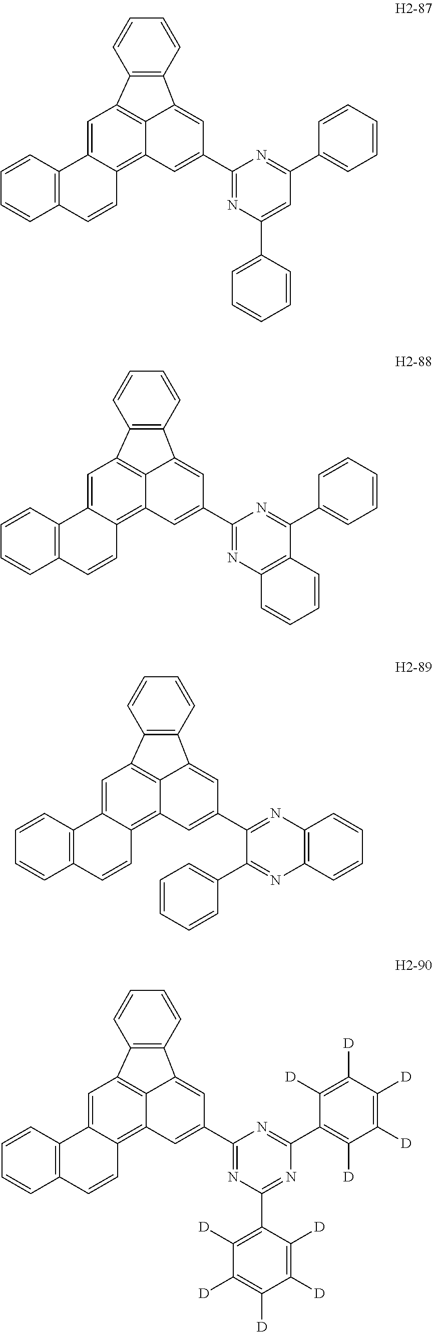 [SMILES: c1ccc(-c2cc(-c3ccccc3)nc(-c3cc4c5c(cc6c7ccccc7ccc6c5c3)-c3ccccc3-4)n2)cc1 ; c1ccc(-c2nc(-c3cc4c5c(cc6c7ccccc7ccc6c5c3)-c3ccccc3-4)nc3ccccc23)cc1 ; c1ccc(-c2nc3ccccc3nc2-c2cc3c4c(cc5c6ccccc6ccc5c4c2)-c2ccccc2-3)cc1 ; [2H]c1c([2H])c([2H])c(-c2nc(-c3cc4c5c(cc6c7ccccc7ccc6c5c3)-c3ccccc3-4)nc(-c3c([2H])c([2H])c([2H])c([2H])c3[2H])n2)c([2H])c1[2H]]

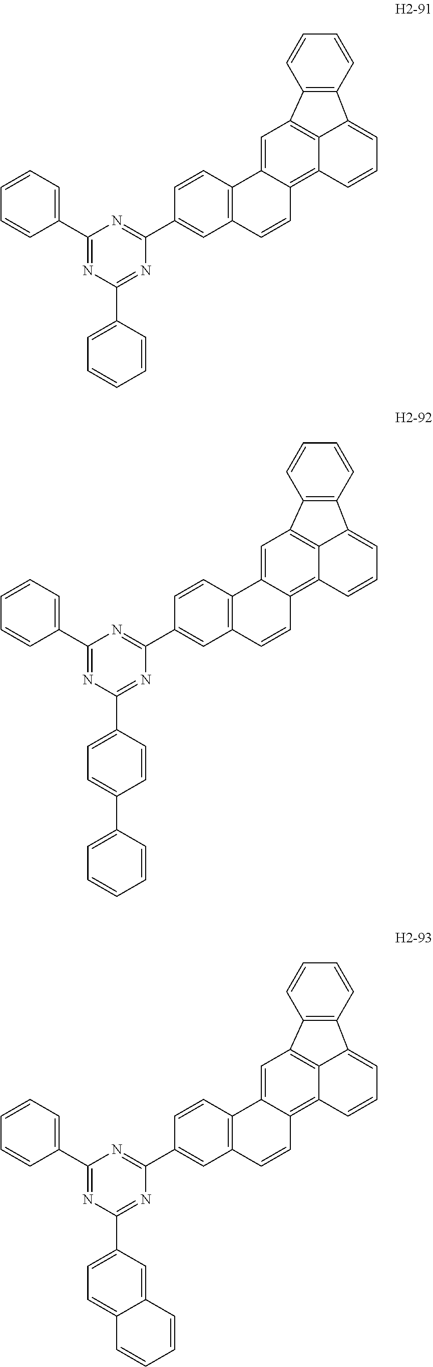 [SMILES: c1ccc(-c2nc(-c3ccccc3)nc(-c3ccc4c(ccc5c6cccc7c6c(cc45)-c4ccccc4-7)c3)n2)cc1 ; c1ccc(-c2ccc(-c3nc(-c4ccccc4)nc(-c4ccc5c(ccc6c7cccc8c7c(cc56)-c5ccccc5-8)c4)n3)cc2)cc1 ; c1ccc(-c2nc(-c3ccc4ccccc4c3)nc(-c3ccc4c(ccc5c6cccc7c6c(cc45)-c4ccccc4-7)c3)n2)cc1]

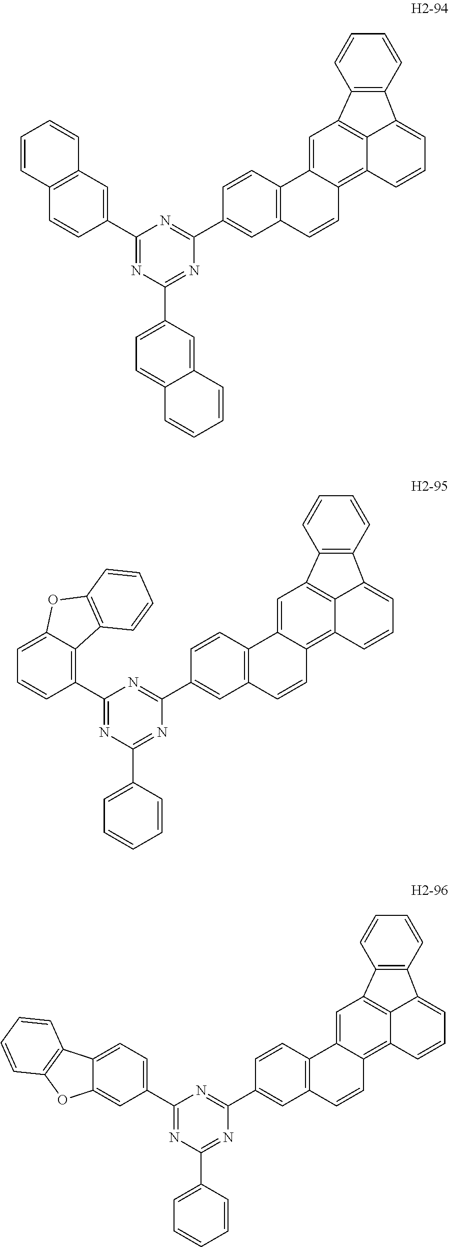 [SMILES: c1ccc2c(c1)-c1cccc3c1c-2cc1c2ccc(-c4nc(-c5ccc6ccccc6c5)nc(-c5ccc6ccccc6c5)n4)cc2ccc31 ; c1ccc(-c2nc(-c3ccc4c(ccc5c6cccc7c6c(cc45)-c4ccccc4-7)c3)nc(-c3cccc4oc5ccccc5c34)n2)cc1 ; c1ccc(-c2nc(-c3ccc4c(ccc5c6cccc7c6c(cc45)-c4ccccc4-7)c3)nc(-c3ccc4c(c3)oc3ccccc34)n2)cc1]

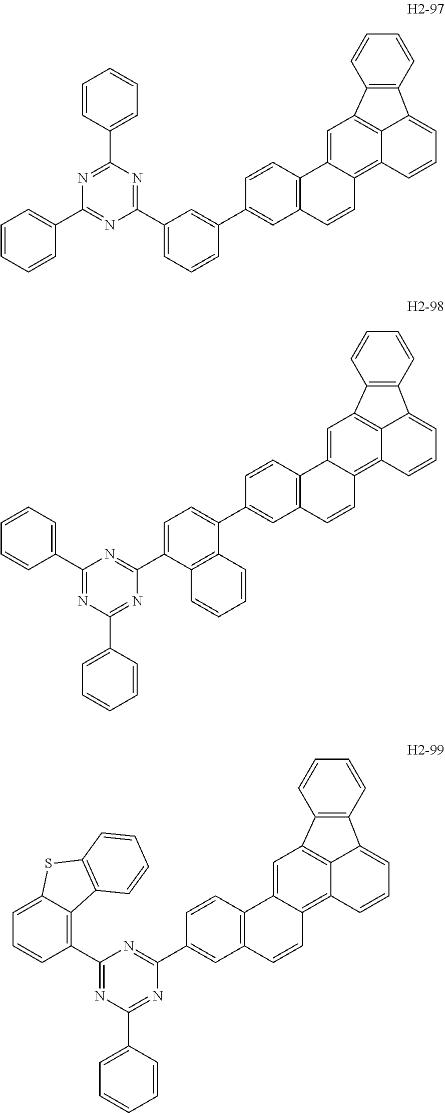 [SMILES: c1ccc(-c2nc(-c3ccccc3)nc(-c3cccc(-c4ccc5c(ccc6c7cccc8c7c(cc56)-c5ccccc5-8)c4)c3)n2)cc1 ; c1ccc(-c2nc(-c3ccccc3)nc(-c3ccc(-c4ccc5c(ccc6c7cccc8c7c(cc56)-c5ccccc5-8)c4)c4ccccc34)n2)cc1 ; c1ccc(-c2nc(-c3ccc4c(ccc5c6cccc7c6c(cc45)-c4ccccc4-7)c3)nc(-c3cccc4sc5ccccc5c34)n2)cc1]

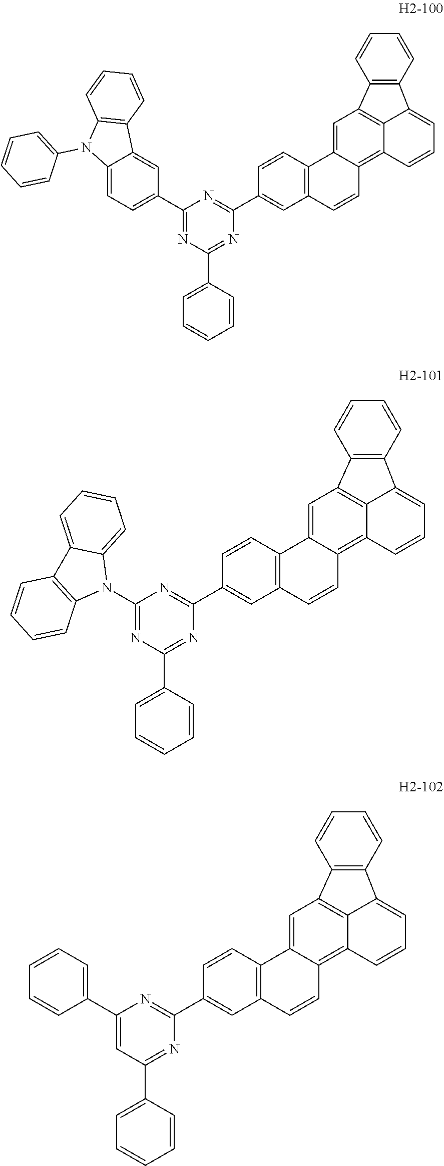 [SMILES: c1ccc(-c2nc(-c3ccc4c(ccc5c6cccc7c6c(cc45)-c4ccccc4-7)c3)nc(-c3ccc4c(c3)c3ccccc3n4-c3ccccc3)n2)cc1 ; c1ccc(-c2nc(-c3ccc4c(ccc5c6cccc7c6c(cc45)-c4ccccc4-7)c3)nc(-n3c4ccccc4c4ccccc43)n2)cc1 ; c1ccc(-c2cc(-c3ccccc3)nc(-c3ccc4c(ccc5c6cccc7c6c(cc45)-c4ccccc4-7)c3)n2)cc1]

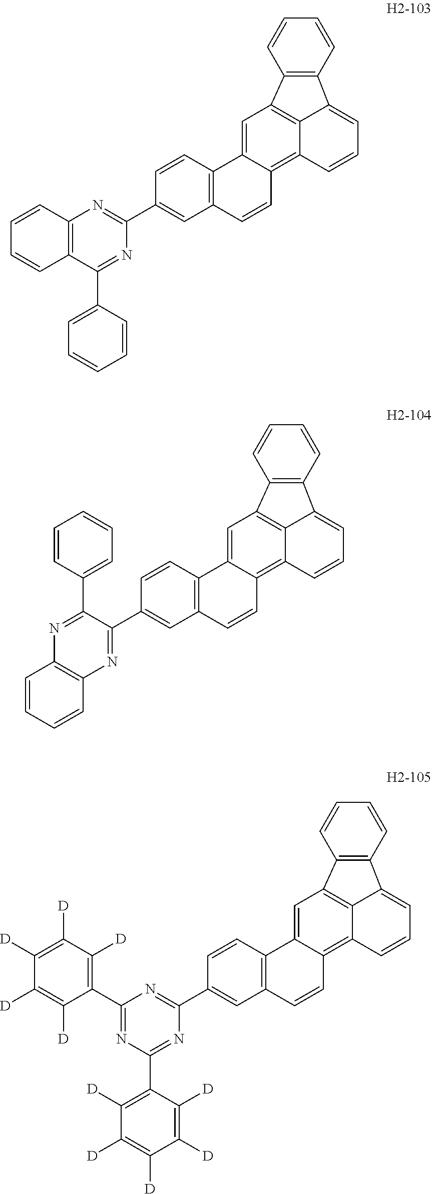 [SMILES: c1ccc(-c2nc(-c3ccc4c(ccc5c6cccc7c6c(cc45)-c4ccccc4-7)c3)nc3ccccc23)cc1 ; c1ccc(-c2nc3ccccc3nc2-c2ccc3c(ccc4c5cccc6c5c(cc34)-c3ccccc3-6)c2)cc1 ; [2H]c1c([2H])c([2H])c(-c2nc(-c3ccc4c(ccc5c6cccc7c6c(cc45)-c4ccccc4-7)c3)nc(-c3c([2H])c([2H])c([2H])c([2H])c3[2H])n2)c([2H])c1[2H]]

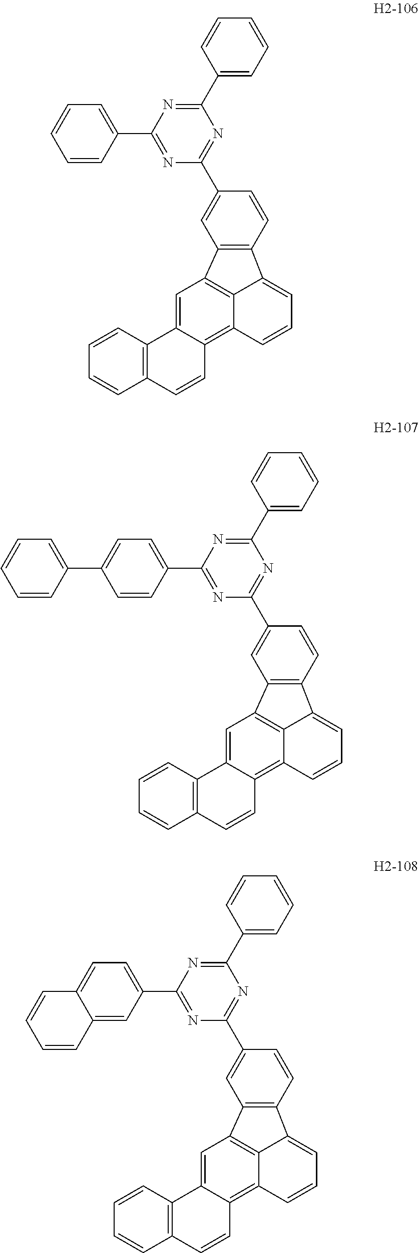 [SMILES: c1ccc(-c2nc(-c3ccccc3)nc(-c3ccc4c(c3)-c3cc5c6ccccc6ccc5c5cccc-4c35)n2)cc1 ; c1ccc(-c2ccc(-c3nc(-c4ccccc4)nc(-c4ccc5c(c4)-c4cc6c7ccccc7ccc6c6cccc-5c46)n3)cc2)cc1 ; c1ccc(-c2nc(-c3ccc4c(c3)-c3cc5c6ccccc6ccc5c5cccc-4c35)nc(-c3ccc4ccccc4c3)n2)cc1]

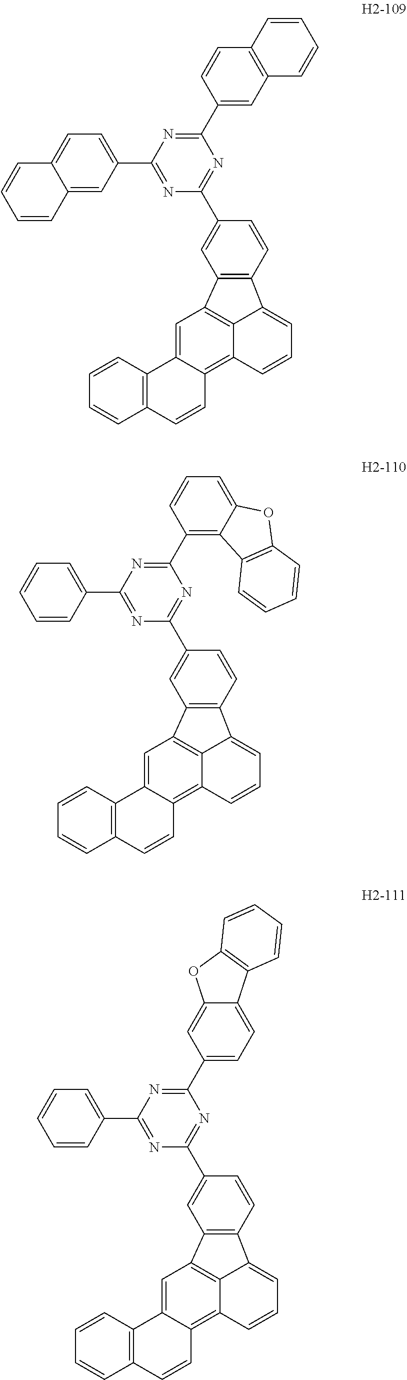 [SMILES: c1ccc2cc(-c3nc(-c4ccc5c(c4)-c4cc6c7ccccc7ccc6c6cccc-5c46)nc(-c4ccc5ccccc5c4)n3)ccc2c1 ; c1ccc(-c2nc(-c3ccc4c(c3)-c3cc5c6ccccc6ccc5c5cccc-4c35)nc(-c3cccc4oc5ccccc5c34)n2)cc1 ; c1ccc(-c2nc(-c3ccc4c(c3)-c3cc5c6ccccc6ccc5c5cccc-4c35)nc(-c3ccc4c(c3)oc3ccccc34)n2)cc1]

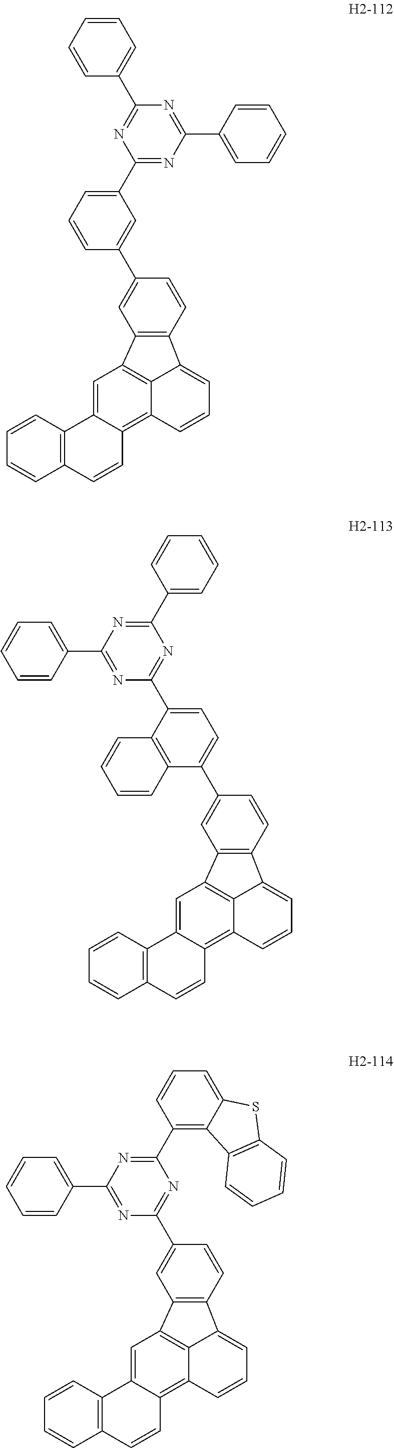 [SMILES: c1ccc(-c2nc(-c3ccccc3)nc(-c3cccc(-c4ccc5c(c4)-c4cc6c7ccccc7ccc6c6cccc-5c46)c3)n2)cc1 ; c1ccc(-c2nc(-c3ccccc3)nc(-c3ccc(-c4ccc5c(c4)-c4cc6c7ccccc7ccc6c6cccc-5c46)c4ccccc34)n2)cc1 ; c1ccc(-c2nc(-c3ccc4c(c3)-c3cc5c6ccccc6ccc5c5cccc-4c35)nc(-c3cccc4sc5ccccc5c34)n2)cc1]

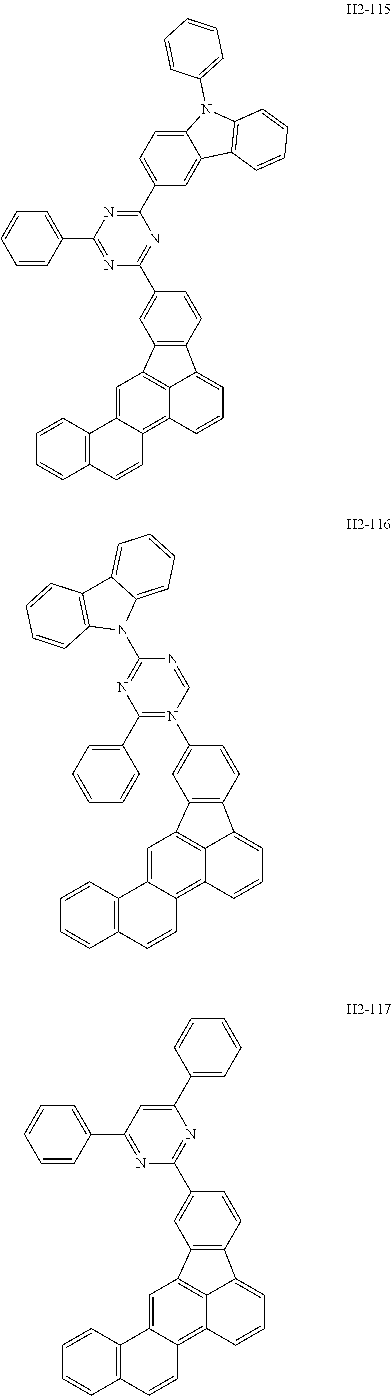

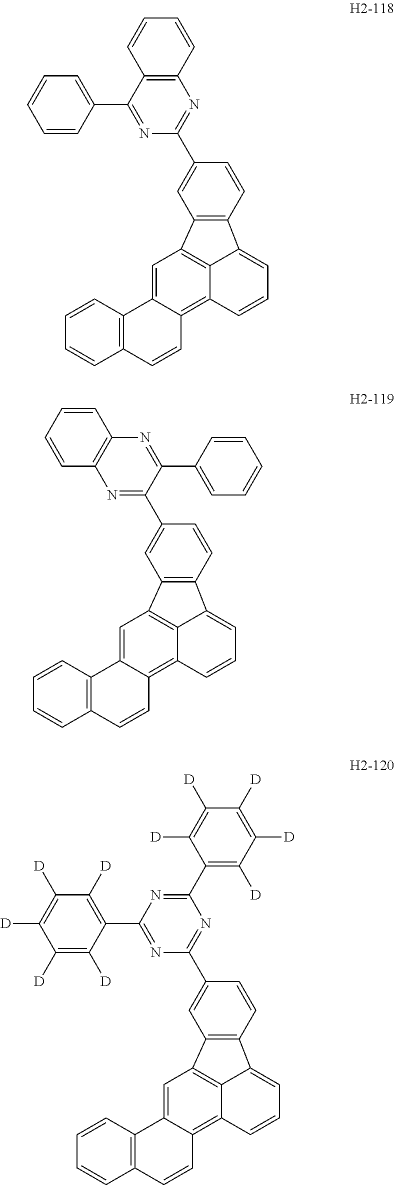

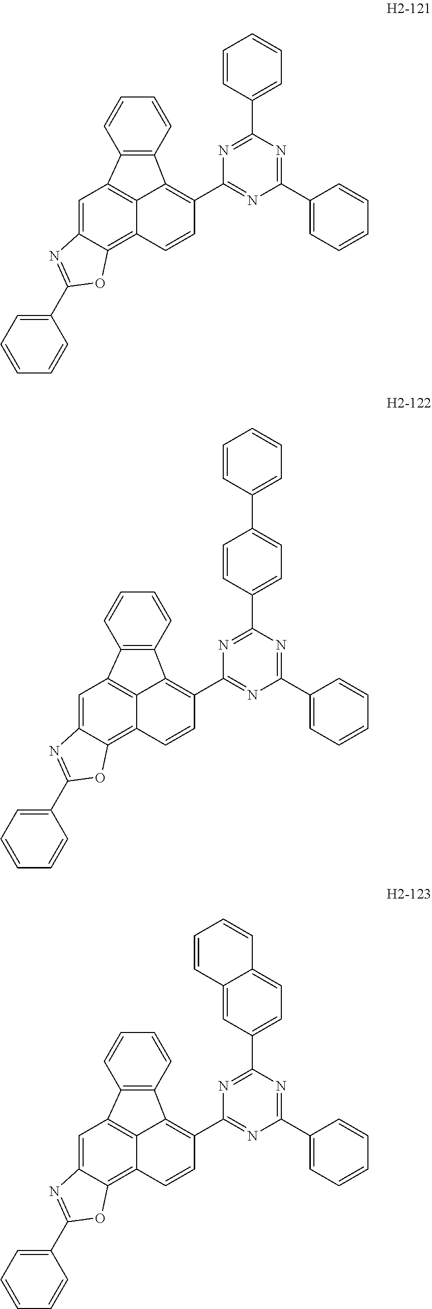 [SMILES: c1ccc(-c2nc(-c3ccccc3)nc(-c3ccc4c5c(cc6nc(-c7ccccc7)oc64)-c4ccccc4-c35)n2)cc1 ; c1ccc(-c2ccc(-c3nc(-c4ccccc4)nc(-c4ccc5c6c(cc7nc(-c8ccccc8)oc75)-c5ccccc5-c46)n3)cc2)cc1 ; c1ccc(-c2nc(-c3ccc4ccccc4c3)nc(-c3ccc4c5c(cc6nc(-c7ccccc7)oc64)-c4ccccc4-c35)n2)cc1]

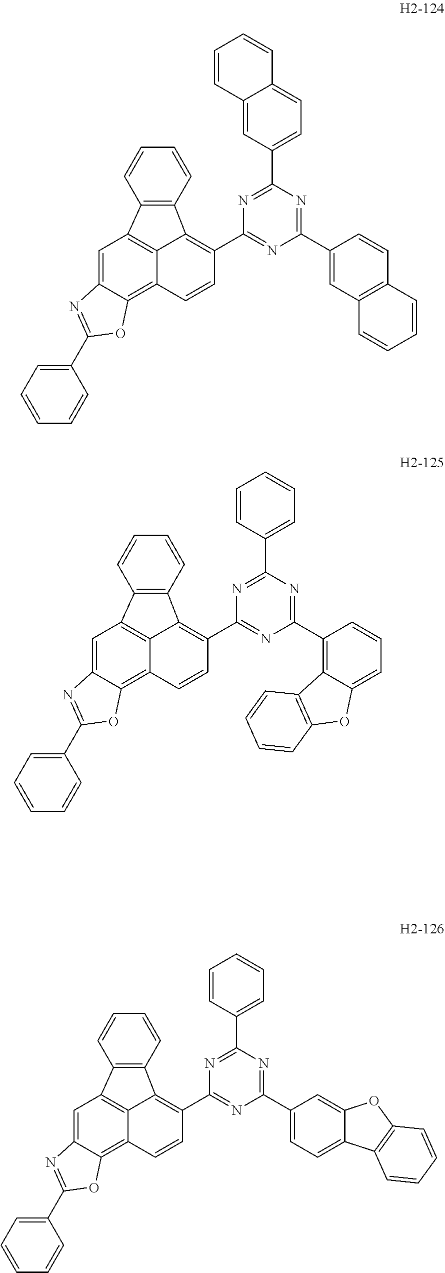 [SMILES: c1ccc(-c2nc3cc4c5c(c(-c6nc(-c7ccc8ccccc8c7)nc(-c7ccc8ccccc8c7)n6)ccc5c3o2)-c2ccccc2-4)cc1 ; c1ccc(-c2nc(-c3ccc4c5c(cc6nc(-c7ccccc7)oc64)-c4ccccc4-c35)nc(-c3cccc4oc5ccccc5c34)n2)cc1 ; c1ccc(-c2nc(-c3ccc4c(c3)oc3ccccc34)nc(-c3ccc4c5c(cc6nc(-c7ccccc7)oc64)-c4ccccc4-c35)n2)cc1]

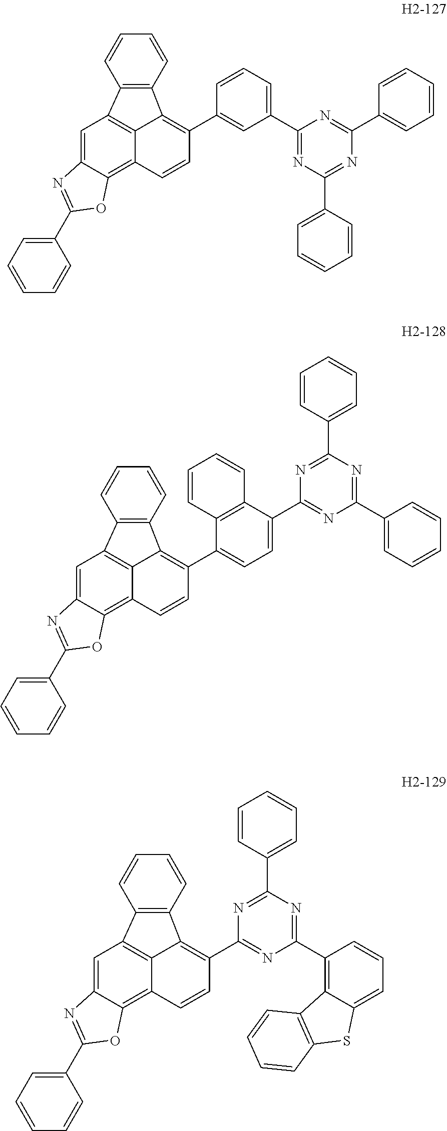 [SMILES: c1ccc(-c2nc(-c3ccccc3)nc(-c3cccc(-c4ccc5c6c(cc7nc(-c8ccccc8)oc75)-c5ccccc5-c46)c3)n2)cc1 ; c1ccc(-c2nc(-c3ccccc3)nc(-c3ccc(-c4ccc5c6c(cc7nc(-c8ccccc8)oc75)-c5ccccc5-c46)c4ccccc34)n2)cc1 ; c1ccc(-c2nc(-c3ccc4c5c(cc6nc(-c7ccccc7)oc64)-c4ccccc4-c35)nc(-c3cccc4sc5ccccc5c34)n2)cc1]

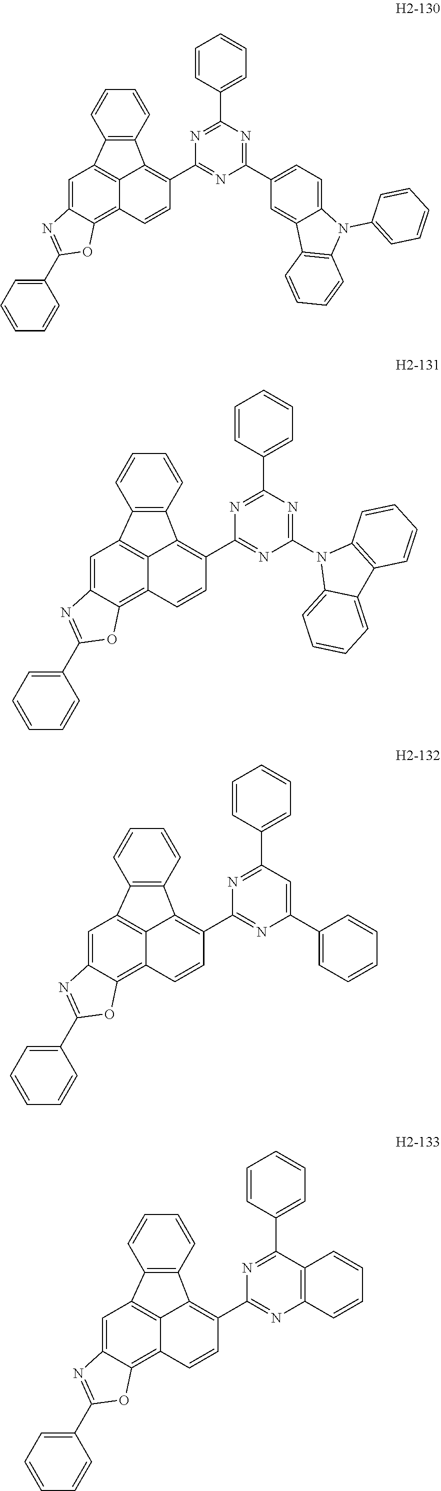 [SMILES: c1ccc(-c2nc(-c3ccc4c(c3)c3ccccc3n4-c3ccccc3)nc(-c3ccc4c5c(cc6nc(-c7ccccc7)oc64)-c4ccccc4-c35)n2)cc1 ; c1ccc(-c2nc(-c3ccc4c5c(cc6nc(-c7ccccc7)oc64)-c4ccccc4-c35)nc(-n3c4ccccc4c4ccccc43)n2)cc1 ; c1ccc(-c2cc(-c3ccccc3)nc(-c3ccc4c5c(cc6nc(-c7ccccc7)oc64)-c4ccccc4-c35)n2)cc1 ; c1ccc(-c2nc3cc4c5c(c(-c6nc(-c7ccccc7)c7ccccc7n6)ccc5c3o2)-c2ccccc2-4)cc1]

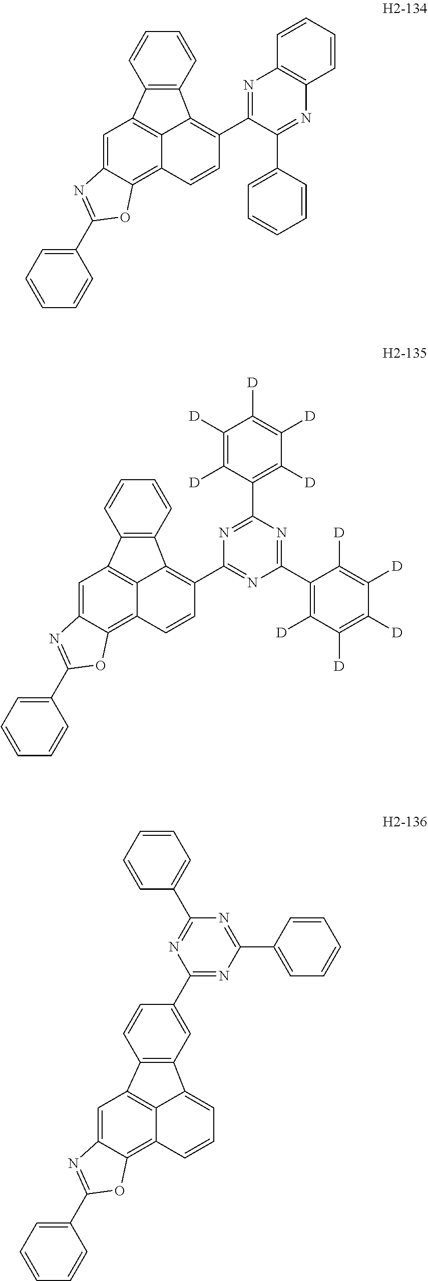 [SMILES: c1ccc(-c2nc3cc4c5c(c(-c6nc7ccccc7nc6-c6ccccc6)ccc5c3o2)-c2ccccc2-4)cc1 ; [2H]c1c([2H])c([2H])c(-c2nc(-c3ccc4c5c(cc6nc(-c7ccccc7)oc64)-c4ccccc4-c35)nc(-c3c([2H])c([2H])c([2H])c([2H])c3[2H])n2)c([2H])c1[2H] ; c1ccc(-c2nc(-c3ccccc3)nc(-c3ccc4c(c3)-c3cccc5c3c-4cc3nc(-c4ccccc4)oc35)n2)cc1]

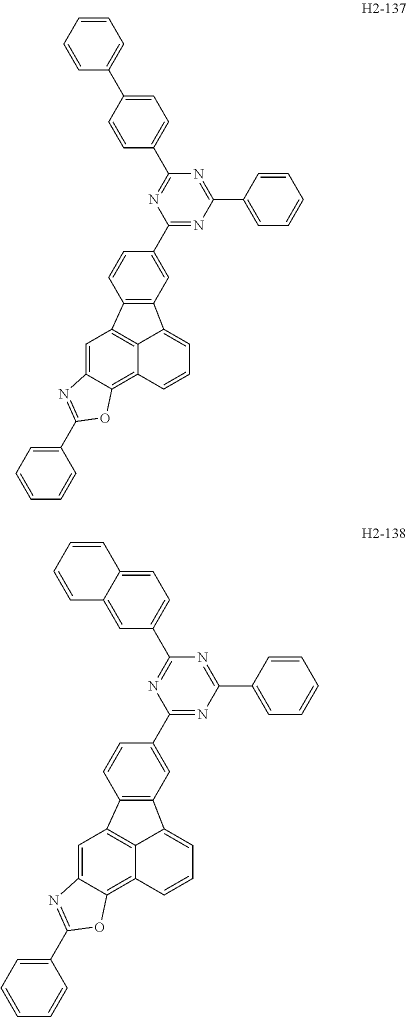 [SMILES: c1ccc(-c2ccc(-c3nc(-c4ccccc4)nc(-c4ccc5c(c4)-c4cccc6c4c-5cc4nc(-c5ccccc5)oc46)n3)cc2)cc1 ; c1ccc(-c2nc(-c3ccc4c(c3)-c3cccc5c3c-4cc3nc(-c4ccccc4)oc35)nc(-c3ccc4ccccc4c3)n2)cc1]

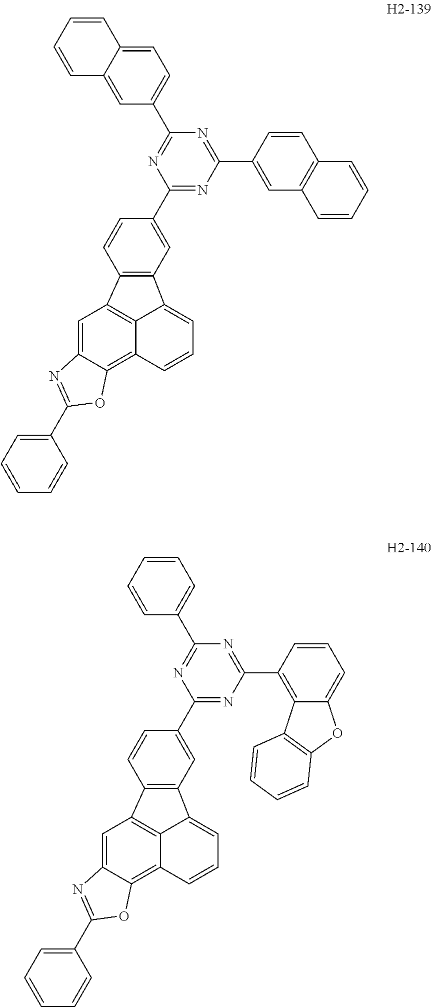 [SMILES: c1ccc(-c2nc3cc4c5c(cccc5c3o2)-c2cc(-c3nc(-c5ccc6ccccc6c5)nc(-c5ccc6ccccc6c5)n3)ccc2-4)cc1 ; c1ccc(-c2nc(-c3ccc4c(c3)-c3cccc5c3c-4cc3nc(-c4ccccc4)oc35)nc(-c3cccc4oc5ccccc5c34)n2)cc1]

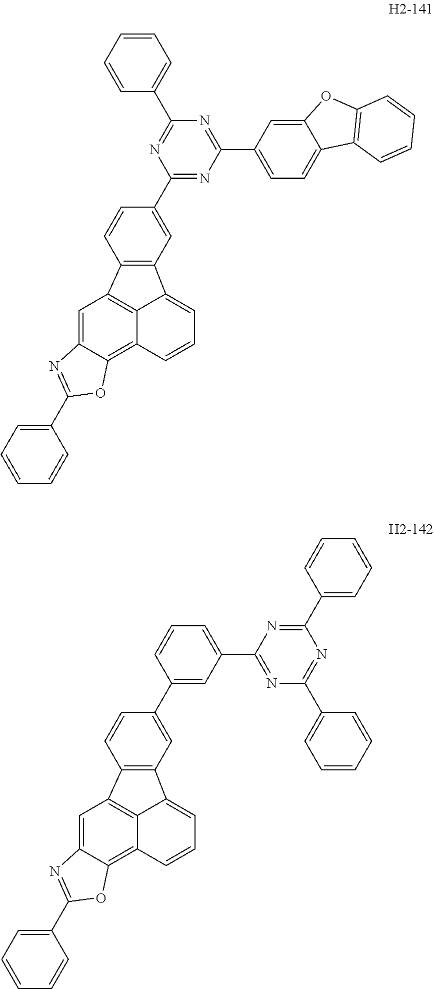 [SMILES: c1ccc(-c2nc(-c3ccc4c(c3)-c3cccc5c3c-4cc3nc(-c4ccccc4)oc35)nc(-c3ccc4c(c3)oc3ccccc34)n2)cc1 ; c1ccc(-c2nc(-c3ccccc3)nc(-c3cccc(-c4ccc5c(c4)-c4cccc6c4c-5cc4nc(-c5ccccc5)oc46)c3)n2)cc1]

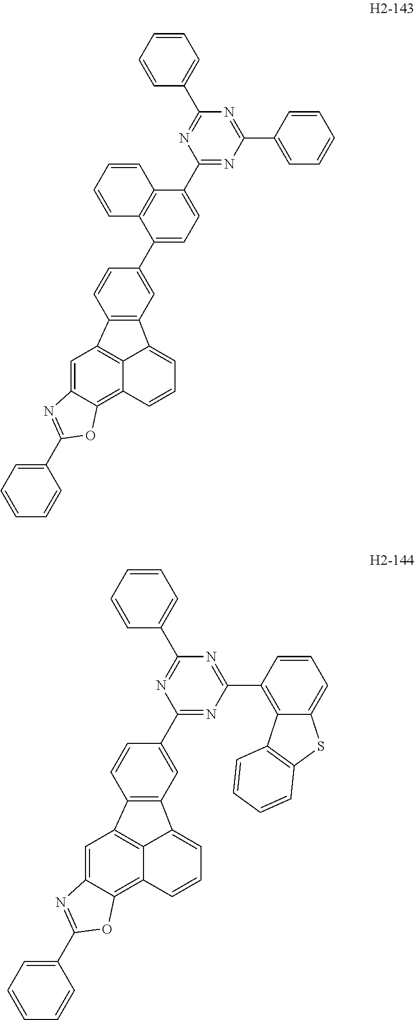 [SMILES: c1ccc(-c2nc(-c3ccccc3)nc(-c3ccc(-c4ccc5c(c4)-c4cccc6c4c-5cc4nc(-c5ccccc5)oc46)c4ccccc34)n2)cc1 ; c1ccc(-c2nc(-c3ccc4c(c3)-c3cccc5c3c-4cc3nc(-c4ccccc4)oc35)nc(-c3cccc4sc5ccccc5c34)n2)cc1]

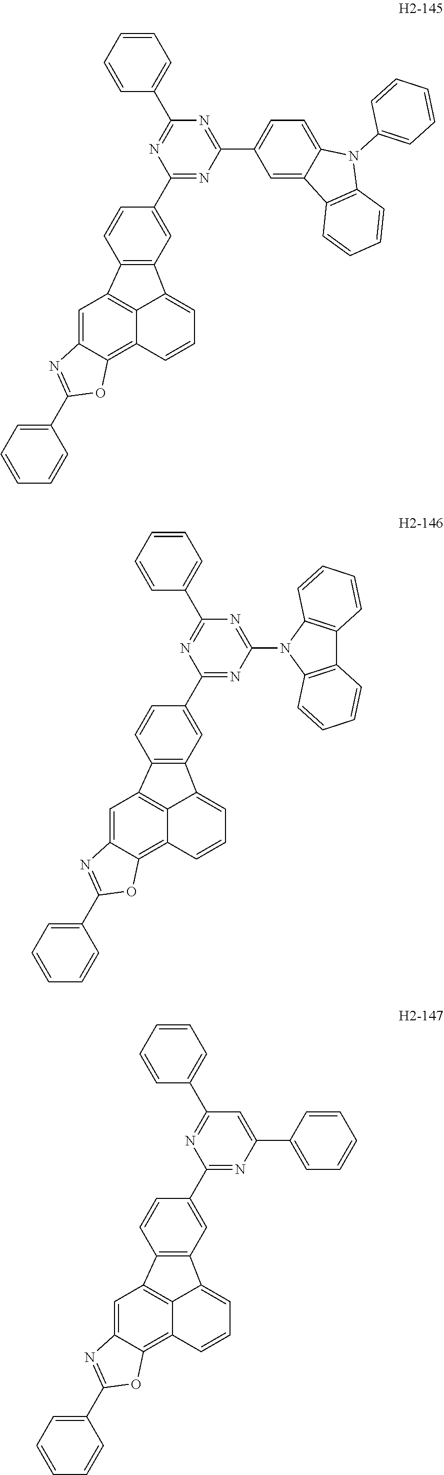 [SMILES: c1ccc(-c2nc(-c3ccc4c(c3)-c3cccc5c3c-4cc3nc(-c4ccccc4)oc35)nc(-c3ccc4c(c3)c3ccccc3n4-c3ccccc3)n2)cc1 ; c1ccc(-c2nc(-c3ccc4c(c3)-c3cccc5c3c-4cc3nc(-c4ccccc4)oc35)nc(-n3c4ccccc4c4ccccc43)n2)cc1 ; c1ccc(-c2cc(-c3ccccc3)nc(-c3ccc4c(c3)-c3cccc5c3c-4cc3nc(-c4ccccc4)oc35)n2)cc1]

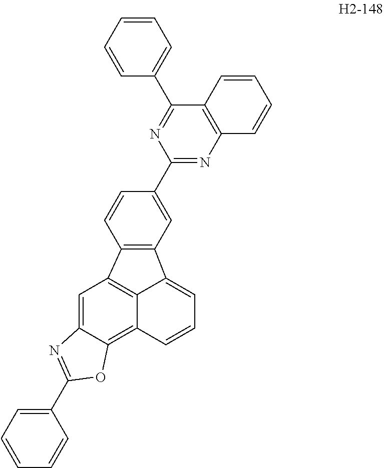 [SMILES: c1ccc(-c2nc3cc4c5c(cccc5c3o2)-c2cc(-c3nc(-c5ccccc5)c5ccccc5n3)ccc2-4)cc1]

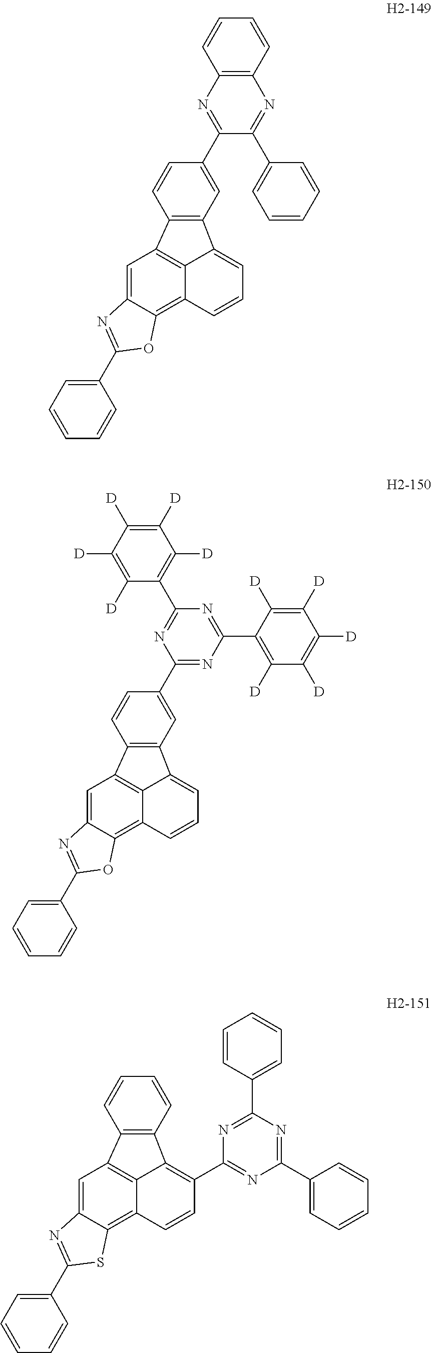 [SMILES: c1ccc(-c2nc3cc4c5c(cccc5c3o2)-c2cc(-c3nc5ccccc5nc3-c3ccccc3)ccc2-4)cc1 ; [2H]c1c([2H])c([2H])c(-c2nc(-c3ccc4c(c3)-c3cccc5c3c-4cc3nc(-c4ccccc4)oc35)nc(-c3c([2H])c([2H])c([2H])c([2H])c3[2H])n2)c([2H])c1[2H] ; c1ccc(-c2nc(-c3ccccc3)nc(-c3ccc4c5c(cc6nc(-c7ccccc7)sc64)-c4ccccc4-c35)n2)cc1]

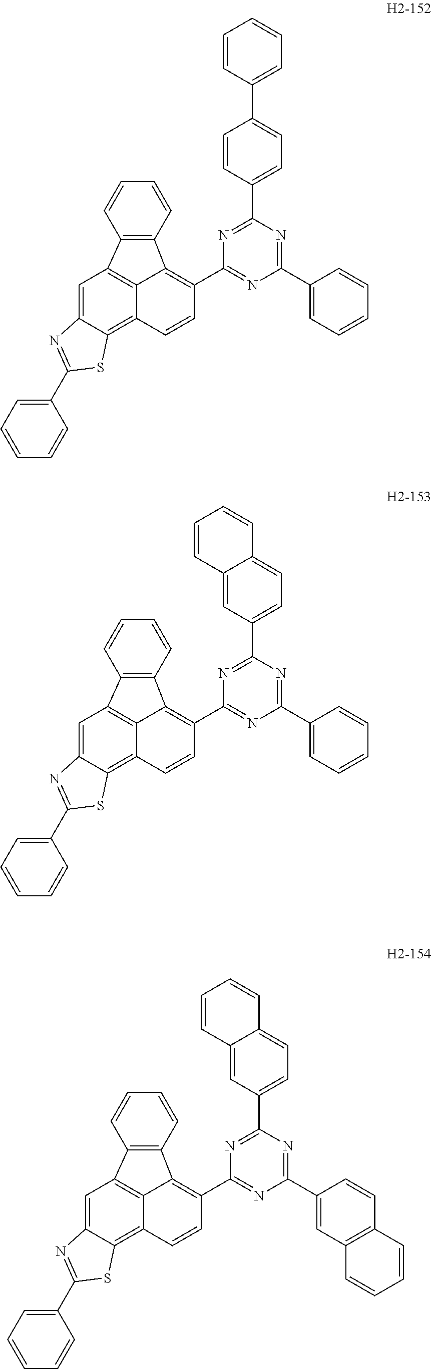 [SMILES: c1ccc(-c2ccc(-c3nc(-c4ccccc4)nc(-c4ccc5c6c(cc7nc(-c8ccccc8)sc75)-c5ccccc5-c46)n3)cc2)cc1 ; c1ccc(-c2nc(-c3ccc4ccccc4c3)nc(-c3ccc4c5c(cc6nc(-c7ccccc7)sc64)-c4ccccc4-c35)n2)cc1 ; c1ccc(-c2nc3cc4c5c(c(-c6nc(-c7ccc8ccccc8c7)nc(-c7ccc8ccccc8c7)n6)ccc5c3s2)-c2ccccc2-4)cc1]

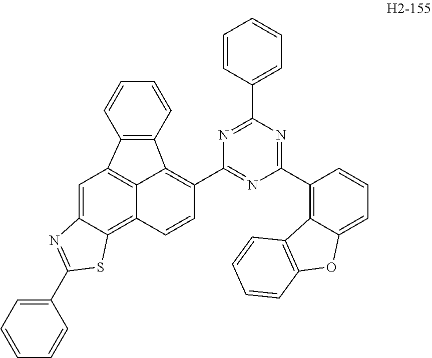 [SMILES: c1ccc(-c2nc(-c3ccc4c5c(cc6nc(-c7ccccc7)sc64)-c4ccccc4-c35)nc(-c3cccc4oc5ccccc5c34)n2)cc1]

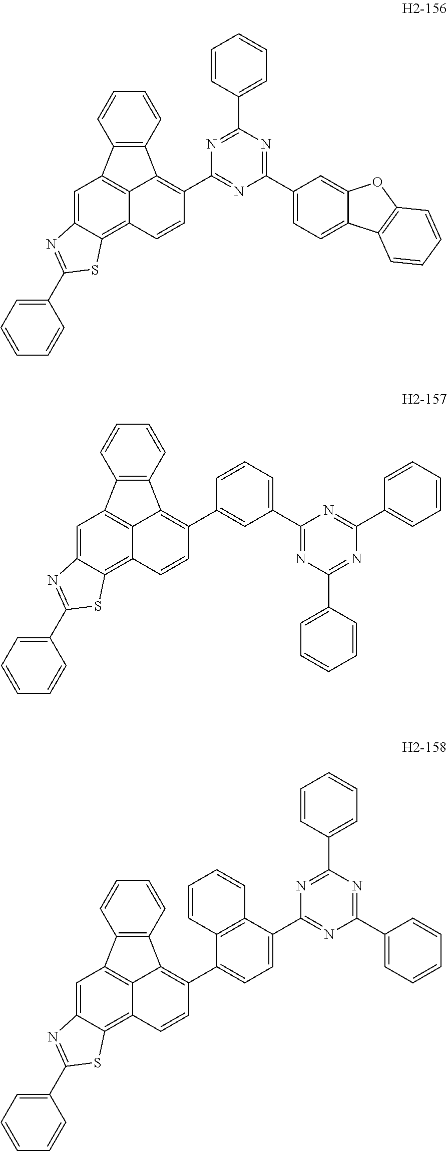 [SMILES: c1ccc(-c2nc(-c3ccc4c(c3)oc3ccccc34)nc(-c3ccc4c5c(cc6nc(-c7ccccc7)sc64)-c4ccccc4-c35)n2)cc1 ; c1ccc(-c2nc(-c3ccccc3)nc(-c3cccc(-c4ccc5c6c(cc7nc(-c8ccccc8)sc75)-c5ccccc5-c46)c3)n2)cc1 ; c1ccc(-c2nc(-c3ccccc3)nc(-c3ccc(-c4ccc5c6c(cc7nc(-c8ccccc8)sc75)-c5ccccc5-c46)c4ccccc34)n2)cc1]

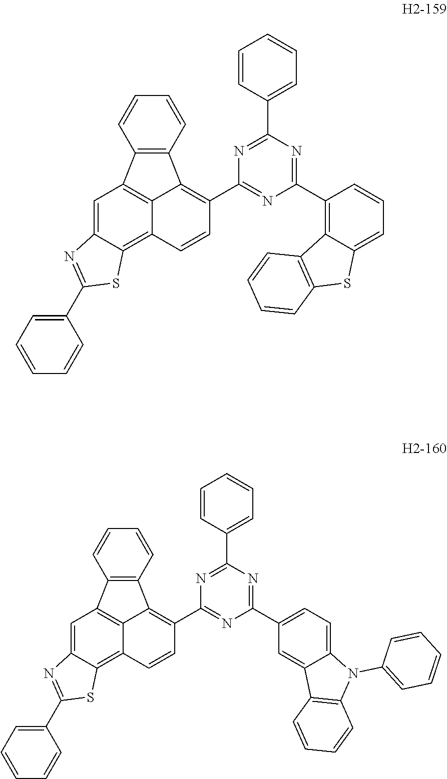

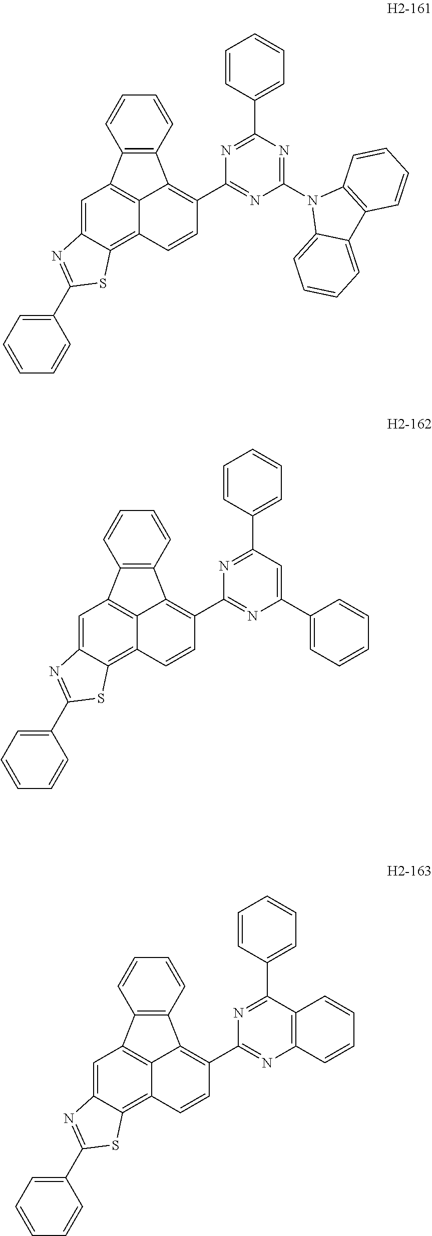 [SMILES: c1ccc(-c2nc(-c3ccc4c5c(cc6nc(-c7ccccc7)sc64)-c4ccccc4-c35)nc(-n3c4ccccc4c4ccccc43)n2)cc1 ; c1ccc(-c2cc(-c3ccccc3)nc(-c3ccc4c5c(cc6nc(-c7ccccc7)sc64)-c4ccccc4-c35)n2)cc1 ; c1ccc(-c2nc3cc4c5c(c(-c6nc(-c7ccccc7)c7ccccc7n6)ccc5c3s2)-c2ccccc2-4)cc1]

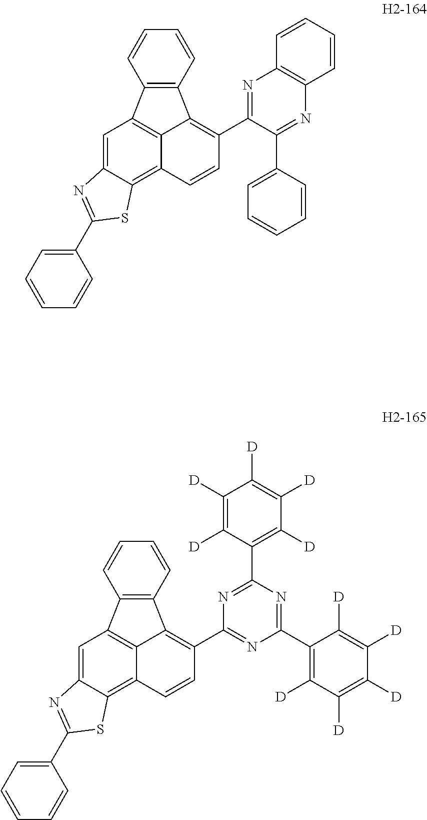 [SMILES: c1ccc(-c2nc3cc4c5c(c(-c6nc7ccccc7nc6-c6ccccc6)ccc5c3s2)-c2ccccc2-4)cc1 ; [2H]c1c([2H])c([2H])c(-c2nc(-c3ccc4c5c(cc6nc(-c7ccccc7)sc64)-c4ccccc4-c35)nc(-c3c([2H])c([2H])c([2H])c([2H])c3[2H])n2)c([2H])c1[2H]]

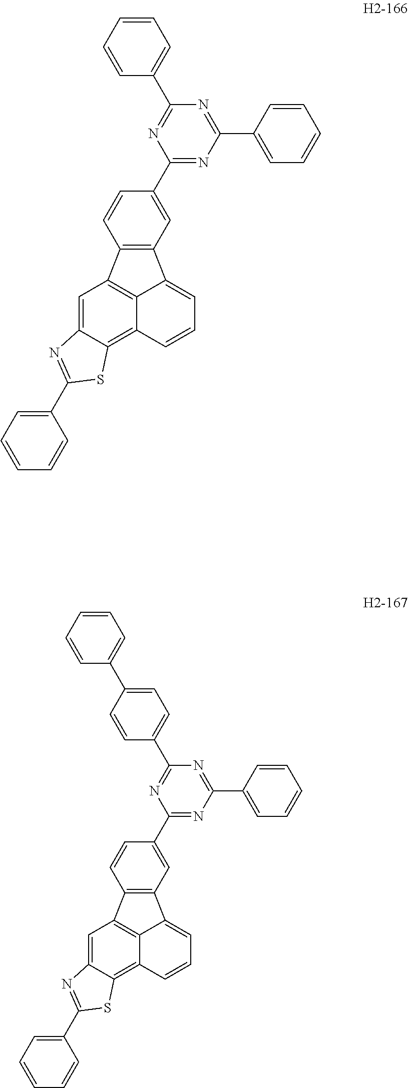 [SMILES: c1ccc(-c2nc(-c3ccccc3)nc(-c3ccc4c(c3)-c3cccc5c3c-4cc3nc(-c4ccccc4)sc35)n2)cc1 ; c1ccc(-c2ccc(-c3nc(-c4ccccc4)nc(-c4ccc5c(c4)-c4cccc6c4c-5cc4nc(-c5ccccc5)sc46)n3)cc2)cc1]

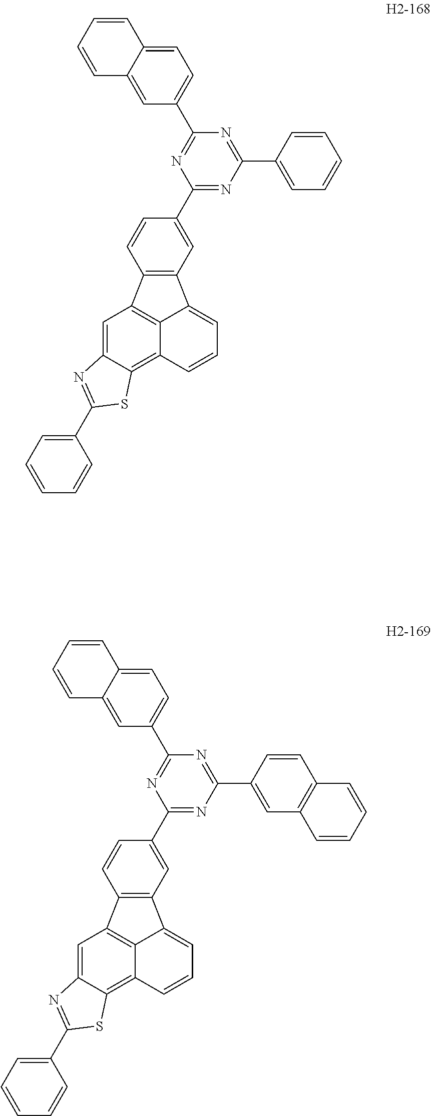 [SMILES: c1ccc(-c2nc(-c3ccc4c(c3)-c3cccc5c3c-4cc3nc(-c4ccccc4)sc35)nc(-c3ccc4ccccc4c3)n2)cc1 ; c1ccc(-c2nc3cc4c5c(cccc5c3s2)-c2cc(-c3nc(-c5ccc6ccccc6c5)nc(-c5ccc6ccccc6c5)n3)ccc2-4)cc1]

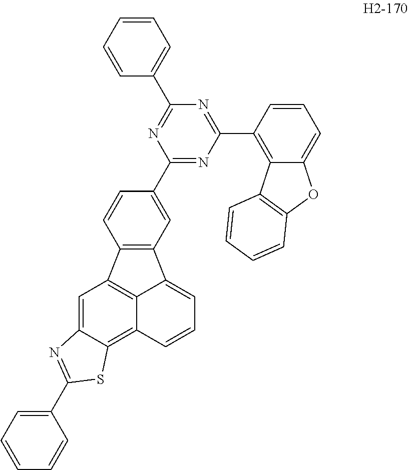 [SMILES: c1ccc(-c2nc(-c3ccc4c(c3)-c3cccc5c3c-4cc3nc(-c4ccccc4)sc35)nc(-c3cccc4oc5ccccc5c34)n2)cc1]

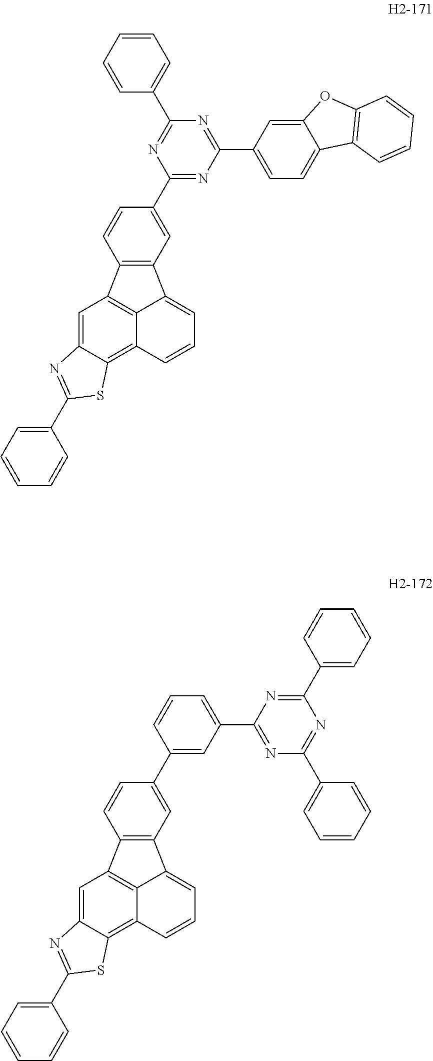 [SMILES: c1ccc(-c2nc(-c3ccc4c(c3)-c3cccc5c3c-4cc3nc(-c4ccccc4)sc35)nc(-c3ccc4c(c3)oc3ccccc34)n2)cc1 ; c1ccc(-c2nc(-c3ccccc3)nc(-c3cccc(-c4ccc5c(c4)-c4cccc6c4c-5cc4nc(-c5ccccc5)sc46)c3)n2)cc1]

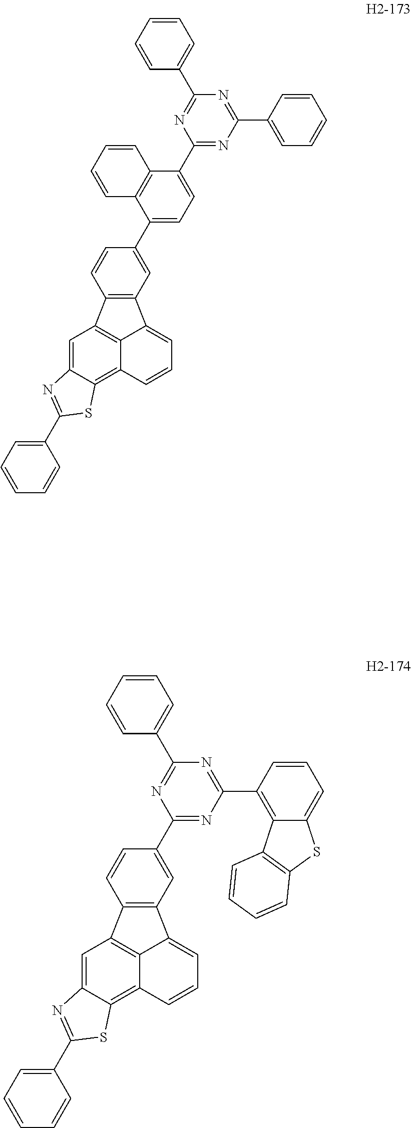 [SMILES: c1ccc(-c2nc(-c3ccccc3)nc(-c3ccc(-c4ccc5c(c4)-c4cccc6c4c-5cc4nc(-c5ccccc5)sc46)c4ccccc34)n2)cc1 ; c1ccc(-c2nc(-c3ccc4c(c3)-c3cccc5c3c-4cc3nc(-c4ccccc4)sc35)nc(-c3cccc4sc5ccccc5c34)n2)cc1]

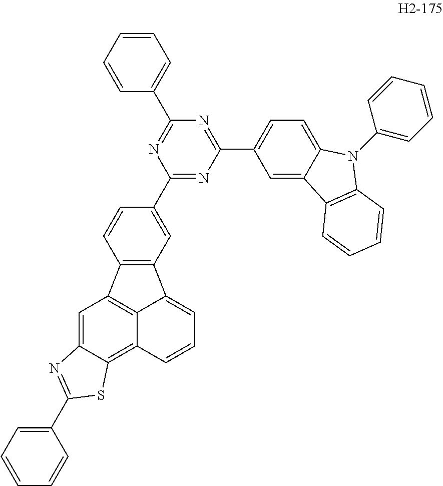 [SMILES: c1ccc(-c2nc(-c3ccc4c(c3)-c3cccc5c3c-4cc3nc(-c4ccccc4)sc35)nc(-c3ccc4c(c3)c3ccccc3n4-c3ccccc3)n2)cc1]

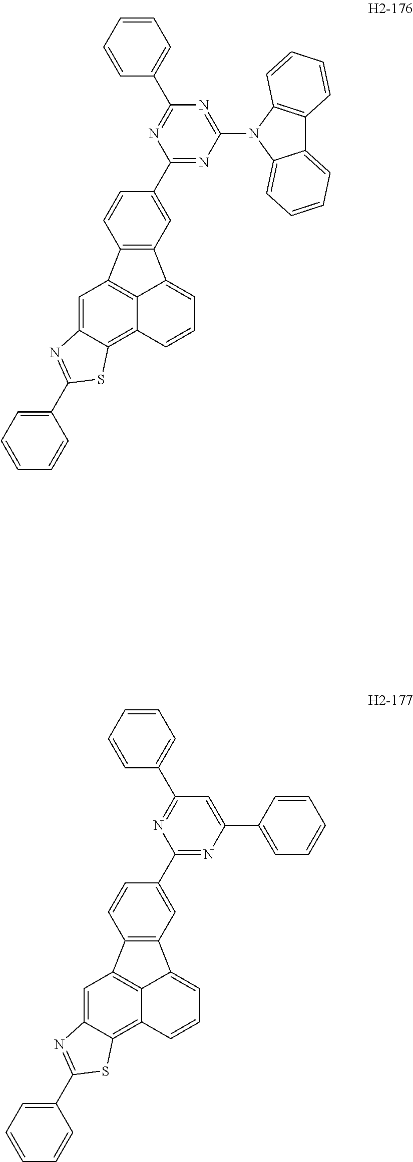 [SMILES: c1ccc(-c2nc(-c3ccc4c(c3)-c3cccc5c3c-4cc3nc(-c4ccccc4)sc35)nc(-n3c4ccccc4c4ccccc43)n2)cc1 ; c1ccc(-c2cc(-c3ccccc3)nc(-c3ccc4c(c3)-c3cccc5c3c-4cc3nc(-c4ccccc4)sc35)n2)cc1]

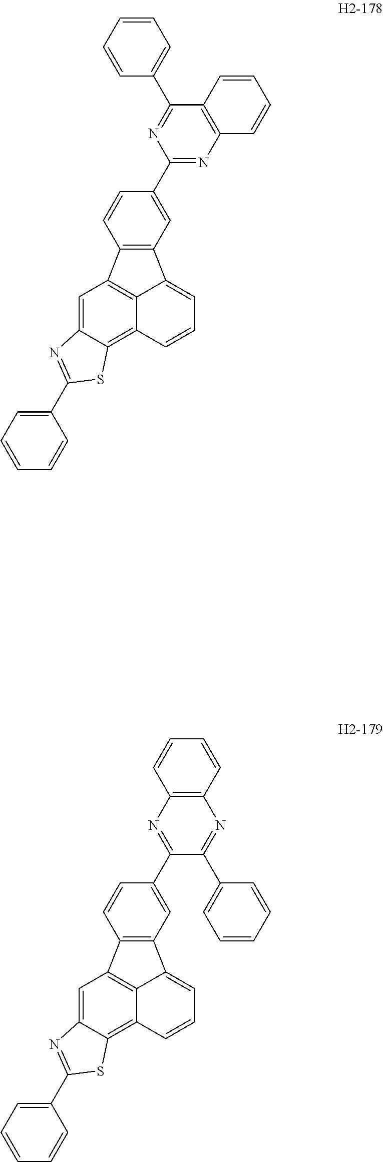 [SMILES: c1ccc(-c2nc3cc4c5c(cccc5c3s2)-c2cc(-c3nc(-c5ccccc5)c5ccccc5n3)ccc2-4)cc1 ; c1ccc(-c2nc3cc4c5c(cccc5c3s2)-c2cc(-c3nc5ccccc5nc3-c3ccccc3)ccc2-4)cc1]

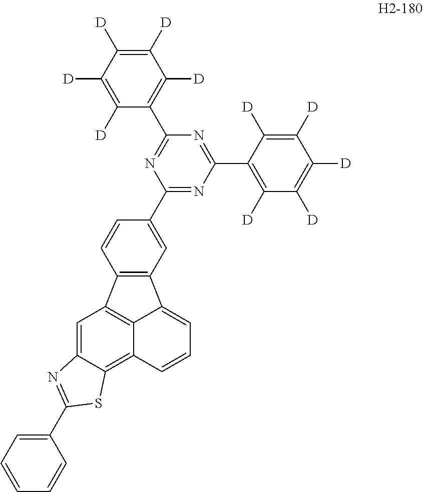 [SMILES: [2H]c1c([2H])c([2H])c(-c2nc(-c3ccc4c(c3)-c3cccc5c3c-4cc3nc(-c4ccccc4)sc35)nc(-c3c([2H])c([2H])c([2H])c([2H])c3[2H])n2)c([2H])c1[2H]]

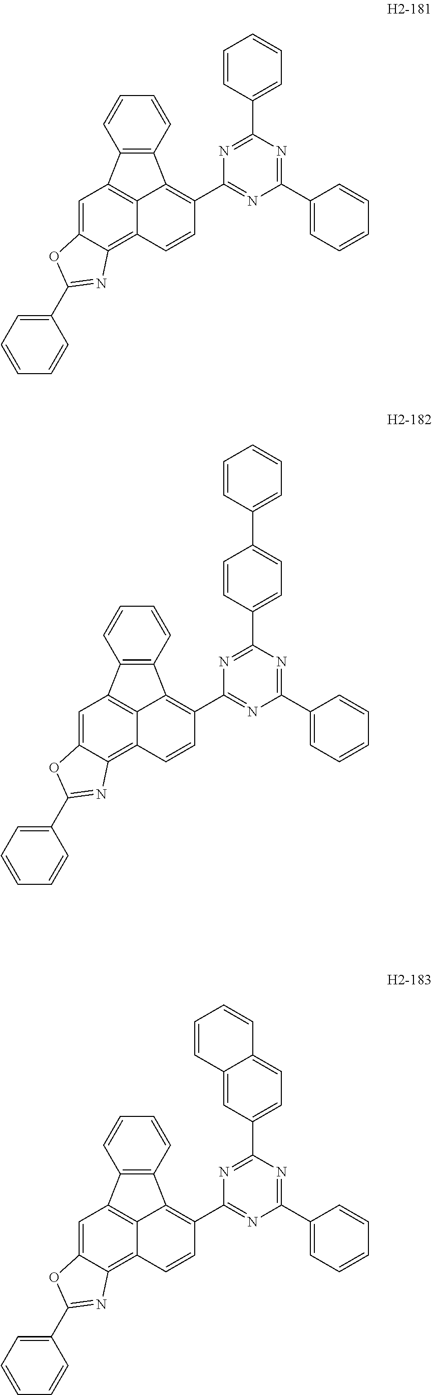 [SMILES: c1ccc(-c2nc(-c3ccccc3)nc(-c3ccc4c5c(cc6oc(-c7ccccc7)nc64)-c4ccccc4-c35)n2)cc1 ; c1ccc(-c2ccc(-c3nc(-c4ccccc4)nc(-c4ccc5c6c(cc7oc(-c8ccccc8)nc75)-c5ccccc5-c46)n3)cc2)cc1 ; c1ccc(-c2nc(-c3ccc4ccccc4c3)nc(-c3ccc4c5c(cc6oc(-c7ccccc7)nc64)-c4ccccc4-c35)n2)cc1]

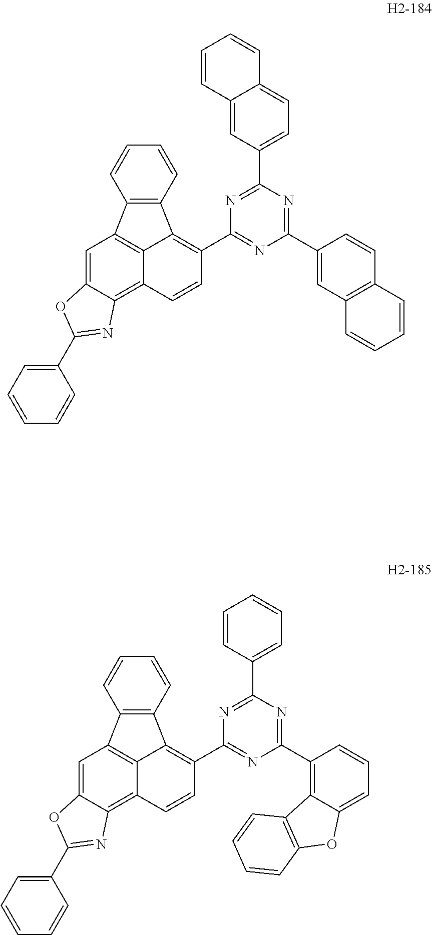 [SMILES: c1ccc(-c2nc3c(cc4c5c(c(-c6nc(-c7ccc8ccccc8c7)nc(-c7ccc8ccccc8c7)n6)ccc53)-c3ccccc3-4)o2)cc1 ; c1ccc(-c2nc(-c3ccc4c5c(cc6oc(-c7ccccc7)nc64)-c4ccccc4-c35)nc(-c3cccc4oc5ccccc5c34)n2)cc1]

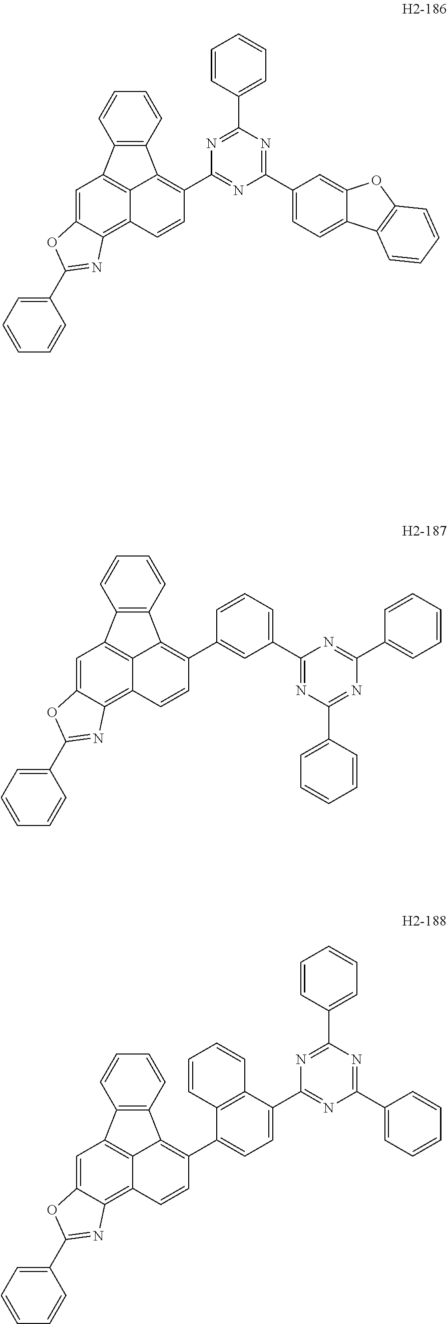 [SMILES: c1ccc(-c2nc(-c3ccc4c(c3)oc3ccccc34)nc(-c3ccc4c5c(cc6oc(-c7ccccc7)nc64)-c4ccccc4-c35)n2)cc1 ; c1ccc(-c2nc(-c3ccccc3)nc(-c3cccc(-c4ccc5c6c(cc7oc(-c8ccccc8)nc75)-c5ccccc5-c46)c3)n2)cc1 ; c1ccc(-c2nc(-c3ccccc3)nc(-c3ccc(-c4ccc5c6c(cc7oc(-c8ccccc8)nc75)-c5ccccc5-c46)c4ccccc34)n2)cc1]

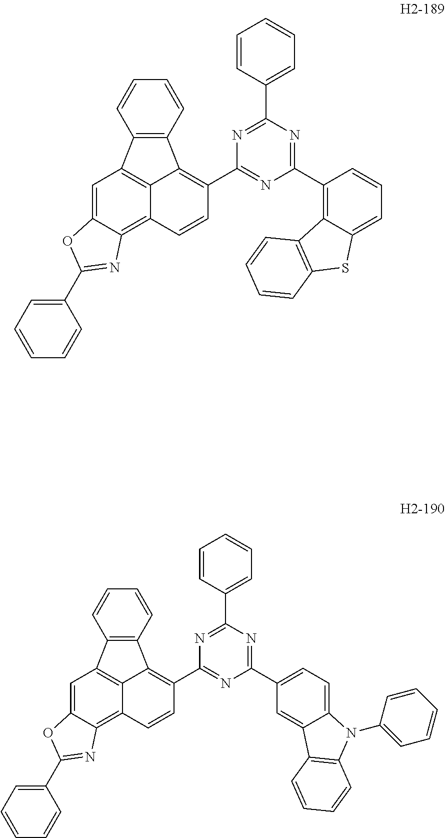 [SMILES: c1ccc(-c2nc(-c3ccc4c5c(cc6oc(-c7ccccc7)nc64)-c4ccccc4-c35)nc(-c3cccc4sc5ccccc5c34)n2)cc1 ; c1ccc(-c2nc(-c3ccc4c(c3)c3ccccc3n4-c3ccccc3)nc(-c3ccc4c5c(cc6oc(-c7ccccc7)nc64)-c4ccccc4-c35)n2)cc1]

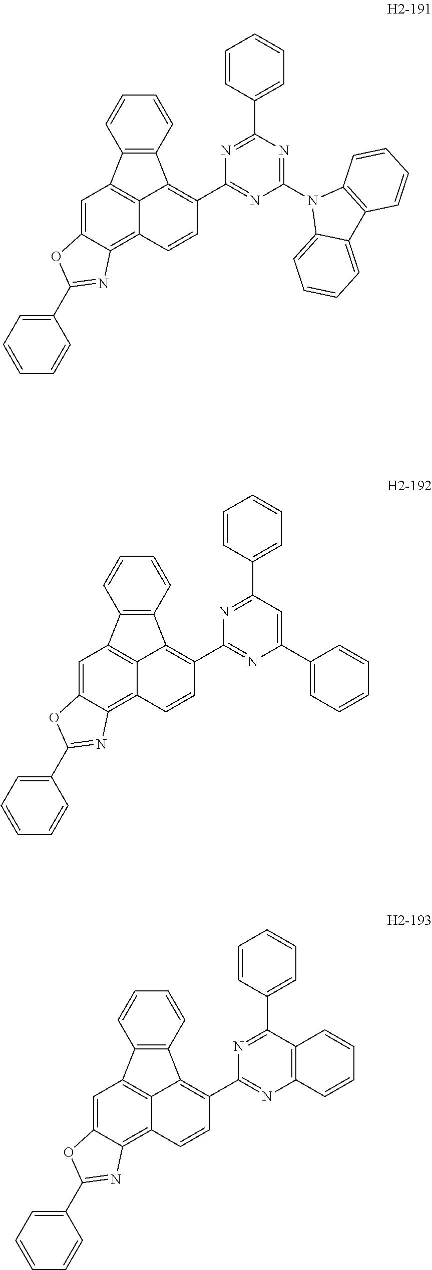 [SMILES: c1ccc(-c2nc(-c3ccc4c5c(cc6oc(-c7ccccc7)nc64)-c4ccccc4-c35)nc(-n3c4ccccc4c4ccccc43)n2)cc1 ; c1ccc(-c2cc(-c3ccccc3)nc(-c3ccc4c5c(cc6oc(-c7ccccc7)nc64)-c4ccccc4-c35)n2)cc1 ; c1ccc(-c2nc3c(cc4c5c(c(-c6nc(-c7ccccc7)c7ccccc7n6)ccc53)-c3ccccc3-4)o2)cc1]

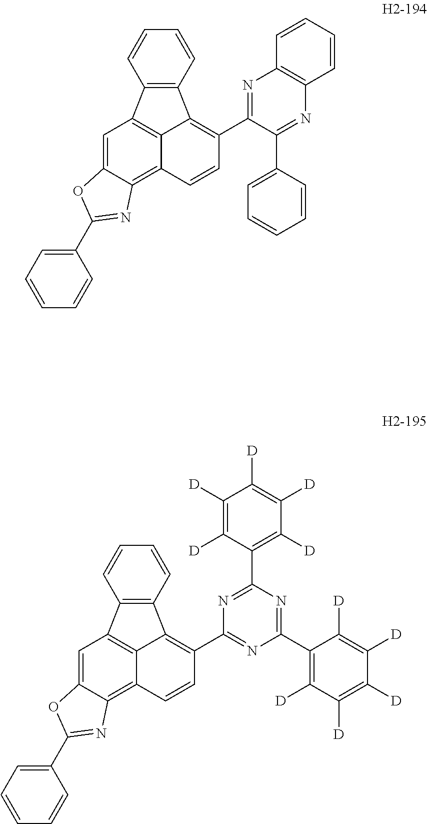 [SMILES: c1ccc(-c2nc3c(cc4c5c(c(-c6nc7ccccc7nc6-c6ccccc6)ccc53)-c3ccccc3-4)o2)cc1 ; [2H]c1c([2H])c([2H])c(-c2nc(-c3ccc4c5c(cc6oc(-c7ccccc7)nc64)-c4ccccc4-c35)nc(-c3c([2H])c([2H])c([2H])c([2H])c3[2H])n2)c([2H])c1[2H]]

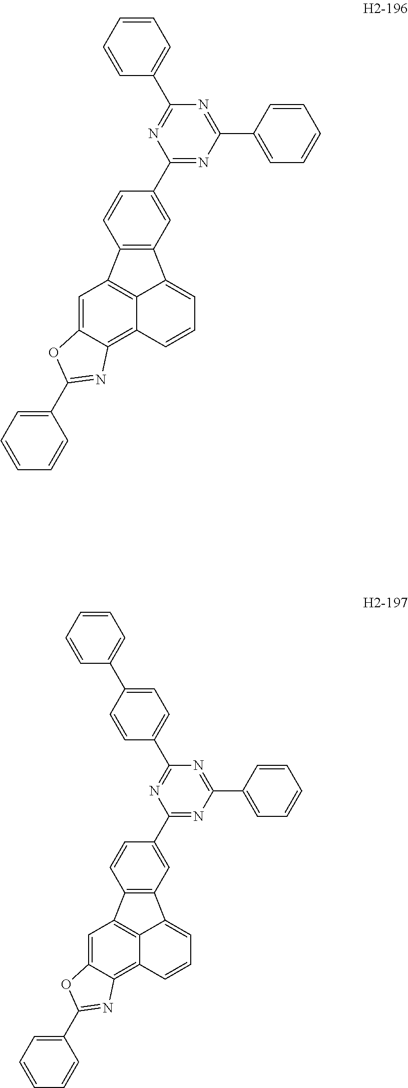 [SMILES: c1ccc(-c2nc(-c3ccccc3)nc(-c3ccc4c(c3)-c3cccc5c3c-4cc3oc(-c4ccccc4)nc35)n2)cc1 ; c1ccc(-c2ccc(-c3nc(-c4ccccc4)nc(-c4ccc5c(c4)-c4cccc6c4c-5cc4oc(-c5ccccc5)nc46)n3)cc2)cc1]

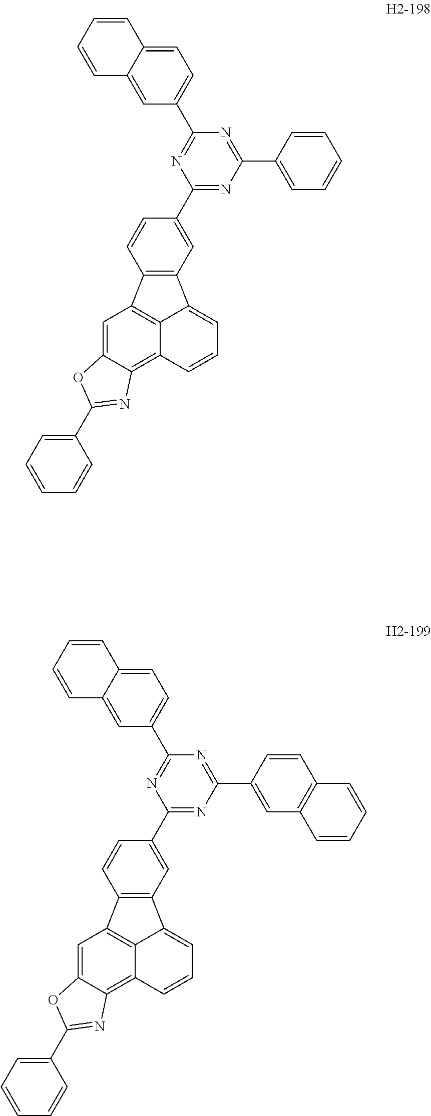 [SMILES: c1ccc(-c2nc(-c3ccc4c(c3)-c3cccc5c3c-4cc3oc(-c4ccccc4)nc35)nc(-c3ccc4ccccc4c3)n2)cc1 ; c1ccc(-c2nc3c(cc4c5c(cccc53)-c3cc(-c5nc(-c6ccc7ccccc7c6)nc(-c6ccc7ccccc7c6)n5)ccc3-4)o2)cc1]

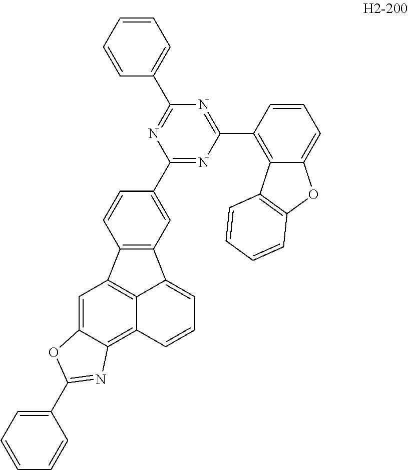 [SMILES: c1ccc(-c2nc(-c3ccc4c(c3)-c3cccc5c3c-4cc3oc(-c4ccccc4)nc35)nc(-c3cccc4oc5ccccc5c34)n2)cc1]

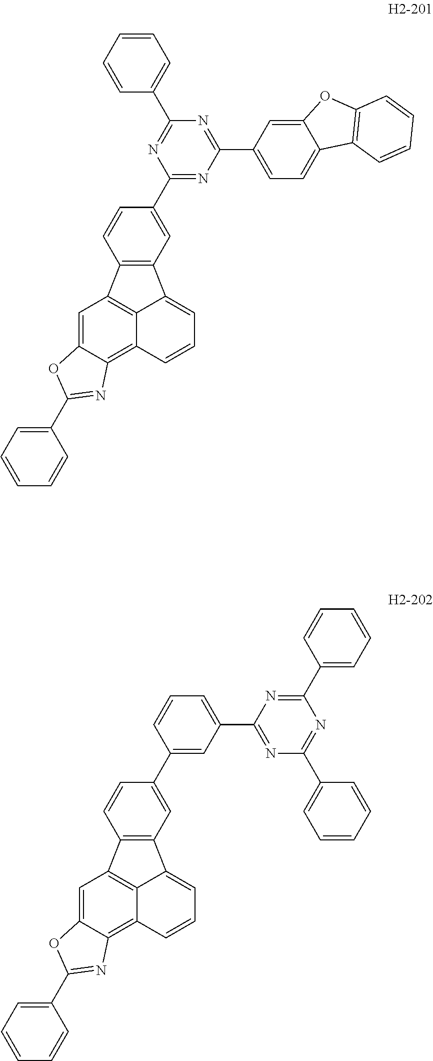 [SMILES: c1ccc(-c2nc(-c3ccc4c(c3)-c3cccc5c3c-4cc3oc(-c4ccccc4)nc35)nc(-c3ccc4c(c3)oc3ccccc34)n2)cc1 ; c1ccc(-c2nc(-c3ccccc3)nc(-c3cccc(-c4ccc5c(c4)-c4cccc6c4c-5cc4oc(-c5ccccc5)nc46)c3)n2)cc1]

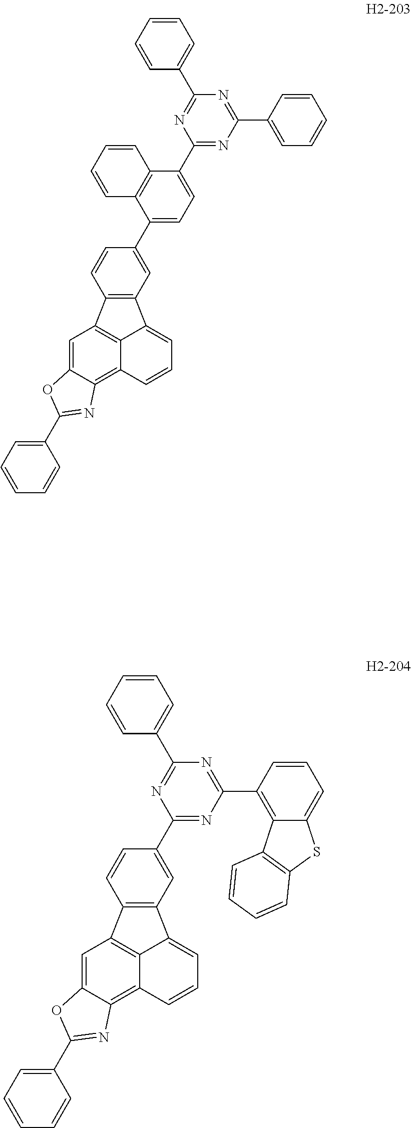 [SMILES: c1ccc(-c2nc(-c3ccccc3)nc(-c3ccc(-c4ccc5c(c4)-c4cccc6c4c-5cc4oc(-c5ccccc5)nc46)c4ccccc34)n2)cc1 ; c1ccc(-c2nc(-c3ccc4c(c3)-c3cccc5c3c-4cc3oc(-c4ccccc4)nc35)nc(-c3cccc4sc5ccccc5c34)n2)cc1]

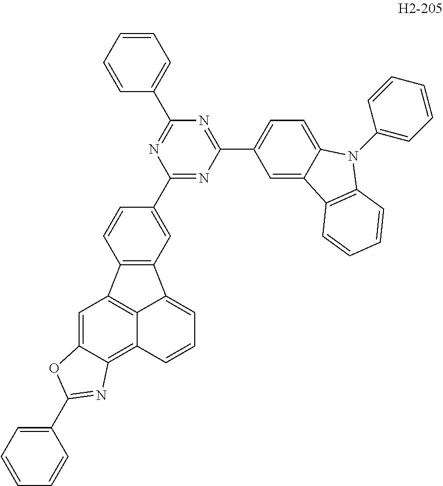 [SMILES: c1ccc(-c2nc(-c3ccc4c(c3)-c3cccc5c3c-4cc3oc(-c4ccccc4)nc35)nc(-c3ccc4c(c3)c3ccccc3n4-c3ccccc3)n2)cc1]

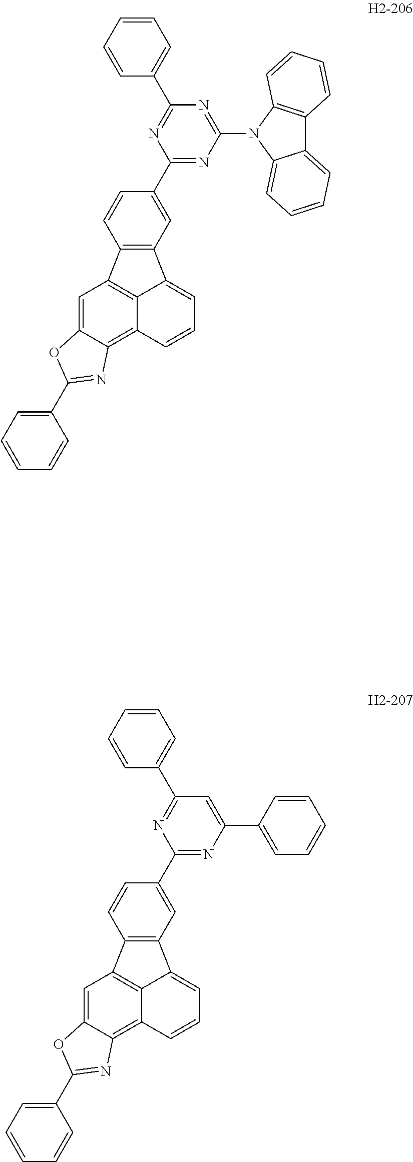 [SMILES: c1ccc(-c2nc(-c3ccc4c(c3)-c3cccc5c3c-4cc3oc(-c4ccccc4)nc35)nc(-n3c4ccccc4c4ccccc43)n2)cc1 ; c1ccc(-c2cc(-c3ccccc3)nc(-c3ccc4c(c3)-c3cccc5c3c-4cc3oc(-c4ccccc4)nc35)n2)cc1]

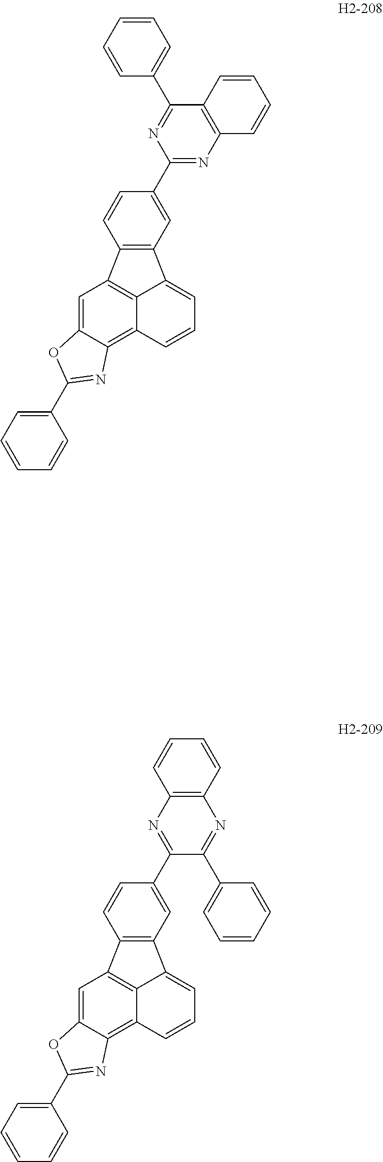 [SMILES: c1ccc(-c2nc3c(cc4c5c(cccc53)-c3cc(-c5nc(-c6ccccc6)c6ccccc6n5)ccc3-4)o2)cc1 ; c1ccc(-c2nc3c(cc4c5c(cccc53)-c3cc(-c5nc6ccccc6nc5-c5ccccc5)ccc3-4)o2)cc1]

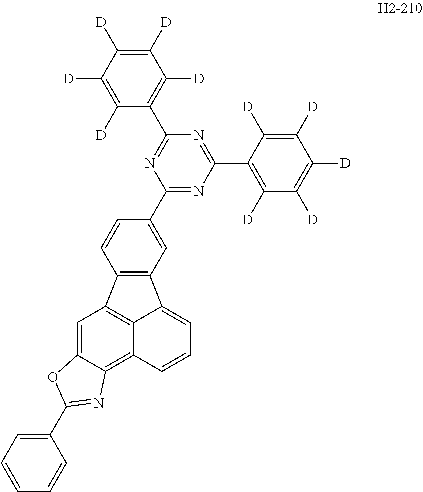 [SMILES: [2H]c1c([2H])c([2H])c(-c2nc(-c3ccc4c(c3)-c3cccc5c3c-4cc3oc(-c4ccccc4)nc35)nc(-c3c([2H])c([2H])c([2H])c([2H])c3[2H])n2)c([2H])c1[2H]]

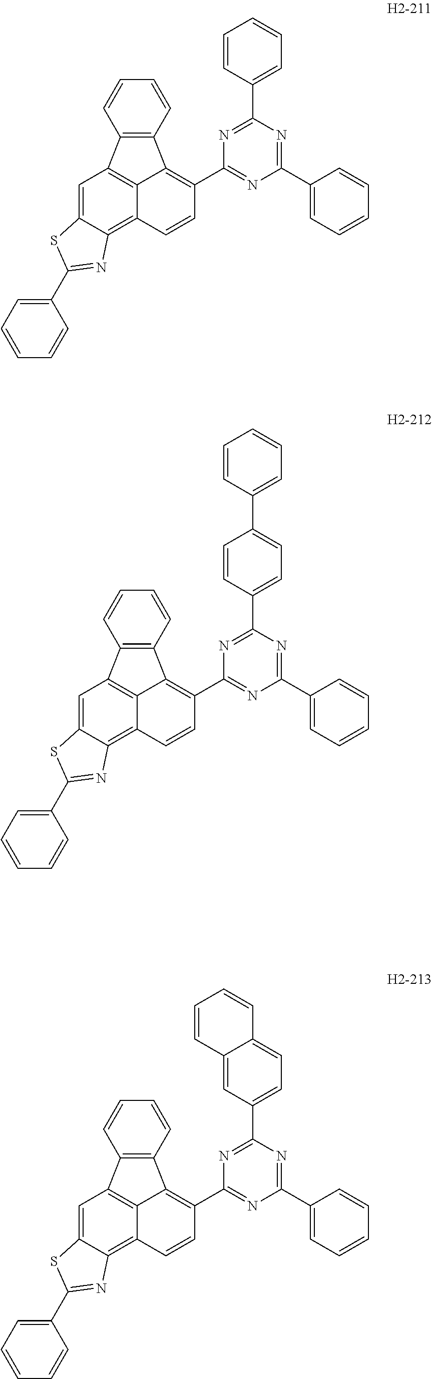 [SMILES: c1ccc(-c2nc(-c3ccccc3)nc(-c3ccc4c5c(cc6sc(-c7ccccc7)nc64)-c4ccccc4-c35)n2)cc1 ; c1ccc(-c2ccc(-c3nc(-c4ccccc4)nc(-c4ccc5c6c(cc7sc(-c8ccccc8)nc75)-c5ccccc5-c46)n3)cc2)cc1 ; c1ccc(-c2nc(-c3ccc4ccccc4c3)nc(-c3ccc4c5c(cc6sc(-c7ccccc7)nc64)-c4ccccc4-c35)n2)cc1]

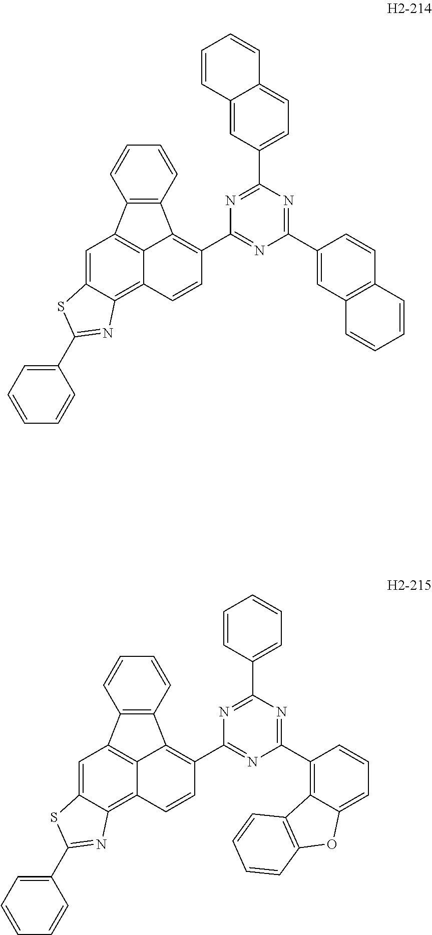 [SMILES: c1ccc(-c2nc3c(cc4c5c(c(-c6nc(-c7ccc8ccccc8c7)nc(-c7ccc8ccccc8c7)n6)ccc53)-c3ccccc3-4)s2)cc1 ; c1ccc(-c2nc(-c3ccc4c5c(cc6sc(-c7ccccc7)nc64)-c4ccccc4-c35)nc(-c3cccc4oc5ccccc5c34)n2)cc1]

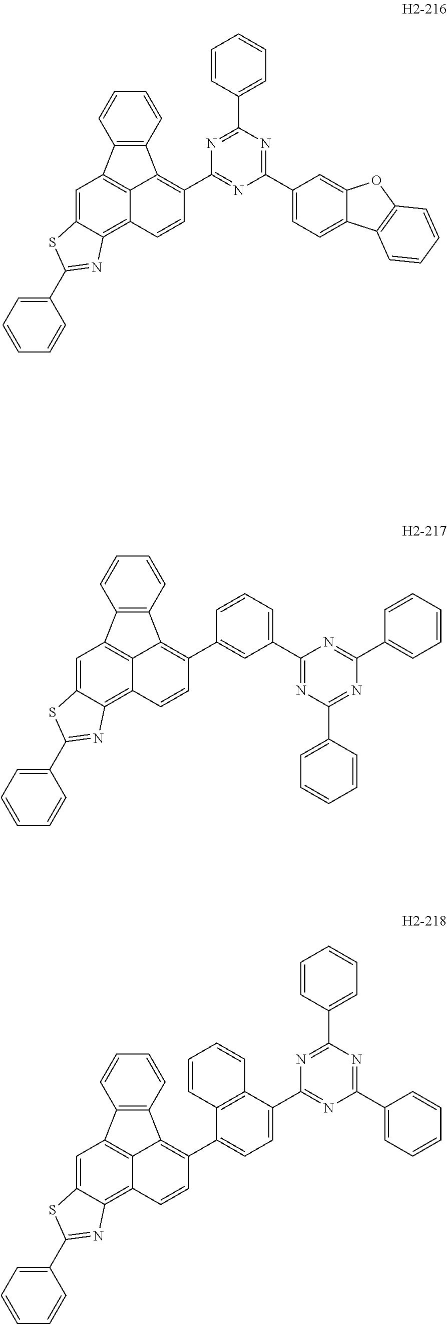 [SMILES: c1ccc(-c2nc(-c3ccc4c(c3)oc3ccccc34)nc(-c3ccc4c5c(cc6sc(-c7ccccc7)nc64)-c4ccccc4-c35)n2)cc1 ; c1ccc(-c2nc(-c3ccccc3)nc(-c3cccc(-c4ccc5c6c(cc7sc(-c8ccccc8)nc75)-c5ccccc5-c46)c3)n2)cc1 ; c1ccc(-c2nc(-c3ccccc3)nc(-c3ccc(-c4ccc5c6c(cc7sc(-c8ccccc8)nc75)-c5ccccc5-c46)c4ccccc34)n2)cc1]

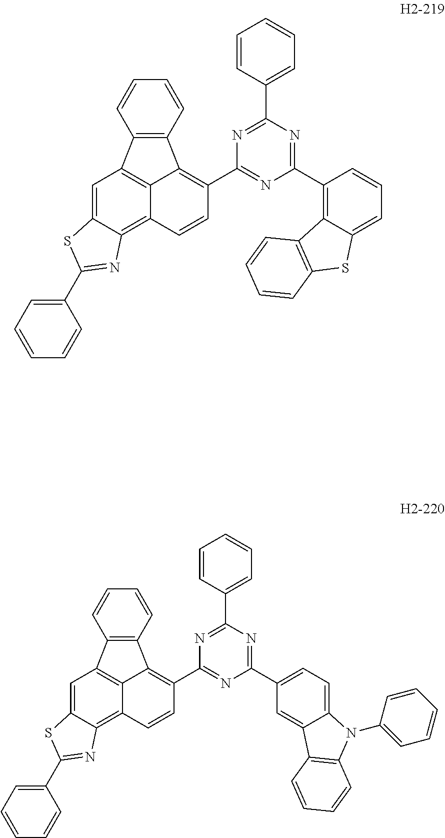 [SMILES: c1ccc(-c2nc(-c3ccc4c5c(cc6sc(-c7ccccc7)nc64)-c4ccccc4-c35)nc(-c3cccc4sc5ccccc5c34)n2)cc1 ; c1ccc(-c2nc(-c3ccc4c(c3)c3ccccc3n4-c3ccccc3)nc(-c3ccc4c5c(cc6sc(-c7ccccc7)nc64)-c4ccccc4-c35)n2)cc1]

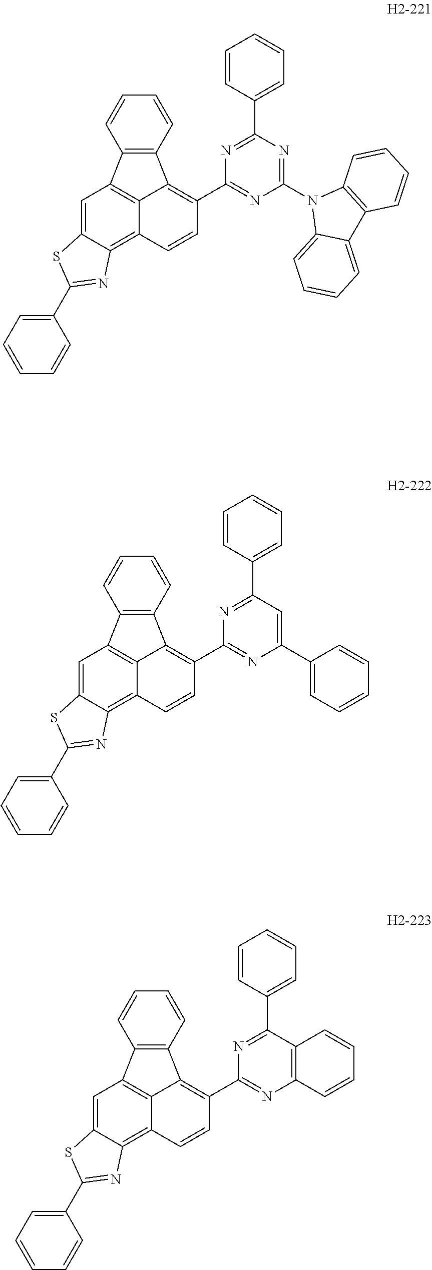 [SMILES: c1ccc(-c2nc(-c3ccc4c5c(cc6sc(-c7ccccc7)nc64)-c4ccccc4-c35)nc(-n3c4ccccc4c4ccccc43)n2)cc1 ; c1ccc(-c2cc(-c3ccccc3)nc(-c3ccc4c5c(cc6sc(-c7ccccc7)nc64)-c4ccccc4-c35)n2)cc1 ; c1ccc(-c2nc3c(cc4c5c(c(-c6nc(-c7ccccc7)c7ccccc7n6)ccc53)-c3ccccc3-4)s2)cc1]

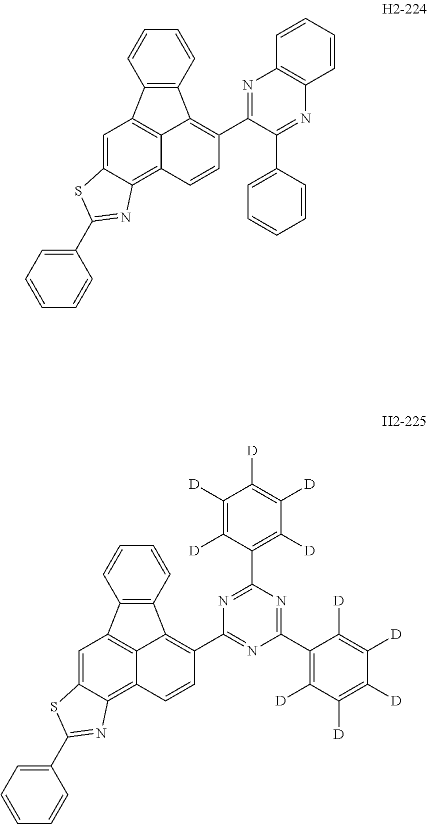 [SMILES: c1ccc(-c2nc3c(cc4c5c(c(-c6nc7ccccc7nc6-c6ccccc6)ccc53)-c3ccccc3-4)s2)cc1 ; [2H]c1c([2H])c([2H])c(-c2nc(-c3ccc4c5c(cc6sc(-c7ccccc7)nc64)-c4ccccc4-c35)nc(-c3c([2H])c([2H])c([2H])c([2H])c3[2H])n2)c([2H])c1[2H]]

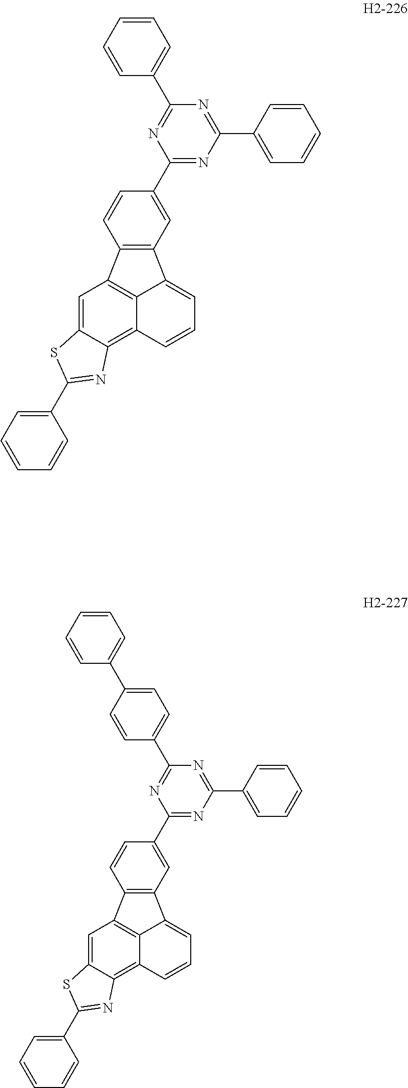 [SMILES: c1ccc(-c2nc(-c3ccccc3)nc(-c3ccc4c(c3)-c3cccc5c3c-4cc3sc(-c4ccccc4)nc35)n2)cc1 ; c1ccc(-c2ccc(-c3nc(-c4ccccc4)nc(-c4ccc5c(c4)-c4cccc6c4c-5cc4sc(-c5ccccc5)nc46)n3)cc2)cc1]

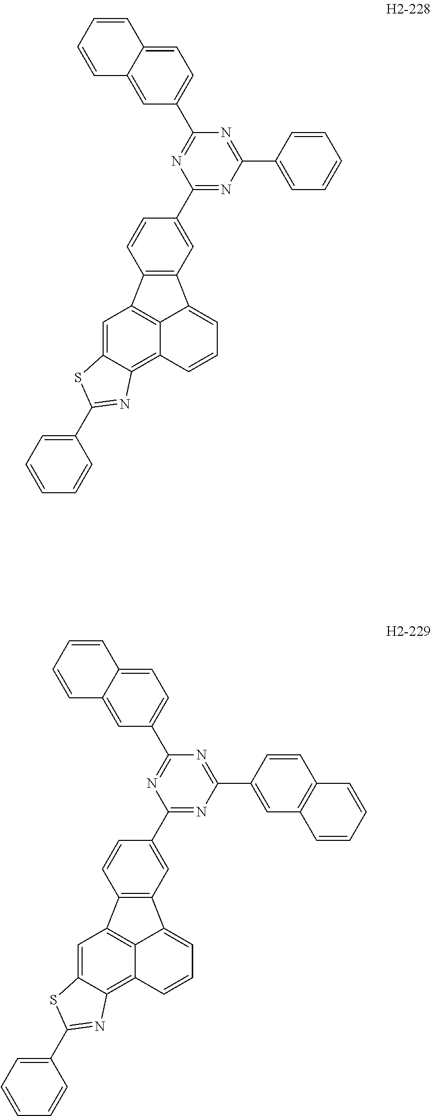 [SMILES: c1ccc(-c2nc(-c3ccc4c(c3)-c3cccc5c3c-4cc3sc(-c4ccccc4)nc35)nc(-c3ccc4ccccc4c3)n2)cc1 ; c1ccc(-c2nc3c(cc4c5c(cccc53)-c3cc(-c5nc(-c6ccc7ccccc7c6)nc(-c6ccc7ccccc7c6)n5)ccc3-4)s2)cc1]

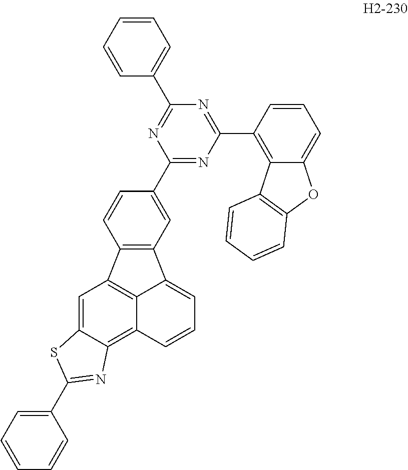 [SMILES: c1ccc(-c2nc(-c3ccc4c(c3)-c3cccc5c3c-4cc3sc(-c4ccccc4)nc35)nc(-c3cccc4oc5ccccc5c34)n2)cc1]

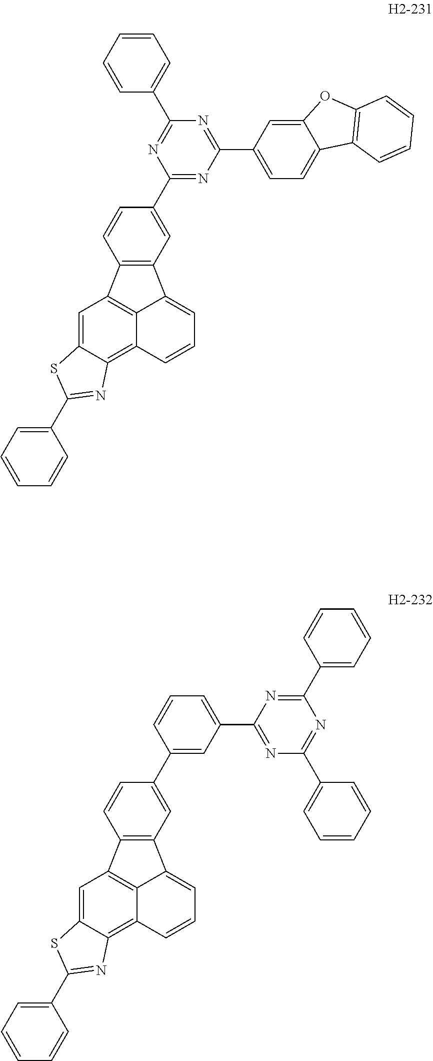 [SMILES: c1ccc(-c2nc(-c3ccc4c(c3)-c3cccc5c3c-4cc3sc(-c4ccccc4)nc35)nc(-c3ccc4c(c3)oc3ccccc34)n2)cc1 ; c1ccc(-c2nc(-c3ccccc3)nc(-c3cccc(-c4ccc5c(c4)-c4cccc6c4c-5cc4sc(-c5ccccc5)nc46)c3)n2)cc1]

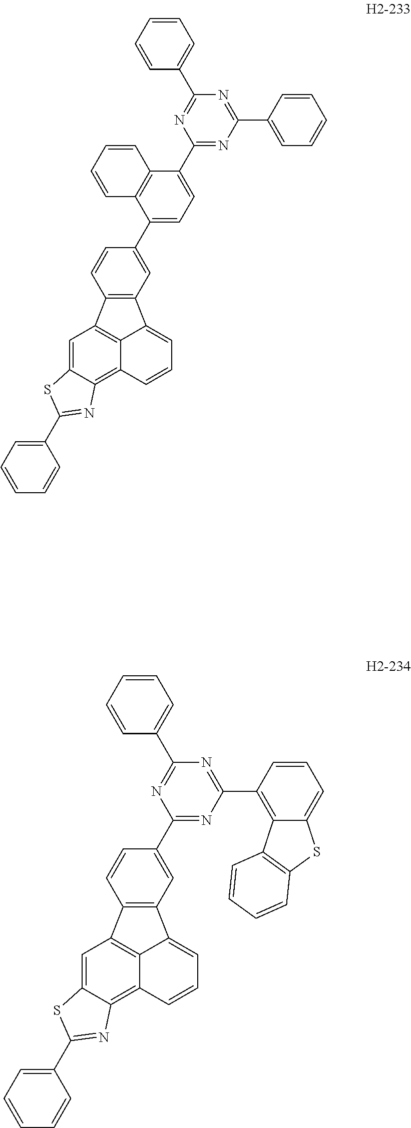 [SMILES: c1ccc(-c2nc(-c3ccccc3)nc(-c3ccc(-c4ccc5c(c4)-c4cccc6c4c-5cc4sc(-c5ccccc5)nc46)c4ccccc34)n2)cc1 ; c1ccc(-c2nc(-c3ccc4c(c3)-c3cccc5c3c-4cc3sc(-c4ccccc4)nc35)nc(-c3cccc4sc5ccccc5c34)n2)cc1]

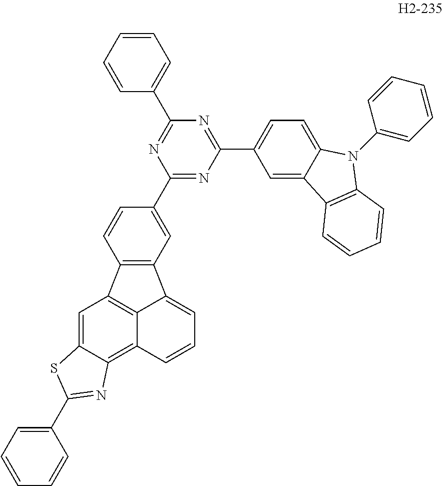 [SMILES: c1ccc(-c2nc(-c3ccc4c(c3)-c3cccc5c3c-4cc3sc(-c4ccccc4)nc35)nc(-c3ccc4c(c3)c3ccccc3n4-c3ccccc3)n2)cc1]

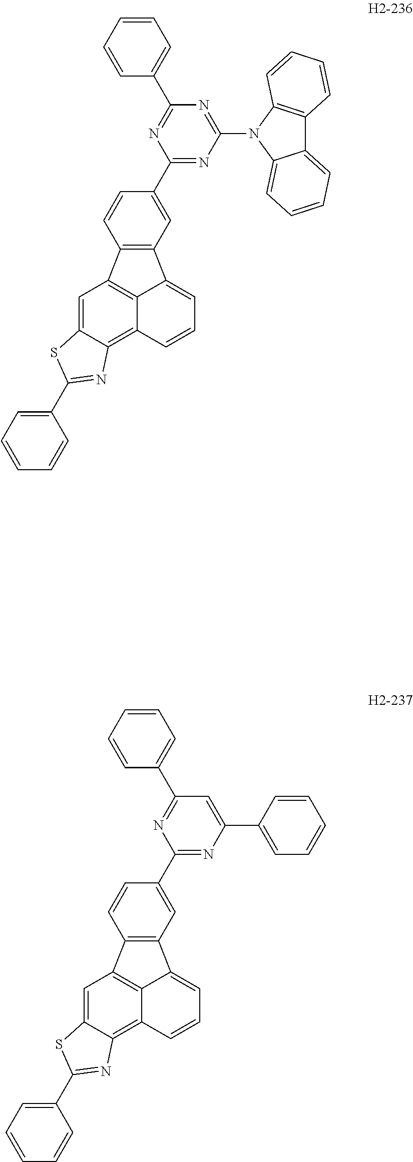 [SMILES: c1ccc(-c2nc(-c3ccc4c(c3)-c3cccc5c3c-4cc3sc(-c4ccccc4)nc35)nc(-n3c4ccccc4c4ccccc43)n2)cc1 ; c1ccc(-c2cc(-c3ccccc3)nc(-c3ccc4c(c3)-c3cccc5c3c-4cc3sc(-c4ccccc4)nc35)n2)cc1]

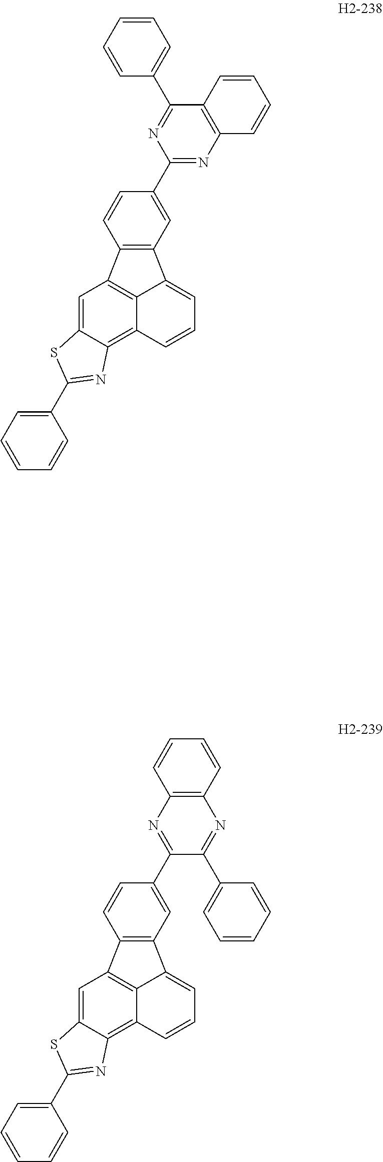 [SMILES: c1ccc(-c2nc3c(cc4c5c(cccc53)-c3cc(-c5nc(-c6ccccc6)c6ccccc6n5)ccc3-4)s2)cc1 ; c1ccc(-c2nc3c(cc4c5c(cccc53)-c3cc(-c5nc6ccccc6nc5-c5ccccc5)ccc3-4)s2)cc1]

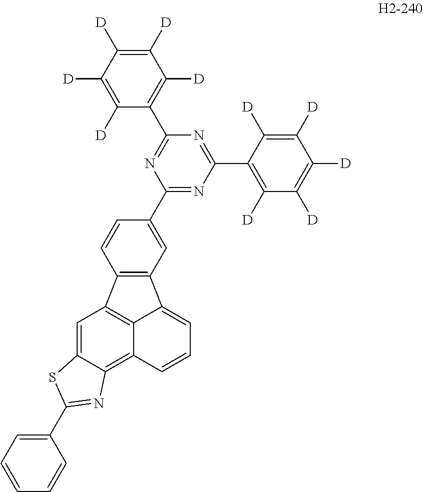 [SMILES: [2H]c1c([2H])c([2H])c(-c2nc(-c3ccc4c(c3)-c3cccc5c3c-4cc3sc(-c4ccccc4)nc35)nc(-c3c([2H])c([2H])c([2H])c([2H])c3[2H])n2)c([2H])c1[2H]]

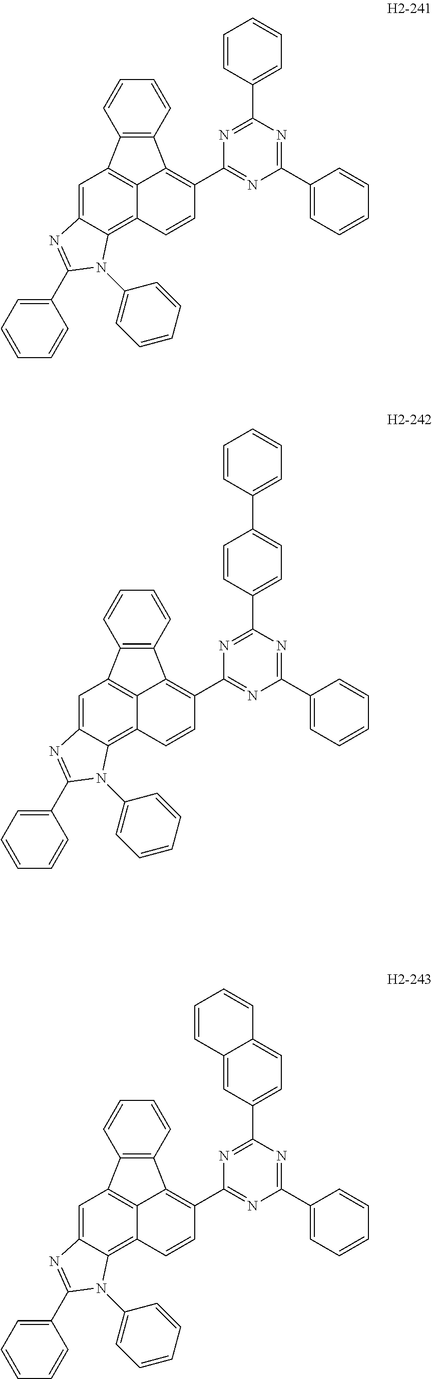 [SMILES: c1ccc(-c2nc(-c3ccccc3)nc(-c3ccc4c5c(cc6nc(-c7ccccc7)n(-c7ccccc7)c64)-c4ccccc4-c35)n2)cc1 ; c1ccc(-c2ccc(-c3nc(-c4ccccc4)nc(-c4ccc5c6c(cc7nc(-c8ccccc8)n(-c8ccccc8)c75)-c5ccccc5-c46)n3)cc2)cc1 ; c1ccc(-c2nc(-c3ccc4ccccc4c3)nc(-c3ccc4c5c(cc6nc(-c7ccccc7)n(-c7ccccc7)c64)-c4ccccc4-c35)n2)cc1]

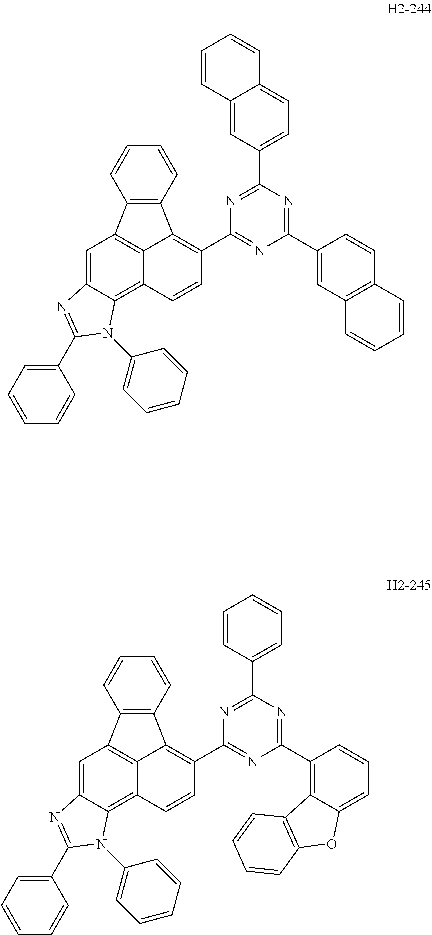 [SMILES: c1ccc(-c2nc3cc4c5c(c(-c6nc(-c7ccc8ccccc8c7)nc(-c7ccc8ccccc8c7)n6)ccc5c3n2-c2ccccc2)-c2ccccc2-4)cc1 ; c1ccc(-c2nc(-c3ccc4c5c(cc6nc(-c7ccccc7)n(-c7ccccc7)c64)-c4ccccc4-c35)nc(-c3cccc4oc5ccccc5c34)n2)cc1]

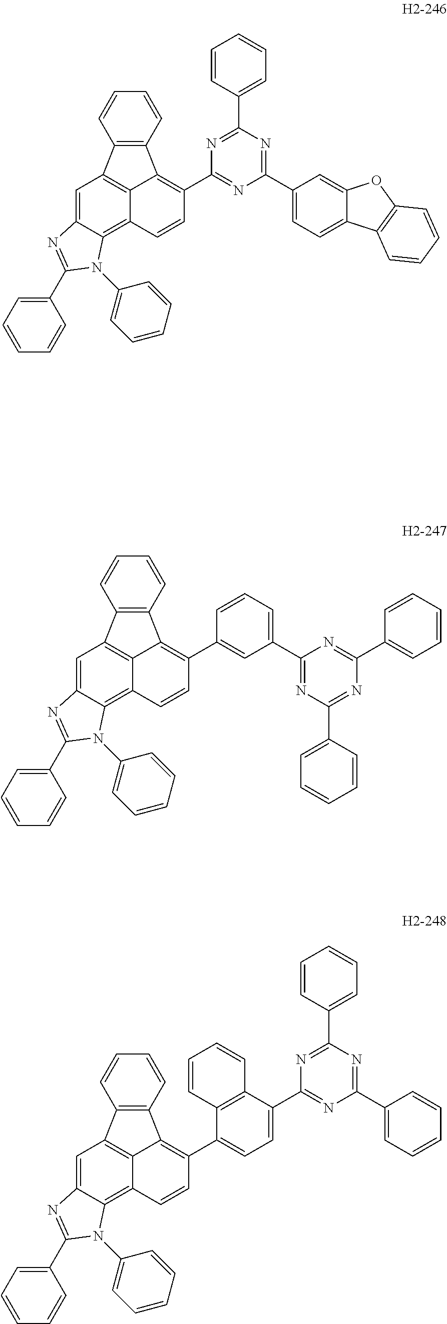 [SMILES: c1ccc(-c2nc(-c3ccc4c(c3)oc3ccccc34)nc(-c3ccc4c5c(cc6nc(-c7ccccc7)n(-c7ccccc7)c64)-c4ccccc4-c35)n2)cc1 ; c1ccc(-c2nc(-c3ccccc3)nc(-c3cccc(-c4ccc5c6c(cc7nc(-c8ccccc8)n(-c8ccccc8)c75)-c5ccccc5-c46)c3)n2)cc1 ; c1ccc(-c2nc(-c3ccccc3)nc(-c3ccc(-c4ccc5c6c(cc7nc(-c8ccccc8)n(-c8ccccc8)c75)-c5ccccc5-c46)c4ccccc34)n2)cc1]

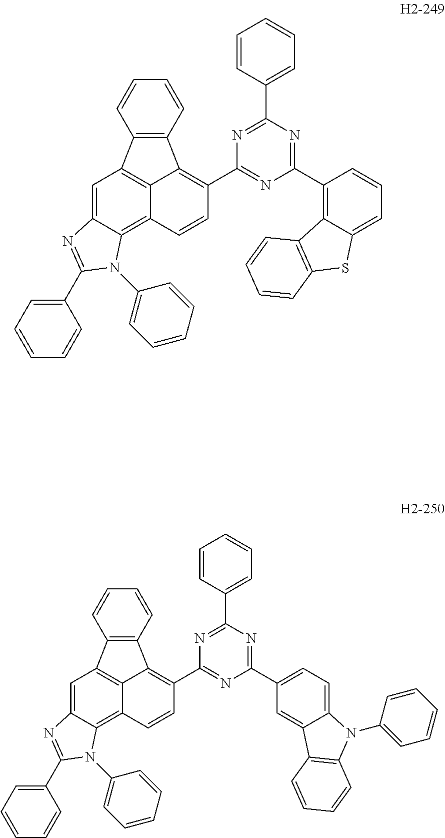 [SMILES: c1ccc(-c2nc(-c3ccc4c5c(cc6nc(-c7ccccc7)n(-c7ccccc7)c64)-c4ccccc4-c35)nc(-c3cccc4sc5ccccc5c34)n2)cc1 ; c1ccc(-c2nc(-c3ccc4c(c3)c3ccccc3n4-c3ccccc3)nc(-c3ccc4c5c(cc6nc(-c7ccccc7)n(-c7ccccc7)c64)-c4ccccc4-c35)n2)cc1]

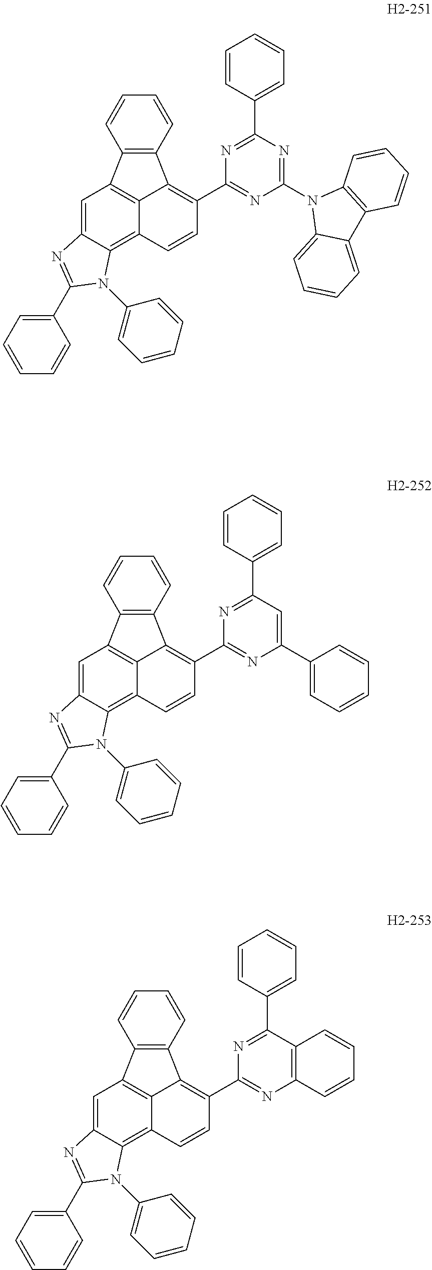 [SMILES: c1ccc(-c2nc(-c3ccc4c5c(cc6nc(-c7ccccc7)n(-c7ccccc7)c64)-c4ccccc4-c35)nc(-n3c4ccccc4c4ccccc43)n2)cc1 ; c1ccc(-c2cc(-c3ccccc3)nc(-c3ccc4c5c(cc6nc(-c7ccccc7)n(-c7ccccc7)c64)-c4ccccc4-c35)n2)cc1 ; c1ccc(-c2nc(-c3ccc4c5c(cc6nc(-c7ccccc7)n(-c7ccccc7)c64)-c4ccccc4-c35)nc3ccccc23)cc1]

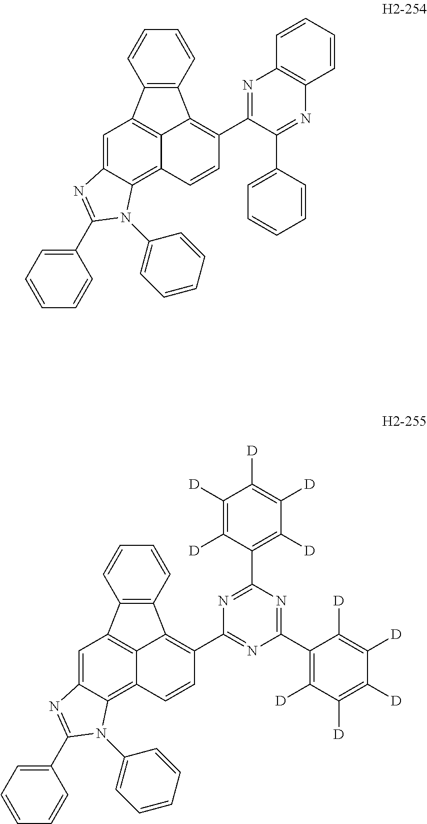 [SMILES: c1ccc(-c2nc3ccccc3nc2-c2ccc3c4c(cc5nc(-c6ccccc6)n(-c6ccccc6)c53)-c3ccccc3-c24)cc1 ; [2H]c1c([2H])c([2H])c(-c2nc(-c3ccc4c5c(cc6nc(-c7ccccc7)n(-c7ccccc7)c64)-c4ccccc4-c35)nc(-c3c([2H])c([2H])c([2H])c([2H])c3[2H])n2)c([2H])c1[2H]]

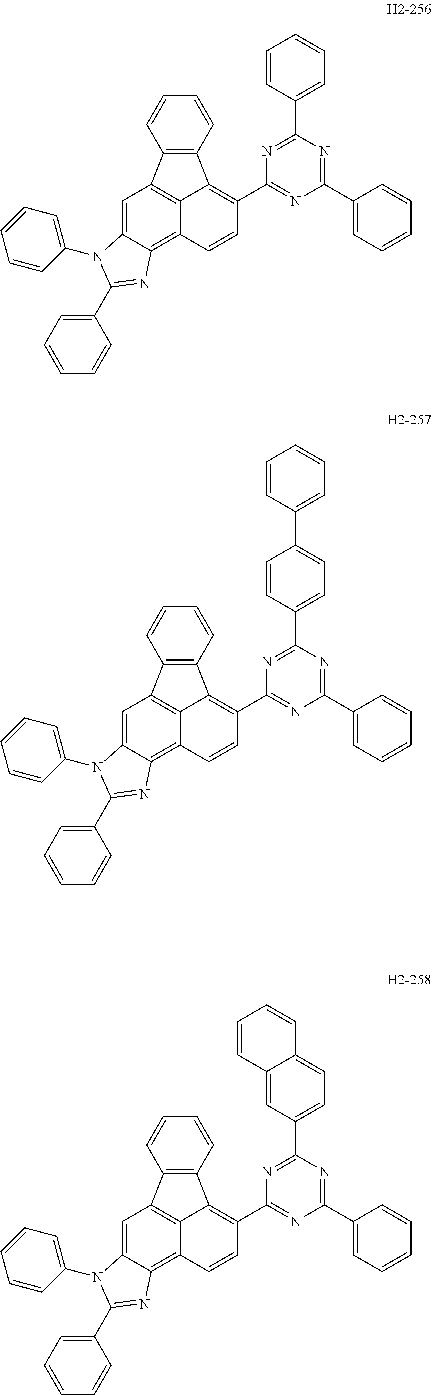 [SMILES: c1ccc(-c2nc(-c3ccccc3)nc(-c3ccc4c5c(cc6c4nc(-c4ccccc4)n6-c4ccccc4)-c4ccccc4-c35)n2)cc1 ; c1ccc(-c2ccc(-c3nc(-c4ccccc4)nc(-c4ccc5c6c(cc7c5nc(-c5ccccc5)n7-c5ccccc5)-c5ccccc5-c46)n3)cc2)cc1 ; c1ccc(-c2nc(-c3ccc4ccccc4c3)nc(-c3ccc4c5c(cc6c4nc(-c4ccccc4)n6-c4ccccc4)-c4ccccc4-c35)n2)cc1]

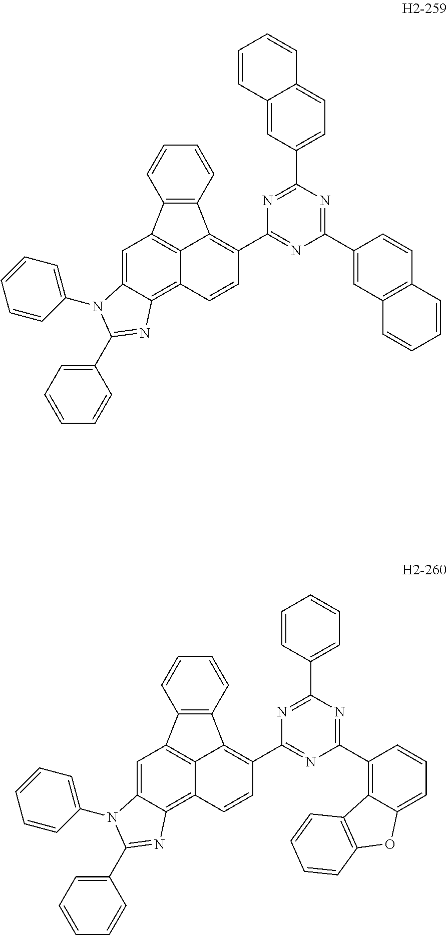 [SMILES: c1ccc(-c2nc3c4ccc(-c5nc(-c6ccc7ccccc7c6)nc(-c6ccc7ccccc7c6)n5)c5c4c(cc3n2-c2ccccc2)-c2ccccc2-5)cc1 ; c1ccc(-c2nc(-c3ccc4c5c(cc6c4nc(-c4ccccc4)n6-c4ccccc4)-c4ccccc4-c35)nc(-c3cccc4oc5ccccc5c34)n2)cc1]

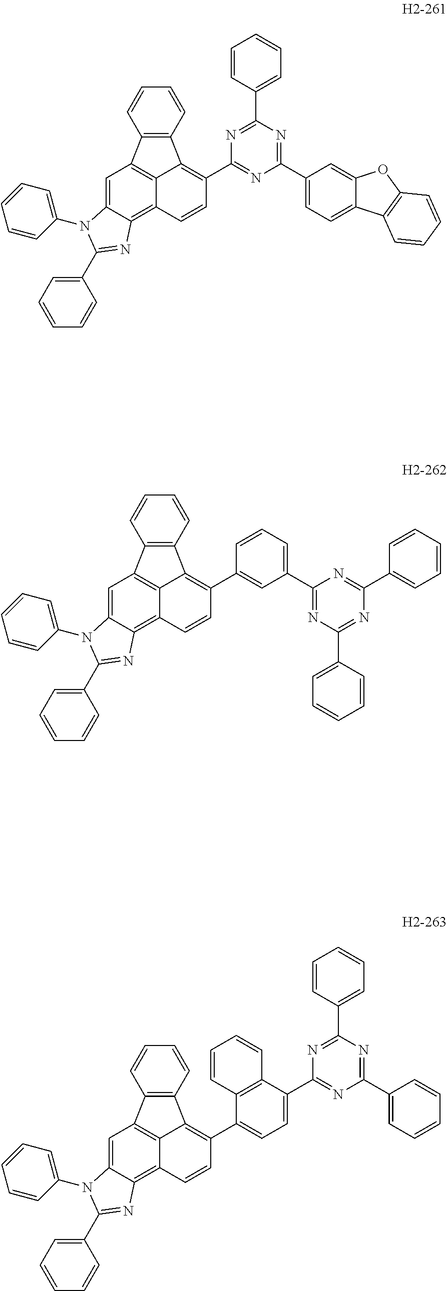 [SMILES: c1ccc(-c2nc(-c3ccc4c(c3)oc3ccccc34)nc(-c3ccc4c5c(cc6c4nc(-c4ccccc4)n6-c4ccccc4)-c4ccccc4-c35)n2)cc1 ; c1ccc(-c2nc(-c3ccccc3)nc(-c3cccc(-c4ccc5c6c(cc7c5nc(-c5ccccc5)n7-c5ccccc5)-c5ccccc5-c46)c3)n2)cc1 ; c1ccc(-c2nc(-c3ccccc3)nc(-c3ccc(-c4ccc5c6c(cc7c5nc(-c5ccccc5)n7-c5ccccc5)-c5ccccc5-c46)c4ccccc34)n2)cc1]

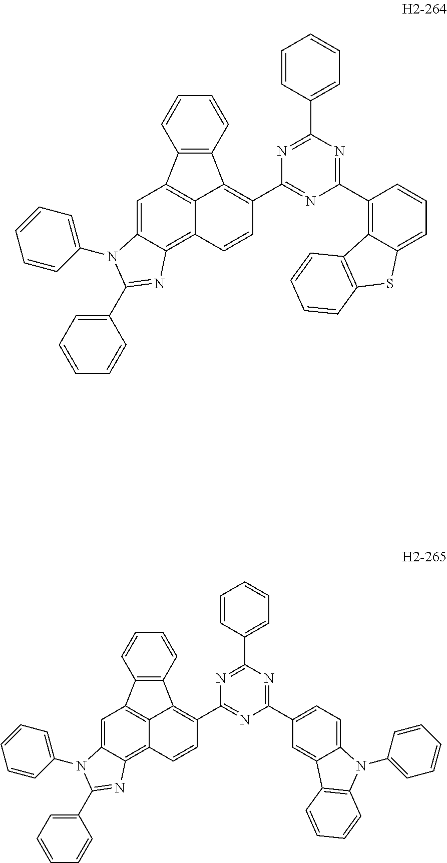 [SMILES: c1ccc(-c2nc(-c3ccc4c5c(cc6c4nc(-c4ccccc4)n6-c4ccccc4)-c4ccccc4-c35)nc(-c3cccc4sc5ccccc5c34)n2)cc1 ; c1ccc(-c2nc(-c3ccc4c(c3)c3ccccc3n4-c3ccccc3)nc(-c3ccc4c5c(cc6c4nc(-c4ccccc4)n6-c4ccccc4)-c4ccccc4-c35)n2)cc1]

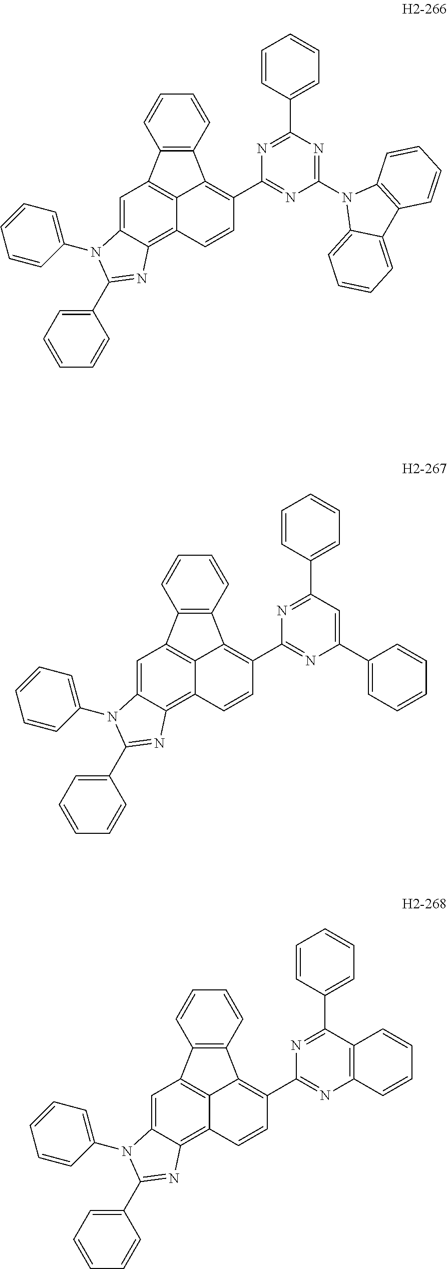 [SMILES: c1ccc(-c2nc(-c3ccc4c5c(cc6c4nc(-c4ccccc4)n6-c4ccccc4)-c4ccccc4-c35)nc(-n3c4ccccc4c4ccccc43)n2)cc1 ; c1ccc(-c2cc(-c3ccccc3)nc(-c3ccc4c5c(cc6c4nc(-c4ccccc4)n6-c4ccccc4)-c4ccccc4-c35)n2)cc1 ; c1ccc(-c2nc(-c3ccc4c5c(cc6c4nc(-c4ccccc4)n6-c4ccccc4)-c4ccccc4-c35)nc3ccccc23)cc1]

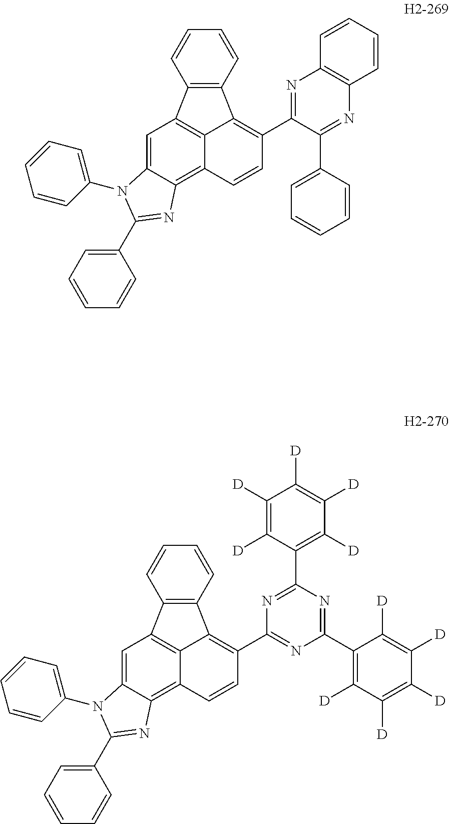 [SMILES: c1ccc(-c2nc3ccccc3nc2-c2ccc3c4c(cc5c3nc(-c3ccccc3)n5-c3ccccc3)-c3ccccc3-c24)cc1 ; [2H]c1c([2H])c([2H])c(-c2nc(-c3ccc4c5c(cc6c4nc(-c4ccccc4)n6-c4ccccc4)-c4ccccc4-c35)nc(-c3c([2H])c([2H])c([2H])c([2H])c3[2H])n2)c([2H])c1[2H]]

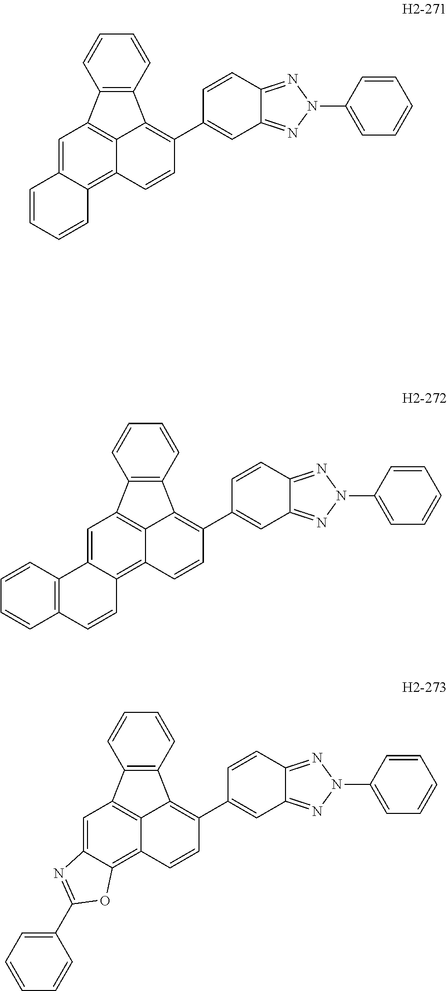 [SMILES: c1ccc(-n2nc3ccc(-c4ccc5c6c(cc7ccccc75)-c5ccccc5-c46)cc3n2)cc1 ; c1ccc(-n2nc3ccc(-c4ccc5c6c(cc7c8ccccc8ccc57)-c5ccccc5-c46)cc3n2)cc1 ; c1ccc(-c2nc3cc4c5c(c(-c6ccc7nn(-c8ccccc8)nc7c6)ccc5c3o2)-c2ccccc2-4)cc1]

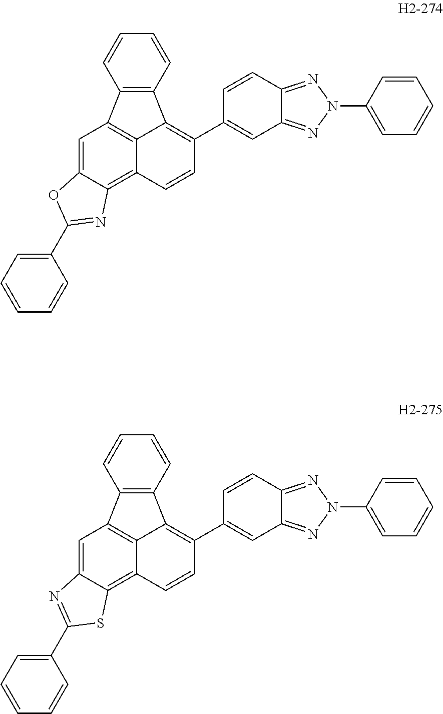 [SMILES: c1ccc(-c2nc3c(cc4c5c(c(-c6ccc7nn(-c8ccccc8)nc7c6)ccc53)-c3ccccc3-4)o2)cc1 ; c1ccc(-c2nc3cc4c5c(c(-c6ccc7nn(-c8ccccc8)nc7c6)ccc5c3s2)-c2ccccc2-4)cc1]

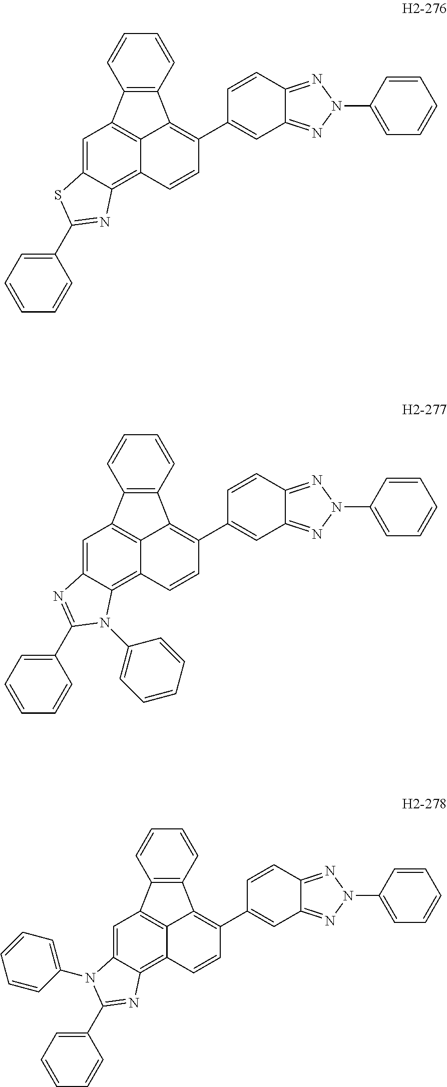 [SMILES: c1ccc(-c2nc3c(cc4c5c(c(-c6ccc7nn(-c8ccccc8)nc7c6)ccc53)-c3ccccc3-4)s2)cc1 ; c1ccc(-c2nc3cc4c5c(c(-c6ccc7nn(-c8ccccc8)nc7c6)ccc5c3n2-c2ccccc2)-c2ccccc2-4)cc1 ; c1ccc(-c2nc3c4ccc(-c5ccc6nn(-c7ccccc7)nc6c5)c5c4c(cc3n2-c2ccccc2)-c2ccccc2-5)cc1]

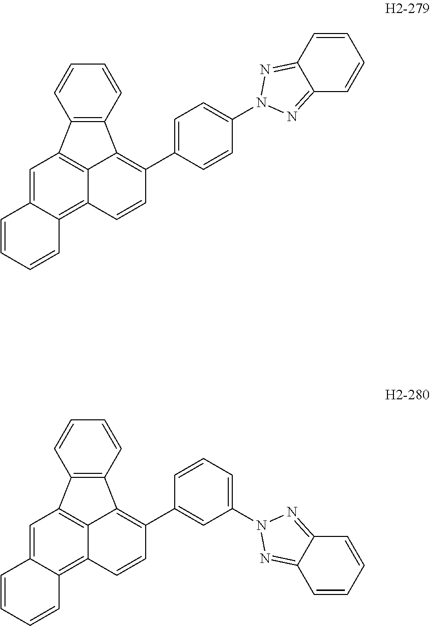 [SMILES: c1ccc2c(c1)-c1cc3ccccc3c3ccc(-c4ccc(-n5nc6ccccc6n5)cc4)c-2c13 ; c1cc(-c2ccc3c4c(cc5ccccc53)-c3ccccc3-c24)cc(-n2nc3ccccc3n2)c1]

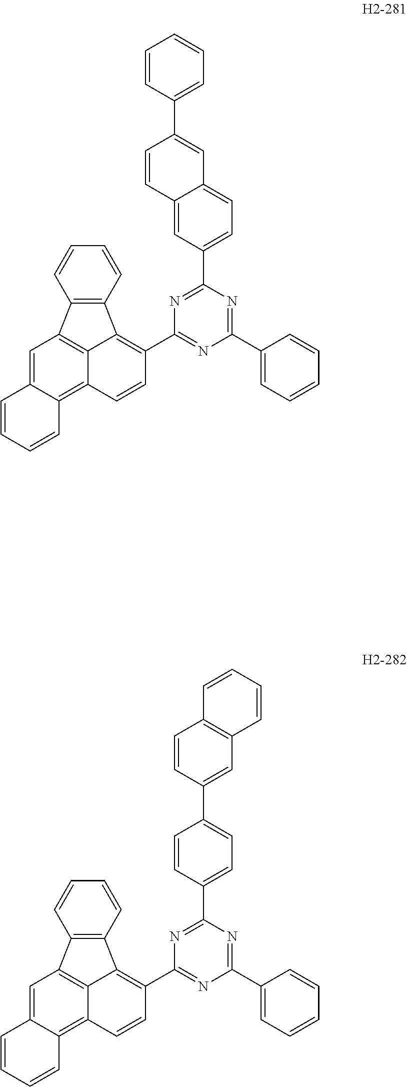 [SMILES: c1ccc(-c2ccc3cc(-c4nc(-c5ccccc5)nc(-c5ccc6c7c(cc8ccccc86)-c6ccccc6-c57)n4)ccc3c2)cc1 ; c1ccc(-c2nc(-c3ccc(-c4ccc5ccccc5c4)cc3)nc(-c3ccc4c5c(cc6ccccc64)-c4ccccc4-c35)n2)cc1]

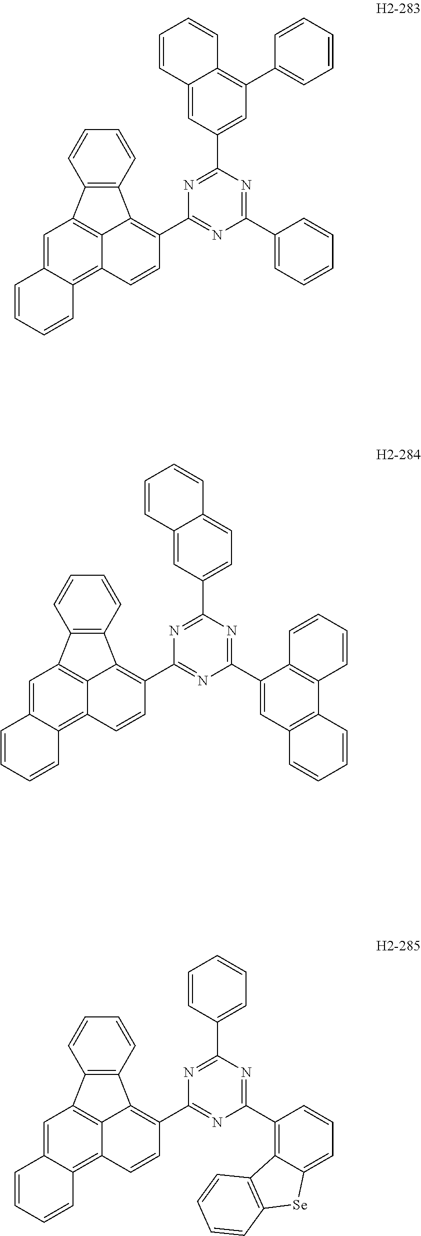 [SMILES: c1ccc(-c2nc(-c3cc(-c4ccccc4)c4ccccc4c3)nc(-c3ccc4c5c(cc6ccccc64)-c4ccccc4-c35)n2)cc1 ; c1ccc2c(c1)-c1cc3ccccc3c3ccc(-c4nc(-c5ccc6ccccc6c5)nc(-c5cc6ccccc6c6ccccc56)n4)c-2c13 ; c1ccc(-c2nc(-c3ccc4c5c(cc6ccccc64)-c4ccccc4-c35)nc(-c3cccc4[se]c5ccccc5c34)n2)cc1]

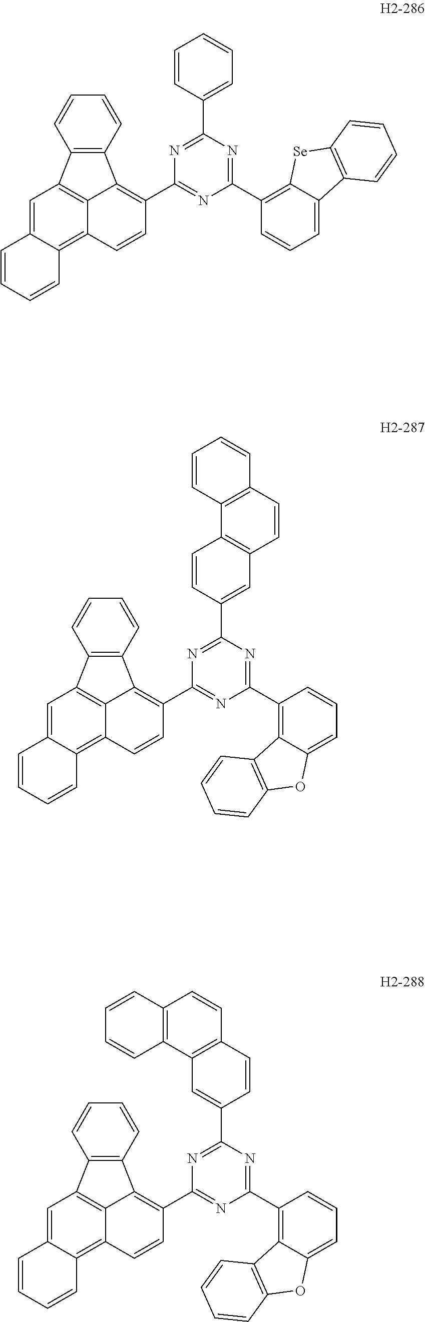 [SMILES: c1ccc(-c2nc(-c3ccc4c5c(cc6ccccc64)-c4ccccc4-c35)nc(-c3cccc4c3[se]c3ccccc34)n2)cc1 ; c1ccc2c(c1)-c1cc3ccccc3c3ccc(-c4nc(-c5ccc6c(ccc7ccccc76)c5)nc(-c5cccc6oc7ccccc7c56)n4)c-2c13 ; c1ccc2c(c1)-c1cc3ccccc3c3ccc(-c4nc(-c5ccc6ccc7ccccc7c6c5)nc(-c5cccc6oc7ccccc7c56)n4)c-2c13]

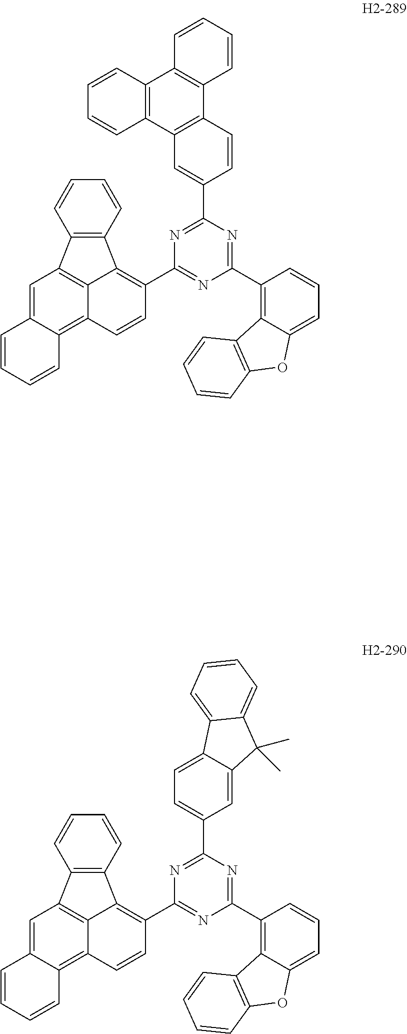 [SMILES: c1ccc2c(c1)-c1cc3ccccc3c3ccc(-c4nc(-c5ccc6c7ccccc7c7ccccc7c6c5)nc(-c5cccc6oc7ccccc7c56)n4)c-2c13 ; CC1(C)c2ccccc2-c2ccc(-c3nc(-c4ccc5c6c(cc7ccccc75)-c5ccccc5-c46)nc(-c4cccc5oc6ccccc6c45)n3)cc21]

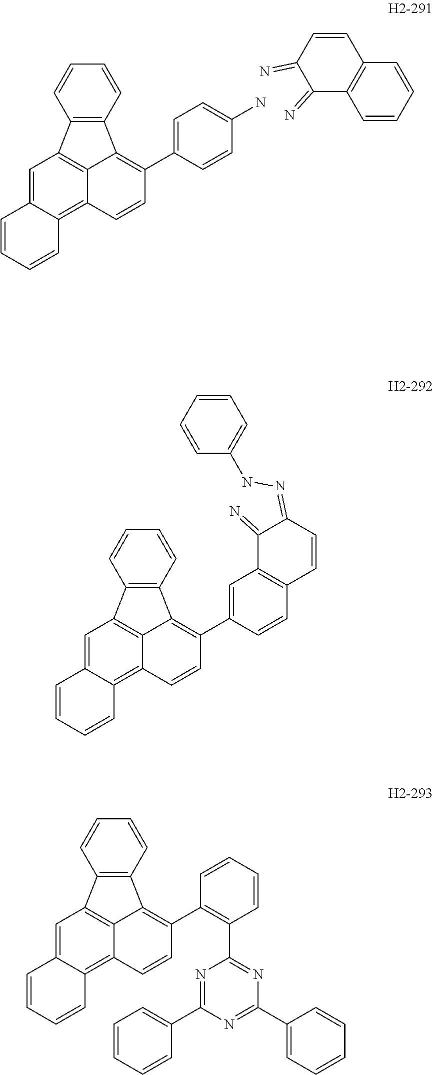

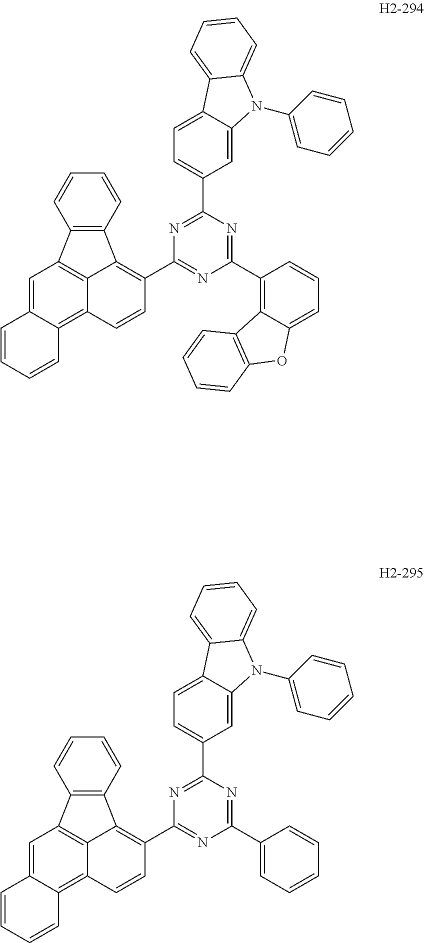 [SMILES: c1ccc(-n2c3ccccc3c3ccc(-c4nc(-c5ccc6c7c(cc8ccccc86)-c6ccccc6-c57)nc(-c5cccc6oc7ccccc7c56)n4)cc32)cc1 ; c1ccc(-c2nc(-c3ccc4c5ccccc5n(-c5ccccc5)c4c3)nc(-c3ccc4c5c(cc6ccccc64)-c4ccccc4-c35)n2)cc1]

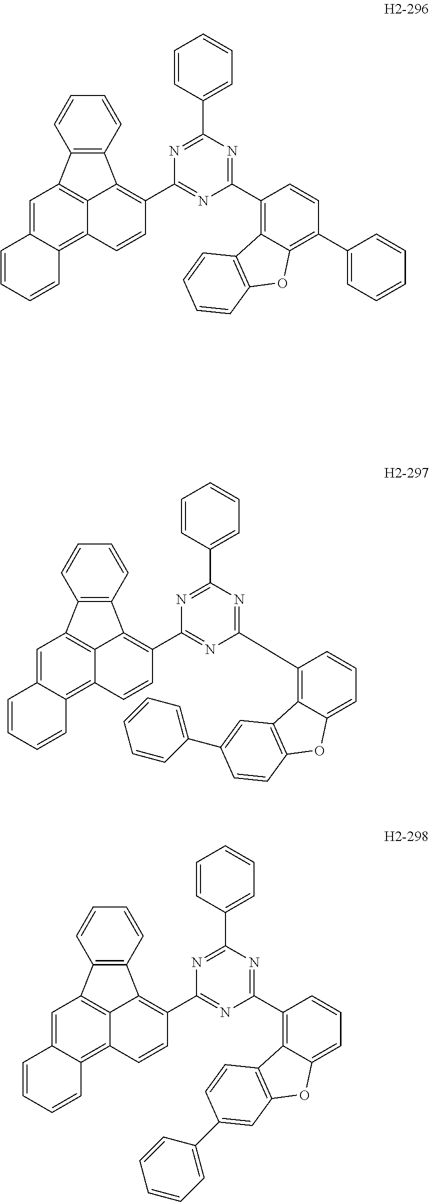 [SMILES: c1ccc(-c2nc(-c3ccc4c5c(cc6ccccc64)-c4ccccc4-c35)nc(-c3ccc(-c4ccccc4)c4oc5ccccc5c34)n2)cc1 ; c1ccc(-c2ccc3oc4cccc(-c5nc(-c6ccccc6)nc(-c6ccc7c8c(cc9ccccc97)-c7ccccc7-c68)n5)c4c3c2)cc1 ; c1ccc(-c2ccc3c(c2)oc2cccc(-c4nc(-c5ccccc5)nc(-c5ccc6c7c(cc8ccccc86)-c6ccccc6-c57)n4)c23)cc1]

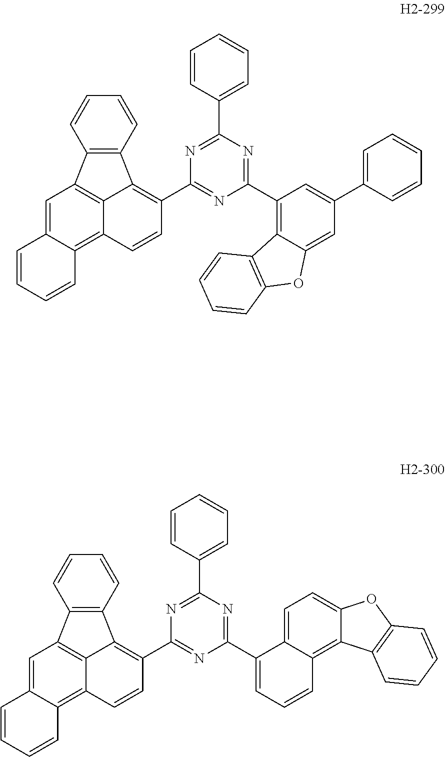 [SMILES: c1ccc(-c2cc(-c3nc(-c4ccccc4)nc(-c4ccc5c6c(cc7ccccc75)-c5ccccc5-c46)n3)c3c(c2)oc2ccccc23)cc1 ; c1ccc(-c2nc(-c3ccc4c5c(cc6ccccc64)-c4ccccc4-c35)nc(-c3cccc4c3ccc3oc5ccccc5c34)n2)cc1]

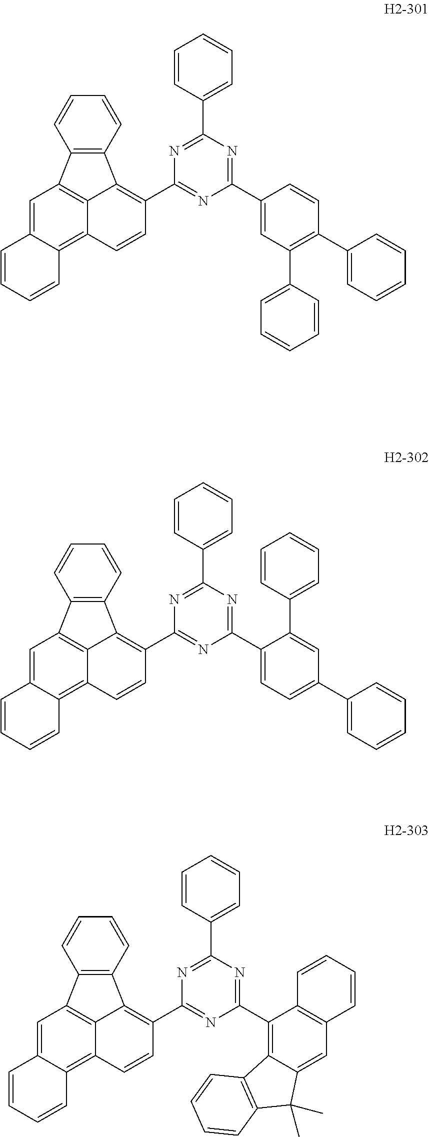 [SMILES: c1ccc(-c2nc(-c3ccc(-c4ccccc4)c(-c4ccccc4)c3)nc(-c3ccc4c5c(cc6ccccc64)-c4ccccc4-c35)n2)cc1 ; c1ccc(-c2ccc(-c3nc(-c4ccccc4)nc(-c4ccc5c6c(cc7ccccc75)-c5ccccc5-c46)n3)c(-c3ccccc3)c2)cc1 ; CC1(C)c2ccccc2-c2c1cc1ccccc1c2-c1nc(-c2ccccc2)nc(-c2ccc3c4c(cc5ccccc53)-c3ccccc3-c24)n1]

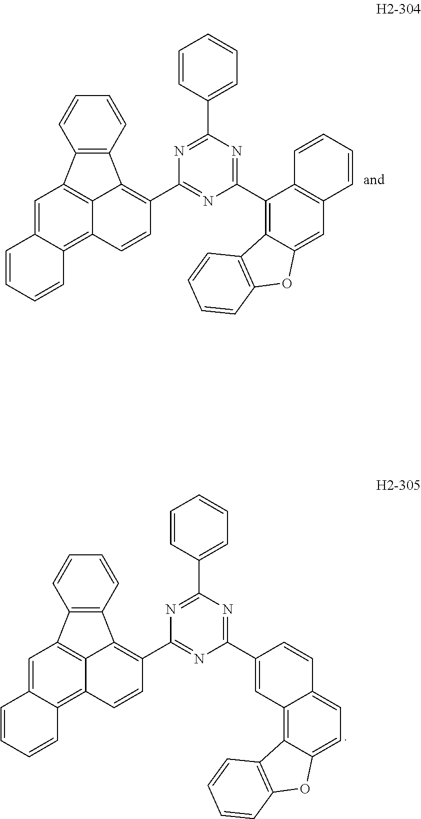 [SMILES: c1ccc(-c2nc(-c3ccc4c5c(cc6ccccc64)-c4ccccc4-c35)nc(-c3c4ccccc4cc4oc5ccccc5c34)n2)cc1 ; c1ccc(-c2nc(-c3ccc4ccc5oc6ccccc6c5c4c3)nc(-c3ccc4c5c(cc6ccccc64)-c4ccccc4-c35)n2)cc1]

5. An organic electroluminescent material comprising a compound represented by the following Formula 1 and a compound represented by the following Formula 2: 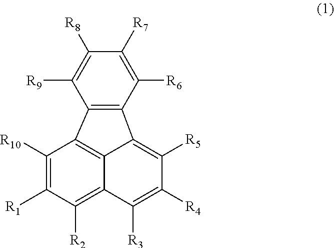
wherein in Formula 1,
R₁ and R₂ are linked to each other to form a substituted or unsubstituted fused ring(s);
R₃ to R₁₀ each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, or a substituted or unsubstituted tri(C6-C30)arylsilyl; and
at least one of the substituent(s) of the fused ring(s) and R₃ to R₁₀ represents a substituted or unsubstituted (3- to 30-membered)heteroaryl comprising at least one N, and 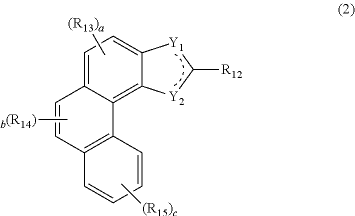
wherein in Formula 2,
Y₁ and Y₂ each independently represent —N═, —NR₁₆—, —O—, or —S—, with a proviso that any one of Y₁ and Y₂ represents —N═, and the other of Y₁ and Y₂ represents —NR₁₆—, —O—, or —S—;
R₁₂ represents a substituted or unsubstituted (C6-C30)aryl, or a substituted or unsubstituted (3- to 30-membered)heteroaryl;
R₁₃ to R₁₆ each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring group of a (C3-C30) aliphatic ring(s) and a (C6-C30) aromatic ring(s), or -L₁-N(Ar₁)(Ar₂); or may be linked to an adjacent substituent(s) to form a ring(s); with a proviso that at least one of R₁₃ to R₁₅ is -L₁-N(Ar₁)(Ar₂);
Ar₁ and Ar₂ each independently represent a substituted or unsubstituted (C6-C30)aryl, a substituted or unsubstituted (3- to 30-membered)heteroaryl, or a substituted or unsubstituted fused ring group of a (C3-C30) aliphatic ring(s) and a (C6-C30) aromatic ring(s);
L₁ represents a single bond, a substituted or unsubstituted (C6-C30)arylene, or a substituted or unsubstituted (3- to 30-membered)heteroarylene; and
a and b each independently represent an integer of 1 or 2, c represents an integer of 1 to 4, where if a to c are an integer of 2 or more, each of R₁₃ to each of R₁₅ may be the same as or different from each other.

6. The organic electroluminescent material according to claim 5, wherein the substituted alkyl, the substituted cycloalkyl, the substituted aryl(ene), the substituted heteroaryl(ene), the substituted alkoxy, the substituted trialkylsilyl, the substituted dialkylarylsilyl, the substituted alkyldiarylsilyl, the substituted triarylsilyl, the substituted fused ring, and the substituted fused ring group of an aliphatic ring(s) and an aromatic ring(s) are substituted by at least one selected from the group consisting of deuterium; a halogen; a cyano; a carboxyl; a nitro; a hydroxyl; a phosphine oxide; a (C1-C30)alkyl; a halo(C1-C30)alkyl; a (C2-C30)alkenyl; a (C2-C30)alkynyl; a (C1-C30)alkoxy; a (C1-C30)alkylthio; a (C3-C30)cycloalkyl; a (C3-C30)cycloalkenyl; a (3- to 7-membered)heterocycloalkyl; a (C6-C30)aryloxy; a (C6-C30)arylthio; a (C6-C30)aryl unsubstituted or substituted with at least one of a (C1-C30)alkyl(s) and a di(C6-C30)arylamino(s); a (3- to 30-membered)heteroaryl unsubstituted or substituted with one or more a (C6-C30)aryl(s); a tri(C1-C30)alkylsilyl; a tri(C6-C30)arylsilyl(s); a di(C1-C30)alkyl(C6-C30)arylsilyl; a (C1-C30)alkyldi(C6-C30)arylsilyl; a fused ring group of an (C3-C30)aliphatic ring(s) and an (C6-C30)aromatic ring(s); amino; a mono- or di-(C1-C30)alkylamino; a mono- or di-(C2-C30)alkenylamino; a mono- or di-(C6-C30)arylamino unsubstituted or substituted with a (C1-C30)alkyl(s); a mono- or di-(3- to 30-membered)heteroarylamino; a (C1-C30)alkyl(C2-C30)alkenylamino; a (C1-C30)alkyl(C6-C30)arylamino; a (C1—C30)alkyl(3- to 30-membered)heteroarylamino; a (C2-C30)alkenyl(C6-C30)arylamino; a (C2-C30)alkenyl(3- to 30-membered)heteroarylamino; a (C6-C30)aryl(3- to 30-membered)heteroarylamino; a (C1-C30)alkylcarbonyl; a (C1-C30)alkoxycarbonyl; a (C6-C30)arylcarbonyl; a di(C6-C30)arylboronyl; a di(C1-C30)alkylboronyl; a (C1-C30)alkyl(C6-C30)arylboronyl; a (C6-C30)aryl(C1-C30)alkyl; and a (C1-C30)alkyl(C6-C30)aryl.

7. The organic electroluminescent material according to claim 5, wherein the compound represented by Formula 2 is at least one of following formulas:

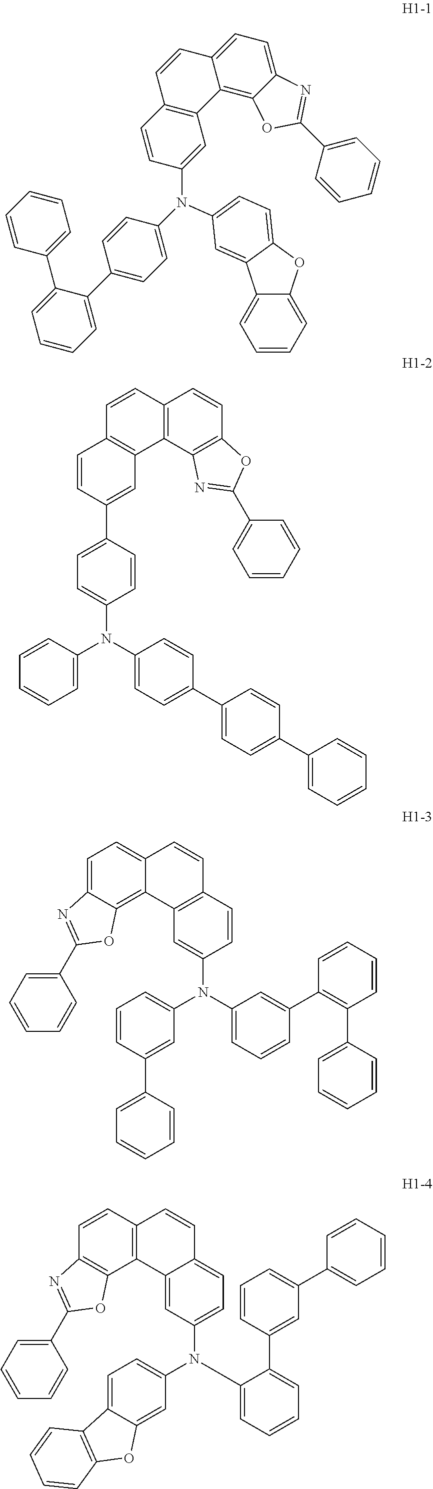 [SMILES: c1ccc(-c2nc3ccc4ccc5ccc(N(c6ccc(-c7ccccc7-c7ccccc7)cc6)c6ccc7oc8ccccc8c7c6)cc5c4c3o2)cc1 ; c1ccc(-c2ccc(-c3ccc(N(c4ccccc4)c4ccc(-c5ccc6ccc7ccc8oc(-c9ccccc9)nc8c7c6c5)cc4)cc3)cc2)cc1 ; c1ccc(-c2cccc(N(c3cccc(-c4ccccc4-c4ccccc4)c3)c3ccc4ccc5ccc6nc(-c7ccccc7)oc6c5c4c3)c2)cc1 ; c1ccc(-c2cccc(-c3ccccc3N(c3ccc4c(c3)oc3ccccc34)c3ccc4ccc5ccc6nc(-c7ccccc7)oc6c5c4c3)c2)cc1]

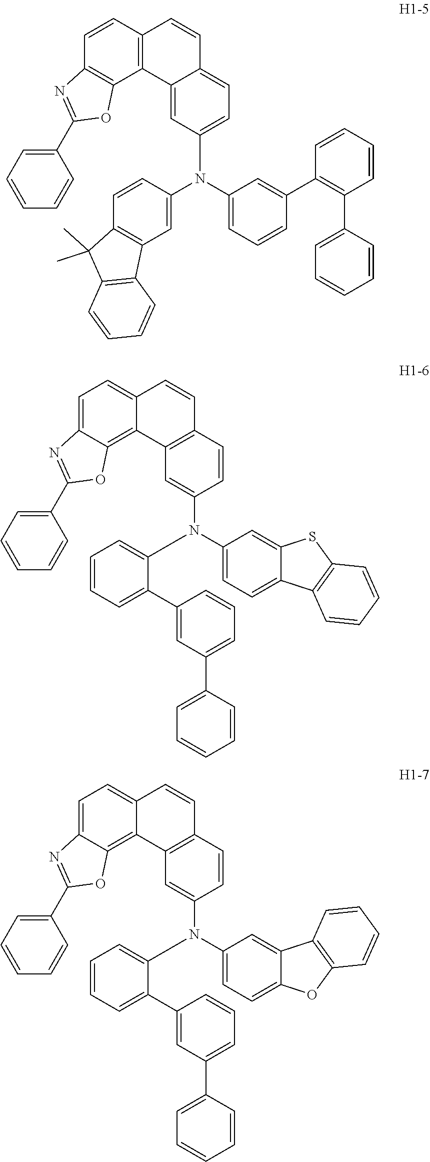

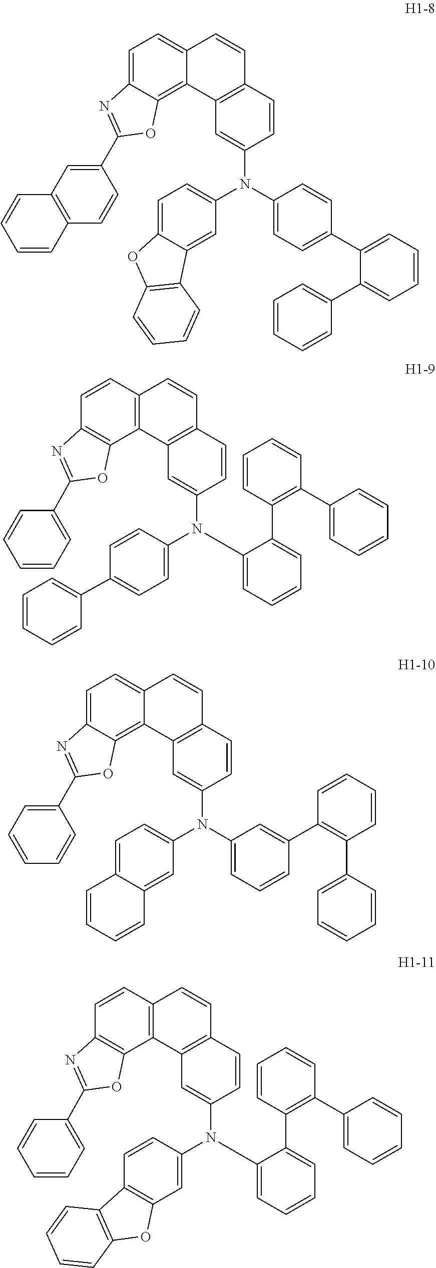

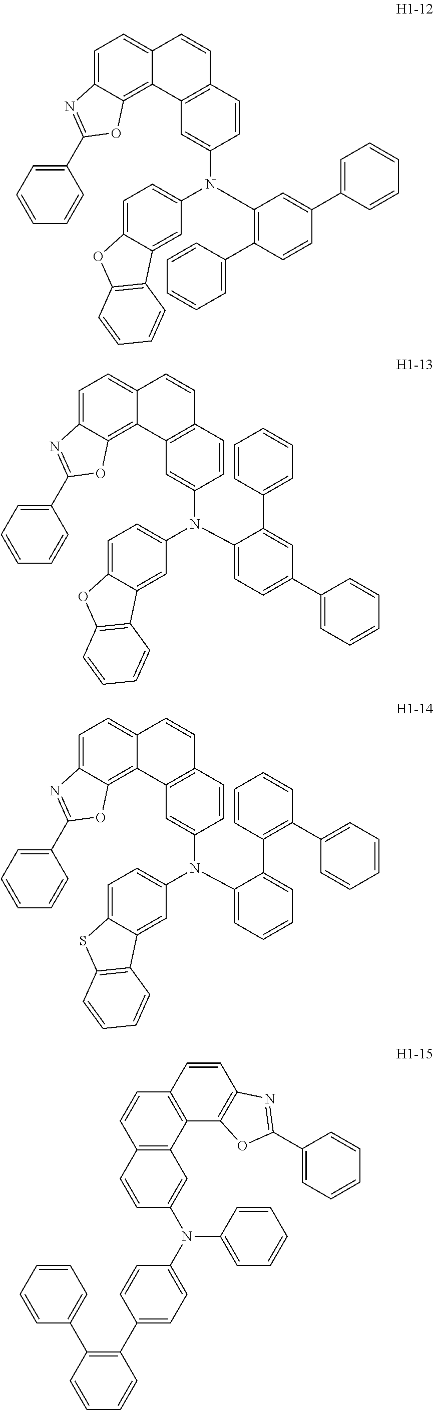

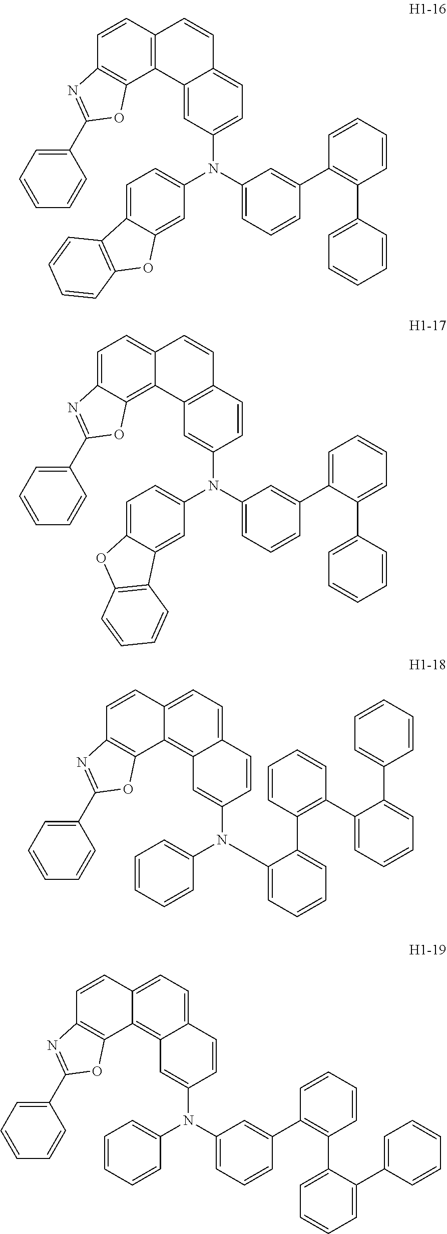

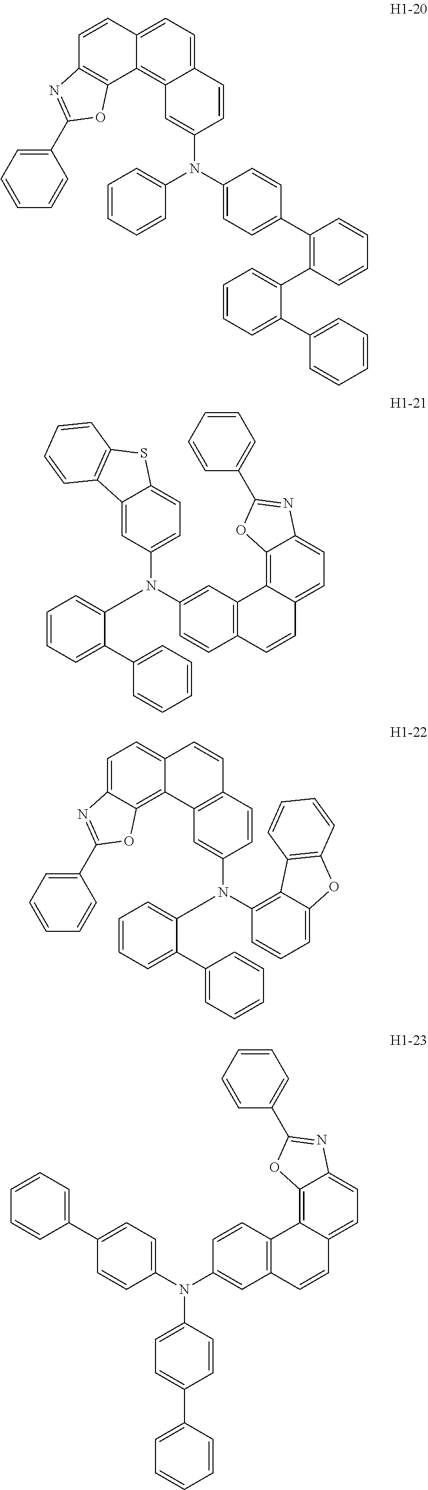

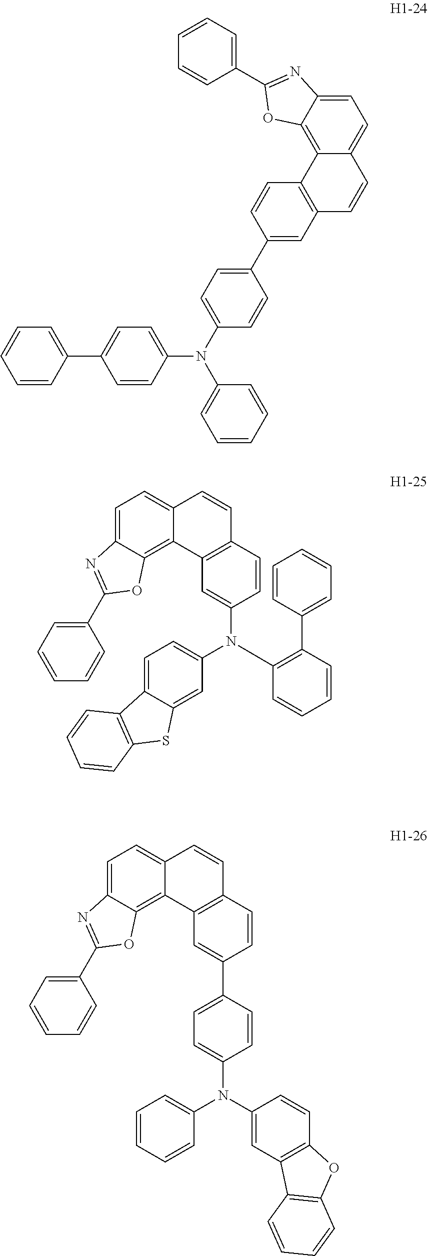 [SMILES: c1ccc(-c2ccc(N(c3ccccc3)c3ccc(-c4ccc5c(ccc6ccc7nc(-c8ccccc8)oc7c65)c4)cc3)cc2)cc1 ; c1ccc(-c2nc3ccc4ccc5ccc(N(c6ccc7c(c6)sc6ccccc67)c6ccccc6-c6ccccc6)cc5c4c3o2)cc1 ; c1ccc(-c2nc3ccc4ccc5ccc(-c6ccc(N(c7ccccc7)c7ccc8oc9ccccc9c8c7)cc6)cc5c4c3o2)cc1]

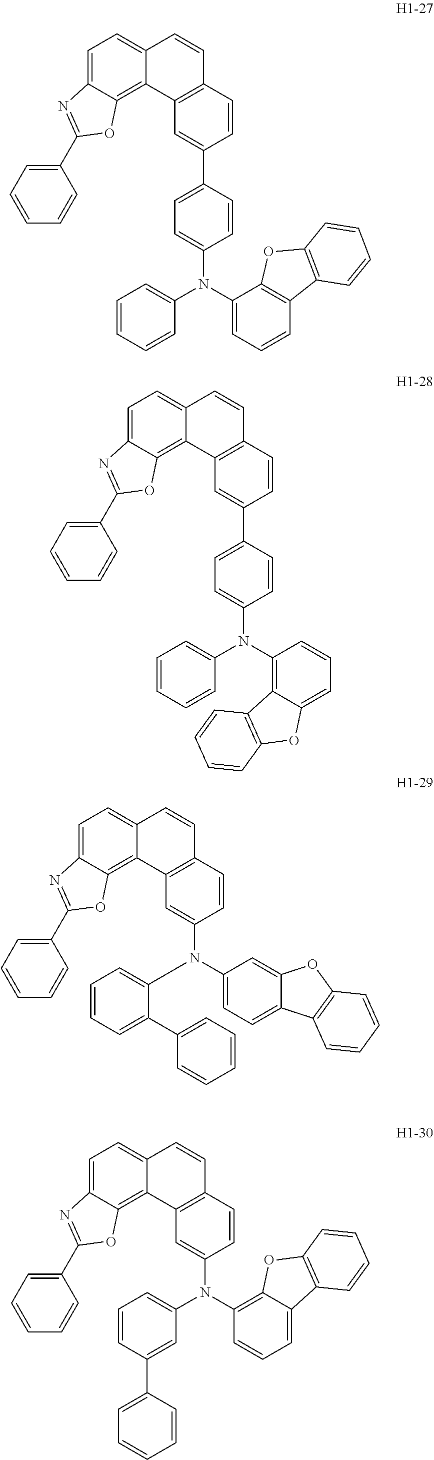

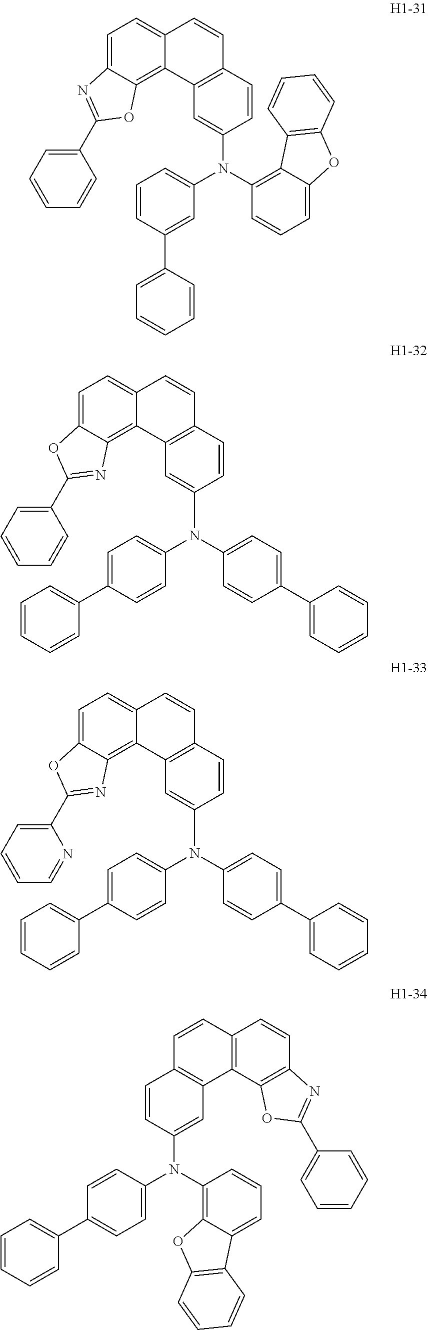

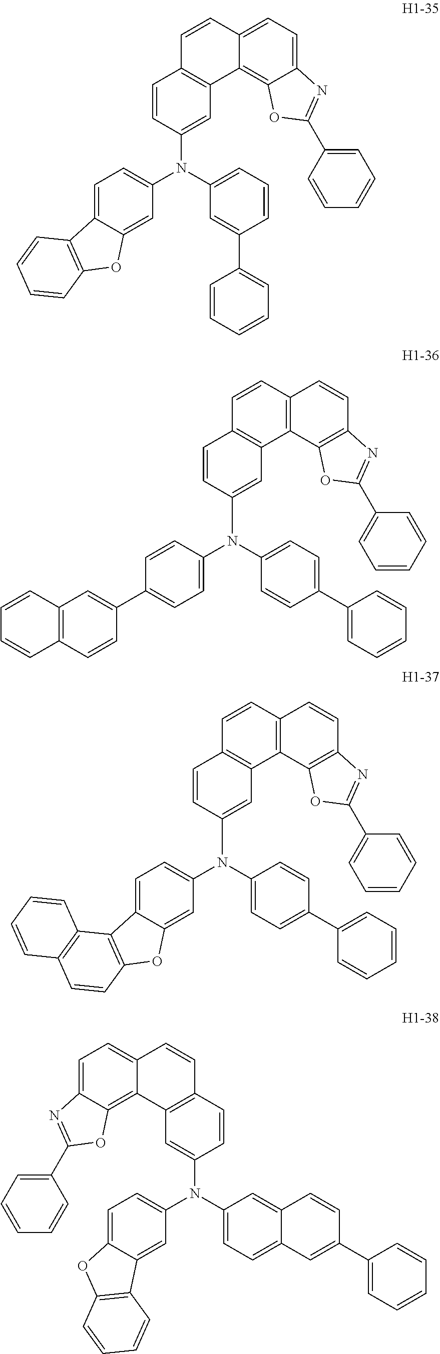 [SMILES: c1ccc(-c2cccc(N(c3ccc4c(c3)oc3ccccc34)c3ccc4ccc5ccc6nc(-c7ccccc7)oc6c5c4c3)c2)cc1 ; c1ccc(-c2ccc(N(c3ccc(-c4ccc5ccccc5c4)cc3)c3ccc4ccc5ccc6nc(-c7ccccc7)oc6c5c4c3)cc2)cc1 ; c1ccc(-c2ccc(N(c3ccc4c(c3)oc3ccc5ccccc5c34)c3ccc4ccc5ccc6nc(-c7ccccc7)oc6c5c4c3)cc2)cc1 ; c1ccc(-c2ccc3cc(N(c4ccc5oc6ccccc6c5c4)c4ccc5ccc6ccc7nc(-c8ccccc8)oc7c6c5c4)ccc3c2)cc1]

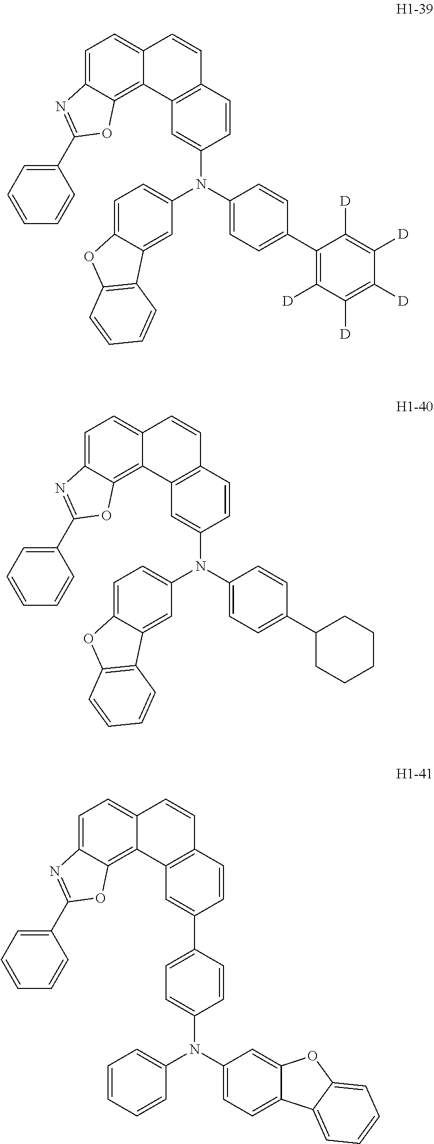 [SMILES: [2H]c1c([2H])c([2H])c(-c2ccc(N(c3ccc4oc5ccccc5c4c3)c3ccc4ccc5ccc6nc(-c7ccccc7)oc6c5c4c3)cc2)c([2H])c1[2H] ; c1ccc(-c2nc3ccc4ccc5ccc(N(c6ccc(C7CCCCC7)cc6)c6ccc7oc8ccccc8c7c6)cc5c4c3o2)cc1 ; c1ccc(-c2nc3ccc4ccc5ccc(-c6ccc(N(c7ccccc7)c7ccc8c(c7)oc7ccccc78)cc6)cc5c4c3o2)cc1]

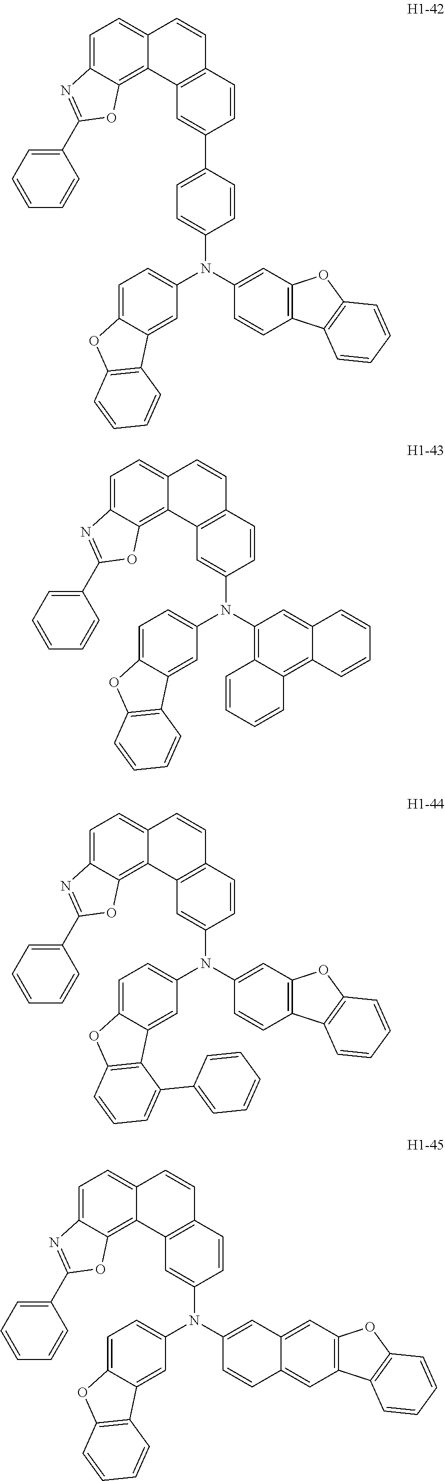

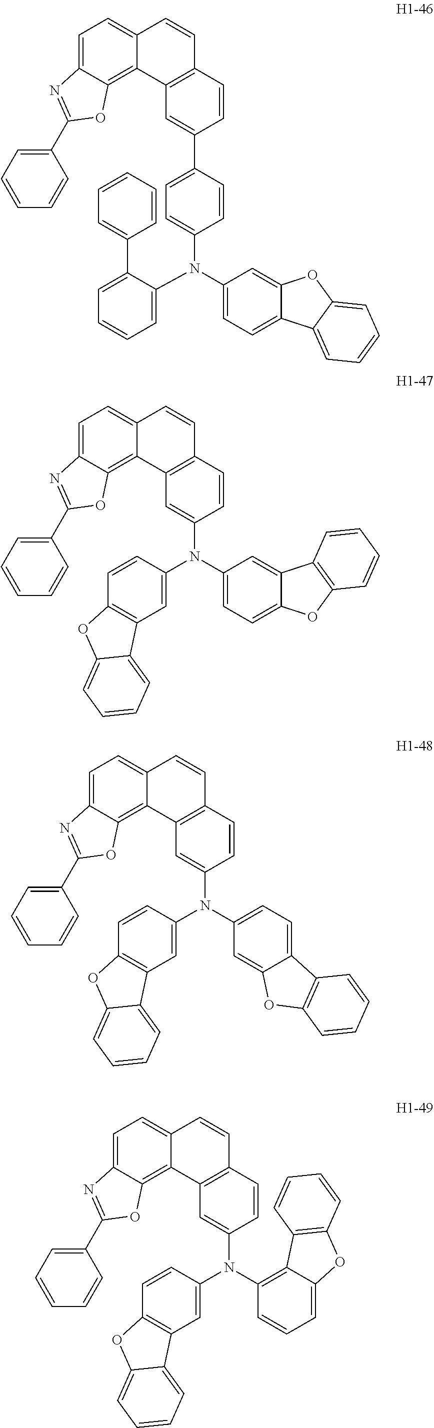

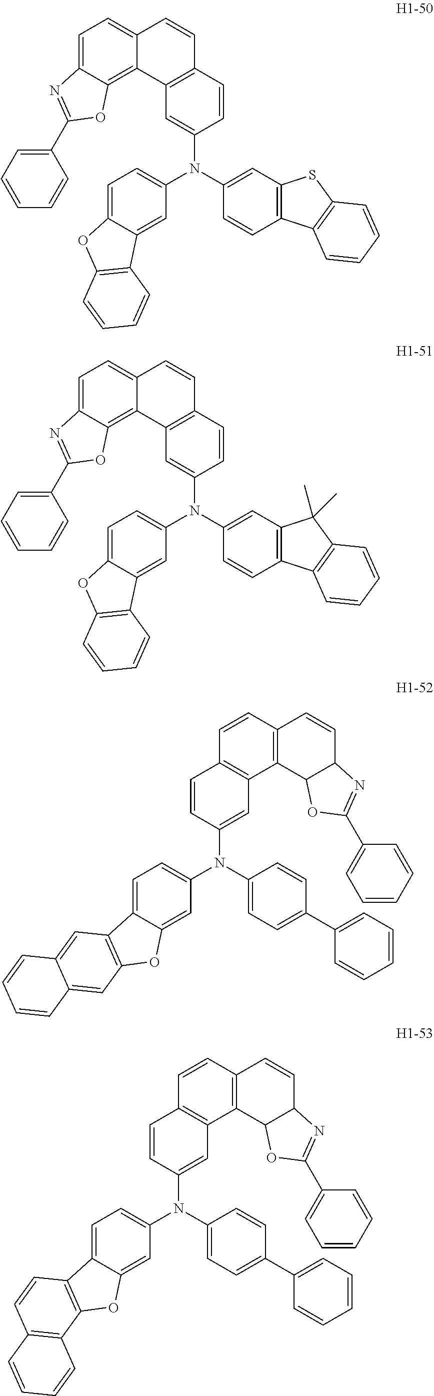

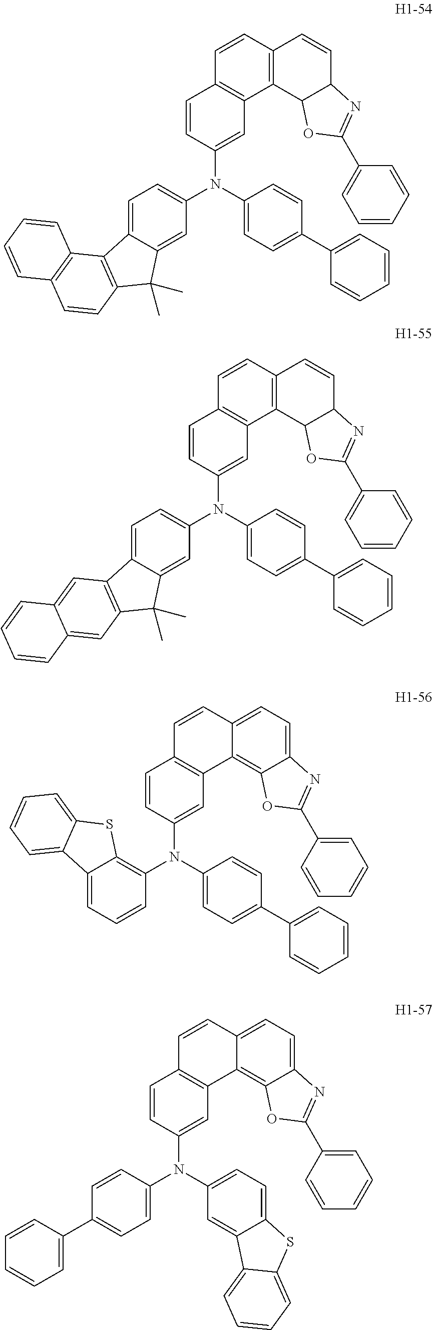

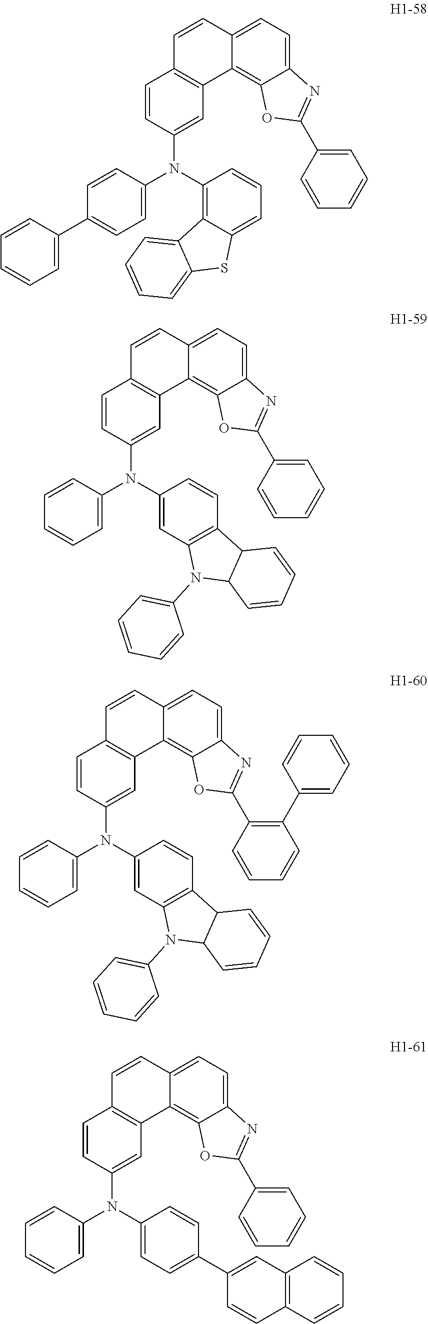

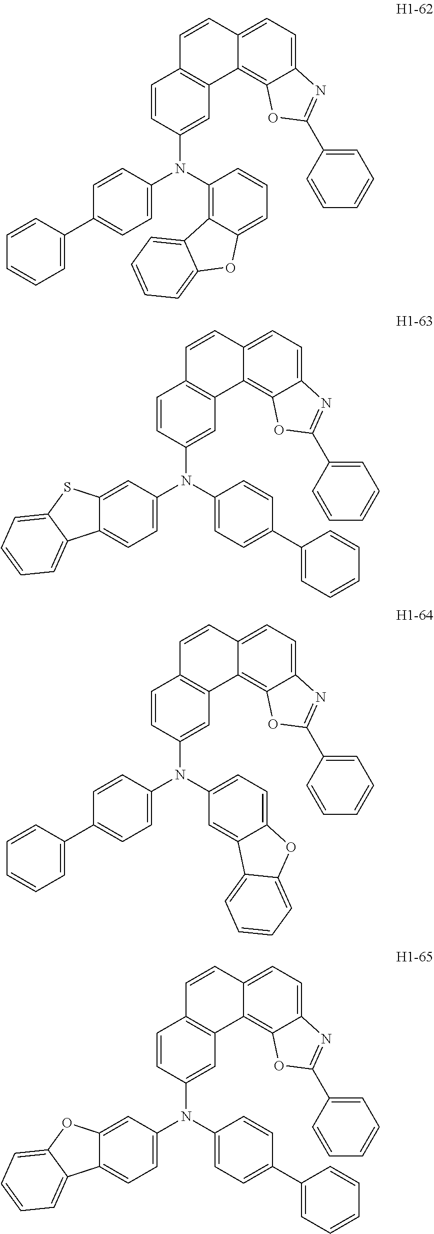

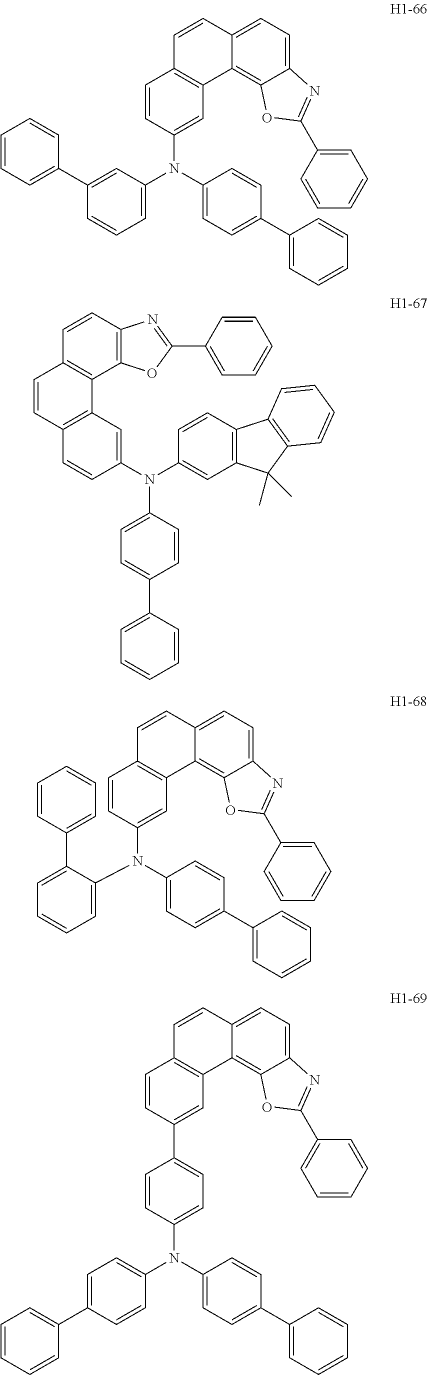

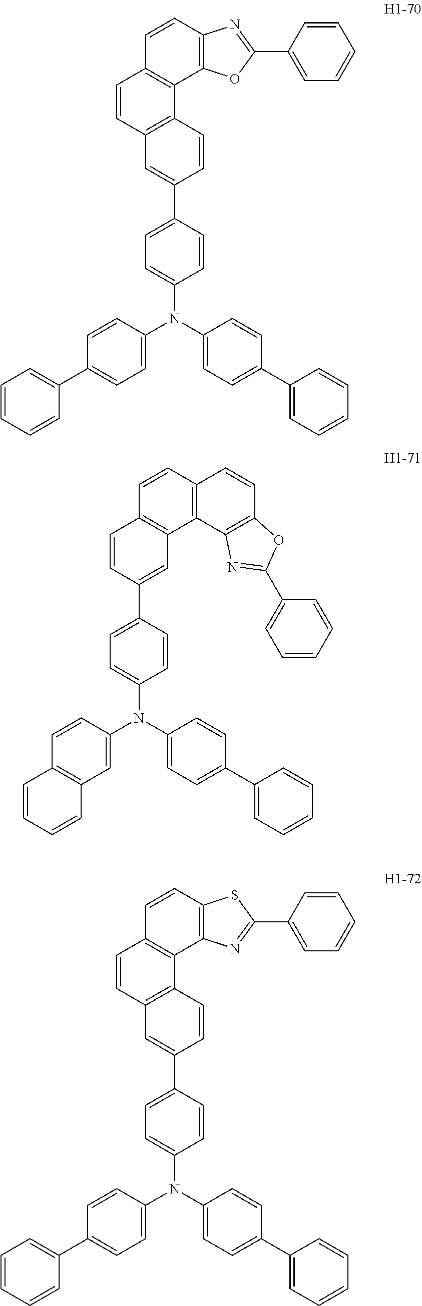

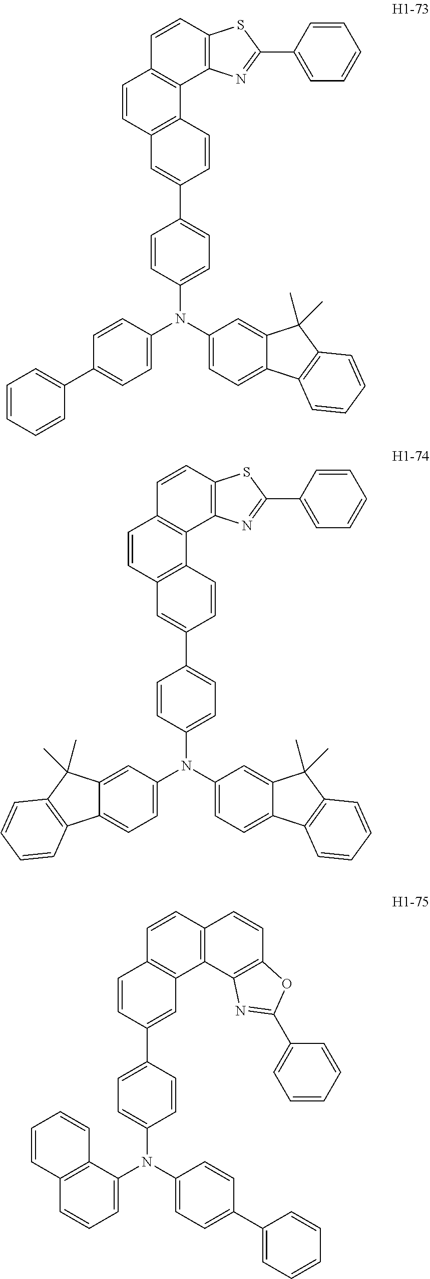

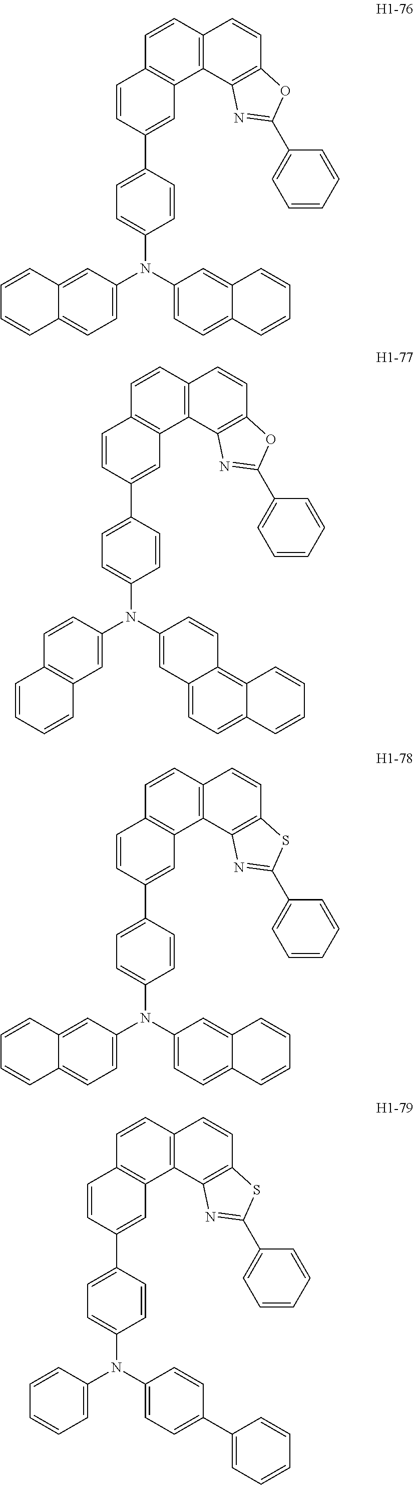

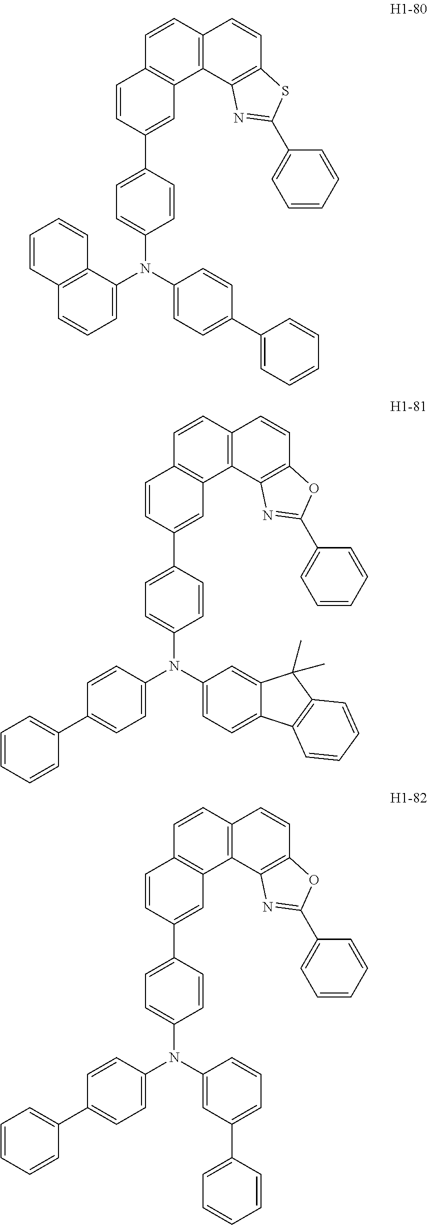

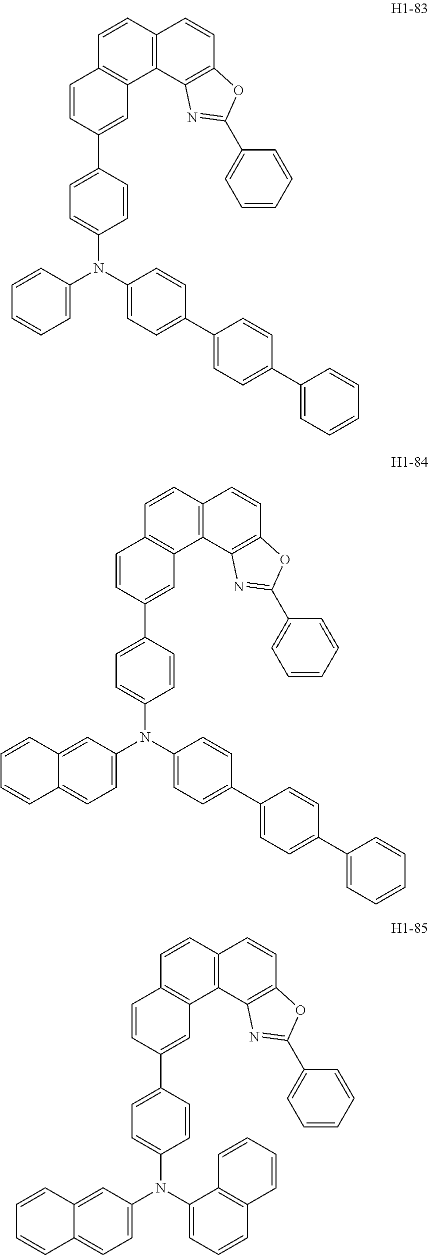 [SMILES: c1ccc(-c2ccc(-c3ccc(N(c4ccccc4)c4ccc(-c5ccc6ccc7ccc8oc(-c9ccccc9)nc8c7c6c5)cc4)cc3)cc2)cc1 ; c1ccc(-c2ccc(-c3ccc(N(c4ccc(-c5ccc6ccc7ccc8oc(-c9ccccc9)nc8c7c6c5)cc4)c4ccc5ccccc5c4)cc3)cc2)cc1 ; c1ccc(-c2nc3c(ccc4ccc5ccc(-c6ccc(N(c7ccc8ccccc8c7)c7cccc8ccccc78)cc6)cc5c43)o2)cc1]

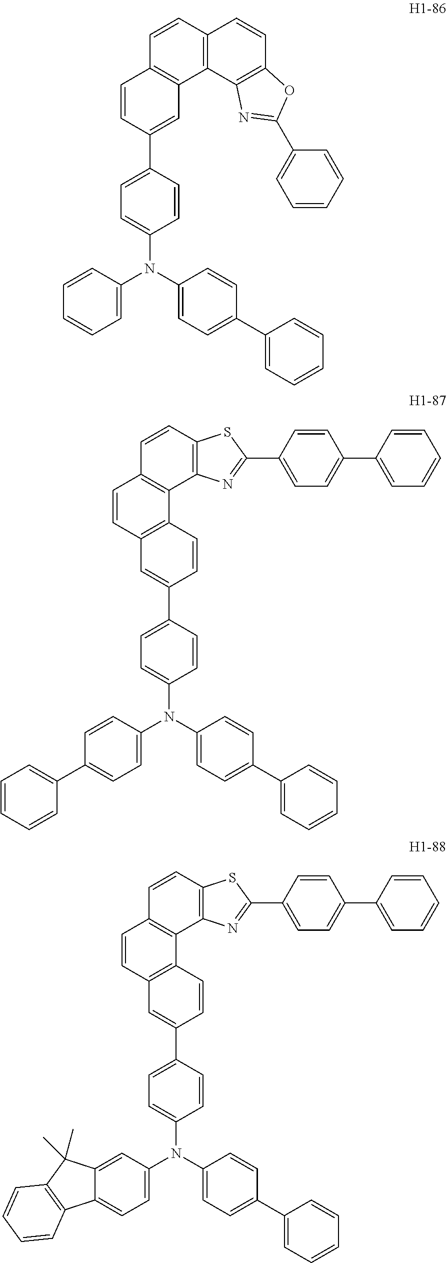

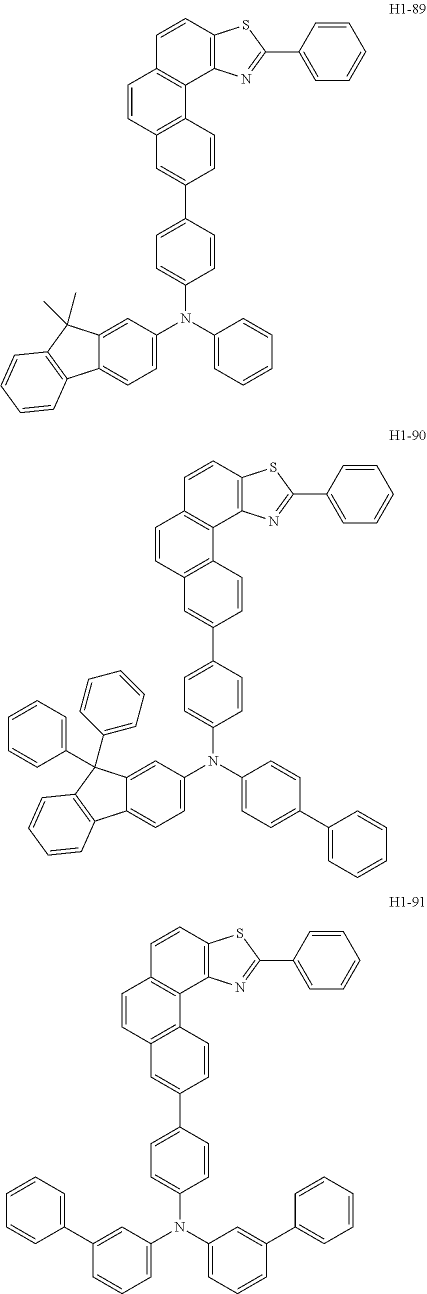 [SMILES: CC1(C)c2ccccc2-c2ccc(N(c3ccccc3)c3ccc(-c4ccc5c(ccc6ccc7sc(-c8ccccc8)nc7c65)c4)cc3)cc21 ; c1ccc(-c2ccc(N(c3ccc(-c4ccc5c(ccc6ccc7sc(-c8ccccc8)nc7c65)c4)cc3)c3ccc4c(c3)C(c3ccccc3)(c3ccccc3)c3ccccc3-4)cc2)cc1 ; c1ccc(-c2cccc(N(c3ccc(-c4ccc5c(ccc6ccc7sc(-c8ccccc8)nc7c65)c4)cc3)c3cccc(-c4ccccc4)c3)c2)cc1]

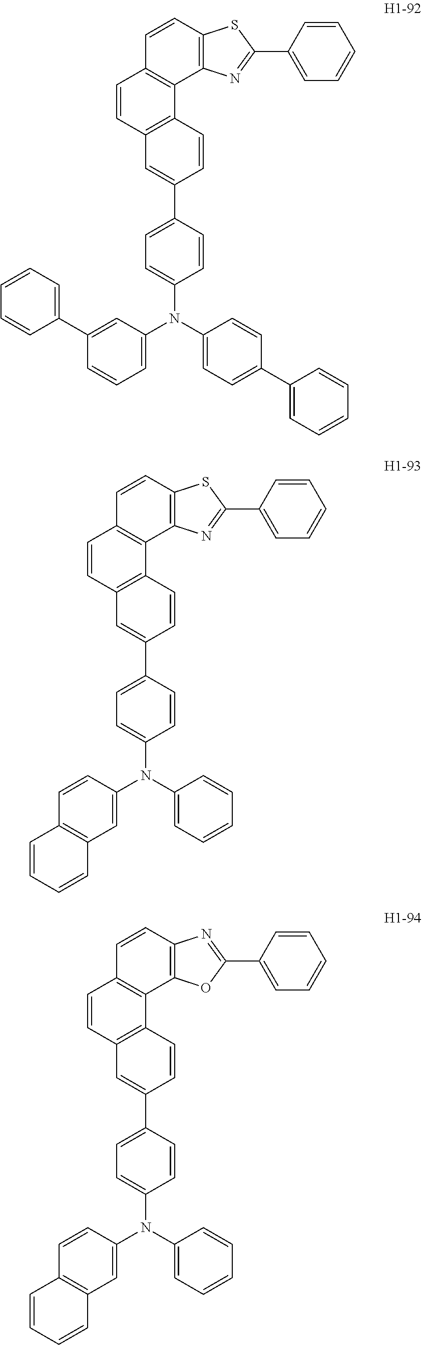

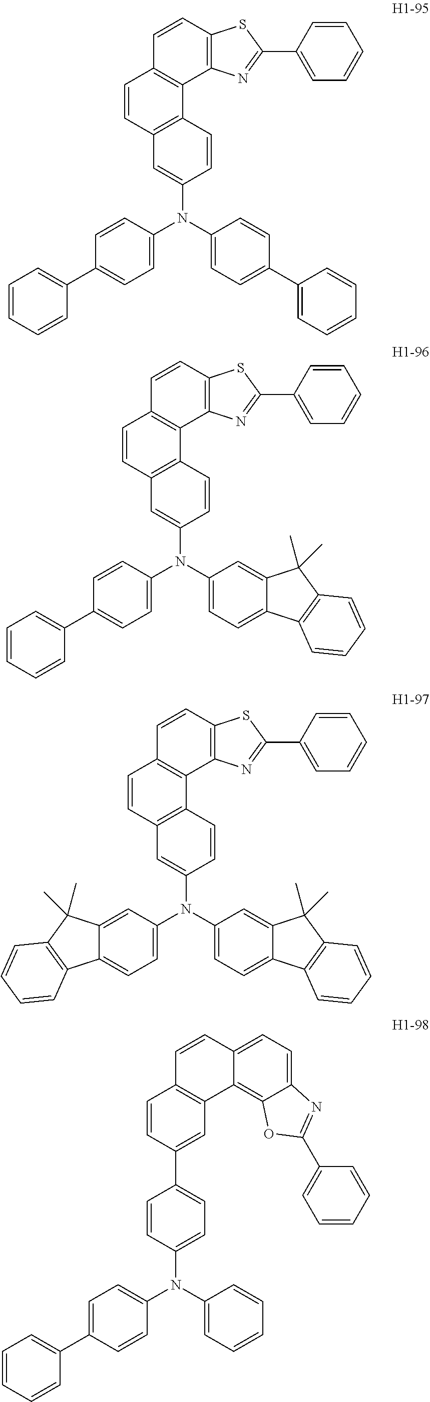

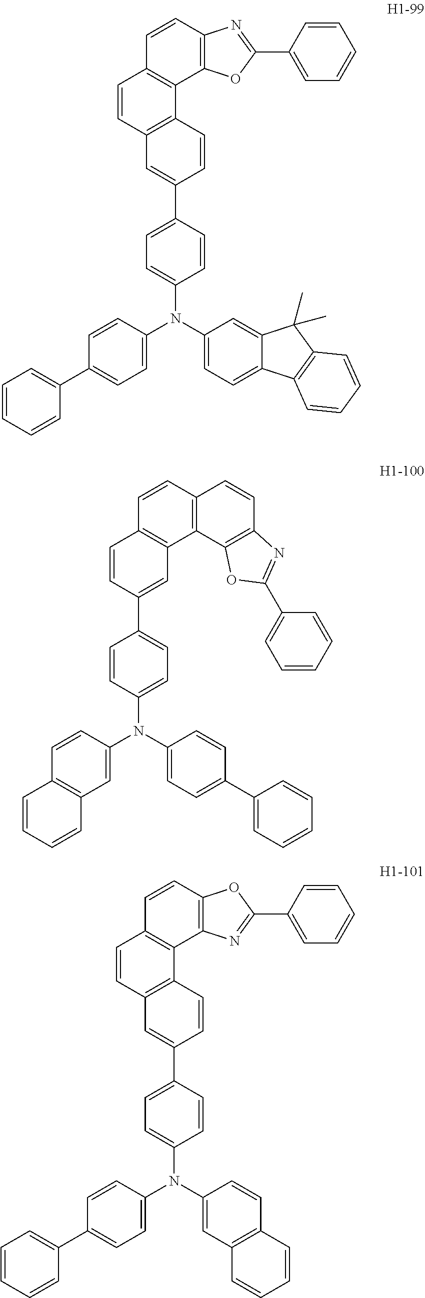

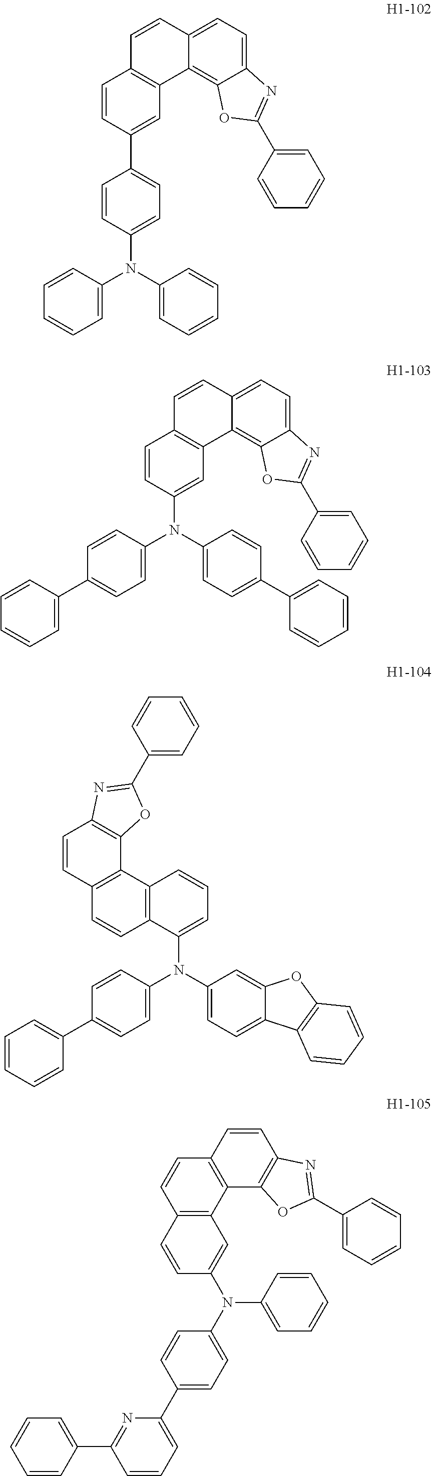 [SMILES: c1ccc(-c2nc3ccc4ccc5ccc(-c6ccc(N(c7ccccc7)c7ccccc7)cc6)cc5c4c3o2)cc1 ; c1ccc(-c2ccc(N(c3ccc(-c4ccccc4)cc3)c3ccc4ccc5ccc6nc(-c7ccccc7)oc6c5c4c3)cc2)cc1 ; c1ccc(-c2ccc(N(c3ccc4c(c3)oc3ccccc34)c3cccc4c3ccc3ccc5nc(-c6ccccc6)oc5c34)cc2)cc1 ; c1ccc(-c2cccc(-c3ccc(N(c4ccccc4)c4ccc5ccc6ccc7nc(-c8ccccc8)oc7c6c5c4)cc3)n2)cc1]

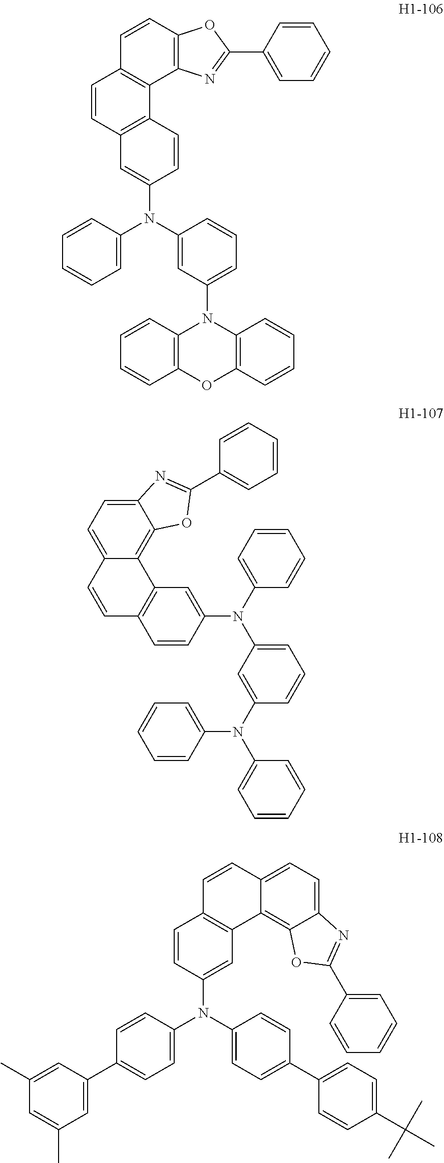

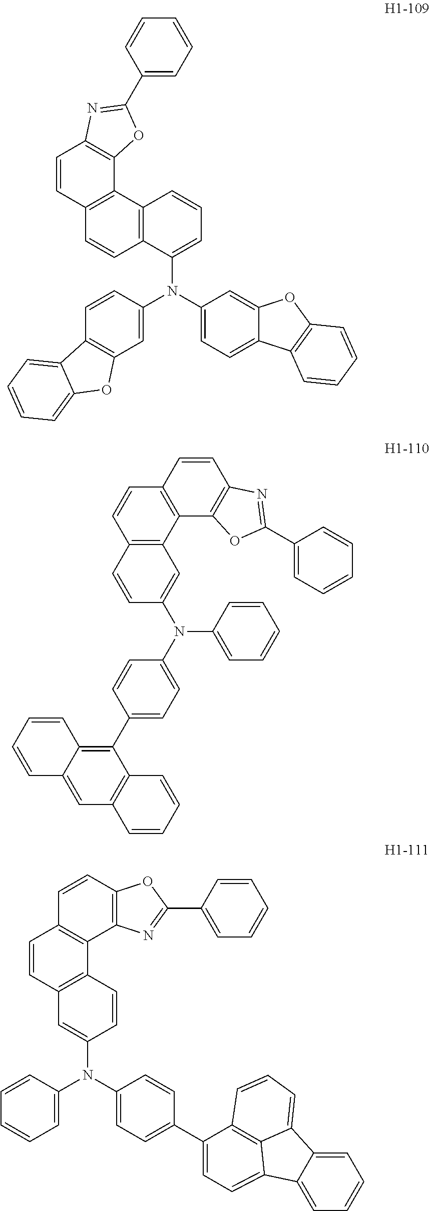 [SMILES: c1ccc(-c2nc3ccc4ccc5c(N(c6ccc7c(c6)oc6ccccc67)c6ccc7c(c6)oc6ccccc67)cccc5c4c3o2)cc1 ; c1ccc(-c2nc3ccc4ccc5ccc(N(c6ccccc6)c6ccc(-c7c8ccccc8cc8ccccc78)cc6)cc5c4c3o2)cc1 ; c1ccc(-c2nc3c(ccc4ccc5cc(N(c6ccccc6)c6ccc(-c7ccc8c9c(cccc79)-c7ccccc7-8)cc6)ccc5c43)o2)cc1]

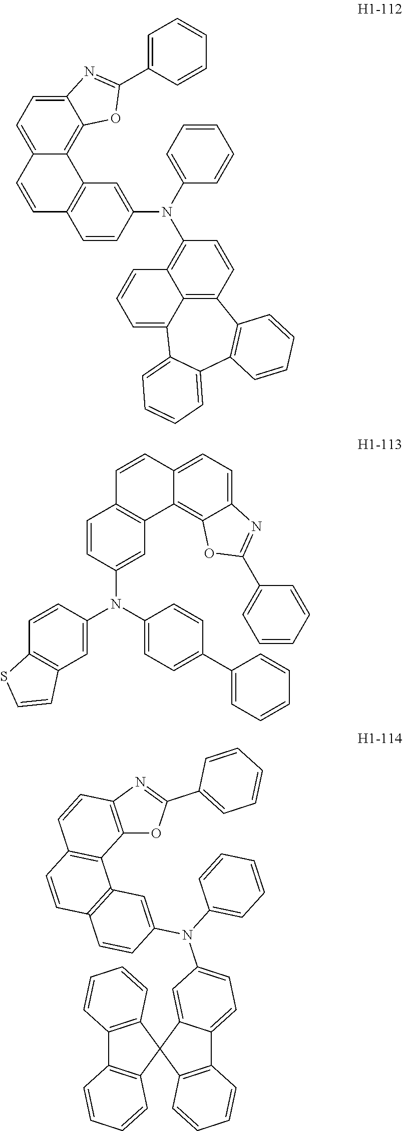

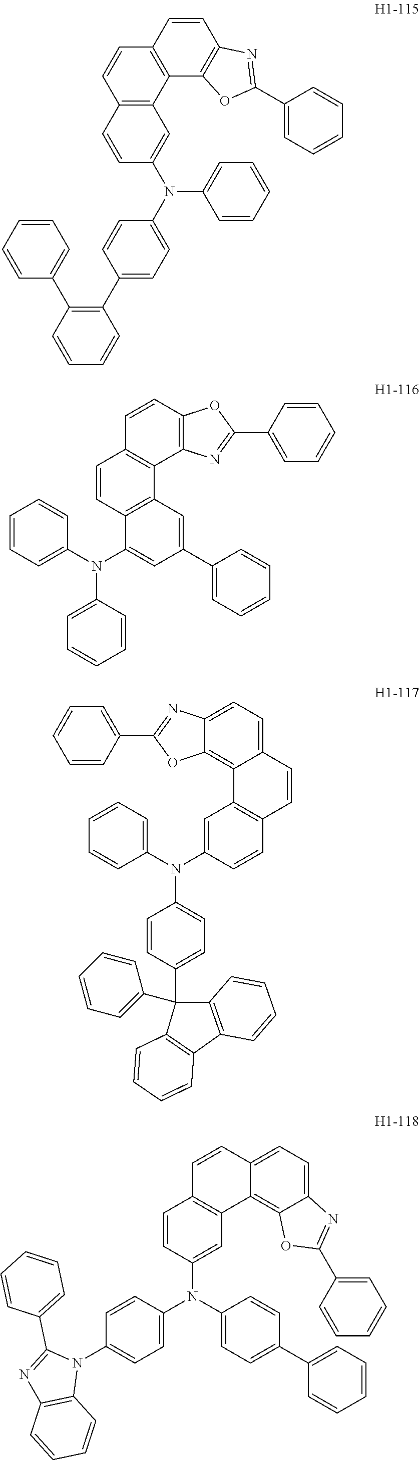

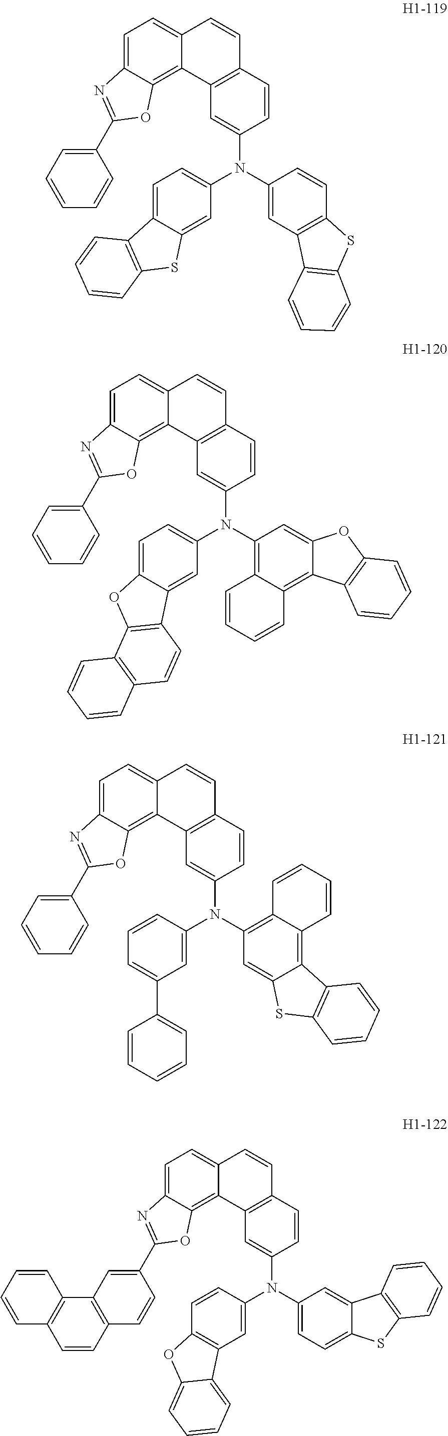 [SMILES: c1ccc(-c2nc3ccc4ccc5ccc(N(c6ccc7c(c6)sc6ccccc67)c6ccc7sc8ccccc8c7c6)cc5c4c3o2)cc1 ; c1ccc(-c2nc3ccc4ccc5ccc(N(c6ccc7oc8c9ccccc9ccc8c7c6)c6cc7oc8ccccc8c7c7ccccc67)cc5c4c3o2)cc1 ; c1ccc(-c2cccc(N(c3ccc4ccc5ccc6nc(-c7ccccc7)oc6c5c4c3)c3cc4sc5ccccc5c4c4ccccc34)c2)cc1 ; c1ccc2c(c1)ccc1ccc(-c3nc4ccc5ccc6ccc(N(c7ccc8oc9ccccc9c8c7)c7ccc8sc9ccccc9c8c7)cc6c5c4o3)cc12]

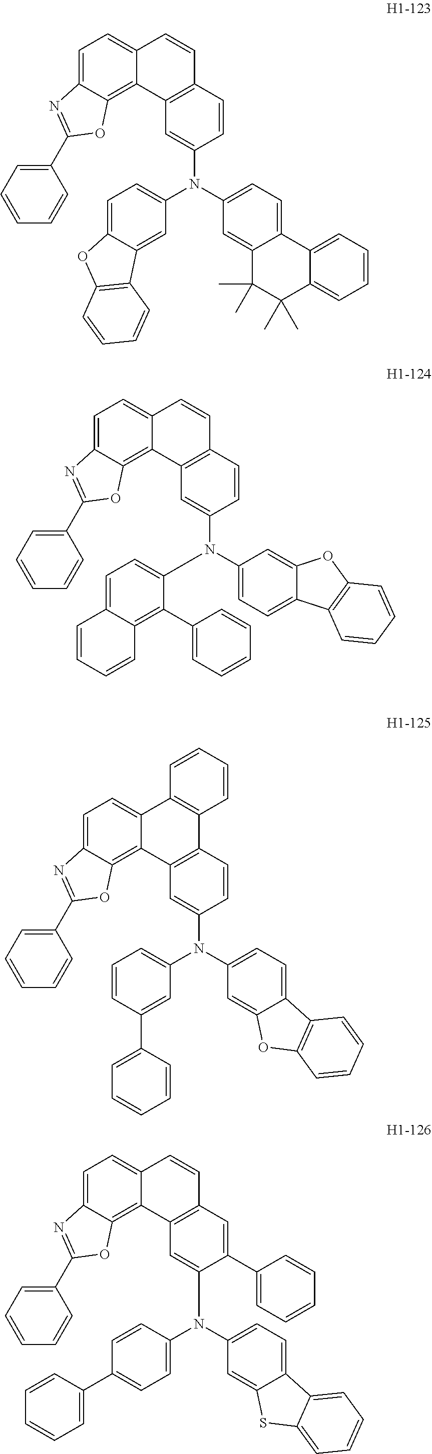 [SMILES: CC1(C)c2ccccc2-c2ccc(N(c3ccc4oc5ccccc5c4c3)c3ccc4ccc5ccc6nc(-c7ccccc7)oc6c5c4c3)cc2C1(C)C ; c1ccc(-c2nc3ccc4ccc5ccc(N(c6ccc7c(c6)oc6ccccc67)c6ccc7ccccc7c6-c6ccccc6)cc5c4c3o2)cc1 ; c1ccc(-c2cccc(N(c3ccc4c(c3)oc3ccccc34)c3ccc4c5ccccc5c5ccc6nc(-c7ccccc7)oc6c5c4c3)c2)cc1 ; c1ccc(-c2ccc(N(c3ccc4c(c3)sc3ccccc34)c3cc4c(ccc5ccc6nc(-c7ccccc7)oc6c54)cc3-c3ccccc3)cc2)cc1]

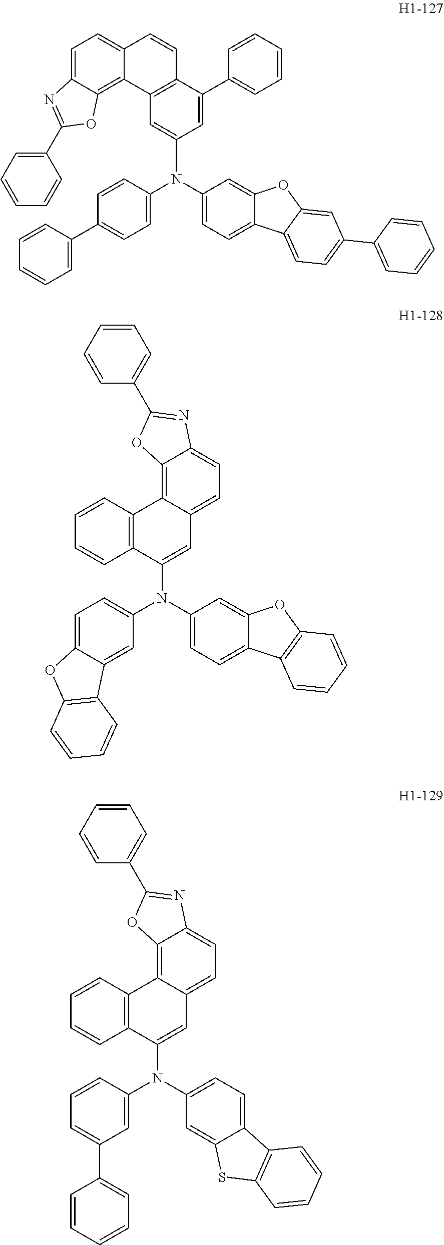 [SMILES: c1ccc(-c2ccc(N(c3ccc4c(c3)oc3cc(-c5ccccc5)ccc34)c3cc(-c4ccccc4)c4ccc5ccc6nc(-c7ccccc7)oc6c5c4c3)cc2)cc1 ; c1ccc(-c2nc3ccc4cc(N(c5ccc6c(c5)oc5ccccc56)c5ccc6oc7ccccc7c6c5)c5ccccc5c4c3o2)cc1 ; c1ccc(-c2cccc(N(c3ccc4c(c3)sc3ccccc34)c3cc4ccc5nc(-c6ccccc6)oc5c4c4ccccc34)c2)cc1]

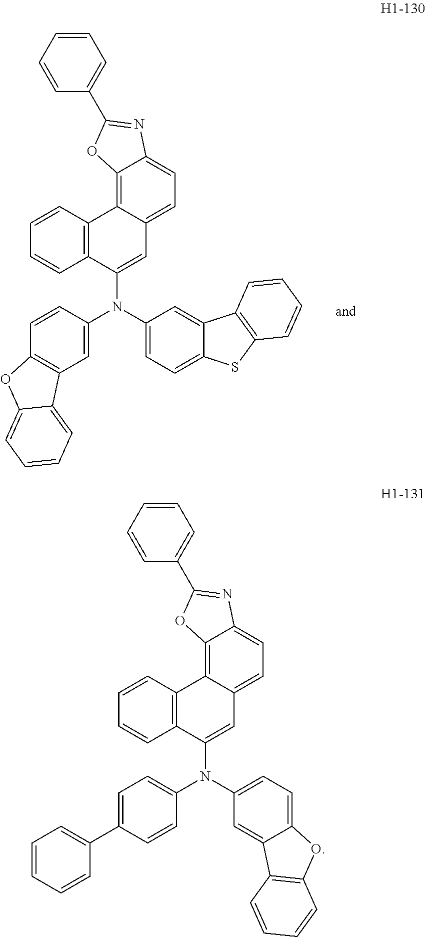 [SMILES: c1ccc(-c2nc3ccc4cc(N(c5ccc6oc7ccccc7c6c5)c5ccc6sc7ccccc7c6c5)c5ccccc5c4c3o2)cc1 ; c1ccc(-c2ccc(N(c3ccc4oc5ccccc5c4c3)c3cc4ccc5nc(-c6ccccc6)oc5c4c4ccccc34)cc2)cc1]

8. An organic electroluminescent material comprising a compound represented by the following Formula 1 and a compound represented by the following Formula 3: 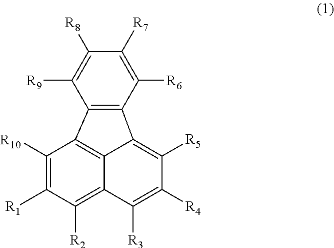
wherein in Formula 1,
R₁ and R₂ are linked to each other to form a substituted or unsubstituted fused ring(s);
R₃ to R₁₀ each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, or a substituted or unsubstituted tri(C6-C30)arylsilyl; and
at least one of the substituent(s) of the fused ring(s) and R₃ to R₁₀ represents a substituted or unsubstituted (3- to 30-membered)heteroaryl comprising at least one N, and 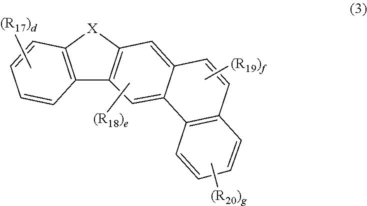
wherein in Formula 3,
X represents O, S, CR₂₁R₂₂, NR₂₃, or Se;
R₂₁ to R₂₃ each independently represent hydrogen, deuterium, a halogen, a substituted or unsubstituted (C1-C30)alkyl, a substituted or unsubstituted (C6-C30)aryl, or a substituted or unsubstituted (3- to 30-membered)heteroaryl; or may be linked to an adjacent substituent(s) to form a ring(s);
R₁₇ to R₂₀ each independently represent hydrogen, deuterium, a halogen, a substituted or unsubstituted (C1-C30)alkyl, a substituted or unsubstituted (C6-C30)aryl, 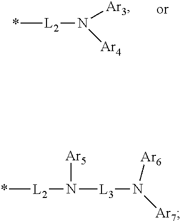
with a proviso that at least one of R₁₇ to R₂₀ is 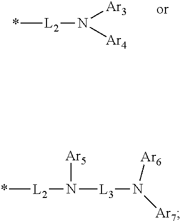
L₂ and L₃ each independently represent a single bond, a substituted or unsubstituted (C6-C30)arylene, a substituted or unsubstituted (C3-C30)cycloalkylene, or a substituted or unsubstituted (3- to 30-membered)heteroarylene;
Ar₃ to Ar₇ each independently represent a substituted or unsubstituted (C6-C30)aryl or a substituted or unsubstituted (3- to 30-membered)heteroaryl;
d and g represent an integer of 1 to 4, e and f represent an integer of 1 or 2, where if d to g are an integer of 2 or more, each of R₁₇ to each of R₂₀ may be the same as or different from each other; and
* represents a site linked to Formula 3.

9. The organic electroluminescent compound according to claim 8, wherein the compound represented by Formula 3 is selected from the following compounds:

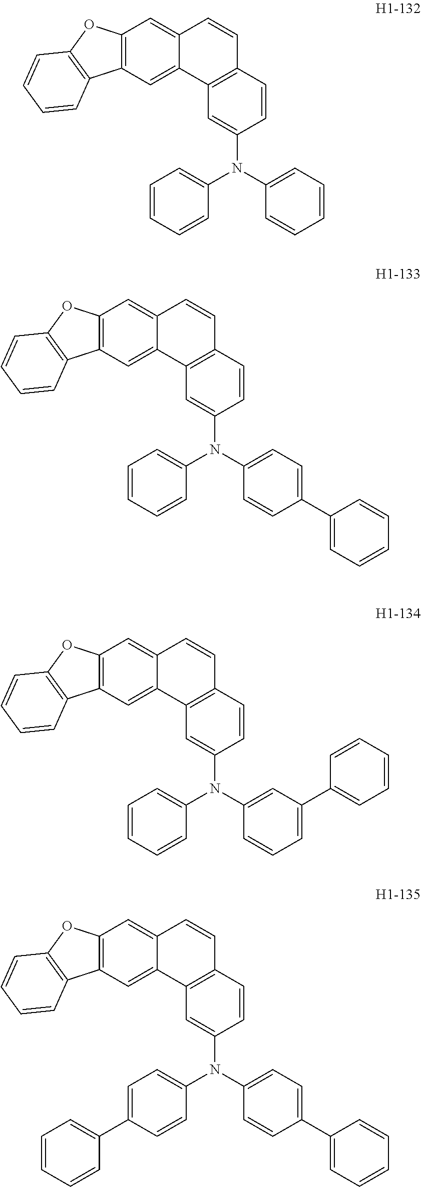 [SMILES: c1ccc(N(c2ccccc2)c2ccc3ccc4cc5oc6ccccc6c5cc4c3c2)cc1 ; c1ccc(-c2ccc(N(c3ccccc3)c3ccc4ccc5cc6oc7ccccc7c6cc5c4c3)cc2)cc1 ; c1ccc(-c2cccc(N(c3ccccc3)c3ccc4ccc5cc6oc7ccccc7c6cc5c4c3)c2)cc1 ; c1ccc(-c2ccc(N(c3ccc(-c4ccccc4)cc3)c3ccc4ccc5cc6oc7ccccc7c6cc5c4c3)cc2)cc1]

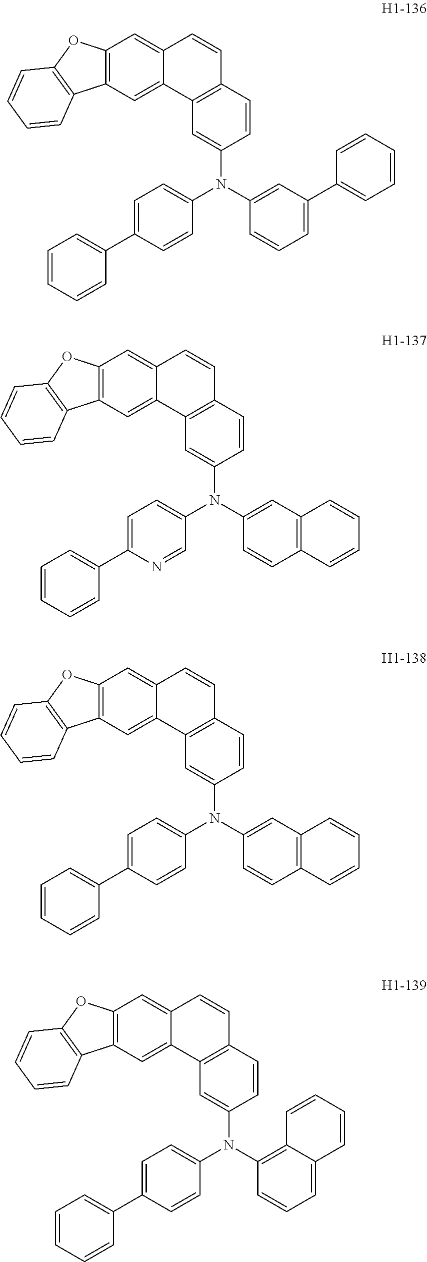 [SMILES: c1ccc(-c2ccc(N(c3cccc(-c4ccccc4)c3)c3ccc4ccc5cc6oc7ccccc7c6cc5c4c3)cc2)cc1 ; c1ccc(-c2ccc(N(c3ccc4ccccc4c3)c3ccc4ccc5cc6oc7ccccc7c6cc5c4c3)cn2)cc1 ; c1ccc(-c2ccc(N(c3ccc4ccccc4c3)c3ccc4ccc5cc6oc7ccccc7c6cc5c4c3)cc2)cc1 ; c1ccc(-c2ccc(N(c3ccc4ccc5cc6oc7ccccc7c6cc5c4c3)c3cccc4ccccc34)cc2)cc1]

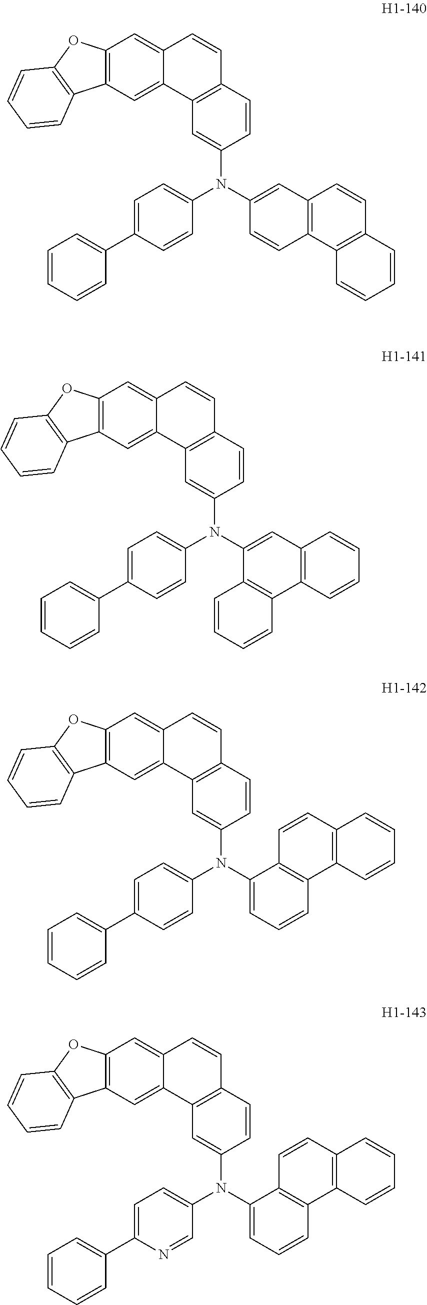 [SMILES: c1ccc(-c2ccc(N(c3ccc4c(ccc5ccccc54)c3)c3ccc4ccc5cc6oc7ccccc7c6cc5c4c3)cc2)cc1 ; c1ccc(-c2ccc(N(c3ccc4ccc5cc6oc7ccccc7c6cc5c4c3)c3cc4ccccc4c4ccccc34)cc2)cc1 ; c1ccc(-c2ccc(N(c3ccc4ccc5cc6oc7ccccc7c6cc5c4c3)c3cccc4c3ccc3ccccc34)cc2)cc1 ; c1ccc(-c2ccc(N(c3ccc4ccc5cc6oc7ccccc7c6cc5c4c3)c3cccc4c3ccc3ccccc34)cn2)cc1]

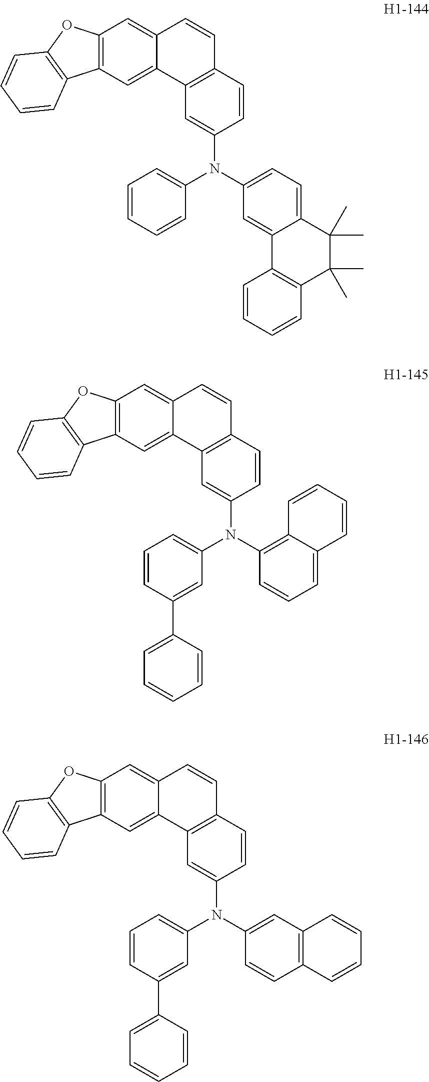 [SMILES: CC1(C)c2ccccc2-c2cc(N(c3ccccc3)c3ccc4ccc5cc6oc7ccccc7c6cc5c4c3)ccc2C1(C)C ; c1ccc(-c2cccc(N(c3ccc4ccc5cc6oc7ccccc7c6cc5c4c3)c3cccc4ccccc34)c2)cc1 ; c1ccc(-c2cccc(N(c3ccc4ccccc4c3)c3ccc4ccc5cc6oc7ccccc7c6cc5c4c3)c2)cc1]

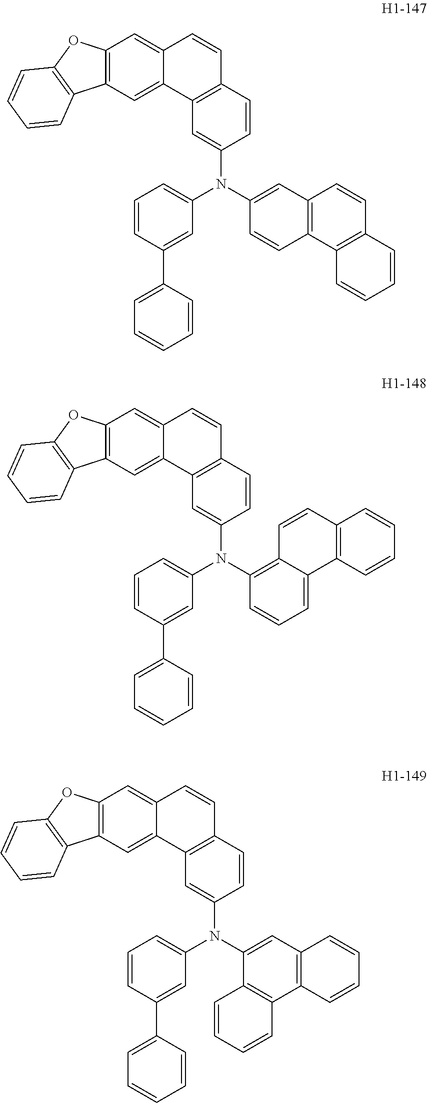 [SMILES: c1ccc(-c2cccc(N(c3ccc4c(ccc5ccccc54)c3)c3ccc4ccc5cc6oc7ccccc7c6cc5c4c3)c2)cc1 ; c1ccc(-c2cccc(N(c3ccc4ccc5cc6oc7ccccc7c6cc5c4c3)c3cccc4c3ccc3ccccc34)c2)cc1 ; c1ccc(-c2cccc(N(c3ccc4ccc5cc6oc7ccccc7c6cc5c4c3)c3cc4ccccc4c4ccccc34)c2)cc1]

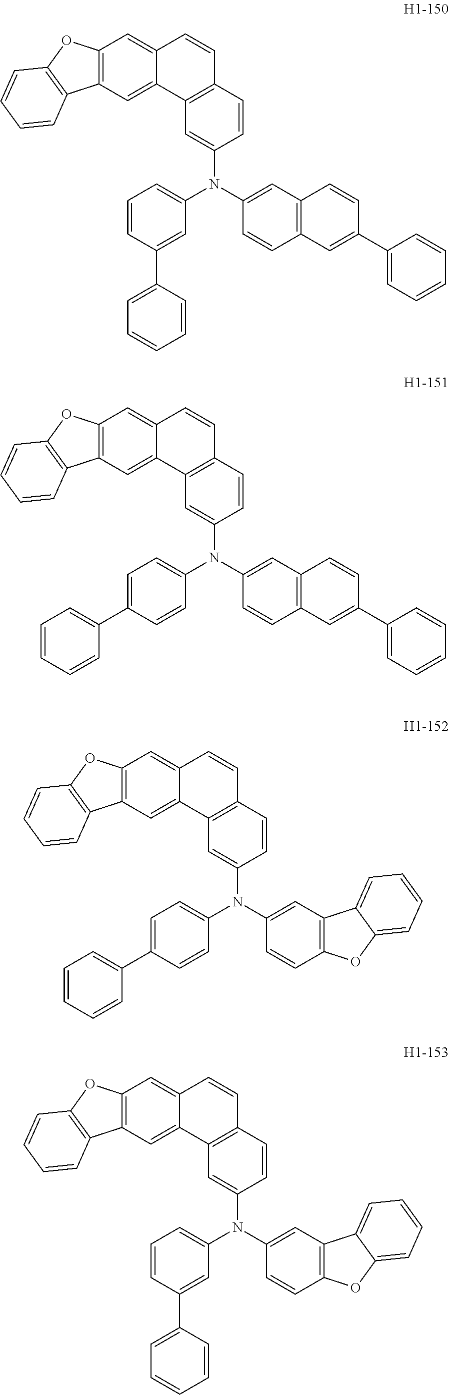 [SMILES: c1ccc(-c2cccc(N(c3ccc4cc(-c5ccccc5)ccc4c3)c3ccc4ccc5cc6oc7ccccc7c6cc5c4c3)c2)cc1 ; c1ccc(-c2ccc(N(c3ccc4cc(-c5ccccc5)ccc4c3)c3ccc4ccc5cc6oc7ccccc7c6cc5c4c3)cc2)cc1 ; c1ccc(-c2ccc(N(c3ccc4ccc5cc6oc7ccccc7c6cc5c4c3)c3ccc4oc5ccccc5c4c3)cc2)cc1 ; c1ccc(-c2cccc(N(c3ccc4ccc5cc6oc7ccccc7c6cc5c4c3)c3ccc4oc5ccccc5c4c3)c2)cc1]

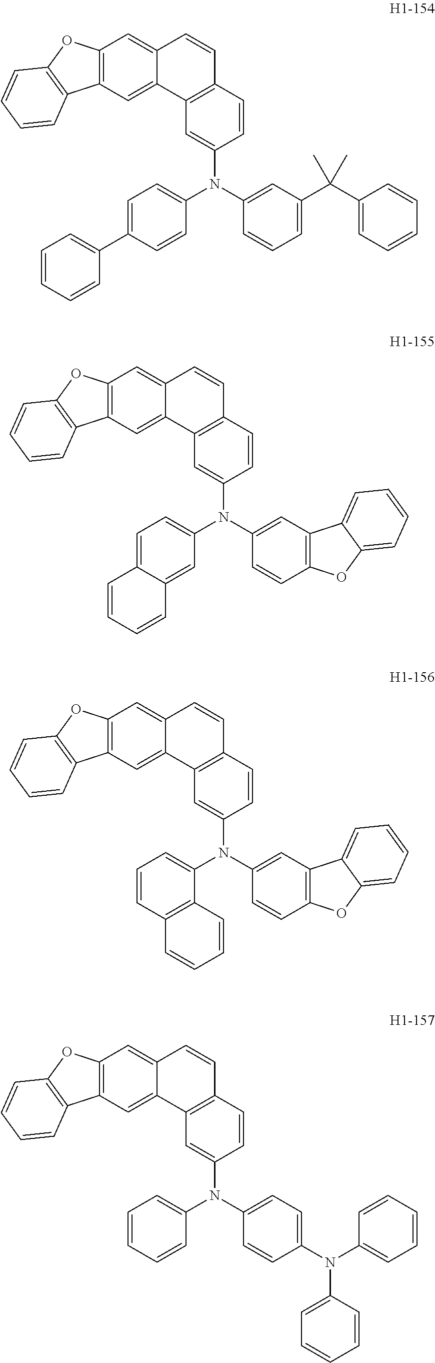 [SMILES: CC(C)(c1ccccc1)c1cccc(N(c2ccc(-c3ccccc3)cc2)c2ccc3ccc4cc5oc6ccccc6c5cc4c3c2)c1 ; c1ccc2cc(N(c3ccc4ccc5cc6oc7ccccc7c6cc5c4c3)c3ccc4oc5ccccc5c4c3)ccc2c1 ; c1ccc2c(N(c3ccc4ccc5cc6oc7ccccc7c6cc5c4c3)c3ccc4oc5ccccc5c4c3)cccc2c1 ; c1ccc(N(c2ccccc2)c2ccc(N(c3ccccc3)c3ccc4ccc5cc6oc7ccccc7c6cc5c4c3)cc2)cc1]

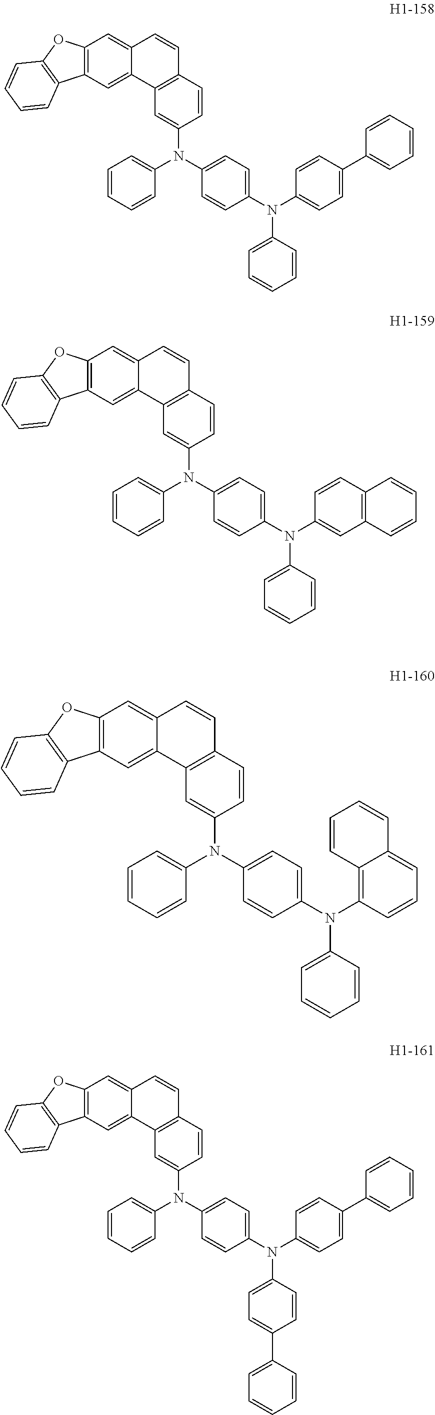 [SMILES: c1ccc(-c2ccc(N(c3ccccc3)c3ccc(N(c4ccccc4)c4ccc5ccc6cc7oc8ccccc8c7cc6c5c4)cc3)cc2)cc1 ; c1ccc(N(c2ccc(N(c3ccccc3)c3ccc4ccc5cc6oc7ccccc7c6cc5c4c3)cc2)c2ccc3ccccc3c2)cc1 ; c1ccc(N(c2ccc(N(c3ccccc3)c3cccc4ccccc34)cc2)c2ccc3ccc4cc5oc6ccccc6c5cc4c3c2)cc1 ; c1ccc(-c2ccc(N(c3ccc(-c4ccccc4)cc3)c3ccc(N(c4ccccc4)c4ccc5ccc6cc7oc8ccccc8c7cc6c5c4)cc3)cc2)cc1]

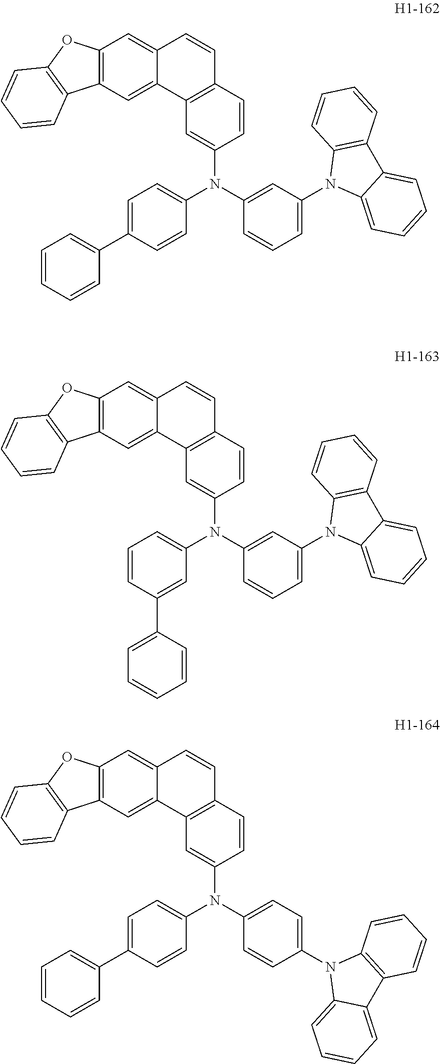 [SMILES: c1ccc(-c2ccc(N(c3cccc(-n4c5ccccc5c5ccccc54)c3)c3ccc4ccc5cc6oc7ccccc7c6cc5c4c3)cc2)cc1 ; c1ccc(-c2cccc(N(c3cccc(-n4c5ccccc5c5ccccc54)c3)c3ccc4ccc5cc6oc7ccccc7c6cc5c4c3)c2)cc1 ; c1ccc(-c2ccc(N(c3ccc(-n4c5ccccc5c5ccccc54)cc3)c3ccc4ccc5cc6oc7ccccc7c6cc5c4c3)cc2)cc1]

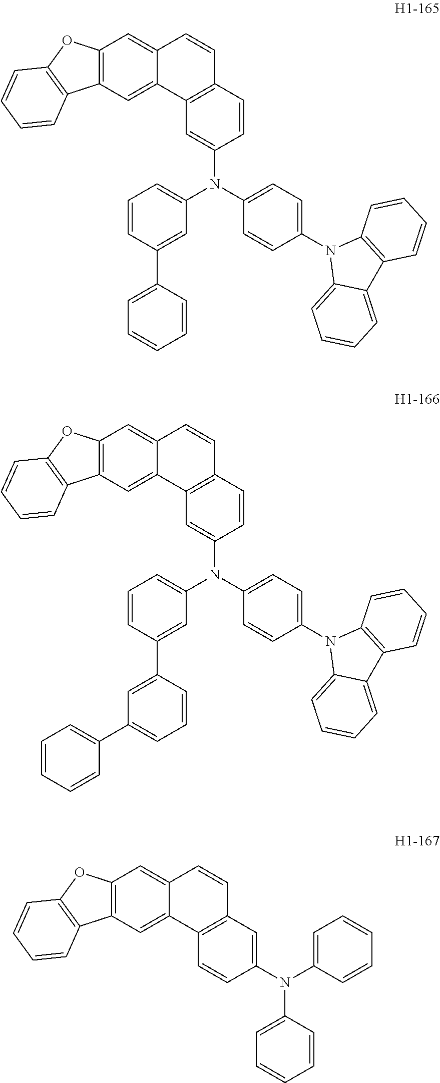 [SMILES: c1ccc(-c2cccc(N(c3ccc(-n4c5ccccc5c5ccccc54)cc3)c3ccc4ccc5cc6oc7ccccc7c6cc5c4c3)c2)cc1 ; c1ccc(-c2cccc(-c3cccc(N(c4ccc(-n5c6ccccc6c6ccccc65)cc4)c4ccc5ccc6cc7oc8ccccc8c7cc6c5c4)c3)c2)cc1 ; c1ccc(N(c2ccccc2)c2ccc3c(ccc4cc5oc6ccccc6c5cc43)c2)cc1]

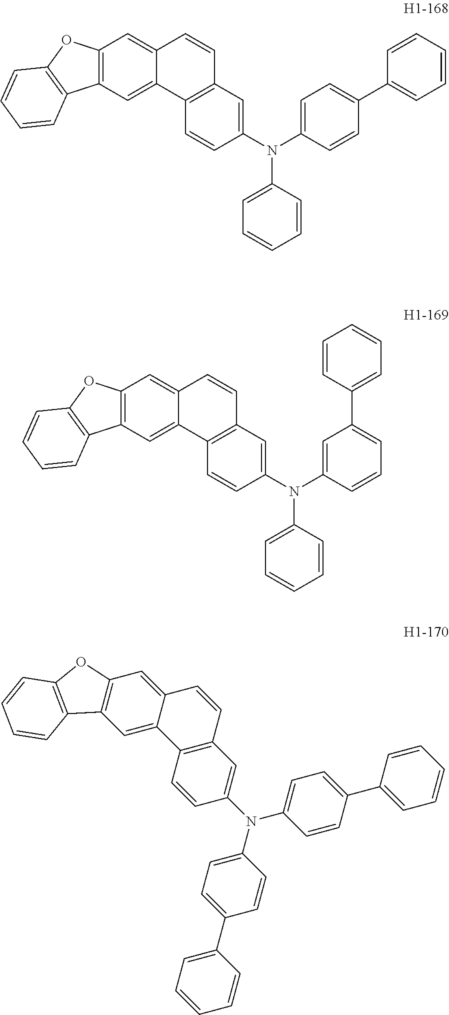 [SMILES: c1ccc(-c2ccc(N(c3ccccc3)c3ccc4c(ccc5cc6oc7ccccc7c6cc54)c3)cc2)cc1 ; c1ccc(-c2cccc(N(c3ccccc3)c3ccc4c(ccc5cc6oc7ccccc7c6cc54)c3)c2)cc1 ; c1ccc(-c2ccc(N(c3ccc(-c4ccccc4)cc3)c3ccc4c(ccc5cc6oc7ccccc7c6cc54)c3)cc2)cc1]

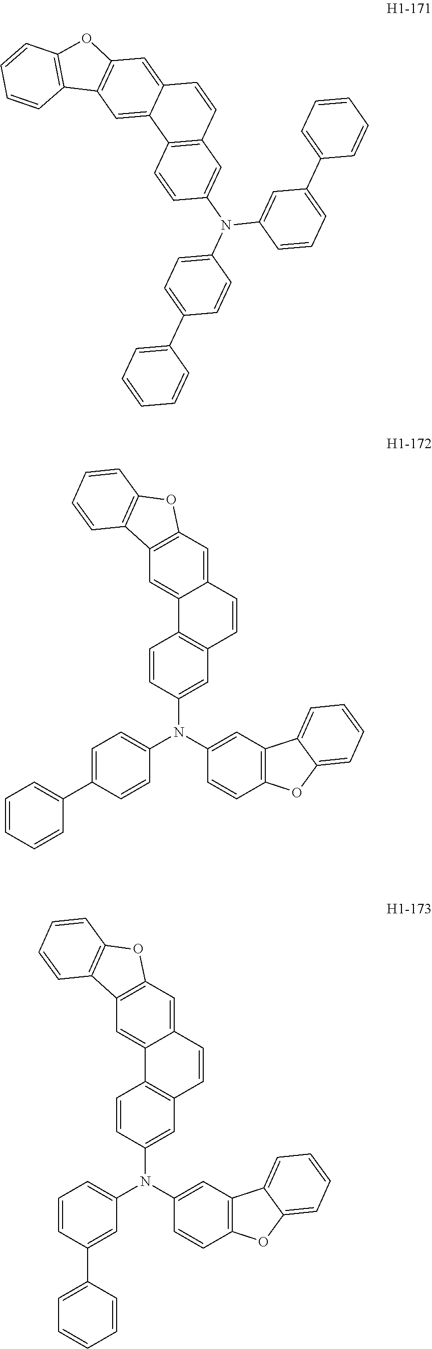 [SMILES: c1ccc(-c2ccc(N(c3cccc(-c4ccccc4)c3)c3ccc4c(ccc5cc6oc7ccccc7c6cc54)c3)cc2)cc1 ; c1ccc(-c2ccc(N(c3ccc4c(ccc5cc6oc7ccccc7c6cc54)c3)c3ccc4oc5ccccc5c4c3)cc2)cc1 ; c1ccc(-c2cccc(N(c3ccc4c(ccc5cc6oc7ccccc7c6cc54)c3)c3ccc4oc5ccccc5c4c3)c2)cc1]

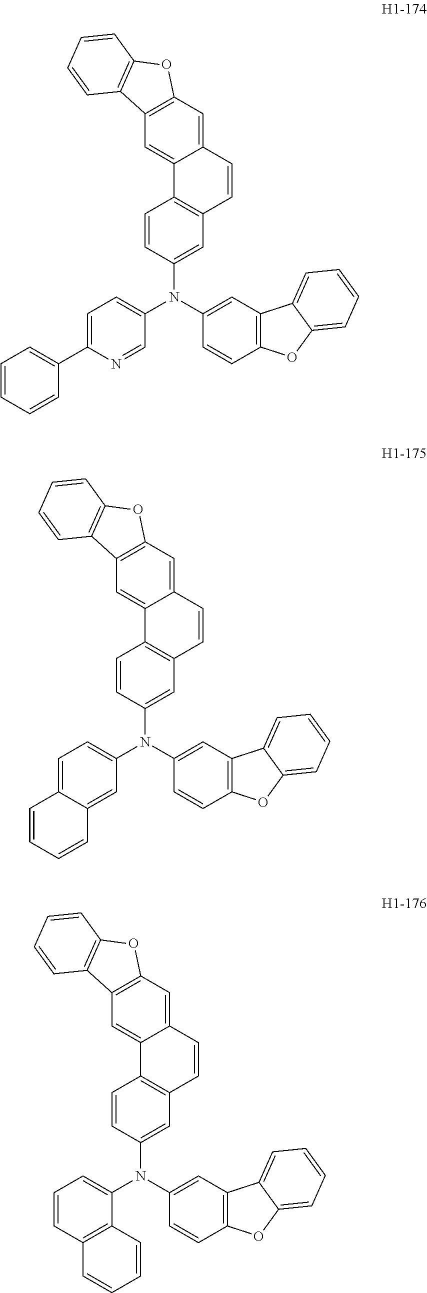 [SMILES: c1ccc(-c2ccc(N(c3ccc4c(ccc5cc6oc7ccccc7c6cc54)c3)c3ccc4oc5ccccc5c4c3)cn2)cc1 ; c1ccc2cc(N(c3ccc4c(ccc5cc6oc7ccccc7c6cc54)c3)c3ccc4oc5ccccc5c4c3)ccc2c1 ; c1ccc2c(N(c3ccc4c(ccc5cc6oc7ccccc7c6cc54)c3)c3ccc4oc5ccccc5c4c3)cccc2c1]

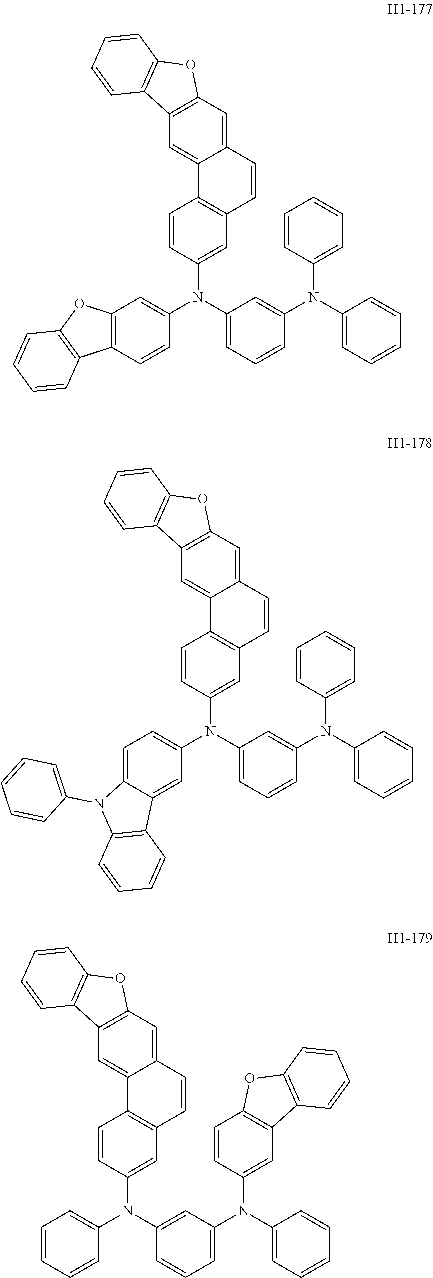 [SMILES: c1ccc(N(c2ccccc2)c2cccc(N(c3ccc4c(ccc5cc6oc7ccccc7c6cc54)c3)c3ccc4c(c3)oc3ccccc34)c2)cc1 ; c1ccc(N(c2ccccc2)c2cccc(N(c3ccc4c(ccc5cc6oc7ccccc7c6cc54)c3)c3ccc4c(c3)c3ccccc3n4-c3ccccc3)c2)cc1 ; c1ccc(N(c2cccc(N(c3ccccc3)c3ccc4oc5ccccc5c4c3)c2)c2ccc3c(ccc4cc5oc6ccccc6c5cc43)c2)cc1]

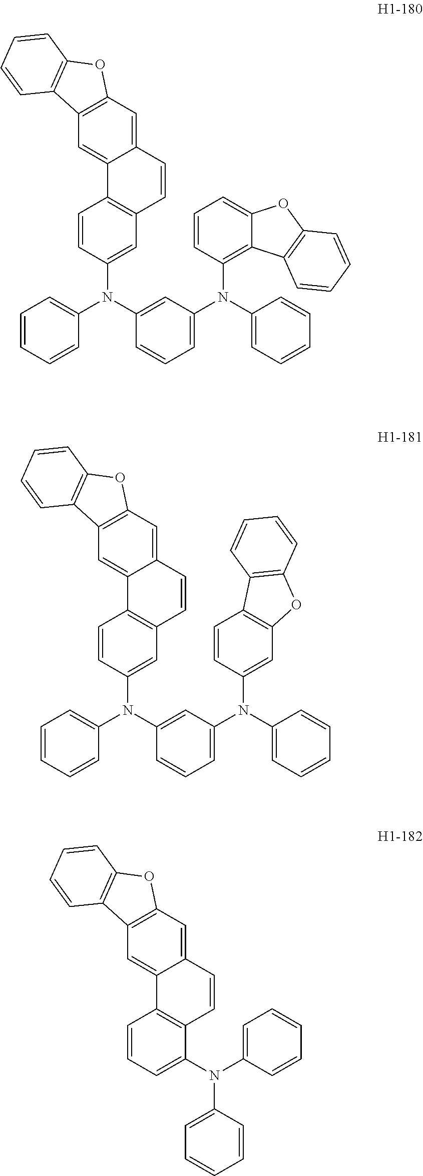 [SMILES: c1ccc(N(c2cccc(N(c3ccccc3)c3cccc4oc5ccccc5c34)c2)c2ccc3c(ccc4cc5oc6ccccc6c5cc43)c2)cc1 ; c1ccc(N(c2cccc(N(c3ccccc3)c3ccc4c(c3)oc3ccccc34)c2)c2ccc3c(ccc4cc5oc6ccccc6c5cc43)c2)cc1 ; c1ccc(N(c2ccccc2)c2cccc3c2ccc2cc4oc5ccccc5c4cc23)cc1]

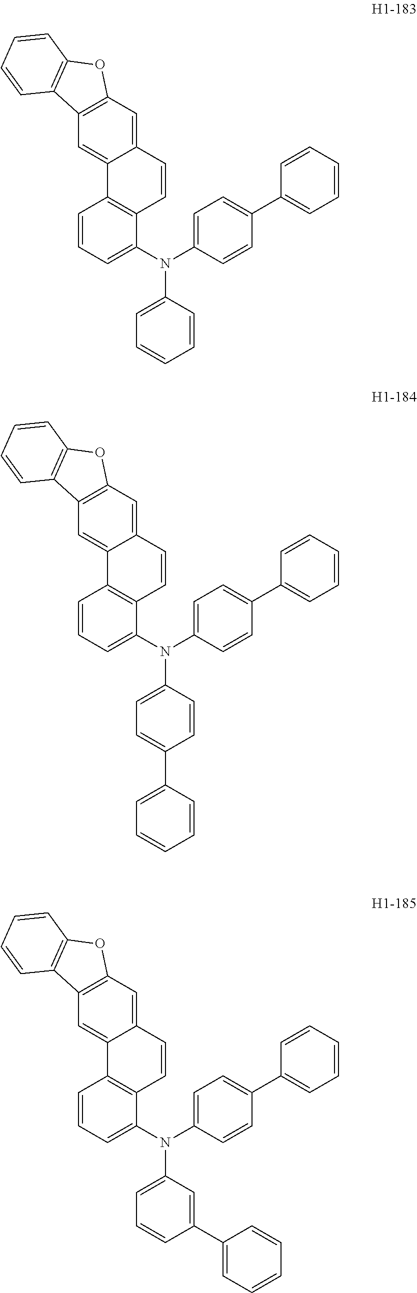 [SMILES: c1ccc(-c2ccc(N(c3ccccc3)c3cccc4c3ccc3cc5oc6ccccc6c5cc34)cc2)cc1 ; c1ccc(-c2ccc(N(c3ccc(-c4ccccc4)cc3)c3cccc4c3ccc3cc5oc6ccccc6c5cc34)cc2)cc1 ; c1ccc(-c2ccc(N(c3cccc(-c4ccccc4)c3)c3cccc4c3ccc3cc5oc6ccccc6c5cc34)cc2)cc1]

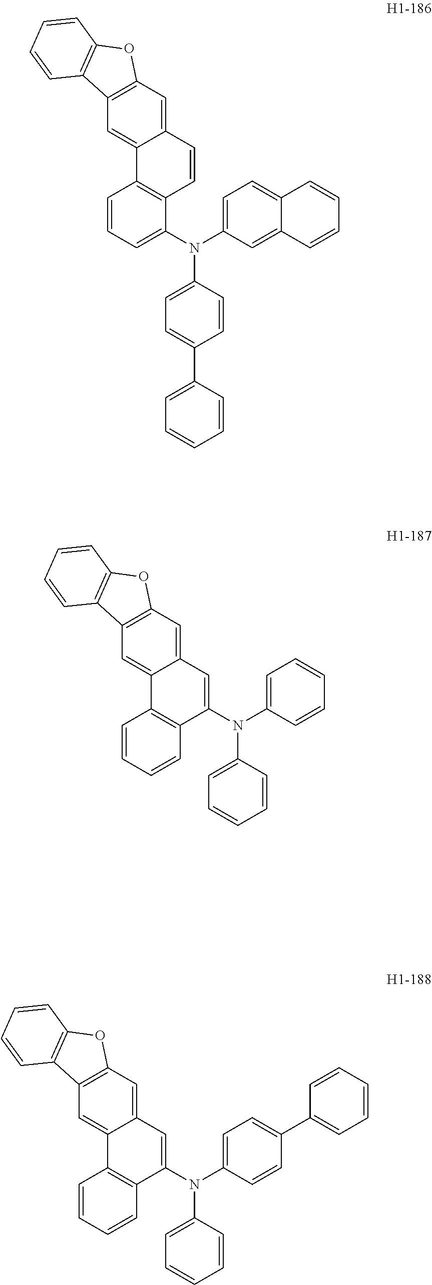 [SMILES: c1ccc(-c2ccc(N(c3ccc4ccccc4c3)c3cccc4c3ccc3cc5oc6ccccc6c5cc34)cc2)cc1 ; c1ccc(N(c2ccccc2)c2cc3cc4oc5ccccc5c4cc3c3ccccc23)cc1 ; c1ccc(-c2ccc(N(c3ccccc3)c3cc4cc5oc6ccccc6c5cc4c4ccccc34)cc2)cc1]

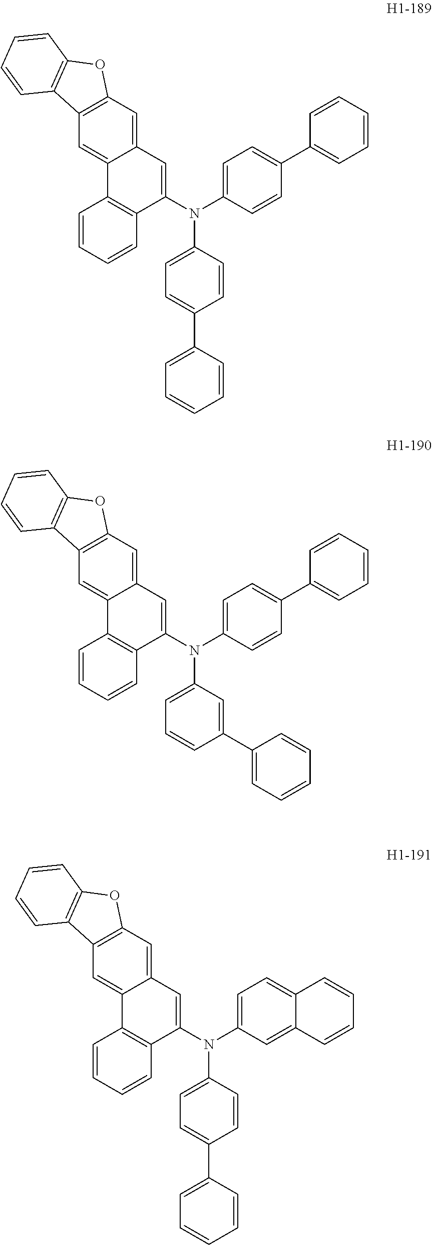 [SMILES: c1ccc(-c2ccc(N(c3ccc(-c4ccccc4)cc3)c3cc4cc5oc6ccccc6c5cc4c4ccccc34)cc2)cc1 ; c1ccc(-c2ccc(N(c3cccc(-c4ccccc4)c3)c3cc4cc5oc6ccccc6c5cc4c4ccccc34)cc2)cc1 ; c1ccc(-c2ccc(N(c3ccc4ccccc4c3)c3cc4cc5oc6ccccc6c5cc4c4ccccc34)cc2)cc1]

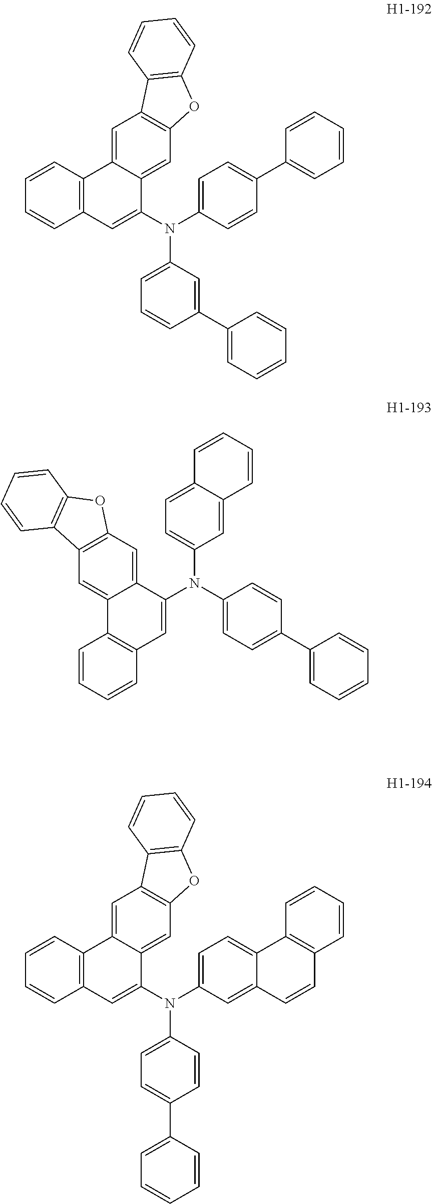 [SMILES: c1ccc(-c2ccc(N(c3cccc(-c4ccccc4)c3)c3cc4ccccc4c4cc5c(cc34)oc3ccccc35)cc2)cc1 ; c1ccc(-c2ccc(N(c3ccc4ccccc4c3)c3cc4ccccc4c4cc5c(cc34)oc3ccccc35)cc2)cc1 ; c1ccc(-c2ccc(N(c3ccc4c(ccc5ccccc54)c3)c3cc4ccccc4c4cc5c(cc34)oc3ccccc35)cc2)cc1]

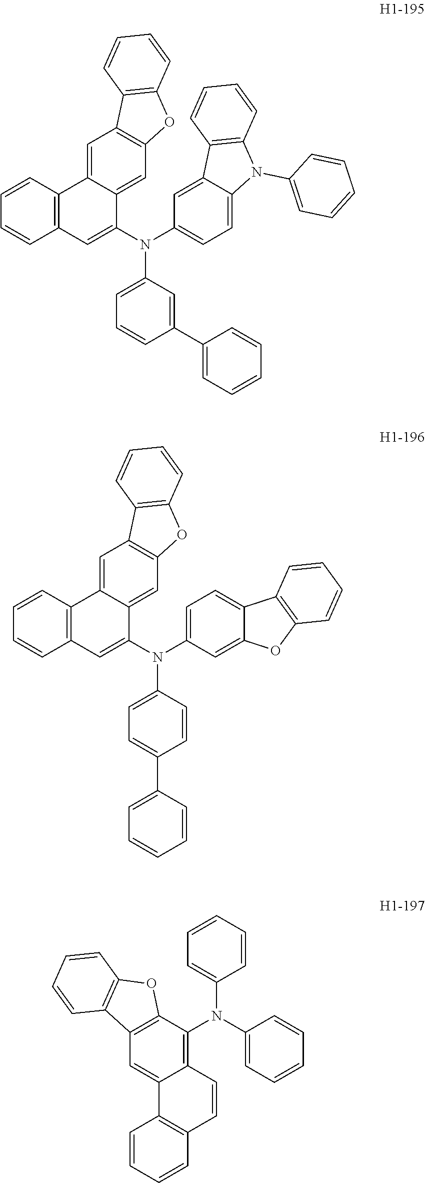 [SMILES: c1ccc(-c2cccc(N(c3ccc4c(c3)c3ccccc3n4-c3ccccc3)c3cc4ccccc4c4cc5c(cc34)oc3ccccc35)c2)cc1 ; c1ccc(-c2ccc(N(c3ccc4c(c3)oc3ccccc34)c3cc4ccccc4c4cc5c(cc34)oc3ccccc35)cc2)cc1 ; c1ccc(N(c2ccccc2)c2c3ccc4ccccc4c3cc3c2oc2ccccc23)cc1]

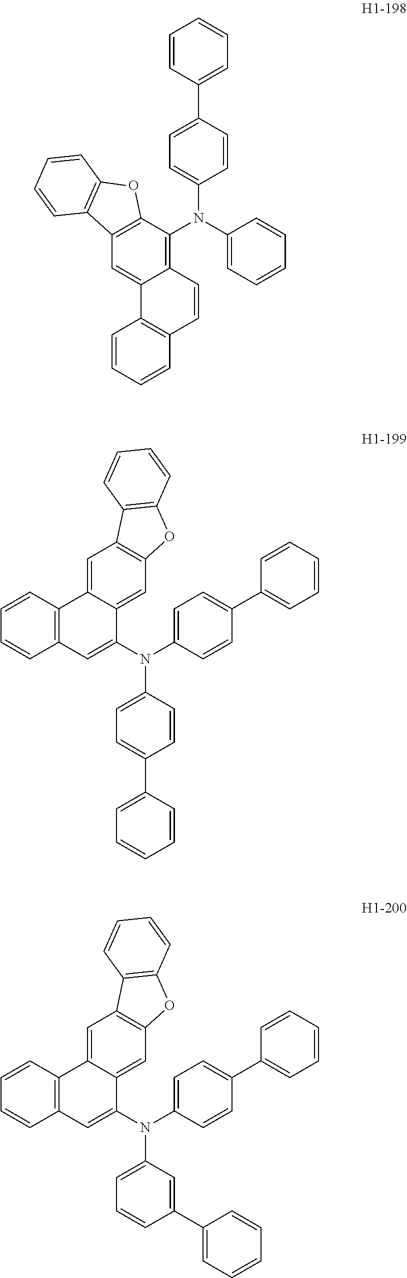 [SMILES: c1ccc(-c2ccc(N(c3ccccc3)c3c4ccc5ccccc5c4cc4c3oc3ccccc34)cc2)cc1 ; c1ccc(-c2ccc(N(c3ccc(-c4ccccc4)cc3)c3cc4ccccc4c4cc5c(cc34)oc3ccccc35)cc2)cc1 ; c1ccc(-c2ccc(N(c3cccc(-c4ccccc4)c3)c3cc4ccccc4c4cc5c(cc34)oc3ccccc35)cc2)cc1]

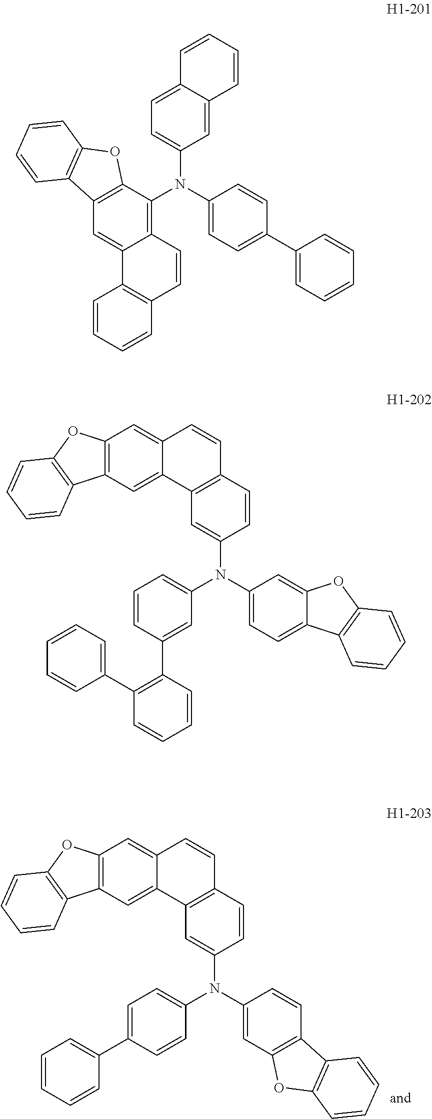 [SMILES: c1ccc(-c2ccc(N(c3ccc4ccccc4c3)c3c4ccc5ccccc5c4cc4c3oc3ccccc34)cc2)cc1 ; c1ccc(-c2ccccc2-c2cccc(N(c3ccc4c(c3)oc3ccccc34)c3ccc4ccc5cc6oc7ccccc7c6cc5c4c3)c2)cc1 ; c1ccc(-c2ccc(N(c3ccc4c(c3)oc3ccccc34)c3ccc4ccc5cc6oc7ccccc7c6cc5c4c3)cc2)cc1]

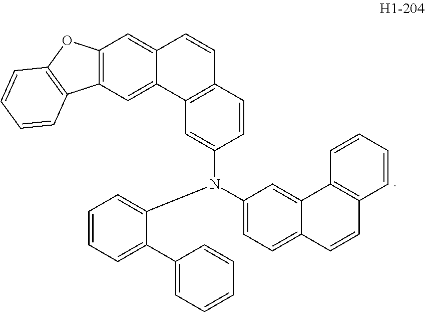 [SMILES: c1ccc(-c2ccccc2N(c2ccc3ccc4ccccc4c3c2)c2ccc3ccc4cc5oc6ccccc6c5cc4c3c2)cc1]

10. An organic electroluminescent device comprising the compound according to claim 1.

11. An organic electroluminescent device comprising the organic electroluminescent material according to claim 5.

12. An organic electroluminescent device comprising the organic electroluminescent material according to claim 8.
